(19) United States
(12) Patent Application Publication
(10) Pub. No.: US 2026/0354023 A1
(43) Pub. Date: Nov. 5, 2026

(54) ORGANIC ELECTROLUMINESCENT DEVICE AND DISPLAY APPARATUS THEREOF

(71) Applicant: BEIJING SUMMER SPROUT TECHNOLOGY CO., LTD., Beijing (CN)

(72) Inventors: Zheng Wang, Beijing (CN); Zhen Wang, Beijing (CN); Hongbo Li, Beijing (CN); Wei Cai, Beijing (CN); Chi Yuen Raymond Kwong, Beijing (CN); Chuanjun Xia, Beijing (CN)

(73) Assignee: BEIJING SUMMER SPROUT TECHNOLOGY CO., LTD., Beijing (CN)

(21) Appl. No.: 19/633,220

(22) Filed: Mar. 30, 2026

(30) Foreign Application Priority Data
Mar. 30, 2025 (CN) 202510386058.2
Sep. 8, 2025 (CN) 202511276650.3
Mar. 13, 2026 (CN) 202610310842.X

(51) Int. Cl. H10K 85/60; C09K 11/02; C09K 11/06; H10K 50/12; H10K 85/30; H10K 101/00; H10K 101/20

(52) U.S. Cl. CPC H10K 85/658; C09K 11/02; C09K 11/06; H10K 85/342; H10K 85/654; H10K 85/6572; C09K 2211/1018; H10K 50/121; H10K 2101/20; H10K 2101/27; H10K 2101/90

(57) ABSTRACT

Provided are an organic electroluminescent device and a display apparatus. The organic electroluminescent device comprises an anode, a cathode, and an organic layer disposed between the anode and the cathode, wherein the organic layer comprises at least a metal complex comprising a ligand Lₐ having a particular structure represented by Formula 1 and a fluorescent material having a structure represented by Formula 2. The organic electroluminescent device can further achieve a significant improvement in device efficiency on the basis of maintaining a relatively low drive voltage and/or a relatively narrow full width at half maximum (FWHM) and has excellent overall performance. Further provided are a display apparatus comprising the organic electroluminescent device and a compound composition comprising the metal complex comprising a ligand Lₐ having a particular structure represented by Formula 1 and the fluorescent material having a structure represented by Formula 2.

### CROSS-REFERENCE TO RELATED APPLICATION(S)

This application claims priority to Chinese Patent Application No. 202510386058.2 filed on Mar. 30, 2025 and Chinese Patent Application No. 202511276650.3 filed on Sep. 8, 2025, and Chinese Patent Application No. 202610310842.X filed on Mar. 13, 2026, the disclosure of which are incorporated herein by reference in their entireties.

### TECHNICAL FIELD

The present disclosure relates to organic electronic devices, for example, organic electroluminescent devices. More particularly, the present disclosure relates to an organic electroluminescent device comprising a metal complex and a fluorescent material in an emissive layer and a display apparatus comprising the organic electroluminescent device.

### BACKGROUND

Organic electronic devices include, but are not limited to, the following types: organic light-emitting diodes (OLEDs), organic field-effect transistors (O-FETs), organic light-emitting transistors (OLETs), organic photovoltaic devices (OPVs), dye-sensitized solar cells (DSSCs), organic optical detectors, organic photoreceptors, organic field-quench devices (OFQDs), light-emitting electrochemical cells (LECs), organic laser diodes and organic plasmon emitting devices.

In 1987, Tang and Van Slyke of Eastman Kodak reported a bilayer organic electroluminescent device, which includes an arylamine hole transporting layer and a tris-8-hydroxyquinolato-aluminum layer as the electron and emitting layer (Applied Physics Letters, 1987, 51 (12): 913-915). Once a bias is applied to the device, green light was emits from the device. This device laid the foundation for the development of modern organic light-emitting diodes (OLEDs). State-of-the-art OLEDs may include multiple layers such as charge injection and transporting layers, charge and exciton blocking layers, and one or multiple emissive layers between the cathode and anode. Since the OLED is a self-emitting solid state device, it offers tremendous potential for display and lighting applications. In addition, the inherent properties of organic materials, such as their flexibility, may make them well suited for particular applications such as fabrication on flexible substrates.

The OLED can be categorized as three different types according to its emitting mechanism. The OLED invented by Tang and van Slyke is a fluorescent OLED. It only utilizes singlet emission. The triplets generated in the device are wasted through nonradiative decay channels. Therefore, the internal quantum efficiency (IQE) of the fluorescent OLED is only 25%. This limitation hindered the commercialization of OLED. In 1997, Forrest and Thompson reported phosphorescent OLED, which uses triplet emission from heavy metal containing complexes as the emitter. As a result, both singlet and triplets can be harvested, achieving 100% IQE. The discovery and development of phosphorescent OLED contributed directly to the commercialization of active-matrix OLED (AMOLED) due to its high efficiency. Recently, Adachi achieved high efficiency through thermally activated delayed fluorescence (TADF) of organic compounds. These emitters have small singlet-triplet gap that makes the transition from triplet back to singlet possible. In the TADF device, the triplet excitons can go through reverse intersystem crossing to generate singlet excitons, resulting in high IQE.

OLEDs can also be classified as small molecule and polymer OLEDs according to the forms of the materials used. A small molecule refers to any organic or organometallic material that is not a polymer. The molecular weight of the small molecule can be large as long as it has well defined structure. Dendrimers with well-defined structures are considered as small molecules. Polymer OLEDs include conjugated polymers and non-conjugated polymers with pendant emitting groups. Small molecule OLED can become the polymer OLED if post polymerization occurred during the fabrication process.

There are various methods for OLED fabrication. Small molecule OLEDs are generally fabricated by vacuum thermal evaporation. Polymer OLEDs are fabricated by solution process such as spin-coating, inkjet printing, and slit printing. If the material can be dissolved or dispersed in a solvent, the small molecule OLED can also be produced by solution process.

The emitting color of the OLED can be achieved by emitter structural design. An OLED may include one emitting layer or a plurality of emitting layers to achieve desired spectrum. In the case of green, yellow, and red OLEDs, phosphorescent emitters have successfully reached commercialization. Blue phosphorescent device still suffers from non-saturated blue color, short device lifetime, and high operating voltage. Commercial full-color OLED displays normally adopt a hybrid strategy, using fluorescent blue and phosphorescent yellow, or red and green. At present, efficiency roll-off of phosphorescent OLEDs at high brightness remains a problem. In addition, it is desirable to have more saturated emitting color, higher efficiency, and longer device lifetime.

WO2020080528A1 has disclosed a polycyclic aromatic compound having a structure represented by a general formula of

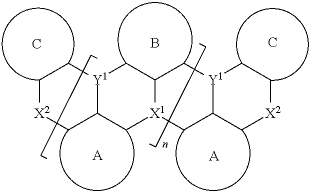

wherein X² each independently represents O, NR, CRR, S, or Se. WO2020080528A1 has further disclosed specific compounds such as

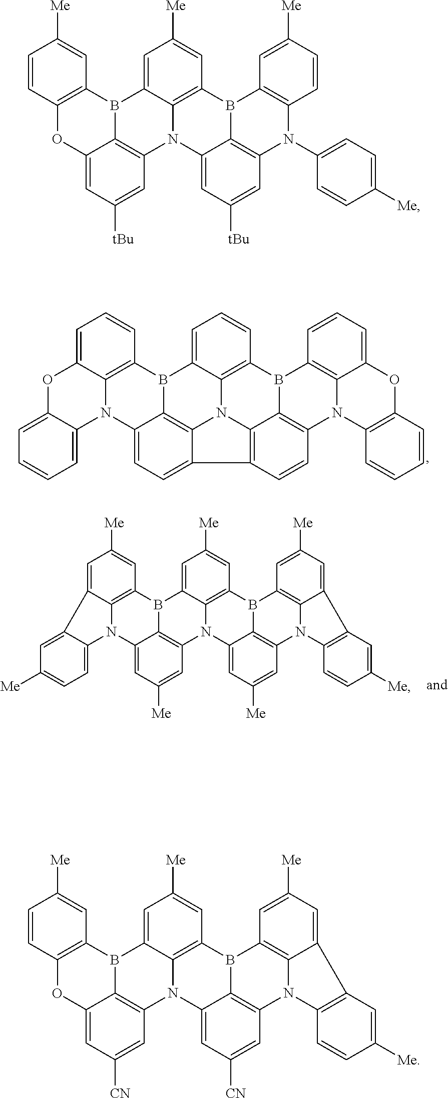 [SMILES: Cc1ccc(N2c3ccc(C)cc3B3c4cc(C)cc5c4N(c4cc(C(C)(C)C)cc6c4B5c4cc(C)ccc4O6)c4cc(C(C)(C)C)cc2c43)cc1 ; c1ccc2c(c1)Oc1cccc3c1N2c1ccc2c4ccc5c6c4n4c2c1B3c1cccc(c1-4)B6c1cccc2c1N5c1ccccc1O2 ; Cc1cc2c3c(c1)B1c4c(cc(C)cc4-n4c5ccc(C)cc5c5cc(C)cc1c54)N3c1cc(C)cc3c1B2c1cc(C)cc2c4cc(C)ccc4n-3c12 ; "and" ; Cc1ccc2c(c1)B1c3cc(C)cc4c3N(c3cc(C#N)cc(c31)O2)c1cc(C#N)cc2c1B4c1cc(C)cc3c4cc(C)ccc4n-2c13]

However, WO2020080528A1 has neither disclosed nor taught different technical effects of devices brought by such compounds for use as fluorescent materials in combination with a metal complex having a particular structure and used as a phosphorescent sensitizer.

CN114478601A has disclosed a compound having a structure represented by a general formula of

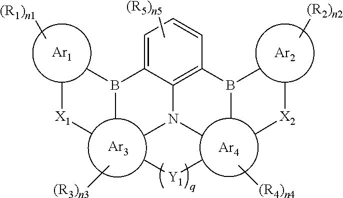

and further disclosed specific structures such as

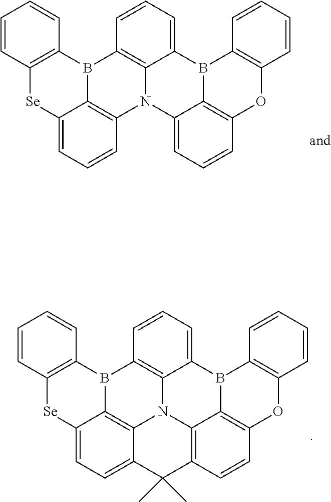 [SMILES: c1ccc2c(c1)Oc1cccc3c1B2c1cccc2c1N3c1cccc3c1B2c1ccccc1[Se]3 ; CC1(C)c2ccc3c4c2N2c5c(cccc5B5c6ccccc6[Se]c6ccc1c2c65)B4c1ccccc1O3]

However, CN114478601A has neither disclosed nor taught different technical effects of devices brought by such compounds for use as fluorescent materials in combination with a metal complex having a particular structure and used as a phosphorescent sensitizer.

In addition to novel light-emitting materials, combinations of different materials, especially combinations of different phosphorescent sensitizers and fluorescent materials, have particularly important effects on device performance. To satisfy increasingly high requirements of the industry, especially requirements for performance such as higher device efficiency and a longer lifetime, combinations of different phosphorescent sensitizers and fluorescent materials still need to be further studied and developed.

### SUMMARY

The present disclosure aims to provide a new organic electroluminescent device to solve at least part of the preceding problems. An organic layer of the organic electroluminescent device comprises both a metal complex having a particular structure (comprising a ligand Lₐ having a structure of Formula 1) and a fluorescent material having a structure represented by Formula 2. The new organic electroluminescent device of the present disclosure can further achieve a significant improvement in device efficiency on the basis of maintaining a relatively low drive voltage and/or a relatively narrow full width at half maximum (FWHM) and has excellent overall performance.

According to an embodiment of the present disclosure, disclosed is an organic electroluminescent device. The organic electroluminescent device comprises a cathode, an anode, and at least one organic layer disposed between the cathode and the anode, wherein the organic layer comprises a metal complex and a fluorescent material;
the metal complex comprises a metal M and a ligand Lₐ coordinated to the metal M, the metal M is selected from a metal with a relative atomic mass greater than 40, and the ligand Lₐ has a structure represented by Formula 1:

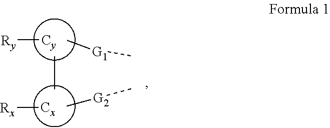

wherein
the ring C_{y} and the ring Cₓ are, at each occurrence identically or differently, selected from an aromatic ring having 6 to 30 ring atoms, a heteroaromatic ring having 5 to 30 ring atoms, or a combination thereof;
G₁ and G₂ are, at each occurrence identically or differently, selected from a single bond, O, S, or NR_{N};
Rₓ and R_{y} represent, at each occurrence identically or differently, mono-substitution, multiple substitutions, or non-substitution;
R_{N}, Rₓ, and R_{y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R_{N}, Rₓ, and R_{y} can be optionally joined to form a ring;
the fluorescent material has a structure represented by Formula 2:

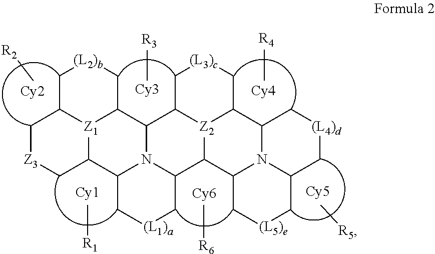

wherein
the ring Cy1, the ring Cy2, the ring Cy3, the ring Cy4, the ring Cy5, and the ring Cy6 are, at each occurrence identically or differently, selected from an unsaturated carbocyclic ring having 5 to 30 carbon atoms, an unsaturated heterocyclic ring having 3 to 30 carbon atoms, or a combination thereof;
Z₁ and Z₂ are, at each occurrence identically or differently, selected from B, N, P, P═O, P═S, As, As═O, or As═S;
Z₃ is, at each occurrence identically or differently, selected from O, S, Se, PR, P═OR, CRR, SiRR, GeRR, C═O, C═S, or C═CRR; when multiple R are present, the multiple R are identical or different;
L₁, L₂, L₃, L₄, and L₅ are, at each occurrence identically or differently, selected from a single bond, O, S, Se, BR′, NR′, PR′, P═OR′, P═SR′, AsR′, As═OR′, As═SR′, C═O, CR′R′, SiR′R′, or GeR′R′; when multiple R′ are present, the multiple R′ are identical or different;
a, b, c, d, and e are each independently selected from 0 or 1;
R₁, R₂, R₃, R₄, R₅, and R₆ represent, at each occurrence identically or differently, mono-substitution, multiple substitutions, or non-substitution;
R, R′, R₁, R₂, R₃, R₄, R₅, and R₆ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, —BR″R″, and combinations thereof;
R″ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof, and adjacent substituents R, R′, R″, R₁, R₂, R₃, R₄, R₅, and R₆ can be optionally joined to form a ring.

According to another embodiment of the present disclosure, further disclosed is a compound composition. The compound composition comprises the preceding metal complex comprising a ligand Lₐ having a structure represented by Formula 1 and the preceding fluorescent material having a structure represented by Formula 2.

According to another embodiment of the present disclosure, further disclosed is a display apparatus comprising the preceding organic electroluminescent device.

According to another embodiment of the present disclosure, further disclosed is an application of the preceding organic electroluminescent device in a display apparatus.

### BRIEF DESCRIPTION OF DRAWINGS

FIG. 1 is a schematic diagram of an organic light-emitting device that may comprise an organic electroluminescent device disclosed herein.

FIG. 2 is a schematic diagram of another organic light-emitting device that may comprise an organic electroluminescent device disclosed herein.

### DETAILED DESCRIPTION

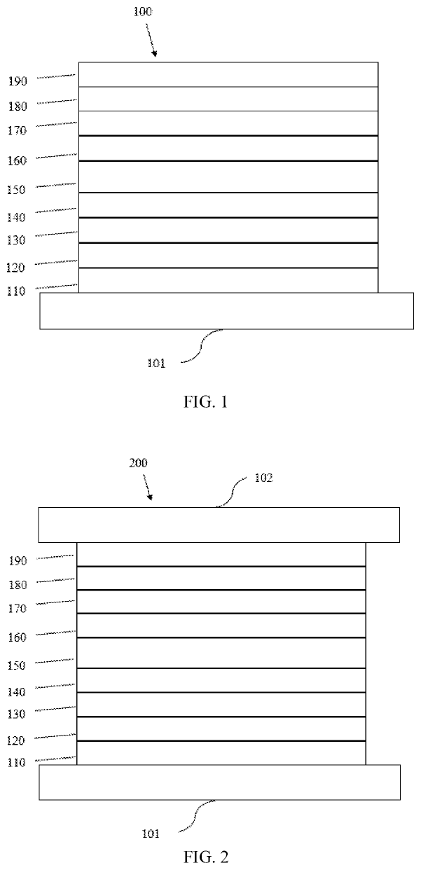

OLEDs can be fabricated on various types of substrates such as glass, plastic, and metal foil. FIG. 1 schematically shows an organic light-emitting device 100 without limitation. The figures are not necessarily drawn to scale. Some of the layers in the figures can also be omitted as needed. Device 100 may include a substrate 101, an anode 110, a hole injection layer 120, a hole transport layer 130, an electron blocking layer 140, an emissive layer 150, a hole blocking layer 160, an electron transport layer 170, an electron injection layer 180 and a cathode 190. Device 100 may be fabricated by depositing the layers described in order. The properties and functions of these various layers, as well as example materials, are described in more detail in U.S. Pat. No. 7,279,704 at cols. 6-10, the contents of which are incorporated by reference herein in its entirety.

More examples for each of these layers are available. For example, a flexible and transparent substrate-anode combination is disclosed in U.S. Pat. No. 5,844,363, which is incorporated by reference herein in its entirety. An example of a p-doped hole transport layer is m-MTDATA doped with F4-TCNQ at a molar ratio of 50:1, as disclosed in U.S. Patent Application Publication No. 2003/0230980, which is incorporated by reference herein in its entirety. Examples of host materials are disclosed in U.S. Pat. No. 6,303,238 to Thompson et al., which is incorporated by reference herein in its entirety. An example of an n-doped electron transport layer is BPhen doped with Li at a molar ratio of 1:1, as disclosed in U.S. Patent Application Publication No. 2003/0230980, which is incorporated by reference herein in its entirety. U.S. Pat. Nos. 5,703,436 and 5,707,745, which are incorporated by reference herein in their entireties, disclose examples of cathodes including composite cathodes having a thin layer of metal such as Mg:Ag with an overlying transparent, electrically-conductive, sputter-deposited ITO layer. The theory and use of blocking layers are described in more detail in U.S. Pat. No. 6,097,147 and U.S. Patent Application Publication No. 2003/0230980, which are incorporated by reference herein in their entireties. Examples of injection layers are provided in U.S. Patent Application Publication No. 2004/0174116, which is incorporated by reference herein in its entirety. A description of protective layers may be found in U.S. Patent Application Publication No. 2004/0174116, which is incorporated by reference herein in its entirety.

The layered structure described above is provided by way of non-limiting examples. Functional OLEDs may be achieved by combining the various layers described in different ways, or layers may be omitted entirely. It may also include other layers not specifically described. Within each layer, a single material or a mixture of multiple materials can be used to achieve optimum performance. Any functional layer may include several sublayers. For example, the emissive layer may have two layers of different emitting materials to achieve desired emission spectrum.

In one embodiment, an OLED may be described as having an “organic layer” disposed between a cathode and an anode. This organic layer may include a single layer or multiple layers.

An OLED can be encapsulated by a barrier layer. FIG. 2 schematically shows an organic light emitting device 200 without limitation. FIG. 3 differs from FIG. 2 in that the organic light emitting device include a barrier layer 102, which is above the cathode 190, to protect it from harmful species from the environment such as moisture and oxygen. Any material that can provide the barrier function can be used as the barrier layer such as glass or organic-inorganic hybrid layers. The barrier layer should be placed directly or indirectly outside of the OLED device. Multilayer thin film encapsulation was described in U.S. Pat. No. 7,968,146, which is incorporated by reference herein in its entirety.

Devices fabricated in accordance with embodiments of the present disclosure can be incorporated into a wide variety of consumer products that have one or more of the electronic component modules (or units) incorporated therein. Some examples of such consumer products include flat panel displays, monitors, medical monitors, televisions, billboards, lights for interior or exterior illumination and/or signaling, heads-up displays, fully or partially transparent displays, flexible displays, smart phones, tablets, phablets, wearable devices, smart watches, laptop computers, digital cameras, camcorders, viewfinders, micro-displays, 3-D displays, vehicles displays, and vehicle tail lights.

The materials and structures described herein may be used in other organic electronic devices listed above.

As used herein, “top” means furthest away from the substrate, while “bottom” means closest to the substrate. Where a first layer is described as “disposed over” a second layer, the first layer is disposed further away from the substrate. There may be other layers between the first and second layers, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

As used herein, “terminal light-emitting material” aims to refer to a material as a final light-emitting source when the organic electroluminescent device (a device with an emissive layer comprising at least two light-emitting materials) described herein is lit. For example, if the emissive layer of the organic electroluminescent device comprises a metal complex (a phosphorescent material) and a fluorescent material, when the device is lit, the metal complex of the two materials does not emit light/almost not emit light due to energy transfer, and the fluorescent material is used as a main light-emitting source in the device. Therefore, in this case, the fluorescent material is the terminal light-emitting material of the organic electroluminescent device and includes, but not limited to, Device Examples 1 to 4 of the present disclosure.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

It is believed that the internal quantum efficiency (IQE) of fluorescent OLEDs can exceed the 25% spin statistics limit through delayed fluorescence. As used herein, there are two types of delayed fluorescence, i.e. P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the transition between the triplet states and the singlet excited states. Compounds that are capable of generating E-type delayed fluorescence are required to have very small singlet-triplet gaps to convert between energy states. Thermal energy can activate the transition from the triplet state back to the singlet state. This type of delayed fluorescence is also known as thermally activated delayed fluorescence (TADF). A distinctive feature of TADF is that the delayed component increases as temperature rises. If the reverse intersystem crossing (RISC) rate is fast enough to minimize the non-radiative decay from the triplet state, the fraction of back populated singlet excited states can potentially reach 75%. The total singlet fraction can be 100%, far exceeding 25% of the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (AEs-T). Organic, non-metal containing, donor-acceptor luminescent materials may be able to achieve this. The emission in these materials is generally characterized as a donor-acceptor charge-transfer (CT) type emission. The spatial separation of the HOMO and LUMO in these donor-acceptor type compounds generally results in small AEs-T. These states may involve CT states. Generally, donor-acceptor luminescent materials are constructed by connecting an electron donor moiety such as amino- or carbazole-derivatives and an electron acceptor moiety such as N-containing six-membered aromatic rings.

### Definition of Terms of Substituents

Halogen or halide—as used herein includes fluorine, chlorine, bromine, and iodine.

Alkyl—as used herein includes both straight and branched chain alkyl groups. Alkyl may be alkyl having 1 to 20 carbon atoms, preferably alkyl having 1 to 12 carbon atoms, and more preferably alkyl having 1 to 6 carbon atoms. Examples of alkyl groups include a methyl group, an ethyl group, a propyl group, an isopropyl group, an n-butyl group, an s-butyl group, an isobutyl group, a t-butyl group, an n-pentyl group, an n-hexyl group, an n-heptyl group, an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, an n-octadecyl group, a neopentyl group, a 1-methylpentyl group, a 2-methylpentyl group, a 1-pentylhexyl group, a 1-butylpentyl group, a 1-heptyloctyl group, and a 3-methylpentyl group. Of the above, preferred are a methyl group, an ethyl group, a propyl group, an isopropyl group, a n-butyl group, an s-butyl group, an isobutyl group, a t-butyl group, an n-pentyl group, a neopentyl group, and an n-hexyl group. Additionally, the alkyl group may be optionally substituted.

Cycloalkyl—as used herein includes cyclic alkyl groups. The cycloalkyl groups may be those having 3 to 20 ring carbon atoms, preferably those having 4 to 10 carbon atoms. Examples of cycloalkyl include cyclobutyl, cyclopentyl, cyclohexyl, 4-methylcyclohexyl, 4,4-dimethylcylcohexyl, 1-adamantyl, 2-adamantyl, 1-norbornyl, 2-norbornyl, and the like. Of the above, preferred are cyclopentyl, cyclohexyl, 4-methylcyclohexyl, and 4,4-dimethylcylcohexyl. Additionally, the cycloalkyl group may be optionally substituted.

Heteroalkyl—as used herein, includes a group formed by replacing one or more carbons in an alkyl chain with a hetero-atom(s) selected from the group consisting of a nitrogen atom, an oxygen atom, a sulfur atom, a selenium atom, a phosphorus atom, a silicon atom, a germanium atom, and a boron atom. Heteroalkyl may be those having 1 to 20 carbon atoms, preferably those having 1 to 10 carbon atoms, and more preferably those having 1 to 6 carbon atoms. Examples of heteroalkyl include methoxymethyl, ethoxymethyl, ethoxyethyl, methylthiomethyl, ethylthiomethyl, ethylthioethyl, methoxymethoxymethyl, ethoxymethoxymethyl, ethoxyethoxyethyl, hydroxymethyl, hydroxyethyl, hydroxypropyl, mercaptomethyl, mercaptoethyl, mercaptopropyl, aminomethyl, aminoethyl, aminopropyl, dimethylaminomethyl, trimethylgermanylmethyl, trimethylgermanylethyl, trimethylgermanylisopropyl, dimethylethylgermanylmethyl, dimethylisopropylgermanylmethyl, tert-butylmethylgermanylmethyl, triethylgermanylmethyl, triethylgermanylethyl, triisopropylgermanylmethyl, triisopropylgermanylethyl, trimethylsilylmethyl, trimethylsilylethyl, and trimethylsilylisopropyl, triisopropylsilylmethyl, triisopropylsilylethyl. Additionally, the heteroalkyl group may be optionally substituted.

Alkenyl—as used herein includes straight chain, branched chain, and cyclic alkene groups. Alkenyl may be those having 2 to 20 carbon atoms, preferably those having 2 to 10 carbon atoms. Examples of alkenyl include vinyl, 1-propenyl group, 1-butenyl, 2-butenyl, 3-butenyl, 1,3-butandienyl, 1-methylvinyl, styryl, 2,2-diphenylvinyl, 1,2-diphenylvinyl, 1-methylallyl, 1,1-dimethylallyl, 2-methylallyl, 1-phenylallyl, 2-phenylallyl, 3-phenylallyl, 3,3-diphenylallyl, 1,2-dimethylallyl, 1-phenyl-1-butenyl, 3-phenyl-1-butenyl, cyclopentenyl, cyclopentadienyl, cyclohexenyl, cycloheptenyl, cycloheptatrienyl, cyclooctenyl, cyclooctatetraenyl, and norbornenyl. Additionally, the alkenyl group may be optionally substituted.

Alkynyl—as used herein includes straight chain alkynyl groups. Alkynyl may be those having 2 to 20 carbon atoms, preferably those having 2 to 10 carbon atoms. Examples of alkynyl groups include ethynyl, propynyl, propargyl, 1-butynyl, 2-butynyl, 3-butynyl, 1-pentynyl, 2-pentynyl, 3,3-dimethyl-1-butynyl, 3-ethyl-3-methyl-1-pentynyl, 3,3-diisopropyl-1-pentynyl, phenylethynyl, phenylpropynyl, etc. Of the above, preferred are ethynyl, propynyl, propargyl, 1-butynyl, 2-butynyl, 3-butynyl, 1-pentynyl, and phenylethynyl. Additionally, the alkynyl group may be optionally substituted.

Aryl or an aromatic group—as used herein includes non-condensed and condensed systems. Aryl may be those having 6 to 30 carbon atoms, preferably those having 6 to 20 carbon atoms, and more preferably those having 6 to 12 carbon atoms. Examples of aryl groups include phenyl, biphenyl, terphenyl, triphenylene, tetraphenylene, naphthalene, anthracene, phenalene, phenanthrene, fluorene, pyrene, chrysene, perylene, and azulene, preferably phenyl, biphenyl, terphenyl, triphenylene, fluorene, and naphthalene. Examples of non-condensed aryl groups include phenyl, biphenyl-2-yl, biphenyl-3-yl, biphenyl-4-yl, p-terphenyl-4-yl, p-terphenyl-3-yl, p-terphenyl-2-yl, m-terphenyl-4-yl, m-terphenyl-3-yl, m-terphenyl-2-yl, o-tolyl, m-tolyl, p-tolyl, p-(2-phenylpropyl)phenyl, 4′-methylbiphenylyl, 4″-t-butyl-p-terphenyl-4-yl, o-cumenyl, m-cumenyl, p-cumenyl, 2,3-xylyl, 3,4-xylyl, 2,5-xylyl, mesityl, and m-quarterphenyl. Additionally, the aryl group may be optionally substituted.

Heterocyclic groups—as used herein include non-aromatic cyclic groups.

Non-aromatic heterocyclic groups include saturated heterocyclic groups having 3 to 20 ring atoms and unsaturated non-aromatic heterocyclic groups having 3 to 20 ring atoms, where at least one ring atom is selected from the group consisting of a nitrogen atom, an oxygen atom, a sulfur atom, a selenium atom, a silicon atom, a phosphorus atom, a germanium atom, and a boron atom. Preferred non-aromatic heterocyclic groups are those having 3 to 7 ring atoms, each of which includes at least one hetero-atom such as nitrogen, oxygen, silicon, or sulfur. Examples of non-aromatic heterocyclic groups include oxiranyl, oxetanyl, tetrahydrofuranyl, tetrahydropyranyl, dioxolanyl, dioxanyl, aziridinyl, dihydropyrrolyl, tetrahydropyrrolyl, piperidinyl, oxazolidinyl, morpholinyl, piperazinyl, oxepinyl, thiepinyl, azepinyl, and tetrahydrosilolyl. Additionally, the heterocyclic group may be optionally substituted.

Heteroaryl—as used herein, includes non-condensed and condensed hetero-aromatic groups having 1 to 5 hetero-atoms, where at least one hetero-atom is selected from the group consisting of a nitrogen atom, an oxygen atom, a sulfur atom, a selenium atom, a silicon atom, a phosphorus atom, a germanium atom, and a boron atom. A hetero-aromatic group is also referred to as heteroaryl. Heteroaryl may be those having 3 to 30 carbon atoms, preferably those having 3 to 20 carbon atoms, and more preferably those having 3 to 12 carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridoindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group may be optionally substituted.

Alkoxy—as used herein, is represented by —O-alkyl, —O-cycloalkyl, —O-heteroalkyl, or —O-heterocyclic group. Examples and preferred examples of alkyl, cycloalkyl, heteroalkyl, and heterocyclic groups are the same as those described above. Alkoxy groups may be those having 1 to 20 carbon atoms, preferably those having 1 to 6 carbon atoms. Examples of alkoxy groups include methoxy, ethoxy, propoxy, butoxy, pentyloxy, hexyloxy, cyclopropyloxy, cyclobutyloxy, cyclopentyloxy, cyclohexyloxy, tetrahydrofuranyloxy, tetrahydropyranyloxy, methoxypropyloxy, ethoxyethyloxy, methoxymethyloxy, and ethoxymethyloxy. Additionally, the alkoxy group may be optionally substituted.

Aryloxy—as used herein, is represented by —O-aryl or —O-heteroaryl. Examples and preferred examples of aryl and heteroaryl are the same as those described above. Aryloxy groups may be those having 6 to 30 carbon atoms, preferably those having 6 to 20 carbon atoms. Examples of aryloxy groups include phenoxy and biphenyloxy. Additionally, the aryloxy group may be optionally substituted.

Arylalkyl—as used herein, contemplates alkyl substituted with an aryl group. Arylalkyl may be those having 7 to 30 carbon atoms, preferably those having 7 to 20 carbon atoms, and more preferably those having 7 to 13 carbon atoms. Examples of arylalkyl groups include benzyl, 1-phenylethyl, 2-phenylethyl, 1-phenylisopropyl, 2-phenylisopropyl, phenyl-t-butyl, alpha-naphthylmethyl, 1-alpha-naphthylethyl, 2-alpha-naphthylethyl, 1-alpha-naphthylisopropyl, 2-alpha-naphthylisopropyl, beta-naphthylmethyl, 1-beta-naphthylethyl, 2-beta-naphthylethyl, 1-beta-naphthylisopropyl, 2-beta-naphthylisopropyl, p-methylbenzyl, m-methylbenzyl, o-methylbenzyl, p-chlorobenzyl, m-chlorobenzyl, o-chlorobenzyl, p-bromobenzyl, m-bromobenzyl, o-bromobenzyl, p-iodobenzyl, m-iodobenzyl, o-iodobenzyl, p-hydroxybenzyl, m-hydroxybenzyl, o-hydroxybenzyl, p-aminobenzyl, m-aminobenzyl, o-aminobenzyl, p-nitrobenzyl, m-nitrobenzyl, o-nitrobenzyl, p-cyanobenzyl, m-cyanobenzyl, o-cyanobenzyl, 1-hydroxy-2-phenylisopropyl, and 1-chloro-2-phenylisopropyl. Of the above, preferred are benzyl, p-cyanobenzyl, m-cyanobenzyl, o-cyanobenzyl, 1-phenylethyl, 2-phenylethyl, 1-phenylisopropyl, and 2-phenylisopropyl. Additionally, the arylalkyl group may be optionally substituted.

Alkylsilyl—as used herein, contemplates a silyl group substituted with an alkyl group. Alkylsilyl groups may be those having 3 to 20 carbon atoms, preferably those having 3 to 10 carbon atoms. Examples of alkylsilyl groups include trimethylsilyl, triethylsilyl, methyldiethylsilyl, ethyldimethylsilyl, tripropylsilyl, tributylsilyl, triisopropylsilyl, methyldiisopropylsilyl, dimethylisopropylsilyl, tri-t-butylsilyl, triisobutylsilyl, dimethyl t-butylsilyl, and methyldi-t-butylsilyl. Additionally, the alkylsilyl group may be optionally substituted.

Arylsilyl—as used herein, contemplates a silyl group substituted with an aryl group. Arylsilyl groups may be those having 6 to 30 carbon atoms, preferably those having 8 to 20 carbon atoms. Examples of arylsilyl groups include triphenylsilyl, phenyldibiphenylylsilyl, diphenylbiphenylsilyl, phenyldiethylsilyl, diphenylethylsilyl, phenyldimethylsilyl, diphenylmethylsilyl, phenyldiisopropylsilyl, diphenylisopropylsilyl, diphenylbutylsilyl, diphenylisobutylsilyl, diphenyl t-butylsilyl. Additionally, the arylsilyl group may be optionally substituted.

Alkylgermanyl—as used herein contemplates germanyl substituted with an alkyl group. The alkylgermanyl may be those having 3 to 20 carbon atoms, preferably those having 3 to 10 carbon atoms. Examples of alkylgermanyl include trimethylgermanyl, triethylgermanyl, methyldiethylgermanyl, ethyldimethylgermanyl, tripropylgermanyl, tributylgermanyl, triisopropylgermanyl, methyldiisopropylgermanyl, dimethylisopropylgermanyl, tri-t-butylgermanyl, triisobutylgermanyl, dimethyl-t-butylgermanyl, and methyldi-t-butylgermanyl. Additionally, the alkylgermanyl may be optionally substituted.

Arylgermanyl—as used herein contemplates a germanyl substituted with at least one aryl group or heteroaryl group. Arylgermanyl may be those having 6 to 30 carbon atoms, preferably those having 8 to 20 carbon atoms. Examples of arylgermanyl include triphenylgermanyl, phenyldibiphenylylgermanyl, diphenylbiphenylgermanyl, phenyldiethylgermanyl, diphenylethylgermanyl, phenyldimethylgermanyl, diphenylmethylgermanyl, phenyldiisopropylgermanyl, diphenylisopropylgermanyl, diphenylbutylgermanyl, diphenylisobutylgermanyl, and diphenyl-t-butylgermanyl. Additionally, the arylgermanyl may be optionally substituted.

The term “aza” in azadibenzofuran, azadibenzothiophene, etc. means that one or more of C—H groups in the respective aromatic fragment are replaced by a nitrogen atom. For example, azatriphenylene encompasses dibenzo[f,h]quinoxaline, dibenzo[f,h]quinoline and other analogs with two or more nitrogens in the ring system. One of ordinary skill in the art can readily envision other nitrogen analogs of the aza-derivatives described above, and all such analogs are intended to be encompassed by the terms as set forth herein.

In the present disclosure, unless otherwise defined, when any term of the group consisting of substituted alkyl, substituted cycloalkyl, substituted heteroalkyl, substituted heterocyclic group, substituted arylalkyl, substituted alkoxy, substituted aryloxy, substituted alkenyl, substituted alkynyl, substituted aryl, substituted heteroaryl, substituted alkylsilyl, substituted arylsilyl, substituted alkylgermanyl, substituted arylgermanyl, substituted amino, substituted acyl, substituted carbonyl, a substituted carboxylic acid group, a substituted ester group, substituted sulfinyl, substituted sulfonyl, and substituted phosphino is used, it means that any group of alkyl, cycloalkyl, heteroalkyl, heterocyclic group, arylalkyl, alkoxy, aryloxy, alkenyl, alkynyl, aryl, heteroaryl, alkylsilyl, arylsilyl, amino, acyl, carbonyl, a carboxylic acid group, an ester group, sulfinyl, sulfonyl, and phosphino may be substituted with one or more moieties selected from the group consisting of deuterium, halogen, unsubstituted alkyl having 1 to 20 carbon atoms, unsubstituted cycloalkyl having 3 to 20 ring carbon atoms, unsubstituted heteroalkyl having 1 to 20 carbon atoms, an unsubstituted heterocyclic group having 3 to 20 ring atoms, unsubstituted arylalkyl having 7 to 30 carbon atoms, unsubstituted alkoxy having 1 to 20 carbon atoms, unsubstituted aryloxy having 6 to 30 carbon atoms, unsubstituted alkenyl having 2 to 20 carbon atoms, unsubstituted alkynyl having 2 to 20 carbon atoms, unsubstituted aryl having 6 to 30 carbon atoms, unsubstituted heteroaryl having 3 to 30 carbon atoms, unsubstituted alkylsilyl having 3 to 20 carbon atoms, unsubstituted arylsilyl having 6 to 20 carbon atoms, unsubstituted alkylgermanyl having 3 to 20 carbon atoms, unsubstituted arylgermanyl group having 6 to 20 carbon atoms, unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or an attached fragment are considered to be equivalent.

In the compounds mentioned in the present disclosure, hydrogen atoms may be partially or fully replaced by deuterium. Other atoms such as carbon and nitrogen can also be replaced by their other stable isotopes. The replacement by other stable isotopes in the compounds may be preferred due to its enhancements of device efficiency and stability.

In the compounds mentioned in the present disclosure, multiple substitutions refer to a range that includes a di-substitution, up to the maximum available substitution. When substitution in the compounds mentioned in the present disclosure represents multiple substitution (including di-, tri-, and tetra-substitutions, etc.), that means the substituent may exist at a plurality of available substitution positions on its linking structure, the substituents present at a plurality of available substitution positions may be the same structure or different structures.

In the compounds mentioned in the present disclosure, adjacent substituents in the compounds cannot be joined to form a ring unless otherwise explicitly defined, for example, adjacent substituents can be optionally joined to form a ring. In the compounds mentioned in the present disclosure, the expression that adjacent substituents can be optionally joined to form a ring includes a case where adjacent substituents may be joined to form a ring and a case where adjacent substituents are not joined to form a ring. When adjacent substituents can be optionally joined to form a ring, the ring formed may be monocyclic or polycyclic (including spirocyclic, endocyclic, fusedcyclic, and etc.), as well as alicyclic, heteroalicyclic, aromatic, or heteroaromatic. In such expression, adjacent substituents may refer to substituents bonded to the same atom, substituents bonded to carbon atoms which are directly bonded to each other, or substituents bonded to carbon atoms which are more distant from each other. Preferably, adjacent substituents refer to substituents bonded to the same carbon atom and substituents bonded to carbon atoms which are directly bonded to each other.

The expression that adjacent substituents can be optionally joined to form a ring is also intended to mean that two substituents bonded to the same carbon atom are joined to each other via a chemical bond to form a ring, which can be exemplified by the following formula:

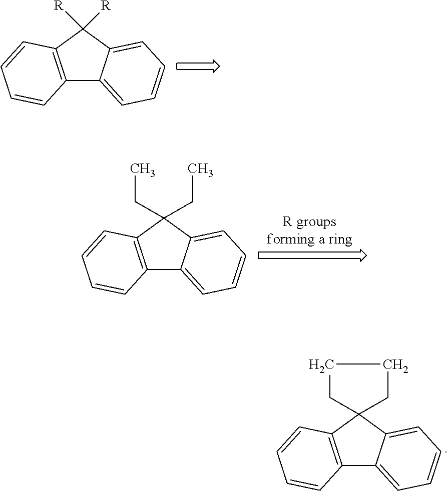

The expression that adjacent substituents can be optionally joined to form a ring is also intended to mean that two substituents bonded to carbon atoms which are directly bonded to each other are joined to each other via a chemical bond to form a ring, which can be exemplified by the following formula:

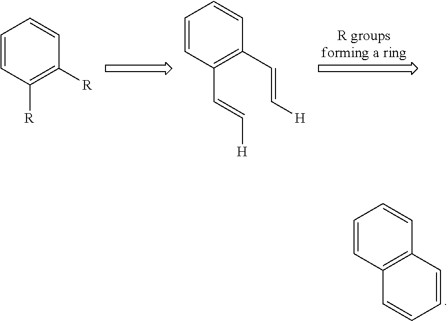

The expression that adjacent substituents can be optionally joined to form a ring is also intended to mean that two substituents bonded to a further distant carbon atom are joined to each other via a chemical bond to form a ring, which can be exemplified by the following formula:

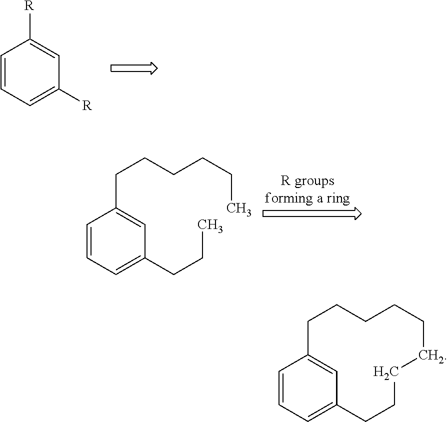

Furthermore, the expression that adjacent substituents can be optionally joined to form a ring is also intended to mean that, in the case where one of the two substituents bonded to carbon atoms which are directly bonded to each other represents hydrogen, the second substituent is bonded at a position at which the hydrogen atom is bonded, thereby forming a ring. This is exemplified by the following formula:

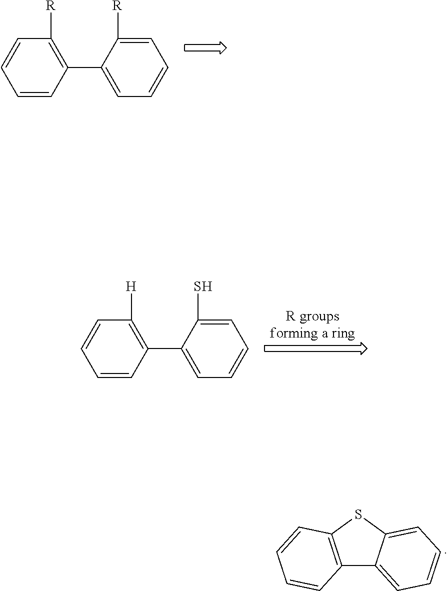

According to an embodiment of the present disclosure, disclosed is an organic electroluminescent device. The organic electroluminescent device comprises a cathode, an anode, and at least one organic layer disposed between the cathode and the anode, wherein the organic layer comprises a metal complex and a fluorescent material;
the metal complex comprises a metal M and a ligand Lₐ coordinated to the metal M, the metal M is selected from a metal with a relative atomic mass greater than 40, and the ligand Lₐ has a structure represented by Formula 1:

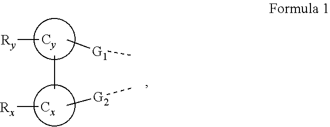

wherein
the ring C_{y} and the ring Cₓ are, at each occurrence identically or differently, selected from an aromatic ring having 6 to 30 ring atoms, a heteroaromatic ring having 5 to 30 ring atoms, or a combination thereof;
G₁ and G₂ are, at each occurrence identically or differently, selected from a single bond, O, S, or NR_{N};
Rₓ and R_{y} represent, at each occurrence identically or differently, mono-substitution, multiple substitutions, or non-substitution;
R_{N}, Rₓ, and R_{y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R_{N}, Rₓ, and R_{y} can be optionally joined to form a ring;
the fluorescent material has a structure represented by Formula 2:

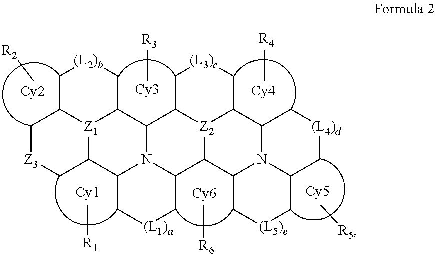

wherein
the ring Cy1, the ring Cy2, the ring Cy3, the ring Cy4, the ring Cy5, and the ring Cy6 are, at each occurrence identically or differently, selected from an unsaturated carbocyclic ring having 5 to 30 carbon atoms, an unsaturated heterocyclic ring having 3 to 30 carbon atoms, or a combination thereof;
Z₁ and Z₂ are, at each occurrence identically or differently, selected from B, N, P, P═O, P═S, As, As═O, or As═S;
Z₃ is, at each occurrence identically or differently, selected from O, S, Se, PR, POR, CRR, SiRR, GeRR, C═O, C═S, or C═CRR; when multiple R are present, the multiple R are identical or different;
L₁, L₂, L₃, L₄, and L₅ are, at each occurrence identically or differently, selected from a single bond, O, S, Se, BR′, NR′, PR′, P═OR′, P═SR′, AsR′, As═OR′, As═SR′, C═O, CR′R′, SiR′R′, or GeR′R′; when multiple R′ are present, the multiple R′ are identical or different;
a, b, c, d, and e are each independently selected from 0 or 1;
R₁, R₂, R₃, R₄, R₅, and R₆ represent, at each occurrence identically or differently, mono-substitution, multiple substitutions, or non-substitution;
R, R′, R₁, R₂, R₃, R₄, R₅, and R₆ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, —BR″R″, and combinations thereof;
R″ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents R, R′, R″, R₁, R₂, R₃, R₄, R₅, and R₆ can be optionally joined to form a ring.

Herein, the expression that “adjacent substituents R_{N}, Rₓ, and R_{y} can be optionally joined to form a ring” is intended to mean that any one or more of groups of adjacent substituents, such as two substituents Rₓ, two substituents R_{y}, substituents Rₓ and R_{y}, substituents Rₓ and R_{N}, and substituents R_{y} and R_{N}, can be joined to form a ring. Obviously, it is also possible that none of these groups of adjacent substituents are joined to form a ring.

Herein, the expression that “adjacent substituents R, R′, R″, R₁, R₂, R₃, R₄, R₅, and R₆ can be optionally joined to form a ring” is intended to mean that any one or more of groups of adjacent substituents, including, but not limited to, two substituents R, two substituents R′, two substituents R″, two substituents R₁, two substituents R₂, two substituents R₃, two substituents R₄, two substituents R₅, two substituents R₆, substituents R and R₁, substituents R and R₂, substituents R′ and R₁, substituents R′ and R₂, substituents R′ and R₃, substituents R′ and R₄, substituents R′ and R₅, substituents R′ and R₆, substituents R₁ and R₆, substituents R₆ and R₅, substituents R₄ and R₃, substituents R₂ and R₃, substituents R″ and R₁, substituents R″ and R₂, substituents R″ and R₃, substituents R″ and R₄, substituents R″ and R₅, substituents R″ and R₆, substituents R″ and R′, and substituents R″ and R, can be joined to form a ring. Obviously, it is also possible that none of these groups of adjacent substituents are joined to form a ring.

In this embodiment, the expression that “a, b, c, d, and e are each independently selected from 0 or 1” is intended to mean that Cy1 and Cy6, Cy2 and Cy3, Cy3 and Cy4, Cy4 and Cy5, and Cy5 and Cy6 corresponding to a, b, c, d, and e are joined or disjoined. For example, when a is 0, it means that L₁ is absent, and Cy1 and Cy6 are disjoined (that is, Cy1 is not joined to Cy6); and the same is true when one or more of a, b, c, d, and e are 0. More specifically, for example, Formula 2-1-2-1 described herein is the case where L₄ in Formula 2-1-2 is selected from a single bond (d=1).

Herein, a “carbocyclic ring” comprises a saturated carbocyclic ring and an unsaturated carbocyclic ring, the “unsaturated carbocyclic ring” comprises an aromatic unsaturated carbocyclic ring and a non-aromatic unsaturated carbocyclic ring, a “heterocyclic ring” comprises a saturated heterocyclic ring and an unsaturated heterocyclic ring, and the “unsaturated heterocyclic ring” comprises an aromatic unsaturated heterocyclic ring and a non-aromatic unsaturated heterocyclic ring.

In this embodiment, “R, R′, R₁, R₂, R₃, R₄, R₅, and R₆ are, at each occurrence identically or differently,” means that the listed substituents may be identical or different at each occurrence, where the listed substituents include substituents with different reference numerals, for example, R and R₁ may be identical or different at each occurrence; or the listed substituents include substituents with the same reference numerals, for example, when multiple R₁ are present, each R₁ may be identical or different. The same is true for the other listed substituents that are identical or different.

According to an embodiment of the present disclosure, the fluorescent material has a relative molecular weight of 450 to 1500.

According to an embodiment of the present disclosure, the fluorescent material has a relative molecular weight of 500 to 1300.

According to an embodiment of the present disclosure, the fluorescent material has a relative molecular weight of 800 to 1200.

According to an embodiment of the present disclosure, the fluorescent material has a relative molecular weight of 600 to 1000.

According to an embodiment of the present disclosure, the metal complex has a structure of Formula M(Lₐ)ₘ(L_{b})ₙ(L_{c})_{q}, the ligands Lₐ, L_{b}, and L_{c} are a first ligand, a second ligand, and a third ligand coordinated to the metal M, respectively, and the ligands Lₐ, L_{b}, and L_{c} can be optionally joined to form a multidentate ligand;
the metal M is selected from a metal with a relative atomic mass greater than 40;
m is selected from 1, 2, or 3, n is selected from 0, 1, or 2, q is selected from 0, 1, or 2, and m+n+q is equal to the oxidation state of the metal M; when m is greater than or equal to 2, multiple Lₐ are identical or different; when n is equal to 2, two L_{b} are identical or different; when q is equal to 2, two L are identical or different;
the ligand Lₐ has a structure represented by Formula 1-1:

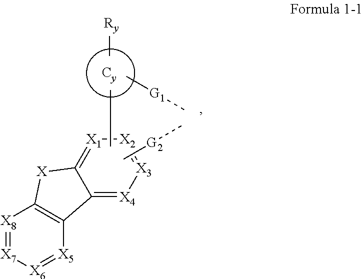

wherein
the ring C_{y} is, at each occurrence identically or differently, selected from a substituted or unsubstituted aromatic ring having 6 to 30 ring atoms, a substituted or unsubstituted heteroaromatic ring having 5 to 30 ring atoms, or a combination thereof;
G₁ and G₂ are, at each occurrence identically or differently, selected from a single bond, O, S, or NR_{N};
X is, at each occurrence identically or differently, selected from the group consisting of O, S, Se, NR′″, CR′″R′″, and SiR′″R′″; when two R′″ are present at the same time, the two R′″ are identical or different;
X₁ to X₄ are, at each occurrence identically or differently, selected from C, CRₓ, or N;
one of X₁ to X₄ is selected from C and joined to the ring C_{y}, and another of X₁ to X₄ is selected from C or N and joined to the metal via G₂;
X₅ to X₈ are, at each occurrence identically or differently, selected from CRₓ or N;
R_{y} represents, at each occurrence identically or differently, mono-substitution, multiple substitutions, or non-substitution;
R_{N}, Rₓ, R_{y}, and R′″ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R_{N}, Rₓ, R_{y}, and R′″ can be optionally joined to form a ring; and
L_{b} and L_{c} are, at each occurrence identically or differently, a monoanionic bidentate ligand.

In this embodiment, the expression that “adjacent substituents R_{N}, Rₓ, R_{y}, and R′″ can be optionally joined to form a ring” is intended to mean that any one or more of groups of adjacent substituents, such as two substituents R′″, two substituents Rₓ, two substituents R_{y}, substituents R_{N} and R_{y}, substituents R_{N} and Rₓ, substituents R_{y} and Rₓ, substituents R′″ and Rₓ, substituents R′″ and R_{y}, and substituents R′″ and R_{N}, can be joined to form a ring. Obviously, it is also possible that none of these groups of adjacent substituents are joined to form a ring.

According to an embodiment of the present disclosure, when X₁, X₂, X₃, or X₄ joined to G₂ is selected from N, G₂ is selected from a single bond, and X₁, X₂, X₃, or X₄ is joined to the metal via G₂ to form a metal-nitrogen bond; or when X₁, X₂, X₃, or X₄ joined to G₂ is selected from C, G₂ is selected from a single bond, O, S, or NR′, and X₁, X₂, X₃, or X₄ is joined to the metal M via G₂; and the ring C_{y} is joined to the metal M via G₁.

According to an embodiment of the present disclosure, preferably, G₁ and/or G₂ are each selected from a single bond.

According to an embodiment of the present disclosure, G₁ is a single bond, and the ring C_{y} is, at each occurrence identically or differently, selected from any structure in the group consisting of the following:

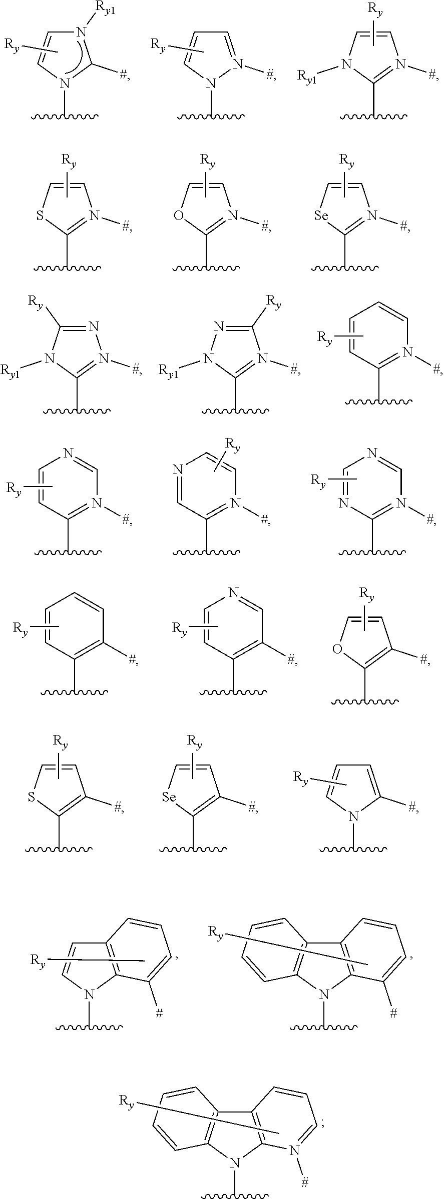

wherein
R_{y} represents, at each occurrence identically or differently, mono-substitution, multiple substitutions, or non-substitution;
R_{y} and R_{y1} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R_{y} and R_{y1} can be optionally joined to form a ring; and

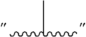

“#” represents a position where C_{y} is joined to the metal M, and
represents a position where C_{y} is joined to X₁, X₂, X₃, or X₄.

According to an embodiment of the present disclosure, the second ligand L_{b} and the third ligand L_{c} of the metal complex are, at each occurrence identically or differently, selected from a structure represented by any one of the group consisting of:

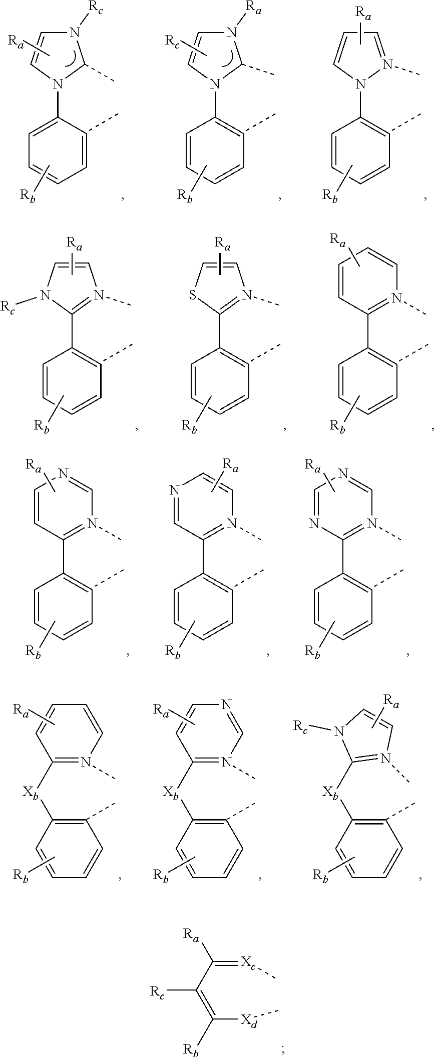

wherein
Rₐ and R_{b} represent, at each occurrence identically or differently, mono-substitution, multiple substitutions, or non-substitution;
X_{b} is, at each occurrence identically or differently, selected from the group consisting of: O, S, Se, NR_{N1}, and CR_{C1}R_{C2};
X_{c} and X_{d} are, at each occurrence identically or differently, selected from the group consisting of: O, S, Se, and NR_{N2};
Rₐ, R_{b}, R_{c}, R_{N1}, R_{N2}, R_{C1}, and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents Rₐ, R_{b}, R_{c}, R_{N1}, R_{N2}, R_{C1}, and R_{C2} can be optionally joined to form a ring.

Herein, the expression that “adjacent substituents Rₐ, R_{b}, R_{c}, R_{N1}, R_{N2}, R_{C1}, and R_{C2} can be optionally joined to form a ring” is intended to mean that any one or more of groups of adjacent substituents, such as two substituents Rₐ, two substituents R_{b}, two substituents R_{c}, substituents Rₐ and R_{b}, substituents Rₐ and R_{c}, substituents R_{b} and R_{c}, substituents Rₐ and R_{N1}, substituents R_{b} and R_{N1}, substituents Rₐ and R_{C1}, substituents Rₐ and R_{C2}, substituents R_{b} and R_{C1}, substituents R_{b} and R_{C2}, substituents Rₐ and R_{N2}, substituents R_{b} and R_{N2}, and substituents R_{C1} and R_{C2}, may be joined to form a ring. For example, adjacent substituents Rₐ and R_{b} in

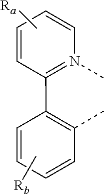

can be optionally joined to form a ring, which can form one or more of the following structures including, but not limited to,

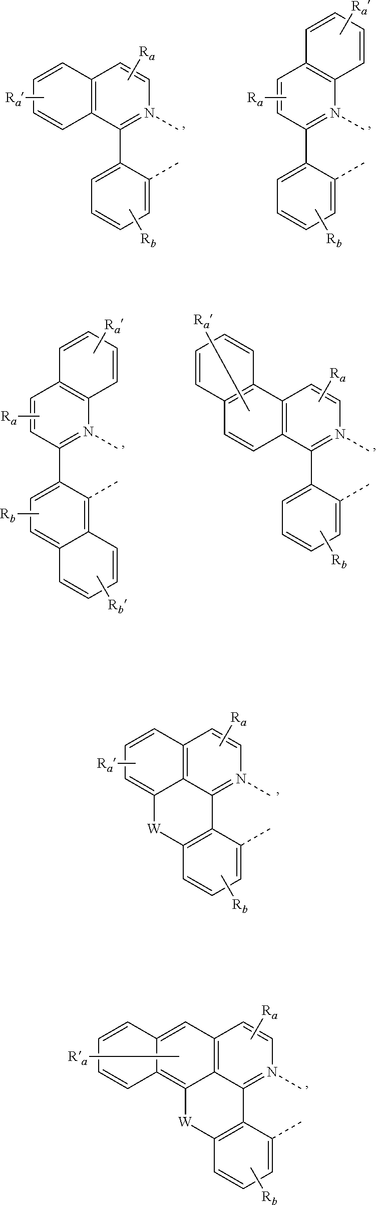

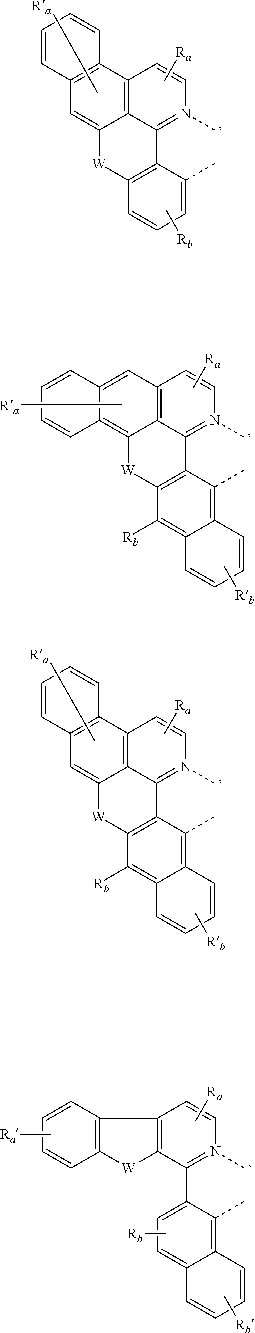

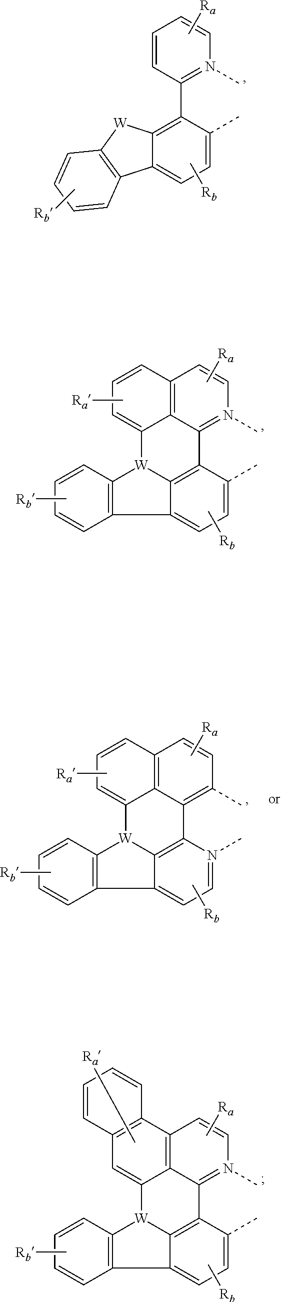

wherein W is selected from O, S, Se, NR_{w}, or CR_{w}R_{w}, and R_{w}, Rₐ′, and R_{b}′ are defined the same as Rₐ. Obviously, it is also possible that none of these substituents are joined to form a ring.

According to an embodiment of the present disclosure, the metal M is selected from the group consisting of Cu, Ag, Au, Ru, Rh, Pd, Os, Ir, and Pt.

According to an embodiment of the present disclosure, the metal M is selected from Pt or Ir.

According to an embodiment of the present disclosure, the metal complex has a structure of Formula Ir(Lₐ)ₘ(L_{b})₃₋ₘ and has a structure represented by Formula 1-1-1 or Formula

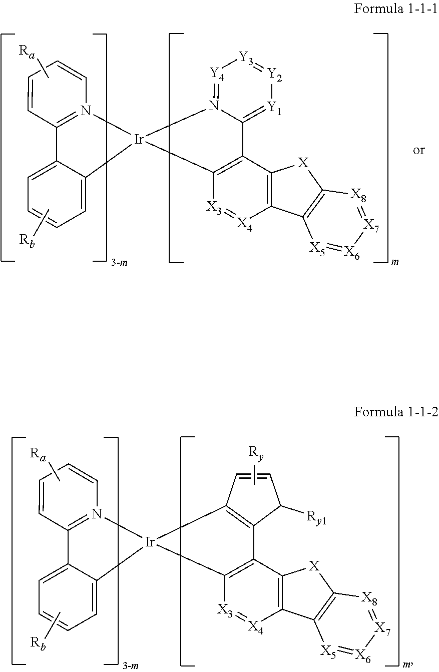

wherein
m is selected from 1 or 2; when m is selected from 1, two L_{b} are identical or different; when m is selected from 2, two Lₐ are identical or different;
X is selected from the group consisting of O, S, Se, NR′″, CR′″R′″, and SiR′″R′″; when two R′″ are present at the same time, the two R′″ are identical or different;
X₃ to X₈ are, at each occurrence identically or differently, selected from CRₓ or N;
in Formula 1-1-1, Y₁ to Y₄ are, at each occurrence identically or differently, selected from CR_{y} or N;
in Formula 1-1-2, R_{y} represents, at each occurrence identically or differently, mono-substitution, multiple substitutions, or non-substitution;
Rₐ and R_{b} represent, at each occurrence identically or differently, mono-substitution, multiple substitutions, or non-substitution;
R′″, Rₓ, R_{y}, R_{y1}, Rₐ, and R_{b} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents R″, Rₓ, R_{y}, R_{y1}, Rₐ, and R_{b} can be optionally joined to form a ring.

According to an embodiment of the present disclosure, the metal complex has a structure of Formula Ir(Lₐ)ₘ(L_{b})₃₋ₘ and has a structure represented by Formula 1-1-3:

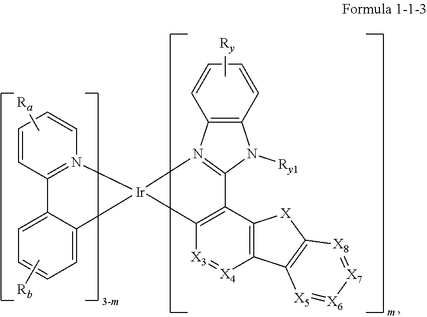

wherein
m is selected from 1 or 2; when m is selected from 1, two L_{b} are identical or different;
when m is selected from 2, two Lₐ are identical or different;
X is selected from the group consisting of O, S, Se, NR′″, CR′″R′″, and SiR′″R′″; when two R′″ are present at the same time, the two R′″ are identical or different;
X₃ to X₈ are, at each occurrence identically or differently, selected from CRₓ or N;
R_{y}, Rₐ, and R_{b} represent, at each occurrence identically or differently, mono-substitution, multiple substitutions, or non-substitution;
R′″, Rₓ, R_{y}, R_{y1}, Rₐ, and R_{b} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents R′″, Rₓ, R_{y}, R_{y1}, Rₐ, and R_{b} can be optionally joined to form a ring.

Herein, the expression that “adjacent substituents R′″, Rₓ, R_{y}, R_{y1}, Rₐ, and R_{b} can be optionally joined to form a ring” is intended to mean that any one or more of groups of adjacent substituents, such as two substituents R′″, two substituents Rₓ, two substituents R_{y}, substituents R_{y} and Rₓ, substituents R_{y} and R_{y1}, substituents R′″ and Rₓ, substituents R′″ and R_{y}, substituents R′″ and R_{y1}, two substituents Rₐ, two substituents R_{b}, and substituents Rₐ and R_{b}, can be joined to form a ring. Obviously, it is also possible that none of these groups of adjacent substituents are joined to form a ring.

According to an embodiment of the present disclosure, the metal complex has a general formula of Ir(Lₐ)ₘ(L_{b})₃₋ₘ and has a structure represented by Formula 1-1-4:

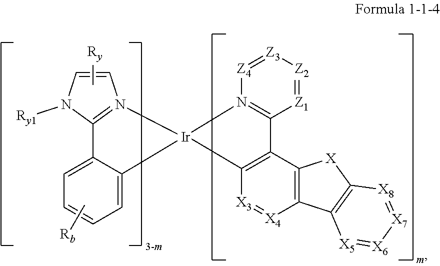

wherein
m is selected from 1 or 2; when m is selected from 1, two L_{b} are the same or different;
when m is selected from 2, two Lₐ are the same or different;
Rₐ and R_{b} represent, at each occurrence identically or differently, mono-substitution, multiple substitutions, or non-substitution;
X is selected from the group consisting of O, S, Se, NR′″, CR′″R′″, and SiR′″R′″; when two R′″ are present at the same time, the two R′″ are identical or different;
X₃ to X₈ are, at each occurrence identically or differently, selected from CRₓ or N;
Y₁ to Y₄ are, at each occurrence identically or differently, selected from CR_{y} or N;
R′″, Rₓ, R_{y}, Rₐ, R_{b}, and R_{c} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents Rₐ and R_{c} can be optionally joined to form a ring; and
adjacent substituents R′″, Rₓ, R_{y}, and R_{b} can be optionally joined to form a ring.

Herein, the expression that “adjacent substituents Rₐ and R_{c} can be optionally joined to form a ring” is intended to mean that any one or more of groups of adjacent substituents, such as two substituents Rₐ, two substituents R_{c}, and substituents Rₐ and R_{c}, may be joined to form a ring. Obviously, it is also possible that none of these substituents are joined to form a ring.

Herein, the expression that “adjacent substituents R′″, Rₓ, R_{y}, and R_{b} can be optionally joined to form a ring” is intended to mean that any one or more of groups of adjacent substituents, such as two substituents R′″, two substituents Rₓ, two substituents R_{y}, substituents Rₓ and R′″, substituents Rₓ and R_{y}, substituents R_{y} and R′″, and two substituents R_{b}, may be joined to form a ring. Obviously, it is also possible that none of these substituents are joined to form a ring.

According to an embodiment of the present disclosure, X is selected from O, S, Se, or CR′″R″.

According to an embodiment of the present disclosure, X is selected from O or S.

According to an embodiment of the present disclosure, X is selected from O.

According to an embodiment of the present disclosure, Rₐ and R_{b} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, cyano, hydroxyl, sulfanyl, and combinations thereof.

According to an embodiment of the present disclosure, at least one Rₐ and/or at least one R_{b} are, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, cyano, hydroxyl, sulfanyl, and combinations thereof.

According to an embodiment of the present disclosure, X₃ to X₈ are, at each occurrence identically or differently, selected from CRₓ.

According to an embodiment of the present disclosure, Y₁ to Y₄ are, at each occurrence identically or differently, selected from CR_{y}.

According to an embodiment of the present disclosure, Rₓ and R_{y} are, at each occurrence identically or differently, selected from the group consisting of: hydrogen, deuterium, halogen, cyano, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, and combinations thereof.

According to an embodiment of the present disclosure, Rₓ and R_{y} are, at each occurrence identically or differently, selected from the group consisting of: hydrogen, deuterium, halogen, cyano, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted amino having 0 to 20 carbon atoms, and combinations thereof.

According to an embodiment of the present disclosure, at least one of X₃ to X₈ is selected from CRₓ, and the Rₓ is selected from cyano or fluorine.

According to an embodiment of the present disclosure, at least two of X₃ to X₈ are selected from CRₓ, one of the Rₓ is selected from cyano or fluorine, and at least another one of the Rₓ is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

According to an embodiment of the present disclosure, at least three of X₃ to X₈ are selected from CRₓ, one of the Rₓ is selected from cyano or fluorine, and at least another two of the Rₓ are, at each occurrence identically or differently, selected from the group consisting of: deuterium, fluorine, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and combinations thereof.

According to an embodiment of the present disclosure, at least three of X₃ to X₈ are selected from CRₓ, one of the Rₓ is selected from cyano or fluorine, one of the Rₓ is selected from substituted or unsubstituted alkyl having 1 to 12 carbon atoms, substituted or unsubstituted cycloalkyl having 3 to 10 ring carbon atoms, or a combination thereof, and another one of the Rₓ is selected from substituted or unsubstituted aryl having 6 to 15 carbon atoms, substituted or unsubstituted heteroaryl having 3 to 15 carbon atoms, or a combination thereof.

According to an embodiment of the present disclosure, X₅ to X₈ are selected from CRₓ, and at least one of the Rₓ is cyano or fluorine.

According to an embodiment of the present disclosure, X₇ is CRₓ, and the Rₓ is cyano or fluorine; or X₈ is CRₓ, and the Rₓ is cyano.

According to an embodiment of the present disclosure, X₃ is selected from CRₓ, and the Rₓ is selected from substituted or unsubstituted alkyl having 1 to 12 carbon atoms, substituted or unsubstituted cycloalkyl having 3 to 10 ring carbon atoms, or a combination thereof; X₇ is selected from CRₓ, and the Rₓ is selected from cyano or fluorine; and X₈ is selected from CRₓ, and the Rₓ is selected from substituted or unsubstituted aryl having 6 to 15 carbon atoms, substituted or unsubstituted heteroaryl having 3 to 15 carbon atoms, or a combination thereof.

According to an embodiment of the present disclosure, in Formula 1-1-1, Y₁ to Y₄ are, at each occurrence identically or differently, selected from CR_{y}, and the R_{y} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, cyano, isocyano, hydroxyl, sulfanyl, and combinations thereof.

According to an embodiment of the present disclosure, in Formula 1-1-1, at least one of Y₁ to Y₄ is selected from CR_{y}, and the R_{y} is, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted aryl having 6 to 30 carbon atoms, substituted or unsubstituted heteroaryl having 3 to 30 carbon atoms, cyano, isocyano, and combinations thereof.

According to an embodiment of the present disclosure, in Formula 1-1-1, at least one of Y₂ and/or Y₃ is selected from CR_{y}, and the R_{y} is, at each occurrence identically or differently, selected from the group consisting of: deuterium, fluorine, substituted or unsubstituted alkyl having 1 to 12 carbon atoms, substituted or unsubstituted cycloalkyl having 3 to 12 ring carbon atoms, substituted or unsubstituted aryl having 6 to 20 carbon atoms, substituted or unsubstituted heteroaryl having 3 to 20 carbon atoms, cyano, and combinations thereof.

According to an embodiment of the present disclosure, in Formula 1-1-2, R_{y} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, cyano, isocyano, hydroxyl, sulfanyl, and combinations thereof.

According to an embodiment of the present disclosure, R_{c} and R_{y1} are, at each occurrence identically or differently, selected from the group consisting of: substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, and combinations thereof.

According to an embodiment of the present disclosure, R_{c} and R_{y1} are, at each occurrence identically or differently, selected from the group consisting of: substituted or unsubstituted arylalkyl having 7 to 30 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, and combinations thereof.

According to an embodiment of the present disclosure, R_{c} and R_{y1} are, at each occurrence identically or differently, selected from substituted or unsubstituted aryl having 6 to 30 carbon atoms.

According to an embodiment of the present disclosure, in Formula 1-1-2, adjacent R_{y} are joined to form a substituted or unsubstituted carbocyclic ring or heterocyclic ring.

According to an embodiment of the present disclosure, in Formula 1-1-2, adjacent R_{y} are joined to form a substituted or unsubstituted aromatic ring or heteroaromatic ring.

According to an embodiment of the present disclosure, in Formula 1-1-2, adjacent R_{y} are joined to form a substituted or unsubstituted benzene ring.

According to an embodiment of the present disclosure, in Formula 1-1-4, adjacent Rₐ are joined to form a substituted or unsubstituted carbocyclic ring or heterocyclic ring.

According to an embodiment of the present disclosure, in Formula 1-1-4, adjacent Rₐ are joined to form a substituted or unsubstituted aromatic ring or heteroaromatic ring.

According to an embodiment of the present disclosure, in Formula 1-1-4, adjacent Rₐ are joined to form a substituted or unsubstituted benzene ring.

According to an embodiment of the present disclosure, Lₐ is, at each occurrence identically or differently, selected from the group consisting of La-1-k1, La-2-1 to La-2-63, and La-3-k3, k1 is selected from an integer from 1 to 300, and k3 is selected from an integer from 1 to 282; wherein for specific structures of La-1-k1, La-2-1 to La-2-63, and La-3-k3, refer to claim 9.

According to an embodiment of the present disclosure, L_{b} is, at each occurrence identically or differently, selected from any one of the group consisting of L_{b1} to L_{b169}, wherein for specific structures of L_{b1} to L_{b169}, refer to claim 10.

According to an embodiment of the present disclosure, L_{c} is, at each occurrence identically or differently, selected from any one of the group consisting of L_{c1} to L_{c50}, wherein for specific structures of L_{c1} to L_{c50}, refer to claim 11.

According to an embodiment of the present disclosure, the metal complex is selected from the group consisting of GD1 to GD785, wherein for specific structures of GD1 to GD785, refer to claim 12.

According to an embodiment of the present disclosure, the ring Cy1, the ring Cy2, the ring Cy3, the ring Cy4, the ring Cy5, and the ring Cy6 are, at each occurrence identically or differently, selected from a five-membered unsaturated carbocyclic ring, an aromatic ring having 6 to 30 carbon atoms, or a heteroaromatic ring having 3 to 30 carbon atoms.

According to an embodiment of the present disclosure, the ring Cy1, the ring Cy2, the ring Cy3, the ring Cy4, the ring Cy5, and the ring Cy6 are, at each occurrence identically or differently, selected from a five-membered unsaturated carbocyclic ring, an aromatic ring having 6 to 18 carbon atoms, or a heteroaromatic ring having 3 to 18 carbon atoms.

According to an embodiment of the present disclosure, the ring Cy1, the ring Cy2, the ring Cy3, the ring Cy4, the ring Cy5, and the ring Cy6 are, at each occurrence identically or differently, selected from a pyrrole ring, a furan ring, a thiophene ring, an imidazole ring, a pyrazole ring, a thiazole ring, an oxazole ring, a benzene ring, a pyridine ring, a pyrazine ring, a pyridazine ring, a pyrimidine ring, a triazine ring, a benzimidazole ring, a benzofuran ring, a benzothiophene ring, a benzothiazole ring, a benzoxazole ring, a dibenzofuran ring, a dibenzothiophene ring, a carbazole ring, a pyridoindole ring, a naphthalene ring, a phenanthrene ring, an anthracene ring, an indene ring, a fluorene ring, an indole ring, a benzosilole ring, a dibenzosilole ring, a dibenzoselenophene ring, or a combination thereof.

According to an embodiment of the present disclosure, the ring Cy1, the ring Cy2, the ring Cy3, the ring Cy4, the ring Cy5, and the ring Cy6 are, at each occurrence identically or differently, selected from a benzene ring.

According to an embodiment of the present disclosure, the fluorescent material has a structure represented by Formula 2-1:

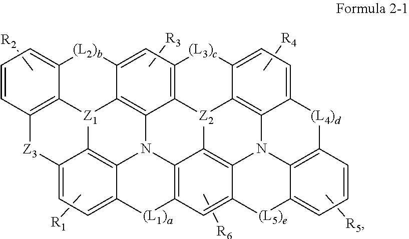

wherein
Z₁ and Z₂ are, at each occurrence identically or differently, selected from B, N, P, P═O, P═S, As, As═O, or As═S;
Z₃ is, at each occurrence identically or differently, selected from O, S, Se, PR, P═OR, CRR, SiRR, GeRR, C═O, C═S, or C═CRR; when multiple R are present, the multiple R are identical or different;
L₁, L₂, L₃, L₄, and L₅ are, at each occurrence identically or differently, selected from a single bond, O, S, Se, BR′, NR′, PR′, P═OR′, P═SR′, AsR′, As═OR′, As═SR′, C═O, CR′R′, SiR′R′, or GeR′R′; when multiple R′ are present, the multiple R′ are identical or different;
a, b, c, d, and e are each independently selected from 0 or 1;
R₁, R₂, R₃, R₄, R₅, and R₆ represent, at each occurrence identically or differently, mono-substitution, multiple substitutions, or non-substitution;
R₁, R₂, R₃, R₄, R₅, R₆, R, and R′ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, —BR″R″, and combinations thereof;
R″ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents R₁, R₂, R₃, R₄, R₅, R₆, R, R′, and R″ can be optionally joined to form a ring.

According to an embodiment of the present disclosure, L₁, L₂, L₃, L₄, and L₅ are, at each occurrence identically or differently, selected from a single bond, O, S, Se, BR′, NR′, P═OR′, C═O, CR′R′, or SiR′R′; and the R′ is, at each occurrence identically or differently, selected from the group consisting of: substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted aryl having 6 to 30 carbon atoms, substituted or unsubstituted heteroaryl having 3 to 30 carbon atoms, and combinations thereof.

According to an embodiment of the present disclosure, L₁, L₂, L₃, L₄, and L₅ are, at each occurrence identically or differently, selected from a single bond, O, S, NR′, or CR′R′; and the R′ is, at each occurrence identically or differently, selected from the group consisting of: substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and combinations thereof.

According to an embodiment of the present disclosure, L₁, L₂, L₃, L₄, and L₅ are, at each occurrence identically or differently, selected from a single bond.

According to an embodiment of the present disclosure, a+b+c+d+e is greater than or equal to 1.

According to an embodiment of the present disclosure, a+b+c+d+e=0, 1, or 2.

According to an embodiment of the present disclosure, a+d+e=1 or 2.

According to an embodiment of the present disclosure, d+e=1 or 2.

According to an embodiment of the present disclosure, a, b, c, and e are all 0, and d=1.

According to an embodiment of the present disclosure, a, b, c, and e are all 0, d=1, and L₄ is selected from a single bond.

According to an embodiment of the present disclosure, the fluorescent material has a structure represented by any one of Formula 2-1-1 to Formula 2-1-11:

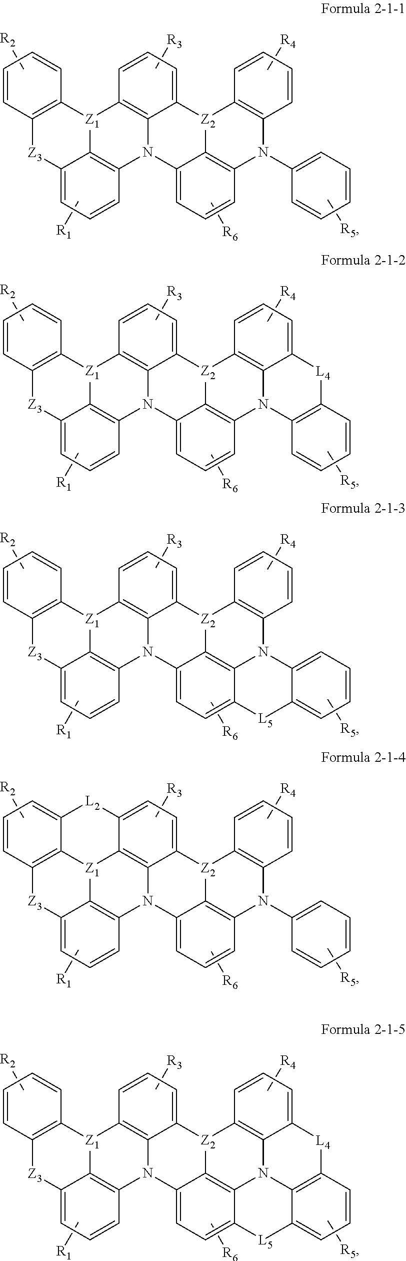

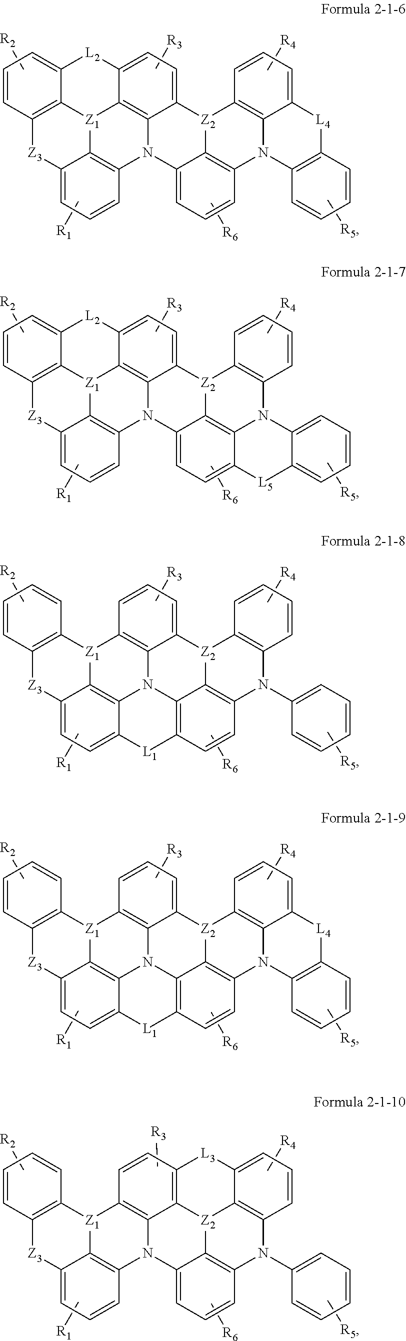

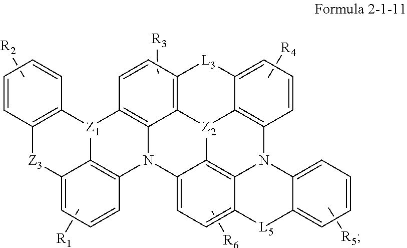

wherein
Z₁ and Z₂ are, at each occurrence identically or differently, selected from B, N, P, P═O, P═S, As, As═O, or As═S;
Z₃ is, at each occurrence identically or differently, selected from O, S, Se, PR, POR, CRR, SiRR, GeRR, C═O, C═S, or C═CRR; when multiple R are present, the multiple R are identical or different;
L₁, L₂, L₃, L₄, and L₅ are, at each occurrence identically or differently, selected from a single bond, O, S, Se, BR′, NR′, PR′, P═OR′, P═SR′, AsR′, As═OR′, As═SR′, C═O, CR′R′, SiR′R′, or GeR′R′; when multiple R′ are present, the multiple R′ are identical or different;
R₁, R₂, R₃, R₄, R₅, and R₆ represent, at each occurrence identically or differently, mono-substitution, multiple substitutions, or non-substitution;
R₁, R₂, R₃, R₄, R₅, R₆, R, and R′ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, —BR″R″, and combinations thereof;
R″ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents R₁, R₂, R₃, R₄, R₅, R₆, R, R′, and R″ can be optionally joined to form a ring.

According to an embodiment of the present disclosure, Z₁ and Z₂ are, at each occurrence identically or differently, selected from B, P, P═O, or P═S.

According to an embodiment of the present disclosure, Z₁ and Z₂ are, at each occurrence identically or differently, selected from B or P═O.

According to an embodiment of the present disclosure, at least one of Z₁ or Z₂ is selected from B.

According to an embodiment of the present disclosure, Z₁ and Z₂ are, at each occurrence, selected from B.

According to an embodiment of the present disclosure, Z₃ is, at each occurrence identically or differently, selected from O, S, Se, PR, P═OR, SiRR, C═O, or CRR; when multiple R are present, the multiple R are identical or different; R is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and combinations thereof, and adjacent substituents R can be optionally joined to form a ring.

According to an embodiment of the present disclosure, Z₃ is, at each occurrence identically or differently, selected from O, Se, SiRR, C═O, or CRR; R is, at each occurrence identically or differently, selected from the group consisting of: substituted or unsubstituted alkyl having 1 to 10 carbon atoms, substituted or unsubstituted cycloalkyl having 3 to 10 ring carbon atoms, substituted or unsubstituted aryl having 6 to 14 carbon atoms, substituted or unsubstituted heteroaryl having 3 to 14 carbon atoms, and combinations thereof; and adjacent substituents R can be optionally joined to form a ring.

According to an embodiment of the present disclosure, Z₃ is, at each occurrence identically or differently, selected from O, S, Se, or C═O.

According to an embodiment of the present disclosure, R₁, R₂, R₃, R₄, R₅, and R₆ are, at each occurrence identically or differently, selected from the group consisting of: hydrogen, deuterium, fluorine, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted alkylgermanyl having 3 to 20 carbon atoms, substituted or unsubstituted amino having 0 to 20 carbon atoms, cyano, isocyano, hydroxyl, sulfanyl, and combinations thereof; and adjacent substituents R₁, R₂, R₃, R₄, R₅, and R₆ can be optionally joined to form a ring.

According to an embodiment of the present disclosure, R₁, R₂, R₃, R₄, R₅, and R₆ are, at each occurrence identically or differently, selected from the group consisting of: hydrogen, deuterium, fluorine, substituted or unsubstituted alkyl having 1 to 20 carbon atoms, substituted or unsubstituted cycloalkyl having 3 to 20 ring carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted amino having 0 to 20 carbon atoms, cyano, hydroxyl, sulfanyl, and combinations thereof; and adjacent substituents R₁, R₂, R₃, R₄, R₅, and R₆ can be optionally joined to form a ring.

According to an embodiment of the present disclosure, at least one (for example, one, two, three, or four) of R₁, R₂, R₃, R₄, R₅, or R₆ is selected from the group consisting of: deuterium, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted amino having 0 to 20 carbon atoms, and combinations thereof.

According to an embodiment of the present disclosure, at least one R₁, at least one R₂, at least one R₃, at least one R₄, at least one R₅, and at least one R₆ are each selected from the group consisting of: deuterium, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted amino having 0 to 20 carbon atoms, hydroxyl, sulfanyl, and combinations thereof.

According to an embodiment of the present disclosure, at least one R₁, at least one R₂, at least one R₃, at least one R₄, at least one R₅, and at least one R₆ are, at each occurrence identically or differently, selected from the group consisting of: deuterium, substituted or unsubstituted alkyl having 1 to 10 carbon atoms, substituted or unsubstituted cycloalkyl having 3 to 10 ring carbon atoms, substituted or unsubstituted alkenyl having 2 to 20 carbon atoms, substituted or unsubstituted aryl having 6 to 14 carbon atoms, substituted or unsubstituted heteroaryl having 3 to 14 carbon atoms, hydroxyl, sulfanyl, and combinations thereof; and adjacent substituents R₁, R₂, R₃, R₄, R₅, and R₆ can be optionally joined to form a ring.

According to an embodiment of the present disclosure, the fluorescent material is selected from a structure represented by Formula 2-1-2.

According to an embodiment of the present disclosure, the fluorescent material has a structure represented by Formula 2-1-2-1:

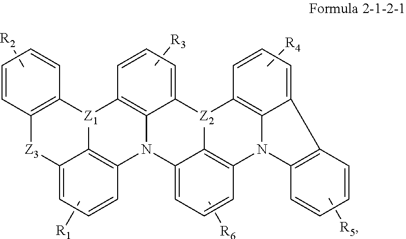

wherein
Z₁ and Z₂ are, at each occurrence identically or differently, selected from B, N, P, P═O, P═S, As, As═O, or As═S;
Z₃ is, at each occurrence identically or differently, selected from O, S, Se, PR, P═OR, CRR, SiRR, GeRR, C═O, C═S, or C═CRR; when multiple R are present, the multiple R are identical or different;
R₁, R₂, R₃, R₄, R₅, and R₆ represent, at each occurrence identically or differently, mono-substitution, multiple substitutions, or non-substitution;
R₁, R₂, R₃, R₄, R₅, R₆, and R are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, —BR″R″, and combinations thereof;
R″ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents R₁, R₂, R₃, R₄, R₅, R₆, R, and R″ can be optionally joined to form a ring.

According to an embodiment of the present disclosure, the fluorescent material comprises at least one deuterium.

According to an embodiment of the present disclosure, at least one of R₁, R₂, R₃, R₄, R₅, or R₆ is selected from deuterium or any one of the following groups each substituted with one or more deuteriums: substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted aryl having 6 to 30 carbon atoms, substituted or unsubstituted heteroaryl having 3 to 30 carbon atoms, or a combination thereof.

According to an embodiment of the present disclosure, at least one R₁ and/or at least one R₂ and/or at least one R₃ and/or at least one R₄ and/or at least one R₅ and/or at least one R₆ are, at each occurrence identically or differently, selected from the group consisting of: deuterium or any one of the following groups each substituted with one or more deuteriums: substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, or a combination thereof.

According to an embodiment of the present disclosure, at least one R₅ is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted aryl having 6 to 30 carbon atoms, substituted or unsubstituted heteroaryl having 3 to 30 carbon atoms, and combinations thereof.

According to an embodiment of the present disclosure, the fluorescent material is selected from the group consisting of Compound 3-1-k2, Compound 3-2-k2, Compound 3-3-k2, Compound 3-4-k2, Compound 3-5-k2, Compound 3-6-k2, Compound 3-7-k2, Compound 3-8-k2, Compound 3-9-k2, Compound 3-10-k2, Compound 3-11-k2, Compound 3-12-k2, Compound 3-13-k2, Compound 3-14-k2, and Compound 4-1-k4, k2 is selected from an integer from 1 to 330, and k4 is selected from an integer from 1 to 129; wherein for specific structures of Compound 3-1-k2, Compound 3-2-k2, Compound 3-3-k2, Compound 3-4-k2, Compound 3-5-k2, Compound 3-6-k2, Compound 3-7-k2, Compound 3-8-k2, Compound 3-9-k2, Compound 3-10-k2, Compound 3-11-k2, Compound 3-12-k2, Compound 3-13-k2, Compound 3-14-k2, and Compound 4-1-k4, refer to claim 20.

According to an embodiment of the present disclosure, hydrogens in Compound 3-1-k2, Compound 3-2-k2, Compound 3-3-k2, Compound 3-4-k2, Compound 3-5-k2, Compound 3-6-k2, Compound 3-7-k2, Compound 3-8-k2, Compound 3-9-k2, Compound 3-10-k2, Compound 3-11-k2, Compound 3-12-k2, Compound 3-13-k2, Compound 3-14-k2, and Compound 4-1-k4 (where k2 is selected from an integer from 1 to 330, and k4 is selected from an integer from 1 to 129) can be partially or fully substituted with deuterium.

According to an embodiment of the present disclosure, the fluorescent material is selected from the group consisting of Compound 3-1-k2, Compound 3-2-k2, Compound 3-3-k2, Compound 3-4-k2, Compound 3-5-k2, Compound 3-6-k2, Compound 3-7-k2, Compound 3-8-k2, Compound 3-9-k2, Compound 3-10-k2, Compound 3-11-k2, Compound 3-12-k2, Compound 3-13-k2, Compound 3-14-k2, Compound 4-1-k4, and Compound 5-1-k5, k2 is selected from an integer from 1 to 330, k4 is selected from an integer from 1 to 129, and k5 is selected from an integer from 1 to 400; wherein for specific structures of Compound 3-1-k2, Compound 3-2-k2, Compound 3-3-k2, Compound 3-4-k2, Compound 3-5-k2, Compound 3-6-k2, Compound 3-7-k2, Compound 3-8-k2, Compound 3-9-k2, Compound 3-10-k2, Compound 3-11-k2, Compound 3-12-k2, Compound 3-13-k2, Compound 3-14-k2, Compound 4-1-k4, and Compound 5-1-k5, refer to claim 20.

According to an embodiment of the present disclosure, hydrogens in Compound 3-1-k2, Compound 3-2-k2, Compound 3-3-k2, Compound 3-4-k2, Compound 3-5-k2, Compound 3-6-k2, Compound 3-7-k2, Compound 3-8-k2, Compound 3-9-k2, Compound 3-10-k2, Compound 3-11-k2, Compound 3-12-k2, Compound 3-13-k2, Compound 3-14-k2, Compound 4-1-k4, and Compound 5-1-k5 (wherein k2 is selected from an integer from 1 to 330, k4 is selected from an integer from 1 to 129, and k5 is selected from an integer from 1 to 400) can be partially or fully substituted with deuterium.

According to an embodiment of the present disclosure, the fluorescent material is a delayed fluorescent material.

According to an embodiment of the present disclosure, the organic layer is an emissive layer, the metal complex is a phosphorescent sensitizer, and the fluorescent material is a thermally activated delayed fluorescent (TADF) material.

According to an embodiment of the present disclosure, a maximum emission wavelength in a photoluminescence spectrum of the metal complex is λₘₐₓ₁, and 500 nm≤λₘₐₓ₁≤600 nm.

According to an embodiment of the present disclosure, the maximum emission wavelength in the photoluminescence spectrum of the metal complex is λₘₐₓ₁, and 505 nm≤λₘₐₓ₁≤560 nm.

According to an embodiment of the present disclosure, the maximum emission wavelength in the photoluminescence spectrum of the metal complex is λₘₐₓ₁, and 510 nm≤λₘₐₓ₁≤550 nm.

According to an embodiment of the present disclosure, a maximum emission wavelength in a photoluminescence spectrum of the fluorescent material is λₘₐₓ₂, and 500 nm≤λₘₐₓ₂≤600 nm.

According to an embodiment of the present disclosure, the maximum emission wavelength in the photoluminescence spectrum of the fluorescent material is λₘₐₓ₂, and 510 nm≤λₘₐₓ₂≤580 nm.

According to an embodiment of the present disclosure, the maximum emission wavelength in the photoluminescence spectrum of the fluorescent material is λₘₐₓ₂, and 510 nm≤λₘₐₓ₂≤560 nm.

According to an embodiment of the present disclosure, the maximum emission wavelength in the photoluminescence spectrum of the fluorescent material is λₘₐₓ₂, and 530 nm≤λₘₐₓ₂≤540 nm.

According to an embodiment of the present disclosure, the maximum emission wavelength in the photoluminescence spectrum of the metal complex is λₘₐₓ₁, and the maximum emission wavelength in the photoluminescence spectrum of the fluorescent material is λₘₐₓ₂, wherein λₘₐₓ₁≤λₘₐₓ₂, or 0<λₘₐₓ₁−λₘₐₓ₂≤30 nm.

According to an embodiment of the present disclosure, 0<λₘₐₓ₂−λₘₐₓ₁≤40 nm, or 0<λₘₐₓ₁−λₘₐₓ₂≤20 nm.

According to an embodiment of the present disclosure, 10 nm≤λₘₐₓ₂−λₘₐₓ₁≤30 nm, or 0<λₘₐₓ₁−λₘₐₓ₂≤10 nm.

According to an embodiment of the present disclosure, the organic electroluminescent device emits green light or yellow light.

According to an embodiment of the present disclosure, a maximum emission wavelength in an electroluminescence spectrum of the organic electroluminescent device is λₘₐₓ, and 500 nm≤λₘₐₓ≤600 nm.

According to an embodiment of the present disclosure, the maximum emission wavelength in the electroluminescence spectrum of the organic electroluminescent device is λₘₐₓ, and 510 nm≤λₘₐₓ≤580 nm.

According to an embodiment of the present disclosure, a weight of the fluorescent material in the emissive layer of the organic electroluminescent device accounts for 0.01% to 5% of a total weight of the emissive layer.

According to an embodiment of the present disclosure, the weight of the fluorescent material in the emissive layer of the organic electroluminescent device accounts for 0.05% to 3% of the total weight of the emissive layer.

According to an embodiment of the present disclosure, the weight of the fluorescent material in the emissive layer of the organic electroluminescent device accounts for 0.1% to 1% of the total weight of the emissive layer.

According to an embodiment of the present disclosure, a full width at half maximum FWHM2 of the fluorescent material in the organic electroluminescent device is ≤60 nm.

According to an embodiment of the present disclosure, the full width at half maximum FWHM2 of the fluorescent material in the organic electroluminescent device is ≤50 nm.

According to an embodiment of the present disclosure, the full width at half maximum FWHM2 of the fluorescent material in the organic electroluminescent device is ≤40 nm.

According to an embodiment of the present disclosure, the fluorescent material serves as a main light-emitting source in the organic electroluminescent device.

According to an embodiment of the present disclosure, the fluorescent material serves as a terminal light-emitting material of the organic electroluminescent device.

According to an embodiment of the present disclosure, the fluorescent material comprises one material or multiple different materials.

According to an embodiment of the present disclosure, the emissive layer comprises a host material.

According to an embodiment of the present disclosure, the host material is a host compound.

According to an embodiment of the present disclosure, the emissive layer comprises at least one first host compound.

According to an embodiment of the present disclosure, the emissive layer further comprises at least two host compounds.

According to an embodiment of the present disclosure, at least one of the host compounds comprises at least one chemical group selected from the group consisting of: benzene, pyridine, pyrimidine, triazine, carbazole, azacarbazole, indolocarbazole, dibenzothiophene, aza-dibenzothiophene, dibenzofuran, azadibenzofuran, dibenzoselenophene, triphenylene, azatriphenylene, fluorene, silafluorene, naphthalene, quinoline, isoquinoline, quinazoline, quinoxaline, phenanthrene, azaphenanthrene, and combinations thereof.

According to an embodiment of the present disclosure, the first host compound has a structure represented by Formula X-1 or Formula X-2:

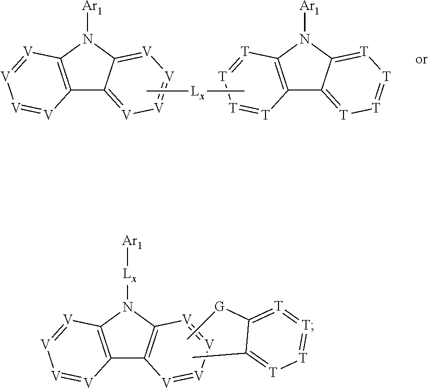

wherein
Lₓ is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 30 carbon atoms, substituted or unsubstituted heteroarylene having 3 to 30 carbon atoms, or a combination thereof;
G is, at each occurrence identically or differently, selected from C(R_{g})₂, NR_{g}, O, or S;
V is, at each occurrence identically or differently, selected from C, CRᵥ, or N;
in Formula X-1, T is, at each occurrence identically or differently, selected from C, CR_{T}, or N;
in Formula X-2, T is, at each occurrence identically or differently, selected from CR_{T} or N;
R_{g}, Rᵥ, and R_{T} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
Ar₁ is, at each occurrence identically or differently, selected from substituted or unsubstituted aryl having 6 to 30 carbon atoms, substituted or unsubstituted heteroaryl having 3 to 30 carbon atoms, or a combination thereof; and
adjacent substituents R_{g}, Rᵥ, and R_{T} can be optionally joined to form a ring.

In this embodiment, the expression that “adjacent substituents R_{g}, Rᵥ, and R_{T} can be optionally joined to form a ring” is intended to mean that any one or more of groups of adjacent substituents, such as two substituents Rᵥ, two substituents R_{T}, two substituents R_{g}, substituents Rᵥ and R_{T}, substituents Rᵥ and R_{g}, and substituents R_{g} and R_{T}, may be joined to form a ring. Obviously, it is also possible that none of these substituents are joined to form a ring.

According to an embodiment of the present disclosure, the first host compound has a structure represented by one of Formula X-a to Formula X-p:

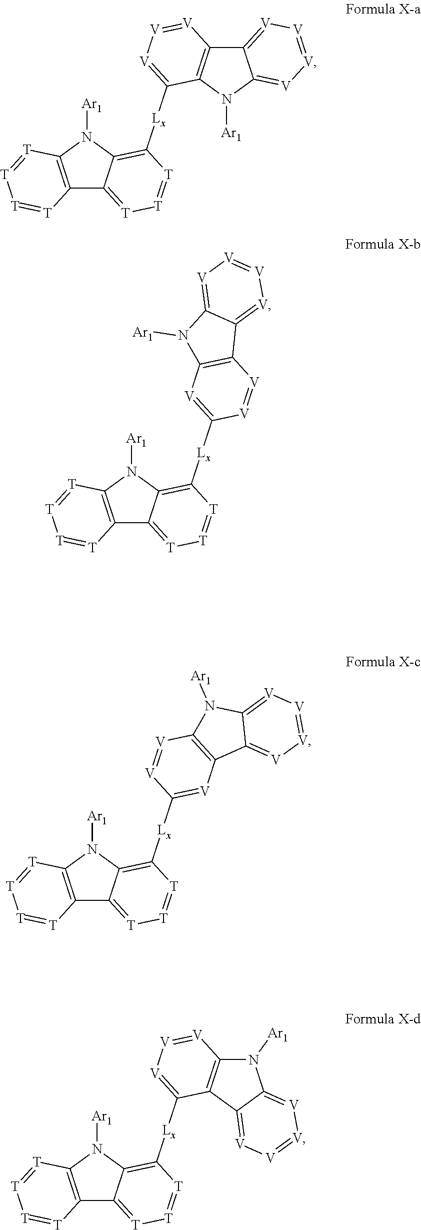

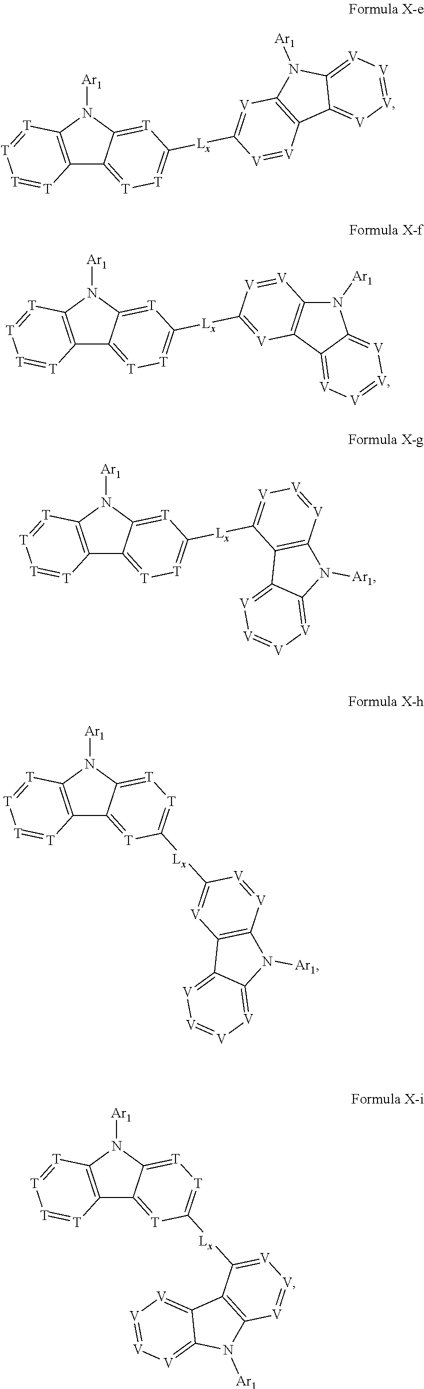

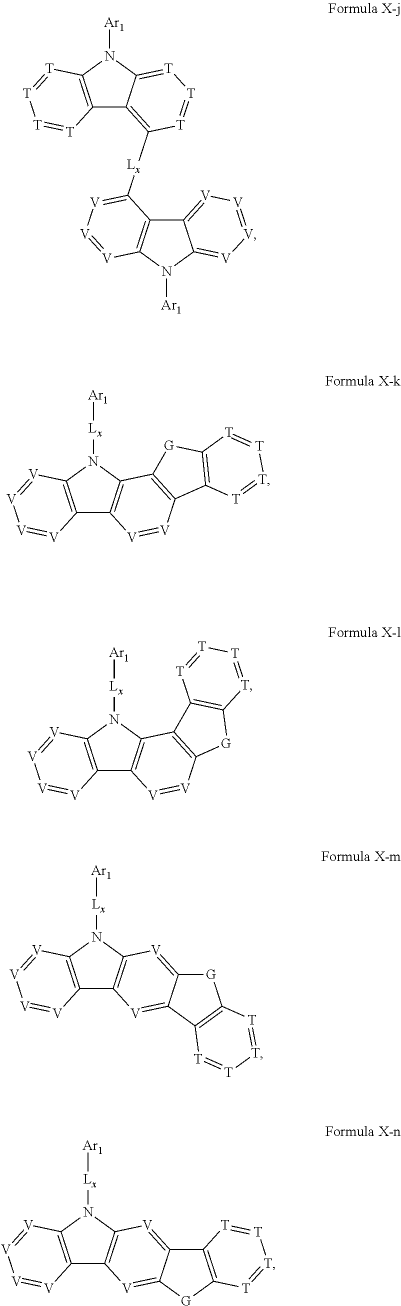

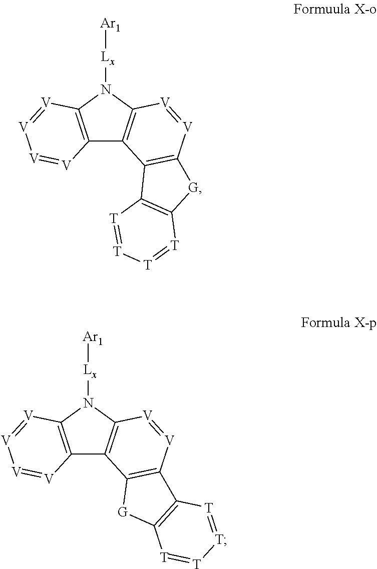

wherein
Lₓ is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms, or a combination thereof;
G is, at each occurrence identically or differently, selected from C(R_{g})₂, NR_{g}, O, or S;
V is, at each occurrence identically or differently, selected from CRᵥ or N;
T is, at each occurrence identically or differently, selected from CR_{T} or N;
R_{g}, Rᵥ, and R_{T} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
Ar₁ is, at each occurrence identically or differently, selected from substituted or unsubstituted aryl having 6 to 30 carbon atoms, substituted or unsubstituted heteroaryl having 3 to 30 carbon atoms, or a combination thereof; and
adjacent substituents R_{g}, Rᵥ, and R_{T} can be optionally joined to form a ring.

According to an embodiment of the present disclosure, the first host compound is selected from the group consisting of the following compounds:

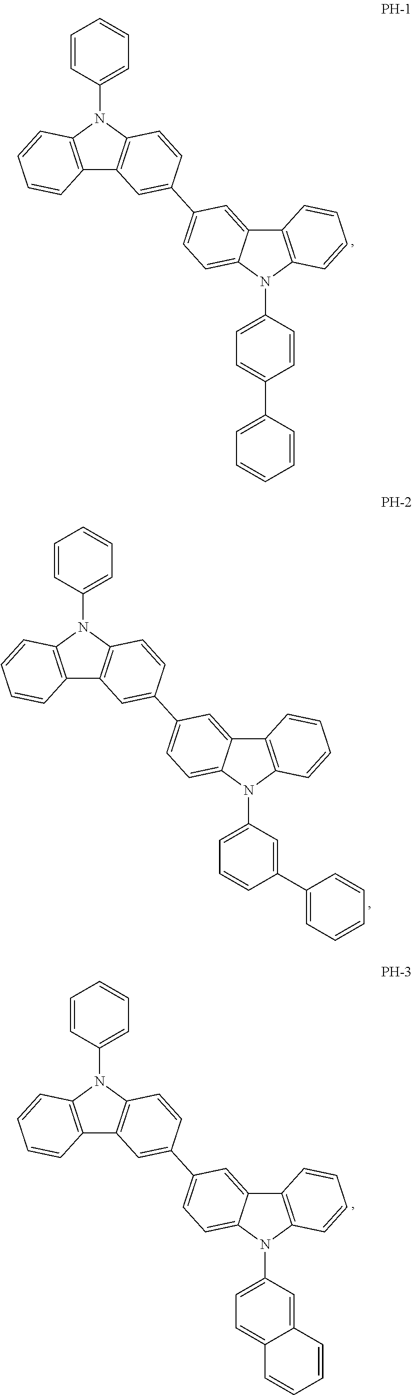 [SMILES: c1ccc(-c2ccc(-n3c4ccccc4c4cc(-c5ccc6c(c5)c5ccccc5n6-c5ccccc5)ccc43)cc2)cc1 ; c1ccc(-c2cccc(-n3c4ccccc4c4cc(-c5ccc6c(c5)c5ccccc5n6-c5ccccc5)ccc43)c2)cc1 ; c1ccc(-n2c3ccccc3c3cc(-c4ccc5c(c4)c4ccccc4n5-c4ccc5ccccc5c4)ccc32)cc1]

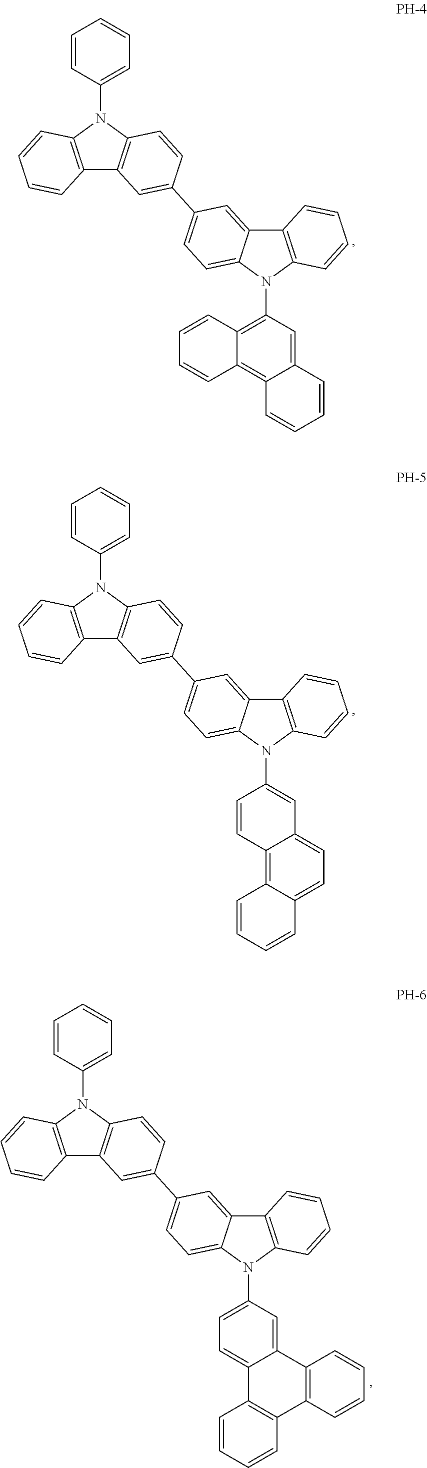 [SMILES: c1ccc(-n2c3ccccc3c3cc(-c4ccc5c(c4)c4ccccc4n5-c4cc5ccccc5c5ccccc45)ccc32)cc1 ; c1ccc(-n2c3ccccc3c3cc(-c4ccc5c(c4)c4ccccc4n5-c4ccc5c(ccc6ccccc65)c4)ccc32)cc1 ; c1ccc(-n2c3ccccc3c3cc(-c4ccc5c(c4)c4ccccc4n5-c4ccc5c6ccccc6c6ccccc6c5c4)ccc32)cc1]

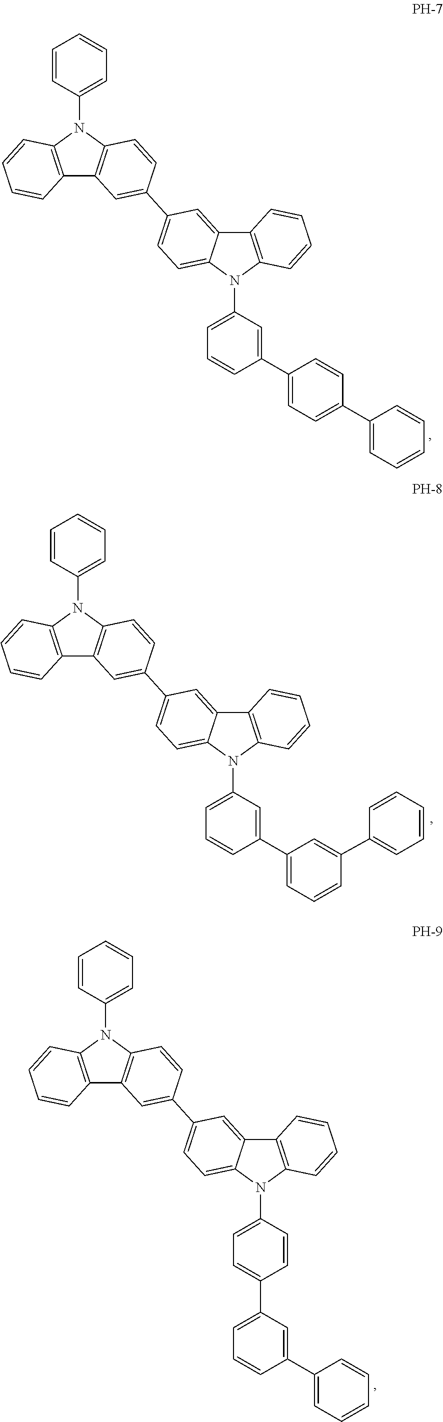 [SMILES: c1ccc(-c2ccc(-c3cccc(-n4c5ccccc5c5cc(-c6ccc7c(c6)c6ccccc6n7-c6ccccc6)ccc54)c3)cc2)cc1 ; c1ccc(-c2cccc(-c3cccc(-n4c5ccccc5c5cc(-c6ccc7c(c6)c6ccccc6n7-c6ccccc6)ccc54)c3)c2)cc1 ; c1ccc(-c2cccc(-c3ccc(-n4c5ccccc5c5cc(-c6ccc7c(c6)c6ccccc6n7-c6ccccc6)ccc54)cc3)c2)cc1]

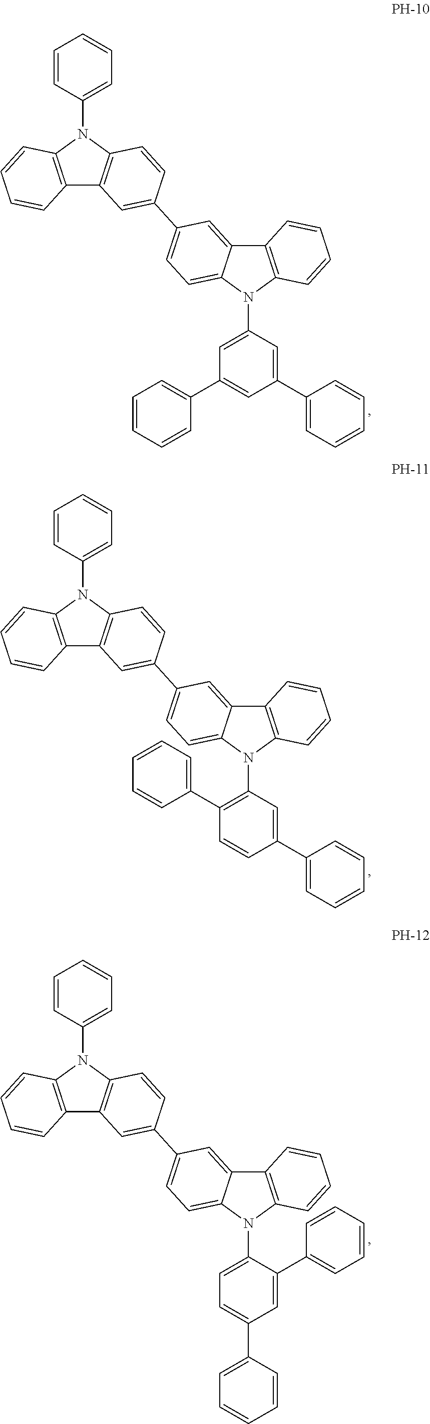 [SMILES: c1ccc(-c2cc(-c3ccccc3)cc(-n3c4ccccc4c4cc(-c5ccc6c(c5)c5ccccc5n6-c5ccccc5)ccc43)c2)cc1 ; c1ccc(-c2ccc(-c3ccccc3)c(-n3c4ccccc4c4cc(-c5ccc6c(c5)c5ccccc5n6-c5ccccc5)ccc43)c2)cc1 ; c1ccc(-c2ccc(-n3c4ccccc4c4cc(-c5ccc6c(c5)c5ccccc5n6-c5ccccc5)ccc43)c(-c3ccccc3)c2)cc1]

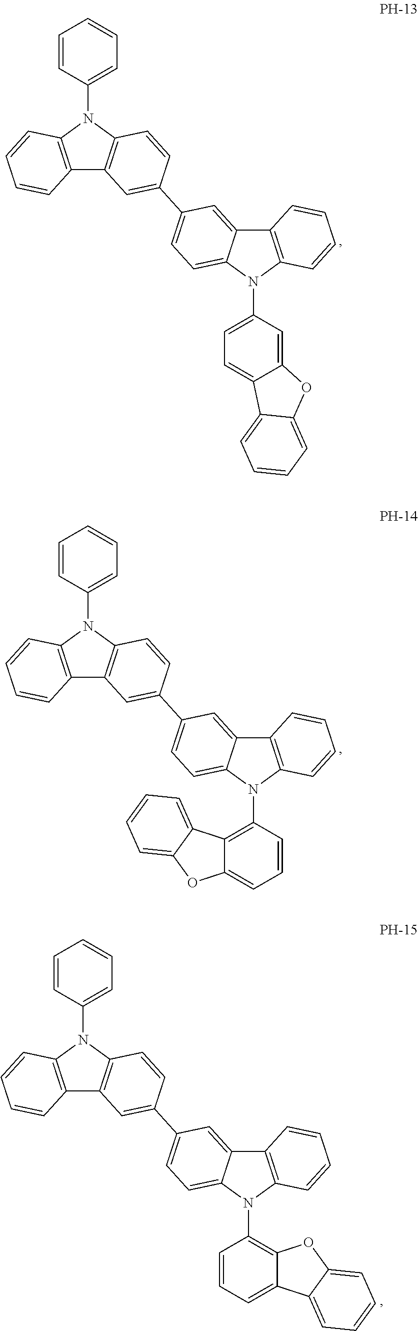 [SMILES: c1ccc(-n2c3ccccc3c3cc(-c4ccc5c(c4)c4ccccc4n5-c4ccc5c(c4)oc4ccccc45)ccc32)cc1 ; c1ccc(-n2c3ccccc3c3cc(-c4ccc5c(c4)c4ccccc4n5-c4cccc5oc6ccccc6c45)ccc32)cc1 ; c1ccc(-n2c3ccccc3c3cc(-c4ccc5c(c4)c4ccccc4n5-c4cccc5c4oc4ccccc45)ccc32)cc1]

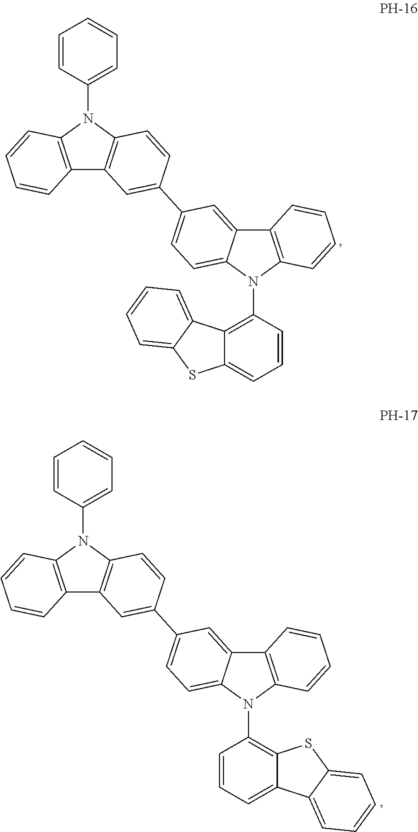 [SMILES: c1ccc(-n2c3ccccc3c3cc(-c4ccc5c(c4)c4ccccc4n5-c4cccc5sc6ccccc6c45)ccc32)cc1 ; c1ccc(-n2c3ccccc3c3cc(-c4ccc5c(c4)c4ccccc4n5-c4cccc5c4sc4ccccc45)ccc32)cc1]

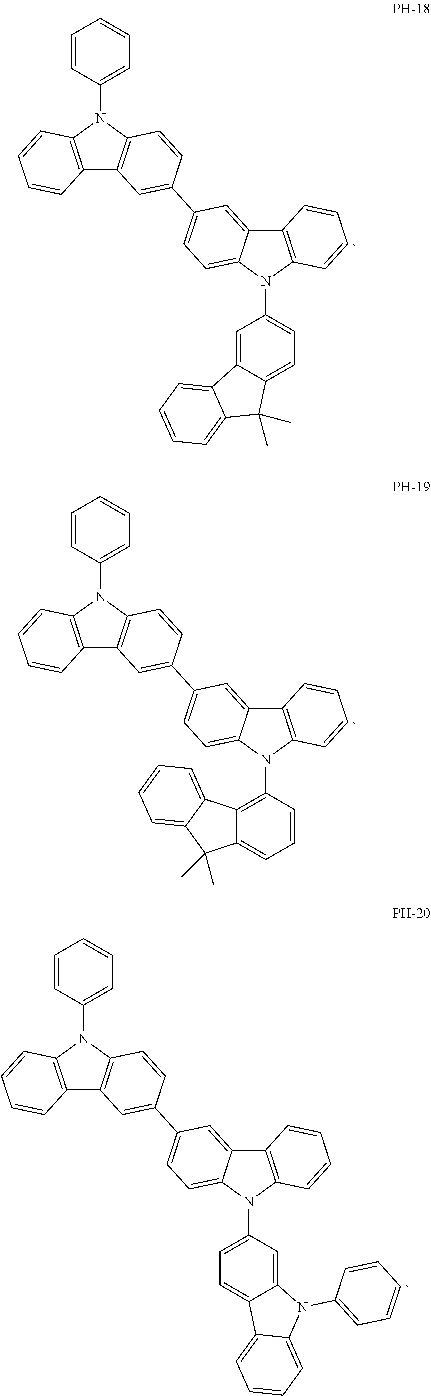 [SMILES: CC1(C)c2ccccc2-c2cc(-n3c4ccccc4c4cc(-c5ccc6c(c5)c5ccccc5n6-c5ccccc5)ccc43)ccc21 ; CC1(C)c2ccccc2-c2c(-n3c4ccccc4c4cc(-c5ccc6c(c5)c5ccccc5n6-c5ccccc5)ccc43)cccc21 ; c1ccc(-n2c3ccccc3c3cc(-c4ccc5c(c4)c4ccccc4n5-c4ccc5c6ccccc6n(-c6ccccc6)c5c4)ccc32)cc1]

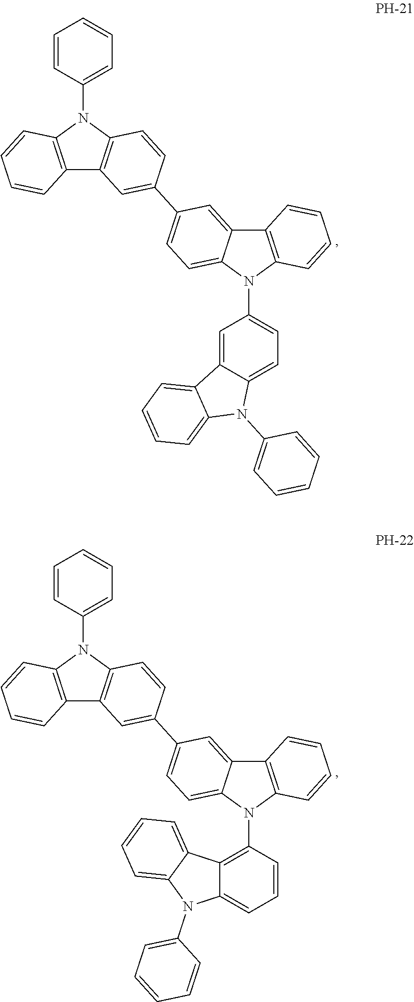 [SMILES: c1ccc(-n2c3ccccc3c3cc(-c4ccc5c(c4)c4ccccc4n5-c4ccc5c(c4)c4ccccc4n5-c4ccccc4)ccc32)cc1 ; c1ccc(-n2c3ccccc3c3cc(-c4ccc5c(c4)c4ccccc4n5-c4cccc5c4c4ccccc4n5-c4ccccc4)ccc32)cc1]

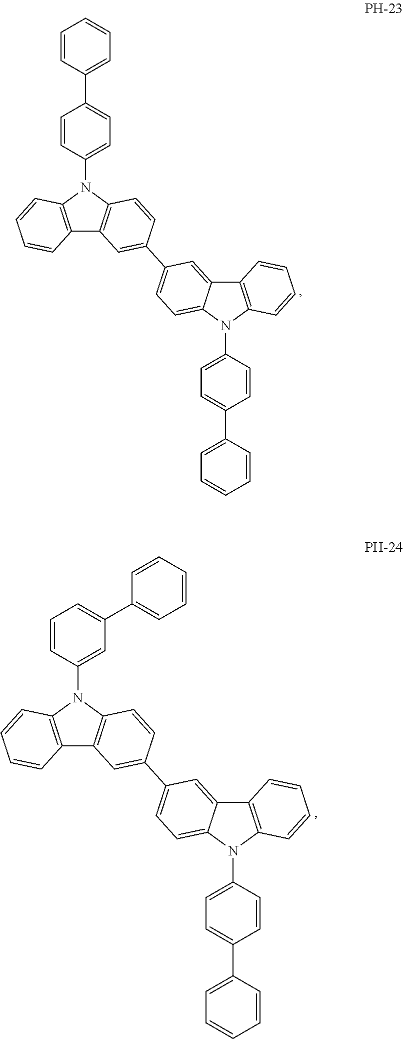 [SMILES: c1ccc(-c2ccc(-n3c4ccccc4c4cc(-c5ccc6c(c5)c5ccccc5n6-c5ccc(-c6ccccc6)cc5)ccc43)cc2)cc1 ; c1ccc(-c2ccc(-n3c4ccccc4c4cc(-c5ccc6c(c5)c5ccccc5n6-c5cccc(-c6ccccc6)c5)ccc43)cc2)cc1]

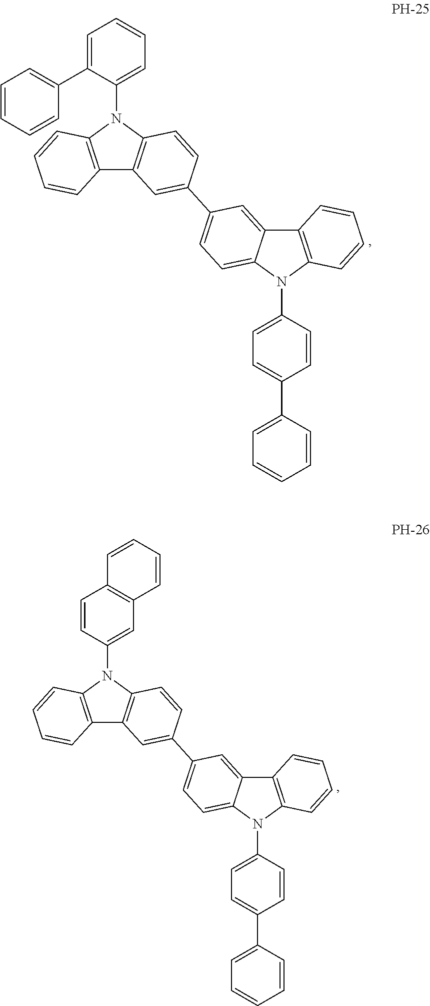 [SMILES: c1ccc(-c2ccc(-n3c4ccccc4c4cc(-c5ccc6c(c5)c5ccccc5n6-c5ccccc5-c5ccccc5)ccc43)cc2)cc1 ; c1ccc(-c2ccc(-n3c4ccccc4c4cc(-c5ccc6c(c5)c5ccccc5n6-c5ccc6ccccc6c5)ccc43)cc2)cc1]

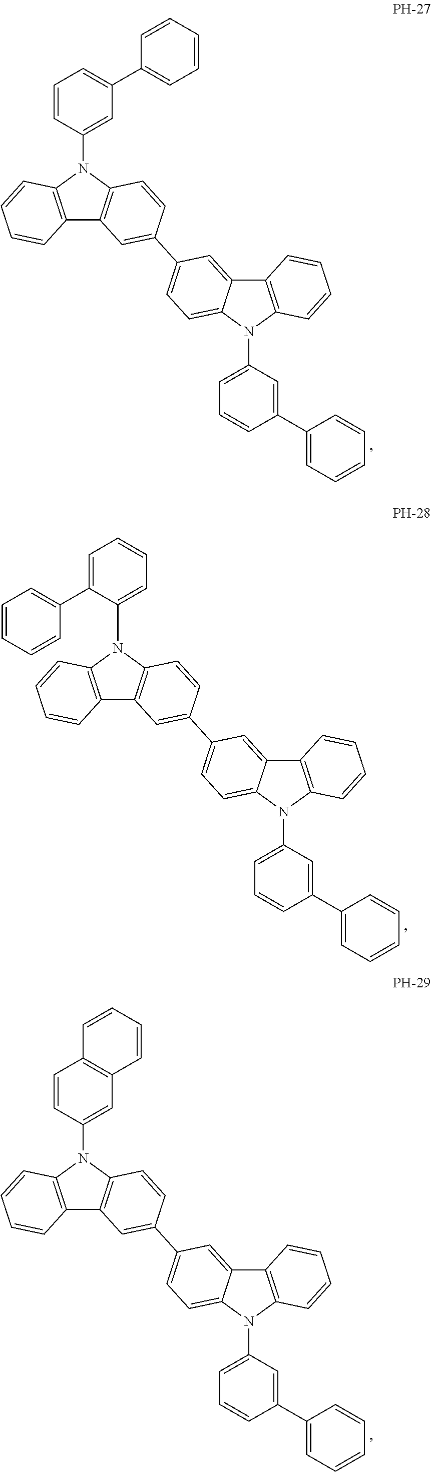 [SMILES: c1ccc(-c2cccc(-n3c4ccccc4c4cc(-c5ccc6c(c5)c5ccccc5n6-c5cccc(-c6ccccc6)c5)ccc43)c2)cc1 ; c1ccc(-c2cccc(-n3c4ccccc4c4cc(-c5ccc6c(c5)c5ccccc5n6-c5ccccc5-c5ccccc5)ccc43)c2)cc1 ; c1ccc(-c2cccc(-n3c4ccccc4c4cc(-c5ccc6c(c5)c5ccccc5n6-c5ccc6ccccc6c5)ccc43)c2)cc1]

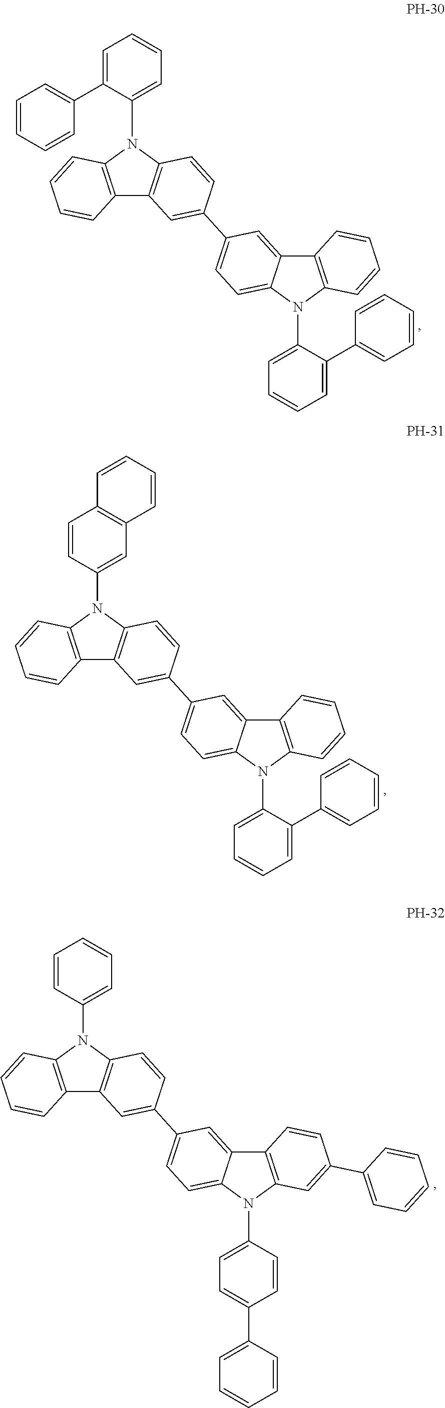 [SMILES: c1ccc(-c2ccccc2-n2c3ccccc3c3cc(-c4ccc5c(c4)c4ccccc4n5-c4ccccc4-c4ccccc4)ccc32)cc1 ; c1ccc(-c2ccccc2-n2c3ccccc3c3cc(-c4ccc5c(c4)c4ccccc4n5-c4ccc5ccccc5c4)ccc32)cc1 ; c1ccc(-c2ccc(-n3c4ccc(-c5ccc6c(c5)c5ccccc5n6-c5ccccc5)cc4c4ccc(-c5ccccc5)cc43)cc2)cc1]

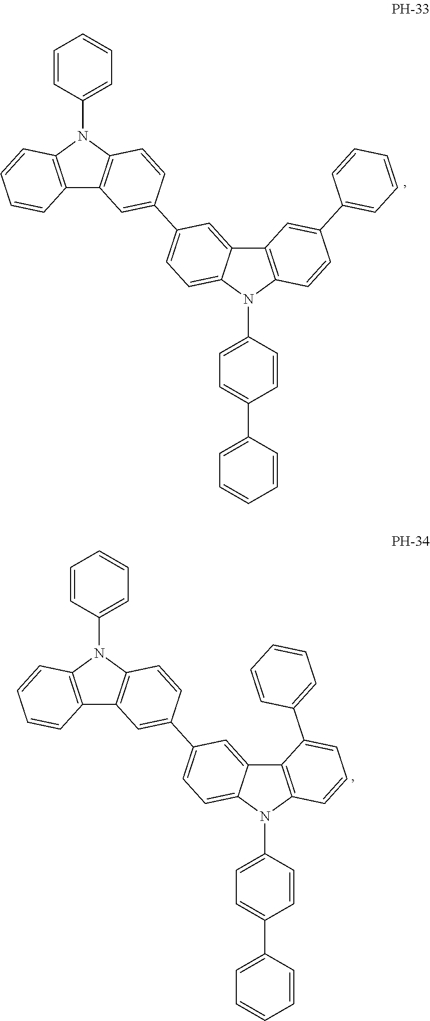 [SMILES: c1ccc(-c2ccc(-n3c4ccc(-c5ccccc5)cc4c4cc(-c5ccc6c(c5)c5ccccc5n6-c5ccccc5)ccc43)cc2)cc1 ; c1ccc(-c2ccc(-n3c4ccc(-c5ccc6c(c5)c5ccccc5n6-c5ccccc5)cc4c4c(-c5ccccc5)cccc43)cc2)cc1]

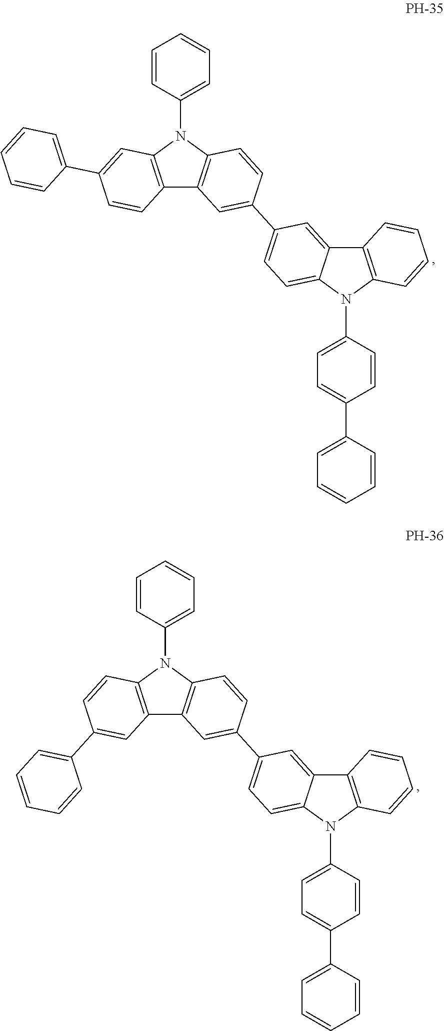 [SMILES: c1ccc(-c2ccc(-n3c4ccccc4c4cc(-c5ccc6c(c5)c5ccc(-c7ccccc7)cc5n6-c5ccccc5)ccc43)cc2)cc1 ; c1ccc(-c2ccc(-n3c4ccccc4c4cc(-c5ccc6c(c5)c5cc(-c7ccccc7)ccc5n6-c5ccccc5)ccc43)cc2)cc1]

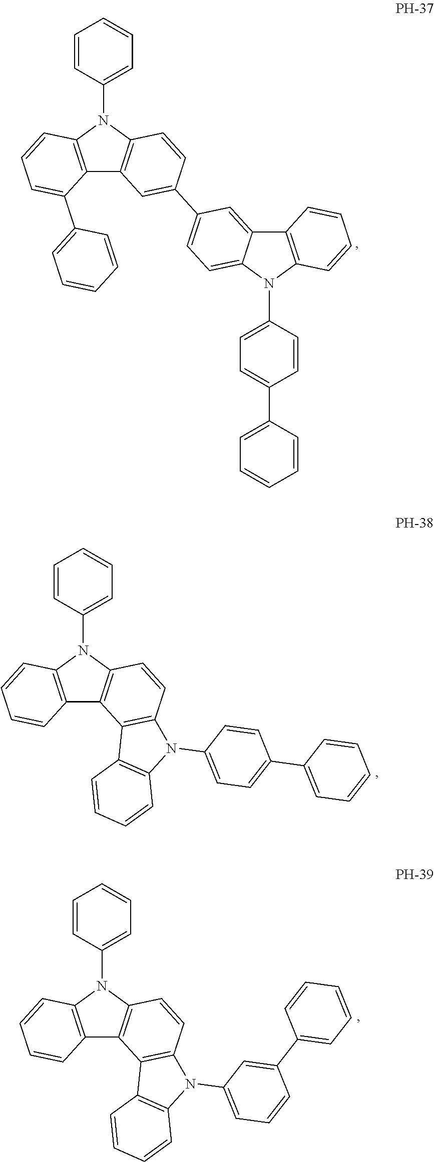 [SMILES: c1ccc(-c2ccc(-n3c4ccccc4c4cc(-c5ccc6c(c5)c5c(-c7ccccc7)cccc5n6-c5ccccc5)ccc43)cc2)cc1 ; c1ccc(-c2ccc(-n3c4ccccc4c4c5c6ccccc6n(-c6ccccc6)c5ccc43)cc2)cc1 ; c1ccc(-c2cccc(-n3c4ccccc4c4c5c6ccccc6n(-c6ccccc6)c5ccc43)c2)cc1]

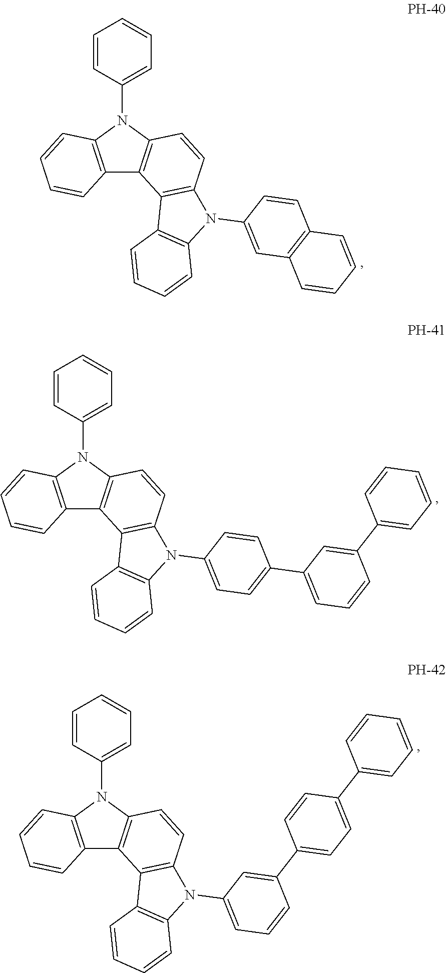 [SMILES: c1ccc(-n2c3ccccc3c3c4c5ccccc5n(-c5ccc6ccccc6c5)c4ccc32)cc1 ; c1ccc(-c2cccc(-c3ccc(-n4c5ccccc5c5c6c7ccccc7n(-c7ccccc7)c6ccc54)cc3)c2)cc1 ; c1ccc(-c2ccc(-c3cccc(-n4c5ccccc5c5c6c7ccccc7n(-c7ccccc7)c6ccc54)c3)cc2)cc1]

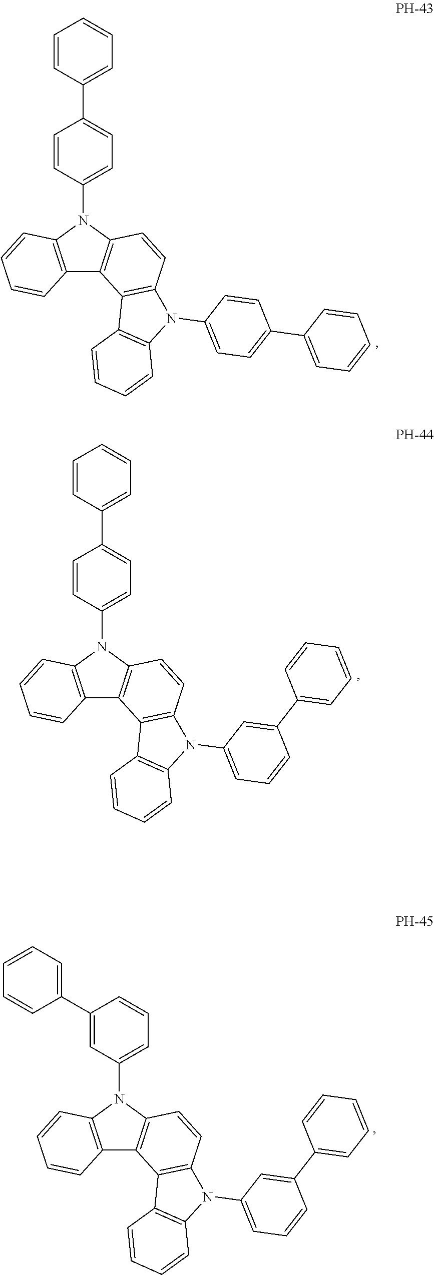 [SMILES: c1ccc(-c2ccc(-n3c4ccccc4c4c5c6ccccc6n(-c6ccc(-c7ccccc7)cc6)c5ccc43)cc2)cc1 ; c1ccc(-c2ccc(-n3c4ccccc4c4c5c6ccccc6n(-c6cccc(-c7ccccc7)c6)c5ccc43)cc2)cc1 ; c1ccc(-c2cccc(-n3c4ccccc4c4c5c6ccccc6n(-c6cccc(-c7ccccc7)c6)c5ccc43)c2)cc1]

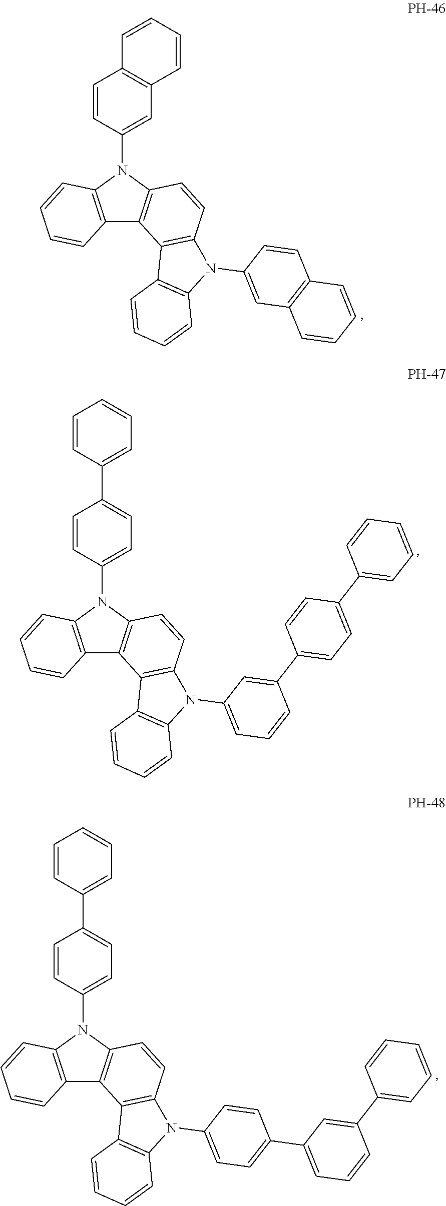 [SMILES: c1ccc2cc(-n3c4ccccc4c4c5c6ccccc6n(-c6ccc7ccccc7c6)c5ccc43)ccc2c1 ; c1ccc(-c2ccc(-c3cccc(-n4c5ccccc5c5c6c7ccccc7n(-c7ccc(-c8ccccc8)cc7)c6ccc54)c3)cc2)cc1 ; c1ccc(-c2ccc(-n3c4ccccc4c4c5c6ccccc6n(-c6ccc(-c7cccc(-c8ccccc8)c7)cc6)c5ccc43)cc2)cc1]

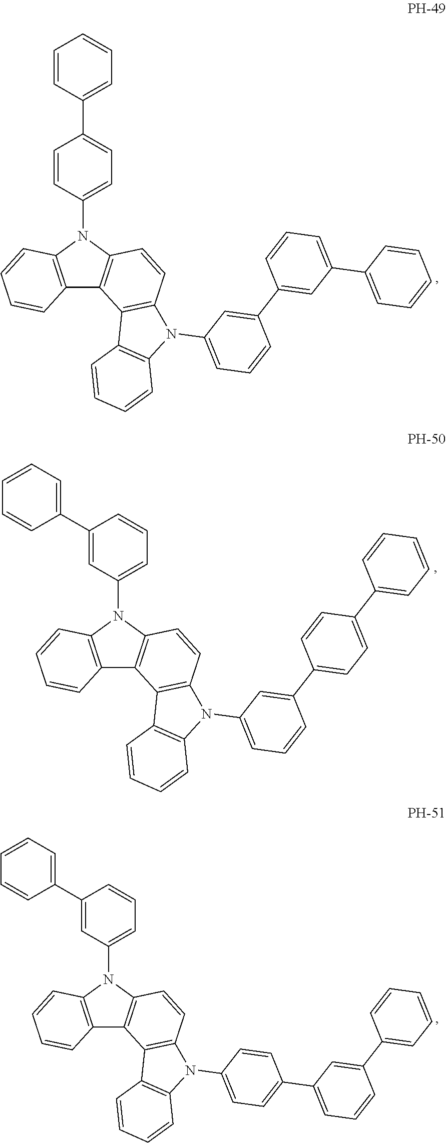 [SMILES: c1ccc(-c2ccc(-n3c4ccccc4c4c5c6ccccc6n(-c6cccc(-c7cccc(-c8ccccc8)c7)c6)c5ccc43)cc2)cc1 ; c1ccc(-c2ccc(-c3cccc(-n4c5ccccc5c5c6c7ccccc7n(-c7cccc(-c8ccccc8)c7)c6ccc54)c3)cc2)cc1 ; c1ccc(-c2cccc(-c3ccc(-n4c5ccccc5c5c6c7ccccc7n(-c7cccc(-c8ccccc8)c7)c6ccc54)cc3)c2)cc1]

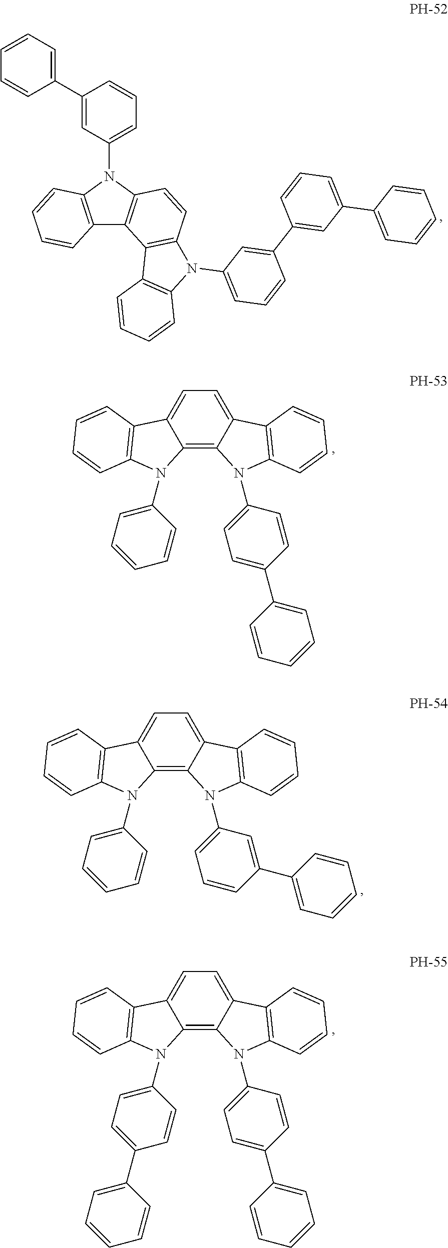 [SMILES: c1ccc(-c2cccc(-c3cccc(-n4c5ccccc5c5c6c7ccccc7n(-c7cccc(-c8ccccc8)c7)c6ccc54)c3)c2)cc1 ; c1ccc(-c2ccc(-n3c4ccccc4c4ccc5c6ccccc6n(-c6ccccc6)c5c43)cc2)cc1 ; c1ccc(-c2cccc(-n3c4ccccc4c4ccc5c6ccccc6n(-c6ccccc6)c5c43)c2)cc1 ; c1ccc(-c2ccc(-n3c4ccccc4c4ccc5c6ccccc6n(-c6ccc(-c7ccccc7)cc6)c5c43)cc2)cc1]

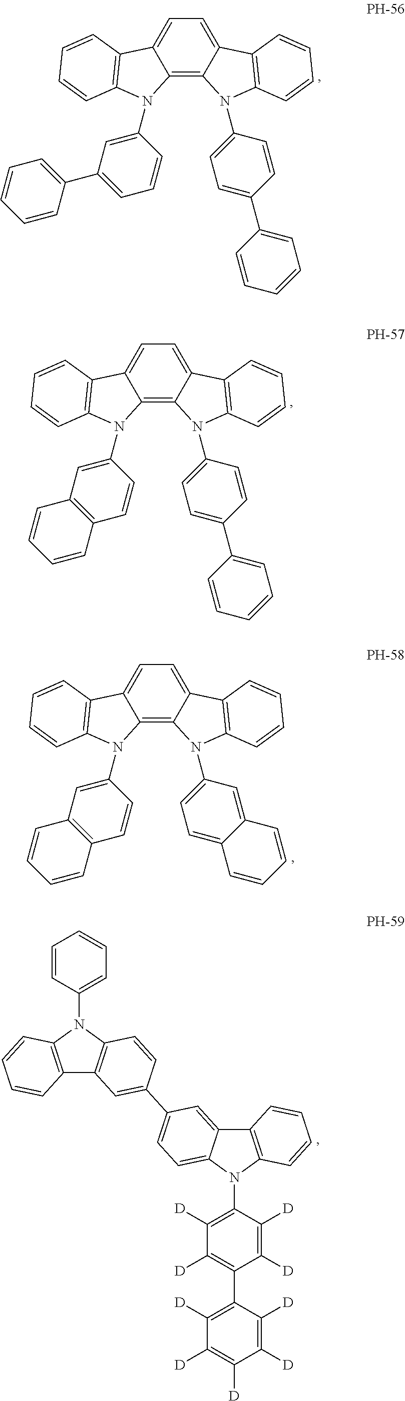 [SMILES: c1ccc(-c2ccc(-n3c4ccccc4c4ccc5c6ccccc6n(-c6cccc(-c7ccccc7)c6)c5c43)cc2)cc1 ; c1ccc(-c2ccc(-n3c4ccccc4c4ccc5c6ccccc6n(-c6ccc7ccccc7c6)c5c43)cc2)cc1 ; c1ccc2cc(-n3c4ccccc4c4ccc5c6ccccc6n(-c6ccc7ccccc7c6)c5c43)ccc2c1 ; [2H]c1c([2H])c([2H])c(-c2c([2H])c([2H])c(-n3c4ccccc4c4cc(-c5ccc6c(c5)c5ccccc5n6-c5ccccc5)ccc43)c([2H])c2[2H])c([2H])c1[2H]]

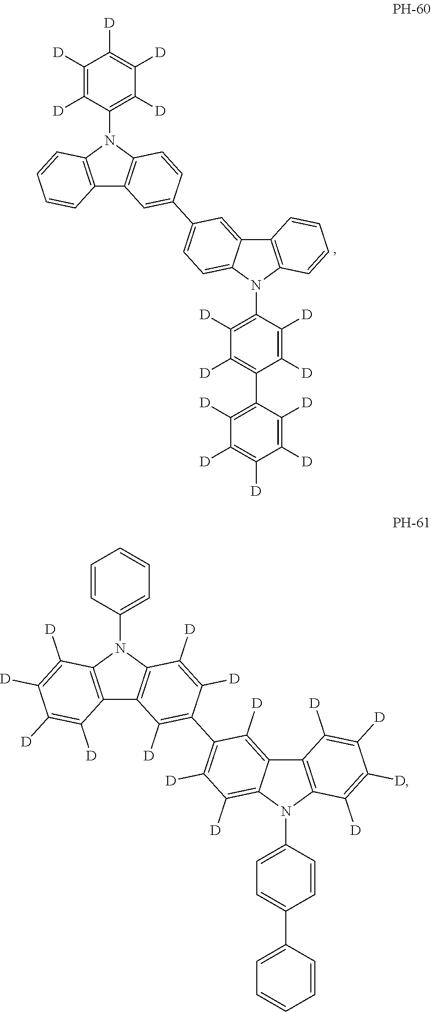

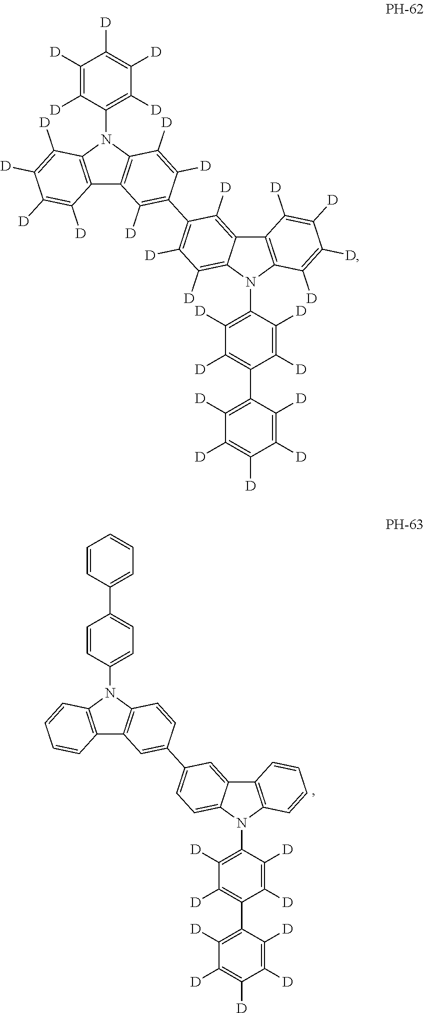

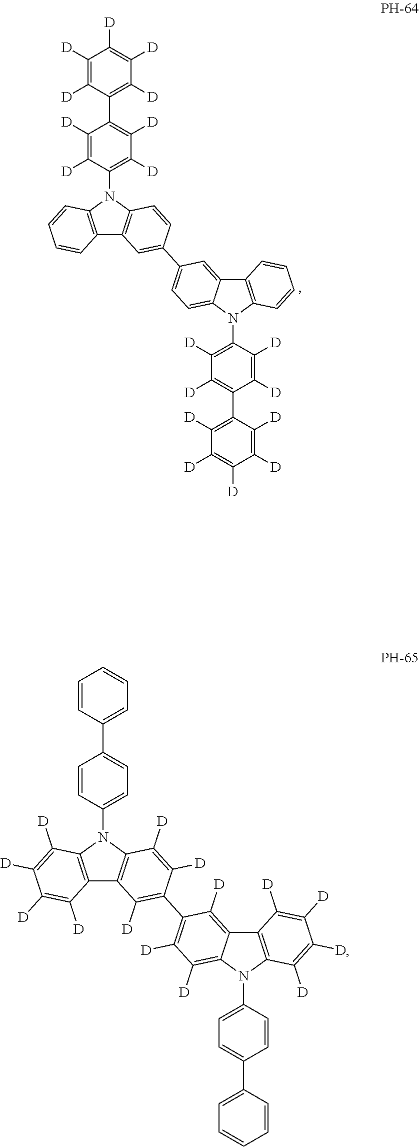

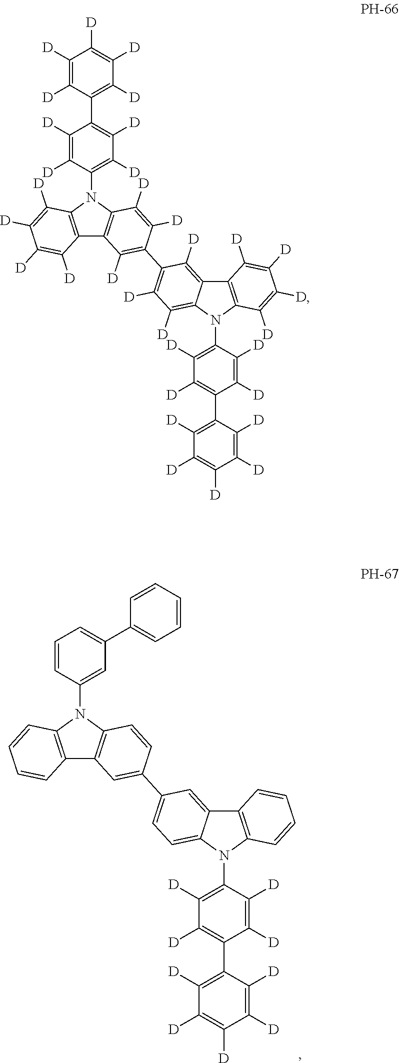

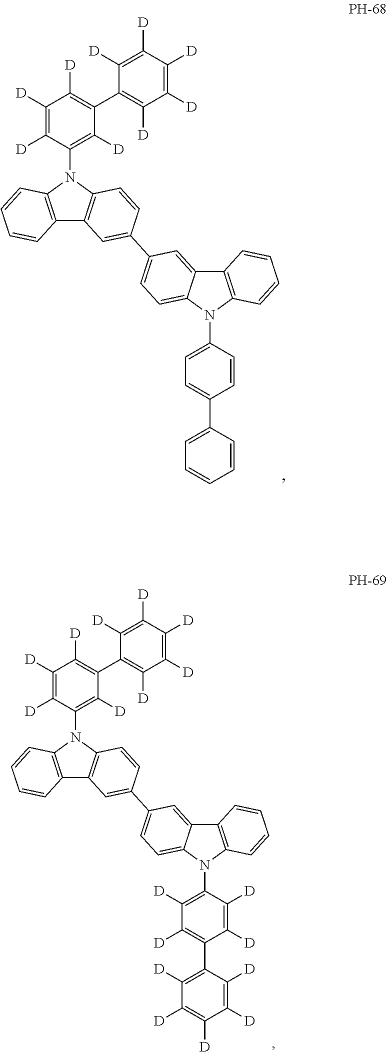 [SMILES: [2H]c1c([2H])c([2H])c(-c2c([2H])c([2H])c([2H])c(-n3c4ccccc4c4cc(-c5ccc6c(c5)c5ccccc5n6-c5ccc(-c6ccccc6)cc5)ccc43)c2[2H])c([2H])c1[2H] ; [2H]c1c([2H])c([2H])c(-c2c([2H])c([2H])c(-n3c4ccccc4c4cc(-c5ccc6c(c5)c5ccccc5n6-c5c([2H])c([2H])c([2H])c(-c6c([2H])c([2H])c([2H])c([2H])c6[2H])c5[2H])ccc43)c([2H])c2[2H])c([2H])c1[2H]]

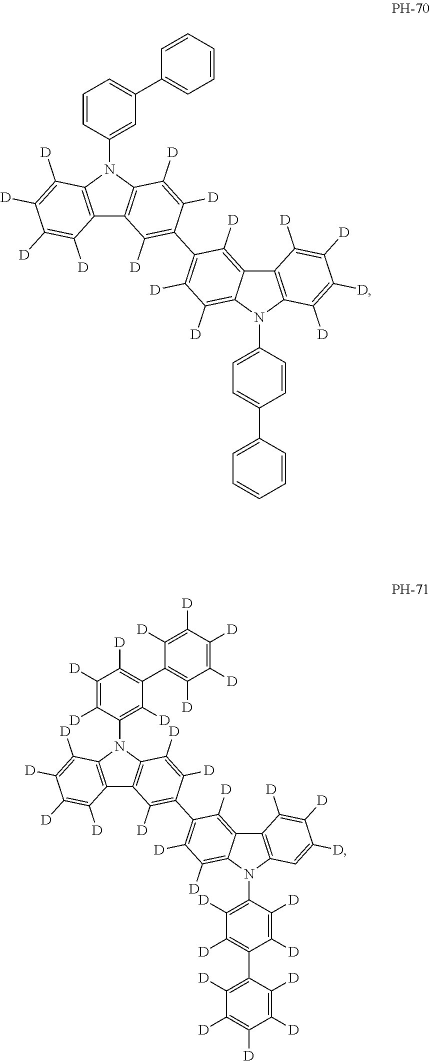

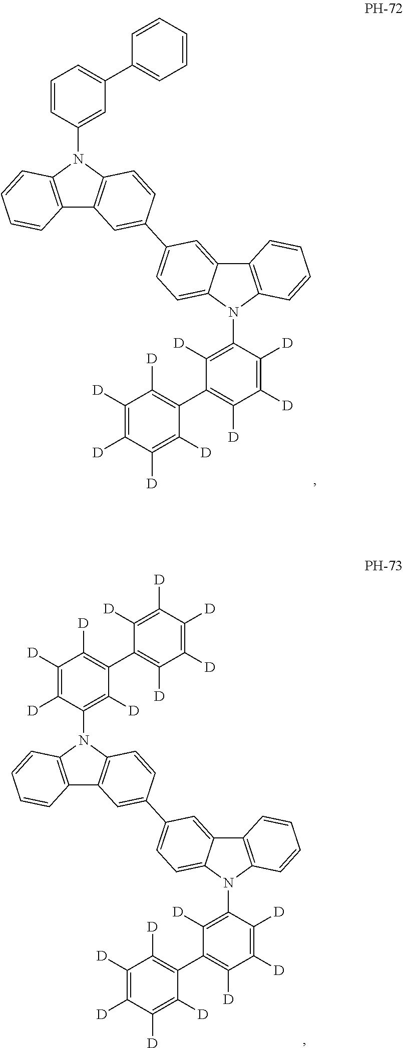 [SMILES: [2H]c1c([2H])c([2H])c(-c2c([2H])c([2H])c([2H])c(-n3c4ccccc4c4cc(-c5ccc6c(c5)c5ccccc5n6-c5cccc(-c6ccccc6)c5)ccc43)c2[2H])c([2H])c1[2H] ; [2H]c1c([2H])c([2H])c(-c2c([2H])c([2H])c([2H])c(-n3c4ccccc4c4cc(-c5ccc6c(c5)c5ccccc5n6-c5c([2H])c([2H])c([2H])c(-c6c([2H])c([2H])c([2H])c([2H])c6[2H])c5[2H])ccc43)c2[2H])c([2H])c1[2H]]

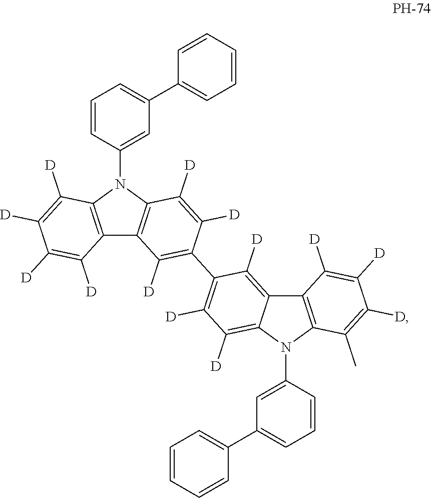

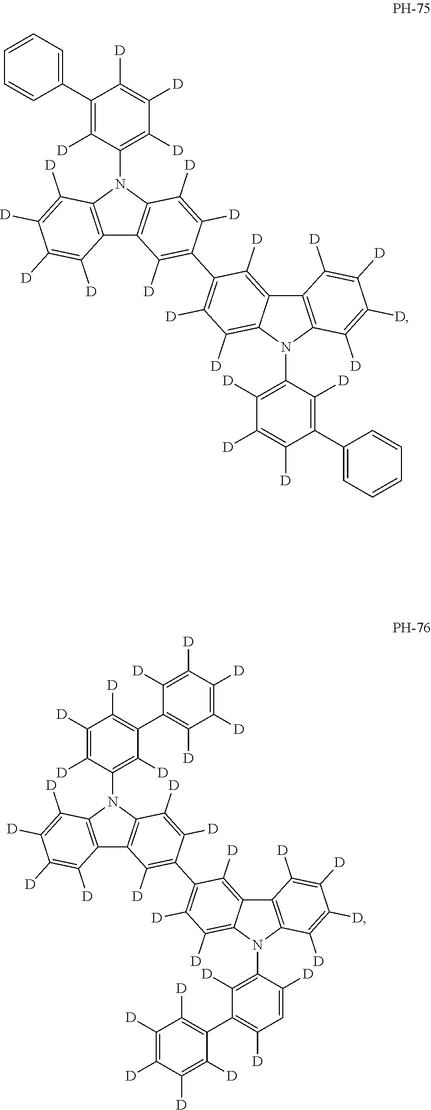

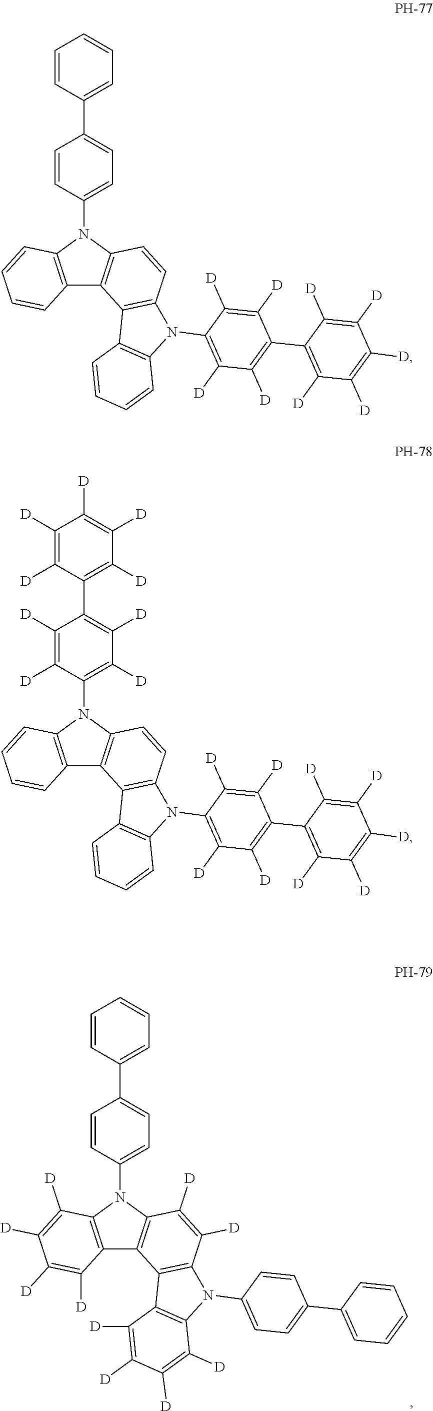

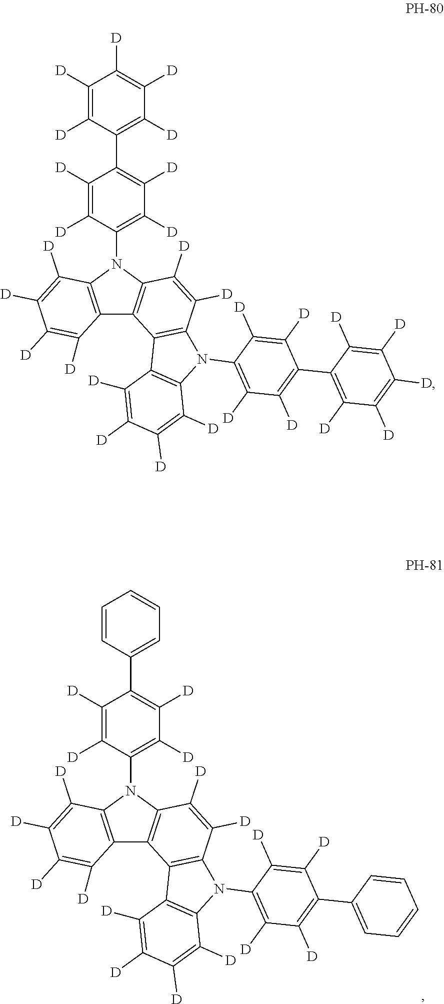

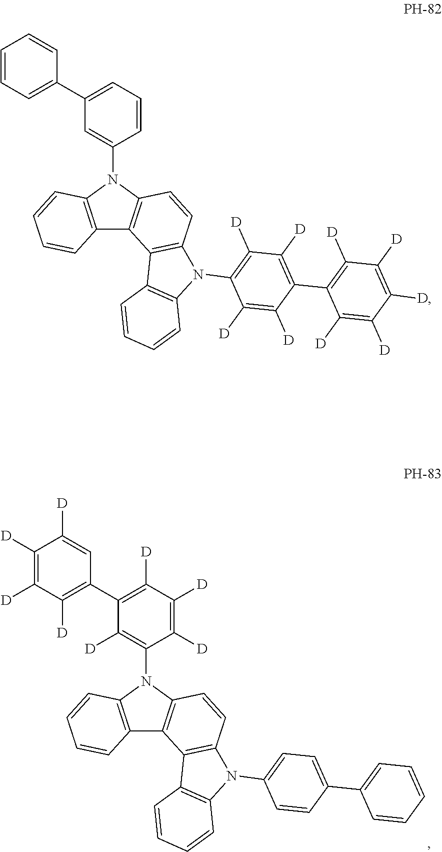

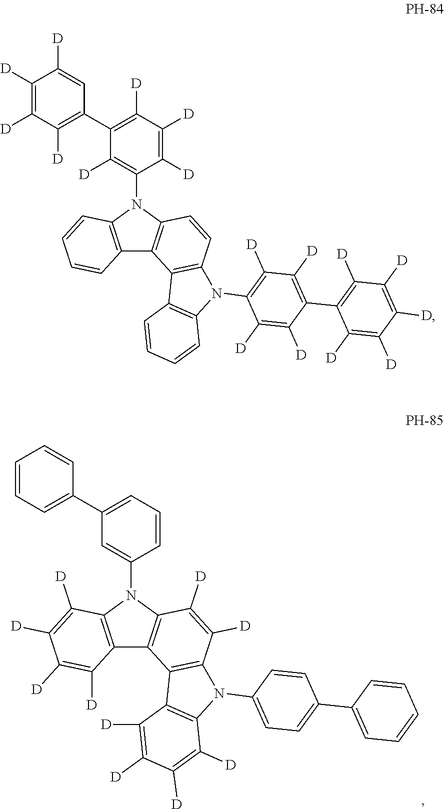

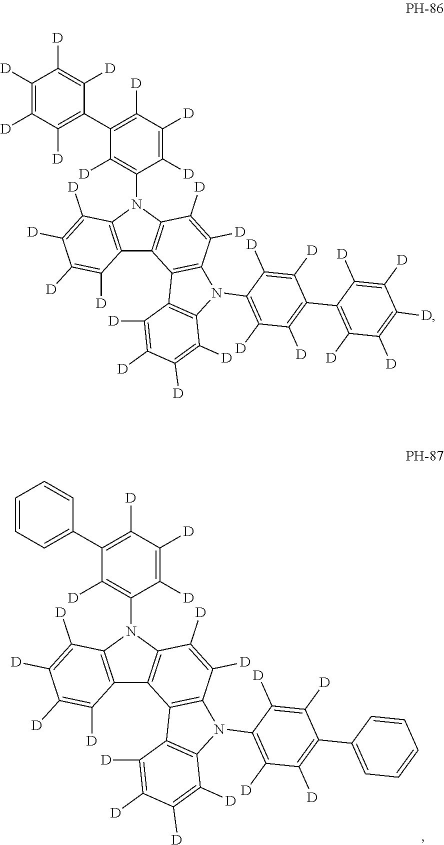

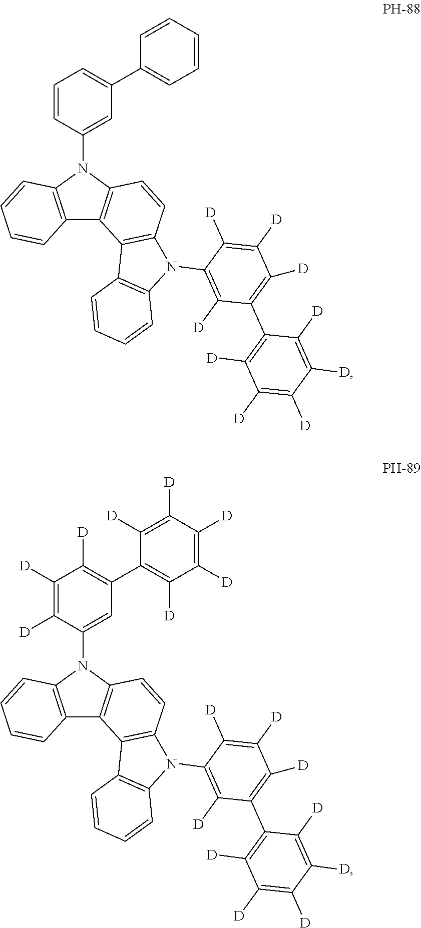

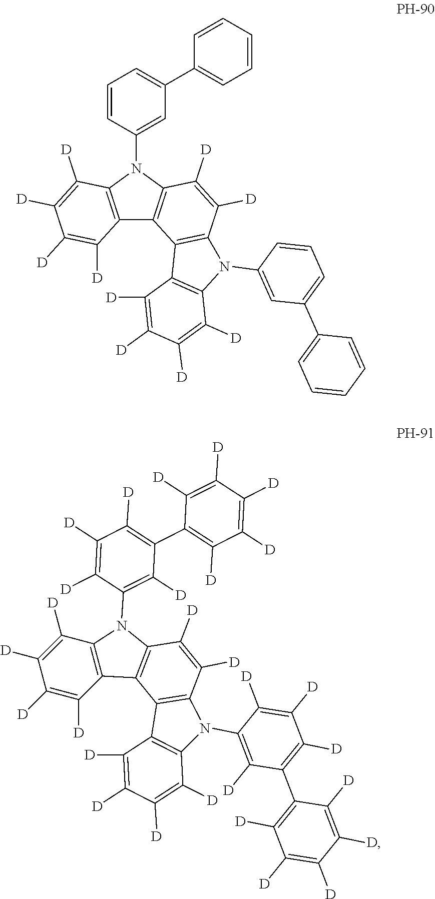

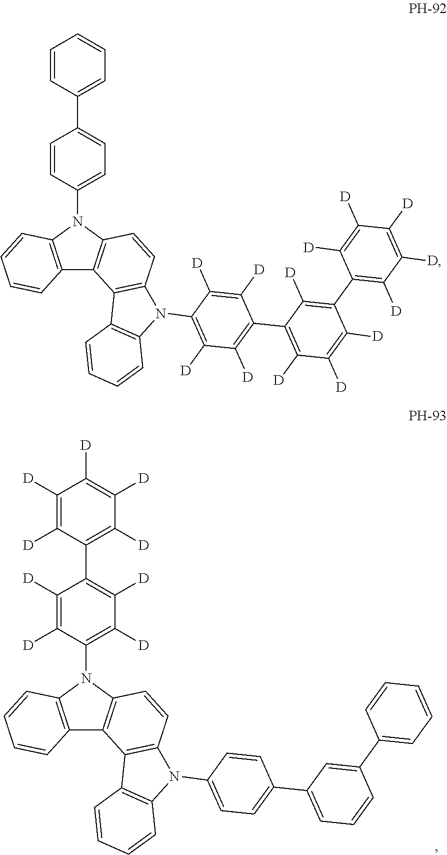

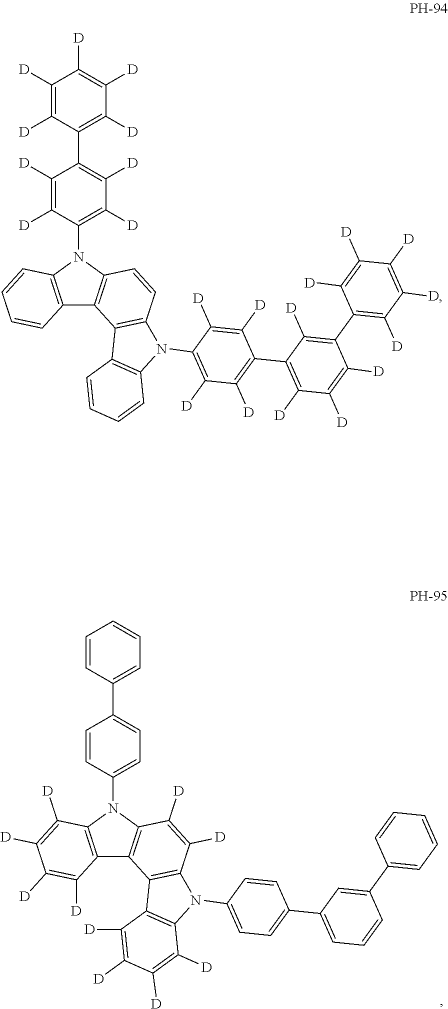

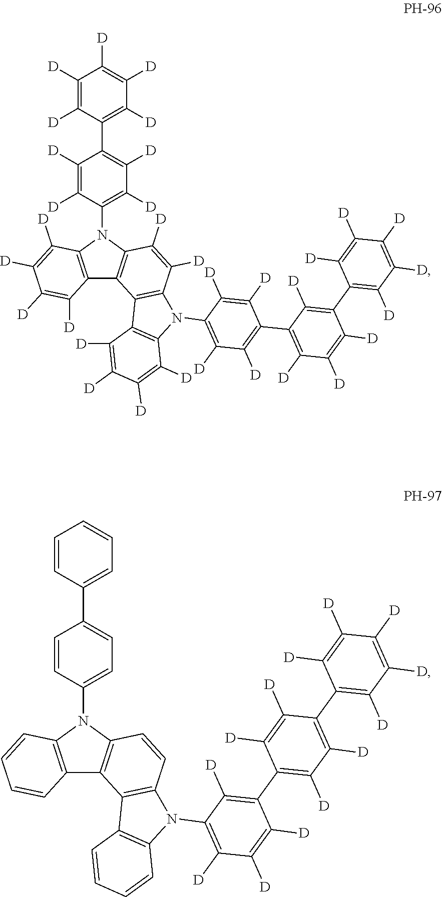

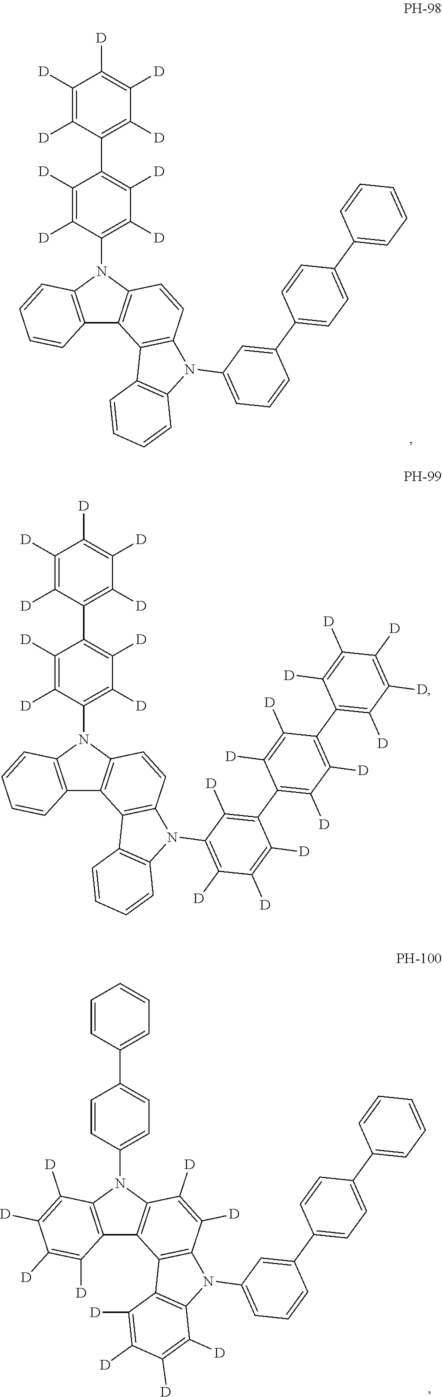

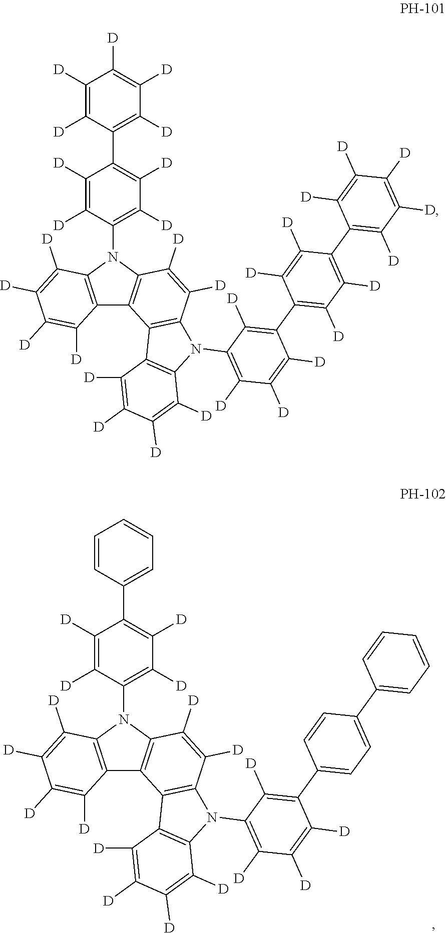

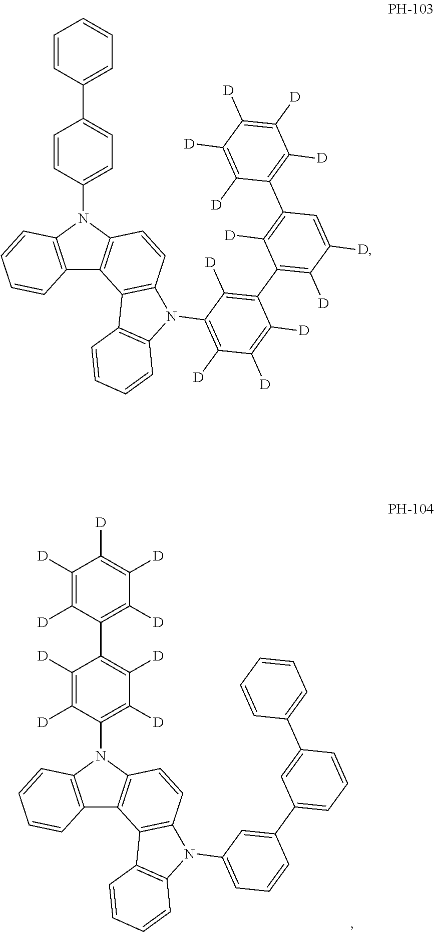

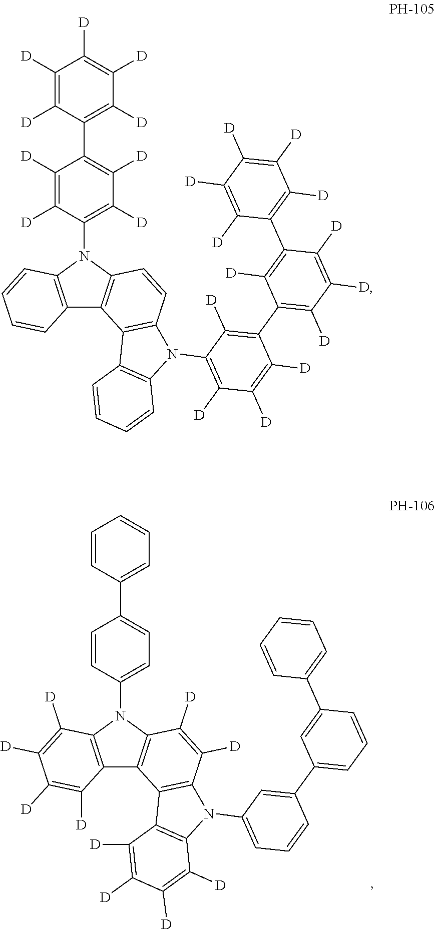

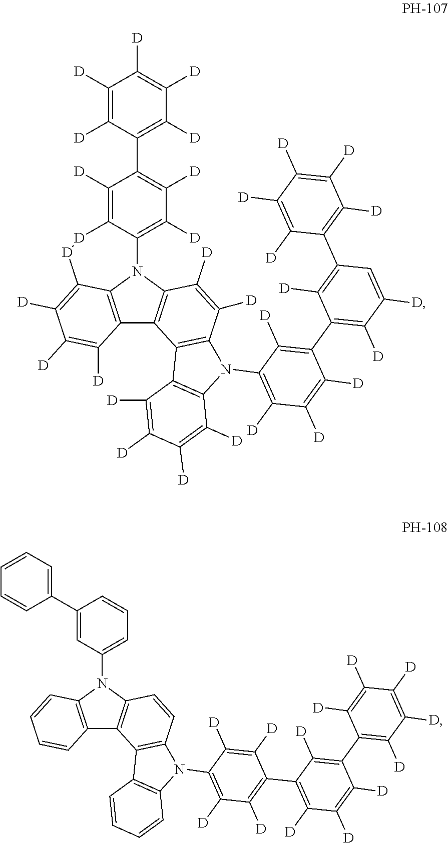

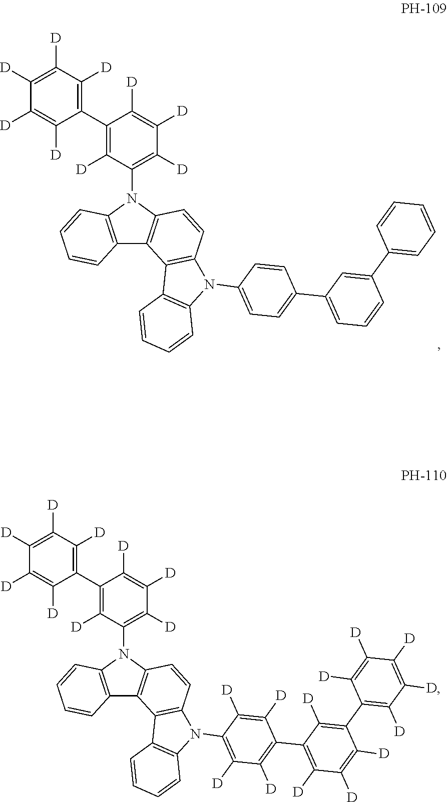

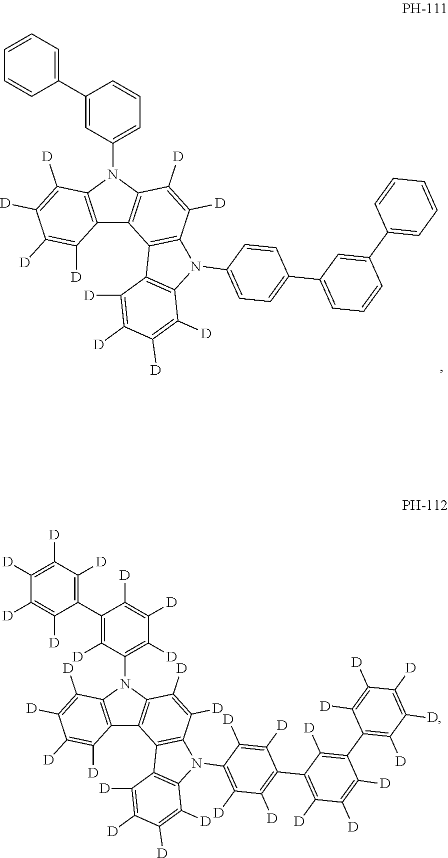

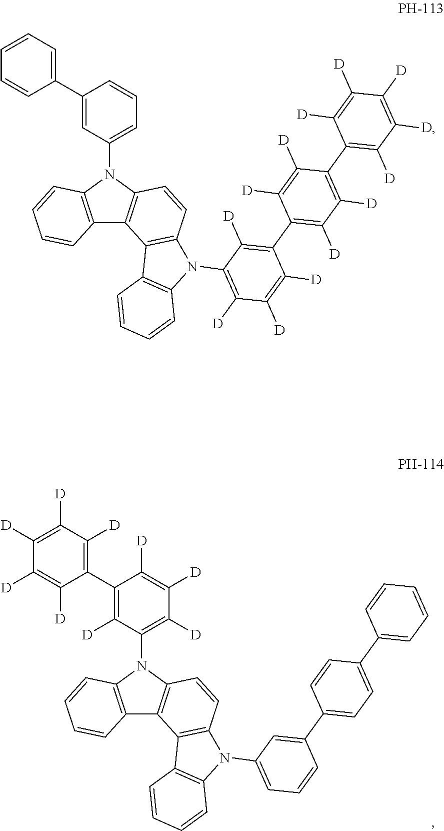

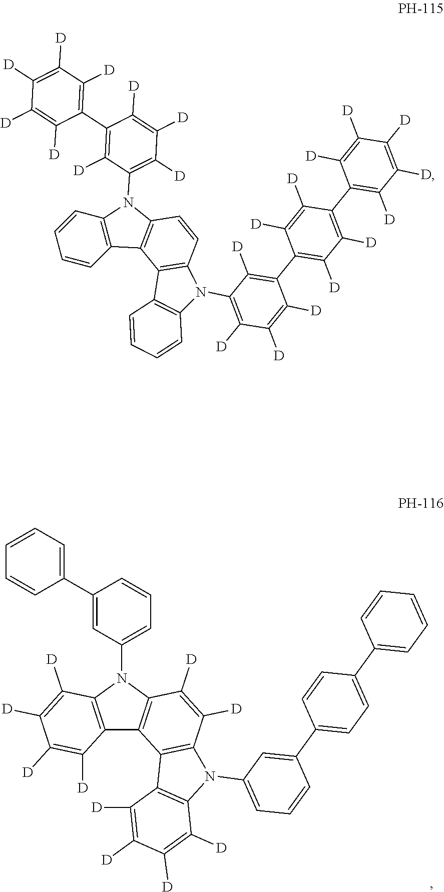

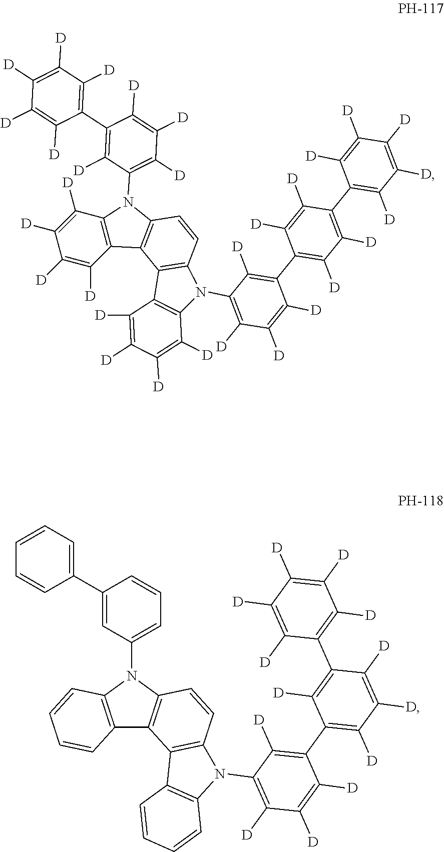

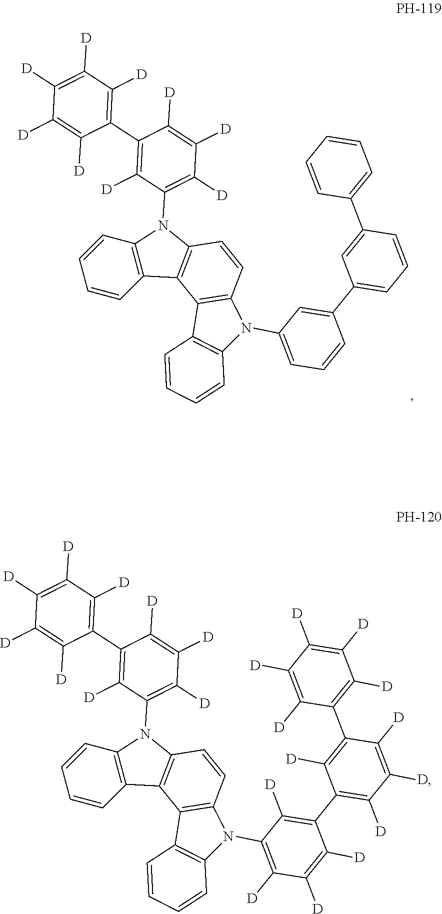

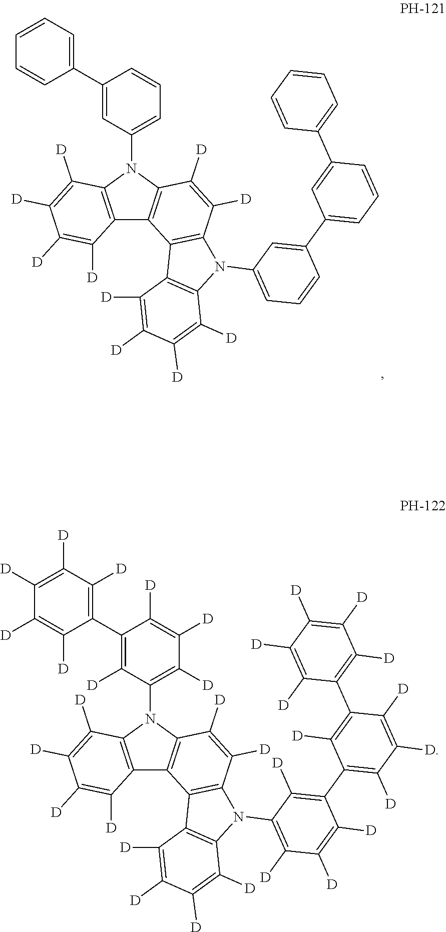

According to an embodiment of the present disclosure, the emissive layer further comprises a second host compound, and the second host compound has a structure represented by Formula Y:

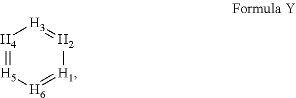

wherein
H₁ to H₆ are, at each occurrence identically or differently, selected from C, CRₕ, or N, at least two of H₁ to H₆ are N, and at least one of H₁ to H₆ is C and joined to Formula A:

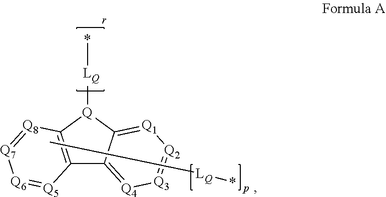

wherein
Q is, at each occurrence identically or differently, selected from the group consisting of O, S, Se, N, NR_{Q}, CR_{Q}R_{Q}, SiR_{Q}R_{Q}, GeR_{Q}R_{Q}, and R_{Q}C═CR_{Q}; when two R_{Q} are present at the same time, the two R_{Q} may be identical or different;
p is 0 or 1; r is 0 or 1;
when Q is selected from N, p is 0 and r is 1;
when Q is selected from the group consisting of O, S, Se, NR_{Q}, CR_{Q}R_{Q}, SiR_{Q}R_{Q}, GeR_{Q}R_{Q}, and R_{Q}C═CR_{Q}, p is 1 and r is 0;
L_{Q} is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 30 carbon atoms, substituted or unsubstituted heteroarylene having 3 to 30 carbon atoms, or a combination thereof;
Q₁ to Q₈ are, at each occurrence identically or differently, selected from C, CR_{q}, or N;
Rₕ, R_{Q}, and R_{q} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
“*” represents a position where Formula A is joined to Formula Y; and
adjacent substituents Rₕ, R_{Q}, and R_{q} can be optionally joined to form a ring.

Herein, the expression that “adjacent substituents Rₕ, R_{Q}, and R_{q} can be optionally joined to form a ring” is intended to mean that any one or more of groups of adjacent substituents, such as two substituents Rₕ, two substituents R_{Q}, two substituents R_{q}, and two substituents R_{Q} and R_{q}, may be joined to form a ring. Obviously, it is also possible that none of these substituents are joined to form a ring.

According to an embodiment of the present disclosure, the second host compound is selected from the group consisting of the following compounds:

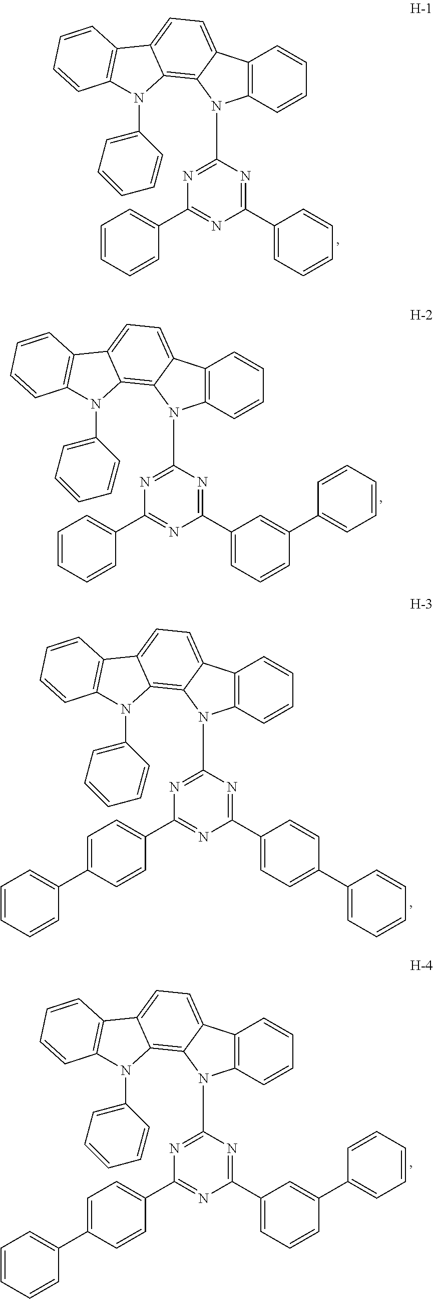 [SMILES: c1ccc(-c2nc(-c3ccccc3)nc(-n3c4ccccc4c4ccc5c6ccccc6n(-c6ccccc6)c5c43)n2)cc1 ; c1ccc(-c2cccc(-c3nc(-c4ccccc4)nc(-n4c5ccccc5c5ccc6c7ccccc7n(-c7ccccc7)c6c54)n3)c2)cc1 ; c1ccc(-c2ccc(-c3nc(-c4ccc(-c5ccccc5)cc4)nc(-n4c5ccccc5c5ccc6c7ccccc7n(-c7ccccc7)c6c54)n3)cc2)cc1 ; c1ccc(-c2ccc(-c3nc(-c4cccc(-c5ccccc5)c4)nc(-n4c5ccccc5c5ccc6c7ccccc7n(-c7ccccc7)c6c54)n3)cc2)cc1]

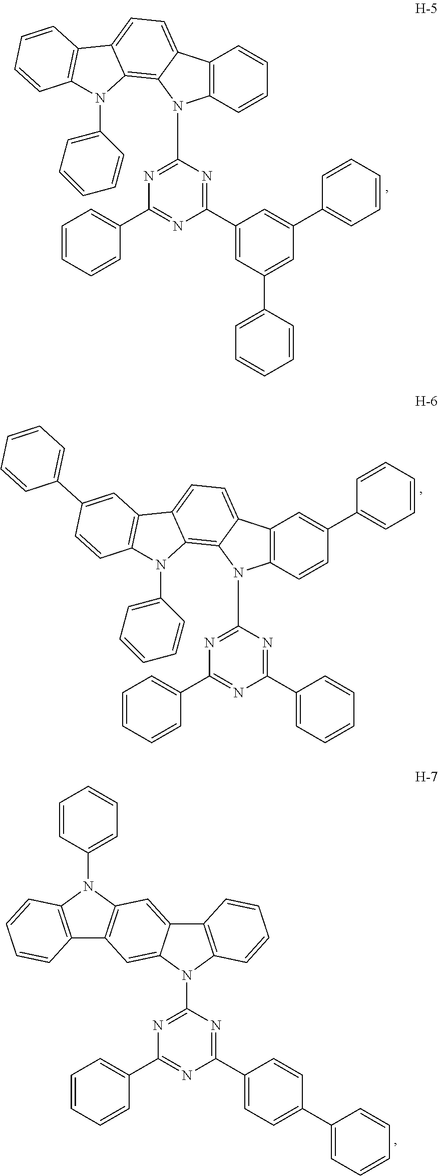 [SMILES: c1ccc(-c2cc(-c3ccccc3)cc(-c3nc(-c4ccccc4)nc(-n4c5ccccc5c5ccc6c7ccccc7n(-c7ccccc7)c6c54)n3)c2)cc1 ; c1ccc(-c2ccc3c(c2)c2ccc4c5cc(-c6ccccc6)ccc5n(-c5nc(-c6ccccc6)nc(-c6ccccc6)n5)c4c2n3-c2ccccc2)cc1 ; c1ccc(-c2ccc(-c3nc(-c4ccccc4)nc(-n4c5ccccc5c5cc6c(cc54)c4ccccc4n6-c4ccccc4)n3)cc2)cc1]

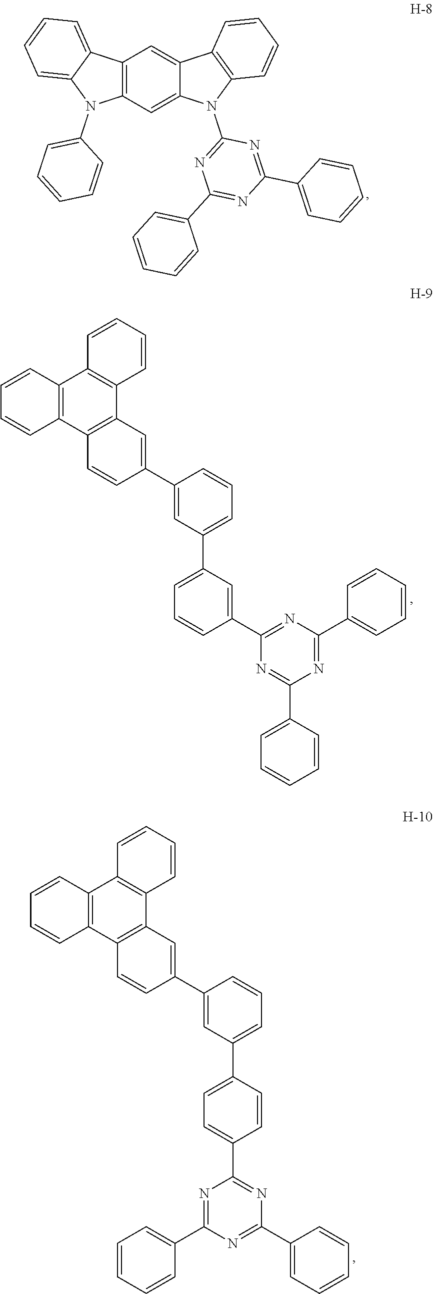 [SMILES: c1ccc(-c2nc(-c3ccccc3)nc(-n3c4ccccc4c4cc5c6ccccc6n(-c6ccccc6)c5cc43)n2)cc1 ; c1ccc(-c2nc(-c3ccccc3)nc(-c3cccc(-c4cccc(-c5ccc6c7ccccc7c7ccccc7c6c5)c4)c3)n2)cc1 ; c1ccc(-c2nc(-c3ccccc3)nc(-c3ccc(-c4cccc(-c5ccc6c7ccccc7c7ccccc7c6c5)c4)cc3)n2)cc1]

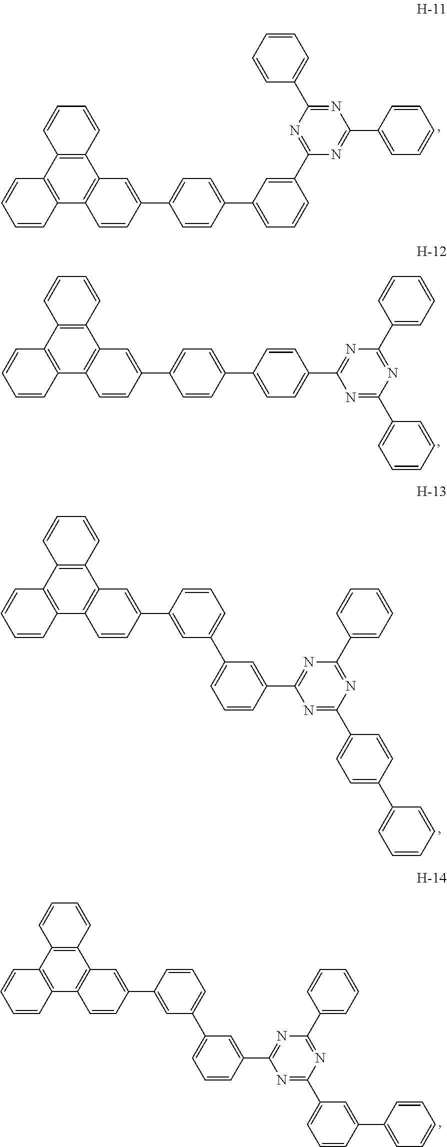 [SMILES: c1ccc(-c2nc(-c3ccccc3)nc(-c3cccc(-c4ccc(-c5ccc6c7ccccc7c7ccccc7c6c5)cc4)c3)n2)cc1 ; c1ccc(-c2nc(-c3ccccc3)nc(-c3ccc(-c4ccc(-c5ccc6c7ccccc7c7ccccc7c6c5)cc4)cc3)n2)cc1 ; c1ccc(-c2ccc(-c3nc(-c4ccccc4)nc(-c4cccc(-c5cccc(-c6ccc7c8ccccc8c8ccccc8c7c6)c5)c4)n3)cc2)cc1 ; c1ccc(-c2cccc(-c3nc(-c4ccccc4)nc(-c4cccc(-c5cccc(-c6ccc7c8ccccc8c8ccccc8c7c6)c5)c4)n3)c2)cc1]

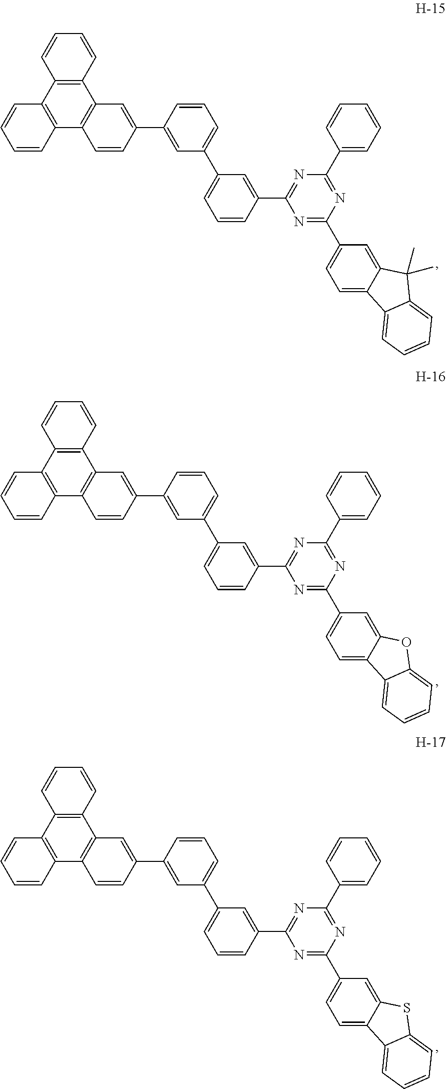 [SMILES: CC1(C)c2ccccc2-c2ccc(-c3nc(-c4ccccc4)nc(-c4cccc(-c5cccc(-c6ccc7c8ccccc8c8ccccc8c7c6)c5)c4)n3)cc21 ; c1ccc(-c2nc(-c3cccc(-c4cccc(-c5ccc6c7ccccc7c7ccccc7c6c5)c4)c3)nc(-c3ccc4c(c3)oc3ccccc34)n2)cc1 ; c1ccc(-c2nc(-c3cccc(-c4cccc(-c5ccc6c7ccccc7c7ccccc7c6c5)c4)c3)nc(-c3ccc4c(c3)sc3ccccc34)n2)cc1]

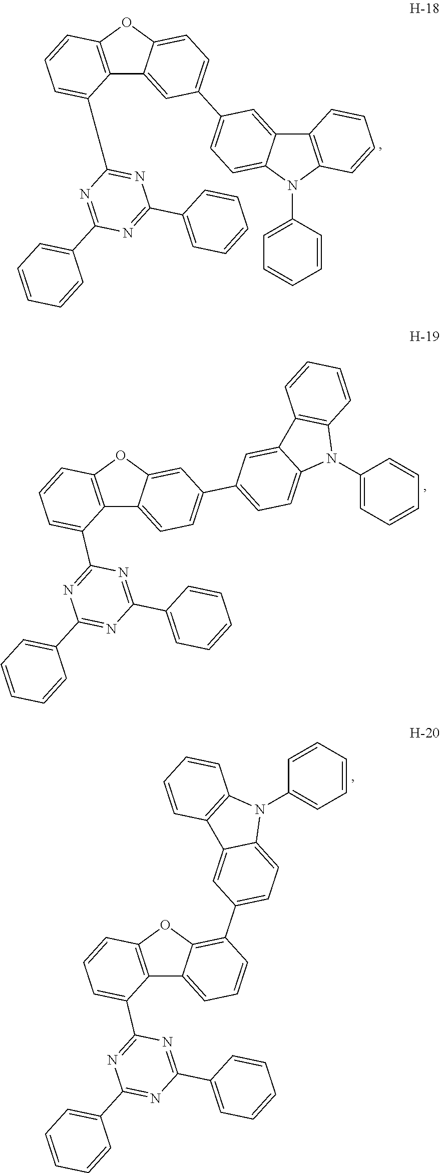 [SMILES: c1ccc(-c2nc(-c3ccccc3)nc(-c3cccc4oc5ccc(-c6ccc7c(c6)c6ccccc6n7-c6ccccc6)cc5c34)n2)cc1 ; c1ccc(-c2nc(-c3ccccc3)nc(-c3cccc4oc5cc(-c6ccc7c(c6)c6ccccc6n7-c6ccccc6)ccc5c34)n2)cc1 ; c1ccc(-c2nc(-c3ccccc3)nc(-c3cccc4oc5c(-c6ccc7c(c6)c6ccccc6n7-c6ccccc6)cccc5c34)n2)cc1]

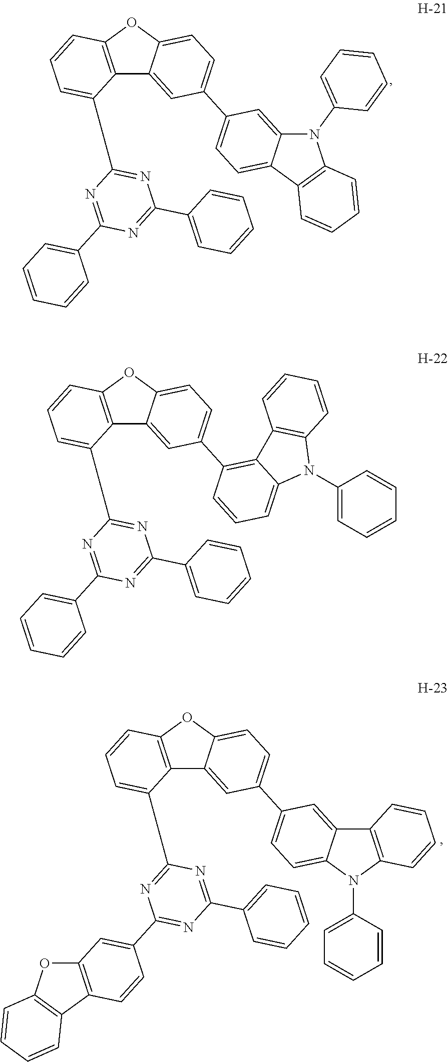 [SMILES: c1ccc(-c2nc(-c3ccccc3)nc(-c3cccc4oc5ccc(-c6ccc7c8ccccc8n(-c8ccccc8)c7c6)cc5c34)n2)cc1 ; c1ccc(-c2nc(-c3ccccc3)nc(-c3cccc4oc5ccc(-c6cccc7c6c6ccccc6n7-c6ccccc6)cc5c34)n2)cc1 ; c1ccc(-c2nc(-c3ccc4c(c3)oc3ccccc34)nc(-c3cccc4oc5ccc(-c6ccc7c(c6)c6ccccc6n7-c6ccccc6)cc5c34)n2)cc1]

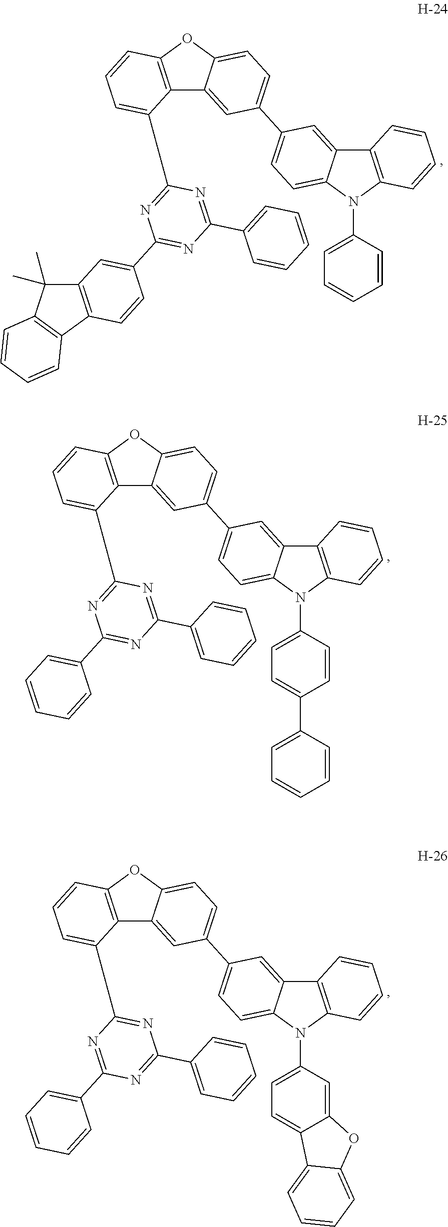 [SMILES: CC1(C)c2ccccc2-c2ccc(-c3nc(-c4ccccc4)nc(-c4cccc5oc6ccc(-c7ccc8c(c7)c7ccccc7n8-c7ccccc7)cc6c45)n3)cc21 ; c1ccc(-c2ccc(-n3c4ccccc4c4cc(-c5ccc6oc7cccc(-c8nc(-c9ccccc9)nc(-c9ccccc9)n8)c7c6c5)ccc43)cc2)cc1 ; c1ccc(-c2nc(-c3ccccc3)nc(-c3cccc4oc5ccc(-c6ccc7c(c6)c6ccccc6n7-c6ccc7c(c6)oc6ccccc67)cc5c34)n2)cc1]

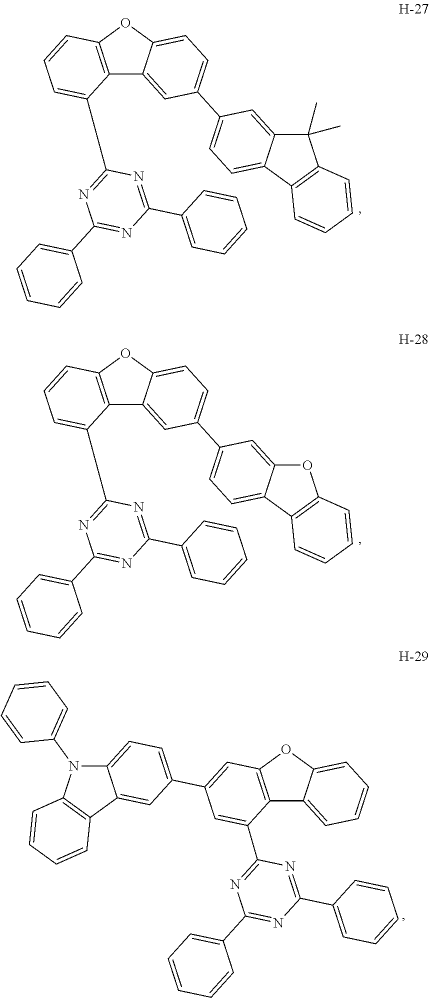

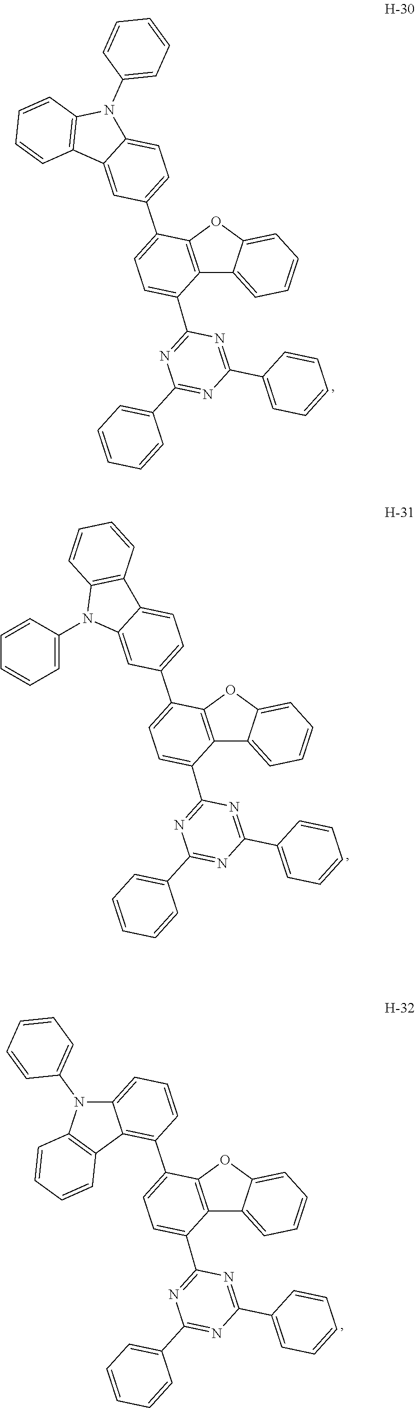 [SMILES: c1ccc(-c2nc(-c3ccccc3)nc(-c3ccc(-c4ccc5c(c4)c4ccccc4n5-c4ccccc4)c4oc5ccccc5c34)n2)cc1 ; c1ccc(-c2nc(-c3ccccc3)nc(-c3ccc(-c4ccc5c6ccccc6n(-c6ccccc6)c5c4)c4oc5ccccc5c34)n2)cc1 ; c1ccc(-c2nc(-c3ccccc3)nc(-c3ccc(-c4cccc5c4c4ccccc4n5-c4ccccc4)c4oc5ccccc5c34)n2)cc1]

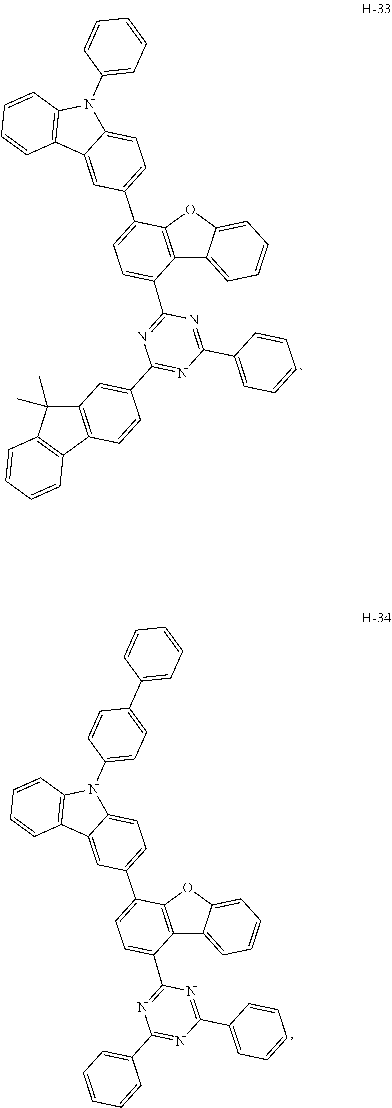 [SMILES: CC1(C)c2ccccc2-c2ccc(-c3nc(-c4ccccc4)nc(-c4ccc(-c5ccc6c(c5)c5ccccc5n6-c5ccccc5)c5oc6ccccc6c45)n3)cc21 ; c1ccc(-c2ccc(-n3c4ccccc4c4cc(-c5ccc(-c6nc(-c7ccccc7)nc(-c7ccccc7)n6)c6c5oc5ccccc56)ccc43)cc2)cc1]

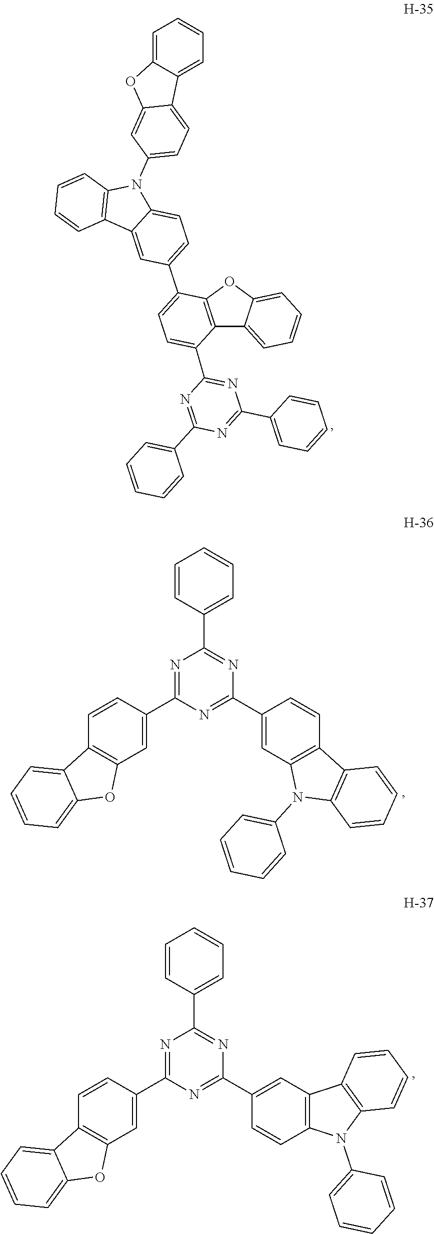 [SMILES: c1ccc(-c2nc(-c3ccccc3)nc(-c3ccc(-c4ccc5c(c4)c4ccccc4n5-c4ccc5c(c4)oc4ccccc45)c4oc5ccccc5c34)n2)cc1 ; c1ccc(-c2nc(-c3ccc4c(c3)oc3ccccc34)nc(-c3ccc4c5ccccc5n(-c5ccccc5)c4c3)n2)cc1 ; c1ccc(-c2nc(-c3ccc4c(c3)oc3ccccc34)nc(-c3ccc4c(c3)c3ccccc3n4-c3ccccc3)n2)cc1]

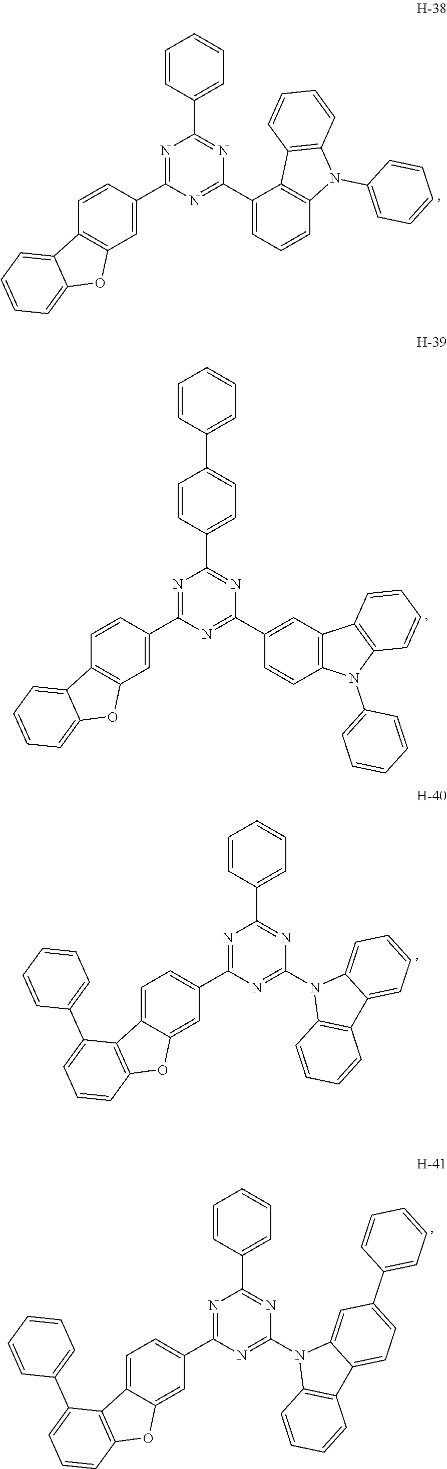 [SMILES: c1ccc(-c2nc(-c3ccc4c(c3)oc3ccccc34)nc(-c3cccc4c3c3ccccc3n4-c3ccccc3)n2)cc1 ; c1ccc(-c2ccc(-c3nc(-c4ccc5c(c4)oc4ccccc45)nc(-c4ccc5c(c4)c4ccccc4n5-c4ccccc4)n3)cc2)cc1 ; c1ccc(-c2nc(-c3ccc4c(c3)oc3cccc(-c5ccccc5)c34)nc(-n3c4ccccc4c4ccccc43)n2)cc1 ; c1ccc(-c2ccc3c4ccccc4n(-c4nc(-c5ccccc5)nc(-c5ccc6c(c5)oc5cccc(-c7ccccc7)c56)n4)c3c2)cc1]

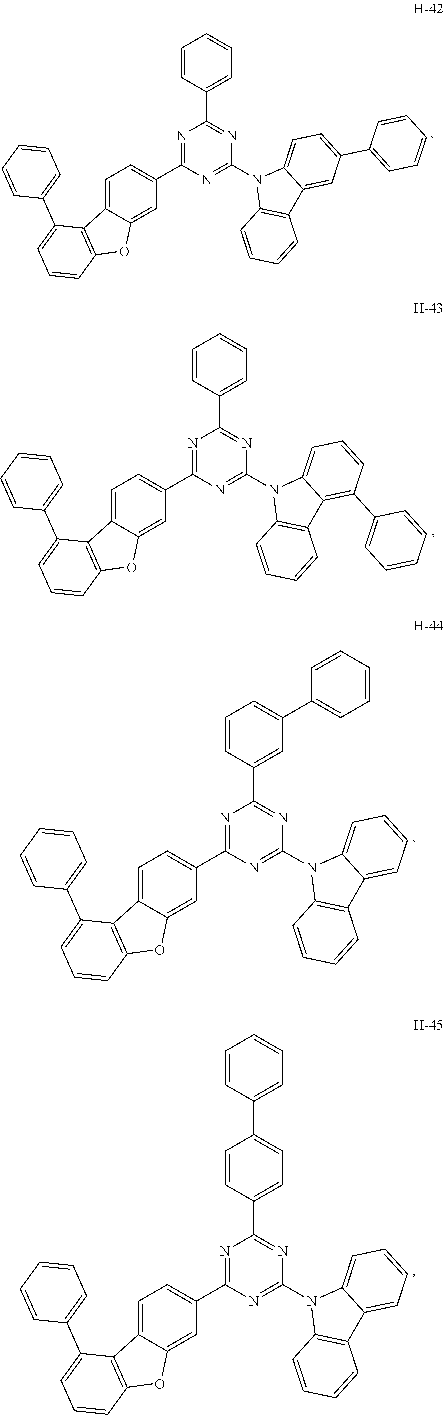 [SMILES: c1ccc(-c2ccc3c(c2)c2ccccc2n3-c2nc(-c3ccccc3)nc(-c3ccc4c(c3)oc3cccc(-c5ccccc5)c34)n2)cc1 ; c1ccc(-c2nc(-c3ccc4c(c3)oc3cccc(-c5ccccc5)c34)nc(-n3c4ccccc4c4c(-c5ccccc5)cccc43)n2)cc1 ; c1ccc(-c2cccc(-c3nc(-c4ccc5c(c4)oc4cccc(-c6ccccc6)c45)nc(-n4c5ccccc5c5ccccc54)n3)c2)cc1 ; c1ccc(-c2ccc(-c3nc(-c4ccc5c(c4)oc4cccc(-c6ccccc6)c45)nc(-n4c5ccccc5c5ccccc54)n3)cc2)cc1]

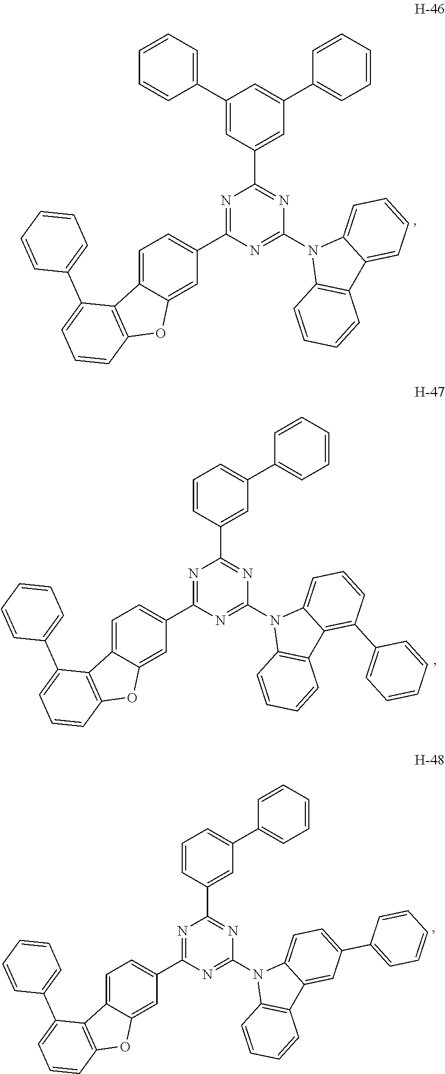 [SMILES: c1ccc(-c2cc(-c3ccccc3)cc(-c3nc(-c4ccc5c(c4)oc4cccc(-c6ccccc6)c45)nc(-n4c5ccccc5c5ccccc54)n3)c2)cc1 ; c1ccc(-c2cccc(-c3nc(-c4ccc5c(c4)oc4cccc(-c6ccccc6)c45)nc(-n4c5ccccc5c5c(-c6ccccc6)cccc54)n3)c2)cc1 ; c1ccc(-c2cccc(-c3nc(-c4ccc5c(c4)oc4cccc(-c6ccccc6)c45)nc(-n4c5ccccc5c5cc(-c6ccccc6)ccc54)n3)c2)cc1]

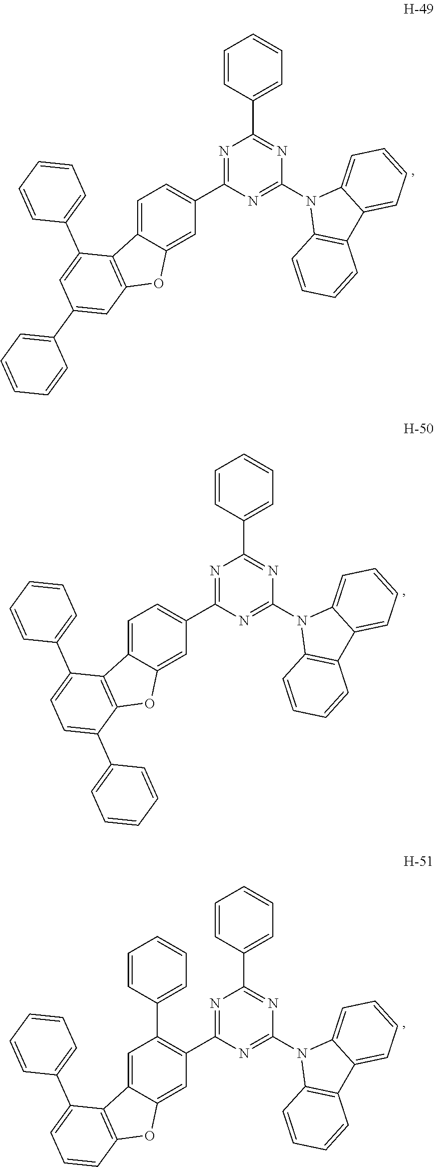 [SMILES: c1ccc(-c2cc(-c3ccccc3)c3c(c2)oc2cc(-c4nc(-c5ccccc5)nc(-n5c6ccccc6c6ccccc65)n4)ccc23)cc1 ; c1ccc(-c2nc(-c3ccc4c(c3)oc3c(-c5ccccc5)ccc(-c5ccccc5)c34)nc(-n3c4ccccc4c4ccccc43)n2)cc1 ; c1ccc(-c2nc(-c3cc4oc5cccc(-c6ccccc6)c5c4cc3-c3ccccc3)nc(-n3c4ccccc4c4ccccc43)n2)cc1]

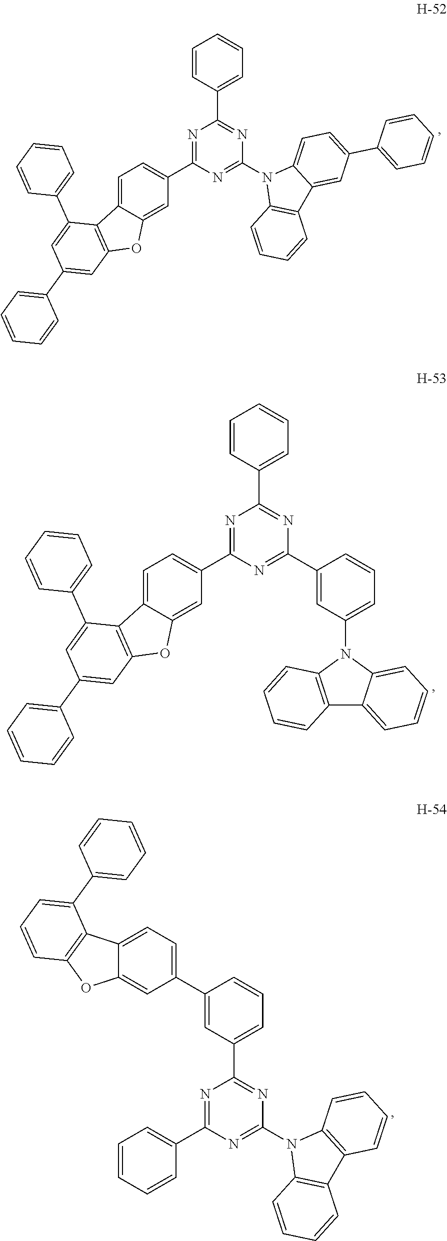 [SMILES: c1ccc(-c2cc(-c3ccccc3)c3c(c2)oc2cc(-c4nc(-c5ccccc5)nc(-n5c6ccccc6c6cc(-c7ccccc7)ccc65)n4)ccc23)cc1 ; c1ccc(-c2cc(-c3ccccc3)c3c(c2)oc2cc(-c4nc(-c5ccccc5)nc(-c5cccc(-n6c7ccccc7c7ccccc76)c5)n4)ccc23)cc1 ; c1ccc(-c2nc(-c3cccc(-c4ccc5c(c4)oc4cccc(-c6ccccc6)c45)c3)nc(-n3c4ccccc4c4ccccc43)n2)cc1]

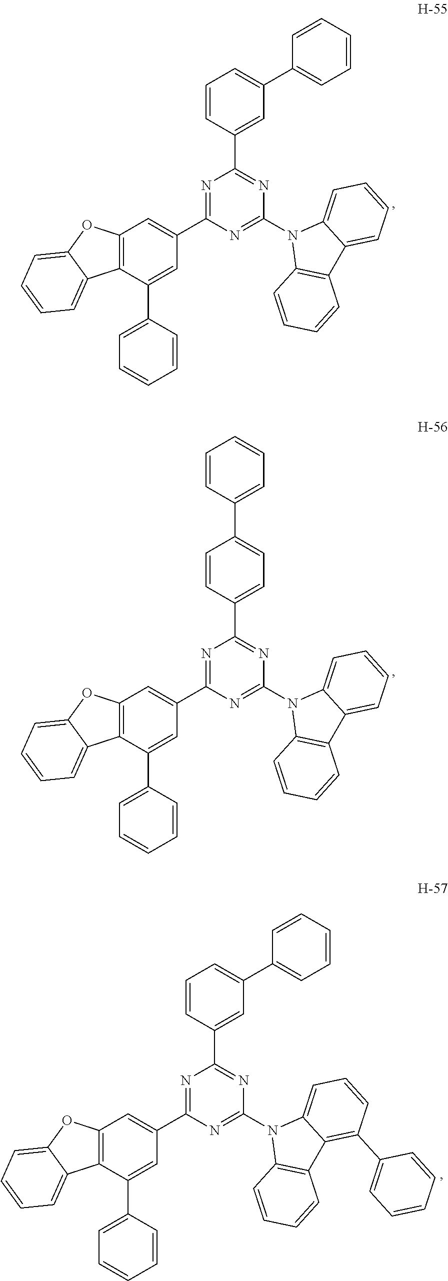 [SMILES: c1ccc(-c2cccc(-c3nc(-c4cc(-c5ccccc5)c5c(c4)oc4ccccc45)nc(-n4c5ccccc5c5ccccc54)n3)c2)cc1 ; c1ccc(-c2ccc(-c3nc(-c4cc(-c5ccccc5)c5c(c4)oc4ccccc45)nc(-n4c5ccccc5c5ccccc54)n3)cc2)cc1 ; c1ccc(-c2cccc(-c3nc(-c4cc(-c5ccccc5)c5c(c4)oc4ccccc45)nc(-n4c5ccccc5c5c(-c6ccccc6)cccc54)n3)c2)cc1]

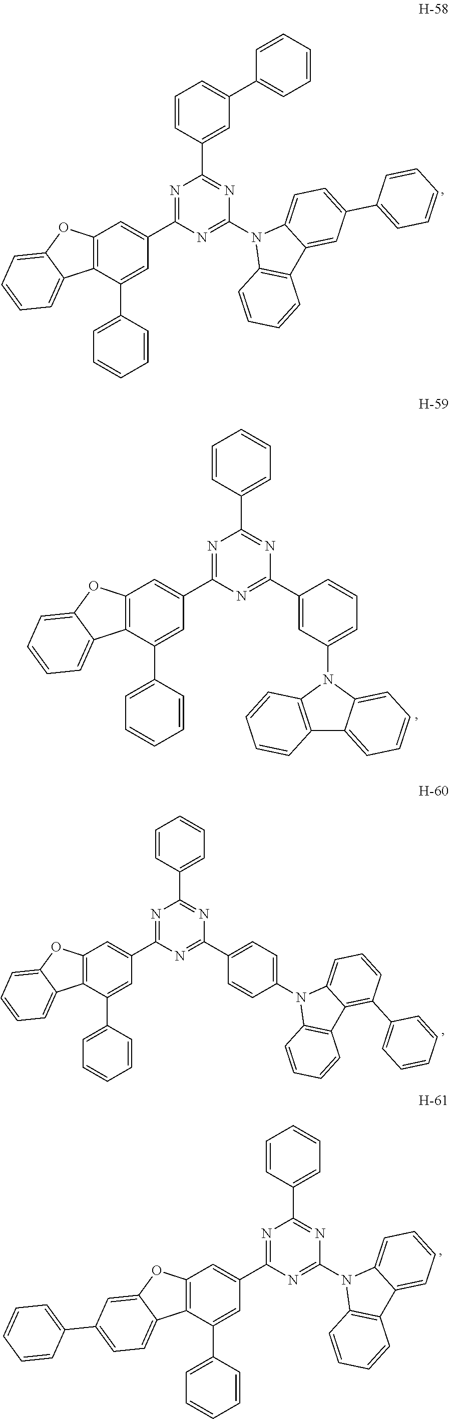 [SMILES: c1ccc(-c2cccc(-c3nc(-c4cc(-c5ccccc5)c5c(c4)oc4ccccc45)nc(-n4c5ccccc5c5cc(-c6ccccc6)ccc54)n3)c2)cc1 ; c1ccc(-c2nc(-c3cccc(-n4c5ccccc5c5ccccc54)c3)nc(-c3cc(-c4ccccc4)c4c(c3)oc3ccccc34)n2)cc1 ; c1ccc(-c2nc(-c3ccc(-n4c5ccccc5c5c(-c6ccccc6)cccc54)cc3)nc(-c3cc(-c4ccccc4)c4c(c3)oc3ccccc34)n2)cc1 ; c1ccc(-c2ccc3c(c2)oc2cc(-c4nc(-c5ccccc5)nc(-n5c6ccccc6c6ccccc65)n4)cc(-c4ccccc4)c23)cc1]

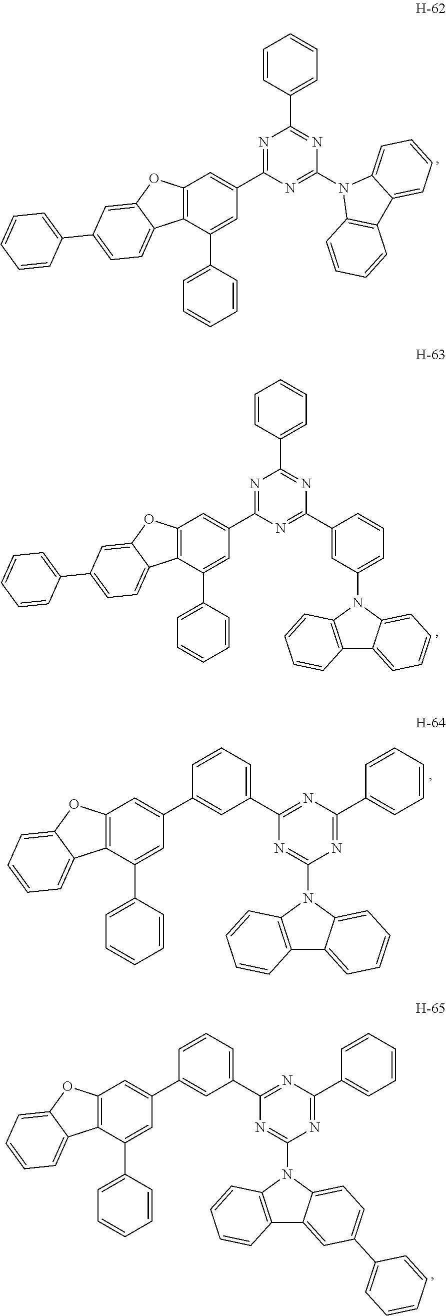 [SMILES: c1ccc(-c2ccc3c(c2)oc2cc(-c4nc(-c5ccccc5)nc(-n5c6ccccc6c6ccccc65)n4)cc(-c4ccccc4)c23)cc1 ; c1ccc(-c2ccc3c(c2)oc2cc(-c4nc(-c5ccccc5)nc(-c5cccc(-n6c7ccccc7c7ccccc76)c5)n4)cc(-c4ccccc4)c23)cc1 ; c1ccc(-c2nc(-c3cccc(-c4cc(-c5ccccc5)c5c(c4)oc4ccccc45)c3)nc(-n3c4ccccc4c4ccccc43)n2)cc1 ; c1ccc(-c2ccc3c(c2)c2ccccc2n3-c2nc(-c3ccccc3)nc(-c3cccc(-c4cc(-c5ccccc5)c5c(c4)oc4ccccc45)c3)n2)cc1]

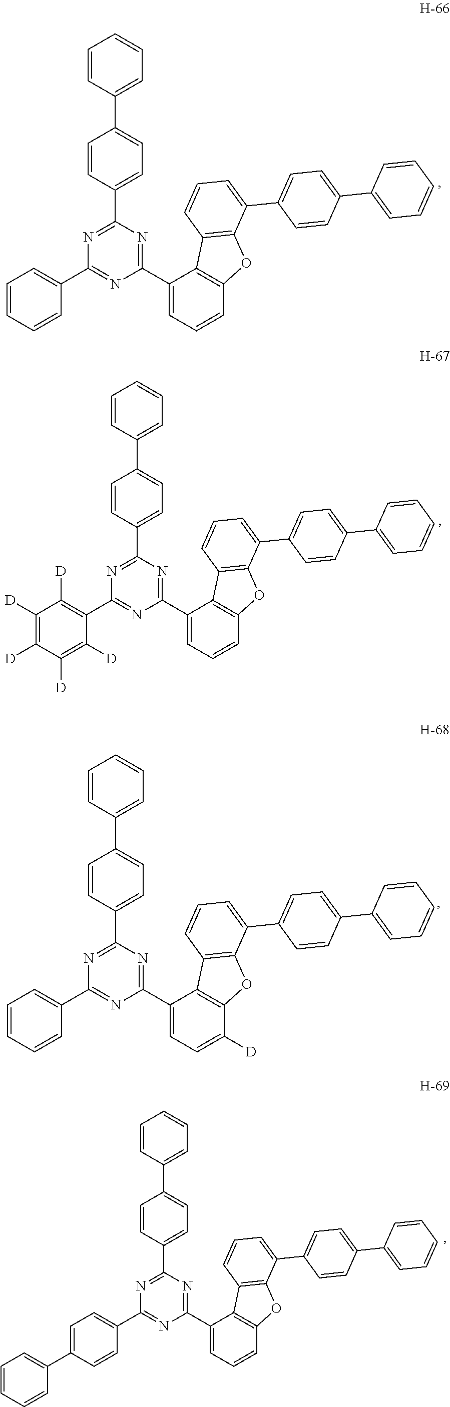 [SMILES: c1ccc(-c2ccc(-c3nc(-c4ccccc4)nc(-c4cccc5oc6c(-c7ccc(-c8ccccc8)cc7)cccc6c45)n3)cc2)cc1 ; [2H]c1c([2H])c([2H])c(-c2nc(-c3ccc(-c4ccccc4)cc3)nc(-c3cccc4oc5c(-c6ccc(-c7ccccc7)cc6)cccc5c34)n2)c([2H])c1[2H] ; [2H]c1ccc(-c2nc(-c3ccccc3)nc(-c3ccc(-c4ccccc4)cc3)n2)c2c1oc1c(-c3ccc(-c4ccccc4)cc3)cccc12 ; c1ccc(-c2ccc(-c3nc(-c4ccc(-c5ccccc5)cc4)nc(-c4cccc5oc6c(-c7ccc(-c8ccccc8)cc7)cccc6c45)n3)cc2)cc1]

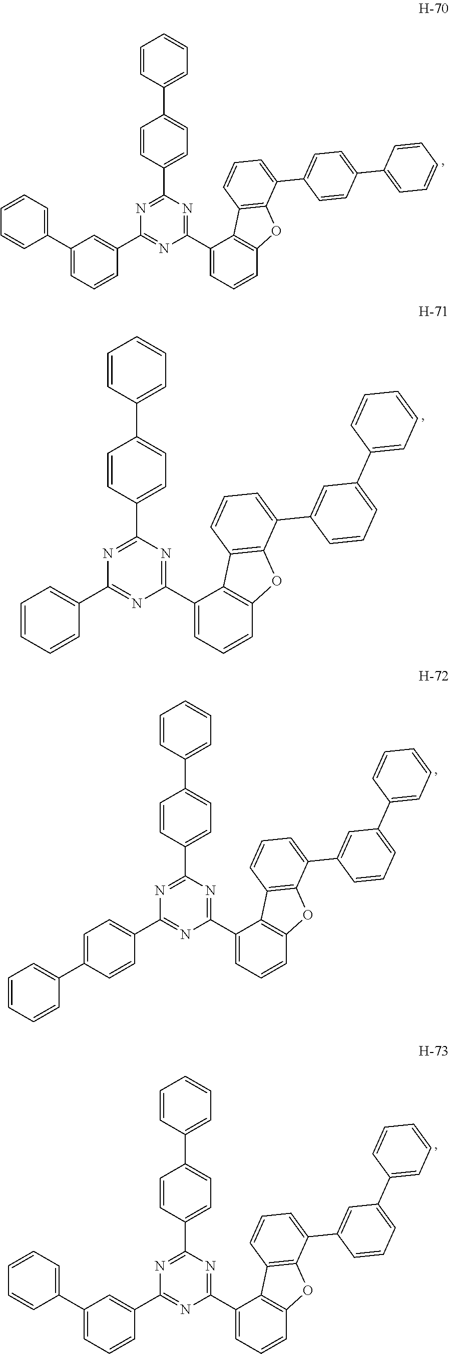 [SMILES: c1ccc(-c2ccc(-c3nc(-c4cccc(-c5ccccc5)c4)nc(-c4cccc5oc6c(-c7ccc(-c8ccccc8)cc7)cccc6c45)n3)cc2)cc1 ; c1ccc(-c2ccc(-c3nc(-c4ccccc4)nc(-c4cccc5oc6c(-c7cccc(-c8ccccc8)c7)cccc6c45)n3)cc2)cc1 ; c1ccc(-c2ccc(-c3nc(-c4ccc(-c5ccccc5)cc4)nc(-c4cccc5oc6c(-c7cccc(-c8ccccc8)c7)cccc6c45)n3)cc2)cc1 ; c1ccc(-c2ccc(-c3nc(-c4cccc(-c5ccccc5)c4)nc(-c4cccc5oc6c(-c7cccc(-c8ccccc8)c7)cccc6c45)n3)cc2)cc1]

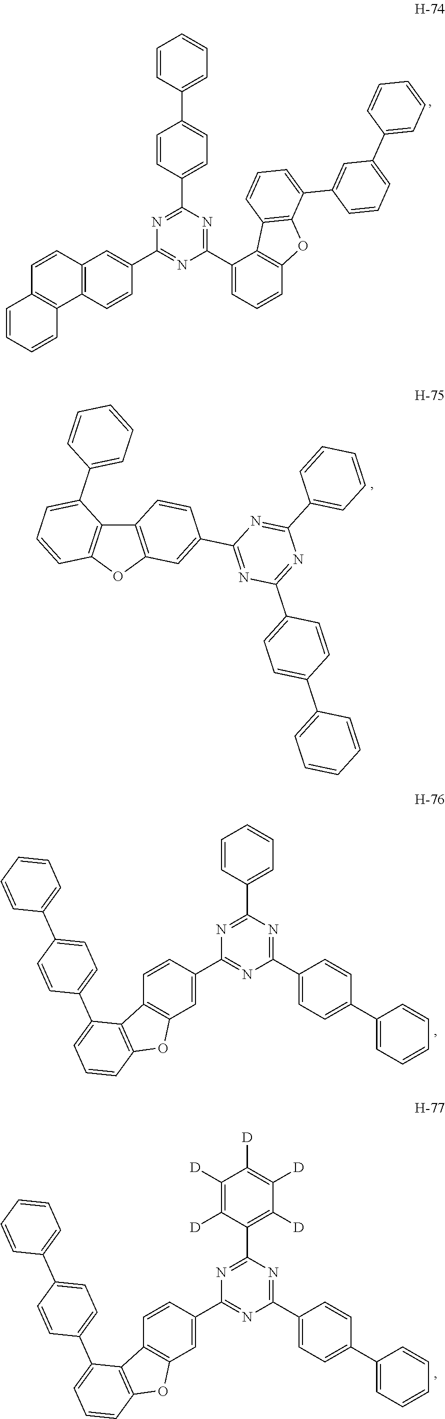 [SMILES: c1ccc(-c2ccc(-c3nc(-c4ccc5c(ccc6ccccc65)c4)nc(-c4cccc5oc6c(-c7cccc(-c8ccccc8)c7)cccc6c45)n3)cc2)cc1 ; c1ccc(-c2ccc(-c3nc(-c4ccccc4)nc(-c4ccc5c(c4)oc4cccc(-c6ccccc6)c45)n3)cc2)cc1 ; c1ccc(-c2ccc(-c3nc(-c4ccccc4)nc(-c4ccc5c(c4)oc4cccc(-c6ccc(-c7ccccc7)cc6)c45)n3)cc2)cc1 ; [2H]c1c([2H])c([2H])c(-c2nc(-c3ccc(-c4ccccc4)cc3)nc(-c3ccc4c(c3)oc3cccc(-c5ccc(-c6ccccc6)cc5)c34)n2)c([2H])c1[2H]]

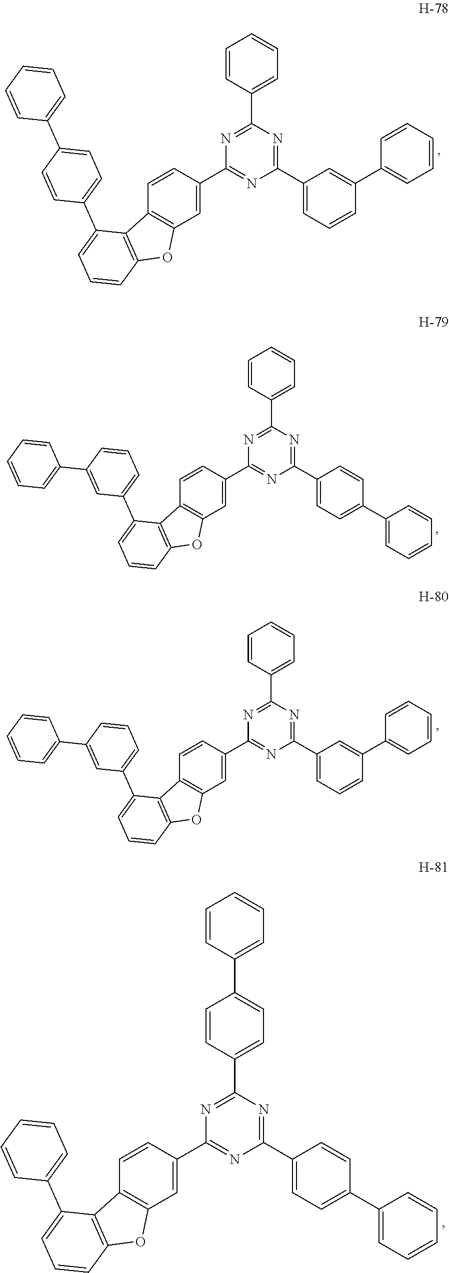 [SMILES: c1ccc(-c2ccc(-c3cccc4oc5cc(-c6nc(-c7ccccc7)nc(-c7cccc(-c8ccccc8)c7)n6)ccc5c34)cc2)cc1 ; c1ccc(-c2ccc(-c3nc(-c4ccccc4)nc(-c4ccc5c(c4)oc4cccc(-c6cccc(-c7ccccc7)c6)c45)n3)cc2)cc1 ; c1ccc(-c2cccc(-c3nc(-c4ccccc4)nc(-c4ccc5c(c4)oc4cccc(-c6cccc(-c7ccccc7)c6)c45)n3)c2)cc1 ; c1ccc(-c2ccc(-c3nc(-c4ccc(-c5ccccc5)cc4)nc(-c4ccc5c(c4)oc4cccc(-c6ccccc6)c45)n3)cc2)cc1]

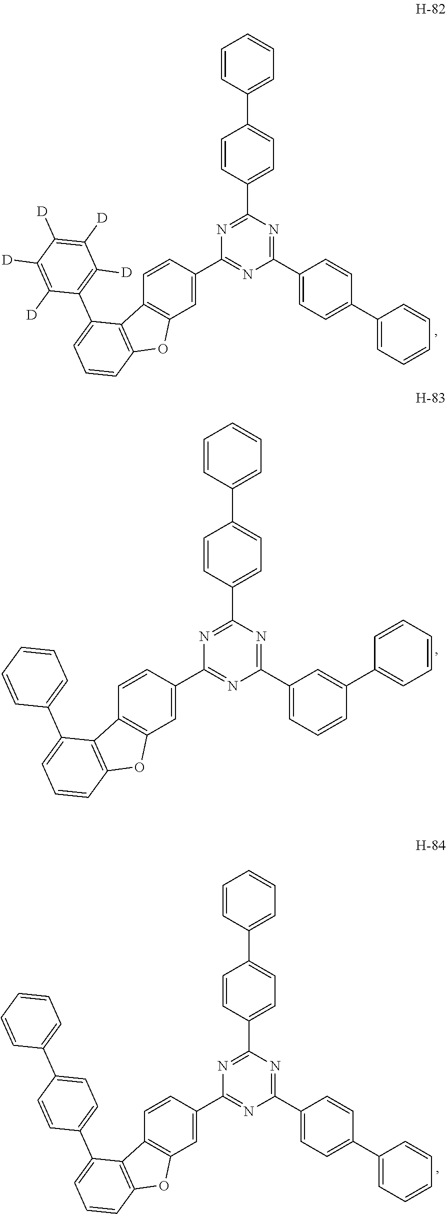 [SMILES: [2H]c1c([2H])c([2H])c(-c2cccc3oc4cc(-c5nc(-c6ccc(-c7ccccc7)cc6)nc(-c6ccc(-c7ccccc7)cc6)n5)ccc4c23)c([2H])c1[2H] ; c1ccc(-c2ccc(-c3nc(-c4cccc(-c5ccccc5)c4)nc(-c4ccc5c(c4)oc4cccc(-c6ccccc6)c45)n3)cc2)cc1 ; c1ccc(-c2ccc(-c3nc(-c4ccc(-c5ccccc5)cc4)nc(-c4ccc5c(c4)oc4cccc(-c6ccc(-c7ccccc7)cc6)c45)n3)cc2)cc1]

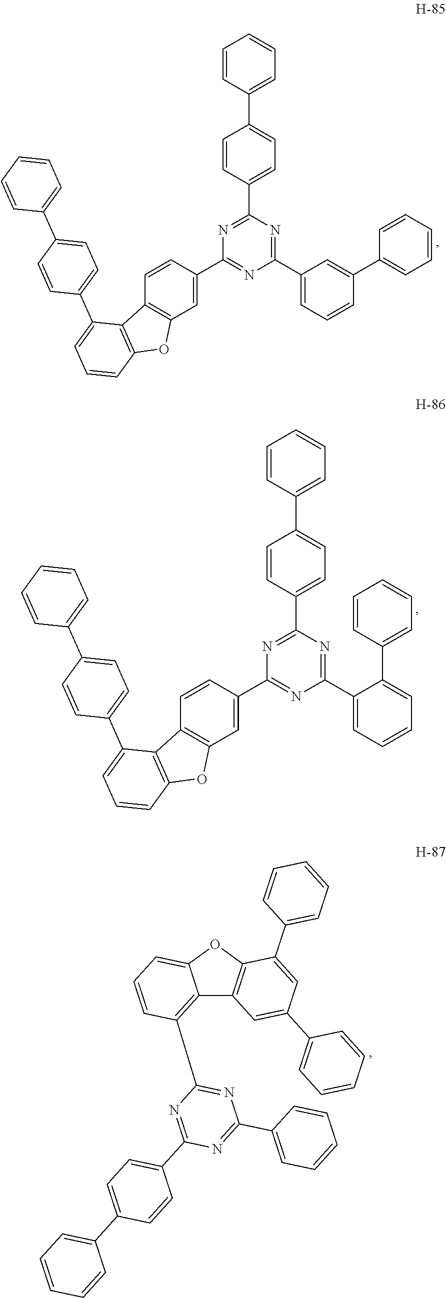 [SMILES: c1ccc(-c2ccc(-c3nc(-c4cccc(-c5ccccc5)c4)nc(-c4ccc5c(c4)oc4cccc(-c6ccc(-c7ccccc7)cc6)c45)n3)cc2)cc1 ; c1ccc(-c2ccc(-c3nc(-c4ccc5c(c4)oc4cccc(-c6ccc(-c7ccccc7)cc6)c45)nc(-c4ccccc4-c4ccccc4)n3)cc2)cc1 ; c1ccc(-c2ccc(-c3nc(-c4ccccc4)nc(-c4cccc5oc6c(-c7ccccc7)cc(-c7ccccc7)cc6c45)n3)cc2)cc1]

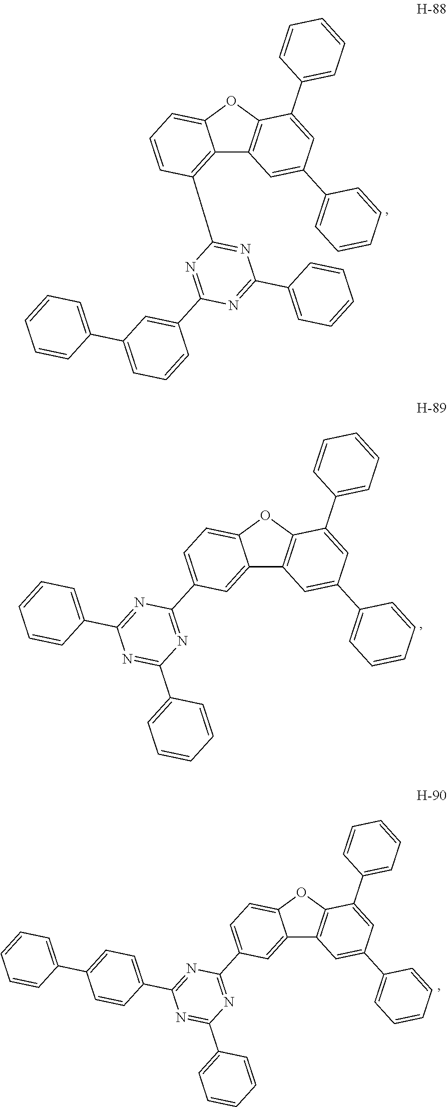 [SMILES: c1ccc(-c2cccc(-c3nc(-c4ccccc4)nc(-c4cccc5oc6c(-c7ccccc7)cc(-c7ccccc7)cc6c45)n3)c2)cc1 ; c1ccc(-c2cc(-c3ccccc3)c3oc4ccc(-c5nc(-c6ccccc6)nc(-c6ccccc6)n5)cc4c3c2)cc1 ; c1ccc(-c2ccc(-c3nc(-c4ccccc4)nc(-c4ccc5oc6c(-c7ccccc7)cc(-c7ccccc7)cc6c5c4)n3)cc2)cc1]

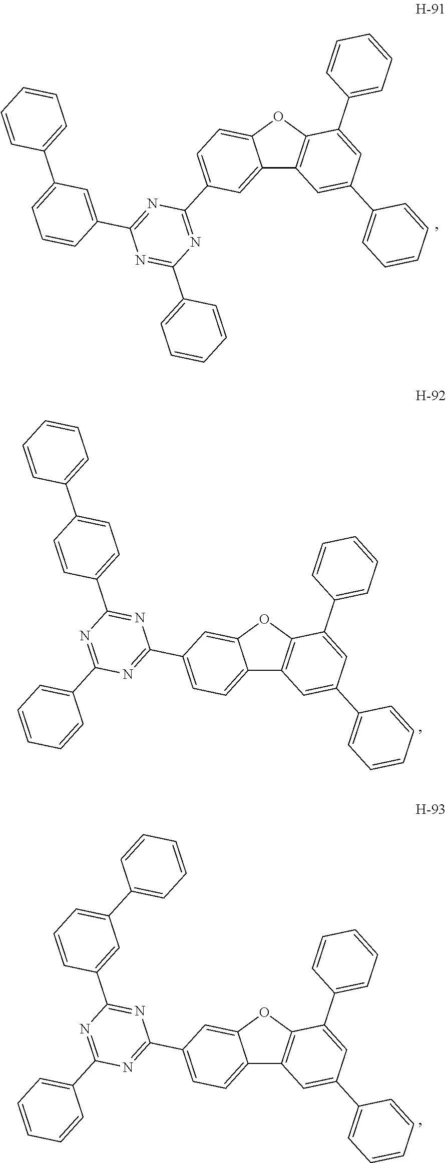 [SMILES: c1ccc(-c2cccc(-c3nc(-c4ccccc4)nc(-c4ccc5oc6c(-c7ccccc7)cc(-c7ccccc7)cc6c5c4)n3)c2)cc1 ; c1ccc(-c2ccc(-c3nc(-c4ccccc4)nc(-c4ccc5c(c4)oc4c(-c6ccccc6)cc(-c6ccccc6)cc45)n3)cc2)cc1 ; c1ccc(-c2cccc(-c3nc(-c4ccccc4)nc(-c4ccc5c(c4)oc4c(-c6ccccc6)cc(-c6ccccc6)cc45)n3)c2)cc1]

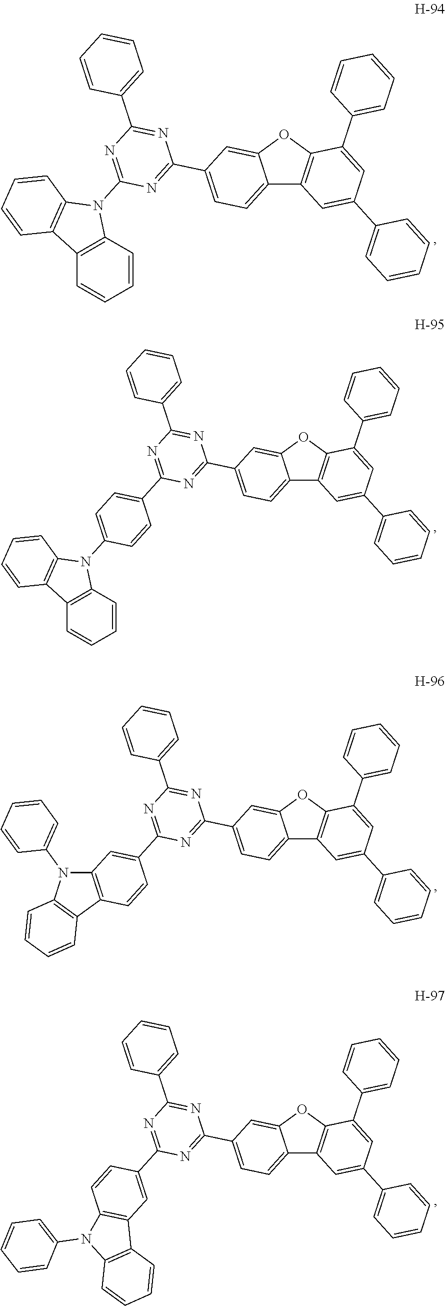 [SMILES: c1ccc(-c2cc(-c3ccccc3)c3oc4cc(-c5nc(-c6ccccc6)nc(-n6c7ccccc7c7ccccc76)n5)ccc4c3c2)cc1 ; c1ccc(-c2cc(-c3ccccc3)c3oc4cc(-c5nc(-c6ccccc6)nc(-c6ccc(-n7c8ccccc8c8ccccc87)cc6)n5)ccc4c3c2)cc1 ; c1ccc(-c2cc(-c3ccccc3)c3oc4cc(-c5nc(-c6ccccc6)nc(-c6ccc7c8ccccc8n(-c8ccccc8)c7c6)n5)ccc4c3c2)cc1 ; c1ccc(-c2cc(-c3ccccc3)c3oc4cc(-c5nc(-c6ccccc6)nc(-c6ccc7c(c6)c6ccccc6n7-c6ccccc6)n5)ccc4c3c2)cc1]

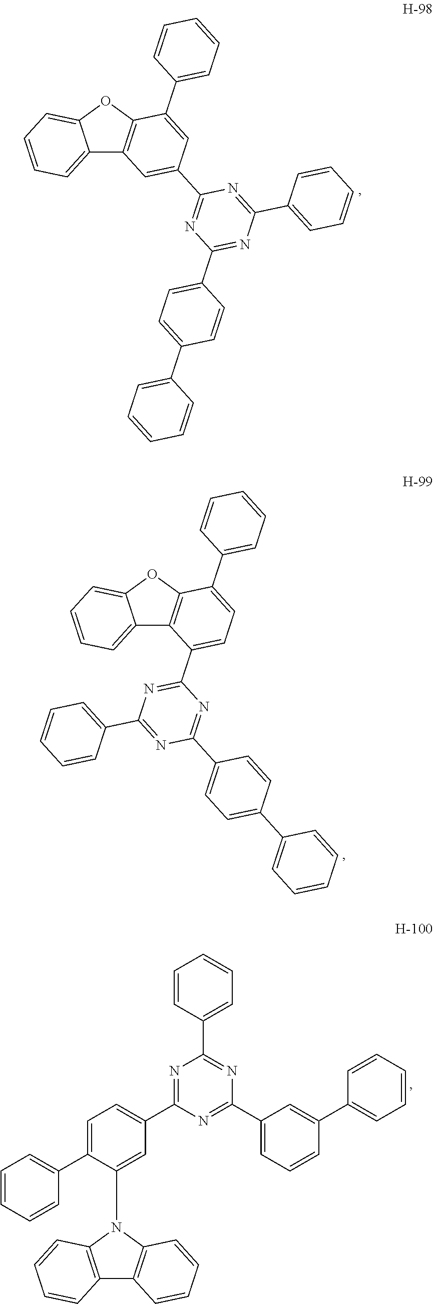 [SMILES: c1ccc(-c2ccc(-c3nc(-c4ccccc4)nc(-c4cc(-c5ccccc5)c5oc6ccccc6c5c4)n3)cc2)cc1 ; c1ccc(-c2ccc(-c3nc(-c4ccccc4)nc(-c4ccc(-c5ccccc5)c5oc6ccccc6c45)n3)cc2)cc1 ; c1ccc(-c2cccc(-c3nc(-c4ccccc4)nc(-c4ccc(-c5ccccc5)c(-n5c6ccccc6c6ccccc65)c4)n3)c2)cc1]

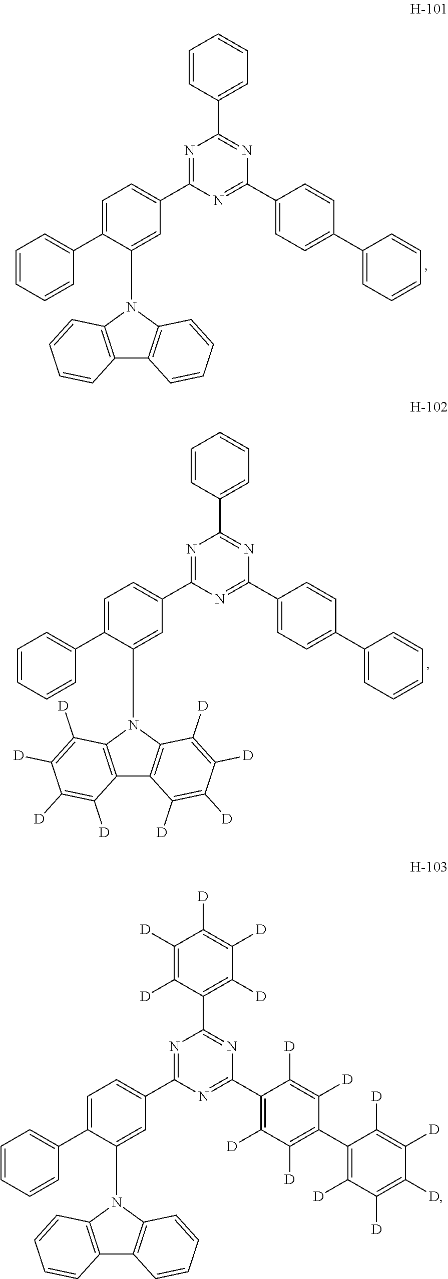

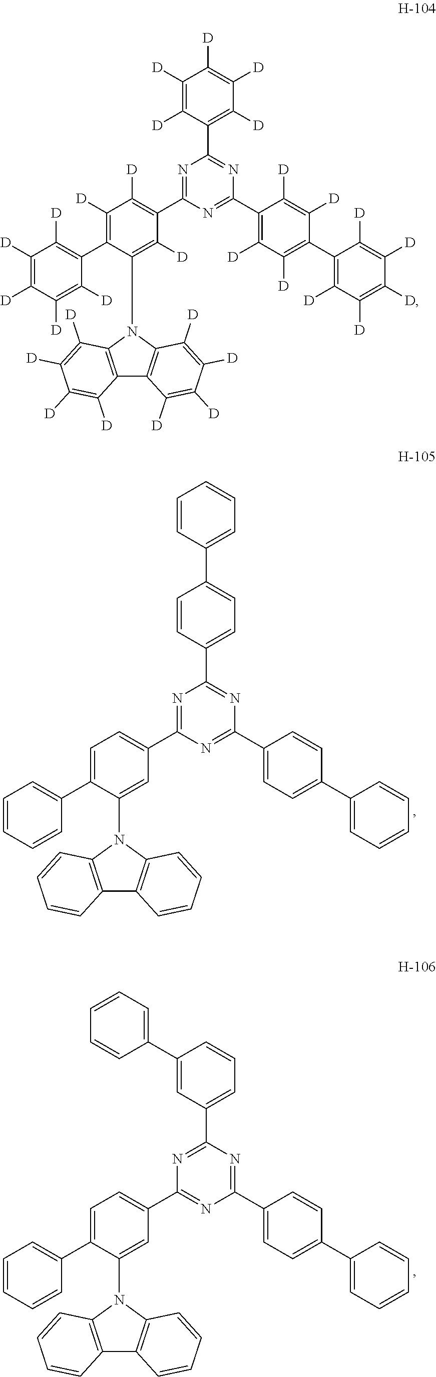

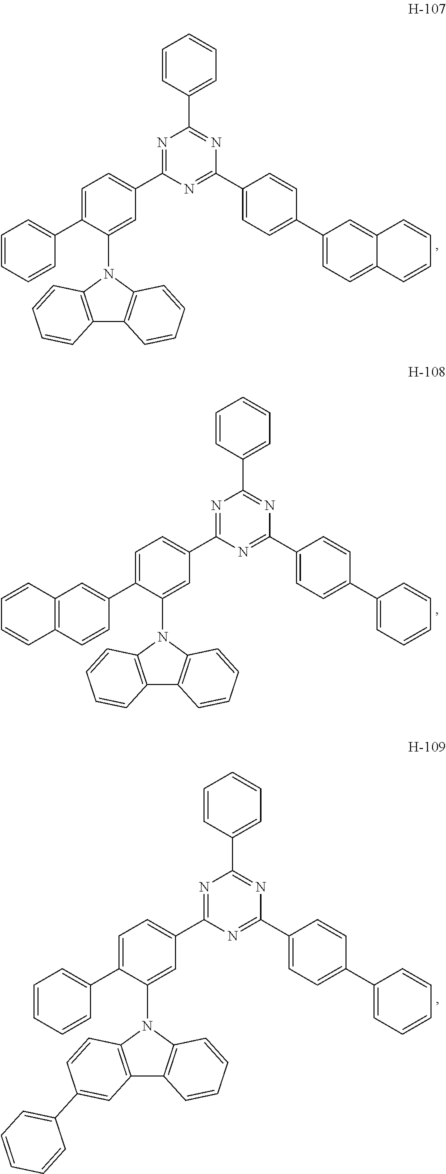 [SMILES: c1ccc(-c2nc(-c3ccc(-c4ccc5ccccc5c4)cc3)nc(-c3ccc(-c4ccccc4)c(-n4c5ccccc5c5ccccc54)c3)n2)cc1 ; c1ccc(-c2ccc(-c3nc(-c4ccccc4)nc(-c4ccc(-c5ccc6ccccc6c5)c(-n5c6ccccc6c6ccccc65)c4)n3)cc2)cc1 ; c1ccc(-c2ccc(-c3nc(-c4ccccc4)nc(-c4ccc(-c5ccccc5)c(-n5c6ccccc6c6cc(-c7ccccc7)ccc65)c4)n3)cc2)cc1]

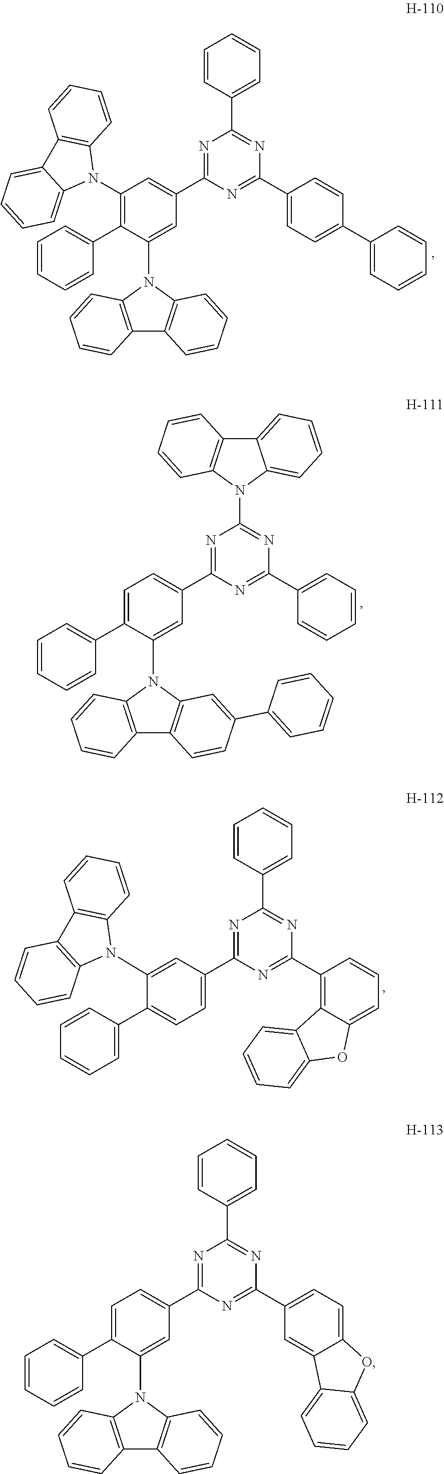 [SMILES: c1ccc(-c2ccc(-c3nc(-c4ccccc4)nc(-c4cc(-n5c6ccccc6c6ccccc65)c(-c5ccccc5)c(-n5c6ccccc6c6ccccc65)c4)n3)cc2)cc1 ; c1ccc(-c2ccc3c4ccccc4n(-c4cc(-c5nc(-c6ccccc6)nc(-n6c7ccccc7c7ccccc76)n5)ccc4-c4ccccc4)c3c2)cc1 ; c1ccc(-c2nc(-c3ccc(-c4ccccc4)c(-n4c5ccccc5c5ccccc54)c3)nc(-c3cccc4oc5ccccc5c34)n2)cc1 ; c1ccc(-c2nc(-c3ccc(-c4ccccc4)c(-n4c5ccccc5c5ccccc54)c3)nc(-c3ccc4oc5ccccc5c4c3)n2)cc1]

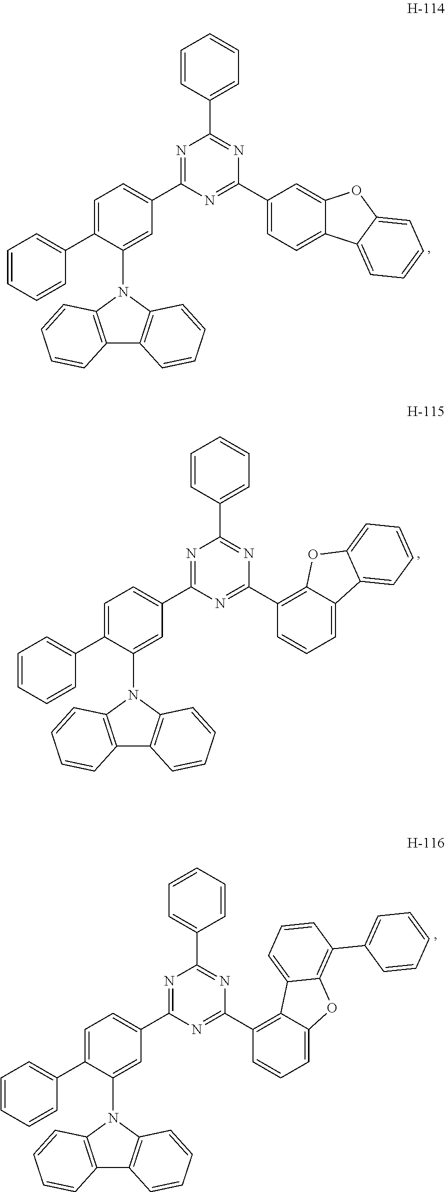 [SMILES: c1ccc(-c2nc(-c3ccc(-c4ccccc4)c(-n4c5ccccc5c5ccccc54)c3)nc(-c3ccc4c(c3)oc3ccccc34)n2)cc1 ; c1ccc(-c2nc(-c3ccc(-c4ccccc4)c(-n4c5ccccc5c5ccccc54)c3)nc(-c3cccc4c3oc3ccccc34)n2)cc1 ; c1ccc(-c2nc(-c3ccc(-c4ccccc4)c(-n4c5ccccc5c5ccccc54)c3)nc(-c3cccc4oc5c(-c6ccccc6)cccc5c34)n2)cc1]

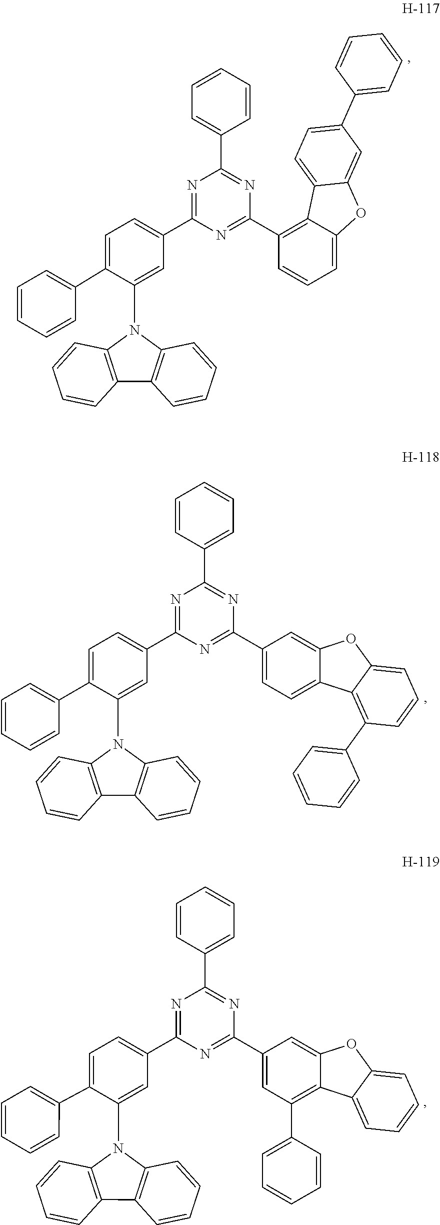 [SMILES: c1ccc(-c2ccc3c(c2)oc2cccc(-c4nc(-c5ccccc5)nc(-c5ccc(-c6ccccc6)c(-n6c7ccccc7c7ccccc76)c5)n4)c23)cc1 ; c1ccc(-c2nc(-c3ccc(-c4ccccc4)c(-n4c5ccccc5c5ccccc54)c3)nc(-c3ccc4c(c3)oc3cccc(-c5ccccc5)c34)n2)cc1 ; c1ccc(-c2nc(-c3ccc(-c4ccccc4)c(-n4c5ccccc5c5ccccc54)c3)nc(-c3cc(-c4ccccc4)c4c(c3)oc3ccccc34)n2)cc1]

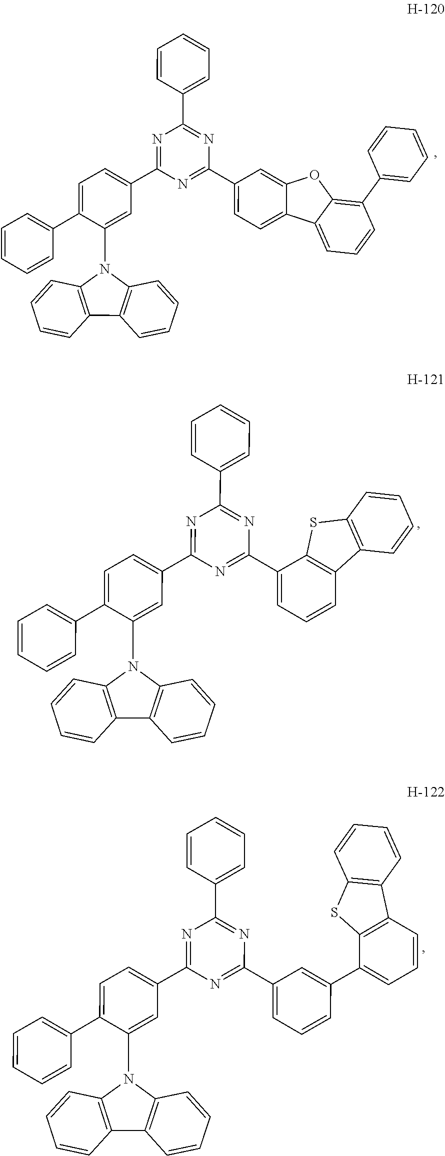 [SMILES: c1ccc(-c2nc(-c3ccc(-c4ccccc4)c(-n4c5ccccc5c5ccccc54)c3)nc(-c3ccc4c(c3)oc3c(-c5ccccc5)cccc34)n2)cc1 ; c1ccc(-c2nc(-c3ccc(-c4ccccc4)c(-n4c5ccccc5c5ccccc54)c3)nc(-c3cccc4c3sc3ccccc34)n2)cc1 ; c1ccc(-c2nc(-c3cccc(-c4cccc5c4sc4ccccc45)c3)nc(-c3ccc(-c4ccccc4)c(-n4c5ccccc5c5ccccc54)c3)n2)cc1]

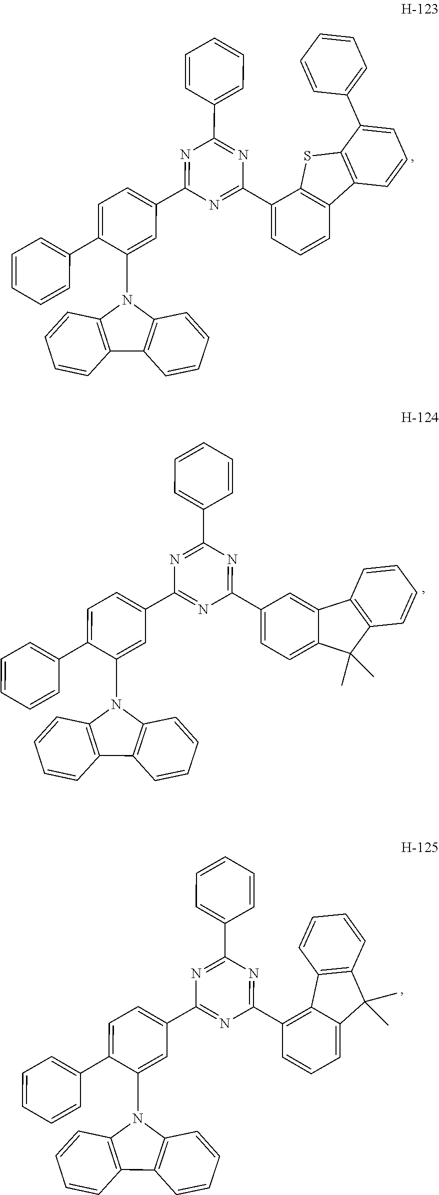 [SMILES: c1ccc(-c2nc(-c3ccc(-c4ccccc4)c(-n4c5ccccc5c5ccccc54)c3)nc(-c3cccc4c3sc3c(-c5ccccc5)cccc34)n2)cc1 ; CC1(C)c2ccccc2-c2cc(-c3nc(-c4ccccc4)nc(-c4ccc(-c5ccccc5)c(-n5c6ccccc6c6ccccc65)c4)n3)ccc21 ; CC1(C)c2ccccc2-c2c(-c3nc(-c4ccccc4)nc(-c4ccc(-c5ccccc5)c(-n5c6ccccc6c6ccccc65)c4)n3)cccc21]

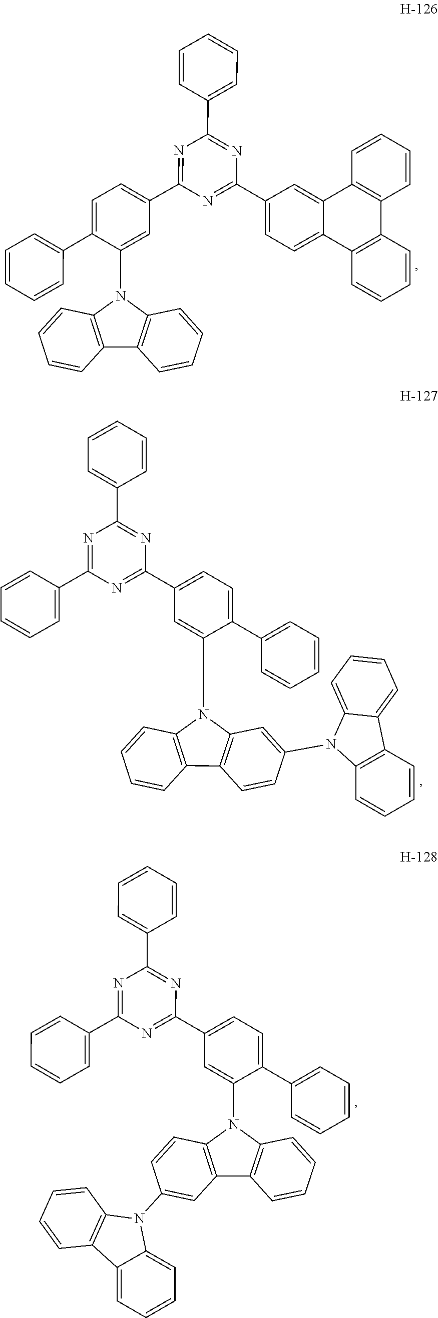 [SMILES: c1ccc(-c2nc(-c3ccc(-c4ccccc4)c(-n4c5ccccc5c5ccccc54)c3)nc(-c3ccc4c5ccccc5c5ccccc5c4c3)n2)cc1 ; c1ccc(-c2nc(-c3ccccc3)nc(-c3ccc(-c4ccccc4)c(-n4c5ccccc5c5ccc(-n6c7ccccc7c7ccccc76)cc54)c3)n2)cc1 ; c1ccc(-c2nc(-c3ccccc3)nc(-c3ccc(-c4ccccc4)c(-n4c5ccccc5c5cc(-n6c7ccccc7c7ccccc76)ccc54)c3)n2)cc1]

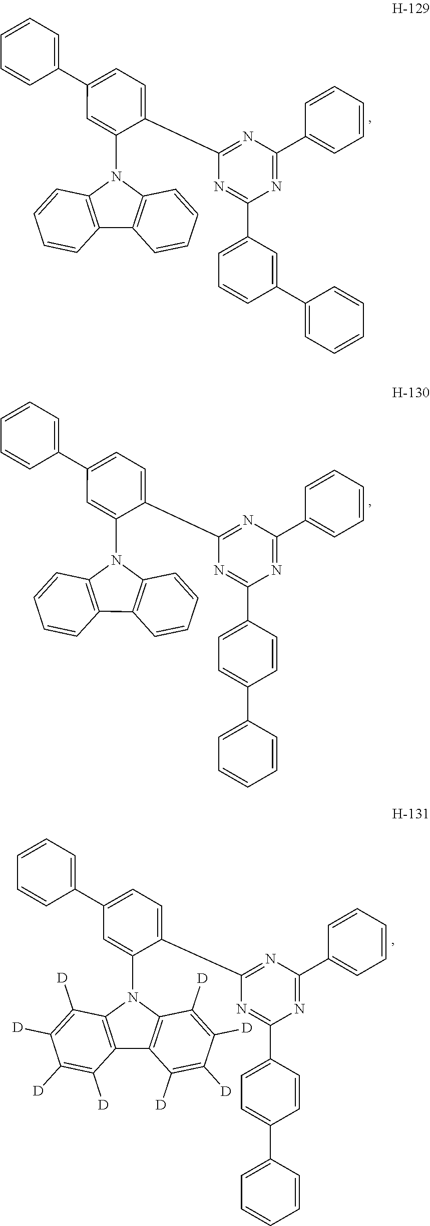 [SMILES: c1ccc(-c2cccc(-c3nc(-c4ccccc4)nc(-c4ccc(-c5ccccc5)cc4-n4c5ccccc5c5ccccc54)n3)c2)cc1 ; c1ccc(-c2ccc(-c3nc(-c4ccccc4)nc(-c4ccc(-c5ccccc5)cc4-n4c5ccccc5c5ccccc54)n3)cc2)cc1 ; [2H]c1c([2H])c([2H])c2c(c1[2H])c1c([2H])c([2H])c([2H])c([2H])c1n2-c1cc(-c2ccccc2)ccc1-c1nc(-c2ccccc2)nc(-c2ccc(-c3ccccc3)cc2)n1]

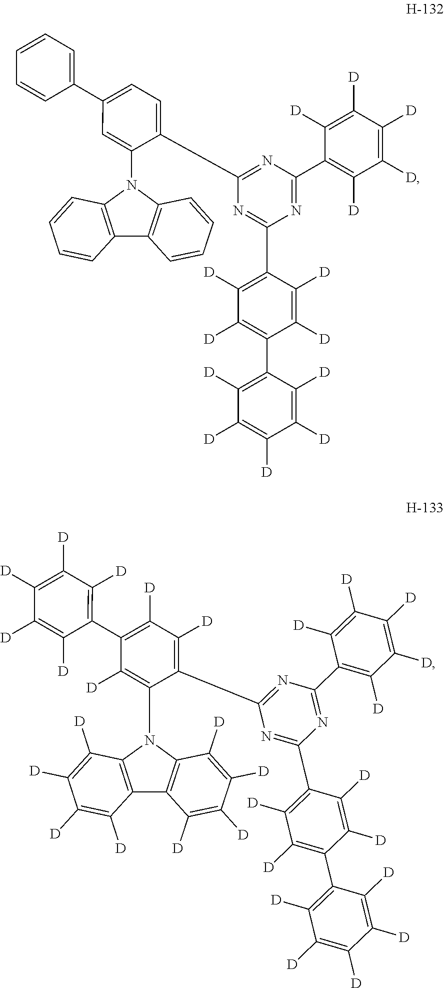

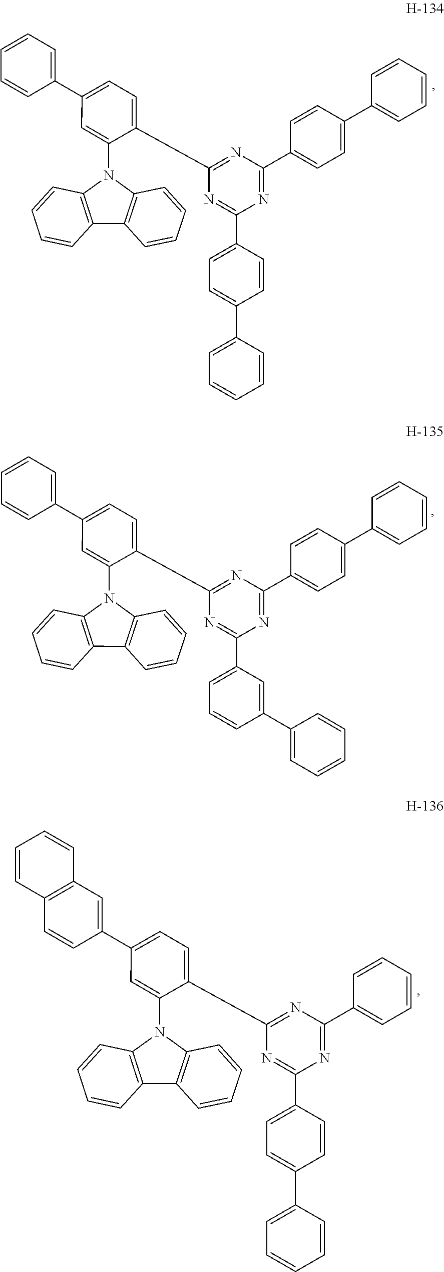 [SMILES: c1ccc(-c2ccc(-c3nc(-c4ccc(-c5ccccc5)cc4)nc(-c4ccc(-c5ccccc5)cc4-n4c5ccccc5c5ccccc54)n3)cc2)cc1 ; c1ccc(-c2ccc(-c3nc(-c4cccc(-c5ccccc5)c4)nc(-c4ccc(-c5ccccc5)cc4-n4c5ccccc5c5ccccc54)n3)cc2)cc1 ; c1ccc(-c2ccc(-c3nc(-c4ccccc4)nc(-c4ccc(-c5ccc6ccccc6c5)cc4-n4c5ccccc5c5ccccc54)n3)cc2)cc1]

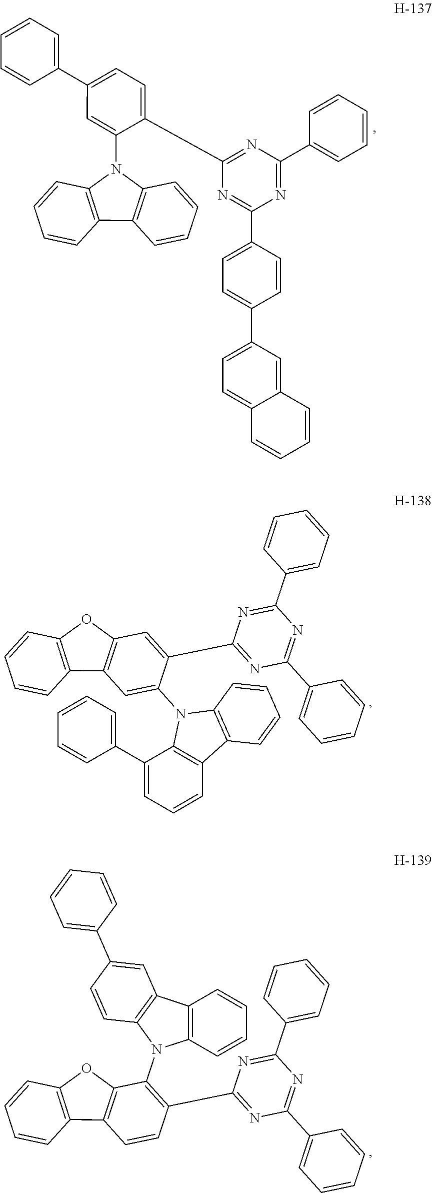 [SMILES: c1ccc(-c2ccc(-c3nc(-c4ccccc4)nc(-c4ccc(-c5ccc6ccccc6c5)cc4)n3)c(-n3c4ccccc4c4ccccc43)c2)cc1 ; c1ccc(-c2nc(-c3ccccc3)nc(-c3cc4oc5ccccc5c4cc3-n3c4ccccc4c4cccc(-c5ccccc5)c43)n2)cc1 ; c1ccc(-c2ccc3c(c2)c2ccccc2n3-c2c(-c3nc(-c4ccccc4)nc(-c4ccccc4)n3)ccc3c2oc2ccccc23)cc1]

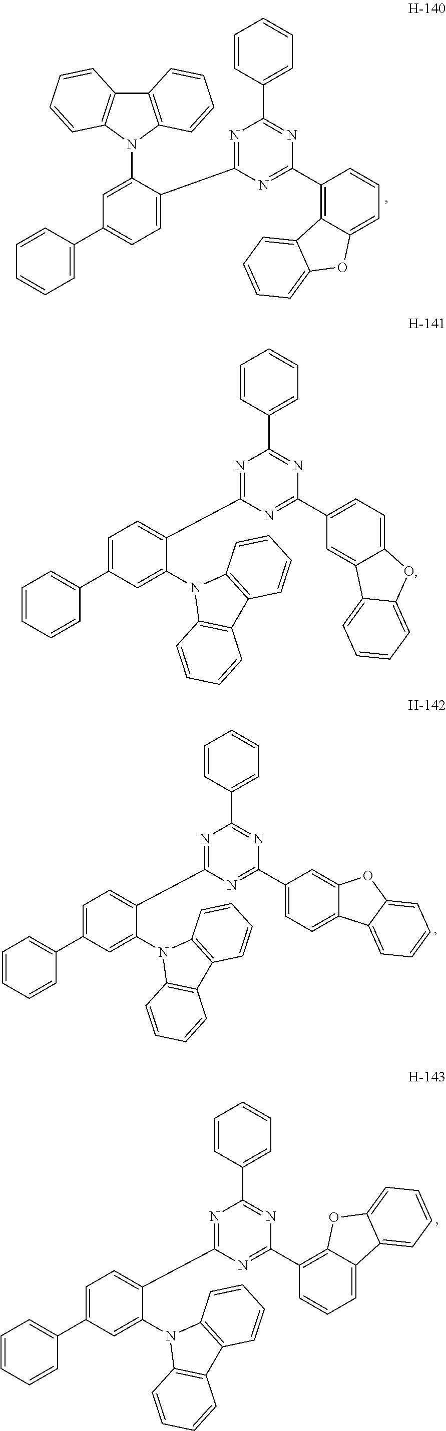 [SMILES: c1ccc(-c2ccc(-c3nc(-c4ccccc4)nc(-c4cccc5oc6ccccc6c45)n3)c(-n3c4ccccc4c4ccccc43)c2)cc1 ; c1ccc(-c2ccc(-c3nc(-c4ccccc4)nc(-c4ccc5oc6ccccc6c5c4)n3)c(-n3c4ccccc4c4ccccc43)c2)cc1 ; c1ccc(-c2ccc(-c3nc(-c4ccccc4)nc(-c4ccc5c(c4)oc4ccccc45)n3)c(-n3c4ccccc4c4ccccc43)c2)cc1 ; c1ccc(-c2ccc(-c3nc(-c4ccccc4)nc(-c4cccc5c4oc4ccccc45)n3)c(-n3c4ccccc4c4ccccc43)c2)cc1]

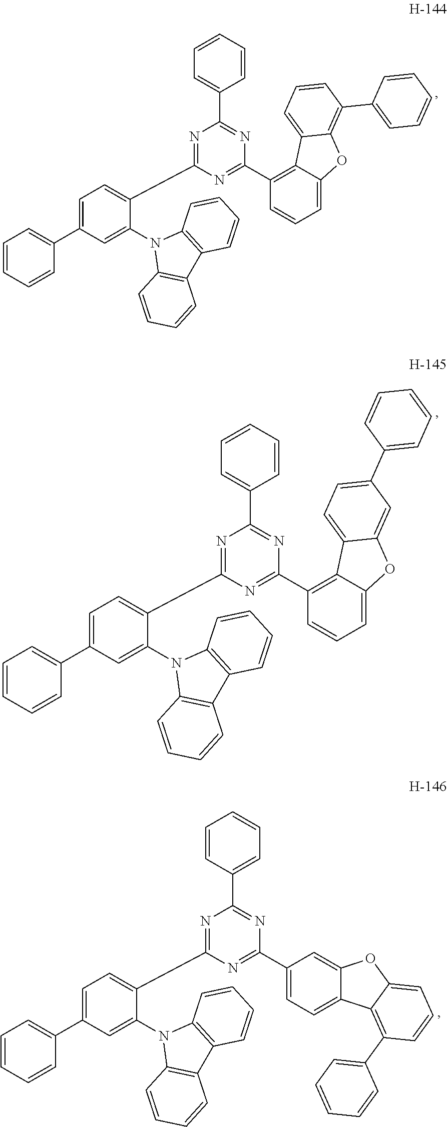 [SMILES: c1ccc(-c2ccc(-c3nc(-c4ccccc4)nc(-c4cccc5oc6c(-c7ccccc7)cccc6c45)n3)c(-n3c4ccccc4c4ccccc43)c2)cc1 ; c1ccc(-c2ccc(-c3nc(-c4ccccc4)nc(-c4cccc5oc6cc(-c7ccccc7)ccc6c45)n3)c(-n3c4ccccc4c4ccccc43)c2)cc1 ; c1ccc(-c2ccc(-c3nc(-c4ccccc4)nc(-c4ccc5c(c4)oc4cccc(-c6ccccc6)c45)n3)c(-n3c4ccccc4c4ccccc43)c2)cc1]

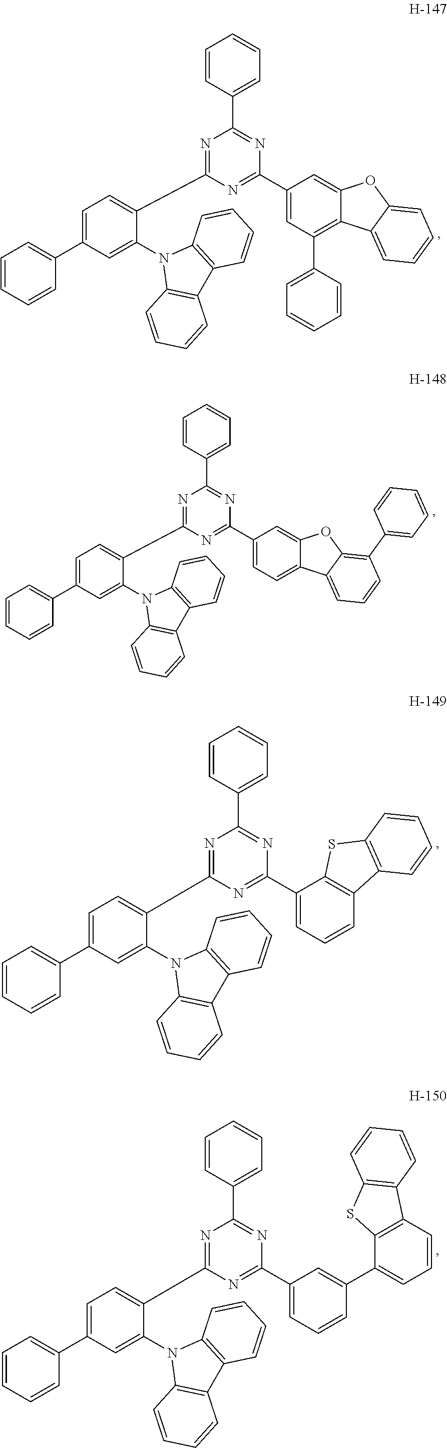 [SMILES: c1ccc(-c2ccc(-c3nc(-c4ccccc4)nc(-c4cc(-c5ccccc5)c5c(c4)oc4ccccc45)n3)c(-n3c4ccccc4c4ccccc43)c2)cc1 ; c1ccc(-c2ccc(-c3nc(-c4ccccc4)nc(-c4ccc5c(c4)oc4c(-c6ccccc6)cccc45)n3)c(-n3c4ccccc4c4ccccc43)c2)cc1 ; c1ccc(-c2ccc(-c3nc(-c4ccccc4)nc(-c4cccc5c4sc4ccccc45)n3)c(-n3c4ccccc4c4ccccc43)c2)cc1 ; c1ccc(-c2ccc(-c3nc(-c4ccccc4)nc(-c4cccc(-c5cccc6c5sc5ccccc56)c4)n3)c(-n3c4ccccc4c4ccccc43)c2)cc1]

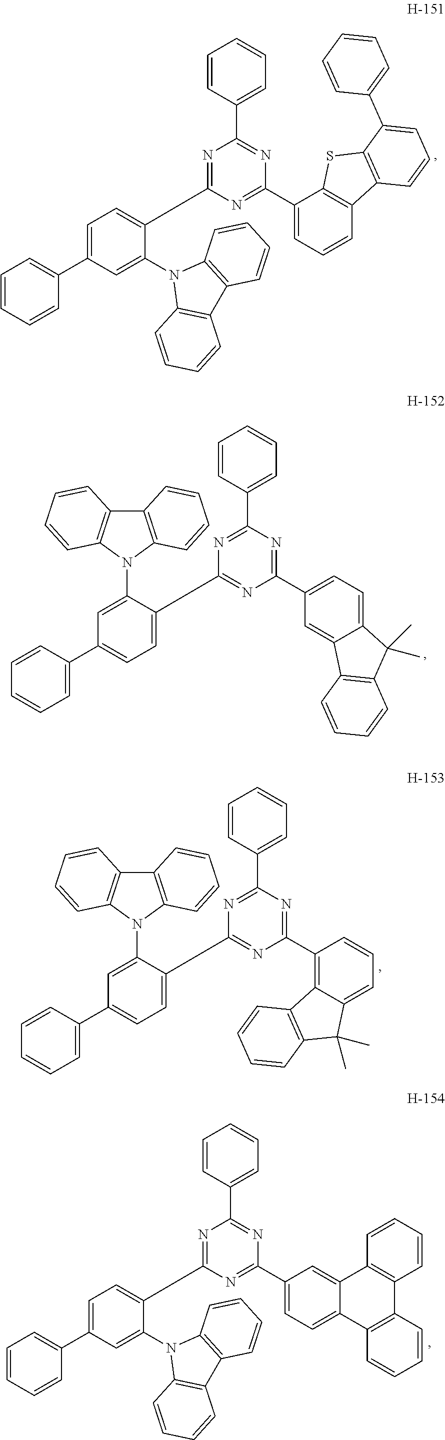 [SMILES: c1ccc(-c2ccc(-c3nc(-c4ccccc4)nc(-c4cccc5c4sc4c(-c6ccccc6)cccc45)n3)c(-n3c4ccccc4c4ccccc43)c2)cc1 ; CC1(C)c2ccccc2-c2cc(-c3nc(-c4ccccc4)nc(-c4ccc(-c5ccccc5)cc4-n4c5ccccc5c5ccccc54)n3)ccc21 ; CC1(C)c2ccccc2-c2c(-c3nc(-c4ccccc4)nc(-c4ccc(-c5ccccc5)cc4-n4c5ccccc5c5ccccc54)n3)cccc21 ; c1ccc(-c2ccc(-c3nc(-c4ccccc4)nc(-c4ccc5c6ccccc6c6ccccc6c5c4)n3)c(-n3c4ccccc4c4ccccc43)c2)cc1]

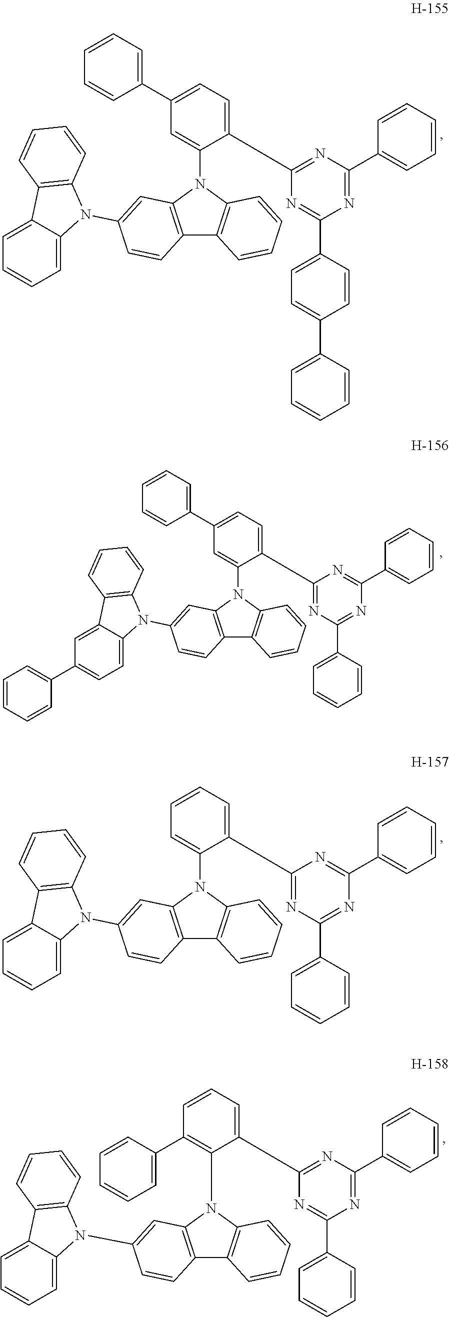 [SMILES: c1ccc(-c2ccc(-c3nc(-c4ccccc4)nc(-c4ccc(-c5ccccc5)cc4-n4c5ccccc5c5ccc(-n6c7ccccc7c7ccccc76)cc54)n3)cc2)cc1 ; c1ccc(-c2ccc(-c3nc(-c4ccccc4)nc(-c4ccccc4)n3)c(-n3c4ccccc4c4ccc(-n5c6ccccc6c6cc(-c7ccccc7)ccc65)cc43)c2)cc1 ; c1ccc(-c2nc(-c3ccccc3)nc(-c3ccccc3-n3c4ccccc4c4ccc(-n5c6ccccc6c6ccccc65)cc43)n2)cc1 ; c1ccc(-c2nc(-c3ccccc3)nc(-c3cccc(-c4ccccc4)c3-n3c4ccccc4c4ccc(-n5c6ccccc6c6ccccc65)cc43)n2)cc1]

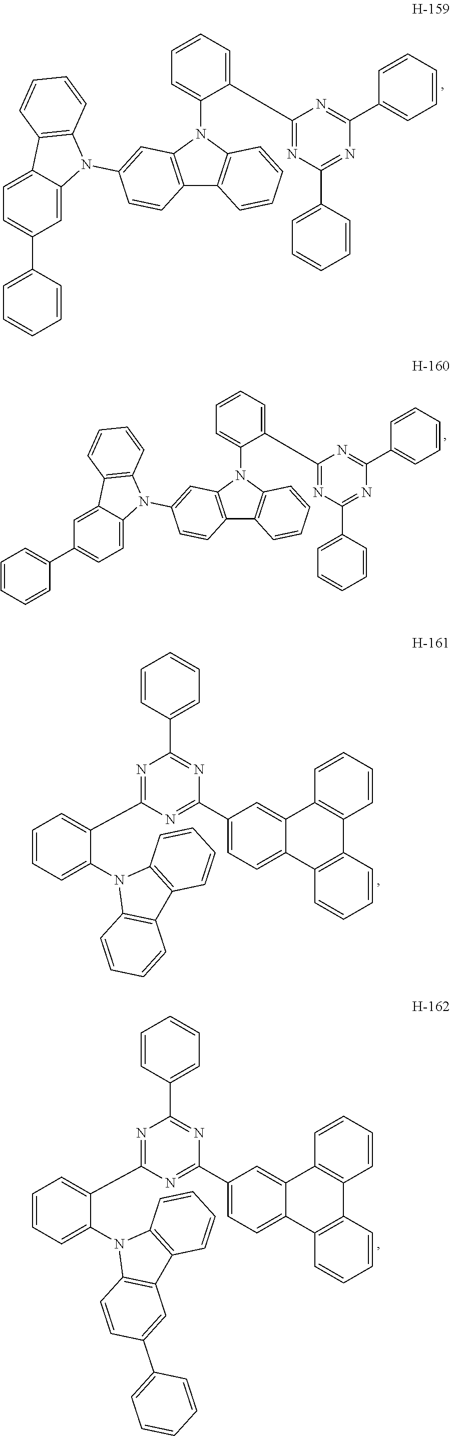 [SMILES: c1ccc(-c2ccc3c4ccccc4n(-c4ccc5c6ccccc6n(-c6ccccc6-c6nc(-c7ccccc7)nc(-c7ccccc7)n6)c5c4)c3c2)cc1 ; c1ccc(-c2ccc3c(c2)c2ccccc2n3-c2ccc3c4ccccc4n(-c4ccccc4-c4nc(-c5ccccc5)nc(-c5ccccc5)n4)c3c2)cc1 ; c1ccc(-c2nc(-c3ccc4c5ccccc5c5ccccc5c4c3)nc(-c3ccccc3-n3c4ccccc4c4ccccc43)n2)cc1 ; c1ccc(-c2ccc3c(c2)c2ccccc2n3-c2ccccc2-c2nc(-c3ccccc3)nc(-c3ccc4c5ccccc5c5ccccc5c4c3)n2)cc1]

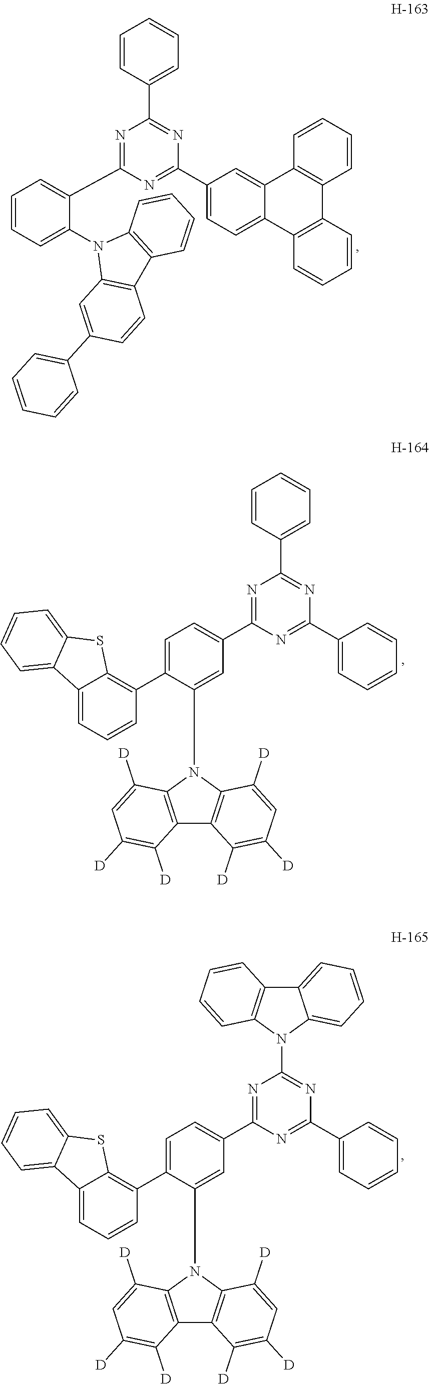 [SMILES: c1ccc(-c2ccc3c4ccccc4n(-c4ccccc4-c4nc(-c5ccccc5)nc(-c5ccc6c7ccccc7c7ccccc7c6c5)n4)c3c2)cc1 ; [2H]c1cc([2H])c2c(c1[2H])c1c([2H])c([2H])cc([2H])c1n2-c1cc(-c2nc(-c3ccccc3)nc(-c3ccccc3)n2)ccc1-c1cccc2c1sc1ccccc12 ; [2H]c1cc([2H])c2c(c1[2H])c1c([2H])c([2H])cc([2H])c1n2-c1cc(-c2nc(-c3ccccc3)nc(-n3c4ccccc4c4ccccc43)n2)ccc1-c1cccc2c1sc1ccccc12]

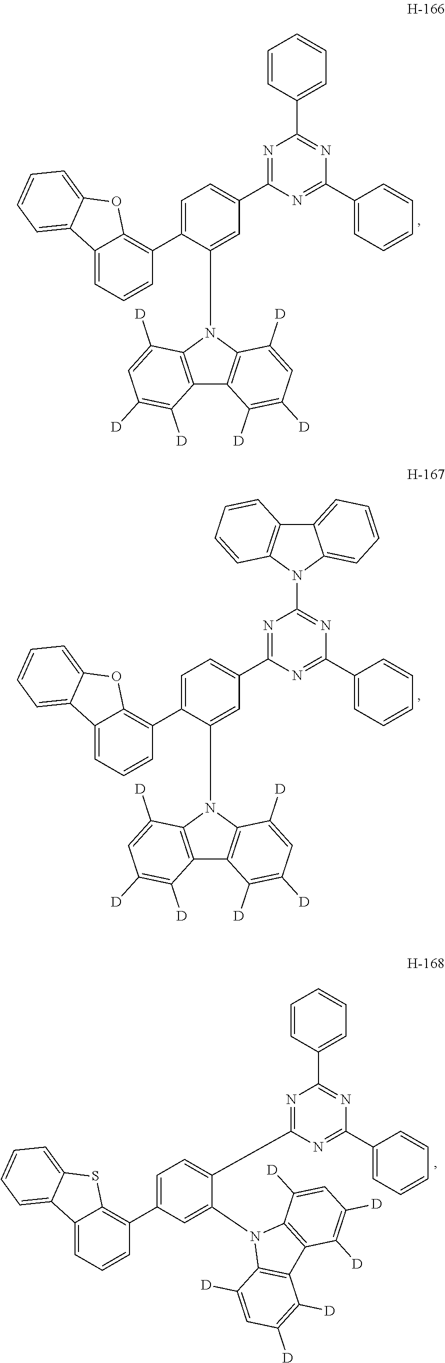 [SMILES: [2H]c1cc([2H])c2c(c1[2H])c1c([2H])c([2H])cc([2H])c1n2-c1cc(-c2nc(-c3ccccc3)nc(-c3ccccc3)n2)ccc1-c1cccc2c1oc1ccccc12 ; [2H]c1cc([2H])c2c(c1[2H])c1c([2H])c([2H])cc([2H])c1n2-c1cc(-c2nc(-c3ccccc3)nc(-n3c4ccccc4c4ccccc43)n2)ccc1-c1cccc2c1oc1ccccc12 ; [2H]c1cc([2H])c2c(c1[2H])c1c([2H])c([2H])cc([2H])c1n2-c1cc(-c2cccc3c2sc2ccccc23)ccc1-c1nc(-c2ccccc2)nc(-c2ccccc2)n1]

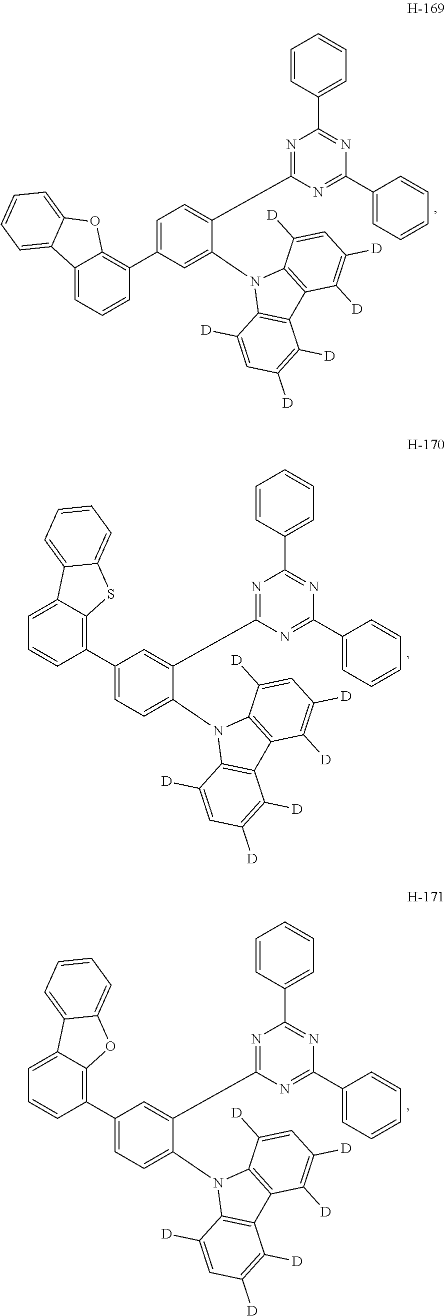 [SMILES: [2H]c1cc([2H])c2c(c1[2H])c1c([2H])c([2H])cc([2H])c1n2-c1cc(-c2cccc3c2oc2ccccc23)ccc1-c1nc(-c2ccccc2)nc(-c2ccccc2)n1 ; [2H]c1cc([2H])c2c(c1[2H])c1c([2H])c([2H])cc([2H])c1n2-c1ccc(-c2cccc3c2sc2ccccc23)cc1-c1nc(-c2ccccc2)nc(-c2ccccc2)n1 ; [2H]c1cc([2H])c2c(c1[2H])c1c([2H])c([2H])cc([2H])c1n2-c1ccc(-c2cccc3c2oc2ccccc23)cc1-c1nc(-c2ccccc2)nc(-c2ccccc2)n1]

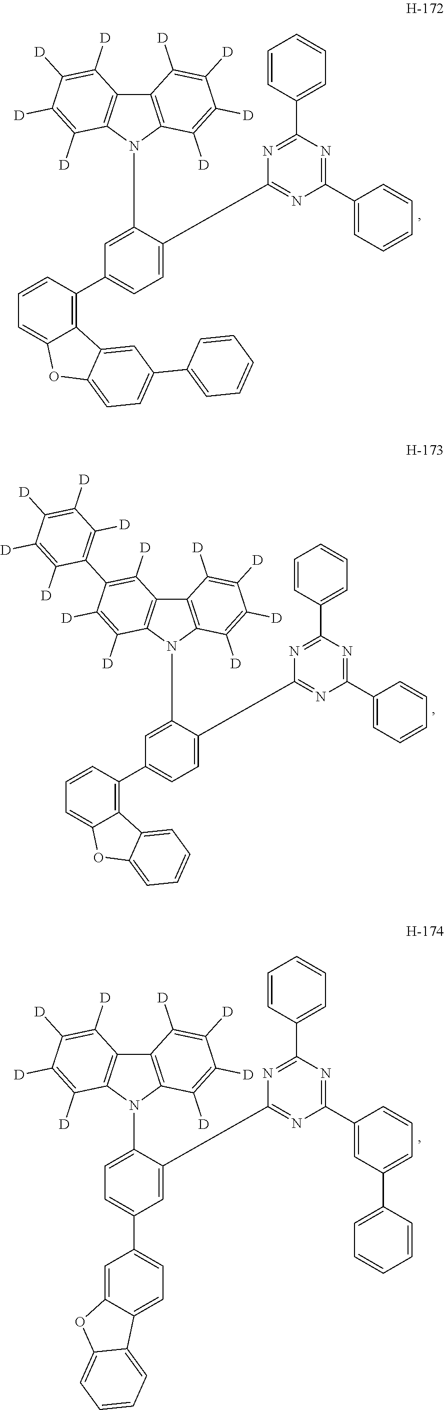 [SMILES: [2H]c1c([2H])c([2H])c2c(c1[2H])c1c([2H])c([2H])c([2H])c([2H])c1n2-c1cc(-c2cccc3oc4ccc(-c5ccccc5)cc4c23)ccc1-c1nc(-c2ccccc2)nc(-c2ccccc2)n1 ; [2H]c1c([2H])c([2H])c(-c2c([2H])c([2H])c3c(c2[2H])c2c([2H])c([2H])c([2H])c([2H])c2n3-c2cc(-c3cccc4oc5ccccc5c34)ccc2-c2nc(-c3ccccc3)nc(-c3ccccc3)n2)c([2H])c1[2H] ; [2H]c1c([2H])c([2H])c2c(c1[2H])c1c([2H])c([2H])c([2H])c([2H])c1n2-c1ccc(-c2ccc3c(c2)oc2ccccc23)cc1-c1nc(-c2ccccc2)nc(-c2cccc(-c3ccccc3)c2)n1]

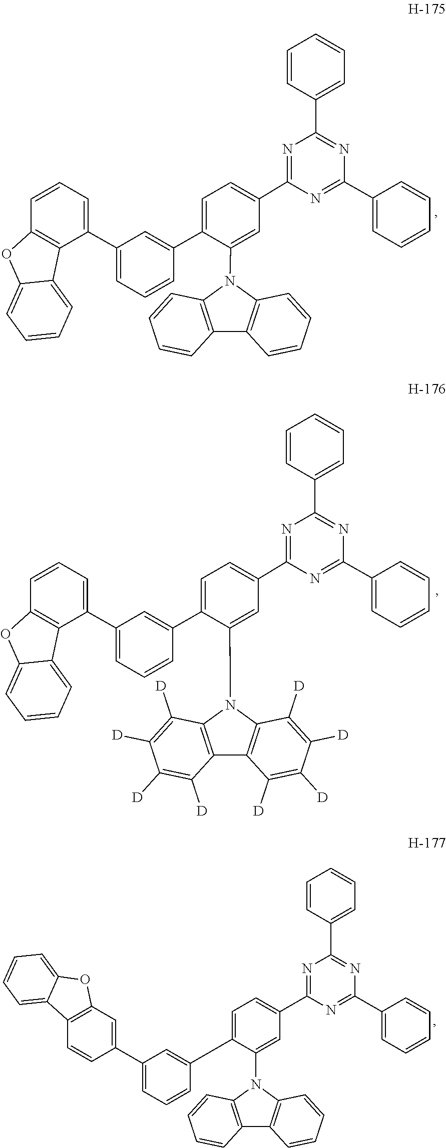 [SMILES: c1ccc(-c2nc(-c3ccccc3)nc(-c3ccc(-c4cccc(-c5cccc6oc7ccccc7c56)c4)c(-n4c5ccccc5c5ccccc54)c3)n2)cc1 ; [2H]c1c([2H])c([2H])c2c(c1[2H])c1c([2H])c([2H])c([2H])c([2H])c1n2-c1cc(-c2nc(-c3ccccc3)nc(-c3ccccc3)n2)ccc1-c1cccc(-c2cccc3oc4ccccc4c23)c1 ; c1ccc(-c2nc(-c3ccccc3)nc(-c3ccc(-c4cccc(-c5ccc6c(c5)oc5ccccc56)c4)c(-n4c5ccccc5c5ccccc54)c3)n2)cc1]

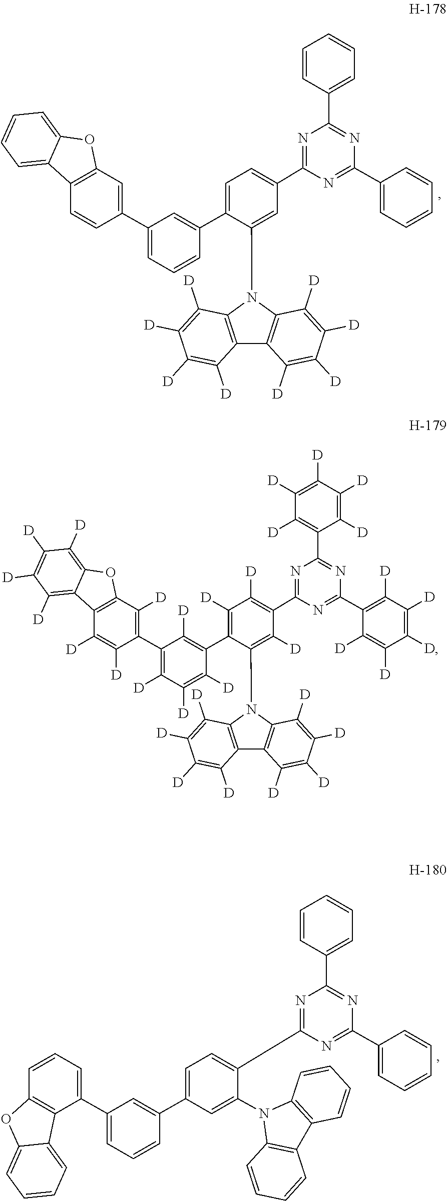

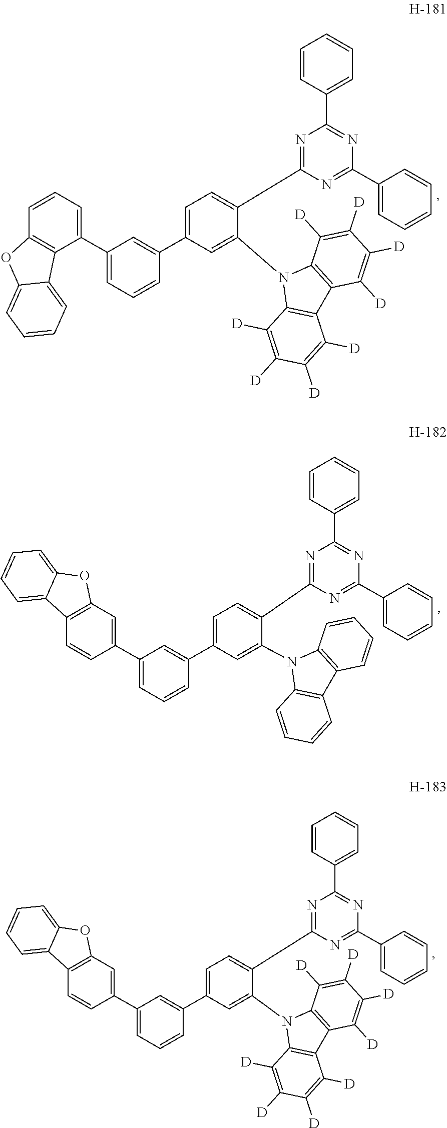 [SMILES: [2H]c1c([2H])c([2H])c2c(c1[2H])c1c([2H])c([2H])c([2H])c([2H])c1n2-c1cc(-c2cccc(-c3cccc4oc5ccccc5c34)c2)ccc1-c1nc(-c2ccccc2)nc(-c2ccccc2)n1 ; c1ccc(-c2nc(-c3ccccc3)nc(-c3ccc(-c4cccc(-c5ccc6c(c5)oc5ccccc56)c4)cc3-n3c4ccccc4c4ccccc43)n2)cc1 ; [2H]c1c([2H])c([2H])c2c(c1[2H])c1c([2H])c([2H])c([2H])c([2H])c1n2-c1cc(-c2cccc(-c3ccc4c(c3)oc3ccccc34)c2)ccc1-c1nc(-c2ccccc2)nc(-c2ccccc2)n1]

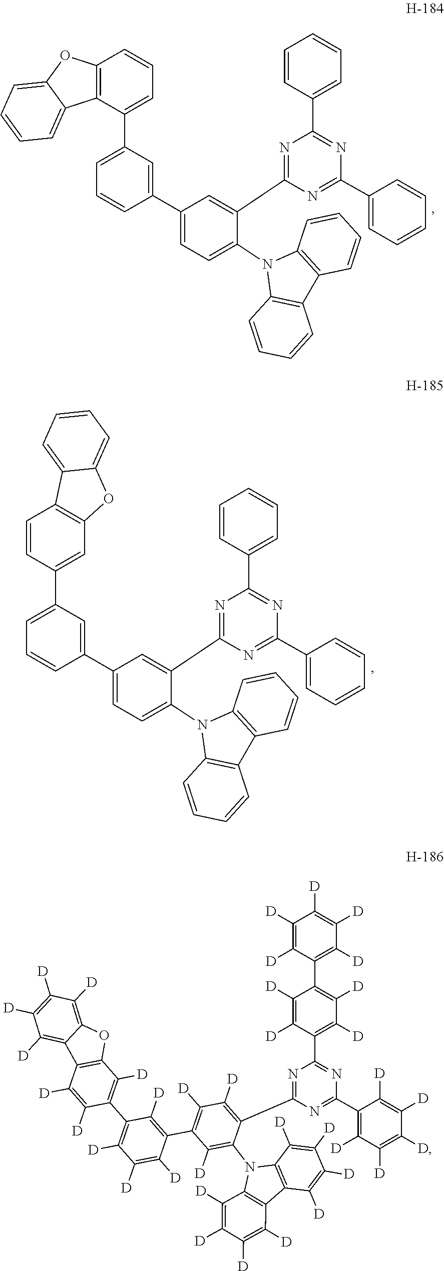

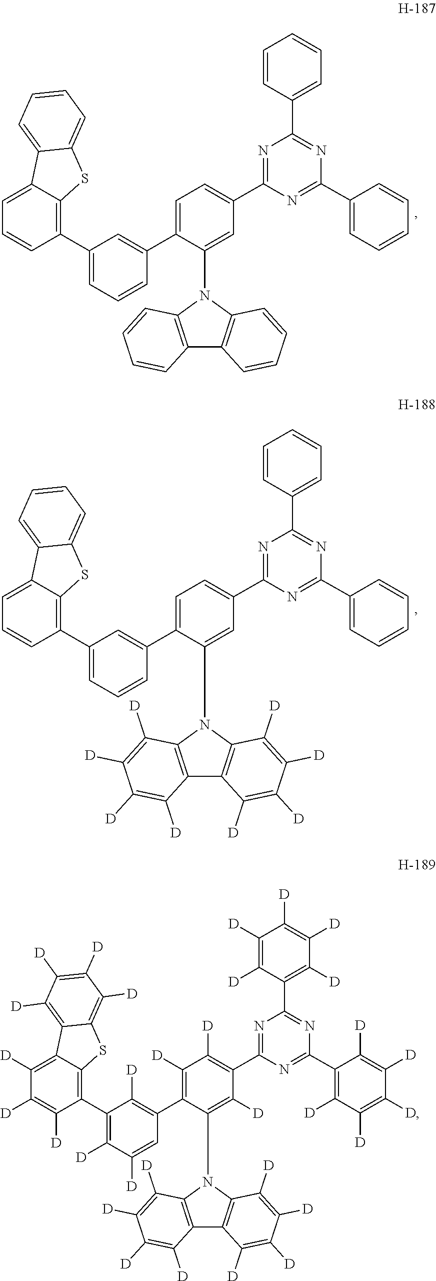

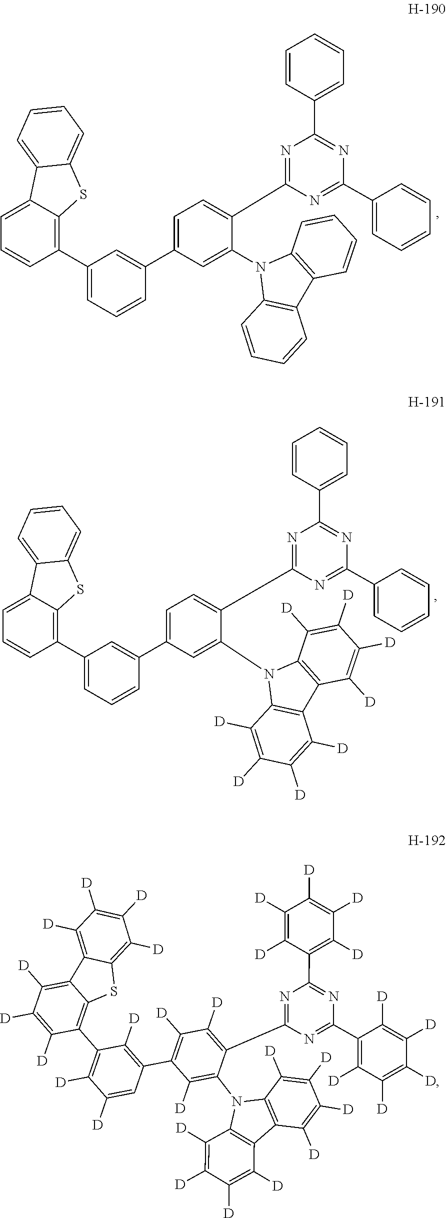

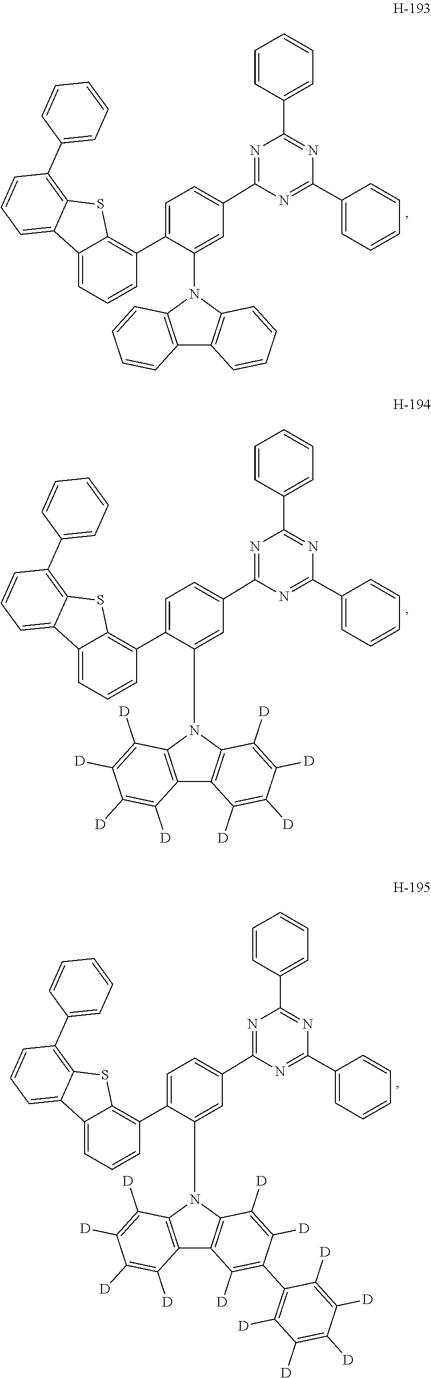 [SMILES: c1ccc(-c2nc(-c3ccccc3)nc(-c3ccc(-c4cccc5c4sc4c(-c6ccccc6)cccc45)c(-n4c5ccccc5c5ccccc54)c3)n2)cc1 ; [2H]c1c([2H])c([2H])c2c(c1[2H])c1c([2H])c([2H])c([2H])c([2H])c1n2-c1cc(-c2nc(-c3ccccc3)nc(-c3ccccc3)n2)ccc1-c1cccc2c1sc1c(-c3ccccc3)cccc12 ; [2H]c1c([2H])c([2H])c(-c2c([2H])c([2H])c3c(c2[2H])c2c([2H])c([2H])c([2H])c([2H])c2n3-c2cc(-c3nc(-c4ccccc4)nc(-c4ccccc4)n3)ccc2-c2cccc3c2sc2c(-c4ccccc4)cccc23)c([2H])c1[2H]]

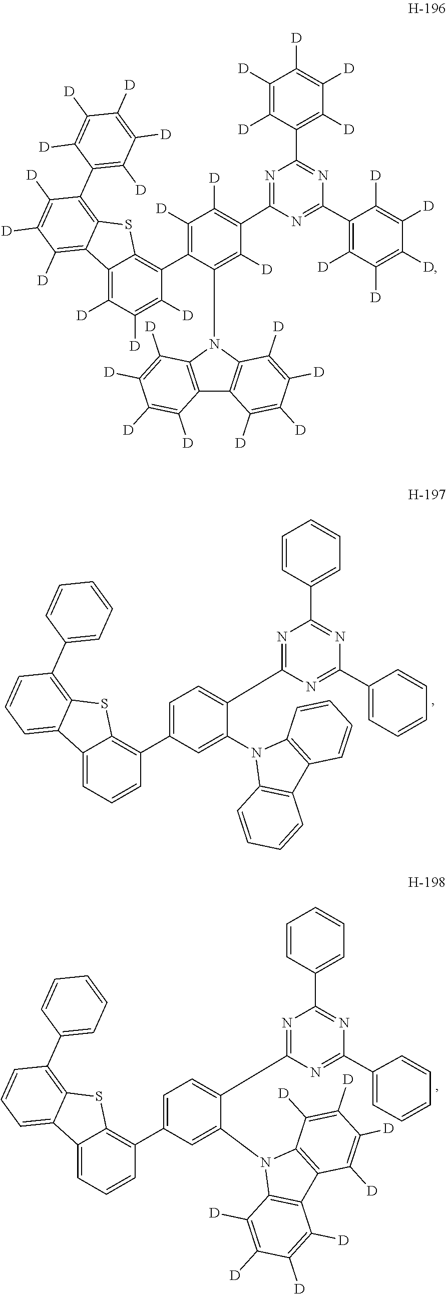

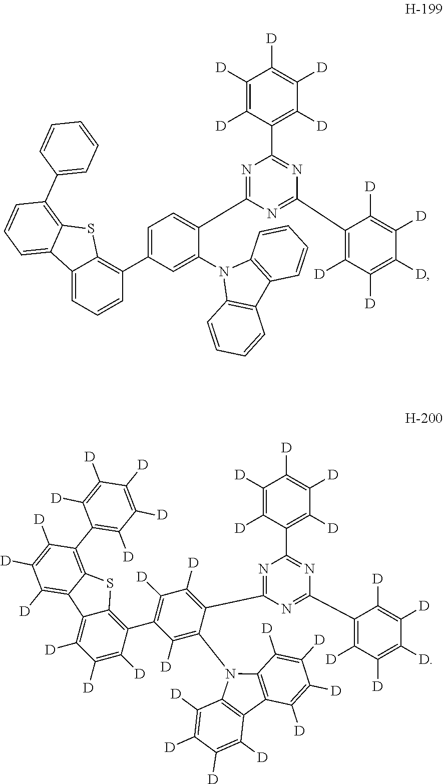

According to an embodiment of the present disclosure, at least one hydrogen in the structure of the first host compound and/or the structure of the second host compound is substituted with deuterium.

Herein, the expression that “at least one hydrogen in the structure of a compound is substituted with deuterium” is intended to mean that the structure of the compound comprises at least one deuterium.

According to an embodiment of the present disclosure, hydrogens in the first host compound and/or the second host compound can be partially or fully substituted with deuterium.

According to an embodiment of the present disclosure, a deuteration rate of the first host compound and/or a deuteration rate of the second host compound are 5% to 100%.

According to an embodiment of the present disclosure, the deuteration rate of the first host compound and/or the deuteration rate of the second host compound are 30% to 100%.

According to an embodiment of the present disclosure, the deuteration rate of the first host compound and/or the deuteration rate of the second host compound are 50% to 100%.

In this embodiment, the “deuteration rate of a compound” refers to a percentage of the number of deuteriums in the compound structure relative to the total number of hydrogens and deuteriums in the compound structure.

According to an embodiment of the present disclosure, the organic electroluminescent device further comprises a hole injection layer. The hole injection layer may be a functional layer comprising a single material or a functional layer comprising multiple materials, wherein the comprised multiple materials are most commonly used as hole transporting materials doped with a certain proportion of p-type conductive doping material. Common p-type doping materials comprise

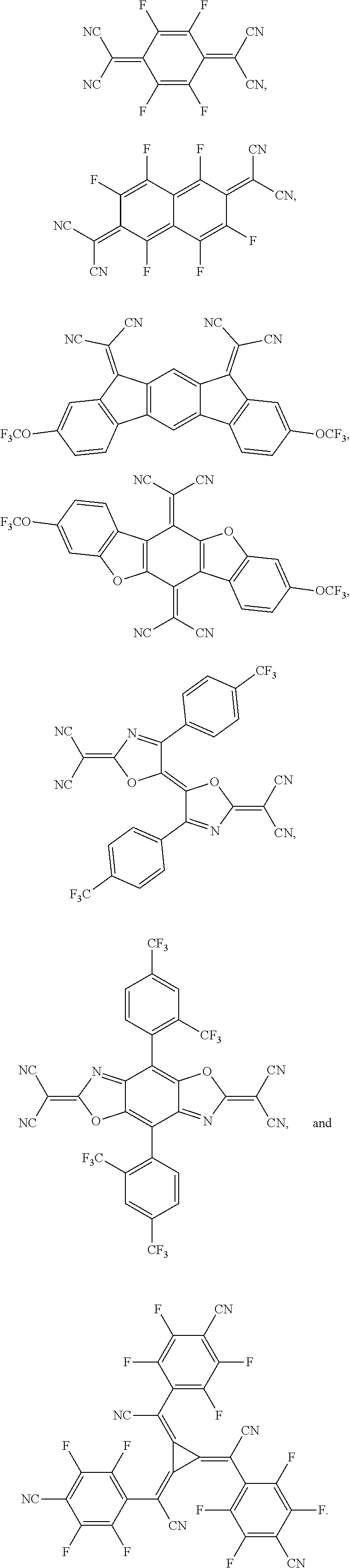

According to another embodiment of the present disclosure, a proportion of the fluorescent material in the emissive layer to the total weight of the emissive layer is 0.001% to 25%.

According to another embodiment of the present disclosure, the proportion of the fluorescent material in the emissive layer to the total weight of the emissive layer is less than 0.01% to 15%.

According to another embodiment of the present disclosure, the proportion of the fluorescent material in the emissive layer to the total weight of the emissive layer is less than 0.1% to 10%.

According to another embodiment of the present disclosure, further disclosed is a compound composition. The compound composition comprises the preceding metal complex comprising a ligand Lₐ having a structure represented by Formula 1 and the preceding fluorescent material having a structure represented by Formula 2.

According to another embodiment of the present disclosure, further disclosed is a display apparatus comprising the organic electroluminescent device of any one of the preceding embodiments.

According to another embodiment of the present disclosure, further disclosed is an application of the organic electroluminescent device of any one of the preceding embodiments in a display apparatus.

Combination with Other Materials

The materials described in the present disclosure for a particular layer in an organic light-emitting device can be used in combination with various other materials present in the device. The combinations of these materials are described in detail in U.S. patent application No. 20160359122 at paragraphs 0132-0161, which is incorporated by reference herein in its entirety. The materials described or referred to are non-limiting examples of materials that may be useful in combination with the compounds disclosed herein, and one of skill in the art can readily consult the literature to identify other materials that may be useful in combination.

The materials described herein as useful for a particular layer in an organic light-emitting device may be used in combination with a variety of other materials present in the device. For example, the compounds disclosed herein may be used in combination with a wide variety of hosts, dopants, transport layers, blocking layers, injection layers, electrodes, and other layers that may be present. The combinations of these materials are described in detail in paragraphs 0080-0101 of U.S. patent application No. 20150349273, which is incorporated by reference herein in its entirety. The materials described or referred to are non-limiting examples of materials that may be useful in combination with the compounds disclosed herein, and one of skill in the art can readily consult the literature to identify other materials that may be useful in combination.

In material synthesis examples, all reactions were carried out under nitrogen protection unless otherwise stated. All reaction solvents were anhydrous and used as received from commercial sources. Synthetic products were structurally confirmed and tested for properties using one or more conventional equipment in the art (including, but not limited to, nuclear magnetic resonance instrument produced by BRUKER, liquid chromatograph produced by SHIMADZU, liquid chromatograph-mass spectrometry produced by SHIMADZU, gas chromatograph-mass spectrometry produced by SHIMADZU, differential Scanning calorimeters produced by SHIMADZU, fluorescence spectrophotometer produced by SHANGHAI LENGGUANG TECH., electrochemical workstation produced by WUHAN CORRTEST, and sublimation apparatus produced by ANHUI BEQ) by methods well-known to persons skilled in the art.

### Material Synthesis Example

A method for preparing the compound of the present disclosure is not limited.

Typically, the following compounds are used as examples without limitation, and the synthesis routes and preparation methods thereof are described below.

### Synthesis Example 1

### Synthesis of Compound 5-1-3

### Step 1:

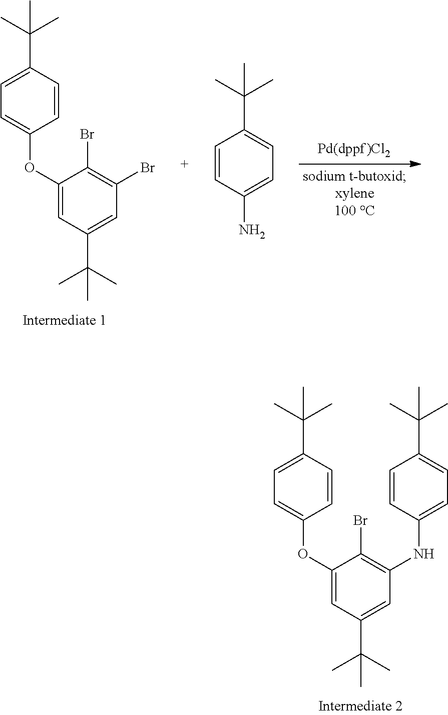 [SMILES: CC(C)(C)c1ccc(Oc2cc(C(C)(C)C)cc(Br)c2Br)cc1 ; CC(C)(C)c1ccc(N)cc1 ; CC(C)(C)c1ccc(Nc2cc(C(C)(C)C)cc(Oc3ccc(C(C)(C)C)cc3)c2Br)cc1]

In a dry 1 L three-necked flask, Intermediate 1 (40.34 g, 91.64 mmol), sodium t-butoxide (26.42 g, 274.92 mmol), p-t-butylaniline (19.14 g, 128.29 mmol), [1,1′-bis(diphenylphosphino) ferrocene]palladium (II) dichloride (Pd(dppf)Cl₂) (3.35 g, 4.58 mmol), and xylene (400 mL) were added in sequence, purged with N₂ three times, heated to 100° C., and reacted overnight. The reaction solution was cooled to room temperature and filtered through a pad of Celite. The filter cake was rinsed with DCM and concentrated under reduced pressure. The crude product was purified through column chromatography with an eluent being pure PE:DCM=10:1 to obtain Intermediate 2 as a yellow solid (32.0 g, with a yield of 68.74%).

### Step 2:

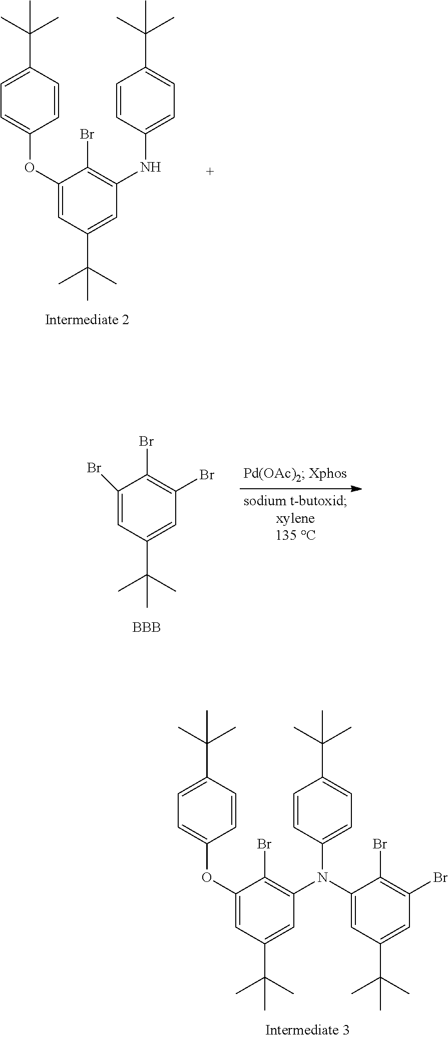

In a dry 1 L three-necked flask, Intermediate 2 (32.0 g, 62.99 mmol), BBB (34.49 g, 94.49 mmol), palladium acetate (Pd(OAc)₂) (1.41 g, 6.30 mmol), 2-dicyclohexylphosphino-2′,4′,6′-triisopropylbiphenyl (Xphos) (4.47 g, 9.45 mmol), sodium t-butoxide (15.13 g, 157.48 mmol), and xylene (450 mL) were added, purged with N₂ three times, heated to 135° C., and reacted overnight. After the reaction was completed, the reaction solution was cooled to room temperature and filtered through a pad of Celite. The filter cake was rinsed with DCM and concentrated under reduced pressure to remove the solvent. The crude product was purified through column chromatography with an eluent being PE:DCM=20:1, and the product was collected to obtain Intermediate 3 as a yellowish white solid (33.8 g, with a yield of 67.24%).

### Step 3:

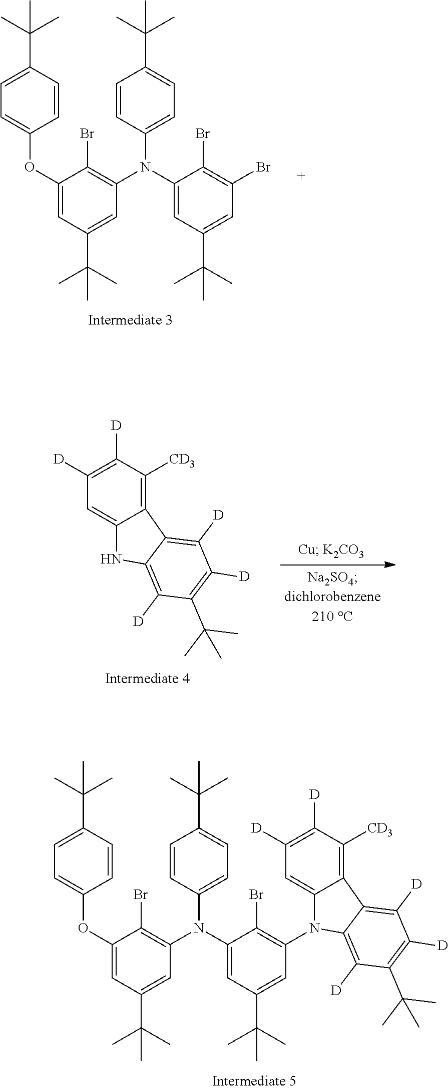 [SMILES: CC(C)(C)c1ccc(Oc2cc(C(C)(C)C)cc(N(c3ccc(C(C)(C)C)cc3)c3cc(C(C)(C)C)cc(Br)c3Br)c2Br)cc1 ; [2H]c1cc2[nH]c3c([2H])c(C(C)(C)C)c([2H])c([2H])c3c2c(C([2H])([2H])[2H])c1[2H] ; [2H]c1cc2c(c(C([2H])([2H])[2H])c1[2H])c1c([2H])c([2H])c(C(C)(C)C)c([2H])c1n2-c1cc(C(C)(C)C)cc(N(c2ccc(C(C)(C)C)cc2)c2cc(C(C)(C)C)cc(Oc3ccc(C(C)(C)C)cc3)c2Br)c1Br]

In a dry 1 L round-bottom flask, Intermediate 3 (33.8 g, 42.36 mmol), Intermediate 4 (14.08 g, 57.19 mmol), Cu (4.04 g, 63.54 mmol), potassium carbonate (26.31 g, 190.62 mmol), sodium sulfate (27.08 g, 190.62 mmol), and dichlorobenzene (450 mL) were added, purged with N₂ three times, heated to 210° C., and reacted for 20 h. The reaction was stopped, and the reaction solution was cooled to room temperature and filtered through a pad of Celite. The filter cake was rinsed with DCM and concentrated under reduced pressure to remove the solvent. The crude product was purified through column chromatography with an eluent being PE:DCM=10:1 to obtain Intermediate 5 as a white solid (14.2 g, with a yield of 35.10%).

### Step 4:

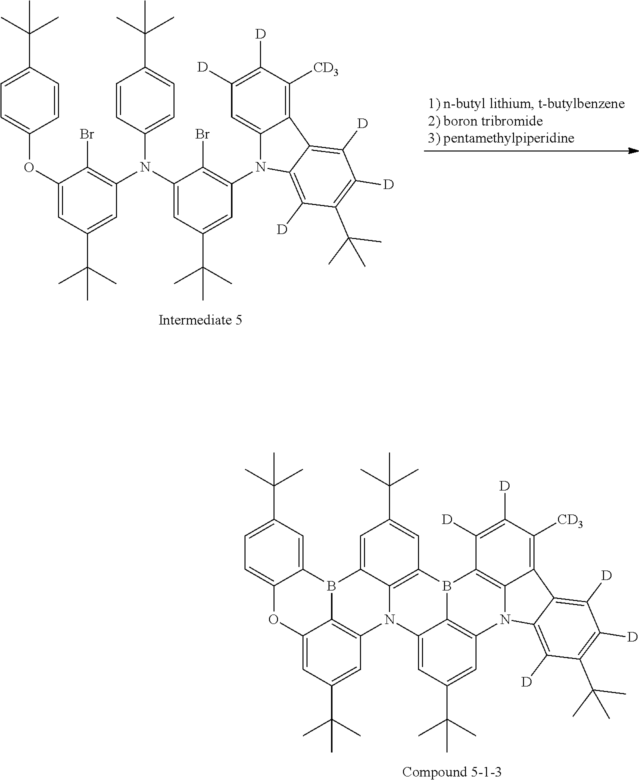 [SMILES: [2H]c1cc2c(c(C([2H])([2H])[2H])c1[2H])c1c([2H])c([2H])c(C(C)(C)C)c([2H])c1n2-c1cc(C(C)(C)C)cc(N(c2ccc(C(C)(C)C)cc2)c2cc(C(C)(C)C)cc(Oc3ccc(C(C)(C)C)cc3)c2Br)c1Br ; [2H]c1c(C(C)(C)C)c([2H])c2c(c1[2H])c1c(C([2H])([2H])[2H])c([2H])c([2H])c3c1n2-c1cc(C(C)(C)C)cc2c1B3c1cc(C(C)(C)C)cc3c1N2c1cc(C(C)(C)C)cc2c1B3c1cc(C(C)(C)C)ccc1O2]

Under nitrogen protection at room temperature, Intermediate 5 (14.2 g, 14.8 mmol) was added to t-butylbenzene (200.0 mL), and n-butyl lithium (37.0 mmol) was added at −70° C., heated to 60° C., reacted for 1.5 h, and cooled to 0° C. Boron tribromide (41.5 mmol) was added and reacted for 1 h. Pentamethylpiperidine (44.4 mmol) was added, heated to 180° C., and reacted for 24 h. The system was cooled and filtered. The filtrate was concentrated and subjected to column chromatography (dichloromethane/petroleum ether=1/5) to obtain Compound 5-1-3 as a yellow solid (245 mg, 0.3 mmol, with a yield of 2.0%). The product was confirmed as the target product with a molecular weight of 820.56.

### Synthesis Example 2

### Synthesis of Compound 5-1-2

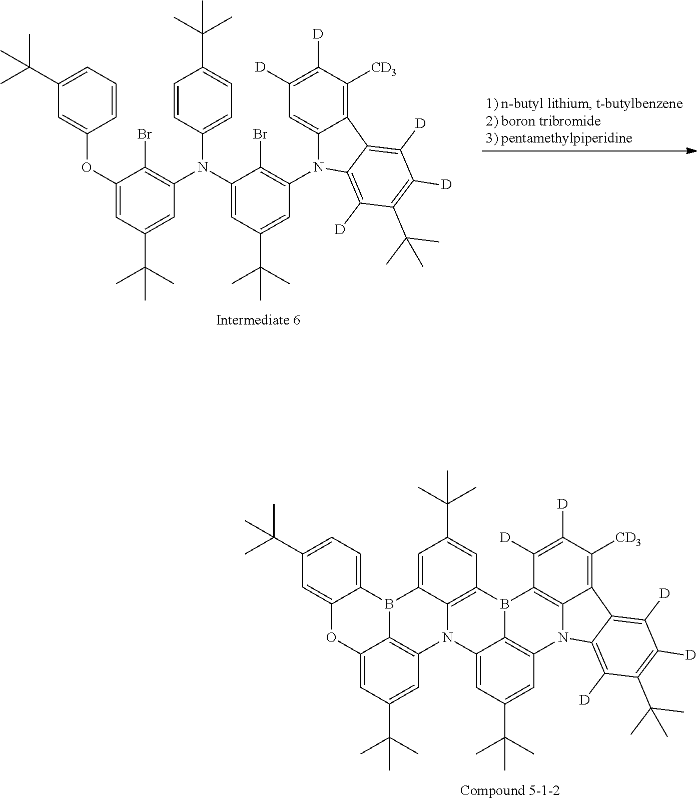 [SMILES: [2H]c1cc2c(c(C([2H])([2H])[2H])c1[2H])c1c([2H])c([2H])c(C(C)(C)C)c([2H])c1n2-c1cc(C(C)(C)C)cc(N(c2ccc(C(C)(C)C)cc2)c2cc(C(C)(C)C)cc(Oc3cccc(C(C)(C)C)c3)c2Br)c1Br ; [2H]c1c(C(C)(C)C)c([2H])c2c(c1[2H])c1c(C([2H])([2H])[2H])c([2H])c([2H])c3c1n2-c1cc(C(C)(C)C)cc2c1B3c1cc(C(C)(C)C)cc3c1N2c1cc(C(C)(C)C)cc2c1B3c1ccc(C(C)(C)C)cc1O2]

A synthesis method of Intermediate 6 may be obtained with reference to the synthesis method of Intermediate 5 described above, which is not repeated here.

Under nitrogen protection at room temperature, Intermediate 6 (15.8 g, 16.4 mmol) was added to t-butylbenzene (200.0 mL), and n-butyl lithium (41.0 mmol) was added at −70° C., heated to 60° C., reacted for 1.5 h, and cooled to 0° C. Boron tribromide (46.0 mmol) was added and reacted for 1 h. Pentamethylpiperidine (49.2 mmol) was added, heated to 180° C., and reacted for 24 h. The system was cooled and filtered. The filtrate was concentrated and subjected to column chromatography (chloromethane/petroleum ether=1/5) to obtain Compound 5-1-2 as a yellow solid (375 mg, 0.46 mmol, with a yield of 2.7%). The product was confirmed as the target product with a molecular weight of 820.56.

### Synthesis Example 3

### Synthesis of Compound 5-1-280

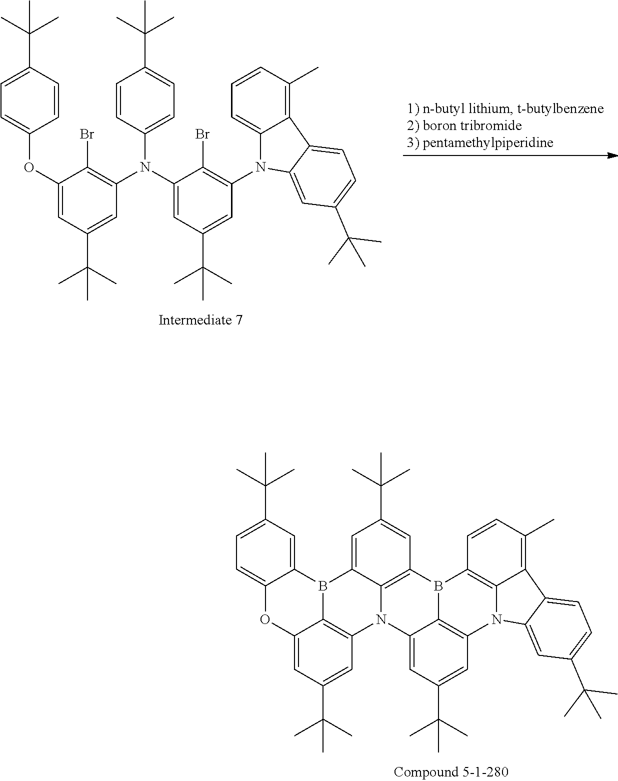 [SMILES: Cc1cccc2c1c1ccc(C(C)(C)C)cc1n2-c1cc(C(C)(C)C)cc(N(c2ccc(C(C)(C)C)cc2)c2cc(C(C)(C)C)cc(Oc3ccc(C(C)(C)C)cc3)c2Br)c1Br ; Cc1ccc2c3c1c1ccc(C(C)(C)C)cc1n3-c1cc(C(C)(C)C)cc3c1B2c1cc(C(C)(C)C)cc2c1N3c1cc(C(C)(C)C)cc3c1B2c1cc(C(C)(C)C)ccc1O3]

A synthesis method of Intermediate 7 may be obtained with reference to the synthesis method of Intermediate 5 described above, which is not repeated here.

Under nitrogen protection at room temperature, Intermediate 7 (27.3 g, 28.6 mmol) was added to t-butylbenzene (300.0 mL), and n-butyl lithium (71.5 mmol) was added at −70° C., heated to 60° C., reacted for 1.5 h, and cooled to 0° C. Boron tribromide (80.1 mmol) was added and reacted for 1 h. Pentamethylpiperidine (85.8 mmol) was added, heated to 180° C., and reacted for 24 h. The system was cooled and filtered. The filtrate was concentrated and subjected to column chromatography (dichloromethane/petroleum ether=1/5) to obtain Compound 5-1-280 as a yellow solid (780 mg, 0.96 mmol, with a yield of 3.3%). The product was confirmed as the target product with a molecular weight of 812.50.

### Synthesis Example 4

### Synthesis of Compound 3-2-6

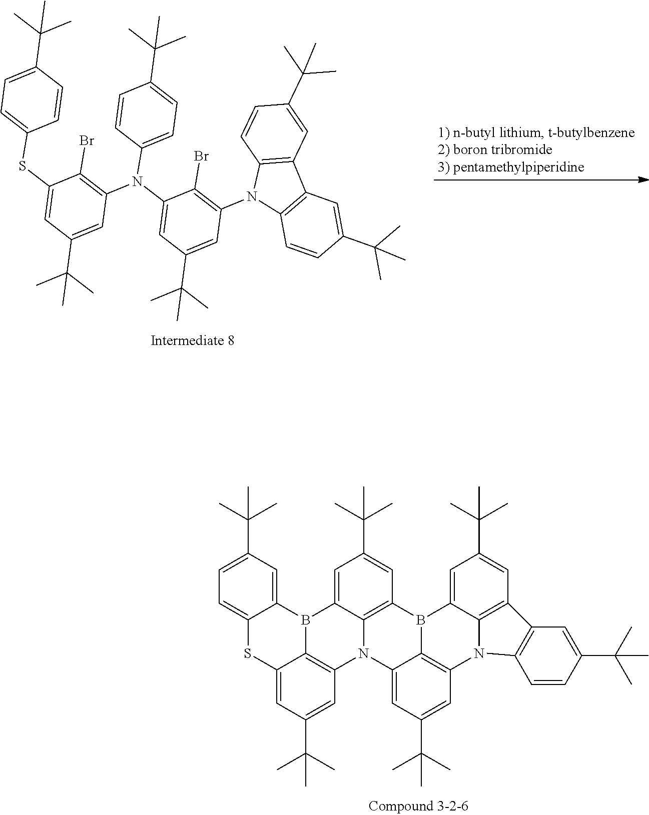 [SMILES: CC(C)(C)c1ccc(Sc2cc(C(C)(C)C)cc(N(c3ccc(C(C)(C)C)cc3)c3cc(C(C)(C)C)cc(-n4c5ccc(C(C)(C)C)cc5c5cc(C(C)(C)C)ccc54)c3Br)c2Br)cc1 ; CC(C)(C)c1ccc2c(c1)B1c3cc(C(C)(C)C)cc4c3N(c3cc(C(C)(C)C)cc(c31)S2)c1cc(C(C)(C)C)cc2c1B4c1cc(C(C)(C)C)cc3c4cc(C(C)(C)C)ccc4n-2c13]

Under nitrogen protection at room temperature, Intermediate 8 (5.6 g, 5.5 mmol) was added to t-butylbenzene (80.0 mL), and n-butyl lithium (13.8 mmol) was added at −70° C., reacted for 1.5 h at room temperature, heated to 60° C. and reacted for 1 h, and cooled to 0° C. Boron tribromide (16.1 mmol) was added, heated to 80° C. and reacted for 12 h, and cooled to 0° C. Pentamethylpiperidine (19.2 mmol) was added, heated to 180° C., and reacted for 48 h. The system was cooled and filtered. The filtrate was concentrated and subjected to column chromatography (toluene/n-hexane=1/5) to obtain Compound 3-2-6 as an orange solid (360 mg, 0.4 mmol, with a yield of 7%). The product was confirmed as the target product with a molecular weight of 870.53.

### Synthesis of Compound 4-1-94

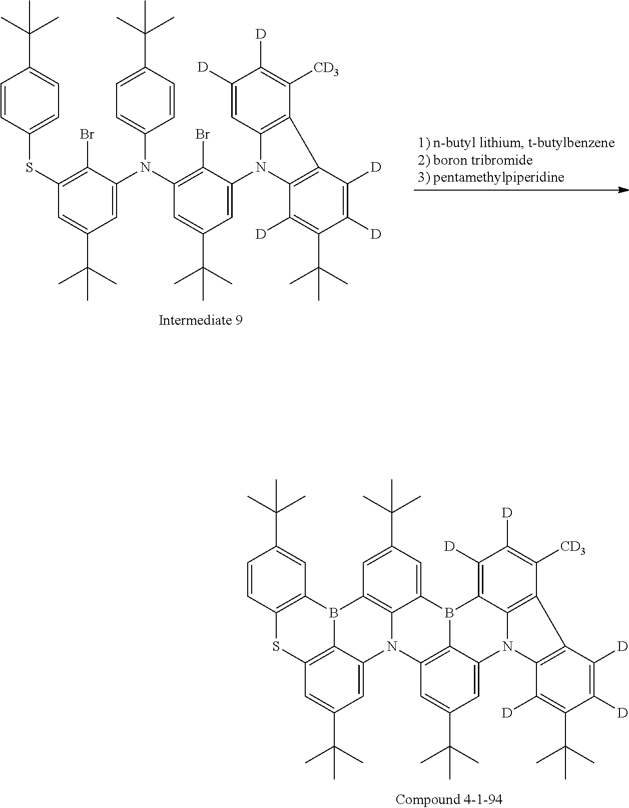 [SMILES: [2H]c1cc2c(c(C([2H])([2H])[2H])c1[2H])c1c([2H])c([2H])c(C(C)(C)C)c([2H])c1n2-c1cc(C(C)(C)C)cc(N(c2ccc(C(C)(C)C)cc2)c2cc(C(C)(C)C)cc(Sc3ccc(C(C)(C)C)cc3)c2Br)c1Br ; [2H]c1c(C(C)(C)C)c([2H])c2c(c1[2H])c1c(C([2H])([2H])[2H])c([2H])c([2H])c3c1n2-c1cc(C(C)(C)C)cc2c1B3c1cc(C(C)(C)C)cc3c1N2c1cc(C(C)(C)C)cc2c1B3c1cc(C(C)(C)C)ccc1S2]

Under nitrogen protection at room temperature, Intermediate 9 (6.8 g, 6.9 mmol) was added to tert-butylbenzene (100.0 ml), and n-butyllithium (16.0 mmol) was added at −70° C. The mixture was allowed to react at room temperature for 1.5 h, heated to 60° C. and reacted for 1 h. The mixture was cooled to 0° C., and boron tribromide (19.5 mmol) was added. The mixture was heated to 80° C. and reacted for 12 h. The mixture was cooled to 0° C., and pentamethylpiperidine (41.8 mmol) was added. The mixture was heated to 180° C. and reacted for 48 h. After cooling, the mixture was filtered, and the filtrate was concentrated and subjected to column chromatography (toluene/n-hexane=1/5) to obtain an orange solid Compound 4-1-94 (250 mg, 0.3 mmol, with a yield of 4%). The product was confirmed as the target product with a molecular weight of 836.48.

The intermediates used in the above synthesis examples may be purchased by those skilled in the art or may be obtained by those skilled in the art with reference to preparation methods in the related art. Moreover, the metal complex of the present disclosure may be easily obtained with reference to preparation methods in the related art, for example, may be prepared with reference to U.S. Pat. No. 8,367,223B2, US20200251666A1, and US20240109926A1. The first host compound of the present disclosure as a host material may be prepared with reference to US20240016057A1 and CN117327056A. The second host compound of the present disclosure may be prepared with reference to US2019198780A1 and CN115368293A. Preparation methods thereof are not described in detail here. The documents listed above are merely exemplary, and other documents may be easily obtained by those skilled in the art.

A method for preparing an electroluminescent device is not limited. The preparation methods of the following examples are merely illustrative and are not to be construed as limiting. Based on the related art, those skilled in the art can make reasonable improvements on the preparation methods of the following examples. For example, the proportions of various materials in an emissive layer are not particularly limited. Those skilled in the art can reasonably select the proportions within certain ranges based on the related art. For example, with the total weight of the materials in the emissive layer for reference, a host material may account for 75% to 98%, a metal complex may account for 1% to 20%, and a fluorescent material may account for 0.01% to 5%; or the host material may account for 88% to 98%, the metal complex may account for 0.05% to 3%, and the fluorescent material may account for 0.1% to 1%. Further, the host material comprises two materials, where the ratio of the two host materials may range from 99:1 to 1:99, the ratio may range from 80:20 to 20:80, or the ratio may range from 70:30 to 30:70. In device examples, the characteristics of a device were tested using the conventional equipment in the art (including, but not limited to, evaporator produced by ANGSTROM ENGINEERING, optical testing system produced by SUZHOU FSTAR, life testing system produced by SUZHOU FSTAR, and ellipsometer produced by BEIJING ELLITOP) by methods well-known to the persons skilled in the art.

### Device Example

### Device Example 1

Firstly, a glass substrate having an indium tin oxide (ITO) anode with a thickness of 80 nm was cleaned and then treated with oxygen plasma and UV ozone. After the treatment, the substrate was dried in a glovebox to remove moisture. Then, the substrate was mounted on a substrate holder and placed in a vacuum chamber. The organic layers specified below were sequentially deposited through vacuum thermal evaporation on the ITO anode at a rate of 0.2-2 Angstroms per second and a vacuum degree of about 100 Torr. Compound HT and Compound HT1 were co-deposited for use as a hole injection layer (HIL). Compound HT was used as a hole transport layer (HTL). Compound PH-1 was used as an electron blocking layer (EBL). The first host compound PH-87, the second host compound H-102, and the metal complex GD314 and the fluorescent material Compound 3-2-6 of the present disclosure were co-deposited for use as an emissive layer (EML) at a weight ratio of 56:37:6:1. On the EML, Compound H-1 was used as a hole blocking layer (HBL). On the HBL, Compound ET and 8-hydroxyquinolinolato-lithium (Liq) were co-deposited for use as an electron transport layer (ETL). Finally, Liq was deposited for use as an electron injection layer with a thickness of 1 nm and Al was deposited for use as a cathode with a thickness of 120 nm. The device was transferred back to the glovebox and encapsulated with a glass lid and a moisture getter to complete the device.

### Device Example 2

Device Example 2 was implemented in the same manner as Device Example 1 except that the metal complex GD314 in the EML was replaced with the metal complex GD419 of the present disclosure.

### Device Example 3

Device Example 3 was implemented in the same manner as Device Example 1 except that the metal complex GD314 in the EML was replaced with the metal complex GD552 of the present disclosure.

### Device Comparative Example 1

Device Comparative Example 1 was implemented in the same manner as Device Example 1 except that the first host compound PH-87, the second host compound H-102, and the fluorescent material Compound 3-2-6 of the present disclosure were co-deposited for use as an EML at a weight ratio of 59:40:1.

### Device Comparative Example 2

Device Comparative Example 2 was implemented in the same manner as Device Example 1 except that the first host compound PH-87, the second host compound H-102, and the metal complex GD314 of the present disclosure were co-deposited for use as an EML at a weight ratio of 56:38:6.

The detailed structures and thicknesses of layers of the devices are shown in Table 1. A layer using more than one material is obtained by doping different compounds at their weight ratio as recorded.

TABLE 1
Part of the device structures of Examples 1 to 3 and Comparative Examples 1 and 2

| Device ID | HIL | HTL | EBL | EML | HBL | ETL |
|---|---|---|---|---|---|---|
| Example 1 | Compound | Compound | Compound | Compound | Compound | Compound |
| | HT:Compound | HT | PH-1 | PH-87:Compound | H-1 (50 | ET:Liq |
| | HT1 (97:3) | (350 Å) | (50 Å) | H-102:GD314:Compound | Å) | (40:60) |
| | (100 Å) | | | 3-2-6 (56:37:6:1) | | (350 Å) |
| | | | | (400 Å) | | |
| Example 2 | Compound | Compound | Compound | Compound | Compound | Compound |
| | HT:Compound | HT | PH-1 | PH-87:Compound | H-1 (50 | ET:Liq |
| | HT1 (97:3) | (350 Å) | (50 Å) | H-102:GD419:Compound | Å) | (40:60) |
| | (100 Å) | | | 3-2-6 (56:37:6:1) | | (350 Å) |
| | | | | (400 Å) | | |
| Example 3 | Compound | Compound | Compound | Compound | Compound | Compound |
| | HT:Compound | HT | PH-1 | PH-87:Compound | H-1 (50 | ET:Liq |
| | HT1 (97:3) | (350 Å) | (50 Å) | H-102:GD552:Compound | Å) | (40:60) |
| | (100 Å) | | | 3-2-6 (56:37:6:1) | | (350 Å) |
| | | | | (400 Å) | | |
| Comparative | Compound | Compound | Compound | Compound | Compound | Compound |
| Example 1 | HT:Compound | HT | PH-1 | PH-87:Compound | H-1 (50 | ET:Liq |
| | HT1 (97:3) | (350 Å) | (50 Å) | H-102:Compound | Å) | (40:60) |
| | (100 Å) | | | 3-2-6 (59:40:1) (400 | | (350 Å) |
| | | | | Å) | | |
| Comparative | Compound | Compound | Compound | Compound | Compound | Compound |
| Example 2 | HT:Compound | HT | PH-1 | PH-87:Compound | H-1 (50 | ET:Liq |
| | HT1 (97:3) | (350 Å) | (50 Å) | H-102:GD314 | Å) | (40:60) |
| | (100 Å) | | | (56:38:6) (400 Å) | | (350 Å) |

The materials used in the devices are as follows:

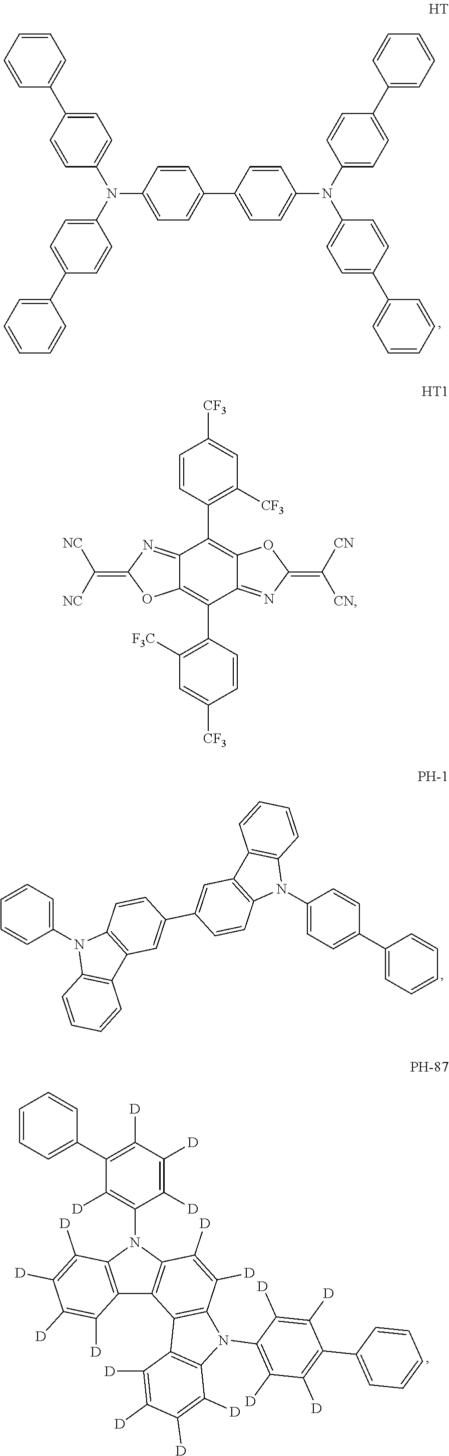 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; N#CC(C#N)=c1nc2c(-c3ccc(C(F)(F)F)cc3C(F)(F)F)c3oc(=C(C#N)C#N)nc3c(-c3ccc(C(F)(F)F)cc3C(F)(F)F)c2o1 ; c1ccc(-c2ccc(-n3c4ccccc4c4cc(-c5ccc6c(c5)c5ccccc5n6-c5ccccc5)ccc43)cc2)cc1 ; [2H]c1c([2H])c(-c2ccccc2)c([2H])c(-n2c3c([2H])c([2H])c([2H])c([2H])c3c3c4c5c([2H])c([2H])c([2H])c([2H])c5n(-c5c([2H])c([2H])c(-c6ccccc6)c([2H])c5[2H])c4c([2H])c([2H])c32)c1[2H]]

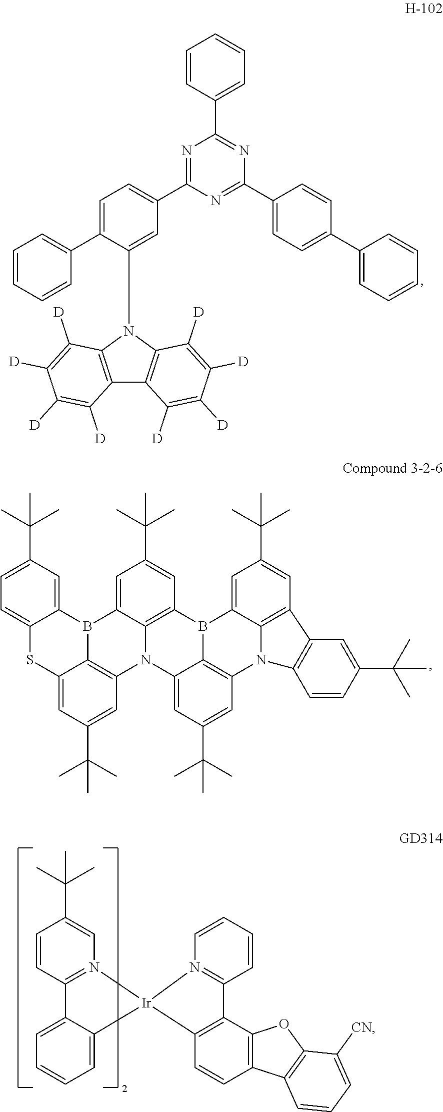

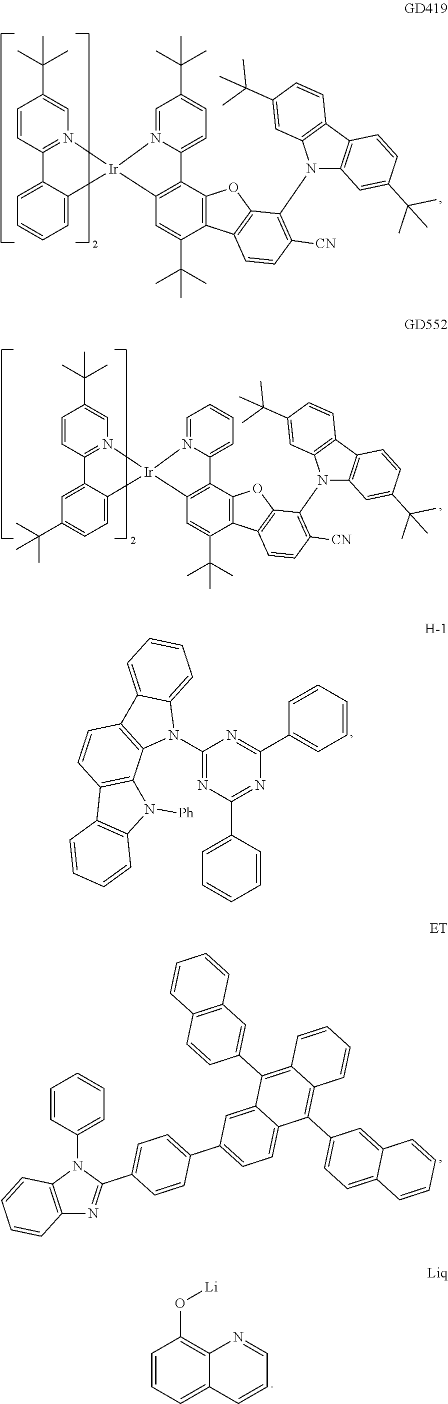

At a constant luminance of 1000 cd/m², the CIE data, maximum emission wavelength (max), full width at half maximum (FWHM), drive voltage (V), current efficiency (CE), power efficiency (PE), and external quantum efficiency (EQE) of each device were measured. The data are recorded and shown in Table 2.

TABLE 2
Device data of Examples 1 to 3 and Comparative Examples 1 and 2

| | | λₘₐₓ | FWHM | Voltage | CE | PE | EQE |
|---|---|---|---|---|---|---|---|
| Device ID | CIE (x, y) | (nm) | (nm) | (V) | (cd/A) | (lm/W) | (%) |
| Example 1 | (0.309, 0.673) | 540 | 34.6 | 2.50 | 127 | 159 | 28.87 |
| Example 2 | (0.301, 0.679) | 539 | 34.8 | 2.53 | 130 | 161 | 29.70 |
| Example 3 | (0.300, 0.679) | 539 | 35.1 | 2.71 | 129 | 149 | 29.32 |
| Comparative | (0.296, 0.682) | 539 | 33.6 | 2.59 | 108 | 131 | 25.33 |
| Example 1 | | | | | | | |
| Comparative | (0.335, 0.636) | 528 | 51.6 | 2.52 | 87 | 108 | 22.67 |
| Example 2 | | | | | | | |

Examples 1 to 3 differ from Comparative Example 1 only in that: in the EMLs of Examples 1 to 3, the metal complex comprising a ligand Lₐ having a structure represented by Formula 1 is used as a phosphorescent sensitizer to sensitize the fluorescent material having a particular structure represented by Formula 2; while no phosphorescent sensitizer is used in Comparative Example 1.

As can be seen from the data in Table 2, Examples 1 to 3 have basically the same maximum emission wavelength as Comparative Example 1, indicating that light emits by the devices of Examples 1 to 3 is from the fluorescent material. However, compared with the ordinary fluorescent device of Comparative Example 1, Device Examples 1 to 3 of the present disclosure further achieve unexpected significant improvements in device efficiency while maintaining narrow FWHMs and low voltages basically equal to those of Comparative Example 1. Specifically, compared with Comparative Example 1, the CE of Examples 1, 2, and 3 is increased by 17.6%, 20.4%, and 19.4%, respectively, the PE is increased by 21.4%, 22.9%, and 13.7%, respectively, and the EQE is increased by 14.0%, 17.3%, and 15.8%, respectively.

Example 1 differs from Comparative Example 2 only in that: in Example 1, both the metal complex and the fluorescent material of the present disclosure are used, and the device emits fluorescence; while in Comparative Example 2, only the metal complex is used, without using the fluorescent material, and the device emits phosphorescence. Compared with the phosphorescent device of Comparative Example 2, the sensitized fluorescent device of Example 1 unexpectedly exhibits better effects in all aspects: in addition to a narrower FWHM, the CE, the PE, and the EQE are greatly improved by 46.0%, 47.2%, and 27.3%, respectively.

The above results indicate that compared with either the ordinary fluorescent device comprising no phosphorescent sensitizer or the ordinary phosphorescent device comprising no fluorescent material, the sensitized fluorescent device of the present disclosure, which comprises both the metal complex comprising a ligand Lₐ having a structure represented by Formula 1 and the fluorescent material having a structure of Formula 2 in the emissive layer, can further improve the overall device performance and has a broad application prospect.

More devices having different structures and comprising the metal complex as the phosphorescent sensitizer matched with the fluorescent material of the present disclosure having the structure of Formula 2 are further provided, and the data indicate that these devices also have excellent overall performance. The details are described below.

### Device Example 4

Device Example 4 was implemented in the same manner as Device Example 1 except that Compound PH-23 was used as an EBL, and the first host material Compound PH-75, the second host material Compound H-106, the metal complex GD183, and Compound 3-2-6 were co-deposited for use as an EML at a weight ratio of 65.2:28.0:6.0:0.8.

### Device Comparative Example 3

Device Comparative Example 3 was implemented in the same manner as Device Example 4 except that the first host material Compound PH-75, the second host material Compound H-106, and Compound 3-2-6 were co-deposited for use as an EML at a weight ratio of 69.4:29.8:0.8.

### Device Comparative Example 4

Device Comparative Example 4 was implemented in the same manner as Device Example 4 except that the first host material Compound PH-75, the second host material Compound H-106, and the metal complex GD183 were co-deposited for use as an EML at a weight ratio of 66:28:6.

Detailed structures and thicknesses of layers of the devices are shown in the following table. A layer using more than one material is obtained by doping different compounds at their weight ratio as recorded.

TABLE 3
Part of the device structures of Example 4 and Comparative Examples 3 and 4

| Device ID | HIL | HTL | EBL | EML | HBL | ETL |
|---|---|---|---|---|---|---|
| Example 4 | Compound | Compound | Compound | Compound | Compound | Compound |
| | HT:Compound | HT (350 | PH-23 (50 | PH-75:Compound | H-1 (50 Å) | ET:Liq |
| | HT1 (97:3) | Å) | Å) | H-106:Metal | | (40:60) |
| | (100 Å) | | | Complex | | (350 Å) |
| | | | | GD183:Compound | | |
| | | | | 3-2-6 | | |
| | | | | (65.2:28.0:6.0:0.8) | | |
| | | | | (400 Å) | | |
| Comparative | Compound | Compound | Compound | Compound | Compound | Compound |
| Example 3 | HT:Compound | HT (350 | PH-23 (50 | PH-75:Compound | H-1 (50 Å) | ET:Liq |
| | HT1 (97:3) | Å) | Å) | H-106:Compound | | (40:60) |
| | (100 Å) | | | 3-2-6 | | (350 Å) |
| | | | | (69.4:29.8:0.8) | | |
| | | | | (400 Å) | | |
| Comparative | Compound | Compound | Compound | Compound | Compound | Compound |
| Example 4 | HT:Compound | HT (350 | PH-23 (50 | PH-75:Compound | H-1 (50 Å) | ET:Liq |
| | HT1 (97:3) | Å) | Å) | H-106:Metal | | (40:60) |
| | (100 Å) | | | Complex GD183 | | (350 Å) |
| | | | | (66:28:6) (400 Å) | | |

The new materials used in the devices have the following structures:

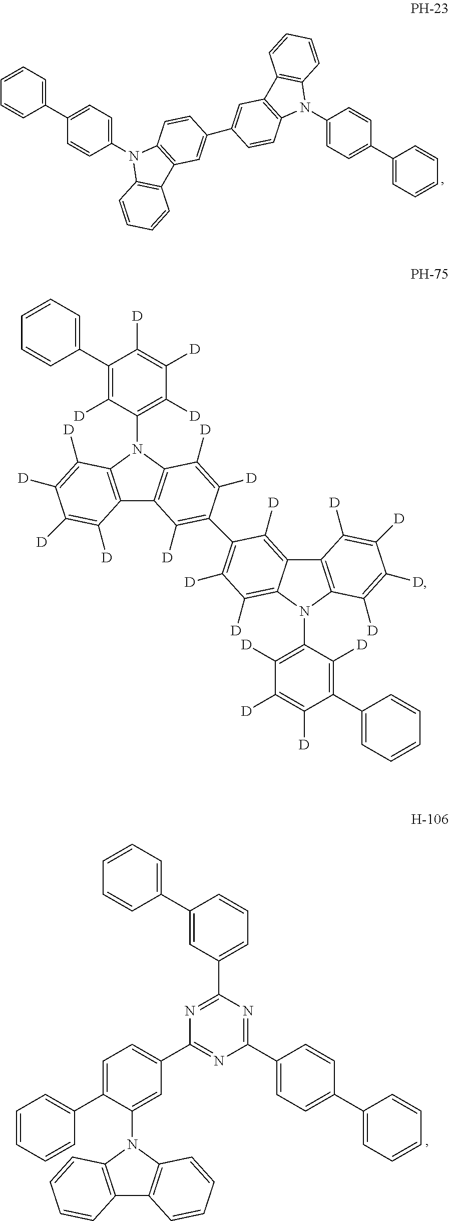

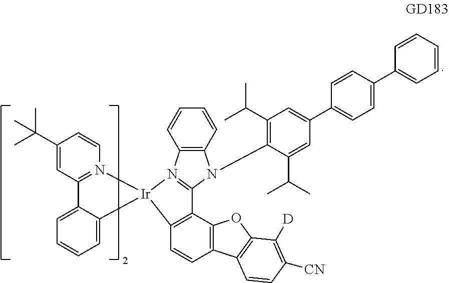

At a luminance of 1000 cd/m², the CIE data, maximum emission wavelength (λₘₐₓ), drive voltage (V), current efficiency (CE), power efficiency (PE), and external quantum efficiency (EQE) of each device were measured. The data are recorded and shown in Table 4.

TABLE 4
Device data of Example 4 and Comparative Examples 3 and 4

| | | λₘₐₓ | | | | EQE |
|---|---|---|---|---|---|---|
| Device ID | CIE (x, y) | (nm) | Voltage (V) | CE (cd/A) | PE (lm/W) | (%) |
| Example 4 | (0.300, 0.677) | 536 | 2.8 | 126 | 142 | 29.6 |
| Comparative | (0.281, 0.682) | 536 | 3.1 | 51 | 51 | 11.9 |
| Example 3 | | | | | | |
| Comparative | (0.335, 0.636) | 525 | 2.8 | 107 | 120 | 28.1 |
| Example 4 | | | | | | |

Example 4 differs from Comparative Example 3 only in that: in the EML of Example 4, the metal complex comprising a ligand Lₐ having a structure represented by Formula 1 is used as a phosphorescent sensitizer to sensitize the fluorescent material having a particular structure represented by Formula 2; while no phosphorescent sensitizer is used in Comparative Example 3.

As can be seen from the data in Table 4, Example 4 has the same maximum emission wavelength as Comparative Example 3, indicating that light emits by the device of Example 4 is from the fluorescent material. However, compared with the ordinary fluorescent device of Comparative Example 3, Device Example 4 of the present disclosure has a lower voltage and further achieves unexpected significant improvements in device efficiency. Specifically, the CE, the PE, and the EQE are greatly improved by 147.1%, 178.4%, and 148.7%, respectively.

Example 4 differs from Comparative Example 4 only in that: in Example 4, both the metal complex and the fluorescent material of the present disclosure are used and the device emits fluorescence; while in Comparative Example 4, only the metal complex is used, without using the fluorescent material, and the device emits phosphorescence. Compared with the phosphorescent device of Comparative Example 4, the sensitized fluorescent device of Example 4 shows further improvements in CE, PE, and EQE in addition to the same low voltage.

More devices having different structures and comprising the fluorescent material with a skeleton of Formula 2 matched with the metal complex comprising a ligand Lₐ having a structure represented by Formula 1 are further provided, and the data indicate that these devices also have excellent overall performance. The details are described below.

### Device Example 5

Device Example 5 was implemented in the same manner as Device Example 1 except that in the EML, the metal complex GD314 was replaced with the metal complex GD154 of the present disclosure, and Compound 3-2-6 was replaced with the fluorescent material Compound 5-1-3 of the present disclosure.

### Device Example 6

Device Example 6 was implemented in the same manner as Device Example 5 except that Compound 5-1-3 in the EML was replaced with the fluorescent material Compound 5-1-2 of the present disclosure.

### Device Example 7

Device Example 7 was implemented in the same manner as Device Example 5 except that Compound 5-1-3 in the EML was replaced with the fluorescent material Compound 5-1-280 of the present disclosure.

### Device Comparative Example 5

Device Comparative Example 5 was implemented in the same manner as Device Example 5 except that the first host compound PH-87, the second host compound H-102, and the metal complex GD154 were co-deposited for use as an EML at a weight ratio of 56:38:6.

The detailed structures and thicknesses of layers of the devices are shown in Table 5. A layer using more than one material is obtained by doping different compounds at their weight ratio as recorded.

TABLE 5
Part of the device structures of Examples 5 to 5 and Comparative Example 5

| Device ID | HIL | HTL | EBL | EML | HBL | ETL |
|---|---|---|---|---|---|---|
| Example 5 | Compound | Compound | Compound | Compound | Compound | Compound |
| | HT:Compound | HT | PH-1 | PH-87:Compound | H-1 (50 | ET:Liq |
| | HT1 (97:3) | (350 Å) | (50 Å) | H-102:GD154:Compound | Å) | (40:60) |
| | (100 Å) | | | 5-1-3 (56:37:6:1) | | (350 Å) |
| | | | | (400 Å) | | |
| Example 6 | Compound | Compound | Compound | Compound | Compound | Compound |
| | HT:Compound | HT | PH-1 | PH-87:Compound | H-1 (50 | ET:Liq |
| | HT1 (97:3) | (350 Å) | (50 Å) | H-102:GD154:Compound | Å) | (40:60) |
| | (100 Å) | | | 5-1-2 (56:37:6:1) | | (350 Å) |
| | | | | (400 Å) | | |
| Example 7 | Compound | Compound | Compound | Compound | Compound | Compound |
| | HT:Compound | HT | PH-1 | PH-87:Compound | H-1 (50 | ET:Liq |
| | HT1 (97:3) | (350 Å) | (50 Å) | H-102:GD154:Compound | Å) | (40:60) |
| | (100 Å) | | | 5-1-280 (56:37:6:1) | | (350 Å) |
| | | | | (400 Å) | | |
| Comparative | Compound | Compound | Compound | Compound | Compound | Compound |
| Example 5 | HT:Compound | HT | PH-1 | PH-87:Compound | H-1 (50 | ET:Liq |
| | HT1 (97:3) | (350 Å) | (50 Å) | H-102:Metal Complex | Å) | (40:60) |
| | (100 Å) | | | GD154 (56:38:6) (400 | | (350 Å) |
| | | | | Å) | | |

The new materials used in the devices have the following structures:

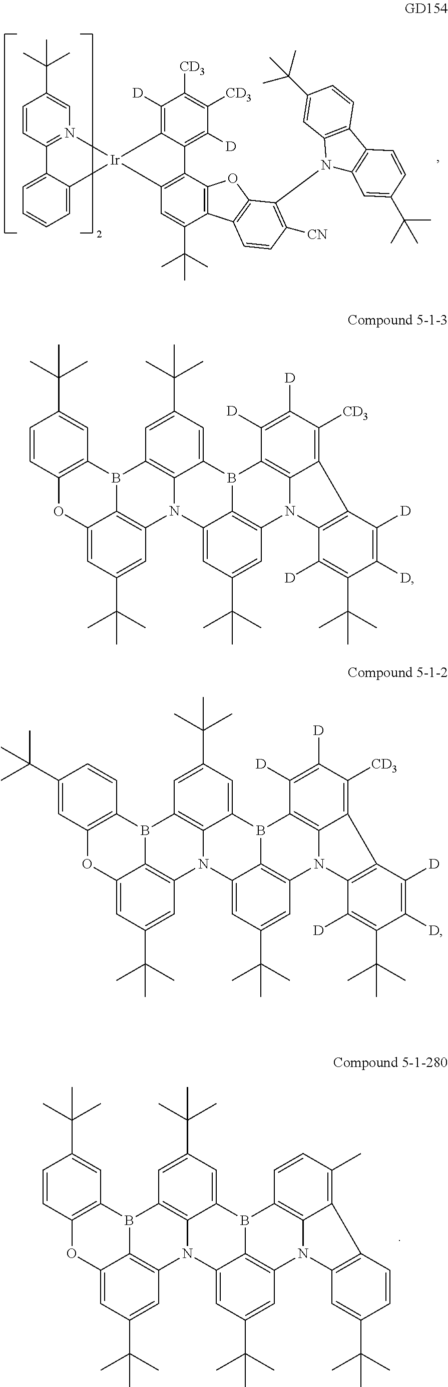

At a constant luminance of 1000 cd/m², the CIE data, maximum emission wavelength (λₘₐₓ), drive voltage (V), current efficiency (CE), power efficiency (PE), and external quantum efficiency (EQE) of each device were measured. The data are recorded and shown in Table 6.

TABLE 6
Device data of Examples 5 to 7 and Comparative Example 5

| | | λₘₐₓ | | | | EQE |
|---|---|---|---|---|---|---|
| Device ID | CIE (x, y) | (nm) | Voltage (V) | CE (cd/A) | PE (lm/W) | (%) |
| Example 5 | (0.235, 0.716) | 527 | 2.6 | 120 | 147 | 29.8 |
| Example 6 | (0.236, 0.715) | 527 | 2.6 | 121 | 148 | 29.9 |
| Example 7 | (0.237, 0.716) | 527 | 2.6 | 121 | 146 | 29.7 |
| Comparative | (0.261, 0.676) | 520 | 2.6 | 97 | 116 | 25.7 |
| Example 5 | | | | | | |

As can be seen from the data in the above table, Examples 5 to 7 of the sensitized fluorescent devices prepared by matching other fluorescent materials having the skeleton of Formula 2 but different structures with the metal complex comprising a ligand Lₐ having a structure represented by Formula 1 also exhibit excellent overall performance.

As can be seen from the data in Table 6, compared with the ordinary phosphorescent device of Comparative Example 5, Device Examples 5 to 7 of the present disclosure further achieve unexpected significant improvements in device efficiency while maintaining the same low voltage as Comparative Example 5. Specifically, compared with Comparative Example 5, the CE of Examples 5 to 7 is increased by 23.7%, 24.7%, and 24.7%, respectively, the PE is increased by 26.7%, 27.6%, and 25.7%, respectively, and the EQE is increased by 15.9%, 16.3%, and 15.6%, respectively.

More devices having different structures and comprising the fluorescent material with a skeleton of Formula 2 matched with the metal complex comprising a ligand Lₐ having a structure represented by Formula 1 are further provided, and the data indicate that these devices also have excellent overall performance. The details are described below.

### Device Example 8

Device Example 8 was implemented in the same manner as Device Example 1 except that the first host compound PH-87, the second host compound H-102, the metal complex GD555, and the fluorescent material Compound 4-1-94 were co-deposited for use as an EML at a weight ratio of 56:37:6:1.

### Device Comparative Example 6

Device Comparative Example 6 was implemented in the same manner as Device Example 1 except that the first host compound PH-87, the second host compound H-102, and the fluorescent material Compound 4-1-94 were co-deposited for use as an EML at a weight ratio of 59:40:1.

### Device Comparative Example 7

Device Comparative Example 7 was implemented in the same manner as Device Example 1 except that the first host compound PH-87, the second host compound H-102, and the metal complex GD555 were co-deposited for use as an EML at a weight ratio of 56:38:6.

TABLE 7
Part of the device structures of Example 8 and Comparative Examples 6 and 7

| Device ID | HIL | HTL | EBL | EML | HBL | ETL |
|---|---|---|---|---|---|---|
| Example 8 | Compound | Compound | Compound | Compound | Compound | CompoundET:Liq |
| | HT:Compound | HT | PH-1 | PH-87:Compound | H-1 | (40:60) |
| | HT1 (97:3) | (350 Å) | (50 Å) | H-102:GD555:Compound | (50 Å) | (350 Å) |
| | (100 Å) | | | 4-1-94 | | |
| | | | | (56:37:6:1) | | |
| | | | | (400 Å) | | |
| Comparative | Compound | Compound | Compound | Compound | Compound | CompoundET:Liq |
| Example 6 | HT:Compound | HT | PH-1 | PH-87:Compound | H-1 | (40:60) |
| | HT1 (97:3) | (350 Å) | (50 Å) | H-102:Compound | (50 Å) | (350 Å) |
| | (100 Å) | | | 4-1-94 | | |
| | | | | (59:40:1) | | |
| | | | | (400 Å) | | |
| Comparative | Compound | Compound | Compound | Compound | Compound | CompoundET:Liq |
| Example 7 | HT:Compound | HT | PH-1 | PH-87:Compound | H-1 | (40:60) |
| | HT1 (97:3) | (350 Å) | (50 Å) | H-102:GD555 | (50 Å) | (350 Å) |
| | (100 Å) | | | (56:38:6) | | |
| | | | | (400 Å) | | |

The materials used in the devices are as follows:

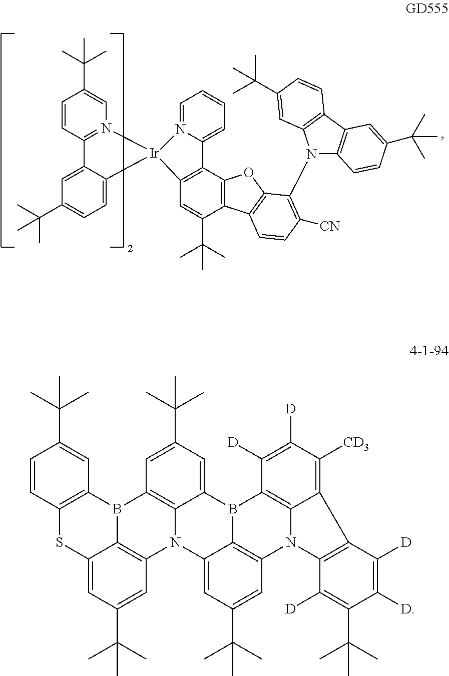

At a constant luminance of 1000 cd/m², the CIE data, maximum emission wavelength (λₘₐₓ), full width at half maximum (FWHM), drive voltage (V), current efficiency (CE), power efficiency (PE), and external quantum efficiency (EQE) of each device were measured. The data are recorded and shown in Table 8.

TABLE 8
Device data of Example 8 and Comparative Examples 6 and 7

| | | λₘₐₓ | FWHM | Voltage | CE | PE | EQE |
|---|---|---|---|---|---|---|---|
| Device ID | CIE (x, y) | (nm) | (nm) | (V) | (cd/A) | (lm/W) | (%) |
| Example 8 | (0.309, 0.673) | 536 | 34.5 | 2.60 | 131 | 161 | 30.4 |
| Comparative | (0.274, 0.698) | 535 | 33.4 | 2.59 | 110 | 134 | 26.1 |
| Example 6 | | | | | | | |
| Comparative | (0.297, 0.664) | 525 | 29.6 | 2.61 | 112 | 135 | 28.6 |
| Example 7 | | | | | | | |

The difference between Example 8 and Comparative Example 6 lies only in that: in the EML of Example 8, a metal complex comprising a Lₐ ligand represented by Formula 1 is used as a phosphorescent sensitizer to sensitize the fluorescent material having a specific structure represented by Formula 2, while no phosphorescent sensitizer is used in Comparative Example 6.

As can be seen from the data in Table 8, Example 8 and Comparative Example 6 have basically the same maximum emission wavelength, indicating that the light emitted by the device of Example 8 originates from the fluorescent material. However, compared with the ordinary fluorescent device of Comparative Example 6, Device Example 8 of the present disclosure achieves unexpected significant improvements in device efficiency while maintaining a narrow FWHM and low voltage basically equivalent to those of Comparative Example 6. Specifically, compared with Comparative Example 6, the CE, PE, and EQE of Example 8 are increased by 19.1%, 20.1%, and 16.5%, respectively.

The difference between Example 8 and Comparative Example 7 lies only in that: in Example 8, both the metal complex and the fluorescent material of the present disclosure are used, and the device emits fluorescence; while in Comparative Example 7, only the metal complex is used without the fluorescent material, and the device emits phosphorescence. Compared with the phosphorescent device of Comparative Example 7, the sensitized fluorescent device of Example 8 unexpectedly exhibits better effects in all aspects: in addition to a comparably low voltage, the CE, PE, and EQE are significantly improved by 17.0%, 19.3%, and 6.3%, respectively.

This once again proves that the sensitized fluorescent device of the present disclosure, which comprises both the metal complex comprising a ligand Lₐ having a structure represented by Formula 1 and the fluorescent material having a structure of Formula 2 in the emissive layer, can further improve the overall device performance and has a broad application prospect.

The above results indicate that compared with either the ordinary fluorescent device comprising no phosphorescent sensitizer or the ordinary phosphorescent device comprising no fluorescent material, the sensitized fluorescent device of the present disclosure, which comprises both the metal complex comprising a ligand Lₐ having a structure represented by Formula 1 and the fluorescent material having a structure of Formula 2 in the emissive layer, can further improve the overall device performance and has a broad application prospect.

It should be understood that various embodiments described herein are merely examples and not intended to limit the scope of the present disclosure. Therefore, it is apparent to the persons skilled in the art that the present disclosure as claimed may include variations from specific embodiments and preferred embodiments described herein. Many of materials and structures described herein may be substituted with other materials and structures without departing from the spirit of the present disclosure. It should be understood that various theories as to why the present disclosure works are not intended to be limitative.

What is claimed is:

1. An organic electroluminescent device, comprising a cathode, an anode, and at least one organic layer disposed between the cathode and the anode, wherein the organic layer comprises a metal complex and a fluorescent material;
the metal complex comprises a metal M and a ligand Lₐ coordinated to the metal M, the metal M is selected from a metal with a relative atomic mass greater than 40, and the ligand Lₐ has a structure represented by Formula 1: 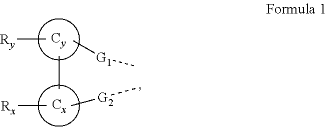
wherein
the ring C_{y} and the ring Cₓ are, at each occurrence identically or differently, selected from an aromatic ring having 6 to 30 ring atoms, a heteroaromatic ring having 5 to 30 ring atoms, or a combination thereof;
G₁ and G₂ are, at each occurrence identically or differently, selected from a single bond, O, S, or NR_{N};
Rₓ and R_{y} represent, at each occurrence identically or differently, mono-substitution, multiple substitutions, or non-substitution;
R_{N}, Rₓ, and R_{y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R_{N}, Rₓ, and R_{y} can be optionally joined to form a ring;
the fluorescent material has a structure represented by Formula 2: 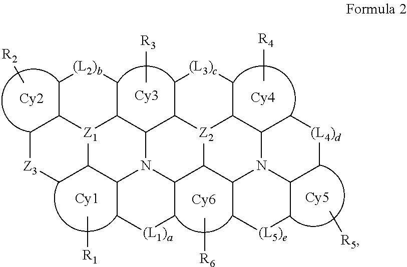
wherein
the ring Cy1, the ring Cy2, the ring Cy3, the ring Cy4, the ring Cy5, and the ring Cy6 are, at each occurrence identically or differently, selected from an unsaturated carbocyclic ring having 5 to 30 carbon atoms, an unsaturated heterocyclic ring having 3 to 30 carbon atoms, or a combination thereof;
Z₁ and Z₂ are, at each occurrence identically or differently, selected from B, N, P, P═O, P═S, As, As═O, or As═S;
Z₃ is, at each occurrence identically or differently, selected from O, S, Se, PR, P═OR, CRR, SiRR, GeRR, C═O, C═S, or C═CRR; when multiple R are present, the multiple R are identical or different;
L₁, L₂, L₃, L₄, and L₅ are, at each occurrence identically or differently, selected from a single bond, O, S, Se, BR′, NR′, PR′, P═OR′, P═SR′, AsR′, As═OR′, As═SR′, C═O, CR′R′, SiR′R′, or GeR′R′; when multiple R′ are present, the multiple R′ are identical or different;
a, b, c, d, and e are each independently selected from 0 or 1;
R₁, R₂, R₃, R₄, R₅, and R₆ represent, at each occurrence identically or differently, mono-substitution, multiple substitutions, or non-substitution;
R, R′, R₁, R₂, R₃, R₄, R₅, and R₆ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, —BR″R″, and combinations thereof;
R″ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents R, R′, R″, R₁, R₂, R₃, R₄, R₅, and R₆ can be optionally joined to form a ring.

2. The organic electroluminescent device according to claim 1, wherein the metal complex has a structure of Formula M(Lₐ)ₘ(L_{b})ₙ(L_{c})_{q}, the ligands Lₐ, L_{b}, and L_{c} are a first ligand, a second ligand, and a third ligand coordinated to the metal M, respectively, and the ligands Lₐ, L_{b}, and L_{c} can be optionally joined to form a multidentate ligand;
the metal M is selected from a metal with a relative atomic mass greater than 40; preferably, the metal M is selected from the group consisting of Cu, Ag, Au, Ru, Rh, Pd, Os, Ir, and Pt; more preferably, the metal M is selected from Pt or Ir;
m is selected from 1, 2, or 3, n is selected from 0, 1, or 2, q is selected from 0, 1, or 2, and m+n+q is equal to the oxidation state of the metal M; when m is greater than or equal to 2, multiple Lₐ are identical or different; when n is equal to 2, two L_{b} are identical or different; when q is equal to 2, two L_{c} are identical or different;
the ligand Lₐ has a structure represented by Formula 1-1: 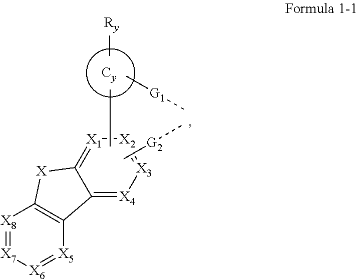
wherein
the ring C_{y} is, at each occurrence identically or differently, selected from a substituted or unsubstituted aromatic ring having 6 to 30 ring atoms, a substituted or unsubstituted heteroaromatic ring having 5 to 30 ring atoms, or a combination thereof;
G₁ and G₂ are, at each occurrence identically or differently, selected from a single bond, O, S, or NR_{N}; preferably, G₁ and G₂ are each selected from a single bond;
X is, at each occurrence identically or differently, selected from the group consisting of O, S, Se, NR′″, CR′″R′″, and SiR′″R′″; when two R′″ are present at the same time, the two R′″ are identical or different;
X₁ to X₄ are, at each occurrence identically or differently, selected from C, CRₓ, or N;
one of X₁ to X₄ is selected from C and joined to the ring C_{y}, and another of X₁ to X₄ is selected from C or N and joined to the metal via G₂;
X₅ to X₈ are, at each occurrence identically or differently, selected from CRₓ or N;
R_{y} represents, at each occurrence identically or differently, mono-substitution, multiple substitutions, or non-substitution;
R_{N}, Rₓ, R_{y}, and R′″ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R_{N}, Rₓ, R_{y}, and R′″ can be optionally joined to form a ring; and
L_{b} and L_{c} are, at each occurrence identically or differently, a monoanionic bidentate ligand.

3. The organic electroluminescent device according to claim 2, wherein the second ligand L_{b} and the third ligand L_{c} of the metal complex are, at each occurrence identically or differently, selected from a structure represented by any one of the group consisting of: 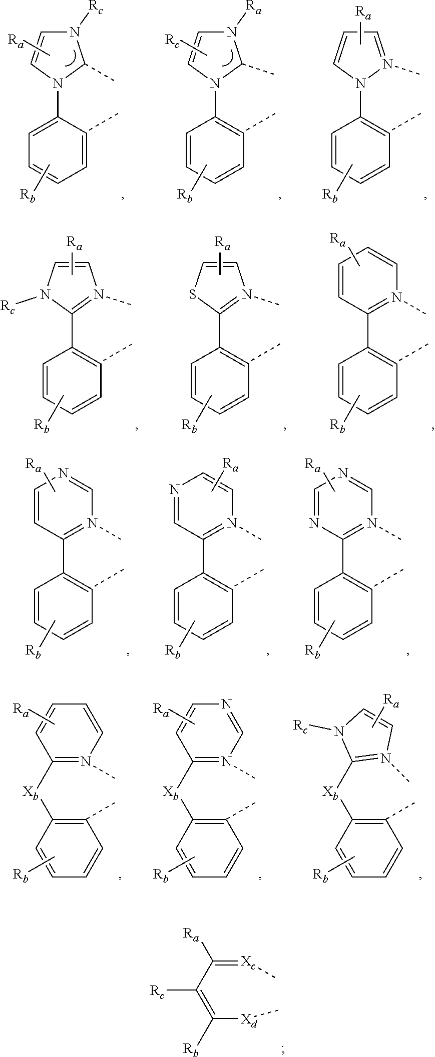
wherein
Rₐ and R_{b} represent, at each occurrence identically or differently, mono-substitution, multiple substitutions, or non-substitution;
X_{b} is, at each occurrence identically or differently, selected from the group consisting of: O, S, Se, NR_{N1}, and CR_{C1}R_{C2};
X_{c} and X_{d} are, at each occurrence identically or differently, selected from the group consisting of: O, S, Se, and NR_{N2};
Rₐ, R_{b}, R_{c}, R_{N1}, R_{N2}, R_{C1}, and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents Rₐ, R_{b}, R_{c}, R_{N1}, R_{N2}, R_{C1}, and R_{C2} can be optionally joined to form a ring.

4. The organic electroluminescent device according to claim 1, wherein the metal complex has a structure of Formula Ir(Lₐ)ₘ(L_{b})₃₋ₘ and has a structure represented by Formula 1-1-1 or Formula 1-1-2: 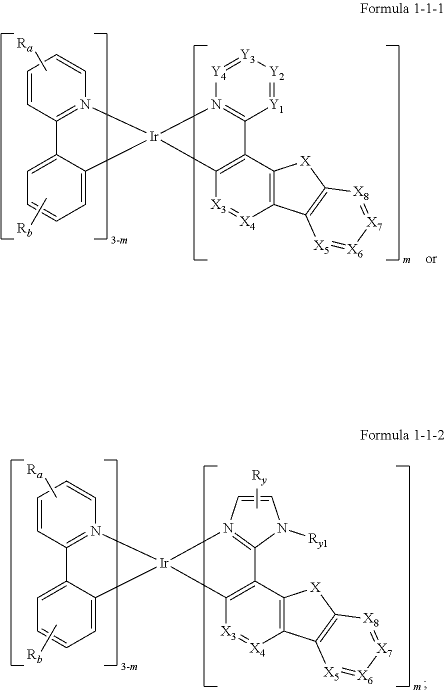
wherein
m is selected from 1 or 2; when m is selected from 1, two L_{b} are identical or different; when m is selected from 2, two Lₐ are identical or different;
X is selected from the group consisting of O, S, Se, NR′″, CR′″R′″, and SiR′″R′″; when two R′″ are present at the same time, the two R′″ are identical or different;
X₃ to X₈ are, at each occurrence identically or differently, selected from CRₓ or N;
in Formula 1-1-1, Y₁ to Y₄ are, at each occurrence identically or differently, selected from CR_{y} or N;
in Formula 1-1-2, R_{y} represents, at each occurrence identically or differently, mono-substitution, multiple substitutions, or non-substitution;
Rₐ and R_{b} represent, at each occurrence identically or differently, mono-substitution, multiple substitutions, or non-substitution;
R′″, Rₓ, R_{y}, R_{y1}, Rₐ, and R_{b} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents R′″, Rₓ, R_{y}, R_{y1}, Rₐ, and R_{b} can be optionally joined to form a ring.

5. The organic electroluminescent device according to claim 2, wherein at least one of X₃ to X₈ is selected from CRₓ, and the Rₓ is selected from cyano or fluorine;
preferably, at least two of X₃ to X₈ are selected from CRₓ, one of the Rₓ is selected from cyano or fluorine, and at least another one of the Rₓ is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof,
more preferably, at least three of X₃ to X₈ are selected from CRₓ, one of the Rₓ is selected from cyano or fluorine, and at least another two of the Rₓ are, at each occurrence identically or differently, selected from the group consisting of: deuterium, fluorine, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and combinations thereof;
still more preferably, at least three of X₃ to X₈ are selected from CRₓ, one of the Rₓ is selected from cyano or fluorine, one of the Rₓ is selected from substituted or unsubstituted alkyl having 1 to 12 carbon atoms, substituted or unsubstituted cycloalkyl having 3 to 10 ring carbon atoms, or a combination thereof, and another one of the Rₓ is selected from substituted or unsubstituted aryl having 6 to 15 carbon atoms, substituted or unsubstituted heteroaryl having 3 to 15 carbon atoms, or a combination thereof.

6. The organic electroluminescent device according to claim 2, wherein X₅ to X₈ are selected from CRₓ, and at least one of the Rₓ is cyano or fluorine;
preferably, X₇ is CRₓ, and the Rₓ is cyano or fluorine; or X₈ is CRₓ, and the Rₓ is cyano.

7. The organic electroluminescent device according to claim 4, wherein Y₁ to Y₄ are, at each occurrence identically or differently, selected from CR_{y}, and R_{y} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, cyano, isocyano, hydroxyl, sulfanyl, and combinations thereof;
preferably, at least one of Y₁ to Y₄ is selected from CR_{y}, and the R_{y} is, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted aryl having 6 to 30 carbon atoms, substituted or unsubstituted heteroaryl having 3 to 30 carbon atoms, cyano, isocyano, and combinations thereof;
more preferably, at least one of Y₂ and/or Y₃ is selected from CR_{y}, and the R_{y} is, at each occurrence identically or differently, selected from the group consisting of: deuterium, fluorine, substituted or unsubstituted alkyl having 1 to 12 carbon atoms, substituted or unsubstituted cycloalkyl having 3 to 12 ring carbon atoms, substituted or unsubstituted aryl having 6 to 20 carbon atoms, substituted or unsubstituted heteroaryl having 3 to 20 carbon atoms, cyano, and combinations thereof.

8. The organic electroluminescent device according to claim 4, wherein R_{y1} is, at each occurrence identically or differently, selected from the group consisting of: substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, and combinations thereof;
preferably, R_{y1} is, at each occurrence identically or differently, selected from the group consisting of: substituted or unsubstituted arylalkyl having 7 to 30 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, and combinations thereof;
more preferably, R_{y1} is, at each occurrence identically or differently, selected from substituted or unsubstituted aryl having 6 to 30 carbon atoms.

9. The organic electroluminescent device according to claim 1, wherein Lₐ is, at each occurrence identically or differently, selected from the group consisting of La-1-k1, La-2-1 to La-2-63, and La-3-k3, k1 is selected from an integer from 1 to 300, and k3 is selected from an integer from 1 to 282;
La-1-k1 has the following structure: 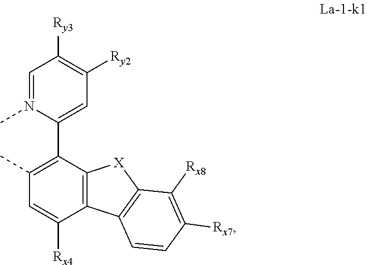
wherein when k1 is selected from 1 to 300, R_{y2}, R_{y3}, Rₓ₄, Rₓ₇, Rₓ₈, and X are selected from atoms or groups in the following table, respectively:

| k1 | La | R_{y2} | R_{y3} | Rₓ₄ | Rₓ₇ | Rₓ₈ | X |
|---|---|---|---|---|---|---|---|
| 1 | La-1-1 | H | H | H | H | H | O |
| 2 | La-1-2 | H | H | H | H | P1 | O |
| 3 | La-1-3 | H | H | H | H | P3 | O |
| 4 | La-1-4 | H | H | H | H | P9 | O |
| 5 | La-1-5 | H | H | H | H | P10 | O |
| 6 | La-1-6 | H | H | H | H | P14 | O |
| 7 | La-1-7 | H | H | H | H | P17 | O |
| 8 | La-1-8 | H | H | H | P1 | H | O |
| 9 | La-1-9 | H | H | H | P3 | H | O |
| 10 | La-1-10 | H | H | H | P9 | H | O |
| 11 | La-1-11 | H | H | H | P11 | H | O |
| 12 | La-1-12 | H | H | H | P13 | H | O |
| 13 | La-1-13 | H | H | H | P14 | H | O |
| 14 | La-1-14 | H | H | P1 | H | H | O |
| 15 | La-1-15 | H | H | P5 | H | H | O |
| 16 | La-1-16 | H | H | P6 | H | H | O |
| 17 | La-1-17 | H | H | P10 | H | H | O |
| 18 | La-1-18 | H | H | P13 | H | H | O |
| 19 | La-1-19 | H | H | P15 | H | H | O |
| 20 | La-1-20 | P2 | H | H | H | H | O |
| 21 | La-1-21 | P4 | H | H | H | H | O |
| 22 | La-1-22 | P5 | H | H | H | H | O |
| 23 | La-1-23 | P7 | H | H | H | H | O |
| 24 | La-1-24 | P10 | H | H | H | H | O |
| 25 | La-1-25 | P13 | H | H | H | H | O |
| 26 | La-1-26 | P17 | H | H | H | H | O |
| 27 | La-1-27 | H | P2 | H | H | H | O |
| 28 | La-1-28 | H | P6 | H | H | H | O |
| 29 | La-1-29 | H | P5 | H | H | H | O |
| 30 | La-1-30 | H | P9 | H | H | H | O |
| 31 | La-1-31 | H | P10 | H | H | H | O |
| 32 | La-1-32 | H | P13 | H | H | H | O |
| 33 | La-1-33 | H | P19 | H | H | H | O |
| 34 | La-1-34 | P1 | P1 | H | H | H | O |
| 35 | La-1-35 | P2 | P2 | H | H | H | O |
| 36 | La-1-36 | P2 | P7 | H | H | H | O |
| 37 | La-1-37 | P7 | P2 | H | H | H | O |
| 38 | La-1-38 | P2 | P10 | H | H | H | O |
| 39 | La-1-39 | P2 | P13 | H | H | H | O |
| 40 | La-1-40 | P10 | P2 | H | H | H | O |
| 41 | La-1-41 | P13 | P2 | H | H | H | O |
| 42 | La-1-42 | P2 | P2 | P5 | H | H | O |
| 43 | La-1-43 | P2 | P2 | P5 | H | H | O |
| 44 | La-1-44 | P2 | P13 | P5 | H | H | O |
| 45 | La-1-45 | P10 | P2 | P5 | H | H | O |
| 46 | La-1-46 | P2 | P2 | P5 | P10 | H | O |
| 47 | La-1-47 | P2 | P2 | P5 | P14 | H | O |
| 48 | La-1-48 | P2 | P13 | P5 | H | P10 | O |
| 49 | La-1-49 | P10 | P2 | P5 | H | P14 | O |
| 50 | La-1-50 | H | H | H | CN | H | O |
| 51 | La-1-51 | H | H | H | CN | D | O |
| 52 | La-1-52 | H | H | P5 | CN | H | O |
| 53 | La-1-53 | H | H | H | CN | P10 | O |
| 54 | La-1-54 | H | H | H | CN | P11 | O |
| 55 | La-1-55 | H | H | H | CN | P12 | O |
| 56 | La-1-56 | H | H | H | CN | P13 | O |
| 57 | La-1-57 | H | H | H | CN | P14 | O |
| 58 | La-1-58 | H | H | H | CN | P15 | O |
| 59 | La-1-59 | H | H | H | CN | P16 | O |
| 60 | La-1-60 | H | H | H | CN | P17 | O |
| 61 | La-1-61 | H | H | H | CN | P18 | O |
| 62 | La-1-62 | H | H | H | CN | P19 | O |
| 63 | La-1-63 | H | H | P5 | CN | P10 | O |
| 64 | La-1-64 | H | H | P5 | CN | P11 | O |
| 65 | La-1-65 | H | H | P5 | CN | P12 | O |
| 66 | La-1-66 | H | H | P5 | CN | P13 | O |
| 67 | La-1-67 | H | H | P5 | CN | P14 | O |
| 68 | La-1-68 | H | H | P5 | CN | P15 | O |
| 69 | La-1-69 | H | H | P5 | CN | P16 | O |
| 70 | La-1-70 | H | H | P5 | CN | P17 | O |
| 71 | La-1-71 | H | H | P5 | CN | P18 | O |
| 72 | La-1-72 | H | H | P5 | CN | P19 | O |
| 73 | La-1-73 | P1 | H | H | CN | P10 | O |
| 74 | La-1-74 | P1 | H | H | CN | P11 | O |
| 75 | La-1-75 | P1 | H | H | CN | P12 | O |
| 76 | La-1-76 | P1 | H | H | CN | P13 | O |
| 77 | La-1-77 | P1 | H | H | CN | P14 | O |
| 78 | La-1-78 | P1 | H | H | CN | P15 | O |
| 79 | La-1-79 | P1 | H | H | CN | P16 | O |
| 80 | La-1-80 | P1 | H | H | CN | P17 | O |
| 81 | La-1-81 | P1 | H | H | CN | P18 | O |
| 82 | La-1-82 | P1 | H | H | CN | P19 | O |
| 83 | La-1-83 | H | P2 | H | CN | P10 | O |
| 84 | La-1-84 | H | P2 | H | CN | P11 | O |
| 85 | La-1-85 | H | P2 | H | CN | P12 | O |
| 86 | La-1-86 | H | P2 | H | CN | P13 | O |
| 87 | La-1-87 | H | P2 | H | CN | P14 | O |
| 88 | La-1-88 | H | P2 | H | CN | P15 | O |
| 89 | La-1-89 | H | P2 | H | CN | P16 | O |
| 90 | La-1-90 | H | P2 | H | CN | P17 | O |
| 91 | La-1-91 | H | P2 | H | CN | P18 | O |
| 92 | La-1-92 | H | P2 | H | CN | P19 | O |
| 93 | La-1-93 | P2 | P10 | H | CN | P10 | O |
| 94 | La-1-94 | P2 | P11 | H | CN | P11 | O |
| 95 | La-1-95 | P2 | P12 | H | CN | P12 | O |
| 96 | La-1-96 | P2 | P13 | H | CN | P13 | O |
| 97 | La-1-97 | P2 | P10 | H | CN | P14 | O |
| 98 | La-1-98 | P2 | P11 | H | CN | P15 | O |
| 99 | La-1-99 | P2 | P12 | H | CN | P16 | O |
| 100 | La-1-100 | P2 | P13 | H | CN | P17 | O |
| 101 | La-1-101 | P2 | P10 | H | CN | P18 | O |
| 102 | La-1-102 | P2 | P13 | H | CN | P19 | O |
| 103 | La-1-103 | P10 | P1 | H | CN | P10 | O |
| 104 | La-1-104 | P11 | P1 | H | CN | P11 | O |
| 105 | La-1-105 | P12 | P1 | H | CN | P12 | O |
| 106 | La-1-106 | P13 | P1 | H | CN | P13 | O |
| 107 | La-1-107 | P10 | P1 | H | CN | P14 | O |
| 108 | La-1-108 | P11 | P1 | H | CN | P15 | O |
| 109 | La-1-109 | P12 | P1 | H | CN | P16 | O |
| 110 | La-1-110 | P13 | P1 | H | CN | P17 | O |
| 111 | La-1-111 | P5 | P1 | H | CN | P18 | O |
| 112 | La-1-112 | P13 | P1 | H | CN | P19 | O |
| 113 | La-1-113 | P1 | H | P5 | CN | P10 | O |
| 114 | La-1-114 | P1 | H | P5 | CN | P11 | O |
| 115 | La-1-115 | P1 | H | P5 | CN | P12 | O |
| 116 | La-1-116 | P1 | H | P5 | CN | P13 | O |
| 117 | La-1-117 | P1 | H | P5 | CN | P14 | O |
| 118 | La-1-118 | P1 | H | P5 | CN | P15 | O |
| 119 | La-1-119 | P1 | H | P5 | CN | P16 | O |
| 120 | La-1-120 | P1 | H | P5 | CN | P17 | O |
| 121 | La-1-121 | P1 | H | P5 | CN | P18 | O |
| 122 | La-1-122 | P1 | H | P5 | CN | P19 | O |
| 123 | La-1-123 | H | P2 | P5 | CN | P10 | O |
| 124 | La-1-124 | H | P2 | P5 | CN | P11 | O |
| 125 | La-1-125 | H | P2 | P5 | CN | P12 | O |
| 126 | La-1-126 | H | P2 | P5 | CN | P13 | O |
| 127 | La-1-127 | H | P2 | P5 | CN | P14 | O |
| 128 | La-1-128 | H | P2 | P5 | CN | P15 | O |
| 129 | La-1-129 | H | P2 | P5 | CN | P16 | O |
| 130 | La-1-130 | H | P2 | P5 | CN | P17 | O |
| 131 | La-1-131 | H | P2 | P5 | CN | P18 | O |
| 132 | La-1-132 | H | P2 | P5 | CN | P19 | O |
| 133 | La-1-133 | P2 | P10 | P5 | CN | P10 | O |
| 134 | La-1-134 | P2 | P11 | P5 | CN | P11 | O |
| 135 | La-1-135 | P2 | P12 | P5 | CN | P12 | O |
| 136 | La-1-136 | P2 | P2 | P5 | CN | P17 | O |
| 137 | La-1-137 | P2 | P10 | P5 | CN | P14 | O |
| 138 | La-1-138 | P2 | P11 | P5 | CN | P15 | O |
| 139 | La-1-139 | P2 | P12 | P5 | CN | P16 | O |
| 140 | La-1-140 | P2 | P13 | P5 | CN | P17 | O |
| 141 | La-1-141 | P2 | P10 | P5 | CN | P18 | O |
| 142 | La-1-142 | P2 | P13 | P5 | CN | P19 | O |
| 143 | La-1-143 | P10 | P1 | P5 | CN | P10 | O |
| 144 | La-1-144 | P11 | P1 | P5 | CN | P11 | O |
| 145 | La-1-145 | P12 | P1 | P5 | CN | P12 | O |
| 146 | La-1-146 | P13 | P1 | P5 | CN | P13 | O |
| 147 | La-1-147 | P10 | P1 | P5 | CN | P14 | O |
| 148 | La-1-148 | P11 | P1 | P5 | CN | P15 | O |
| 149 | La-1-149 | P12 | P1 | P5 | CN | P16 | O |
| 150 | La-1-150 | P13 | P1 | P5 | CN | P17 | O |
| 151 | La-1-151 | P10 | P1 | P5 | CN | P18 | O |
| 152 | La-1-152 | P13 | P1 | P5 | CN | P19 | O |
| 153 | La-1-153 | H | H | P2 | CN | P10 | O |
| 154 | La-1-154 | H | H | P3 | CN | P10 | O |
| 155 | La-1-155 | H | H | P4 | CN | P10 | O |
| 156 | La-1-156 | H | H | P6 | CN | P10 | O |
| 157 | La-1-157 | H | H | P7 | CN | P10 | O |
| 158 | La-1-158 | H | H | P8 | CN | P10 | O |
| 159 | La-1-159 | H | H | P9 | CN | P17 | O |
| 160 | La-1-160 | P1 | H | P6 | CN | P17 | O |
| 161 | La-1-161 | P1 | P1 | P6 | CN | P17 | O |
| 162 | La-1-162 | P1 | P10 | P6 | CN | P17 | O |
| 163 | La-1-163 | P11 | P2 | P6 | CN | P17 | O |
| 164 | La-1-164 | H | H | H | H | CN | O |
| 165 | La-1-165 | H | H | P1 | H | CN | O |
| 166 | La-1-166 | H | H | P2 | H | CN | O |
| 167 | La-1-167 | H | H | P3 | H | CN | O |
| 168 | La-1-168 | H | H | P4 | H | CN | O |
| 169 | La-1-169 | H | H | P5 | H | CN | O |
| 170 | La-1-170 | H | H | P6 | H | CN | O |
| 171 | La-1-171 | H | H | P10 | H | CN | O |
| 172 | La-1-172 | H | H | P15 | H | CN | O |
| 173 | La-1-173 | P1 | H | H | H | CN | O |
| 174 | La-1-174 | P2 | H | H | H | CN | O |
| 175 | La-1-175 | P3 | H | H | H | CN | O |
| 176 | La-1-176 | P4 | H | H | H | CN | O |
| 177 | La-1-177 | P5 | H | H | H | CN | O |
| 178 | La-1-178 | P6 | H | H | H | CN | O |
| 179 | La-1-179 | P8 | H | H | H | CN | O |
| 180 | La-1-180 | P10 | H | H | H | CN | O |
| 181 | La-1-181 | H | P2 | H | H | CN | O |
| 182 | La-1-182 | H | P4 | H | H | CN | O |
| 183 | La-1-183 | H | P5 | H | H | CN | O |
| 184 | La-1-184 | H | P7 | H | H | CN | O |
| 185 | La-1-185 | H | P11 | H | H | CN | O |
| 186 | La-1-186 | H | P13 | H | H | CN | O |
| 187 | La-1-187 | H | P17 | H | H | CN | O |
| 188 | La-1-188 | P1 | P1 | H | H | CN | O |
| 189 | La-1-189 | P2 | P2 | H | H | CN | O |
| 190 | La-1-190 | P1 | P10 | H | H | CN | O |
| 191 | La-1-191 | P11 | P2 | H | H | CN | O |
| 192 | La-1-192 | P1 | P12 | H | H | CN | O |
| 193 | La-1-193 | P13 | P1 | H | H | CN | O |
| 194 | La-1-194 | H | H | H | P10 | CN | O |
| 195 | La-1-195 | H | H | H | P11 | CN | O |
| 196 | La-1-196 | P5 | H | H | P12 | CN | O |
| 197 | La-1-197 | H | P5 | H | P13 | CN | O |
| 198 | La-1-198 | P1 | P1 | H | P14 | CN | O |
| 199 | La-1-199 | H | H | H | P15 | CN | O |
| 200 | La-1-200 | P1 | P10 | H | P16 | CN | O |
| 201 | La-1-201 | P13 | P1 | H | P17 | CN | O |
| 202 | La-1-202 | H | H | H | P18 | CN | O |
| 203 | La-1-203 | P2 | P2 | H | P19 | CN | O |
| 204 | La-1-204 | H | H | H | F | H | O |
| 205 | La-1-205 | H | H | H | F | D | O |
| 206 | La-1-206 | H | H | H | F | P10 | O |
| 207 | La-1-207 | H | H | H | F | P11 | O |
| 208 | La-1-208 | H | H | H | F | P12 | O |
| 209 | La-1-209 | H | H | H | F | P13 | O |
| 210 | La-1-210 | H | H | H | F | P14 | O |
| 211 | La-1-211 | H | H | H | F | P15 | O |
| 212 | La-1-212 | H | H | H | F | P16 | O |
| 213 | La-1-213 | H | H | H | F | P17 | O |
| 214 | La-1-214 | H | H | H | F | P18 | O |
| 215 | La-1-215 | H | H | H | F | P19 | O |
| 216 | La-1-216 | H | H | P1 | F | P10 | O |
| 217 | La-1-217 | H | H | P2 | F | P11 | O |
| 218 | La-1-218 | H | H | P3 | F | P12 | O |
| 219 | La-1-219 | H | H | P4 | F | P13 | O |
| 220 | La-1-220 | H | H | P5 | F | P14 | O |
| 221 | La-1-221 | H | H | P6 | F | P15 | O |
| 222 | La-1-222 | H | H | P7 | F | P16 | O |
| 223 | La-1-223 | H | H | P8 | F | P17 | O |
| 224 | La-1-224 | H | H | P9 | F | P18 | O |
| 225 | La-1-225 | H | H | P10 | F | P19 | O |
| 226 | La-1-226 | P1 | H | H | F | P10 | O |
| 227 | La-1-227 | H | P2 | H | F | P11 | O |
| 228 | La-1-228 | P2 | P2 | H | F | P12 | O |
| 229 | La-1-229 | P1 | P5 | H | F | P13 | O |
| 230 | La-1-230 | P10 | P1 | H | F | P14 | O |
| 231 | La-1-231 | H | P10 | H | F | P15 | O |
| 232 | La-1-232 | P2 | P11 | H | F | P16 | O |
| 233 | La-1-233 | P4 | H | H | F | P17 | O |
| 234 | La-1-234 | H | P6 | H | F | P18 | O |
| 235 | La-1-235 | P13 | H | H | F | P19 | O |
| 236 | La-1-236 | P1 | H | P5 | F | P10 | O |
| 237 | La-1-237 | H | P2 | P6 | F | P11 | O |
| 238 | La-1-238 | P2 | P2 | P7 | F | P12 | O |
| 239 | La-1-239 | P1 | P5 | P5 | F | P13 | O |
| 240 | La-1-240 | P10 | P1 | P6 | F | P14 | O |
| 241 | La-1-241 | H | P10 | P7 | F | P15 | O |
| 242 | La-1-242 | P2 | P11 | P5 | F | P16 | O |
| 243 | La-1-243 | P4 | H | P6 | F | P17 | O |
| 244 | La-1-244 | H | P6 | P7 | F | P18 | O |
| 245 | La-1-245 | P13 | H | P6 | F | P19 | O |
| 246 | La-1-246 | H | H | H | H | H | S |
| 247 | La-1-247 | H | H | P6 | H | H | S |
| 248 | La-1-248 | H | H | P7 | H | H | S |
| 249 | La-1-249 | H | H | P1 | H | H | S |
| 250 | La-1-250 | H | H | P2 | H | H | S |
| 251 | La-1-251 | H | H | H | CN | H | S |
| 252 | La-1-252 | H | H | H | CN | P10 | S |
| 253 | La-1-253 | H | H | H | CN | P1 | S |
| 254 | La-1-254 | H | H | H | CN | P12 | S |
| 255 | La-1-255 | H | H | H | CN | P13 | S |
| 256 | La-1-256 | H | H | H | CN | P14 | S |
| 257 | La-1-257 | H | H | H | CN | P15 | S |
| 258 | La-1-258 | H | H | H | CN | P16 | S |
| 259 | La-1-259 | H | H | H | CN | P17 | S |
| 260 | La-1-260 | H | H | H | CN | P18 | S |
| 261 | La-1-261 | H | H | H | CN | P19 | S |
| 262 | La-1-262 | P1 | H | H | CN | P10 | S |
| 263 | La-1-263 | H | P2 | H | CN | P11 | S |
| 264 | La-1-264 | P3 | H | H | CN | P12 | S |
| 265 | La-1-265 | H | P5 | H | CN | P13 | S |
| 266 | La-1-266 | P5 | H | H | CN | P14 | S |
| 267 | La-1-267 | P1 | P5 | H | CN | P15 | S |
| 268 | La-1-268 | P5 | P2 | H | CN | P16 | S |
| 269 | La-1-269 | P6 | H | H | CN | P17 | S |
| 270 | La-1-270 | P7 | H | H | CN | P18 | S |
| 271 | La-1-271 | P2 | P2 | H | CN | P19 | S |
| 272 | La-1-272 | P1 | H | P1 | CN | P10 | S |
| 273 | La-1-273 | H | P2 | P2 | CN | P11 | S |
| 274 | La-1-274 | P3 | H | P3 | CN | P12 | S |
| 275 | La-1-275 | H | P5 | P4 | CN | P10 | S |
| 276 | La-1-276 | P5 | H | P5 | CN | P14 | S |
| 277 | La-1-277 | P1 | P5 | P6 | CN | P15 | S |
| 278 | La-1-278 | P5 | P2 | P7 | CN | P16 | S |
| 279 | La-1-279 | P6 | H | P8 | CN | P17 | S |
| 280 | La-1-280 | P10 | P2 | P9 | CN | P18 | S |
| 281 | La-1-281 | P2 | P2 | P10 | CN | P19 | S |
| 282 | La-1-282 | H | H | H | H | CN | S |
| 283 | La-1-283 | H | H | P1 | H | CN | S |
| 284 | La-1-284 | H | H | P2 | H | CN | S |
| 285 | La-1-285 | P1 | H | H | H | CN | S |
| 286 | La-1-286 | H | P2 | H | H | CN | S |
| 287 | La-1-287 | P1 | P1 | H | H | CN | S |
| 288 | La-1-288 | P5 | H | H | H | CN | S |
| 289 | La-1-289 | P6 | H | H | H | CN | S |
| 290 | La-1-290 | H | P5 | H | H | CN | S |
| 291 | La-1-291 | H | P6 | H | H | CN | S |
| 292 | La-1-292 | P11 | H | H | H | CN | S |
| 293 | La-1-293 | H | P10 | H | H | CN | S |
| 294 | La-1-294 | P10 | P1 | H | H | CN | S |
| 295 | La-1-295 | P2 | P11 | H | H | CN | S |
| 296 | La-1-296 | P13 | P1 | H | H | CN | S |
| 297 | La-1-297 | H | P15 | H | H | CN | S |
| 298 | La-1-298 | P19 | H | H | H | CN | S |
| 299 | La-1-299 | H | H | P17 | H | CN | S |
| 300 | La-1-300 | H | H | P13 | H | CN | S |

La-2-1 to La-2-63 have the following specific structures: 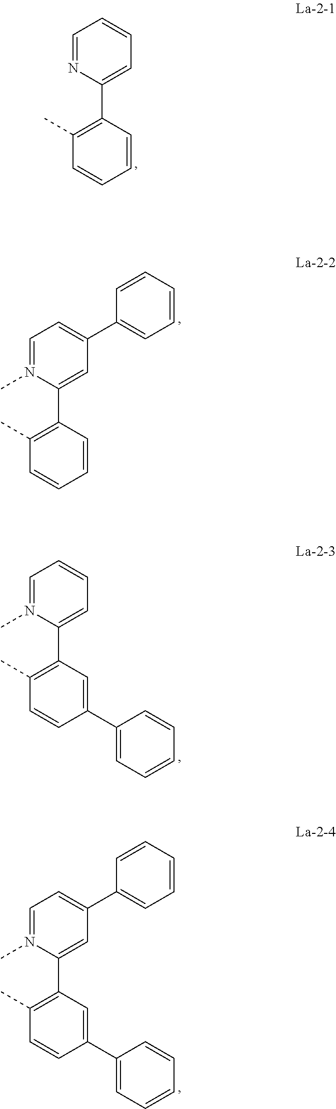 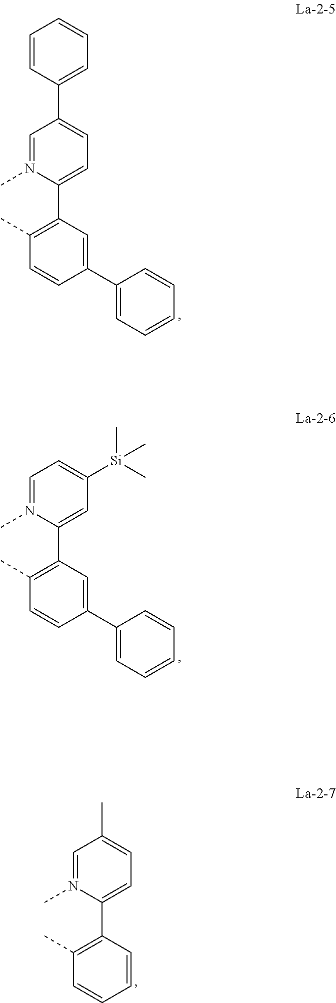 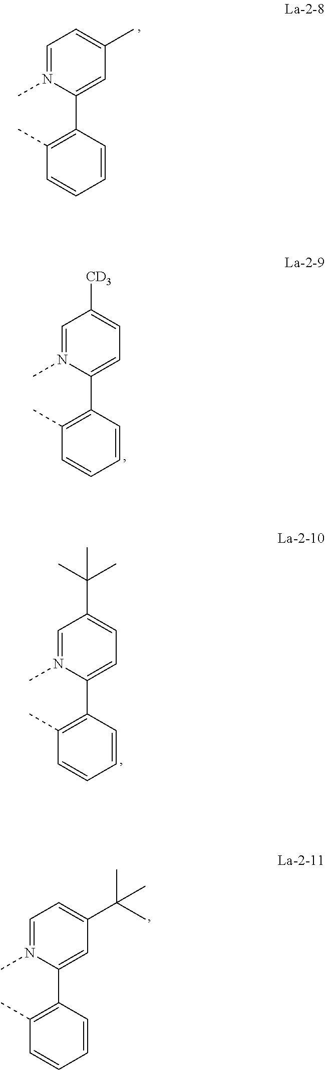 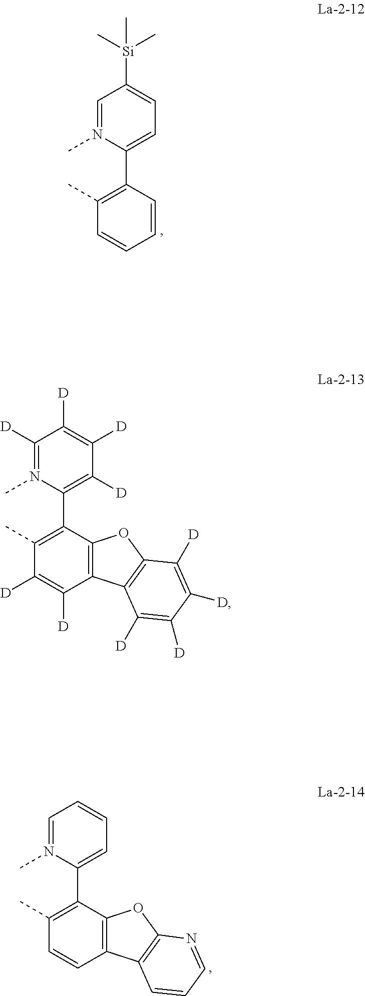 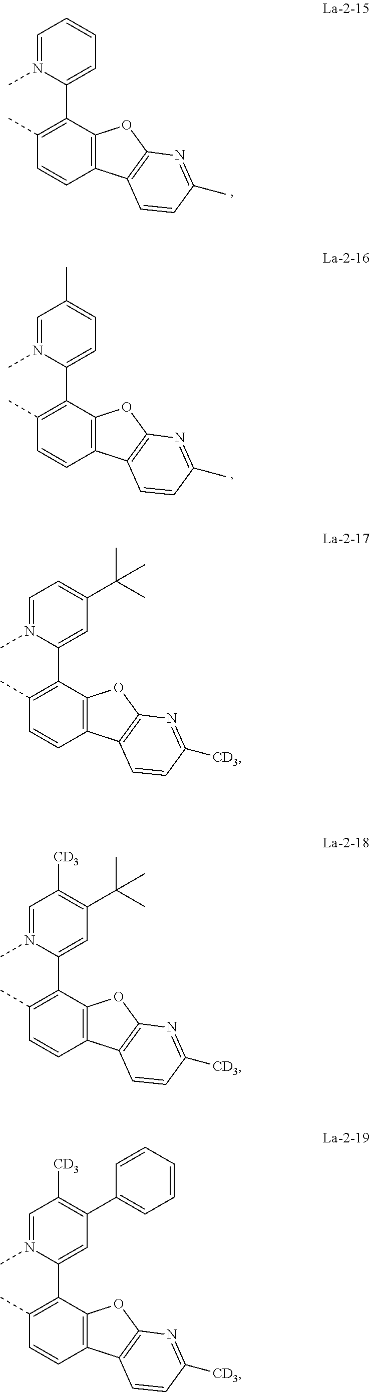 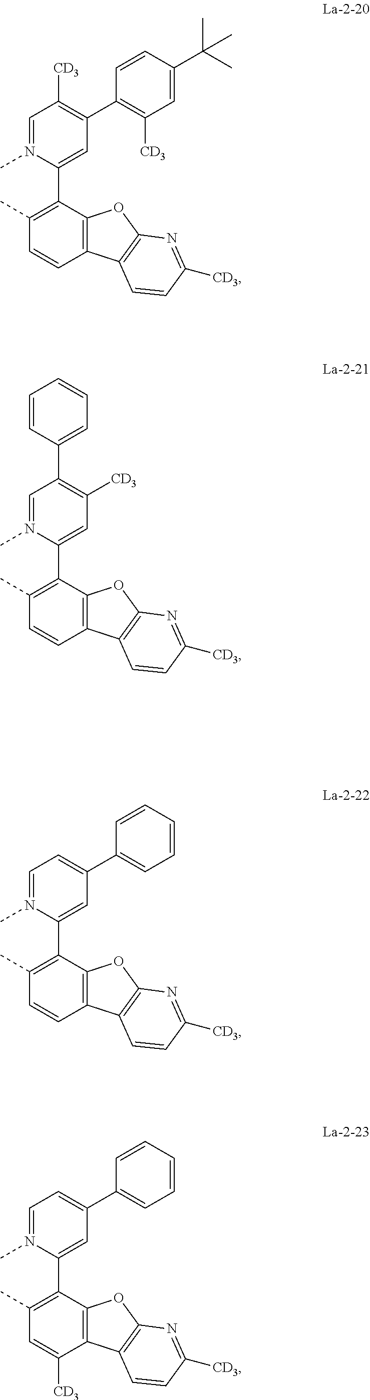 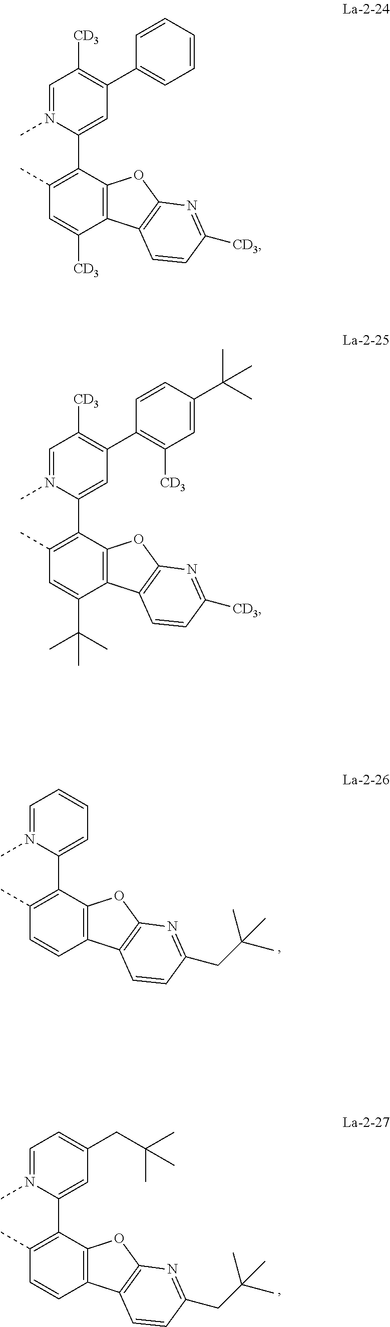 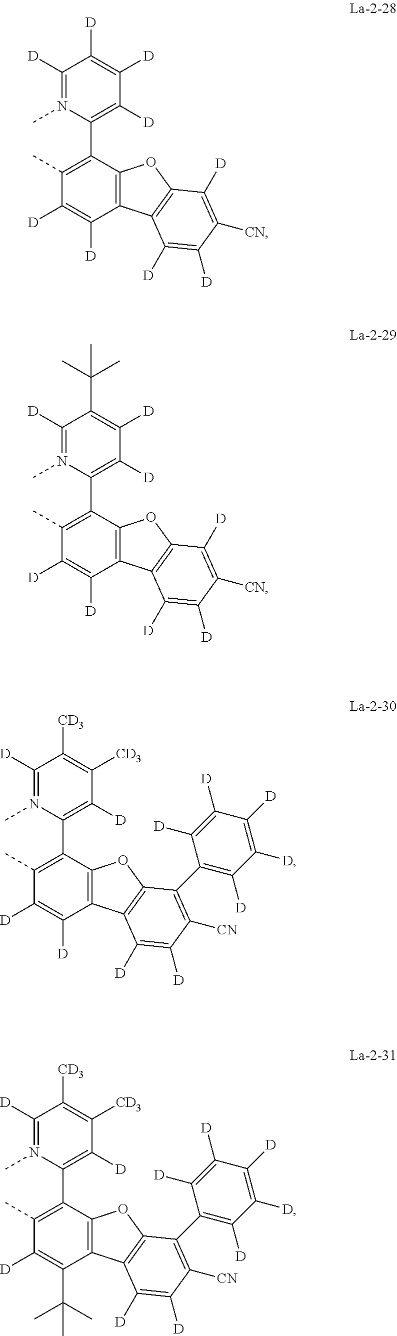 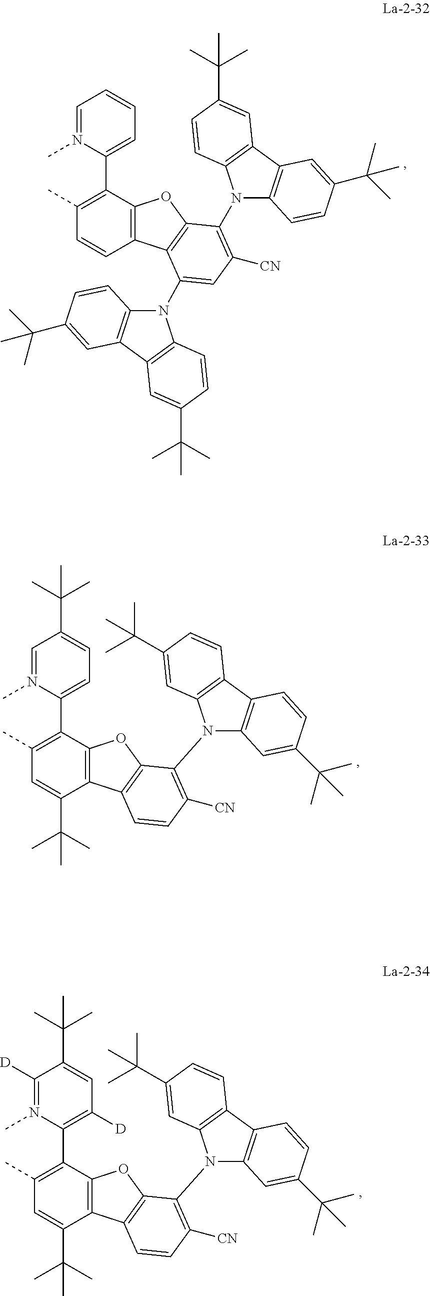 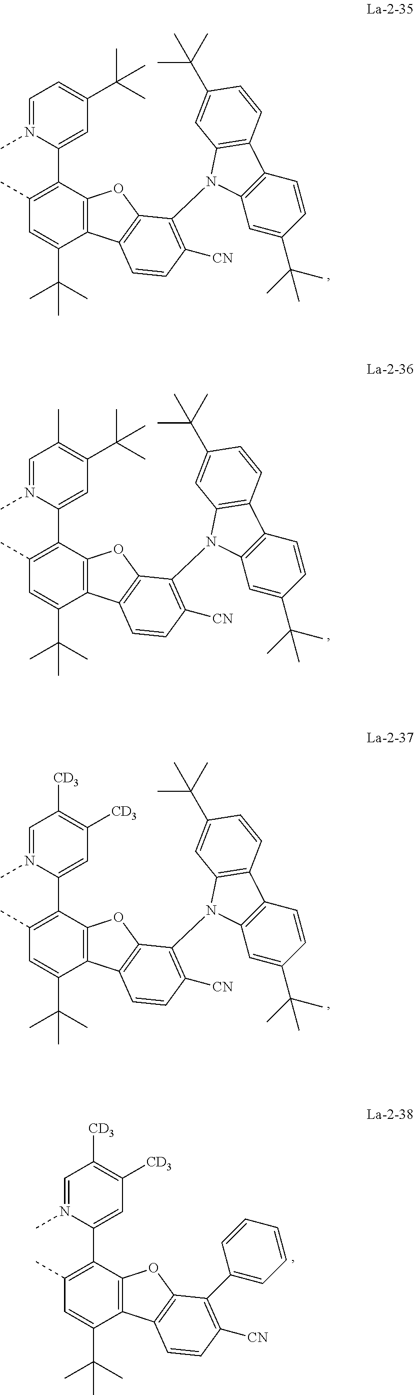 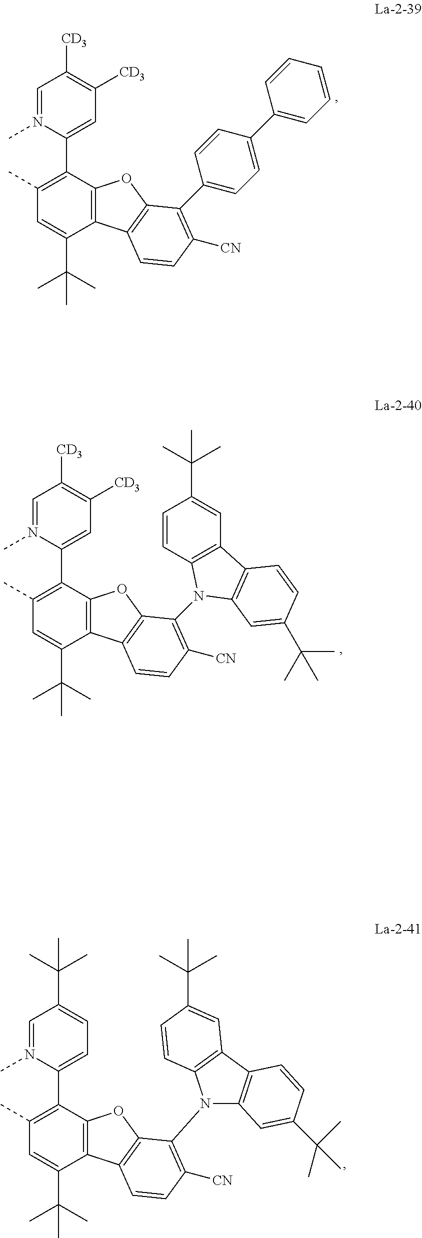 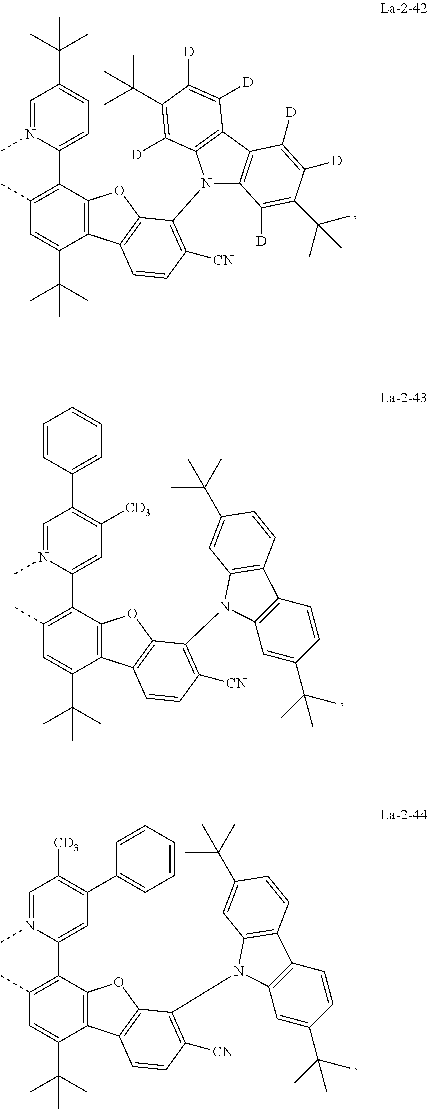 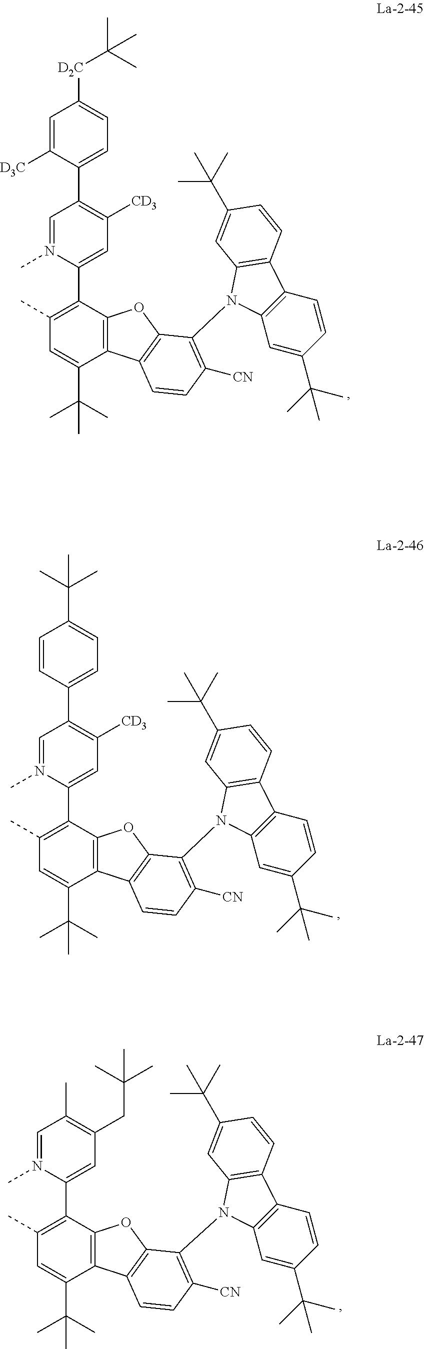 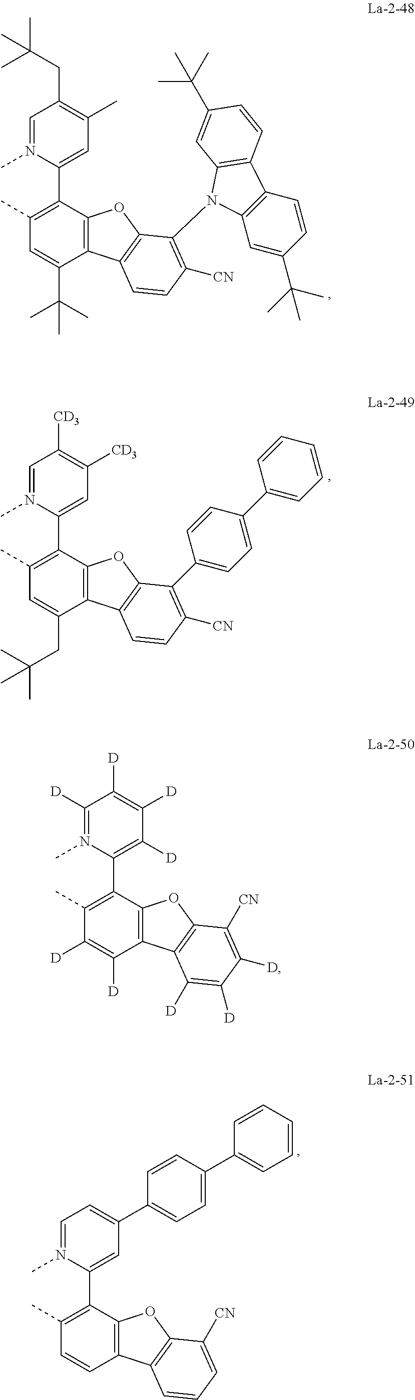 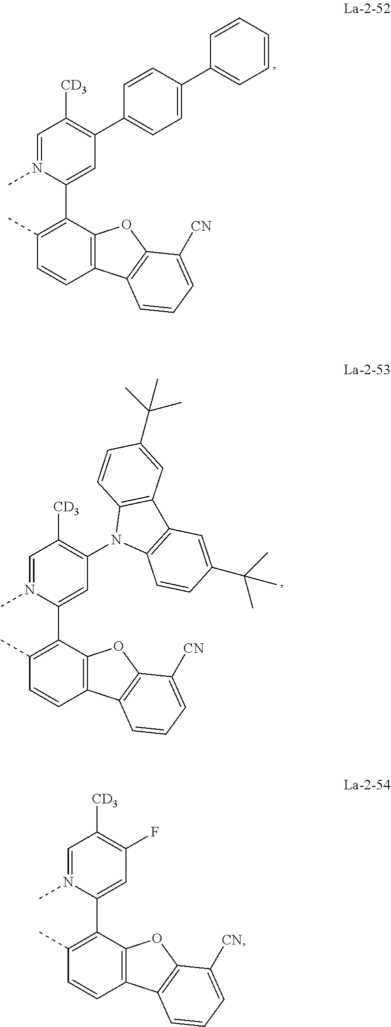 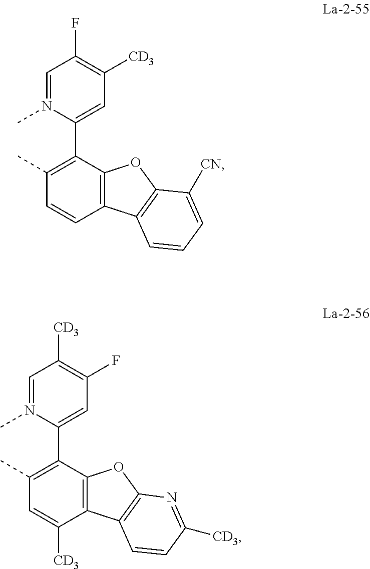 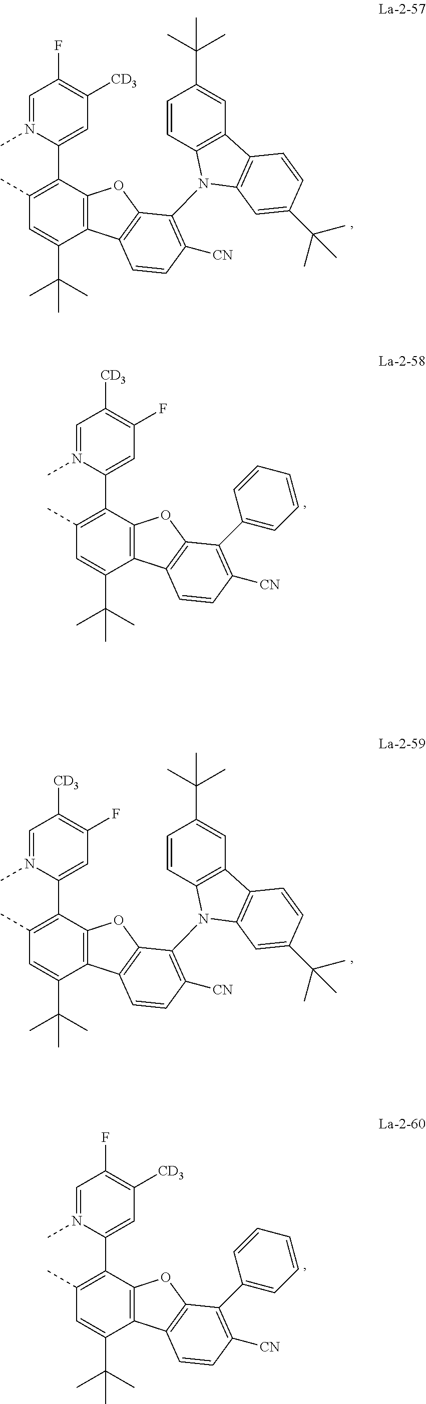 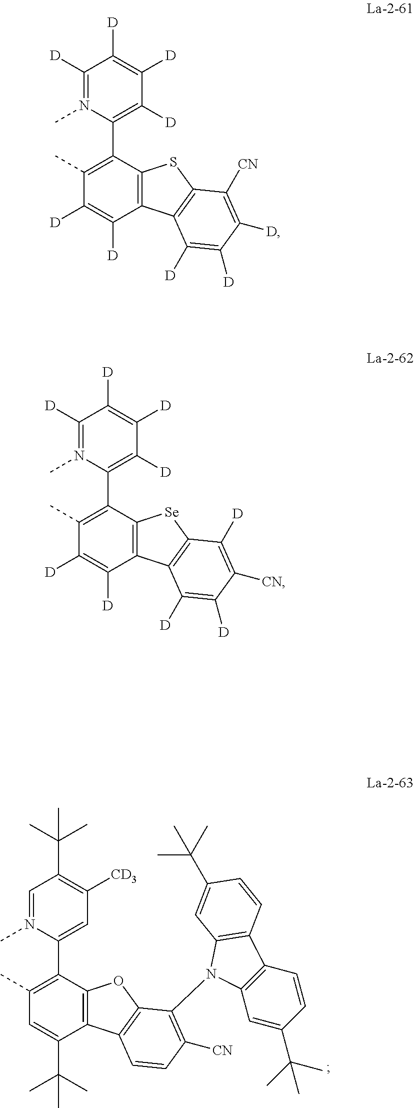
and
La-3-k3 has the following structure: 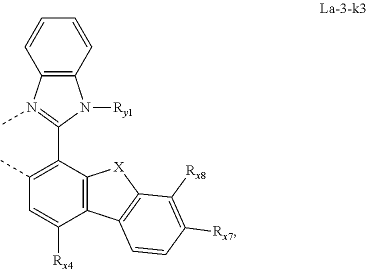
wherein when k3 is selected from 1 to 282, R_{y1}, Rₓ₄, Rₓ₇, Rₓ₈, and X are selected from atoms or groups in the following table, respectively:

| k3 | La | R_{y1} | Rₓ₄ | Rₓ₇ | Rₓ₈ | X |
|---|---|---|---|---|---|---|
| 1 | La-3-1 | R_{y1}-3 | H | H | H | O |
| 2 | La-3-2 | R_{y1}-3 | H | H | P1 | O |
| 3 | La-3-3 | R_{y1}-3 | H | H | P3 | O |
| 4 | La-3-4 | R_{y1}-3 | H | H | P9 | O |
| 5 | La-3-5 | R_{y1}-3 | H | H | P10 | O |
| 6 | La-3-6 | R_{y1}-3 | H | H | P14 | O |
| 7 | La-3-7 | R_{y1}-3 | H | H | P17 | O |
| 8 | La-3-8 | R_{y1}-3 | H | P1 | H | O |
| 9 | La-3-9 | R_{y1}-3 | H | P3 | H | O |
| 10 | La-3-10 | R_{y1}-3 | H | P9 | H | O |
| 11 | La-3-11 | R_{y1}-3 | H | P11 | H | O |
| 12 | La-3-12 | R_{y1}-3 | H | P13 | H | O |
| 13 | La-3-13 | R_{y1}-3 | H | P14 | H | O |
| 14 | La-3-14 | R_{y1}-3 | P1 | H | H | O |
| 15 | La-3-15 | R_{y1}-3 | P5 | H | H | O |
| 16 | La-3-16 | R_{y1}-3 | P6 | H | H | O |
| 17 | La-3-17 | R_{y1}-3 | P10 | H | H | O |
| 18 | La-3-18 | R_{y1}-3 | P13 | H | H | O |
| 19 | La-3-19 | R_{y1}-3 | P15 | H | H | O |
| 20 | La-3-20 | R_{y1}-3 | H | CN | H | O |
| 21 | La-3-21 | R_{y1}-3 | H | CN | D | O |
| 22 | La-3-22 | R_{y1}-3 | P5 | CN | H | O |
| 23 | La-3-23 | R_{y1}-3 | H | CN | P10 | O |
| 24 | La-3-24 | R_{y1}-3 | H | CN | P11 | O |
| 25 | La-3-25 | R_{y1}-3 | H | CN | P12 | O |
| 26 | La-3-26 | R_{y1}-3 | H | CN | P13 | O |
| 27 | La-3-27 | R_{y1}-3 | H | CN | P14 | O |
| 28 | La-3-28 | R_{y1}-3 | H | CN | P15 | O |
| 29 | La-3-29 | R_{y1}-3 | H | CN | P16 | O |
| 30 | La-3-30 | R_{y1}-3 | H | CN | P17 | O |
| 31 | La-3-31 | R_{y1}-3 | H | CN | P18 | O |
| 32 | La-3-32 | R_{y1}-3 | H | CN | P19 | O |
| 33 | La-3-33 | R_{y1}-3 | P5 | CN | P10 | O |
| 34 | La-3-34 | R_{y1}-3 | P5 | CN | P11 | O |
| 35 | La-3-35 | R_{y1}-3 | P5 | CN | P12 | O |
| 36 | La-3-36 | R_{y1}-3 | P5 | CN | P13 | O |
| 37 | La-3-37 | R_{y1}-3 | P5 | CN | P14 | O |
| 38 | La-3-38 | R_{y1}-3 | P5 | CN | P15 | O |
| 39 | La-3-39 | R_{y1}-3 | P5 | CN | P16 | O |
| 40 | La-3-40 | R_{y1}-3 | P5 | CN | P17 | O |
| 41 | La-3-41 | R_{y1}-3 | P5 | CN | P18 | O |
| 42 | La-3-42 | R_{y1}-3 | P5 | CN | P19 | O |
| 43 | La-3-43 | R_{y1}-3 | P2 | CN | P10 | O |
| 44 | La-3-44 | R_{y1}-3 | P3 | CN | P10 | O |
| 45 | La-3-45 | R_{y1}-3 | P4 | CN | P10 | O |
| 46 | La-3-46 | R_{y1}-3 | P6 | CN | P10 | O |
| 47 | La-3-47 | R_{y1}-3 | P7 | CN | P10 | O |
| 48 | La-3-48 | R_{y1}-3 | P8 | CN | P10 | O |
| 49 | La-3-49 | R_{y1}-3 | P9 | CN | P17 | O |
| 50 | La-3-50 | R_{y1}-3 | P6 | CN | P17 | O |
| 51 | La-3-51 | R_{y1}-3 | P6 | CN | P17 | O |
| 52 | La-3-52 | R_{y1}-3 | H | H | CN | O |
| 53 | La-3-53 | R_{y1}-3 | P1 | H | CN | O |
| 54 | La-3-54 | R_{y1}-3 | P2 | H | CN | O |
| 55 | La-3-55 | R_{y1}-3 | P3 | H | CN | O |
| 56 | La-3-56 | R_{y1}-3 | P4 | H | CN | O |
| 57 | La-3-57 | R_{y1}-3 | P5 | H | CN | O |
| 58 | La-3-58 | R_{y1}-3 | P6 | H | CN | O |
| 59 | La-3-59 | R_{y1}-3 | P10 | H | CN | O |
| 60 | La-3-60 | R_{y1}-3 | P15 | H | CN | O |
| 61 | La-3-61 | R_{y1}-3 | H | P10 | CN | O |
| 62 | La-3-62 | R_{y1}-3 | H | P11 | CN | O |
| 63 | La-3-63 | R_{y1}-3 | H | P18 | CN | O |
| 64 | La-3-64 | R_{y1}-3 | H | F | H | O |
| 65 | La-3-65 | R_{y1}-3 | H | F | D | O |
| 66 | La-3-66 | R_{y1}-3 | H | F | P10 | O |
| 67 | La-3-67 | R_{y1}-3 | H | F | P11 | O |
| 68 | La-3-68 | R_{y1}-3 | H | F | P12 | O |
| 69 | La-3-69 | R_{y1}-3 | H | F | P13 | O |
| 70 | La-3-70 | R_{y1}-3 | H | F | P14 | O |
| 71 | La-3-71 | R_{y1}-3 | H | F | P15 | O |
| 72 | La-3-72 | R_{y1}-3 | H | F | P16 | O |
| 73 | La-3-73 | R_{y1}-3 | H | F | P17 | O |
| 74 | La-3-74 | R_{y1}-3 | H | F | P18 | O |
| 75 | La-3-75 | R_{y1}-3 | H | F | P19 | O |
| 76 | La-3-76 | R_{y1}-3 | P1 | F | P10 | O |
| 77 | La-3-77 | R_{y1}-3 | P2 | F | P11 | O |
| 78 | La-3-78 | R_{y1}-3 | P3 | F | P12 | O |
| 79 | La-3-79 | R_{y1}-3 | P4 | F | P13 | O |
| 80 | La-3-80 | R_{y1}-3 | P5 | F | P14 | O |
| 81 | La-3-81 | R_{y1}-3 | P6 | F | P15 | O |
| 82 | La-3-82 | R_{y1}-3 | P7 | F | P16 | O |
| 83 | La-3-83 | R_{y1}-3 | P8 | F | P17 | O |
| 84 | La-3-84 | R_{y1}-3 | P9 | F | P18 | O |
| 85 | La-3-85 | R_{y1}-3 | P10 | F | P19 | O |
| 86 | La-3-86 | R_{y1}-3 | H | H | H | S |
| 87 | La-3-87 | R_{y1}-3 | P6 | H | H | S |
| 88 | La-3-88 | R_{y1}-3 | P7 | H | H | S |
| 89 | La-3-89 | R_{y1}-3 | P1 | H | H | S |
| 90 | La-3-90 | R_{y1}-3 | P2 | H | H | S |
| 91 | La-3-91 | R_{y1}-3 | H | CN | H | S |
| 92 | La-3-92 | R_{y1}-3 | H | CN | P10 | S |
| 93 | La-3-93 | R_{y1}-3 | H | CN | P11 | S |
| 94 | La-3-94 | R_{y1}-3 | H | CN | P12 | S |
| 95 | La-3-95 | R_{y1}-3 | H | CN | P13 | S |
| 96 | La-3-96 | R_{y1}-3 | H | CN | P14 | S |
| 97 | La-3-97 | R_{y1}-3 | H | CN | P15 | S |
| 98 | La-3-98 | R_{y1}-3 | H | CN | P16 | S |
| 99 | La-3-99 | R_{y1}-3 | H | CN | P17 | S |
| 100 | La-3-100 | R_{y1}-3 | H | CN | P18 | S |
| 101 | La-3-101 | R_{y1}-3 | H | CN | P19 | S |
| 102 | La-3-102 | R_{y1}-3 | H | H | CN | S |
| 103 | La-3-103 | R_{y1}-3 | P1 | H | CN | S |
| 104 | La-3-104 | R_{y1}-3 | P2 | H | CN | S |
| 105 | La-3-105 | R_{y1}-3 | P17 | H | CN | S |
| 106 | La-3-106 | R_{y1}-3 | P13 | H | CN | S |
| 107 | La-3-107 | R_{y1}-6 | H | H | H | O |
| 108 | La-3-108 | R_{y1}-6 | H | H | P1 | O |
| 109 | La-3-109 | R_{y1}-6 | H | H | P3 | O |
| 110 | La-3-110 | R_{y1}-6 | H | H | P9 | O |
| 111 | La-3-111 | R_{y1}-6 | H | H | P10 | O |
| 112 | La-3-112 | R_{y1}-6 | H | H | P14 | O |
| 113 | La-3-113 | R_{y1}-6 | H | H | P17 | O |
| 114 | La-3-114 | R_{y1}-6 | H | P1 | H | O |
| 115 | La-3-115 | R_{y1}-6 | H | P3 | H | O |
| 116 | La-3-116 | R_{y1}-6 | H | P9 | H | O |
| 117 | La-3-117 | R_{y1}-6 | H | P11 | H | O |
| 118 | La-3-118 | R_{y1}-6 | H | P13 | H | O |
| 119 | La-3-119 | R_{y1}-6 | H | P14 | H | O |
| 120 | La-3-120 | R_{y1}-6 | P1 | H | H | O |
| 121 | La-3-121 | R_{y1}-6 | P5 | H | H | O |
| 122 | La-3-122 | R_{y1}-6 | P6 | H | H | O |
| 123 | La-3-123 | R_{y1}-6 | P10 | H | H | O |
| 124 | La-3-124 | R_{y1}-6 | P13 | H | H | O |
| 125 | La-3-125 | R_{y1}-6 | P15 | H | H | O |
| 126 | La-3-126 | R_{y1}-6 | H | CN | H | O |
| 127 | La-3-127 | R_{y1}-6 | H | CN | D | O |
| 128 | La-3-128 | R_{y1}-6 | P5 | CN | H | O |
| 129 | La-3-129 | R_{y1}-6 | H | CN | P10 | O |
| 130 | La-3-130 | R_{y1}-6 | H | CN | P11 | O |
| 131 | La-3-131 | R_{y1}-6 | H | CN | P12 | O |
| 132 | La-3-132 | R_{y1}-6 | H | CN | P13 | O |
| 133 | La-3-133 | R_{y1}-6 | H | CN | P14 | O |
| 134 | La-3-134 | R_{y1}-6 | H | CN | P15 | O |
| 135 | La-3-135 | R_{y1}-6 | H | CN | P16 | O |
| 136 | La-3-136 | R_{y1}-6 | H | CN | P17 | O |
| 137 | La-3-137 | R_{y1}-6 | H | CN | P18 | O |
| 138 | La-3-138 | R_{y1}-6 | H | CN | P19 | O |
| 139 | La-3-139 | R_{y1}-6 | P5 | CN | P10 | O |
| 140 | La-3-140 | R_{y1}-6 | P5 | CN | P11 | O |
| 141 | La-3-141 | R_{y1}-6 | P5 | CN | P12 | O |
| 142 | La-3-142 | R_{y1}-6 | P5 | CN | P13 | O |
| 143 | La-3-143 | R_{y1}-6 | P5 | CN | P14 | O |
| 144 | La-3-144 | R_{y1}-6 | P5 | CN | P15 | O |
| 145 | La-3-145 | R_{y1}-6 | P5 | CN | P16 | O |
| 146 | La-3-146 | R_{y1}-6 | P5 | CN | P17 | O |
| 147 | La-3-147 | R_{y1}-6 | P5 | CN | P18 | O |
| 148 | La-3-148 | R_{y1}-6 | P5 | CN | P19 | O |
| 149 | La-3-149 | R_{y1}-6 | P2 | CN | P10 | O |
| 150 | La-3-150 | R_{y1}-6 | P3 | CN | P10 | O |
| 151 | La-3-151 | R_{y1}-6 | P4 | CN | P10 | O |
| 152 | La-3-152 | R_{y1}-6 | P6 | CN | P10 | O |
| 153 | La-3-153 | R_{y1}-6 | P7 | CN | P10 | O |
| 154 | La-3-154 | R_{y1}-6 | P8 | CN | P10 | O |
| 155 | La-3-155 | R_{y1}-6 | P9 | CN | P17 | O |
| 156 | La-3-156 | R_{y1}-6 | P6 | CN | P17 | O |
| 157 | La-3-157 | R_{y1}-6 | P6 | CN | P17 | O |
| 158 | La-3-158 | R_{y1}-6 | H | H | CN | O |
| 159 | La-3-159 | R_{y1}-6 | P1 | H | CN | O |
| 160 | La-3-160 | R_{y1}-6 | P2 | H | CN | O |
| 161 | La-3-161 | R_{y1}-6 | P3 | H | CN | O |
| 162 | La-3-162 | R_{y1}-6 | P4 | H | CN | O |
| 163 | La-3-163 | R_{y1}-6 | P5 | H | CN | O |
| 164 | La-3-164 | R_{y1}-6 | P6 | H | CN | O |
| 165 | La-3-165 | R_{y1}-6 | P10 | H | CN | O |
| 166 | La-3-166 | R_{y1}-6 | P15 | H | CN | O |
| 167 | La-3-167 | R_{y1}-6 | H | P10 | CN | O |
| 168 | La-3-168 | R_{y1}-6 | H | P11 | CN | O |
| 169 | La-3-169 | R_{y1}-6 | H | P18 | CN | O |
| 170 | La-3-170 | R_{y1}-6 | H | F | H | O |
| 171 | La-3-171 | R_{y1}-6 | H | F | D | O |
| 172 | La-3-172 | R_{y1}-6 | H | F | P10 | O |
| 173 | La-3-173 | R_{y1}-6 | H | F | P11 | O |
| 174 | La-3-174 | R_{y1}-6 | H | F | P12 | O |
| 175 | La-3-175 | R_{y1}-6 | H | F | P13 | O |
| 176 | La-3-176 | R_{y1}-6 | H | F | P14 | O |
| 177 | La-3-177 | R_{y1}-6 | H | F | P15 | O |
| 178 | La-3-178 | R_{y1}-6 | H | F | P16 | O |
| 179 | La-3-179 | R_{y1}-6 | H | F | P17 | O |
| 180 | La-3-180 | R_{y1}-6 | H | F | P18 | O |
| 181 | La-3-181 | R_{y1}-6 | H | F | P19 | O |
| 182 | La-3-182 | R_{y1}-6 | P1 | F | P10 | O |
| 183 | La-3-183 | R_{y1}-6 | P2 | F | P11 | O |
| 184 | La-3-184 | R_{y1}-6 | P3 | F | P12 | O |
| 185 | La-3-185 | R_{y1}-6 | P4 | F | P13 | O |
| 186 | La-3-186 | R_{y1}-6 | P5 | F | P14 | O |
| 187 | La-3-187 | R_{y1}-6 | P6 | F | P15 | O |
| 188 | La-3-188 | R_{y1}-6 | P7 | F | P16 | O |
| 189 | La-3-189 | R_{y1}-6 | P8 | F | P17 | O |
| 190 | La-3-190 | R_{y1}-6 | P9 | F | P18 | O |
| 191 | La-3-191 | R_{y1}-6 | P10 | F | P19 | O |
| 192 | La-3-192 | R_{y1}-6 | H | H | H | S |
| 193 | La-3-193 | R_{y1}-6 | P6 | H | H | S |
| 194 | La-3-194 | R_{y1}-6 | P7 | H | H | S |
| 195 | La-3-195 | R_{y1}-6 | P1 | H | H | S |
| 196 | La-3-196 | R_{y1}-6 | P2 | H | H | S |
| 197 | La-3-197 | R_{y1}-6 | H | CN | H | S |
| 198 | La-3-198 | R_{y1}-6 | H | CN | P10 | S |
| 199 | La-3-199 | R_{y1}-6 | H | CN | P11 | S |
| 200 | La-3-200 | R_{y1}-6 | H | CN | P12 | S |
| 201 | La-3-201 | R_{y1}-6 | H | CN | P13 | S |
| 202 | La-3-202 | R_{y1}-6 | H | CN | P14 | S |
| 203 | La-3-203 | R_{y1}-6 | H | CN | P15 | S |
| 204 | La-3-204 | R_{y1}-6 | H | CN | P16 | S |
| 205 | La-3-205 | R_{y1}-6 | H | CN | P17 | S |
| 206 | La-3-206 | R_{y1}-6 | H | CN | P18 | S |
| 207 | La-3-207 | R_{y1}-6 | H | CN | P19 | S |
| 208 | La-3-208 | R_{y1}-6 | H | H | CN | S |
| 209 | La-3-209 | R_{y1}-6 | P1 | H | CN | S |
| 210 | La-3-210 | R_{y1}-6 | P2 | H | CN | S |
| 211 | La-3-211 | R_{y1}-6 | P17 | H | CN | S |
| 212 | La-3-212 | R_{y1}-6 | P13 | H | CN | S |
| 213 | La-3-213 | R_{y1}-1 | H | H | CN | O |
| 214 | La-3-214 | R_{y1}-1 | H | CN | H | O |
| 215 | La-3-215 | R_{y1}-1 | H | CN | D | O |
| 216 | La-3-216 | R_{y1}-1 | P5 | H | H | O |
| 217 | La-3-217 | R_{y1}-1 | P5 | H | CN | O |
| 218 | La-3-218 | R_{y1}-1 | P5 | CN | D | O |
| 219 | La-3-219 | R_{y1}-1 | H | CN | P10 | O |
| 220 | La-3-220 | R_{y1}-1 | H | CN | P15 | O |
| 221 | La-3-221 | R_{y1}-1 | P5 | CN | P12 | O |
| 222 | La-3-222 | R_{y1}-1 | P5 | CN | P17 | O |
| 223 | La-3-223 | R_{y1}-2 | H | H | CN | O |
| 224 | La-3-224 | R_{y1}-2 | H | CN | H | O |
| 225 | La-3-225 | R_{y1}-2 | H | CN | D | O |
| 226 | La-3-226 | R_{y1}-2 | P5 | H | H | O |
| 227 | La-3-227 | R_{y1}-2 | P5 | H | CN | O |
| 228 | La-3-228 | R_{y1}-2 | P5 | CN | D | O |
| 229 | La-3-229 | R_{y1}-2 | H | CN | P10 | O |
| 230 | La-3-230 | R_{y1}-2 | H | CN | P15 | O |
| 231 | La-3-231 | R_{y1}-2 | P5 | CN | P12 | O |
| 232 | La-3-232 | R_{y1}-2 | P5 | CN | P17 | O |
| 233 | La-3-233 | R_{y1}-4 | H | H | CN | O |
| 234 | La-3-234 | R_{y1}-4 | H | CN | H | O |
| 235 | La-3-235 | R_{y1}-4 | H | CN | D | O |
| 236 | La-3-236 | R_{y1}-4 | P5 | H | H | O |
| 237 | La-3-237 | R_{y1}-4 | P5 | H | CN | O |
| 238 | La-3-238 | R_{y1}-4 | P5 | CN | D | O |
| 239 | La-3-239 | R_{y1}-4 | H | CN | P10 | O |
| 240 | La-3-240 | R_{y1}-4 | H | CN | P15 | O |
| 241 | La-3-241 | R_{y1}-4 | P5 | CN | P12 | O |
| 242 | La-3-242 | R_{y1}-4 | P5 | CN | P17 | O |
| 243 | La-3-243 | R_{y1}-5 | H | H | CN | O |
| 244 | La-3-244 | R_{y1}-5 | H | CN | H | O |
| 245 | La-3-245 | R_{y1}-5 | H | CN | D | O |
| 246 | La-3-246 | R_{y1}-5 | P5 | H | H | O |
| 247 | La-3-247 | R_{y1}-5 | P5 | H | CN | O |
| 248 | La-3-248 | R_{y1}-5 | P5 | CN | D | O |
| 249 | La-3-249 | R_{y1}-5 | H | CN | P10 | O |
| 250 | La-3-250 | R_{y1}-5 | H | CN | P15 | O |
| 251 | La-3-251 | R_{y1}-5 | P5 | CN | P12 | O |
| 252 | La-3-252 | R_{y1}-5 | P5 | CN | P17 | O |
| 253 | La-3-253 | R_{y1}-7 | H | H | CN | O |
| 254 | La-3-254 | R_{y1}-7 | H | CN | H | O |
| 255 | La-3-255 | R_{y1}-7 | H | CN | D | O |
| 256 | La-3-256 | R_{y1}-7 | P5 | H | H | O |
| 257 | La-3-257 | R_{y1}-7 | P5 | H | CN | O |
| 258 | La-3-258 | R_{y1}-7 | P5 | CN | D | O |
| 259 | La-3-259 | R_{y1}-7 | H | CN | P10 | O |
| 260 | La-3-260 | R_{y1}-7 | H | CN | P15 | O |
| 261 | La-3-261 | R_{y1}-7 | P5 | CN | P12 | O |
| 262 | La-3-262 | R_{y1}-7 | P5 | CN | P17 | O |
| 263 | La-3-263 | R_{y1}-8 | H | H | CN | O |
| 264 | La-3-264 | R_{y1}-8 | H | CN | H | O |
| 265 | La-3-265 | R_{y1}-8 | H | CN | D | O |
| 266 | La-3-266 | R_{y1}-8 | P5 | H | H | O |
| 267 | La-3-267 | R_{y1}-8 | P5 | H | CN | O |
| 268 | La-3-268 | R_{y1}-8 | P5 | CN | D | O |
| 269 | La-3-269 | R_{y1}-8 | H | CN | P10 | O |
| 270 | La-3-270 | R_{y1}-8 | H | CN | P15 | O |
| 271 | La-3-271 | R_{y1}-8 | P5 | CN | P12 | O |
| 272 | La-3-272 | R_{y1}-8 | P5 | CN | P17 | O |
| 273 | La-3-273 | R_{y1}-9 | H | H | CN | O |
| 274 | La-3-274 | R_{y1}-9 | H | CN | H | O |
| 275 | La-3-275 | R_{y1}-9 | H | CN | D | O |
| 276 | La-3-276 | R_{y1}-9 | P5 | H | H | O |
| 277 | La-3-277 | R_{y1}-9 | P5 | H | CN | O |
| 278 | La-3-278 | R_{y1}-9 | P5 | CN | D | O |
| 279 | La-3-279 | R_{y1}-9 | H | CN | P10 | O |
| 280 | La-3-280 | R_{y1}-9 | H | CN | P15 | O |
| 281 | La-3-281 | R_{y1}-9 | P5 | CN | P12 | O |
| 282 | La-3-282 | R_{y1}-9 | P5 | CN | P17 | O |

wherein P1 to P19 have the following structures: 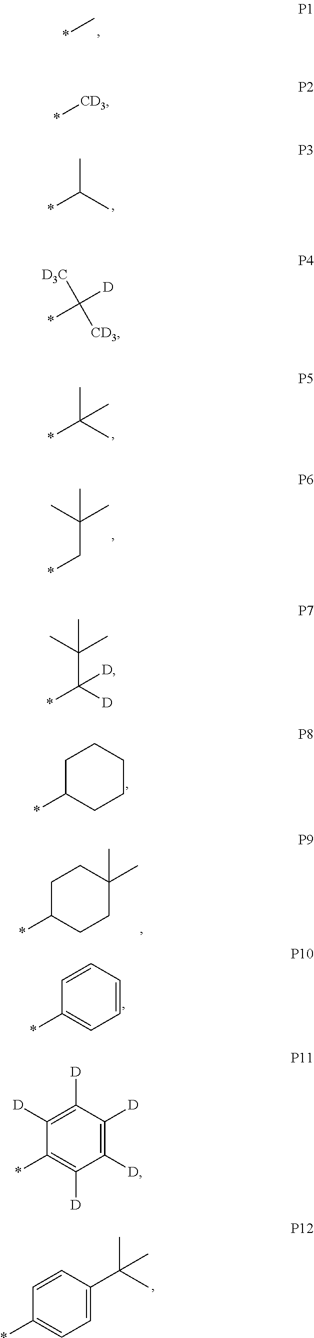 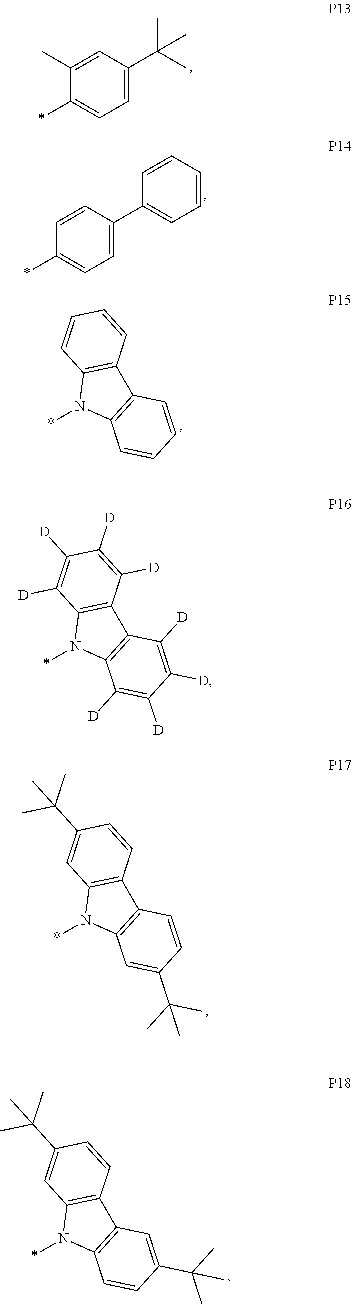 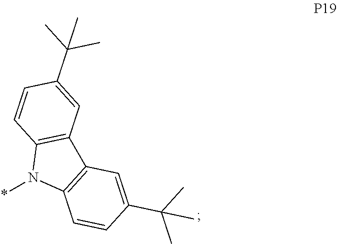 [SMILES: *n1c2ccc(C(C)(C)C)cc2c2cc(C(C)(C)C)ccc21]
wherein “*” represents a position where La-1-k1 or La-3-k3 is joined;
wherein R_{y1}-1 to R_{y1}-9 have the following structures: 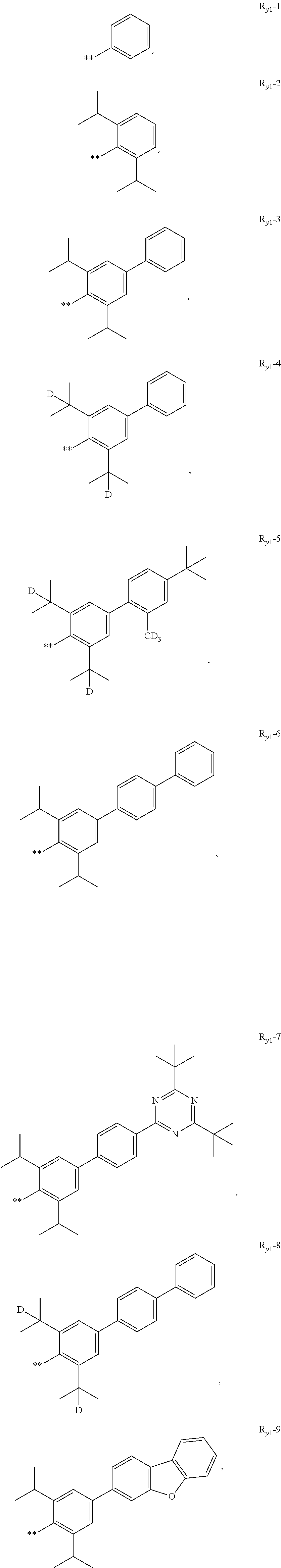
wherein “**” represents a position where La-3-k3 is joined to an imidazole ring fragment; and
wherein optionally, hydrogens in La-1-1 to La-1-300, La-2-1 to La-2-63, and La-3-1 to La-3-282 can be partially or fully substituted with deuterium.

10. The organic electroluminescent device according to claim 9, wherein L_{b} is, at each occurrence identically or differently, selected from any one of the group consisting of L_{b1} to L_{b169} having the following structures: 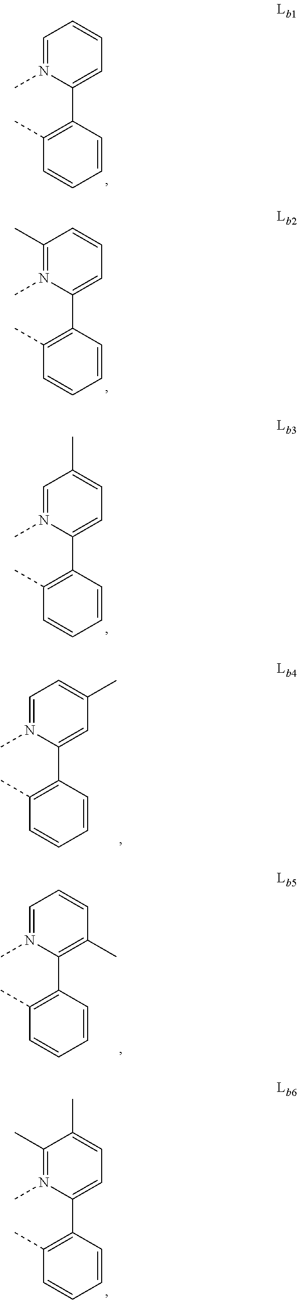 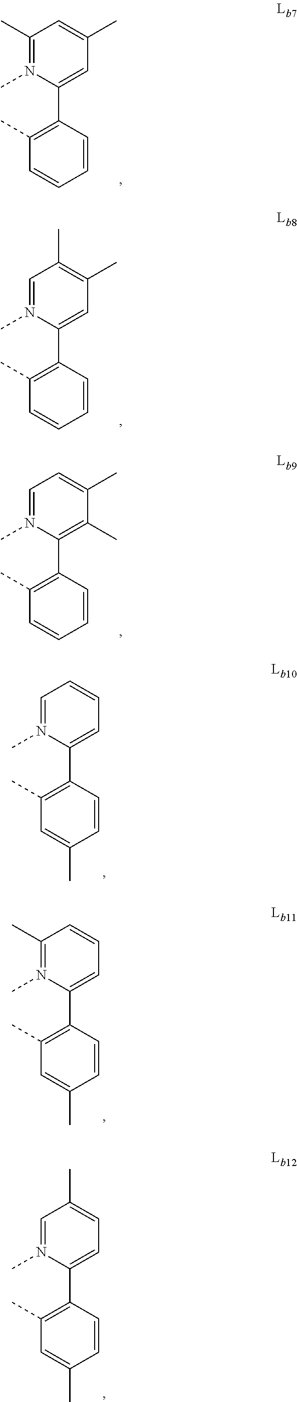 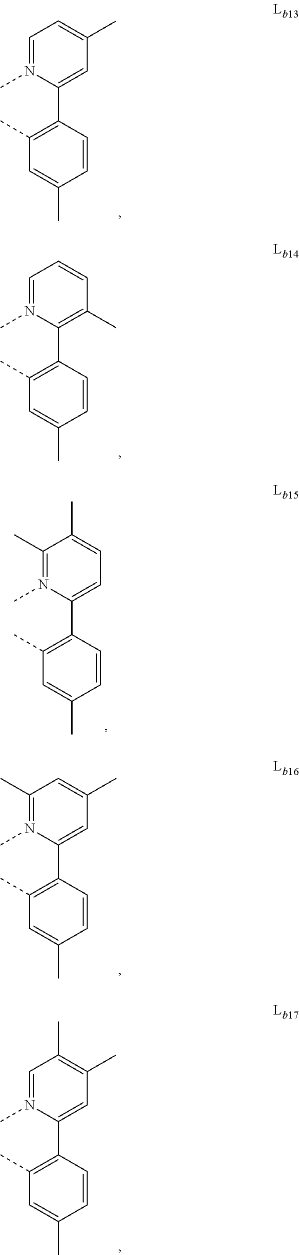 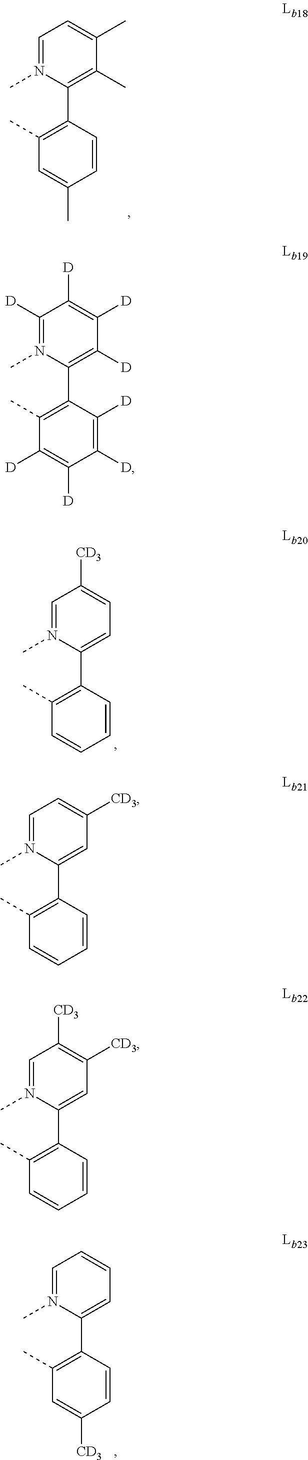 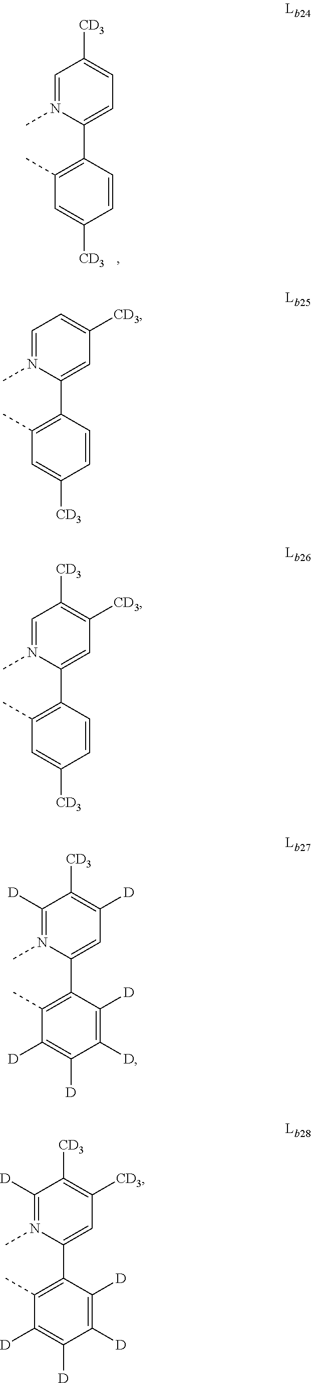 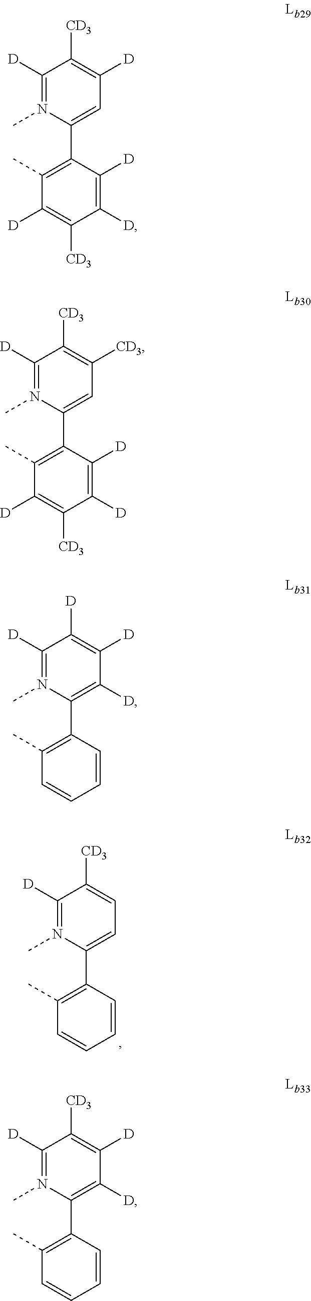 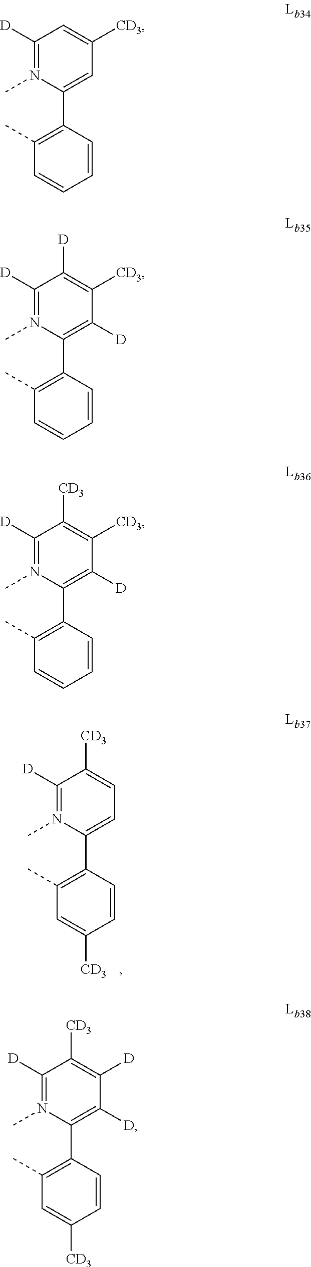 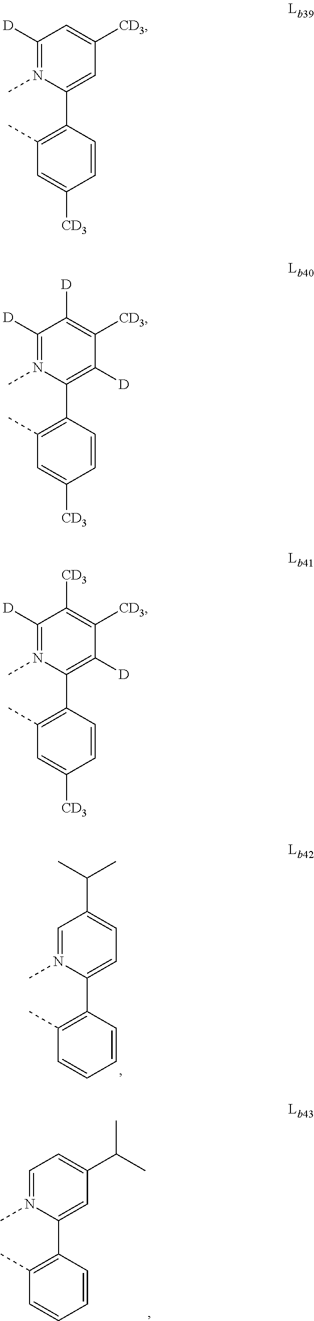 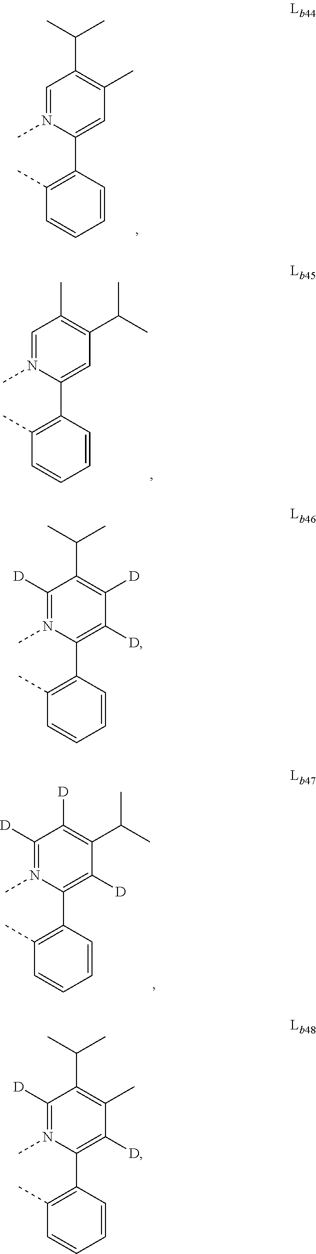 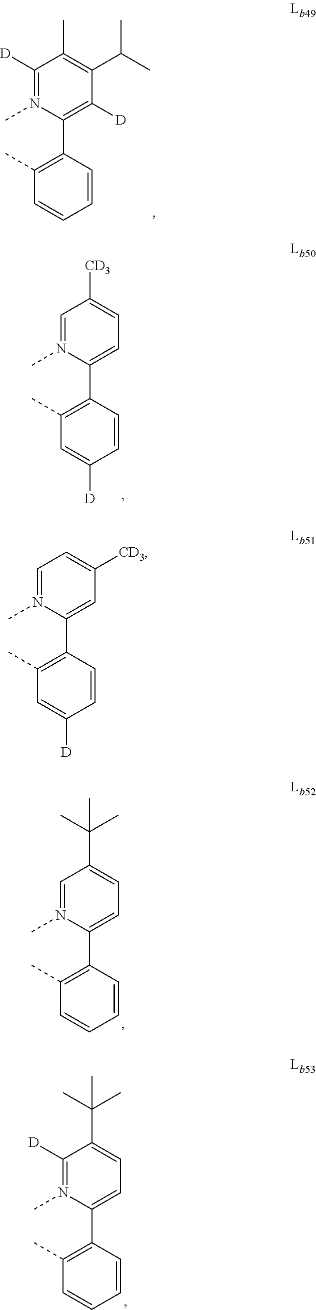 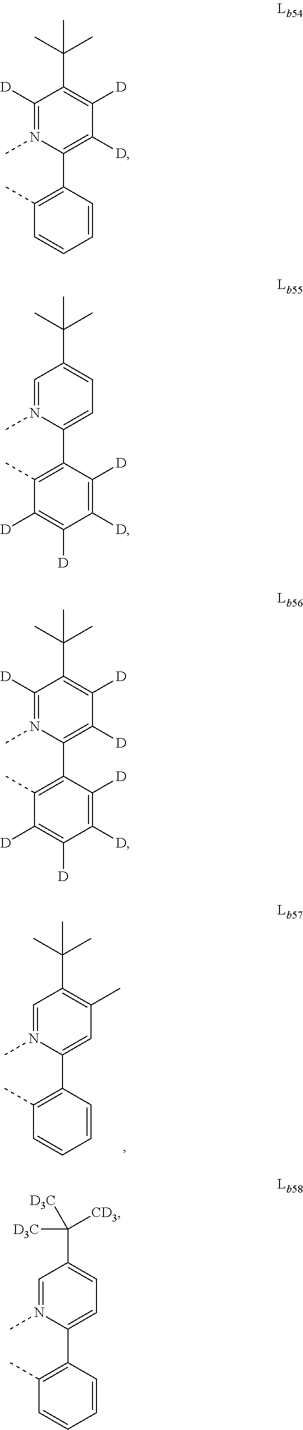 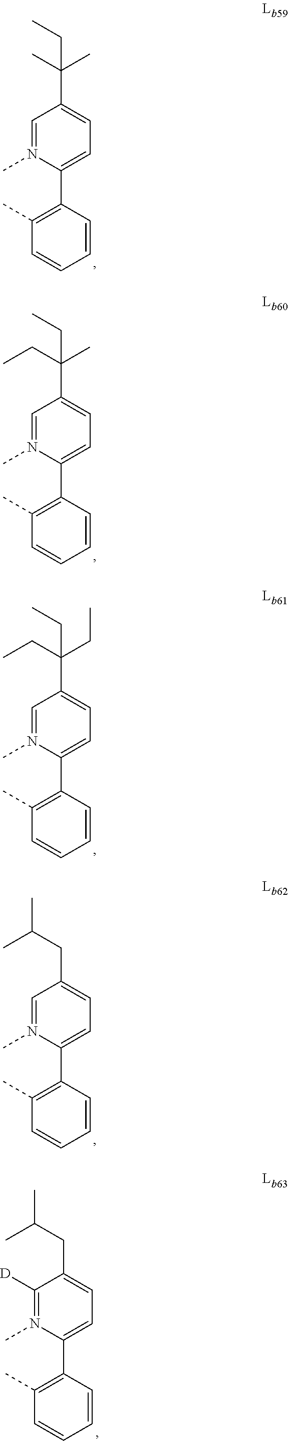 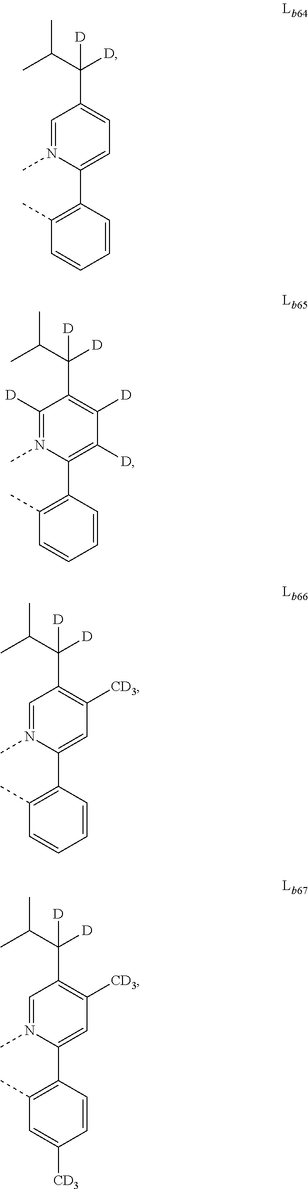 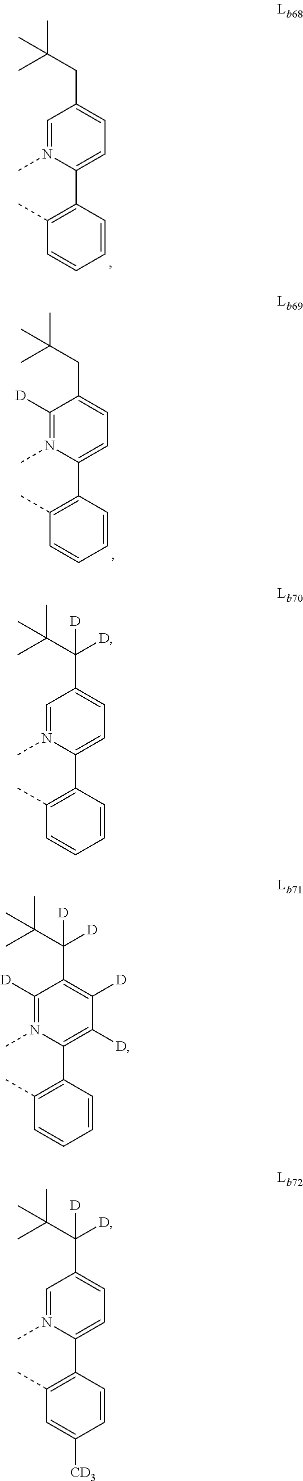 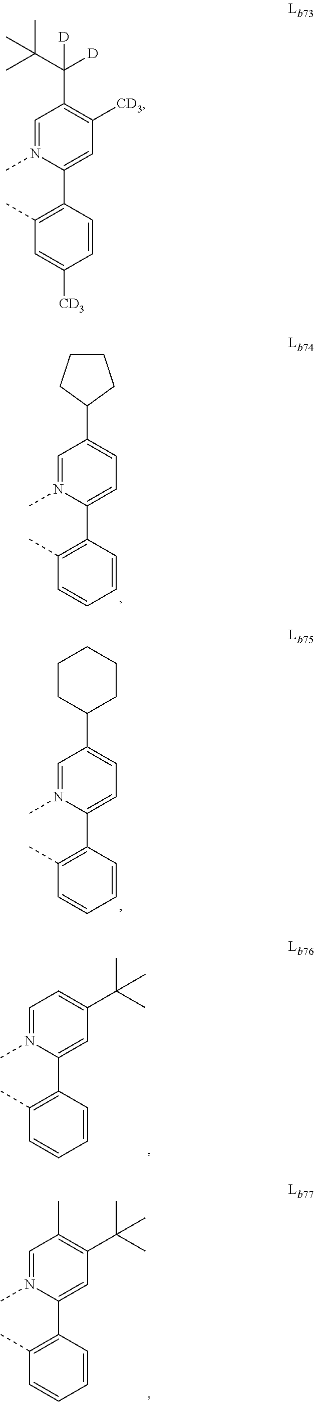 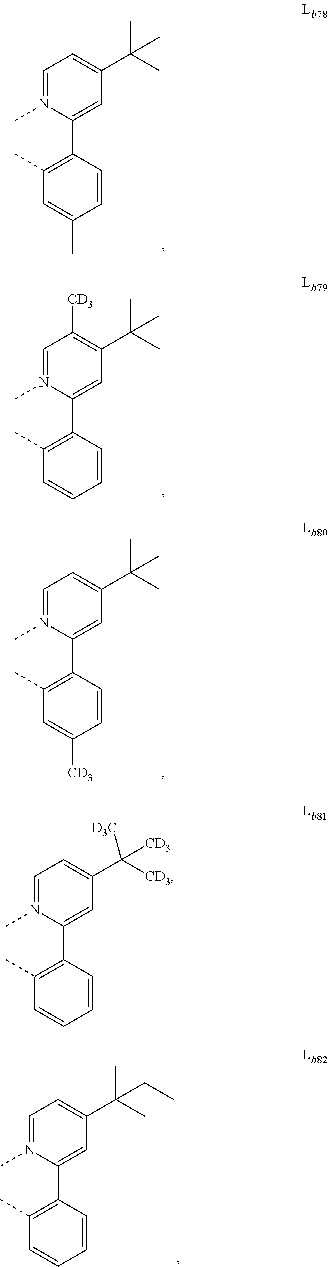 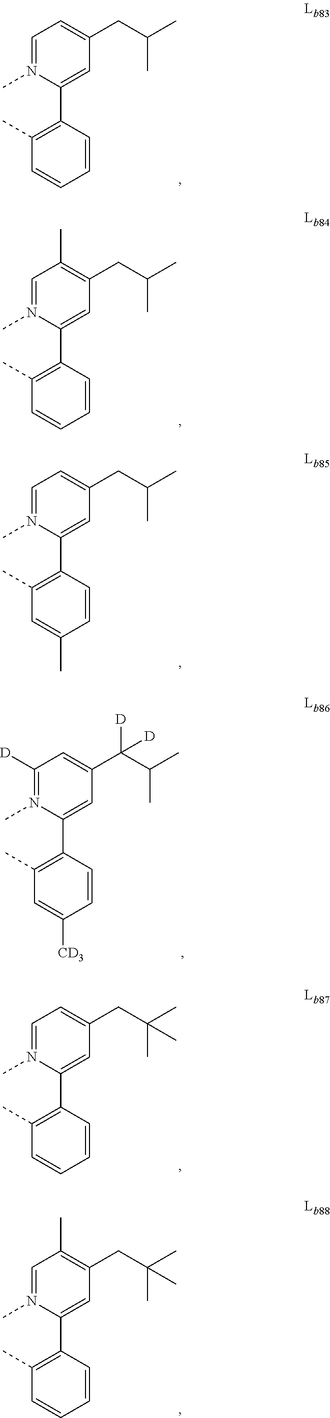 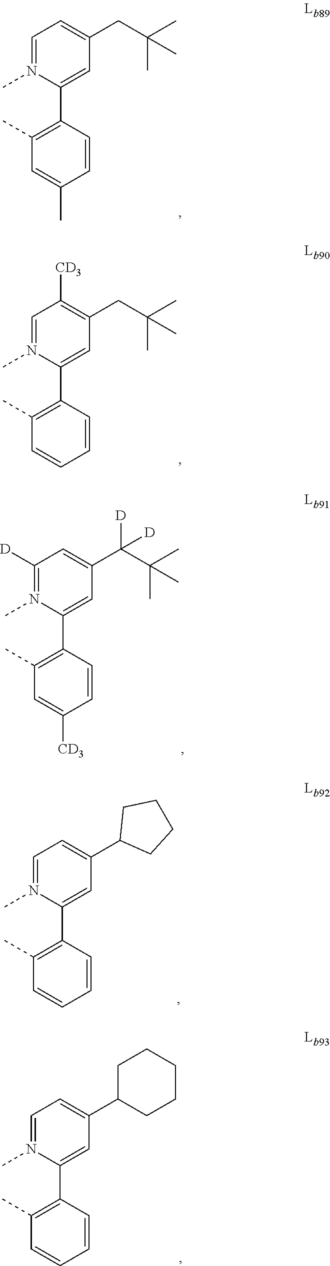 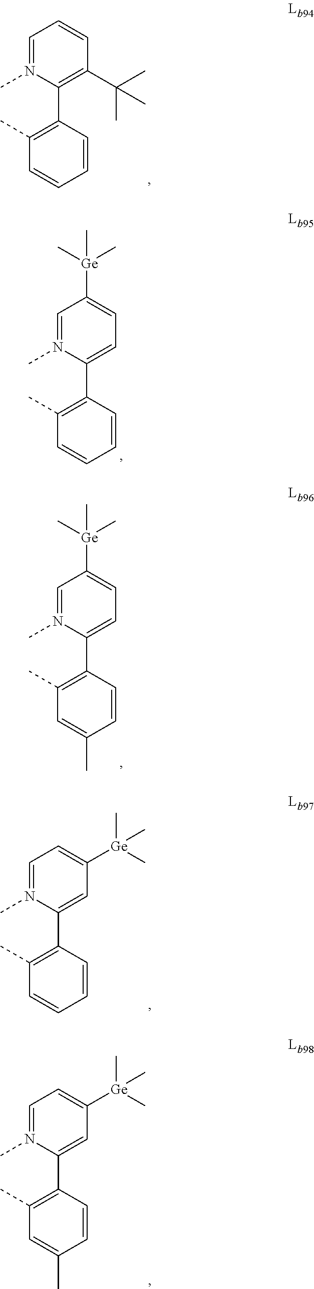 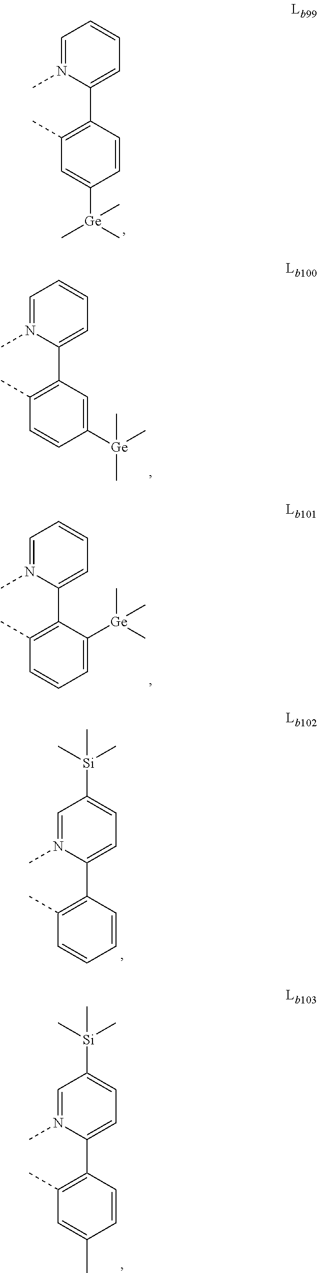 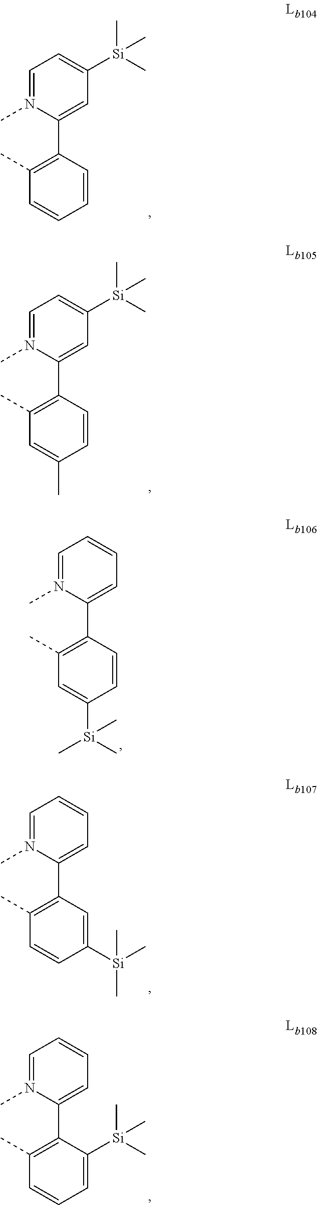 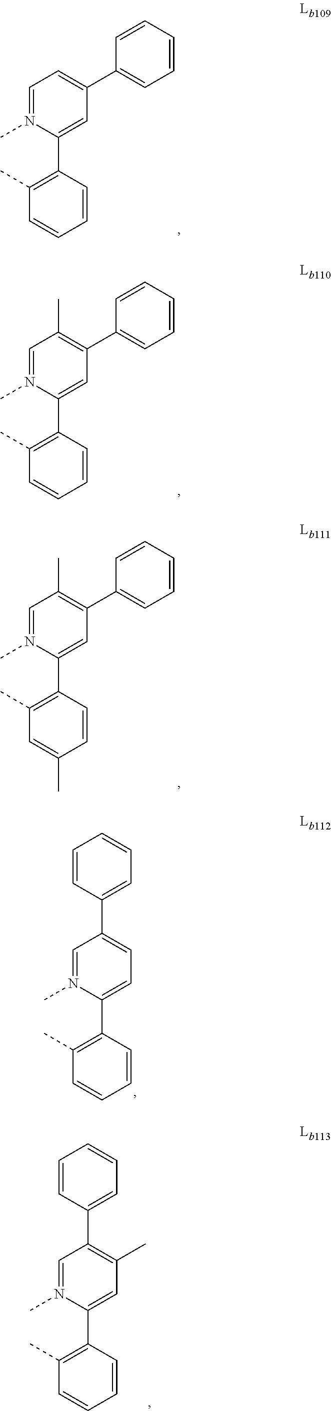 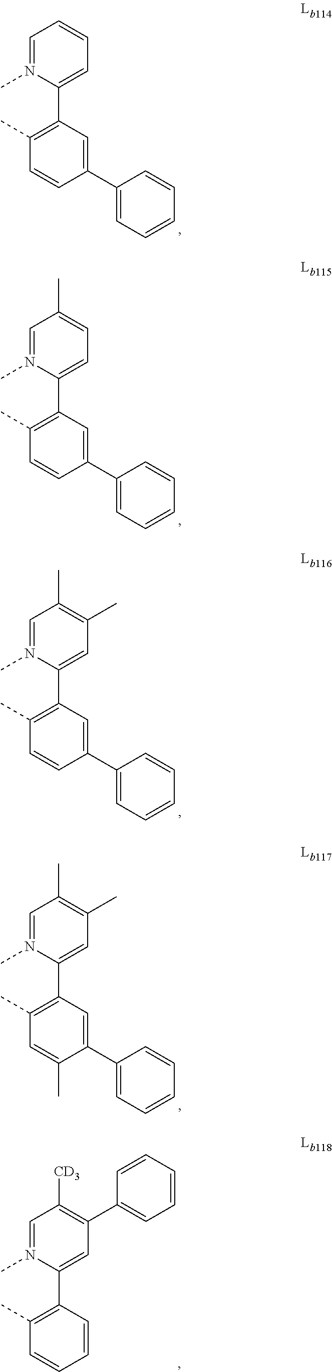 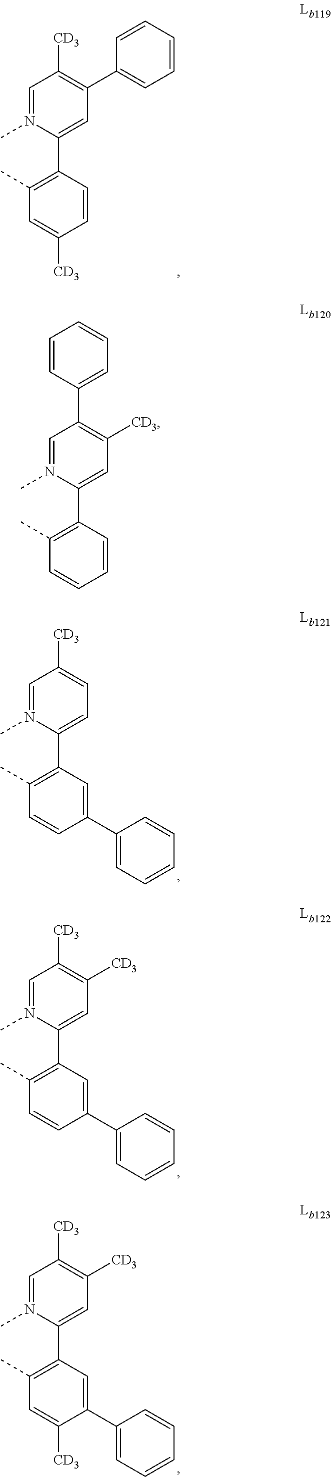 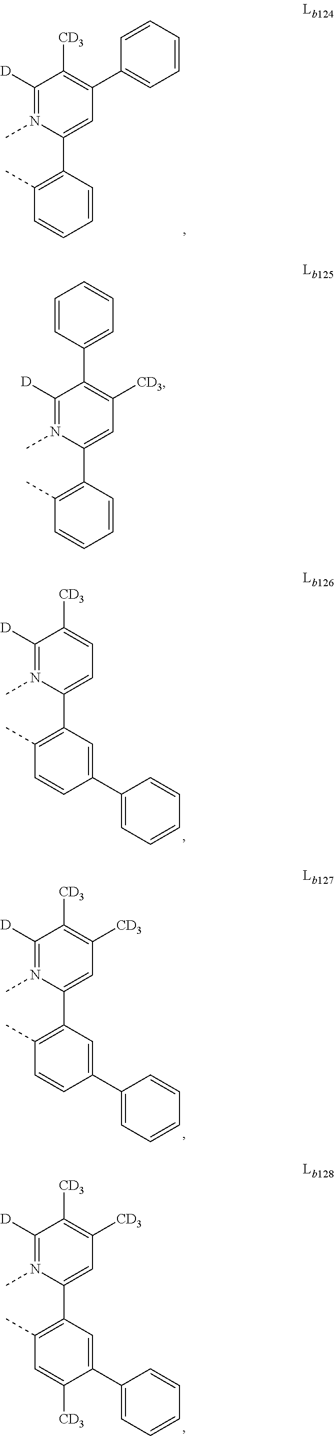 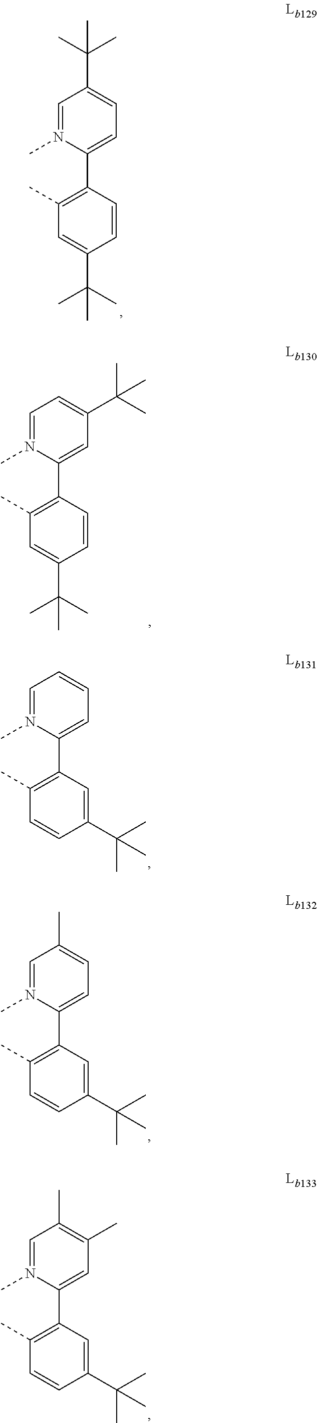 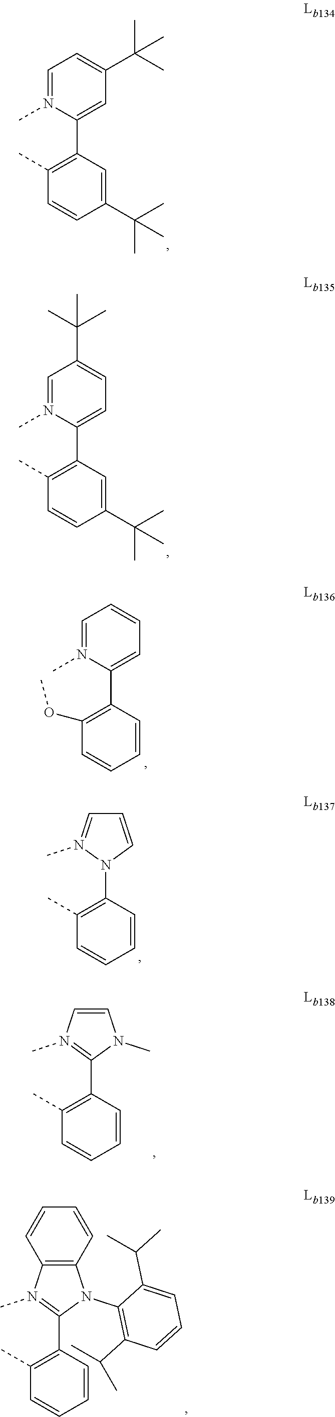 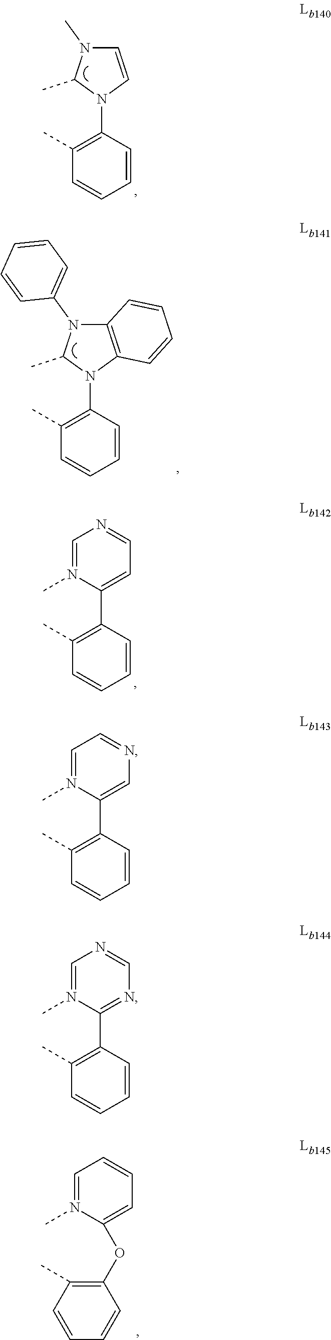 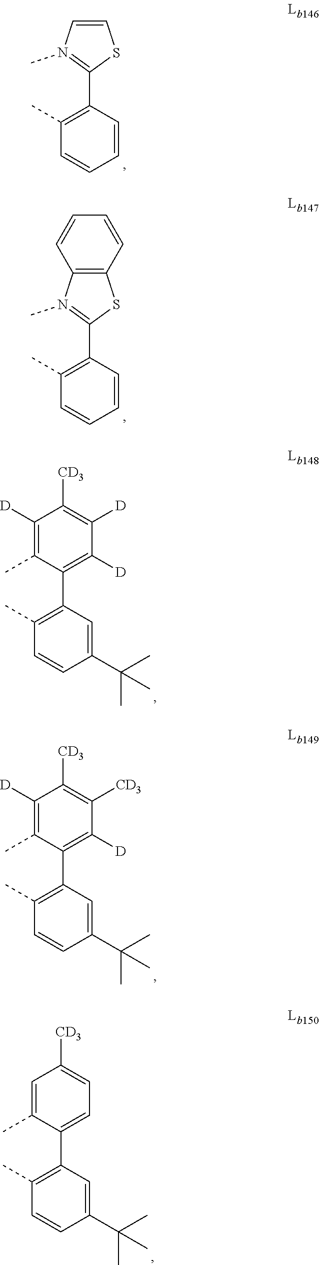 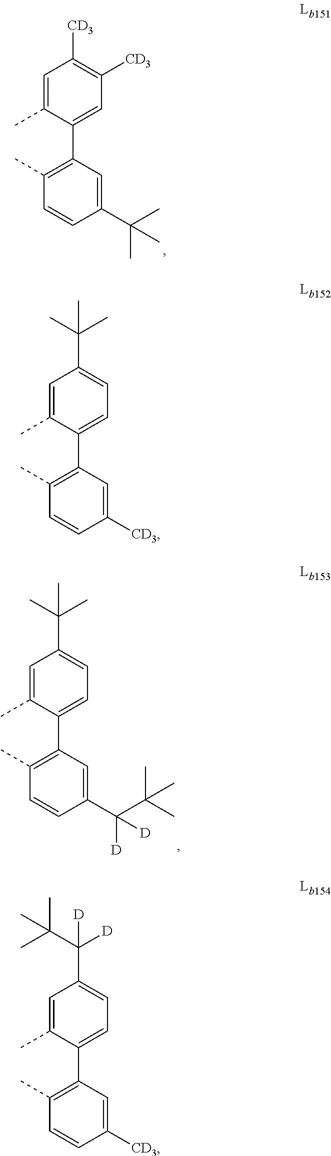 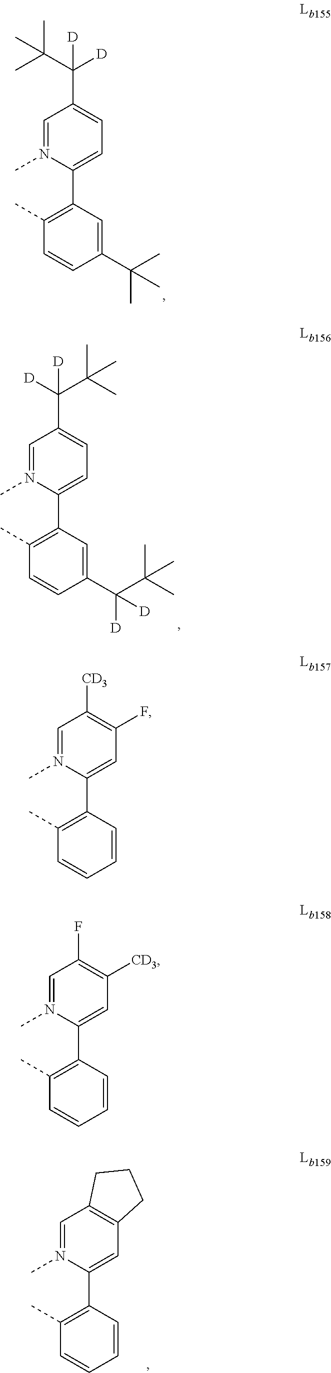 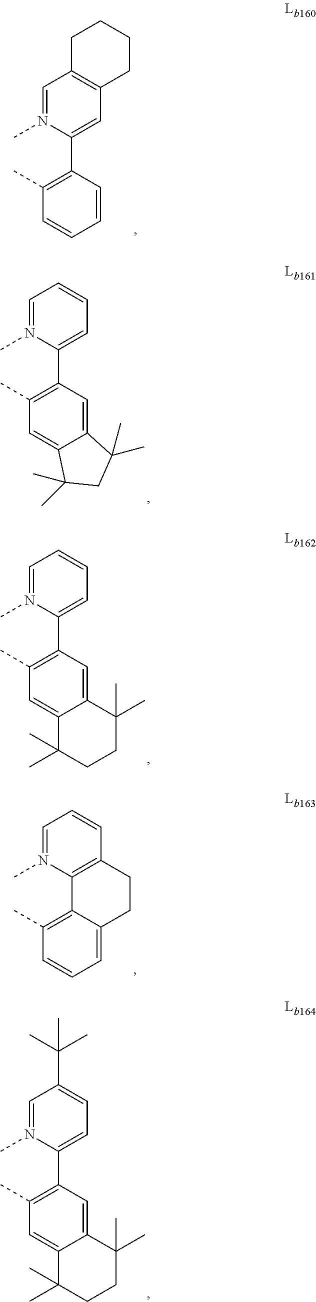 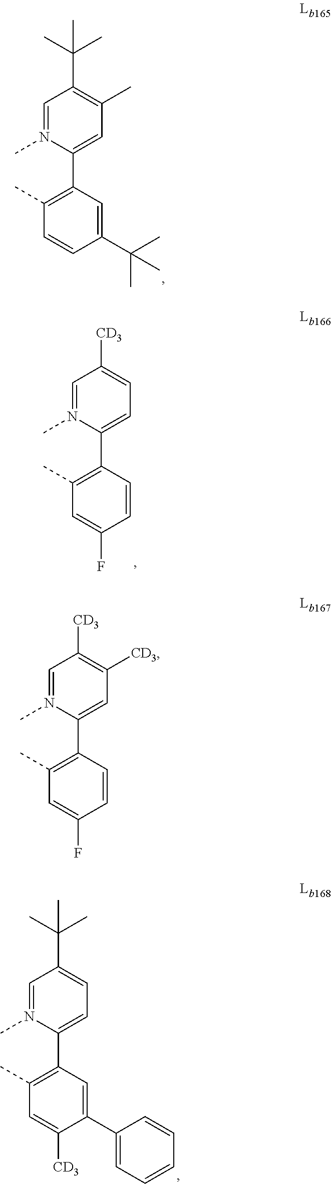 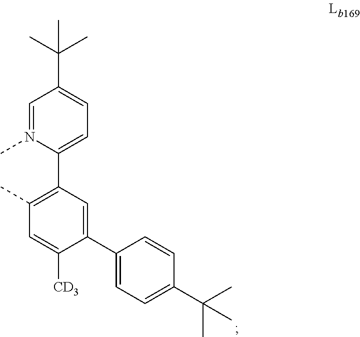
wherein optionally, hydrogens in L_{b1} to L_{b18}, L_{b20} to L_{b26}, and L_{b31} to L_{b169} can be partially or fully substituted with deuterium.

11. The organic electroluminescent device according to claim 10, wherein L_{c} is, at each occurrence identically or differently, selected from any one of the group consisting of L_{c1} to L_{c50} having the following specific structures: 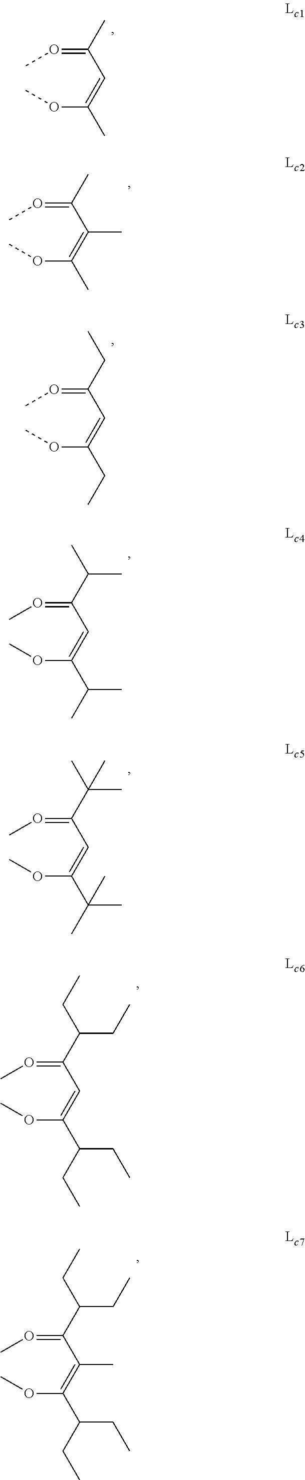 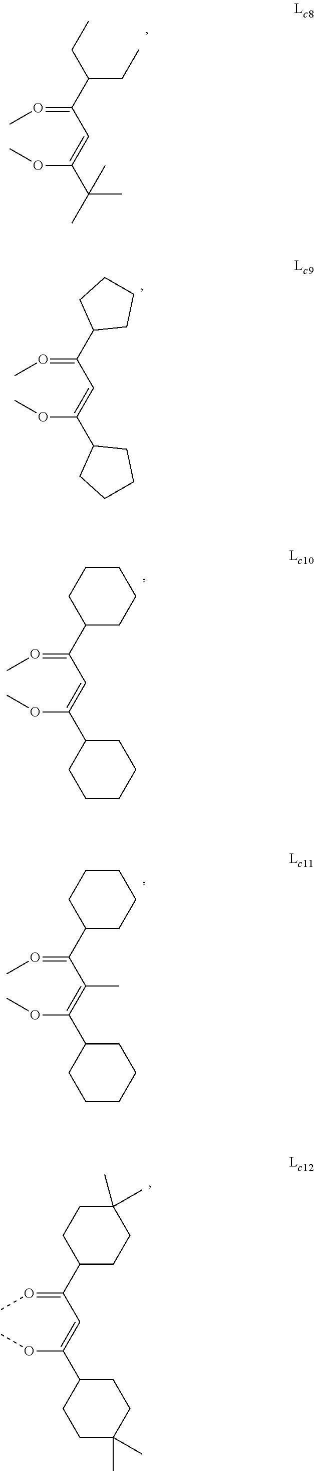 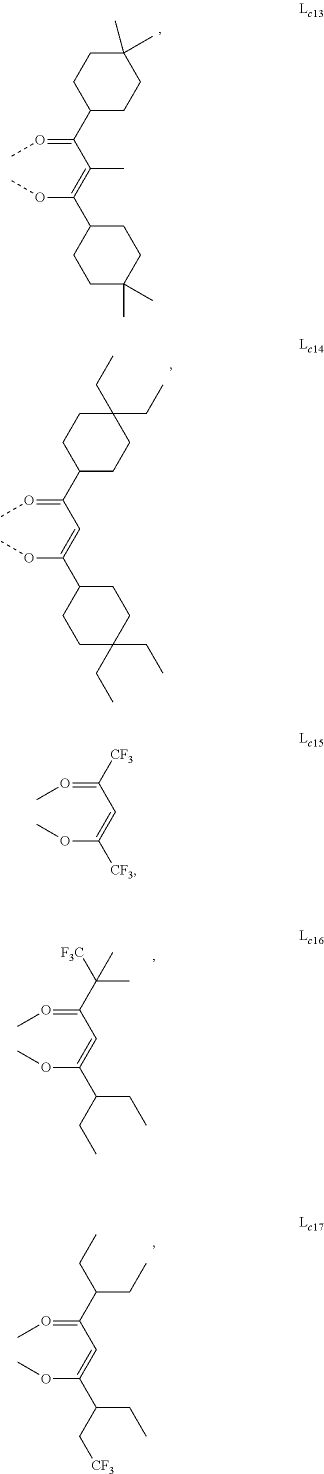 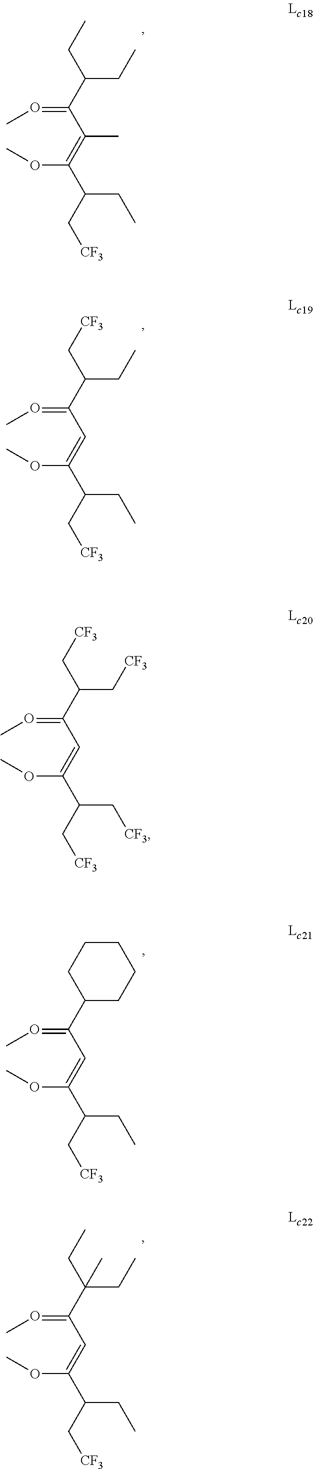 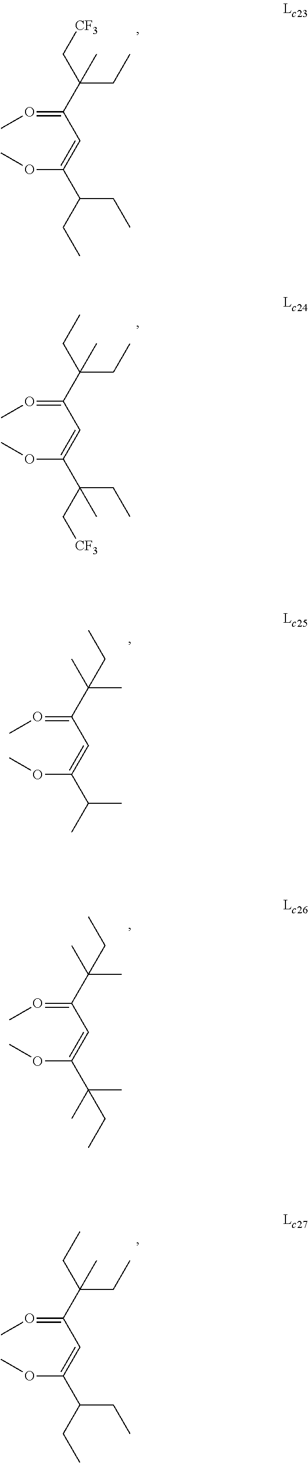 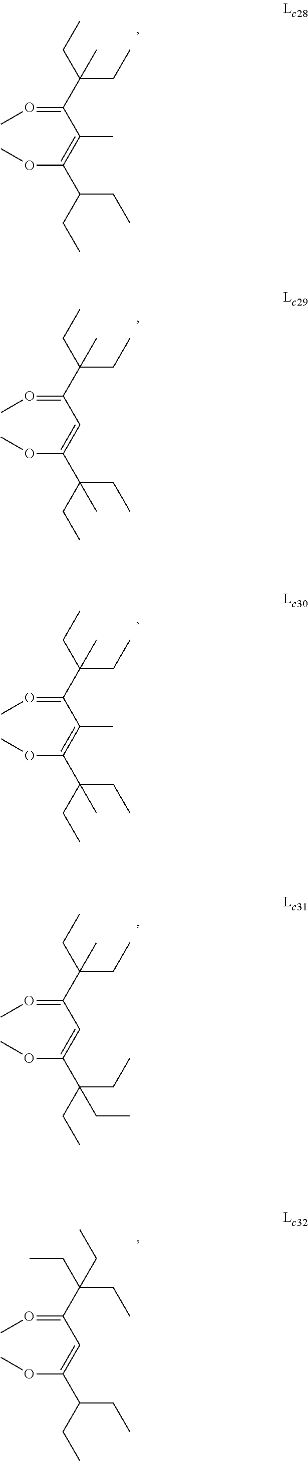 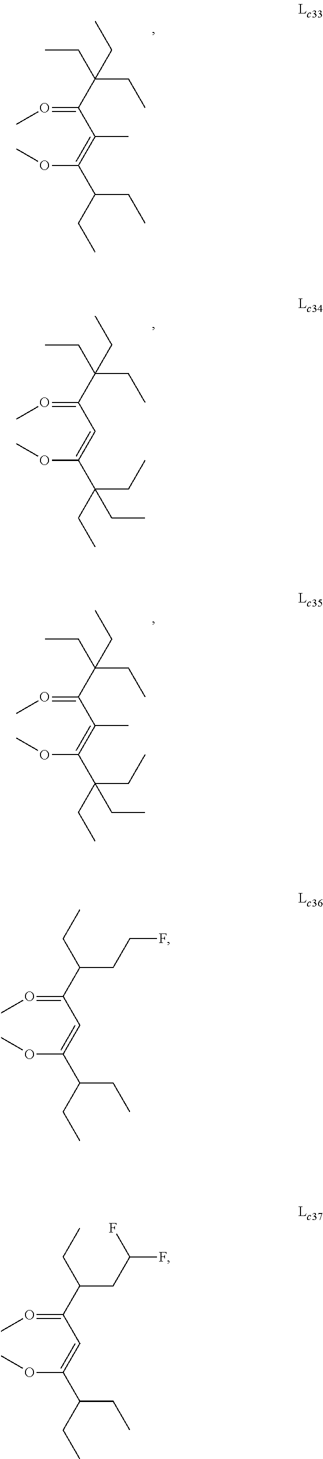 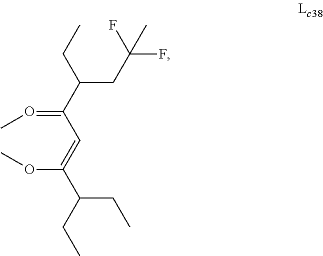 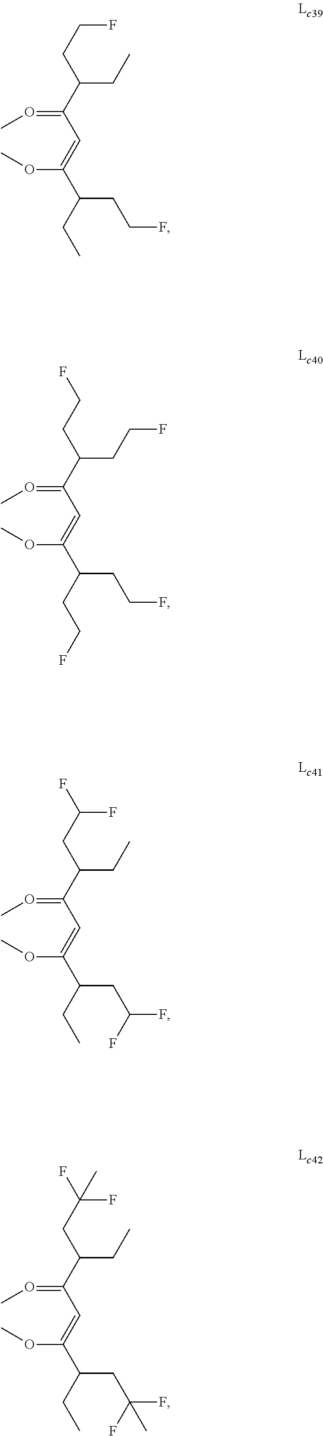 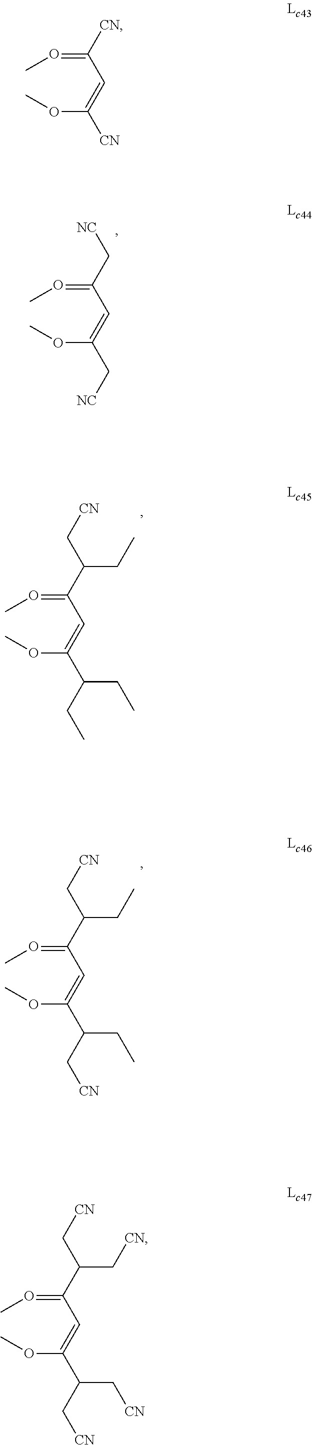 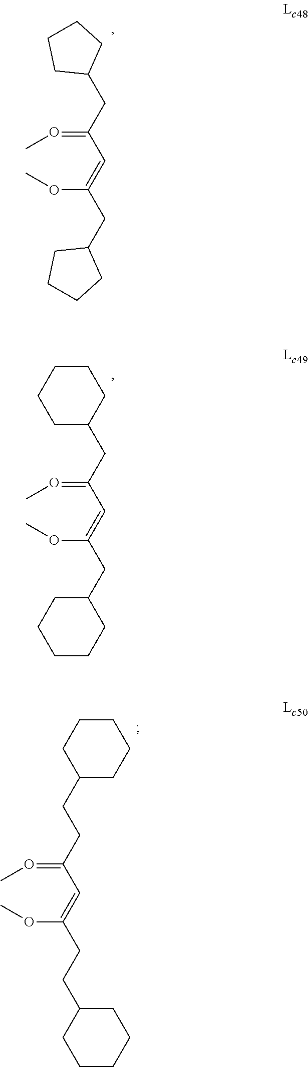
wherein optionally, hydrogens in the above structures of L_{c} can be partially or fully substituted with deuterium.

12. The organic electroluminescent device according to claim 10, wherein the metal complex is selected from the group consisting of GD1 to GD785 whose specific structures are shown below;
GD1 to GD185 have the following structures: 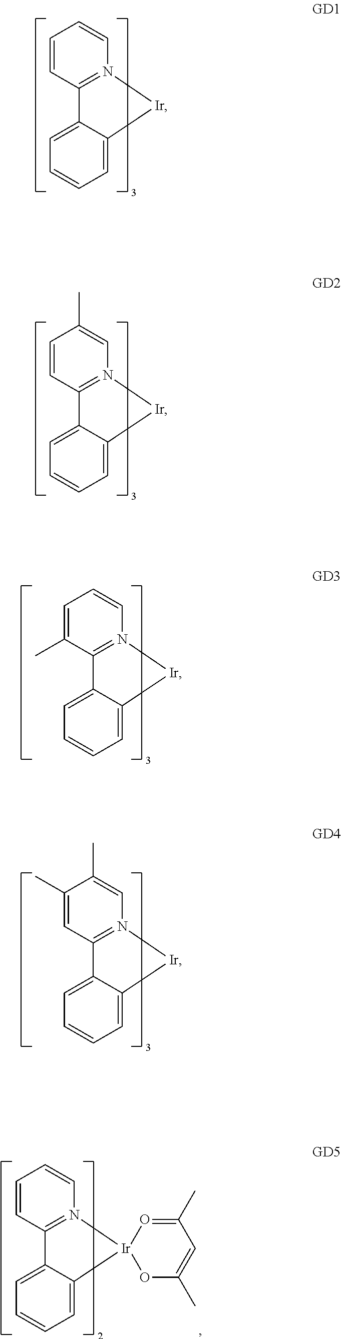 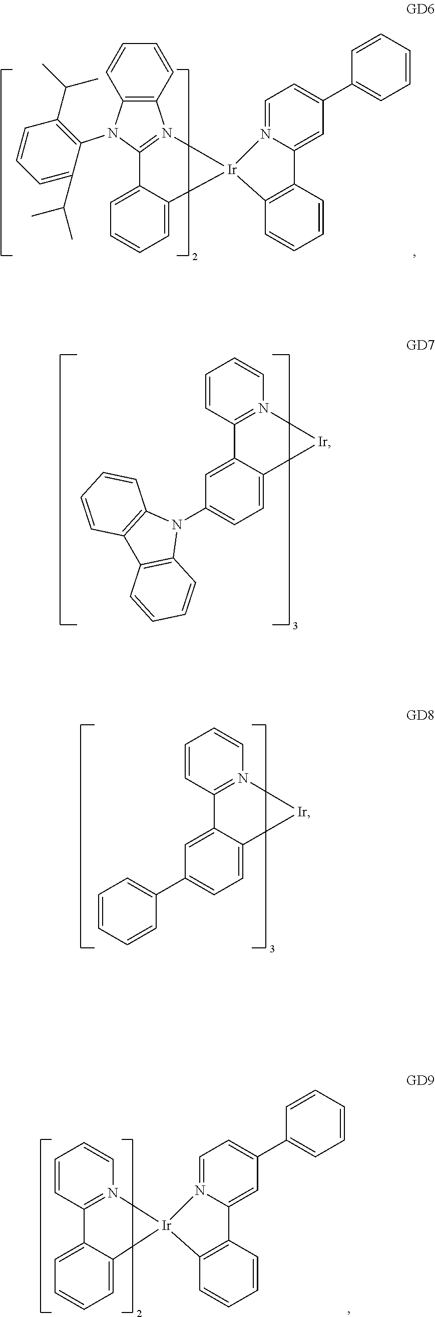 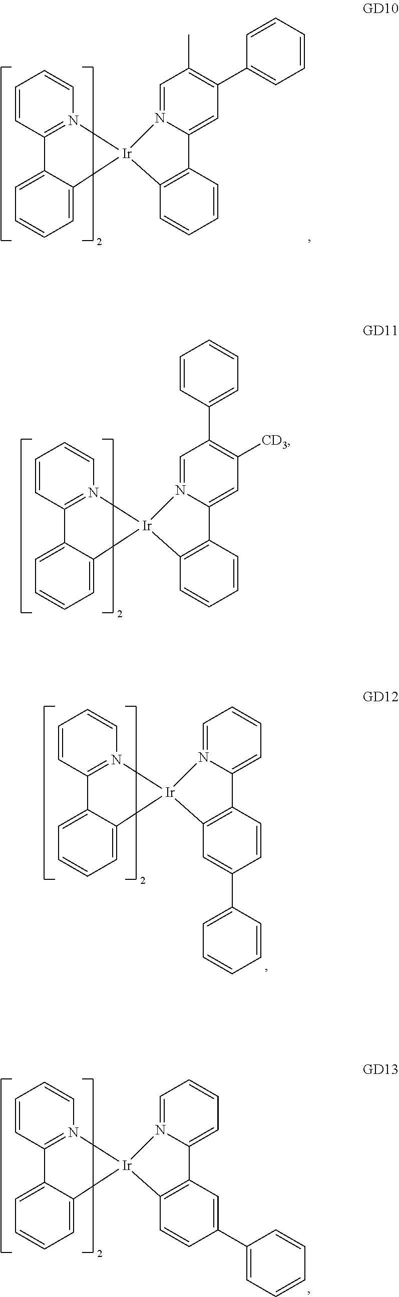 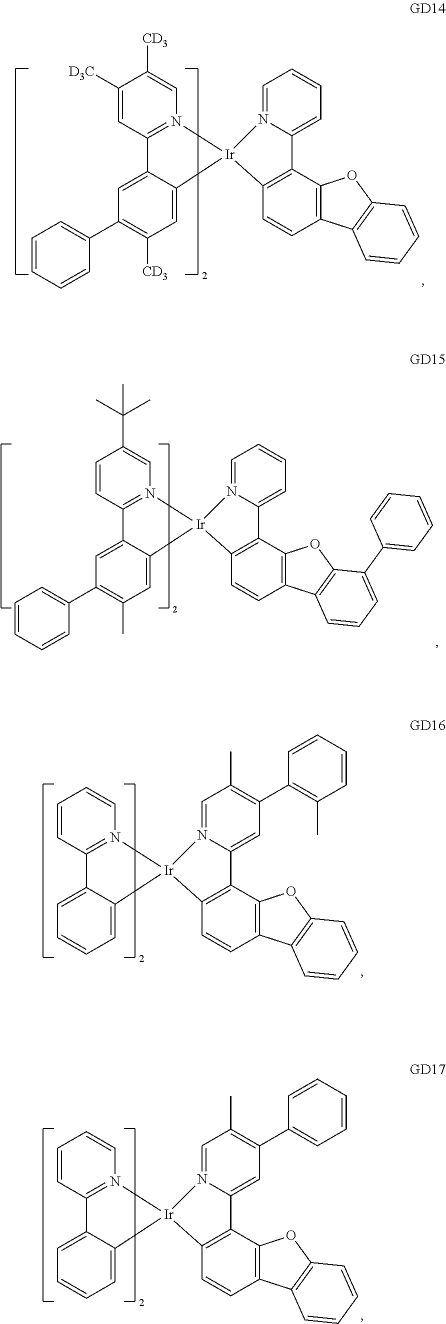 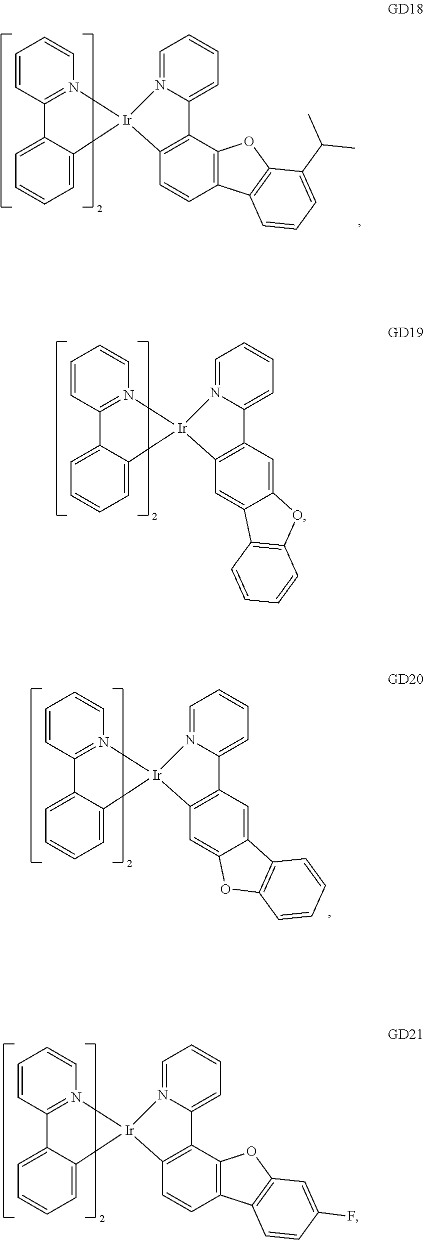 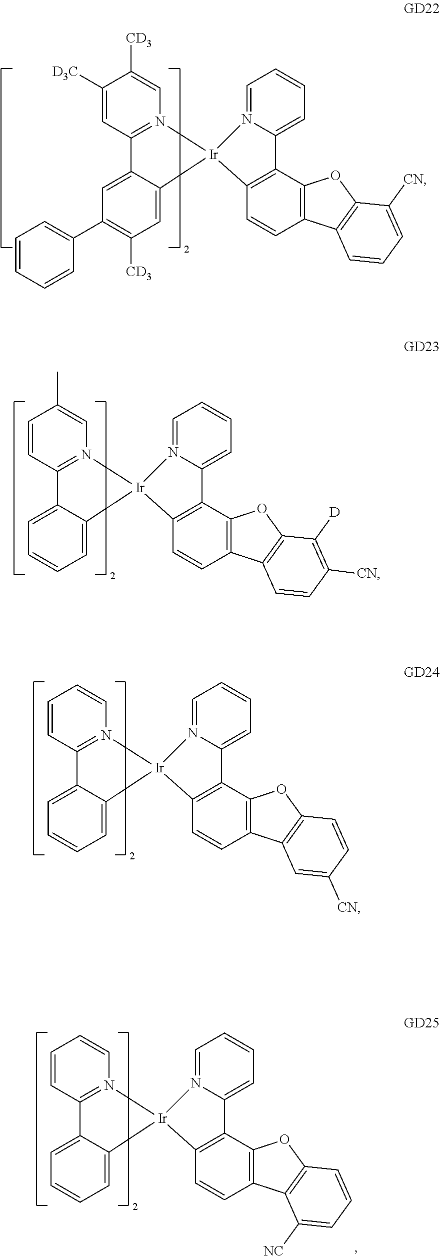 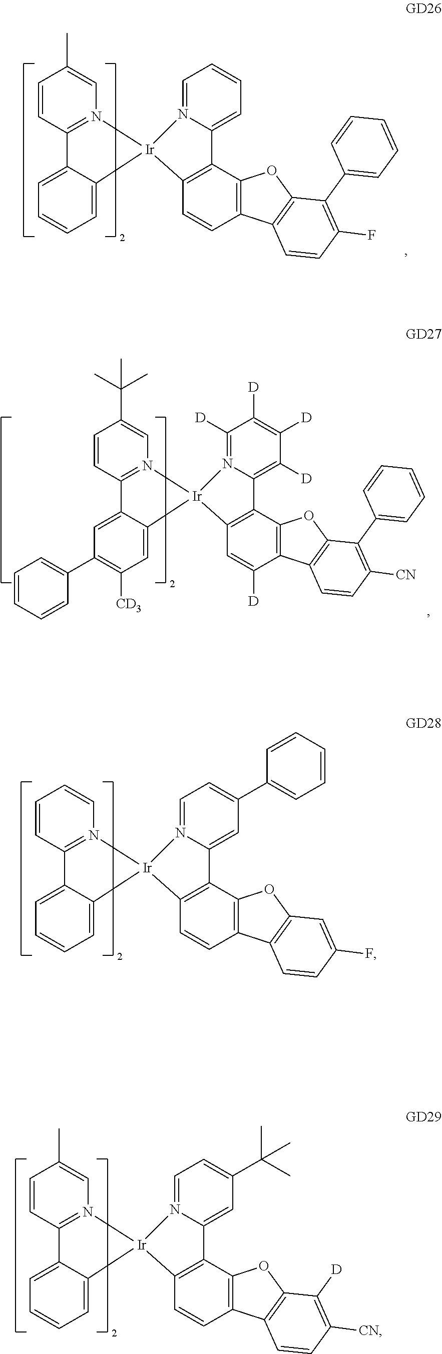 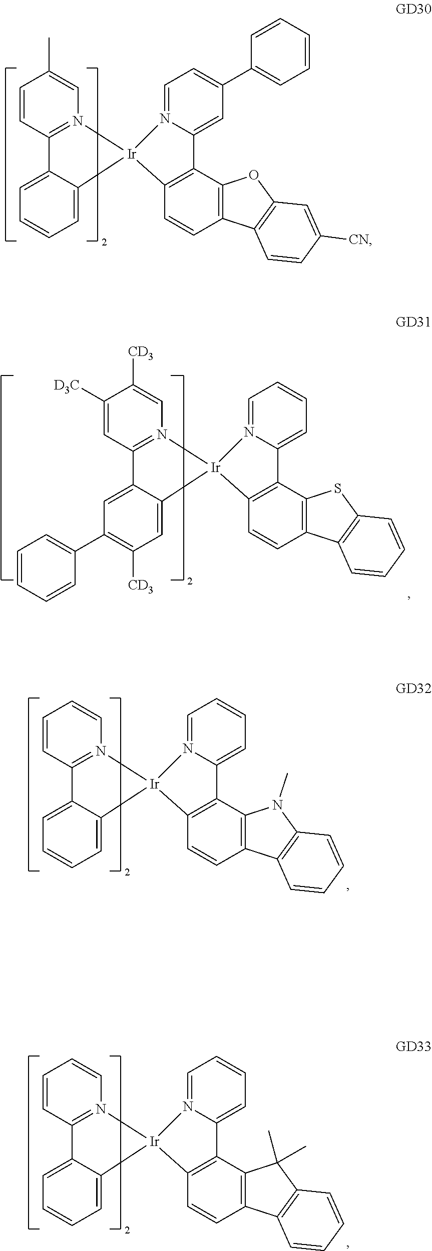 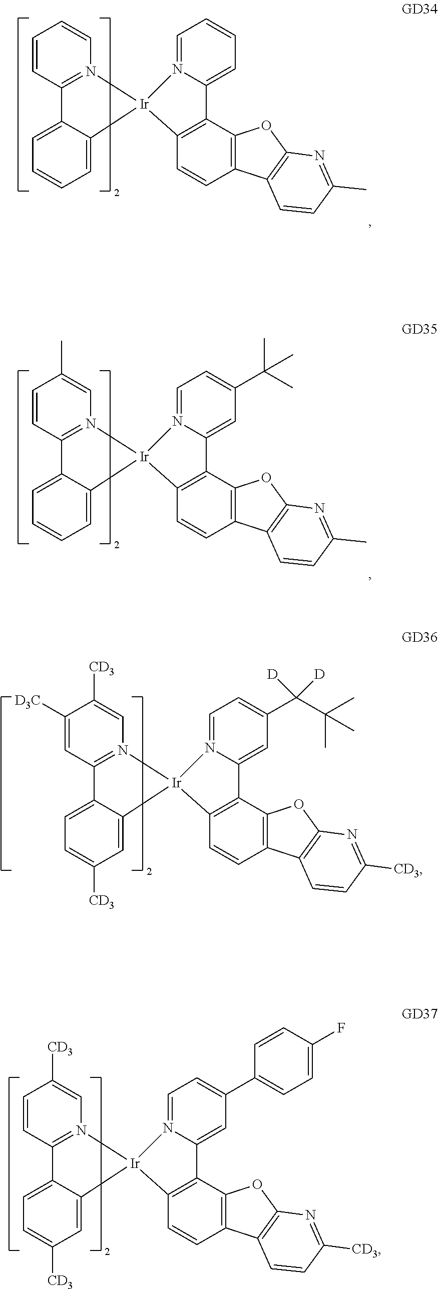 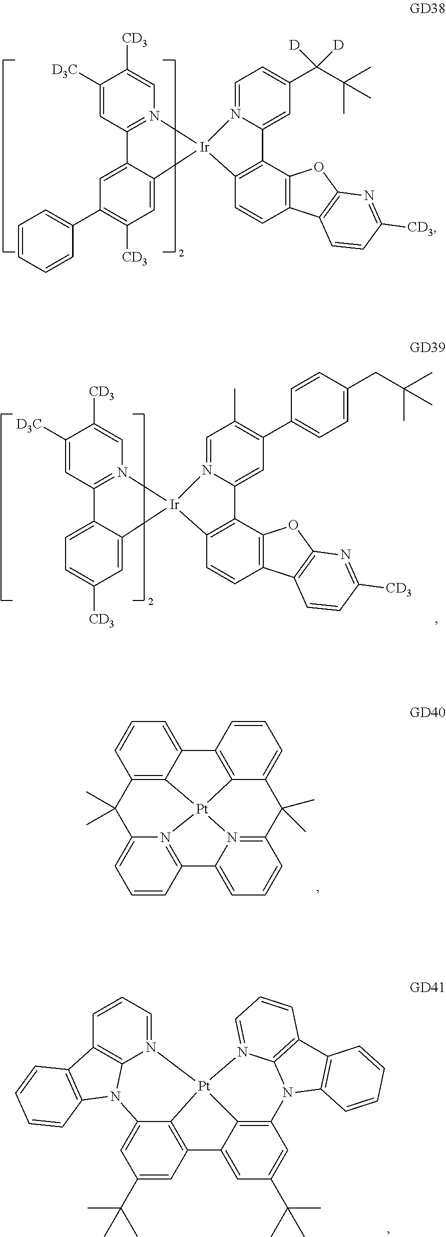 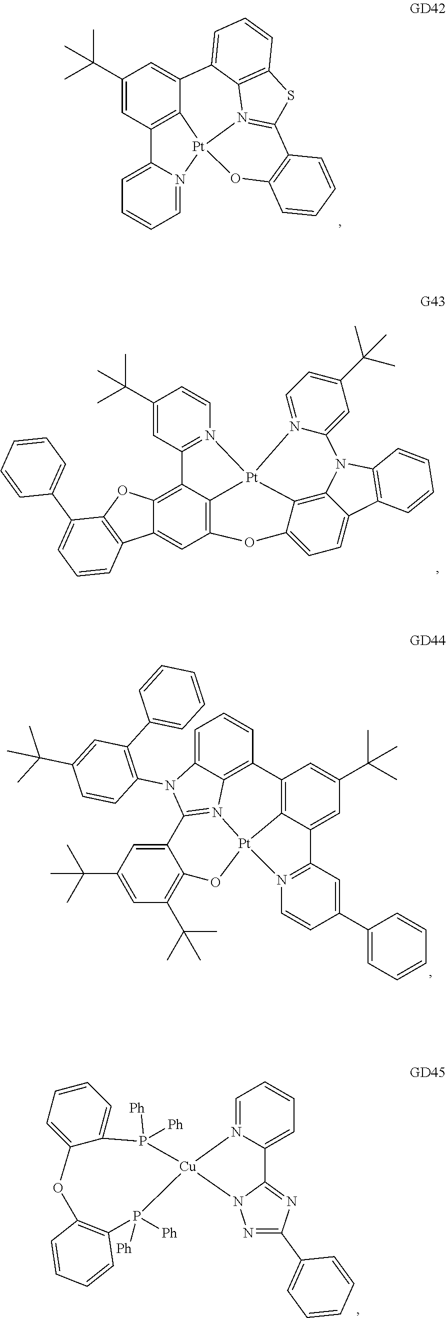 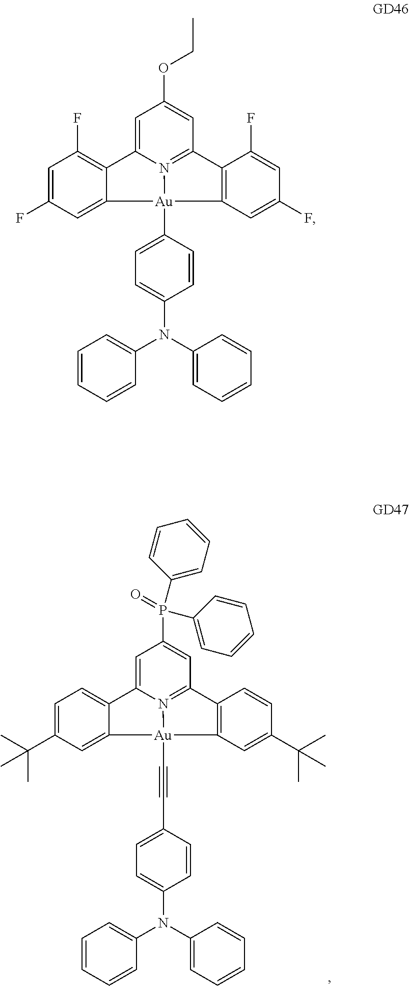 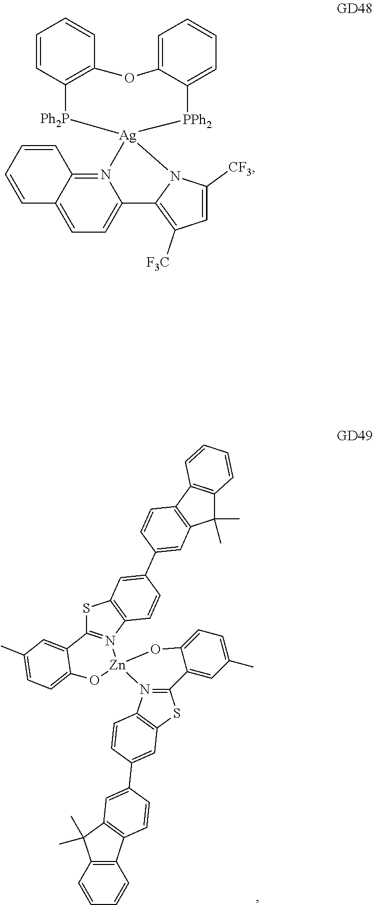 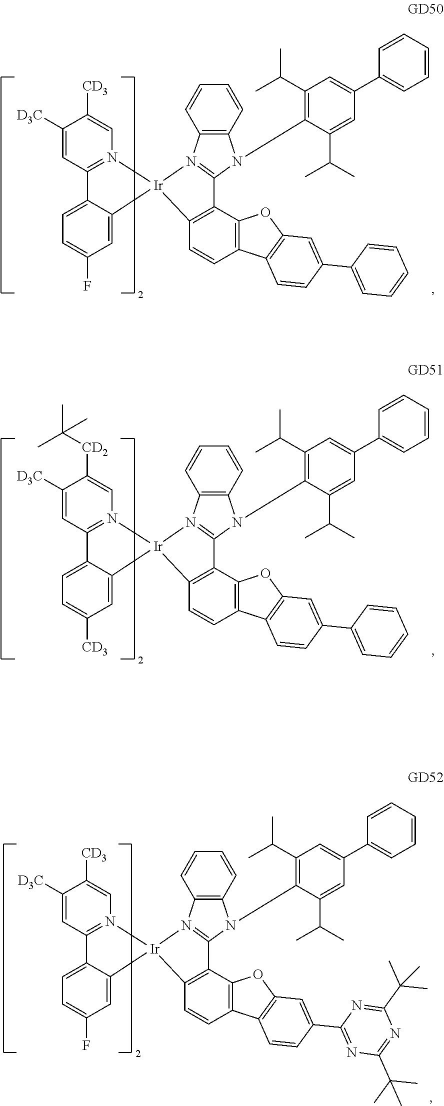 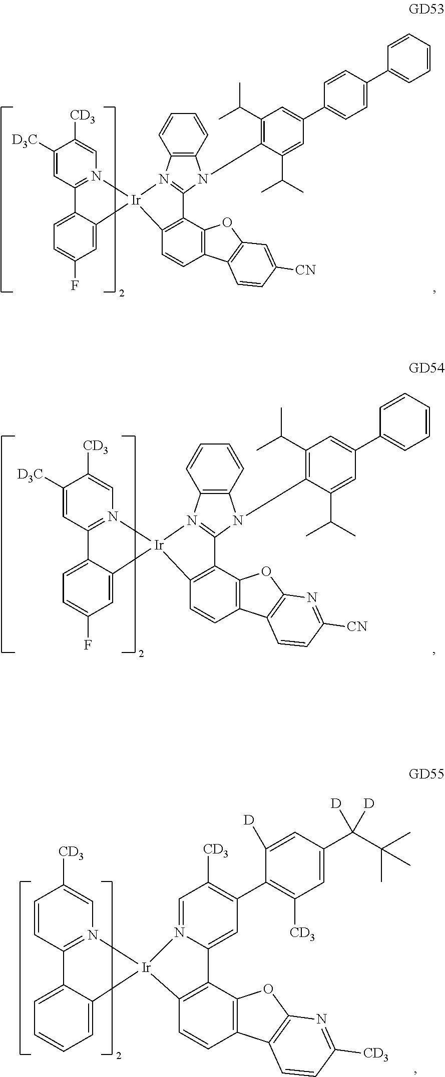 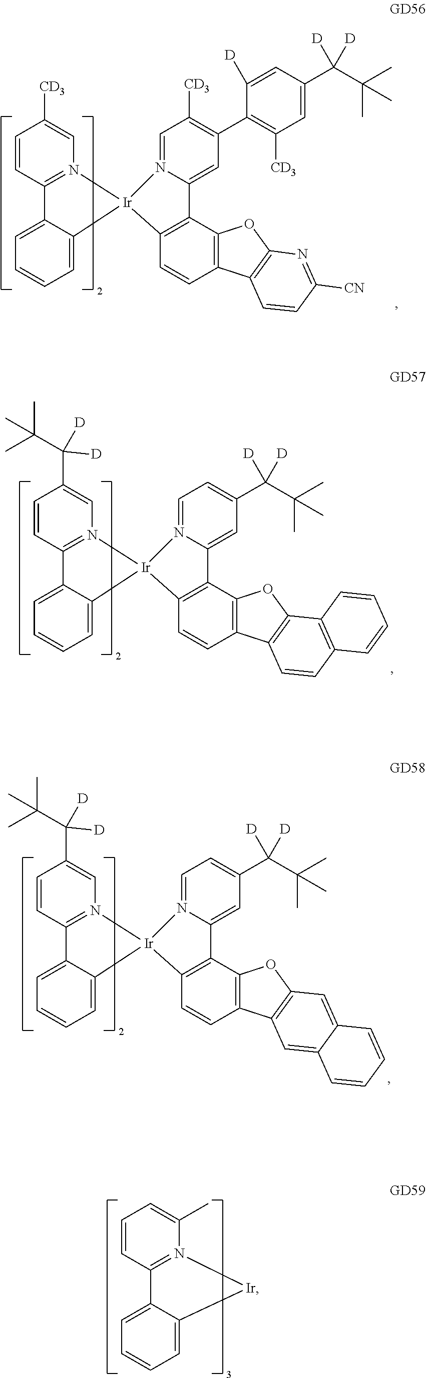 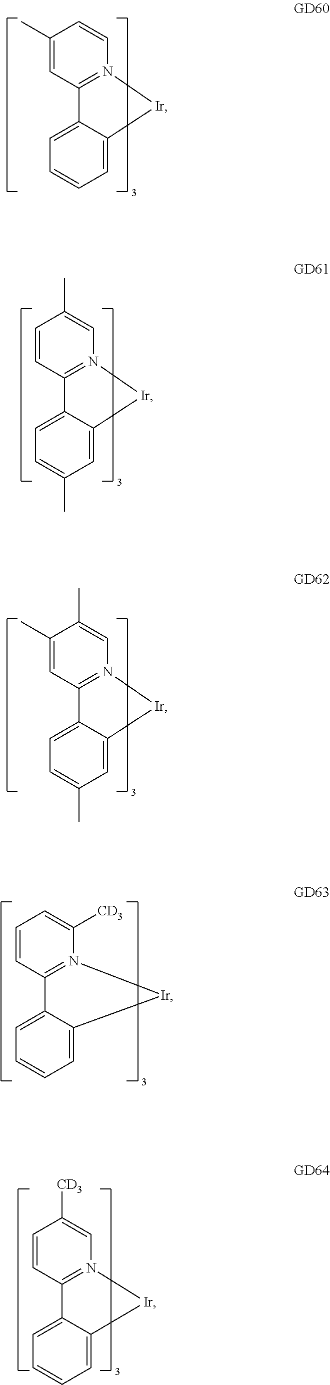 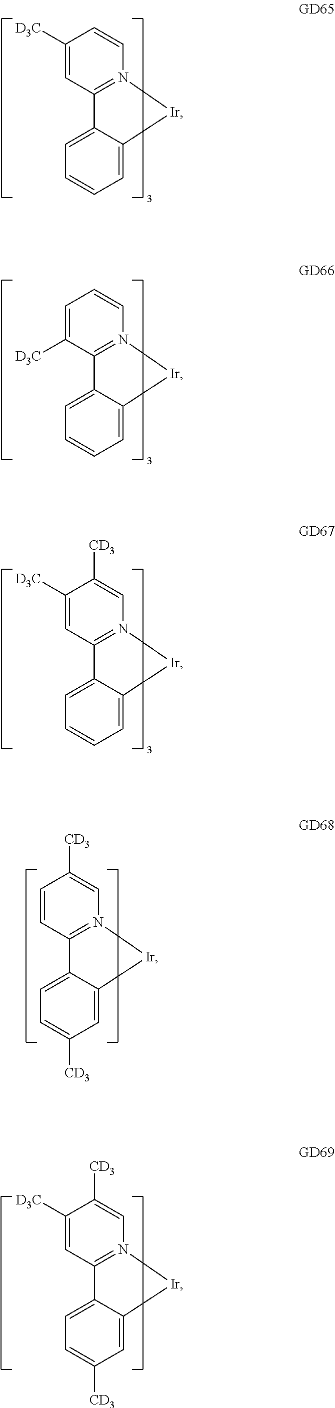 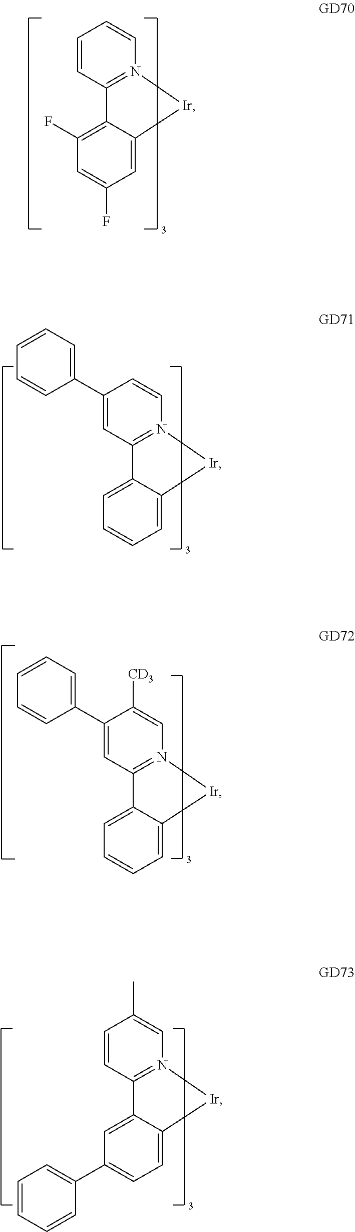 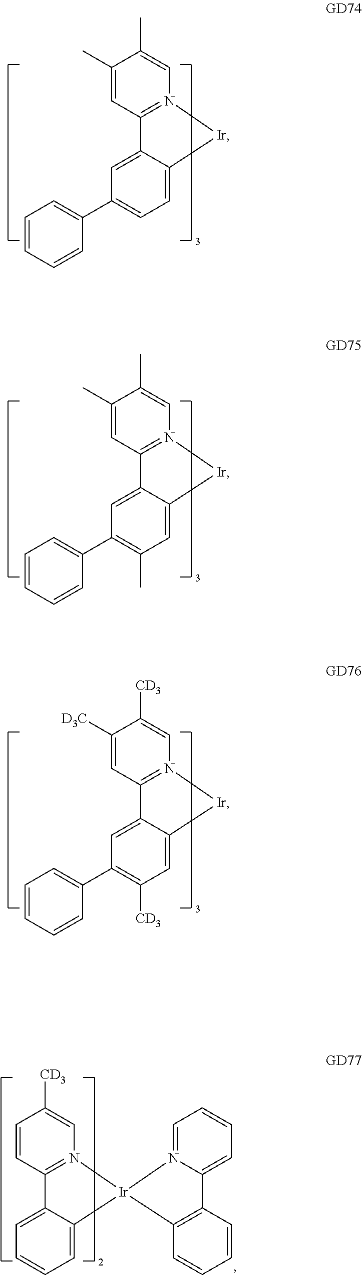 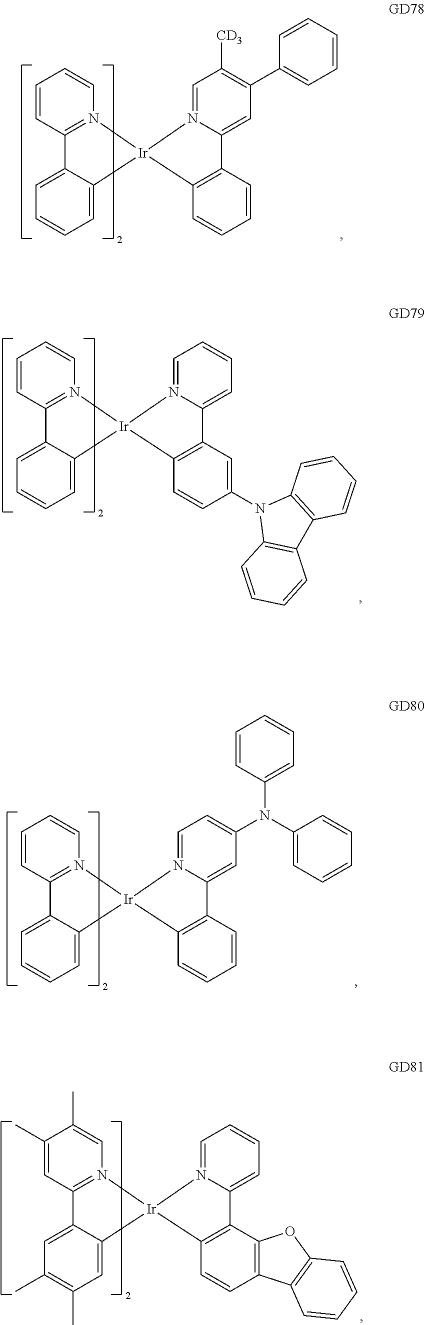 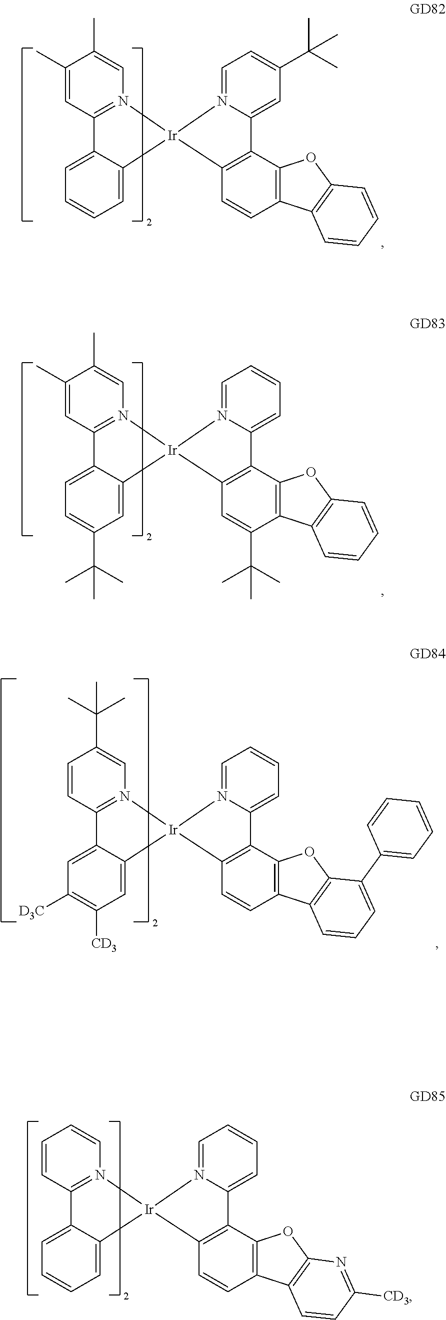 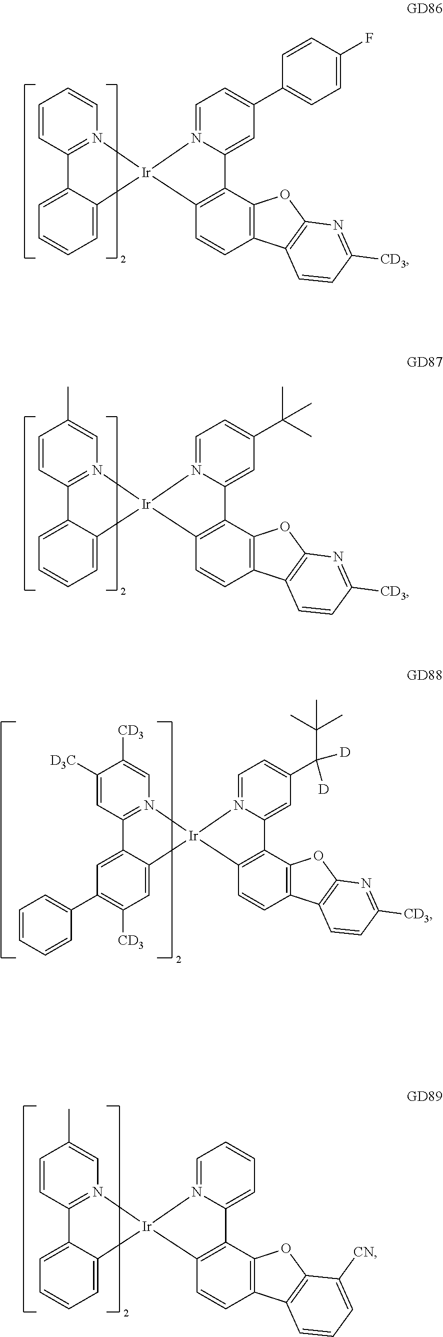 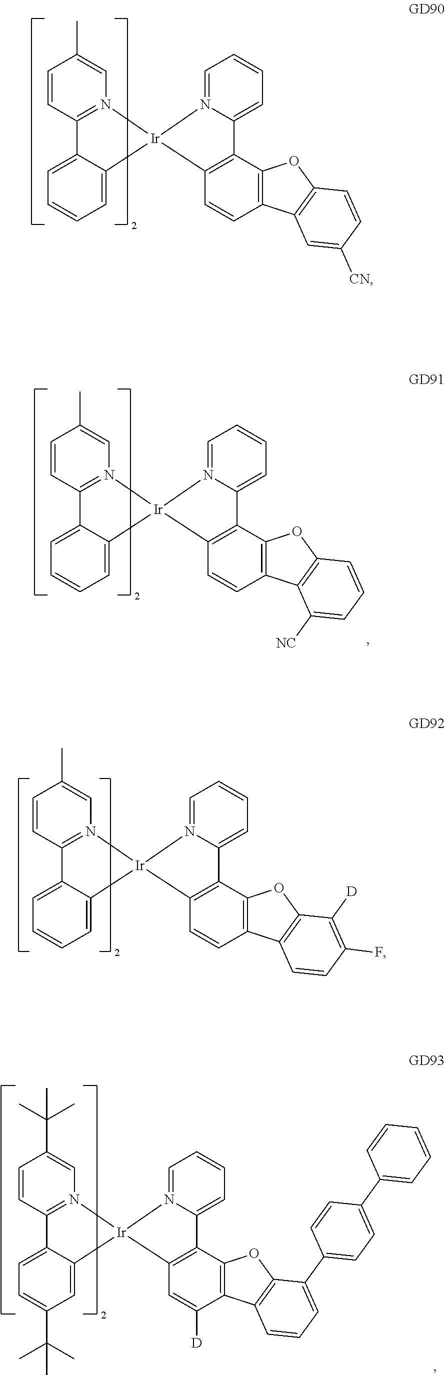 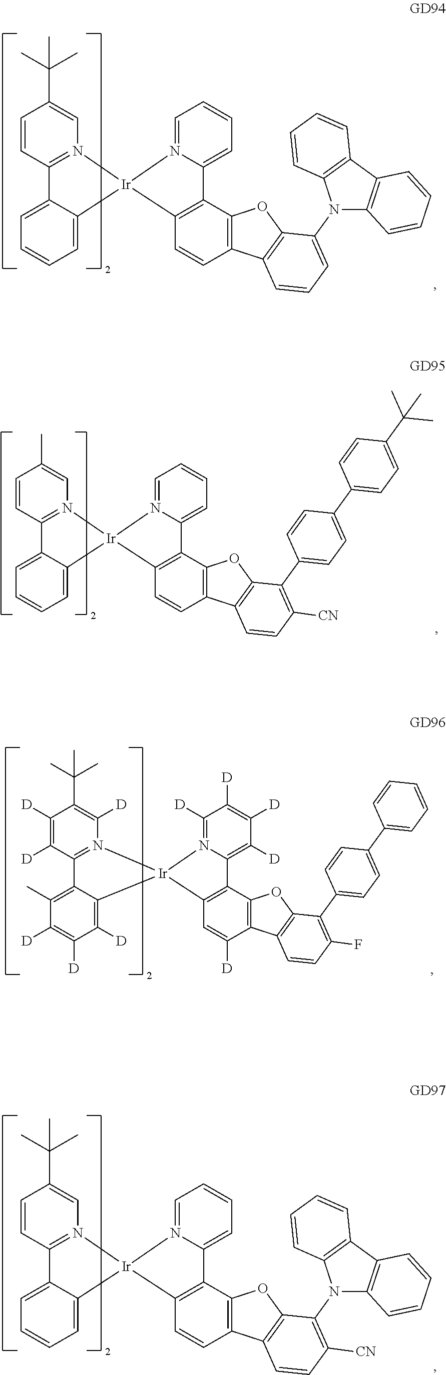 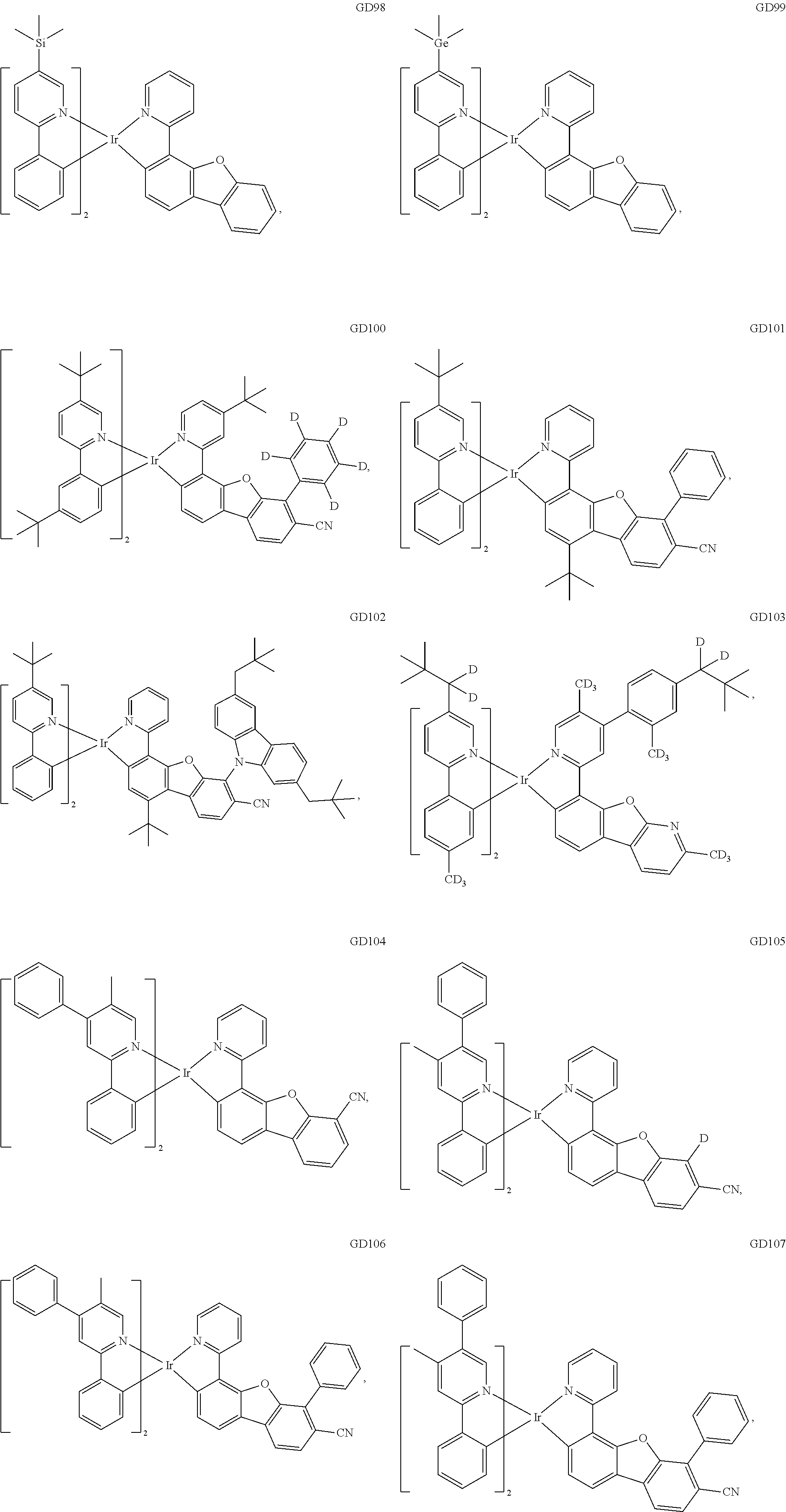 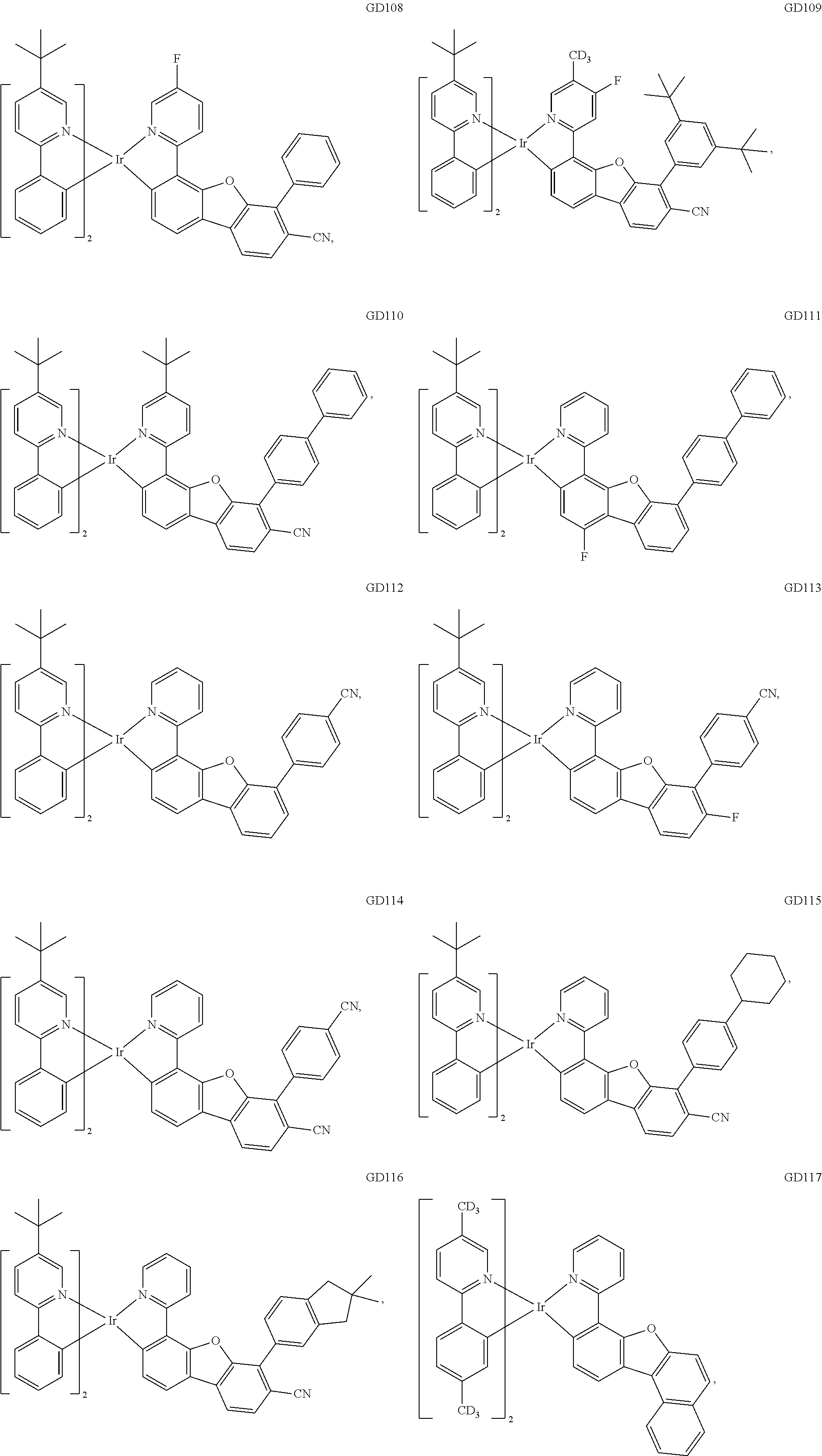 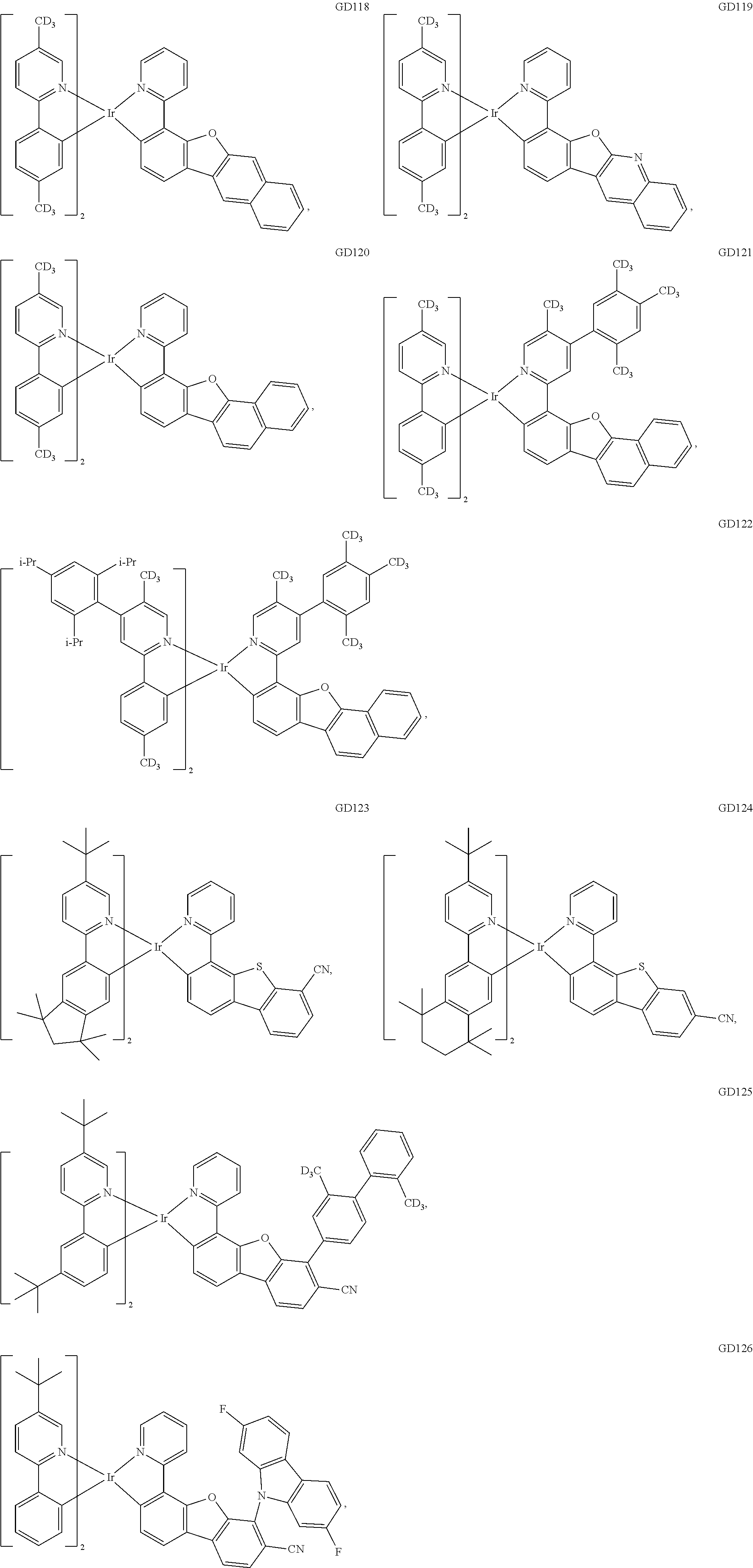 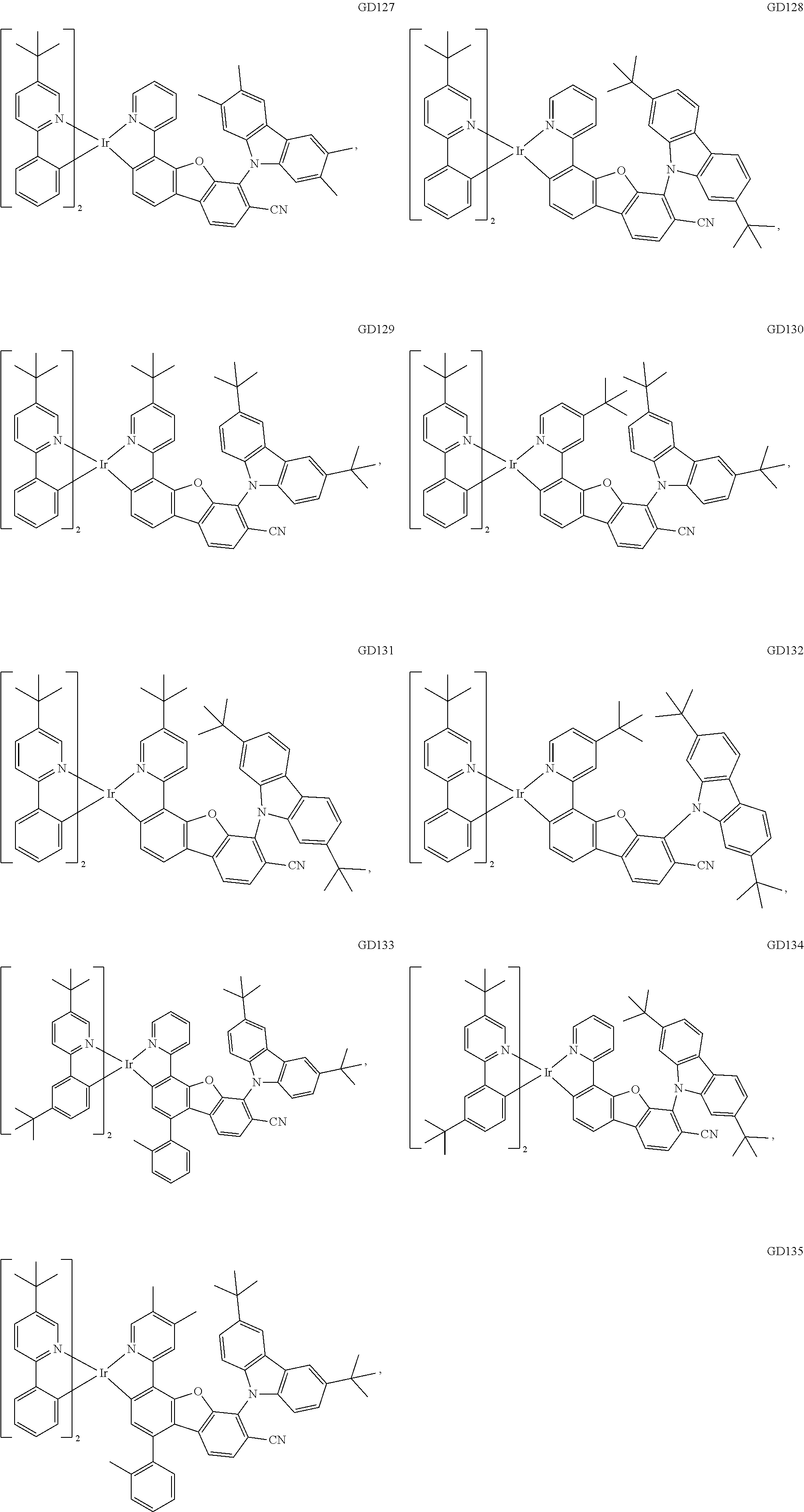 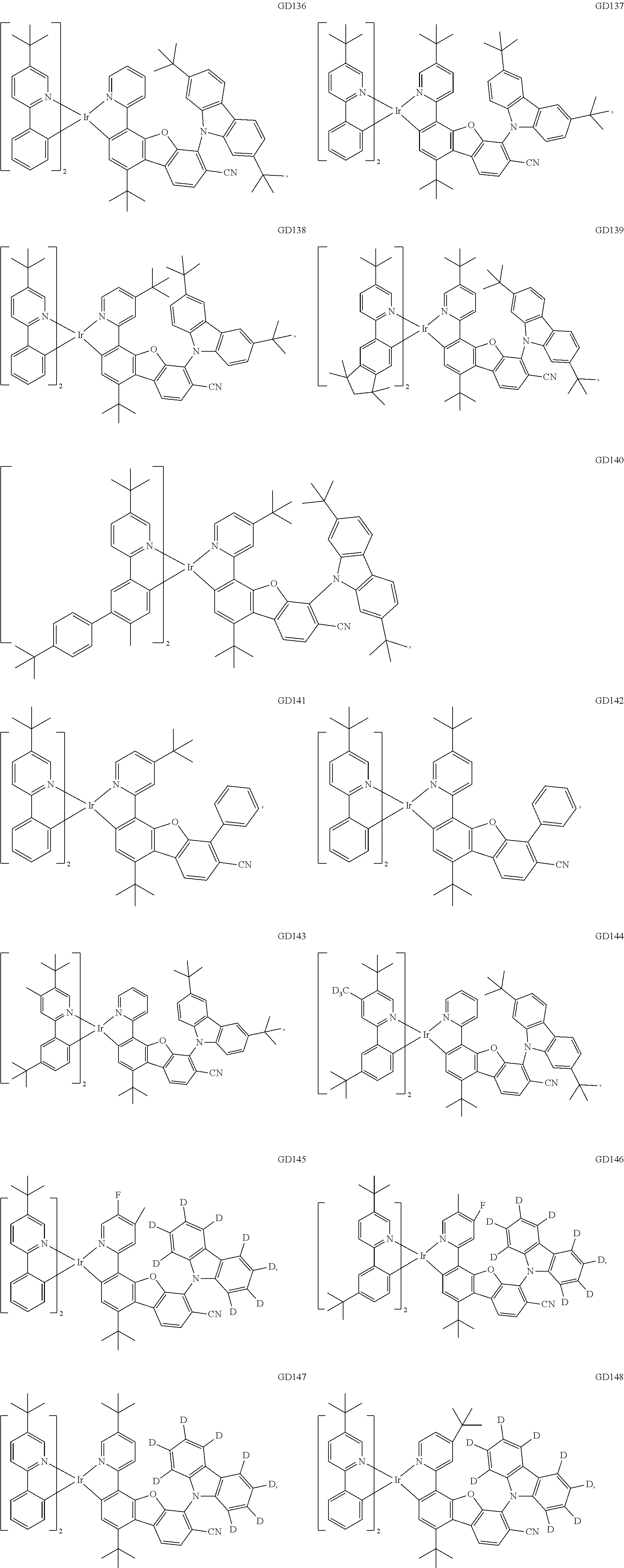 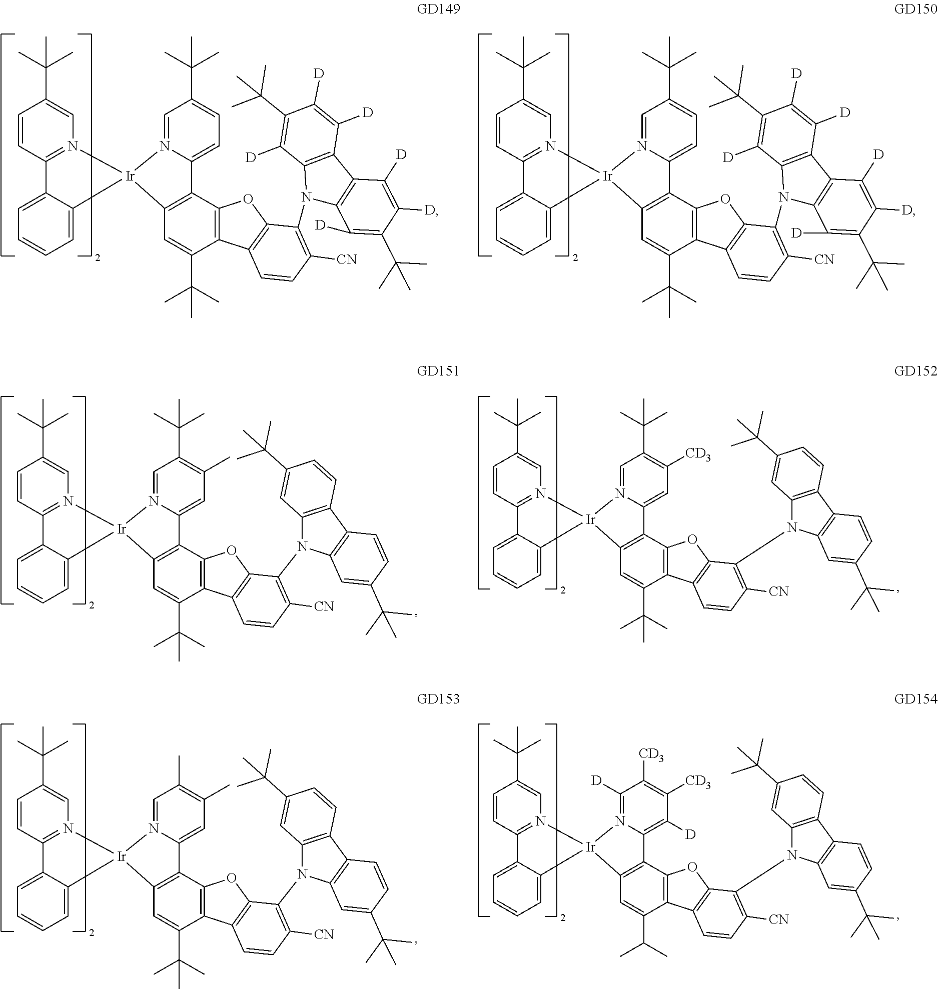 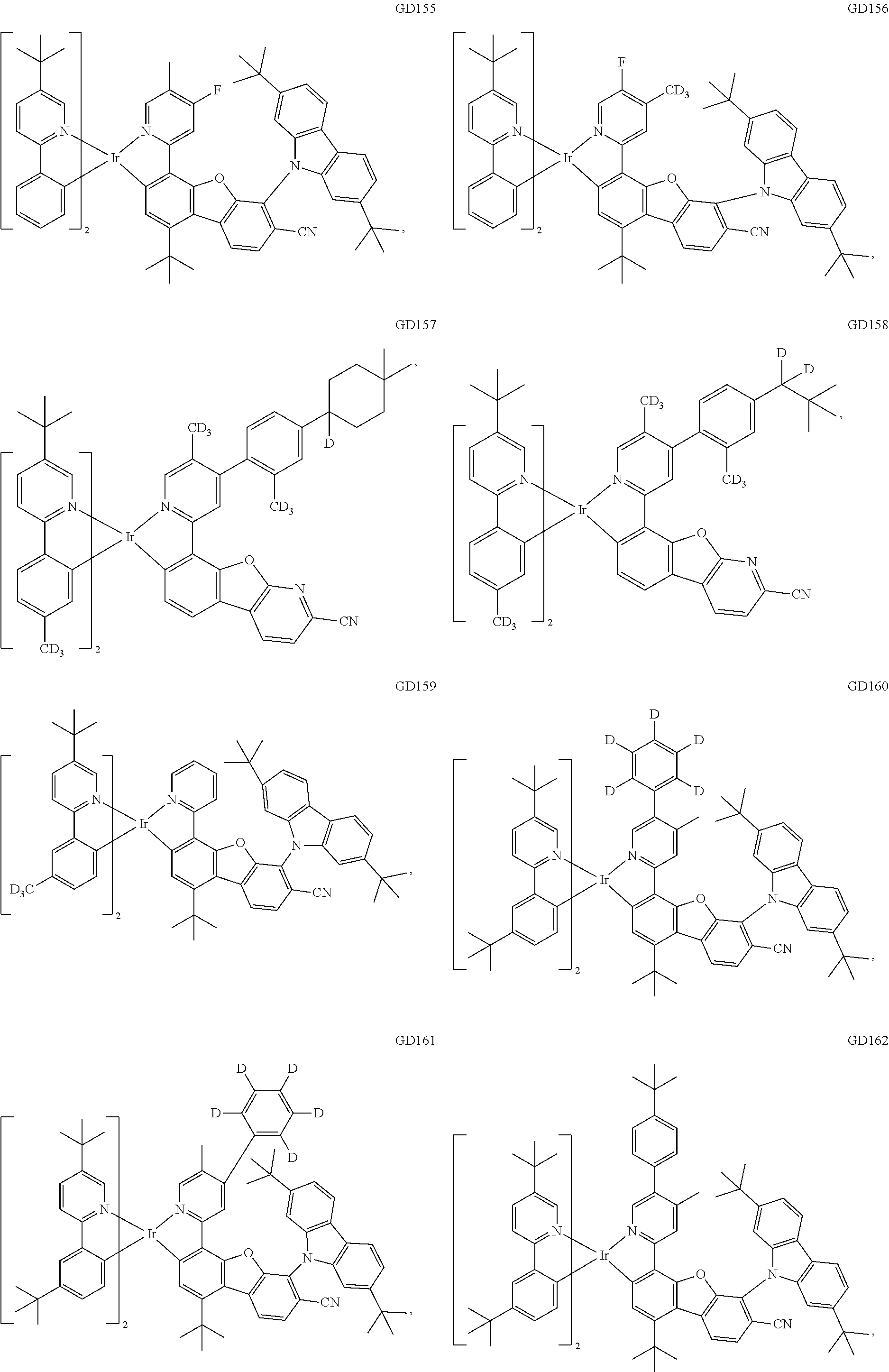 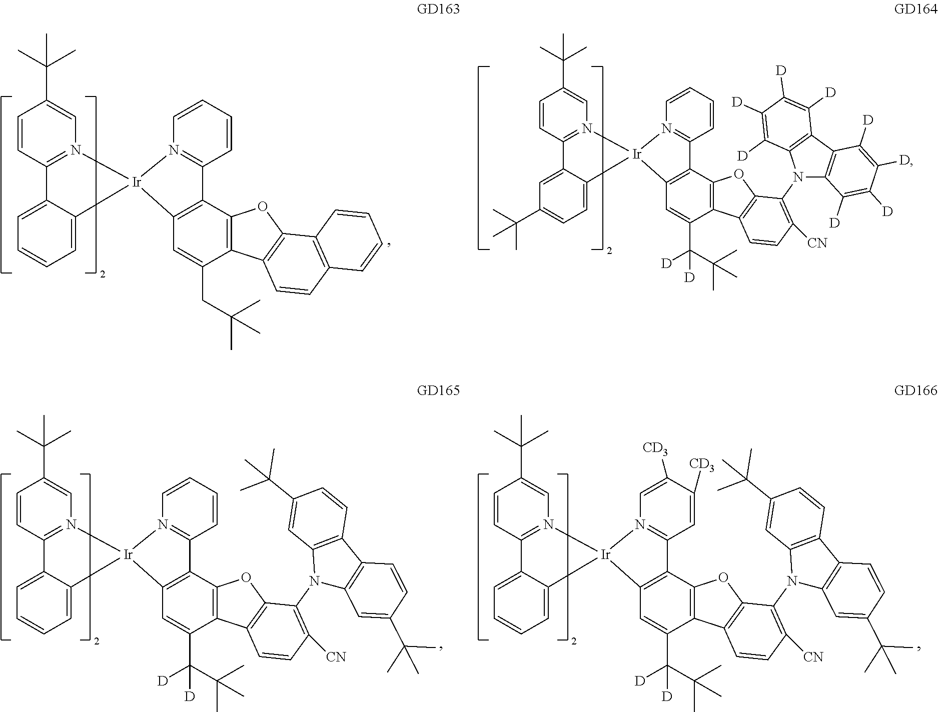 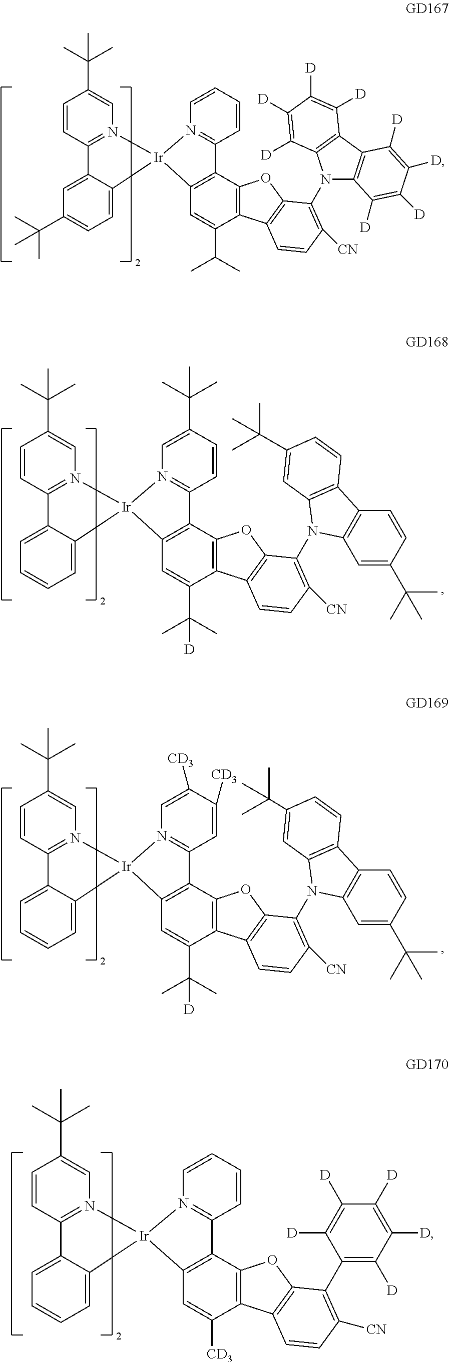 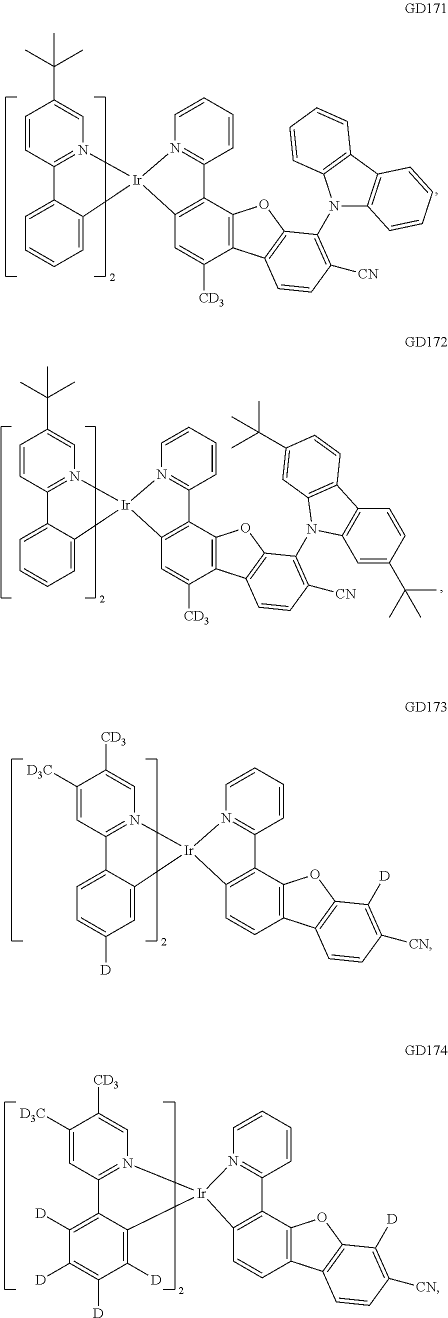 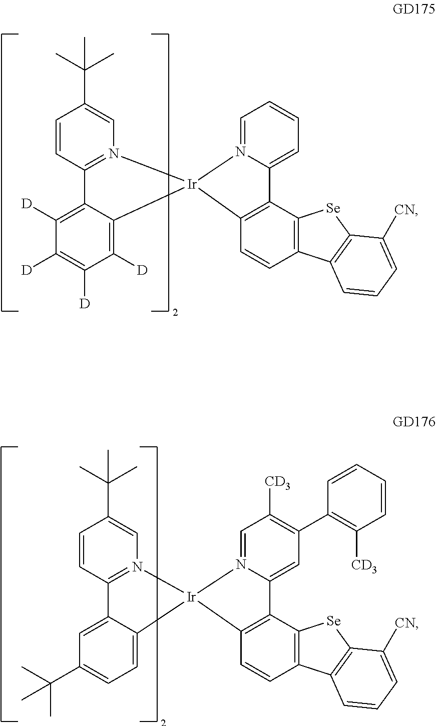 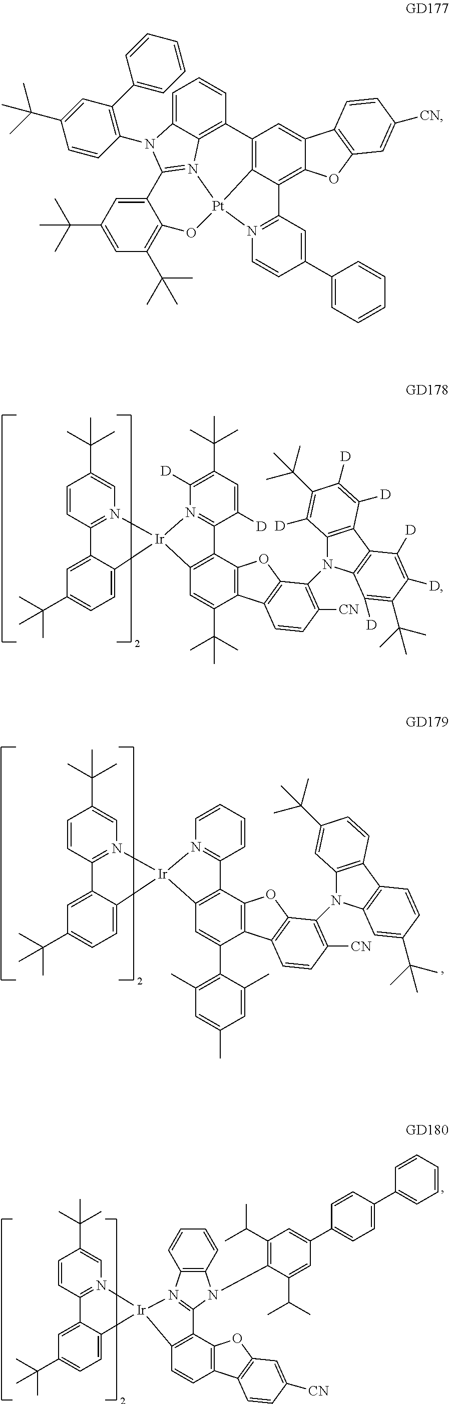 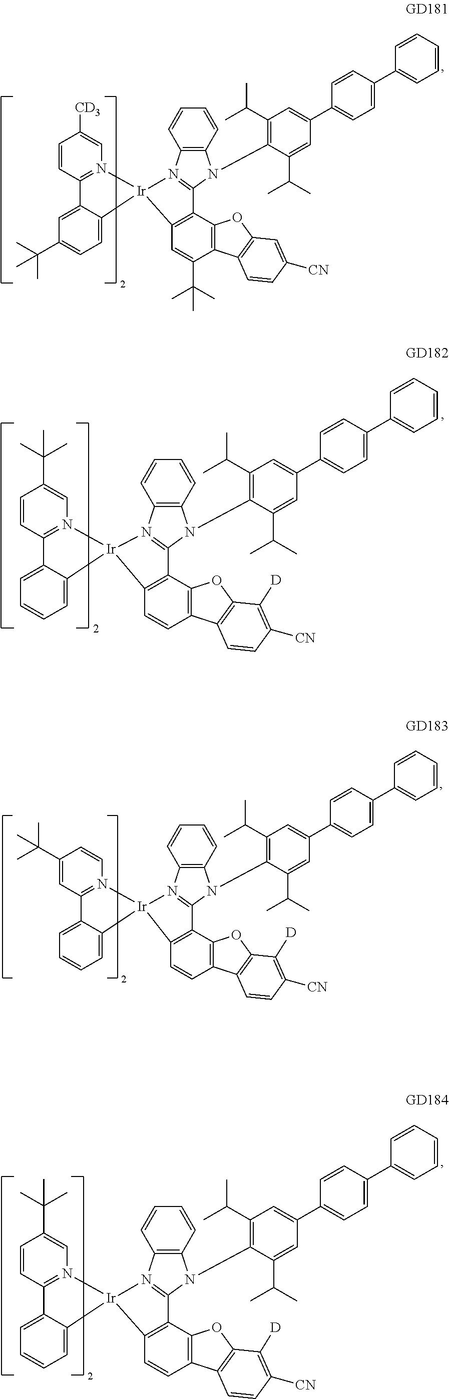 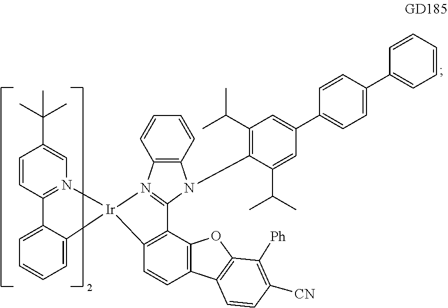
and
GD186 to GD785 each have a structure of Ir(Lₐ)(L_{b})₂, wherein two L_{b} are identical, Lₐ is selected from the group consisting of La-1-1 to La-1-300 and La-2-1 to La-2-63, L_{b} is selected from the group consisting of L_{b1} to L_{b169}, and GD186 to GD785 have specific structures shown in the following table:

| Metal | | | Metal | | | Metal | | |
|---|---|---|---|---|---|---|---|---|
| complex | Lₐ | L_{b} | complex | Lₐ | L_{b} | complex | Lₐ | L_{b} |
| GD186 | La-1-1 | Lb1 | GD187 | La-1-1 | Lb20 | GD188 | La-1-1 | Lb52 |
| GD189 | La-1-5 | Lb1 | GD190 | La-1-5 | Lb20 | GD191 | La-1-5 | Lb52 |
| GD192 | La-1-6 | Lb1 | GD193 | La-1-6 | Lb20 | GD194 | La-1-6 | Lb52 |
| GD195 | La-1-11 | Lb1 | GD196 | La-1-11 | Lb20 | GD197 | La-1-11 | Lb52 |
| GD198 | La-1-15 | Lb1 | GD199 | La-1-15 | Lb20 | GD200 | La-1-15 | Lb52 |
| GD201 | La-1-17 | Lb1 | GD202 | La-1-17 | Lb20 | GD203 | La-1-17 | Lb52 |
| GD204 | La-1-24 | Lb1 | GD205 | La-1-24 | Lb20 | GD206 | La-1-24 | Lb52 |
| GD207 | La-1-25 | Lb1 | GD208 | La-1-25 | Lb20 | GD209 | La-1-25 | Lb52 |
| GD210 | La-1-28 | Lb1 | GD211 | La-1-28 | Lb20 | GD212 | La-1-28 | Lb52 |
| GD213 | La-1-29 | Lb1 | GD214 | La-1-29 | Lb20 | GD215 | La-1-29 | Lb52 |
| GD216 | La-1-31 | Lb1 | GD217 | La-1-31 | Lb20 | GD218 | La-1-31 | Lb52 |
| GD219 | La-1-32 | Lb1 | GD220 | La-1-32 | Lb20 | GD221 | La-1-32 | Lb52 |
| GD222 | La-1-39 | Lb1 | GD223 | La-1-39 | Lb20 | GD224 | La-1-39 | Lb52 |
| GD225 | La-1-49 | Lb1 | GD226 | La-1-49 | Lb20 | GD227 | La-1-49 | Lb52 |
| GD228 | La-1-50 | Lb1 | GD229 | La-1-50 | Lb20 | GD230 | La-1-50 | Lb52 |
| GD231 | La-1-53 | Lb1 | GD232 | La-1-53 | Lb20 | GD233 | La-1-53 | Lb52 |
| GD234 | La-1-57 | Lb1 | GD235 | La-1-57 | Lb20 | GD236 | La-1-57 | Lb52 |
| GD237 | La-1-62 | Lb1 | GD238 | La-1-62 | Lb20 | GD239 | La-1-62 | Lb52 |
| GD240 | La-1-64 | Lb1 | GD241 | La-1-64 | Lb20 | GD242 | La-1-64 | Lb52 |
| GD243 | La-1-67 | Lb1 | GD244 | La-1-67 | Lb20 | GD245 | La-1-67 | Lb52 |
| GD246 | La-1-68 | Lb1 | GD247 | La-1-68 | Lb20 | GD248 | La-1-68 | Lb52 |
| GD249 | La-1-69 | Lb1 | GD250 | La-1-69 | Lb20 | GD251 | La-1-69 | Lb52 |
| GD252 | La-1-70 | Lb1 | GD253 | La-1-70 | Lb20 | GD254 | La-1-70 | Lb52 |
| GD255 | La-1-71 | Lb1 | GD256 | La-1-71 | Lb20 | GD257 | La-1-71 | Lb52 |
| GD258 | La-1-72 | Lb1 | GD259 | La-1-72 | Lb20 | GD260 | La-1-72 | Lb52 |
| GD261 | La-1-74 | Lb1 | GD262 | La-1-74 | Lb20 | GD263 | La-1-74 | Lb52 |
| GD264 | La-1-80 | Lb1 | GD265 | La-1-80 | Lb20 | GD266 | La-1-80 | Lb52 |
| GD267 | La-1-83 | Lb1 | GD268 | La-1-83 | Lb20 | GD269 | La-1-83 | Lb52 |
| GD270 | La-1-101 | Lb1 | GD271 | La-1-101 | Lb20 | GD272 | La-1-101 | Lb52 |
| GD273 | La-1-100 | Lb1 | GD274 | La-1-100 | Lb20 | GD275 | La-1-100 | Lb52 |
| GD276 | La-1-111 | Lb1 | GD277 | La-1-111 | Lb20 | GD278 | La-1-111 | Lb52 |
| GD279 | La-1-114 | Lb1 | GD280 | La-1-114 | Lb20 | GD281 | La-1-114 | Lb52 |
| GD282 | La-1-120 | Lb1 | GD283 | La-1-120 | Lb20 | GD284 | La-1-120 | Lb52 |
| GD285 | La-1-130 | Lb1 | GD286 | La-1-130 | Lb20 | GD287 | La-1-130 | Lb52 |
| GD288 | La-1-133 | Lb1 | GD289 | La-1-133 | Lb20 | GD290 | La-1-133 | Lb52 |
| GD291 | La-1-136 | Lb1 | GD292 | La-1-136 | Lb20 | GD293 | La-1-136 | Lb52 |
| GD294 | La-1-138 | Lb1 | GD295 | La-1-138 | Lb20 | GD296 | La-1-138 | Lb52 |
| GD297 | La-1-148 | Lb1 | GD298 | La-1-148 | Lb20 | GD299 | La-1-148 | Lb52 |
| GD300 | La-1-150 | Lb1 | GD301 | La-1-150 | Lb20 | GD302 | La-1-150 | Lb52 |
| GD303 | La-1-151 | Lb1 | GD304 | La-1-151 | Lb20 | GD305 | La-1-151 | Lb52 |
| GD306 | La-1-157 | Lb1 | GD307 | La-1-157 | Lb20 | GD308 | La-1-157 | Lb52 |
| GD309 | La-1-162 | Lb1 | GD310 | La-1-162 | Lb20 | GD311 | La-1-162 | Lb52 |
| GD312 | La-1-164 | Lb1 | GD313 | La-1-164 | Lb20 | GD314 | La-1-164 | Lb52 |
| GD315 | La-1-169 | Lb1 | GD316 | La-1-169 | Lb20 | GD317 | La-1-169 | Lb52 |
| GD318 | La-1-170 | Lb1 | GD319 | La-1-170 | Lb20 | GD320 | La-1-170 | Lb52 |
| GD321 | La-1-177 | Lb1 | GD322 | La-1-177 | Lb20 | GD323 | La-1-177 | Lb52 |
| GD324 | La-1-178 | Lb1 | GD325 | La-1-178 | Lb20 | GD326 | La-1-178 | Lb52 |
| GD327 | La-1-180 | Lb1 | GD328 | La-1-180 | Lb20 | GD329 | La-1-180 | Lb52 |
| GD330 | La-1-187 | Lb1 | GD331 | La-1-187 | Lb20 | GD332 | La-1-187 | Lb52 |
| GD333 | La-1-189 | Lb1 | GD334 | La-1-189 | Lb20 | GD335 | La-1-189 | Lb52 |
| GD336 | La-1-192 | Lb1 | GD337 | La-1-192 | Lb20 | GD338 | La-1-192 | Lb52 |
| GD339 | La-1-193 | Lb1 | GD340 | La-1-193 | Lb20 | GD341 | La-1-193 | Lb52 |
| GD342 | La-1-194 | Lb1 | GD343 | La-1-194 | Lb20 | GD344 | La-1-194 | Lb52 |
| GD345 | La-1-201 | Lb1 | GD346 | La-1-201 | Lb20 | GD347 | La-1-201 | Lb52 |
| GD348 | La-1-205 | Lb1 | GD349 | La-1-205 | Lb20 | GD350 | La-1-205 | Lb52 |
| GD351 | La-1-206 | Lb1 | GD352 | La-1-206 | Lb20 | GD353 | La-1-206 | Lb52 |
| GD354 | La-1-210 | Lb1 | GD355 | La-1-210 | Lb20 | GD356 | La-1-210 | Lb52 |
| GD357 | La-1-220 | Lb1 | GD358 | La-1-220 | Lb20 | GD359 | La-1-220 | Lb52 |
| GD360 | La-1-230 | Lb1 | GD361 | La-1-230 | Lb20 | GD362 | La-1-230 | Lb52 |
| GD363 | La-1-246 | Lb1 | GD364 | La-1-246 | Lb20 | GD365 | La-1-246 | Lb52 |
| GD366 | La-1-247 | Lb1 | GD367 | La-1-247 | Lb20 | GD368 | La-1-247 | Lb52 |
| GD369 | La-1-251 | Lb1 | GD370 | La-1-251 | Lb20 | GD371 | La-1-251 | Lb52 |
| GD372 | La-1-252 | Lb1 | GD373 | La-1-252 | Lb20 | GD374 | La-1-252 | Lb52 |
| GD375 | La-1-269 | Lb1 | GD376 | La-1-269 | Lb20 | GD377 | La-1-269 | Lb52 |
| GD378 | La-1-277 | Lb1 | GD379 | La-1-277 | Lb20 | GD380 | La-1-277 | Lb52 |
| GD381 | La-1-282 | Lb1 | GD382 | La-1-282 | Lb20 | GD383 | La-1-282 | Lb52 |
| GD384 | La-1-287 | Lb1 | GD385 | La-1-287 | Lb20 | GD386 | La-1-287 | Lb52 |
| GD387 | La-1-300 | Lb1 | GD388 | La-1-300 | Lb20 | GD389 | La-1-300 | Lb52 |
| GD390 | La-2-13 | Lb1 | GD391 | La-2-13 | Lb20 | GD392 | La-2-13 | Lb52 |
| GD393 | La-2-19 | Lb1 | GD394 | La-2-19 | Lb20 | GD395 | La-2-19 | Lb52 |
| GD396 | La-2-23 | Lb1 | GD397 | La-2-23 | Lb20 | GD398 | La-2-23 | Lb52 |
| GD399 | La-2-24 | Lb1 | GD400 | La-2-24 | Lb20 | GD401 | La-2-24 | Lb52 |
| GD402 | La-2-25 | Lb1 | GD403 | La-2-25 | Lb20 | GD404 | La-2-25 | Lb52 |
| GD405 | La-2-28 | Lb1 | GD406 | La-2-28 | Lb20 | GD407 | La-2-28 | Lb52 |
| GD408 | La-2-29 | Lb1 | GD409 | La-2-29 | Lb20 | GD410 | La-2-29 | Lb52 |
| GD411 | La-2-30 | Lb1 | GD412 | La-2-30 | Lb20 | GD413 | La-2-30 | Lb52 |
| GD414 | La-2-31 | Lb1 | GD415 | La-2-31 | Lb20 | GD416 | La-2-31 | Lb52 |
| GD417 | La-2-33 | Lb1 | GD418 | La-2-33 | Lb20 | GD419 | La-2-33 | Lb52 |
| GD420 | La-2-35 | Lb1 | GD421 | La-2-35 | Lb20 | GD422 | La-2-35 | Lb52 |
| GD423 | La-2-37 | Lb1 | GD424 | La-2-37 | Lb20 | GD425 | La-2-37 | Lb52 |
| GD426 | La-2-38 | Lb1 | GD427 | La-2-38 | Lb20 | GD428 | La-2-38 | Lb52 |
| GD429 | La-2-39 | Lb1 | GD430 | La-2-39 | Lb20 | GD431 | La-2-39 | Lb52 |
| GD432 | La-2-40 | Lb1 | GD433 | La-2-40 | Lb20 | GD434 | La-2-40 | Lb52 |
| GD435 | La-2-43 | Lb1 | GD436 | La-2-43 | Lb20 | GD437 | La-2-43 | Lb52 |
| GD438 | La-2-44 | Lb1 | GD439 | La-2-44 | Lb20 | GD440 | La-2-44 | Lb52 |
| GD441 | La-2-45 | Lb1 | GD442 | La-2-45 | Lb20 | GD443 | La-2-45 | Lb52 |
| GD444 | La-2-46 | Lb1 | GD445 | La-2-46 | Lb20 | GD446 | La-2-46 | Lb52 |
| GD447 | La-2-49 | Lb1 | GD448 | La-2-49 | Lb20 | GD449 | La-2-49 | Lb52 |
| GD450 | La-2-50 | Lb1 | GD451 | La-2-50 | Lb20 | GD452 | La-2-50 | Lb52 |
| GD453 | La-2-53 | Lb1 | GD454 | La-2-53 | Lb20 | GD455 | La-2-53 | Lb52 |
| GD456 | La-2-54 | Lb1 | GD457 | La-2-54 | Lb20 | GD458 | La-2-54 | Lb52 |
| GD459 | La-2-55 | Lb1 | GD460 | La-2-55 | Lb20 | GD461 | La-2-55 | Lb52 |
| GD462 | La-2-56 | Lb1 | GD463 | La-2-56 | Lb20 | GD464 | La-2-56 | Lb52 |
| GD465 | La-2-57 | Lb1 | GD466 | La-2-57 | Lb20 | GD467 | La-2-57 | Lb52 |
| GD468 | La-2-58 | Lb1 | GD469 | La-2-58 | Lb20 | GD470 | La-2-58 | Lb52 |
| GD471 | La-2-59 | Lb1 | GD472 | La-2-59 | Lb20 | GD473 | La-2-59 | Lb52 |
| GD474 | La-2-60 | Lb1 | GD475 | La-2-60 | Lb20 | GD476 | La-2-60 | Lb52 |
| GD477 | La-2-61 | Lb1 | GD478 | La-2-61 | Lb20 | GD479 | La-2-61 | Lb52 |
| GD480 | La-2-62 | Lb1 | GD481 | La-2-62 | Lb20 | GD482 | La-2-62 | Lb52 |
| GD483 | La-2-63 | Lb1 | GD484 | La-2-63 | Lb20 | GD485 | La-2-63 | Lb52 |
| GD486 | La-1-1 | Lb135 | GD487 | La-1-1 | Lb165 | GD488 | La-1-1 | Lb3 |
| GD489 | La-1-5 | Lb135 | GD490 | La-1-5 | Lb165 | GD491 | La-1-5 | Lb6 |
| GD492 | La-1-6 | Lb135 | GD493 | La-1-6 | Lb165 | GD494 | La-1-6 | Lb8 |
| GD495 | La-1-11 | Lb135 | GD496 | La-1-11 | Lb165 | GD497 | La-1-11 | Lb9 |
| GD498 | La-1-15 | Lb135 | GD499 | La-1-15 | Lb165 | GD500 | La-1-15 | Lb10 |
| GD501 | La-1-17 | Lb135 | GD502 | La-1-17 | Lb165 | GD503 | La-1-17 | Lb19 |
| GD504 | La-1-24 | Lb135 | GD505 | La-1-24 | Lb165 | GD506 | La-1-24 | Lb20 |
| GD507 | La-1-25 | Lb135 | GD508 | La-1-25 | Lb165 | GD509 | La-1-25 | Lb21 |
| GD510 | La-1-28 | Lb135 | GD511 | La-1-28 | Lb165 | GD512 | La-1-28 | Lb22 |
| GD513 | La-1-29 | Lb135 | GD514 | La-1-29 | Lb165 | GD515 | La-1-29 | Lb23 |
| GD516 | La-1-31 | Lb135 | GD517 | La-1-31 | Lb165 | GD518 | La-1-31 | Lb24 |
| GD519 | La-1-32 | Lb135 | GD520 | La-1-32 | Lb165 | GD521 | La-1-32 | Lb25 |
| GD522 | La-1-39 | Lb135 | GD523 | La-1-39 | Lb165 | GD524 | La-1-39 | Lb26 |
| GD525 | La-1-49 | Lb135 | GD526 | La-1-49 | Lb165 | GD527 | La-1-49 | Lb27 |
| GD528 | La-1-50 | Lb135 | GD529 | La-1-50 | Lb165 | GD530 | La-1-50 | Lb28 |
| GD531 | La-1-53 | Lb135 | GD532 | La-1-53 | Lb165 | GD533 | La-1-53 | Lb29 |
| GD534 | La-1-57 | Lb135 | GD535 | La-1-57 | Lb165 | GD536 | La-1-57 | Lb30 |
| GD537 | La-1-62 | Lb135 | GD538 | La-1-62 | Lb165 | GD539 | La-1-62 | Lb54 |
| GD540 | La-1-64 | Lb135 | GD541 | La-1-64 | Lb165 | GD542 | La-1-64 | Lb55 |
| GD543 | La-1-67 | Lb135 | GD544 | La-1-67 | Lb165 | GD545 | La-1-67 | Lb56 |
| GD546 | La-1-68 | Lb135 | GD547 | La-1-68 | Lb165 | GD548 | La-1-68 | Lb57 |
| GD549 | La-1-69 | Lb135 | GD550 | La-1-69 | Lb165 | GD551 | La-1-69 | Lb70 |
| GD552 | La-1-70 | Lb135 | GD553 | La-1-70 | Lb165 | GD554 | La-1-70 | Lb71 |
| GD555 | La-1-71 | Lb135 | GD556 | La-1-71 | Lb165 | GD557 | La-1-71 | Lb72 |
| GD558 | La-1-72 | Lb135 | GD559 | La-1-72 | Lb165 | GD560 | La-1-72 | Lb73 |
| GD561 | La-1-74 | Lb135 | GD562 | La-1-74 | Lb165 | GD563 | La-1-74 | Lb74 |
| GD564 | La-1-80 | Lb135 | GD565 | La-1-80 | Lb165 | GD566 | La-1-80 | Lb75 |
| GD567 | La-1-83 | Lb135 | GD568 | La-1-83 | Lb165 | GD569 | La-1-83 | Lb76 |
| GD570 | La-1-101 | Lb135 | GD571 | La-1-101 | Lb165 | GD572 | La-1-101 | Lb77 |
| GD573 | La-1-100 | Lb135 | GD574 | La-1-100 | Lb165 | GD575 | La-1-100 | Lb78 |
| GD576 | La-1-111 | Lb135 | GD577 | La-1-111 | Lb165 | GD578 | La-1-111 | Lb79 |
| GD579 | La-1-114 | Lb135 | GD580 | La-1-114 | Lb165 | GD581 | La-1-114 | Lb80 |
| GD582 | La-1-120 | Lb135 | GD583 | La-1-120 | Lb165 | GD584 | La-1-120 | Lb93 |
| GD585 | La-1-130 | Lb135 | GD586 | La-1-130 | Lb165 | GD587 | La-1-130 | Lb94 |
| GD588 | La-1-133 | Lb135 | GD589 | La-1-133 | Lb165 | GD590 | La-1-133 | Lb95 |
| GD591 | La-1-136 | Lb135 | GD592 | La-1-136 | Lb165 | GD593 | La-1-136 | Lb102 |
| GD594 | La-1-138 | Lb135 | GD595 | La-1-138 | Lb165 | GD596 | La-1-138 | Lb103 |
| GD597 | La-1-148 | Lb135 | GD598 | La-1-148 | Lb165 | GD599 | La-1-148 | Lb110 |
| GD600 | La-1-150 | Lb135 | GD601 | La-1-150 | Lb165 | GD602 | La-1-150 | Lb111 |
| GD603 | La-1-151 | Lb135 | GD604 | La-1-151 | Lb165 | GD605 | La-1-151 | Lb112 |
| GD606 | La-1-157 | Lb135 | GD607 | La-1-157 | Lb165 | GD608 | La-1-157 | Lb113 |
| GD609 | La-1-162 | Lb135 | GD610 | La-1-162 | Lb165 | GD611 | La-1-162 | Lb114 |
| GD612 | La-1-164 | Lb135 | GD613 | La-1-164 | Lb165 | GD614 | La-1-164 | Lb115 |
| GD615 | La-1-169 | Lb135 | GD616 | La-1-169 | Lb165 | GD617 | La-1-169 | Lb116 |
| GD618 | La-1-170 | Lb135 | GD619 | La-1-170 | Lb165 | GD620 | La-1-170 | Lb117 |
| GD621 | La-1-177 | Lb135 | GD622 | La-1-177 | Lb165 | GD623 | La-1-177 | Lb118 |
| GD624 | La-1-178 | Lb135 | GD625 | La-1-178 | Lb165 | GD626 | La-1-178 | Lb119 |
| GD627 | La-1-180 | Lb135 | GD628 | La-1-180 | Lb165 | GD629 | La-1-180 | Lb120 |
| GD630 | La-1-187 | Lb135 | GD631 | La-1-187 | Lb165 | GD632 | La-1-187 | Lb121 |
| GD633 | La-1-189 | Lb135 | GD634 | La-1-189 | Lb165 | GD635 | La-1-189 | Lb122 |
| GD636 | La-1-192 | Lb135 | GD637 | La-1-192 | Lb165 | GD638 | La-1-192 | Lb123 |
| GD639 | La-1-193 | Lb135 | GD640 | La-1-193 | Lb165 | GD641 | La-1-193 | Lb124 |
| GD642 | La-1-194 | Lb135 | GD643 | La-1-194 | Lb165 | GD644 | La-1-194 | Lb125 |
| GD645 | La-1-201 | Lb135 | GD646 | La-1-201 | Lb165 | GD647 | La-1-201 | Lb126 |
| GD648 | La-1-205 | Lb135 | GD649 | La-1-205 | Lb165 | GD650 | La-1-205 | Lb127 |
| GD651 | La-1-206 | Lb135 | GD652 | La-1-206 | Lb165 | GD653 | La-1-206 | Lb128 |
| GD654 | La-1-210 | Lb135 | GD655 | La-1-210 | Lb165 | GD656 | La-1-210 | Lb129 |
| GD657 | La-1-220 | Lb135 | GD658 | La-1-220 | Lb165 | GD659 | La-1-220 | Lb130 |
| GD660 | La-1-230 | Lb135 | GD661 | La-1-230 | Lb165 | GD662 | La-1-230 | Lb131 |
| GD663 | La-1-246 | Lb135 | GD664 | La-1-246 | Lb165 | GD665 | La-1-246 | Lb132 |
| GD666 | La-1-247 | Lb135 | GD667 | La-1-247 | Lb165 | GD668 | La-1-247 | Lb133 |
| GD669 | La-1-251 | Lb135 | GD670 | La-1-251 | Lb165 | GD671 | La-1-251 | Lb134 |
| GD672 | La-1-252 | Lb135 | GD673 | La-1-252 | Lb165 | GD674 | La-1-252 | Lb135 |
| GD675 | La-1-269 | Lb135 | GD676 | La-1-269 | Lb165 | GD677 | La-1-269 | Lb136 |
| GD678 | La-1-277 | Lb135 | GD679 | La-1-277 | Lb165 | GD680 | La-1-277 | Lb142 |
| GD681 | La-1-282 | Lb135 | GD682 | La-1-282 | Lb165 | GD683 | La-1-282 | Lb148 |
| GD684 | La-1-287 | Lb135 | GD685 | La-1-287 | Lb165 | GD686 | La-1-287 | Lb149 |
| GD687 | La-1-300 | Lb135 | GD688 | La-1-300 | Lb165 | GD689 | La-1-300 | Lb150 |
| GD690 | La-2-13 | Lb135 | GD691 | La-2-13 | Lb165 | GD692 | La-2-13 | Lb151 |
| GD693 | La-2-19 | Lb135 | GD694 | La-2-19 | Lb165 | GD695 | La-2-19 | Lb152 |
| GD696 | La-2-23 | Lb135 | GD697 | La-2-23 | Lb165 | GD698 | La-2-23 | Lb153 |
| GD699 | La-2-24 | Lb135 | GD700 | La-2-24 | Lb165 | GD701 | La-2-24 | Lb154 |
| GD702 | La-2-25 | Lb135 | GD703 | La-2-25 | Lb165 | GD704 | La-2-25 | Lb155 |
| GD705 | La-2-28 | Lb135 | GD706 | La-2-28 | Lb165 | GD707 | La-2-28 | Lb156 |
| GD708 | La-2-29 | Lb135 | GD709 | La-2-29 | Lb165 | GD710 | La-2-29 | Lb157 |
| GD711 | La-2-30 | Lb135 | GD712 | La-2-30 | Lb165 | GD713 | La-2-30 | Lb158 |
| GD714 | La-2-31 | Lb135 | GD715 | La-2-31 | Lb165 | GD716 | La-2-31 | Lb159 |
| GD717 | La-2-33 | Lb135 | GD718 | La-2-33 | Lb165 | GD719 | La-2-33 | Lb160 |
| GD720 | La-2-35 | Lb135 | GD721 | La-2-35 | Lb165 | GD722 | La-2-35 | Lb161 |
| GD723 | La-2-37 | Lb135 | GD724 | La-2-37 | Lb165 | GD725 | La-2-37 | Lb162 |
| GD726 | La-2-38 | Lb135 | GD727 | La-2-38 | Lb165 | GD728 | La-2-38 | Lb163 |
| GD729 | La-2-39 | Lb135 | GD730 | La-2-39 | Lb165 | GD731 | La-2-39 | Lb164 |
| GD732 | La-2-40 | Lb135 | GD733 | La-2-40 | Lb165 | GD734 | La-2-40 | Lb165 |
| GD735 | La-2-43 | Lb135 | GD736 | La-2-43 | Lb165 | GD737 | La-2-43 | Lb166 |
| GD738 | La-2-44 | Lb135 | GD739 | La-2-44 | Lb165 | GD740 | La-2-44 | Lb167 |
| GD741 | La-2-45 | Lb135 | GD742 | La-2-45 | Lb165 | GD743 | La-2-45 | Lb168 |
| GD744 | La-2-46 | Lb135 | GD745 | La-2-46 | Lb165 | GD746 | La-2-46 | Lb169 |
| GD747 | La-2-49 | Lb135 | GD748 | La-2-49 | Lb165 | GD749 | La-2-49 | Lb3 |
| GD750 | La-2-50 | Lb135 | GD751 | La-2-50 | Lb165 | GD752 | La-2-50 | Lb3 |
| GD753 | La-2-53 | Lb135 | GD754 | La-2-53 | Lb165 | GD755 | La-2-53 | Lb3 |
| GD756 | La-2-54 | Lb135 | GD757 | La-2-54 | Lb165 | GD758 | La-2-54 | Lb3 |
| GD759 | La-2-55 | Lb135 | GD760 | La-2-55 | Lb165 | GD761 | La-2-55 | Lb3 |
| GD762 | La-2-56 | Lb135 | GD763 | La-2-56 | Lb165 | GD764 | La-2-56 | Lb3 |
| GD765 | La-2-57 | Lb135 | GD766 | La-2-57 | Lb165 | GD767 | La-2-57 | Lb3 |
| GD768 | La-2-58 | Lb135 | GD769 | La-2-58 | Lb165 | GD770 | La-2-58 | Lb151 |
| GD771 | La-2-59 | Lb135 | GD772 | La-2-59 | Lb165 | GD773 | La-2-59 | Lb151 |
| GD774 | La-2-60 | Lb135 | GD775 | La-2-60 | Lb165 | GD776 | La-2-60 | Lb151 |
| GD777 | La-2-61 | Lb135 | GD778 | La-2-61 | Lb165 | GD779 | La-2-61 | Lb151 |
| GD780 | La-2-62 | Lb135 | GD781 | La-2-62 | Lb165 | GD782 | La-2-62 | Lb151 |
| GD783 | La-2-63 | Lb135 | GD784 | La-2-63 | Lb165 | GD785 | La-2-63 | Lb151 |

wherein optionally, hydrogens in the above structures of the metal complex can be partially or fully substituted with deuterium.

13. The organic electroluminescent device according to claim 1, wherein the ring Cy1, the ring Cy2, the ring Cy3, the ring Cy4, the ring Cy5, and the ring Cy6 are, at each occurrence identically or differently, selected from a five-membered unsaturated carbocyclic ring, an aromatic ring having 6 to 18 carbon atoms, or a heteroaromatic ring having 3 to 18 carbon atoms;
preferably, the ring Cy1, the ring Cy2, the ring Cy3, the ring Cy4, the ring Cy5, and the ring Cy6 are, at each occurrence identically or differently, selected from a substituted or unsubstituted pyrrole ring, a furan ring, a thiophene ring, an imidazole ring, a pyrazole ring, a thiazole ring, an oxazole ring, a benzene ring, a pyridine ring, a pyrazine ring, a pyridazine ring, a pyrimidine ring, a triazine ring, a benzimidazole ring, a benzofuran ring, a benzothiophene ring, a benzothiazole ring, a benzoxazole ring, a dibenzofuran ring, a dibenzothiophene ring, a carbazole ring, a pyridoindole ring, a naphthalene ring, a phenanthrene ring, an anthracene ring, an indene ring, a fluorene ring, an indole ring, a benzosilole ring, a dibenzosilole ring, a dibenzoselenophene ring, or a combination thereof;
more preferably, the ring Cy1, the ring Cy2, the ring Cy3, the ring Cy4, the ring Cy5, and the ring Cy6 are, at each occurrence identically or differently, selected from a benzene ring.

14. The organic electroluminescent device according to claim 1, wherein L₁, L₂, L₃, L₄, and L₅ are, at each occurrence identically or differently, selected from a single bond, O, S, Se, BR′, NR′, P═OR′, C═O, CR′R′, or SiR′R′; and the R′ is, at each occurrence identically or differently, selected from the group consisting of: substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted aryl having 6 to 30 carbon atoms, substituted or unsubstituted heteroaryl having 3 to 30 carbon atoms, and combinations thereof;
preferably, L₁, L₂, L₃, L₄, and L₅ are, at each occurrence identically or differently, selected from a single bond, O, S, NR′, or CR′R′; and the R′ is, at each occurrence identically or differently, selected from the group consisting of: substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and combinations thereof;
more preferably, L₁, L₂, L₃, L₄, and L₅ are, at each occurrence identically or differently, selected from a single bond.

15. The organic electroluminescent device according to claim 1, wherein a+b+c+d+e=0, 1, or 2; preferably, a+d+e=1 or 2; more preferably, d+e=1 or 2; still more preferably, a, b, c, and e are all 0, and d=1.

16. The organic electroluminescent device according to claim 1, wherein the fluorescent material has a structure represented by any one of Formula 2-1-1 to Formula 2-1-11: 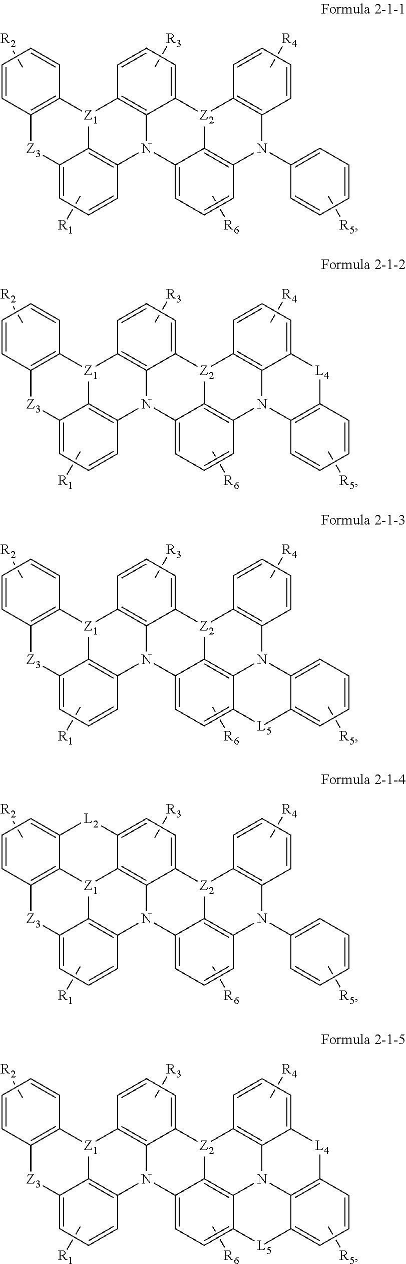 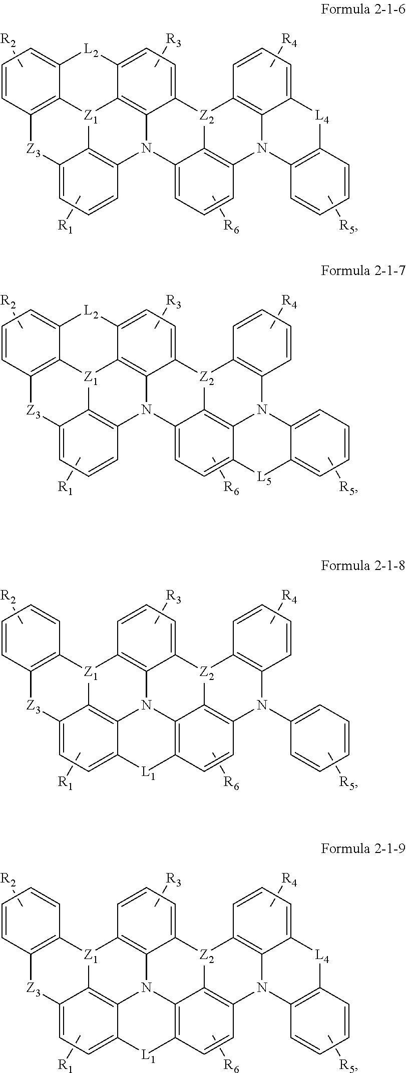 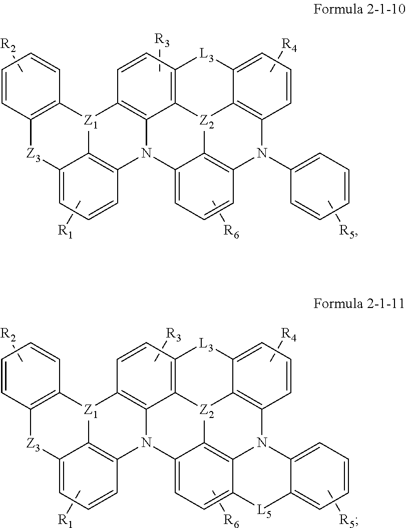
wherein
Z₁ and Z₂ are, at each occurrence identically or differently, selected from B, N, P, P═O, P═S, As, As═O, or As═S;
Z₃ is, at each occurrence identically or differently, selected from O, S, Se, PR, P═OR, CRR, SiRR, GeRR, C═O, C═S, or C═CRR; when multiple R are present, the multiple R are identical or different;
L₁, L₂, L₃, L₄, and L₅ are, at each occurrence identically or differently, selected from a single bond, O, S, Se, BR′, NR′, PR′, P═OR′, P═SR′, AsR′, As═OR′, As═SR′, C═O, CR′R′, SiR′R′, or GeR′R′; when multiple R′ are present, the multiple R′ are identical or different;
R₁, R₂, R₃, R₄, R₅, and R₆ represent, at each occurrence identically or differently, mono-substitution, multiple substitutions, or non-substitution;
R₁, R₂, R₃, R₄, R₅, R₆, R, and R′ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, —BR″R″, and combinations thereof;
R″ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents R₁, R₂, R₃, R₄, R₅, R₆, R, R′, and R″ can be optionally joined to form a ring;
preferably, the fluorescent material has a structure represented by Formula 2-1-2.

17. The organic electroluminescent device according to claim 1, wherein Z₁ and Z₂ are, at each occurrence identically or differently, selected from B, P, P═O, or P═S;
preferably, Z₁ and Z₂ are, at each occurrence identically or differently, selected from B or P═O;
more preferably, Z₁ and Z₂ are, at each occurrence, selected from B.

18. The organic electroluminescent device according to claim 1, wherein Z₃ is, at each occurrence identically or differently, selected from O, S, Se, PR, P═OR, SiRR, C═O, or CRR; when multiple R are present, the multiple R are identical or different; R is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and combinations thereof; and adjacent substituents R can be optionally joined to form a ring;
preferably, Z₃ is, at each occurrence identically or differently, selected from O, Se, SiRR, C═O, or CRR; R is, at each occurrence identically or differently, selected from the group consisting of: substituted or unsubstituted alkyl having 1 to 10 carbon atoms, substituted or unsubstituted cycloalkyl having 3 to 10 ring carbon atoms, substituted or unsubstituted aryl having 6 to 14 carbon atoms, substituted or unsubstituted heteroaryl having 3 to 14 carbon atoms, and combinations thereof; and adjacent substituents R can be optionally joined to form a ring;
more preferably, Z₃ is, at each occurrence identically or differently, selected from O, S, Se, or C═O.

19. The organic electroluminescent device according to claim 1, wherein R₁, R₂, R₃, R₄, R₅, and R₆ are, at each occurrence identically or differently, selected from the group consisting of: hydrogen, deuterium, fluorine, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted alkylgermanyl having 3 to 20 carbon atoms, substituted or unsubstituted amino having 0 to 20 carbon atoms, cyano, isocyano, hydroxyl, sulfanyl, and combinations thereof; and adjacent substituents R₁, R₂, R₃, R₄, R₅, and R₆ can be optionally joined to form a ring;
preferably, R₁, R₂, R₃, R₄, R₅, and R₆ are, at each occurrence identically or differently, selected from the group consisting of: hydrogen, deuterium, fluorine, substituted or unsubstituted alkyl having 1 to 20 carbon atoms, substituted or unsubstituted cycloalkyl having 3 to 20 ring carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted amino having 0 to 20 carbon atoms, cyano, hydroxyl, sulfanyl, and combinations thereof; and adjacent substituents R₁, R₂, R₃, R₄, R₅, and R₆ can be optionally joined to form a ring;
more preferably, at least one R₁, at least one R₂, at least one R₃, at least one R₄, at least one R₅, and/or at least one R₆ are, at each occurrence identically or differently, selected from the group consisting of: deuterium, substituted or unsubstituted alkyl having 1 to 10 carbon atoms, substituted or unsubstituted cycloalkyl having 3 to 10 ring carbon atoms, substituted or unsubstituted alkenyl having 2 to 20 carbon atoms, substituted or unsubstituted aryl having 6 to 14 carbon atoms, substituted or unsubstituted heteroaryl having 3 to 14 carbon atoms, hydroxyl, sulfanyl, and combinations thereof; and adjacent substituents R₁, R₂, R₃, R₄, R₅, and R₆ can be optionally joined to form a ring.

20. The organic electroluminescent device according to claim 1, wherein the fluorescent material is selected from the group consisting of Compound 3-1-k2, Compound 3-2-k2, Compound 3-3-k2, Compound 3-4-k2, Compound 3-5-k2, Compound 3-6-k2, Compound 3-7-k2, Compound 3-8-k2, Compound 3-9-k2, Compound 3-10-k2, Compound 3-11-k2, Compound 3-12-k2, Compound 3-13-k2, Compound 3-14-k2, Compound 4-1-k4, and Compound 5-1-k5, k2 is selected from an integer from 1 to 330, k4 is selected from an integer from 1 to 129, and k5 is selected from an integer from 1 to 400;
Compound 3-1-k2 to Compound 3-14-k2 have the following structures: 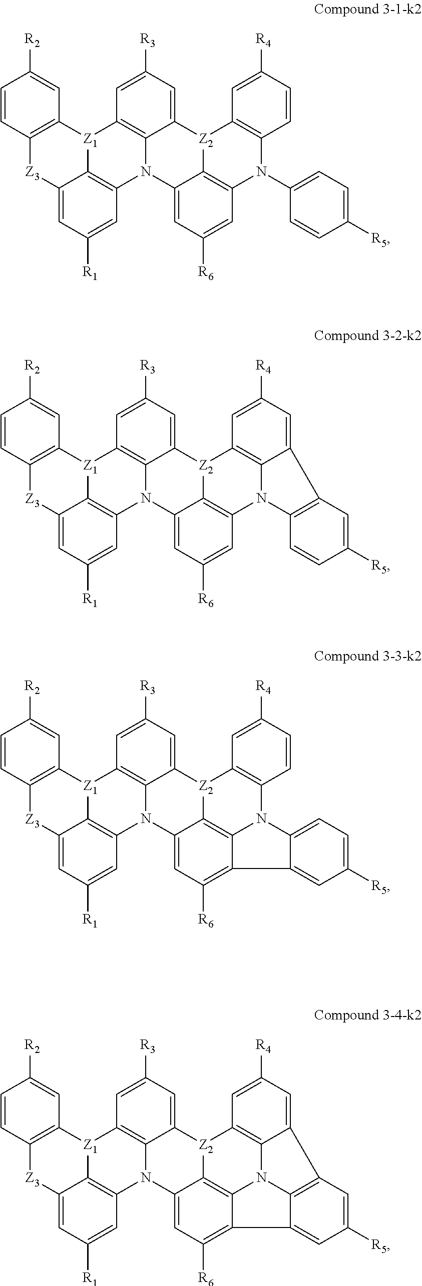 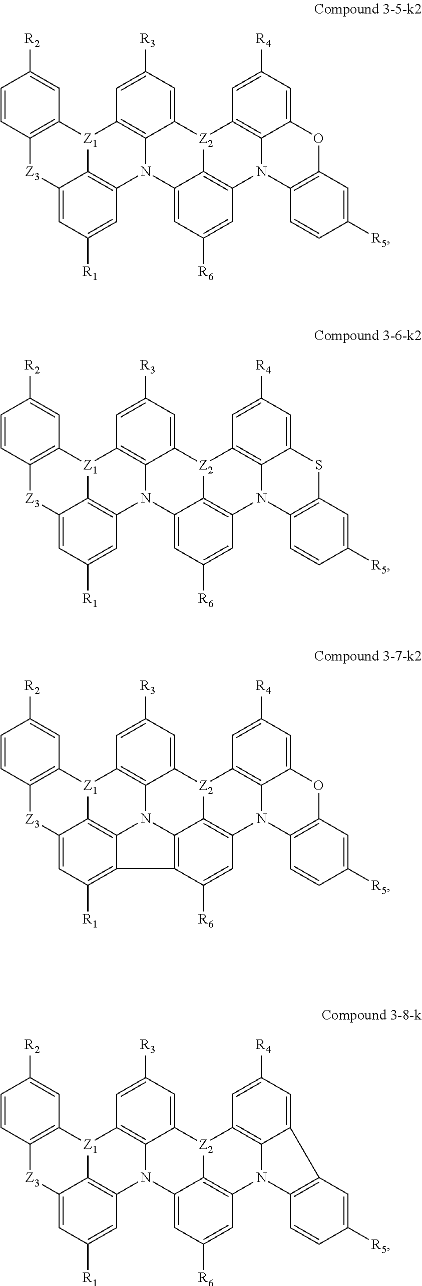 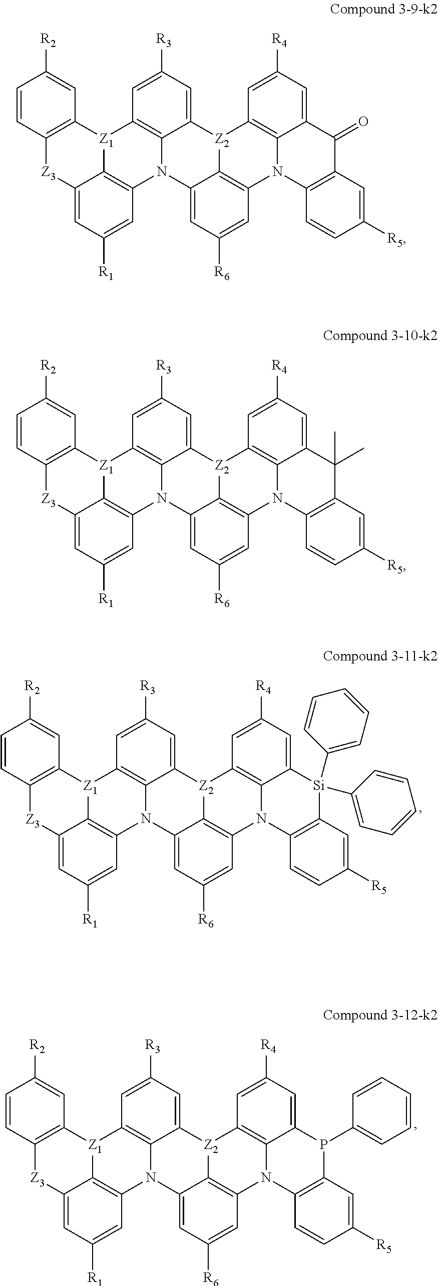 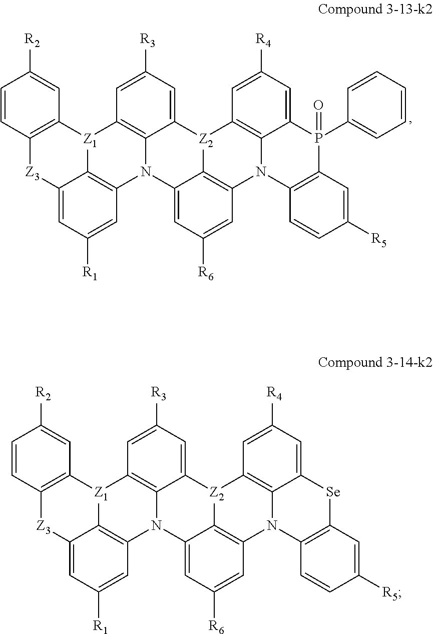
wherein when k2 is selected from an integer from 1 to 330, R₁, R₂, R₃, R₄, R₅, R₆, Z₁, Z₂, and Z₃ are selected from atoms or groups in the following table:

| k2 | R₁ | R₂ | R₃ | R₄ | R₅ | R₆ | Z₁ | Z₂ | Z₃ |
|---|---|---|---|---|---|---|---|---|---|
| 1 | H | H | H | H | H | H | B | B | S |
| 2 | D | D | D | D | D | D | B | B | S |
| 3 | P1 | P1 | P1 | P1 | P1 | P1 | B | B | S |
| 4 | P2 | P2 | P2 | P2 | P2 | P2 | B | B | S |
| 5 | P3 | P3 | P3 | P3 | P3 | P3 | B | B | S |
| 6 | P5 | P5 | P5 | P5 | P5 | P5 | B | B | S |
| 7 | P6 | P6 | P6 | P6 | P6 | P6 | B | B | S |
| 8 | P8 | P8 | P8 | P8 | P8 | P8 | B | B | S |
| 12 | P1 | P1 | H | P1 | P1 | P1 | B | B | S |
| 13 | P2 | P2 | H | P2 | P2 | P2 | B | B | S |
| 14 | P3 | P3 | H | P3 | P3 | P3 | B | B | S |
| 15 | P5 | P5 | H | P5 | P5 | P5 | B | B | S |
| 16 | P6 | P6 | H | P6 | P6 | P6 | B | B | S |
| 17 | P8 | P8 | H | P8 | P8 | P8 | B | B | S |
| 21 | H | H | P17 | H | H | H | B | B | S |
| 22 | P1 | P1 | P17 | P1 | P1 | P1 | B | B | S |
| 23 | P2 | P2 | P17 | P2 | P2 | P2 | B | B | S |
| 24 | P3 | P3 | P17 | P3 | P3 | P3 | B | B | S |
| 25 | P5 | P5 | P17 | P5 | P5 | P5 | B | B | S |
| 26 | P6 | P6 | P17 | P6 | P6 | P6 | B | B | S |
| 27 | P8 | P8 | P17 | P8 | P8 | P8 | B | B | S |
| 31 | P5 | H | P5 | H | H | P5 | B | B | S |
| 32 | P5 | P1 | P5 | P1 | P1 | P5 | B | B | S |
| 33 | P5 | P2 | P5 | P2 | P2 | P5 | B | B | S |
| 34 | P5 | P3 | P5 | P3 | P3 | P5 | B | B | S |
| 35 | P5 | P6 | P5 | P6 | P6 | P5 | B | B | S |
| 36 | P5 | P8 | P5 | P8 | P8 | P5 | B | B | S |
| 40 | P19 | H | P5 | H | H | P19 | B | B | S |
| 41 | P19 | P1 | P5 | P1 | P1 | P19 | B | B | S |
| 42 | P19 | P2 | P5 | P2 | P2 | P19 | B | B | S |
| 43 | P19 | P3 | P5 | P3 | P3 | P19 | B | B | S |
| 44 | P19 | P6 | P5 | P6 | P6 | P19 | B | B | S |
| 45 | P19 | P8 | P5 | P8 | P8 | P19 | B | B | S |
| 58 | H | H | H | H | H | H | B | B | Se |
| 59 | D | D | D | D | D | D | B | B | Se |
| 60 | P1 | P1 | P1 | P1 | P1 | P1 | B | B | Se |
| 61 | P2 | P2 | P2 | P2 | P2 | P2 | B | B | Se |
| 62 | P3 | P3 | P3 | P3 | P3 | P3 | B | B | Se |
| 63 | P5 | P5 | P5 | P5 | P5 | P5 | B | B | Se |
| 64 | P6 | P6 | P6 | P6 | P6 | P6 | B | B | Se |
| 65 | P8 | P8 | P8 | P8 | P8 | P8 | B | B | Se |
| 69 | P1 | P1 | H | P1 | P1 | P1 | B | B | Se |
| 70 | P2 | P2 | H | P2 | P2 | P2 | B | B | Se |
| 71 | P3 | P3 | H | P3 | P3 | P3 | B | B | Se |
| 72 | P5 | P5 | H | P5 | P5 | P5 | B | B | Se |
| 73 | P6 | P6 | H | P6 | P6 | P6 | B | B | Se |
| 74 | P8 | P8 | H | P8 | P8 | P8 | B | B | Se |
| 78 | H | H | P17 | H | H | H | B | B | Se |
| 79 | P1 | P1 | P17 | P1 | P1 | P1 | B | B | Se |
| 80 | P2 | P2 | P17 | P2 | P2 | P2 | B | B | Se |
| 81 | P3 | P3 | P17 | P3 | P3 | P3 | B | B | Se |
| 82 | P5 | P5 | P17 | P5 | P5 | P5 | B | B | Se |
| 83 | P6 | P6 | P17 | P6 | P6 | P6 | B | B | Se |
| 84 | P8 | P8 | P17 | P8 | P8 | P8 | B | B | Se |
| 88 | P5 | H | P5 | H | H | P5 | B | B | Se |
| 89 | P5 | P1 | P5 | P1 | P1 | P5 | B | B | Se |
| 90 | P5 | P2 | P5 | P2 | P2 | P5 | B | B | Se |
| 91 | P5 | P3 | P5 | P3 | P3 | P5 | B | B | Se |
| 92 | P5 | P6 | P5 | P6 | P6 | P5 | B | B | Se |
| 93 | P5 | P8 | P5 | P8 | P8 | P5 | B | B | Se |
| 97 | P19 | H | P5 | H | H | P19 | B | B | Se |
| 98 | P19 | P1 | P5 | P1 | P1 | P19 | B | B | Se |
| 99 | P19 | P2 | P5 | P2 | P2 | P19 | B | B | Se |
| 100 | P19 | P3 | P5 | P3 | P3 | P19 | B | B | Se |
| 101 | P19 | P6 | P5 | P6 | P6 | P19 | B | B | Se |
| 102 | P19 | P8 | P5 | P8 | P8 | P19 | B | B | Se |
| 115 | H | H | H | H | H | H | B | B | C═O |
| 116 | D | D | D | D | D | D | B | B | C═O |
| 117 | P1 | P1 | P1 | P1 | P1 | P1 | B | B | C═O |
| 118 | P2 | P2 | P2 | P2 | P2 | P2 | B | B | C═O |
| 119 | P3 | P3 | P3 | P3 | P3 | P3 | B | B | C═O |
| 120 | P5 | P5 | P5 | P5 | P5 | P5 | B | B | C═O |
| 121 | P6 | P6 | P6 | P6 | P6 | P6 | B | B | C═O |
| 122 | P8 | P8 | P8 | P8 | P8 | P8 | B | B | C═O |
| 123 | P10 | P10 | P10 | P10 | P10 | P10 | B | B | C═O |
| 124 | P12 | P12 | P12 | P12 | P12 | P12 | B | B | C═O |
| 125 | P13 | P13 | P13 | P13 | P13 | P13 | B | B | C═O |
| 126 | P1 | P1 | H | P1 | P1 | P1 | B | B | C═O |
| 127 | P2 | P2 | H | P2 | P2 | P2 | B | B | C═O |
| 128 | P3 | P3 | H | P3 | P3 | P3 | B | B | C═O |
| 129 | P5 | P5 | H | P5 | P5 | P5 | B | B | C═O |
| 130 | P6 | P6 | H | P6 | P6 | P6 | B | B | C═O |
| 131 | P8 | P8 | H | P8 | P8 | P8 | B | B | C═O |
| 132 | P10 | P10 | H | P10 | P10 | P10 | B | B | C═O |
| 133 | P12 | P12 | H | P12 | P12 | P12 | B | B | C═O |
| 134 | P13 | P13 | H | P13 | P13 | P13 | B | B | C═O |
| 135 | H | H | P17 | H | H | H | B | B | C═O |
| 136 | P1 | P1 | P17 | P1 | P1 | P1 | B | B | C═O |
| 137 | P2 | P2 | P17 | P2 | P2 | P2 | B | B | C═O |
| 138 | P3 | P3 | P17 | P3 | P3 | P3 | B | B | C═O |
| 139 | P5 | P5 | P17 | P5 | P5 | P5 | B | B | C═O |
| 140 | P6 | P6 | P17 | P6 | P6 | P6 | B | B | C═O |
| 141 | P8 | P8 | P17 | P8 | P8 | P8 | B | B | C═O |
| 142 | P10 | P10 | P17 | P10 | P10 | P10 | B | B | C═O |
| 143 | P12 | P12 | P17 | P12 | P12 | P12 | B | B | C═O |
| 144 | P13 | P13 | P17 | P13 | P13 | P13 | B | B | C═O |
| 145 | P5 | H | P5 | H | H | P5 | B | B | C═O |
| 146 | P5 | P1 | P5 | P1 | P1 | P5 | B | B | C═O |
| 147 | P5 | P2 | P5 | P2 | P2 | P5 | B | B | C═O |
| 148 | P5 | P3 | P5 | P3 | P3 | P5 | B | B | C═O |
| 149 | P5 | P6 | P5 | P6 | P6 | P5 | B | B | C═O |
| 150 | P5 | P8 | P5 | P8 | P8 | P5 | B | B | C═O |
| 151 | P5 | P10 | P5 | P10 | P10 | P5 | B | B | C═O |
| 152 | P5 | P12 | P5 | P12 | P12 | P5 | B | B | C═O |
| 153 | P5 | P13 | P5 | P13 | P13 | P5 | B | B | C═O |
| 154 | P19 | H | P5 | H | H | P19 | B | B | C═O |
| 155 | P19 | P1 | P5 | P1 | P1 | P19 | B | B | C═O |
| 156 | P19 | P2 | P5 | P2 | P2 | P19 | B | B | C═O |
| 157 | P19 | P3 | P5 | P3 | P3 | P19 | B | B | C═O |
| 158 | P19 | P6 | P5 | P6 | P6 | P19 | B | B | C═O |
| 159 | P19 | P8 | P5 | P8 | P8 | P19 | B | B | C═O |
| 160 | P19 | P10 | P5 | P10 | P10 | P19 | B | B | C═O |
| 161 | P19 | P12 | P5 | P12 | P12 | P19 | B | B | C═O |
| 162 | P19 | P13 | P5 | P13 | P13 | P19 | B | B | C═O |
| 163 | P12 | H | P5 | H | H | P12 | B | B | C═O |
| 164 | P12 | P1 | P5 | P1 | P1 | P12 | B | B | C═O |
| 165 | P12 | P2 | P5 | P2 | P2 | P12 | B | B | C═O |
| 166 | P12 | P3 | P5 | P3 | P3 | P12 | B | B | C═O |
| 167 | P12 | P6 | P5 | P6 | P6 | P12 | B | B | C═O |
| 168 | P12 | P8 | P5 | P8 | P8 | P12 | B | B | C═O |
| 169 | P12 | P10 | P5 | P10 | P10 | P12 | B | B | C═O |
| 170 | P12 | P12 | P5 | P12 | P12 | P12 | B | B | C═O |
| 171 | P12 | P13 | P5 | P13 | P13 | P12 | B | B | C═O |
| 172 | H | H | H | H | H | H | B | B | CMe₂ |
| 173 | P1 | P1 | P1 | P1 | P1 | P1 | B | B | CMe₂ |
| 174 | P5 | P5 | P5 | P5 | P5 | P5 | B | B | CMe₂ |
| 175 | P8 | P8 | P8 | P8 | P8 | P8 | B | B | CMe₂ |
| 176 | P10 | P10 | P10 | P10 | P10 | P10 | B | B | CMe₂ |
| 177 | P2 | P2 | H | P2 | P2 | P2 | B | B | CMe₂ |
| 178 | P3 | P3 | H | P3 | P3 | P3 | B | B | CMe₂ |
| 179 | P5 | P5 | H | P5 | P5 | P5 | B | B | CMe₂ |
| 180 | P6 | P6 | H | P6 | P6 | P6 | B | B | CMe₂ |
| 181 | P10 | P10 | H | P10 | P10 | P10 | B | B | CMe₂ |
| 182 | H | H | P17 | H | H | H | B | B | CMe₂ |
| 183 | P5 | P5 | P17 | P5 | P5 | P5 | B | B | CMe₂ |
| 184 | P5 | H | P5 | H | H | P5 | B | B | CMe₂ |
| 185 | P19 | H | P5 | H | H | P19 | B | B | CMe₂ |
| 186 | P12 | H | P5 | H | H | P12 | B | B | CMe₂ |
| 187 | H | H | H | H | H | H | B | B | SiPh₂ |
| 188 | P1 | P1 | P1 | P1 | P1 | P1 | B | B | SiPh₂ |
| 189 | P5 | P5 | P5 | P5 | P5 | P5 | B | B | SiPh₂ |
| 190 | P8 | P8 | P8 | P8 | P8 | P8 | B | B | SiPh₂ |
| 191 | P10 | P10 | P10 | P10 | P10 | P10 | B | B | SiPh₂ |
| 192 | P2 | P2 | H | P2 | P2 | P2 | B | B | SiPh₂ |
| 193 | P3 | P3 | H | P3 | P3 | P3 | B | B | SiPh₂ |
| 194 | P5 | P5 | H | P5 | P5 | P5 | B | B | SiPh₂ |
| 195 | P6 | P6 | H | P6 | P6 | P6 | B | B | SiPh₂ |
| 196 | P10 | P10 | H | P10 | P10 | P10 | B | B | SiPh₂ |
| 197 | H | H | P17 | H | H | H | B | B | SiPh₂ |
| 198 | P5 | P5 | P17 | P5 | P5 | P5 | B | B | SiPh₂ |
| 199 | P5 | H | P5 | H | H | P5 | B | B | SiPh₂ |
| 200 | P19 | H | P5 | H | H | P19 | B | B | SiPh₂ |
| 201 | P12 | H | P5 | H | H | P12 | B | B | SiPh₂ |
| 202 | H | H | H | H | H | H | B | B | PPh |
| 203 | P1 | P1 | P1 | P1 | P1 | P1 | B | B | PPh |
| 204 | P5 | P5 | P5 | P5 | P5 | P5 | B | B | PPh |
| 205 | P8 | P8 | P8 | P8 | P8 | P8 | B | B | PPh |
| 206 | P10 | P10 | P10 | P10 | P10 | P10 | B | B | PPh |
| 207 | P2 | P2 | H | P2 | P2 | P2 | B | B | PPh |
| 208 | P3 | P3 | H | P3 | P3 | P3 | B | B | PPh |
| 209 | P5 | P5 | H | P5 | P5 | P5 | B | B | PPh |
| 210 | P6 | P6 | H | P6 | P6 | P6 | B | B | PPh |
| 211 | P10 | P10 | H | P10 | P10 | P10 | B | B | PPh |
| 212 | H | H | P17 | H | H | H | B | B | PPh |
| 213 | P5 | P5 | P17 | P5 | P5 | P5 | B | B | PPh |
| 214 | P5 | H | P5 | H | H | P5 | B | B | PPh |
| 215 | P19 | H | P5 | H | H | P19 | B | B | PPh |
| 216 | P12 | H | P5 | H | H | P12 | B | B | PPh |
| 217 | H | H | H | H | H | H | P═O | P═O | S |
| 218 | D | D | D | D | D | D | P═O | P═O | S |
| 219 | P1 | P1 | P1 | P1 | P1 | P1 | P═O | P═O | S |
| 220 | P2 | P2 | P2 | P2 | P2 | P2 | P═O | P═O | S |
| 221 | P3 | P3 | P3 | P3 | P3 | P3 | P═O | P═O | S |
| 222 | P5 | P5 | P5 | P5 | P5 | P5 | P═O | P═O | S |
| 223 | P6 | P6 | P6 | P6 | P6 | P6 | P═O | P═O | S |
| 224 | P8 | P8 | P8 | P8 | P8 | P8 | P═O | P═O | S |
| 225 | P10 | P10 | P10 | P10 | P10 | P10 | P═O | P═O | S |
| 226 | P12 | P12 | P12 | P12 | P12 | P12 | P═O | P═O | S |
| 227 | P13 | P13 | P13 | P13 | P13 | P13 | P═O | P═O | S |
| 228 | P1 | P1 | H | P1 | P1 | P1 | P═O | P═O | S |
| 229 | P2 | P2 | H | P2 | P2 | P2 | P═O | P═O | S |
| 230 | P3 | P3 | H | P3 | P3 | P3 | P═O | P═O | S |
| 231 | P5 | P5 | H | P5 | P5 | P5 | P═O | P═O | S |
| 232 | P6 | P6 | H | P6 | P6 | P6 | P═O | P═O | S |
| 233 | P8 | P8 | H | P8 | P8 | P8 | P═O | P═O | S |
| 234 | P10 | P10 | H | P10 | P10 | P10 | P═O | P═O | S |
| 235 | P12 | P12 | H | P12 | P12 | P12 | P═O | P═O | S |
| 236 | P13 | P13 | H | P13 | P13 | P13 | P═O | P═O | S |
| 237 | H | H | P17 | H | H | H | P═O | P═O | S |
| 238 | P1 | P1 | P17 | P1 | P1 | P1 | P═O | P═O | S |
| 239 | P2 | P2 | P17 | P2 | P2 | P2 | P═O | P═O | S |
| 240 | P3 | P3 | P17 | P3 | P3 | P3 | P═O | P═O | S |
| 241 | P5 | P5 | P17 | P5 | P5 | P5 | P═O | P═O | S |
| 242 | P6 | P6 | P17 | P6 | P6 | P6 | P═O | P═O | S |
| 243 | P8 | P8 | P17 | P8 | P8 | P8 | P═O | P═O | S |
| 244 | P10 | P10 | P17 | P10 | P10 | P10 | P═O | P═O | S |
| 245 | P12 | P12 | P17 | P12 | P12 | P12 | P═O | P═O | S |
| 246 | P13 | P13 | P17 | P13 | P13 | P13 | P═O | P═O | S |
| 247 | P5 | H | P5 | H | H | P5 | P═O | P═O | S |
| 248 | P5 | P1 | P5 | P1 | P1 | P5 | P═O | P═O | S |
| 249 | P5 | P2 | P5 | P2 | P2 | P5 | P═O | P═O | S |
| 250 | P5 | P3 | P5 | P3 | P3 | P5 | P═O | P═O | S |
| 251 | P5 | P6 | P5 | P6 | P6 | P5 | P═O | P═O | S |
| 252 | P5 | P8 | P5 | P8 | P8 | P5 | P═O | P═O | S |
| 253 | P5 | P10 | P5 | P10 | P10 | P5 | P═O | P═O | S |
| 254 | P5 | P12 | P5 | P12 | P12 | P5 | P═O | P═O | S |
| 255 | P5 | P13 | P5 | P13 | P13 | P5 | P═O | P═O | S |
| 256 | P19 | H | P5 | H | H | P19 | P═O | P═O | S |
| 257 | P19 | P1 | P5 | P1 | P1 | P19 | P═O | P═O | S |
| 258 | P19 | P2 | P5 | P2 | P2 | P19 | P═O | P═O | S |
| 259 | P19 | P3 | P5 | P3 | P3 | P19 | P═O | P═O | S |
| 260 | P19 | P6 | P5 | P6 | P6 | P19 | P═O | P═O | S |
| 261 | P19 | P8 | P5 | P8 | P8 | P19 | P═O | P═O | S |
| 262 | P19 | P10 | P5 | P10 | P10 | P19 | P═O | P═O | S |
| 263 | P19 | P12 | P5 | P12 | P12 | P19 | P═O | P═O | S |
| 264 | P19 | P13 | P5 | P13 | P13 | P19 | P═O | P═O | S |
| 265 | P12 | H | P5 | H | H | P12 | P═O | P═O | S |
| 266 | P12 | P1 | P5 | P1 | P1 | P12 | P═O | P═O | S |
| 267 | P12 | P2 | P5 | P2 | P2 | P12 | P═O | P═O | S |
| 268 | P12 | P3 | P5 | P3 | P3 | P12 | P═O | P═O | S |
| 269 | P12 | P6 | P5 | P6 | P6 | P12 | P═O | P═O | S |
| 270 | P12 | P8 | P5 | P8 | P8 | P12 | P═O | P═O | S |
| 271 | P12 | P10 | P5 | P10 | P10 | P12 | P═O | P═O | S |
| 272 | P12 | P12 | P5 | P12 | P12 | P12 | P═O | P═O | S |
| 273 | P12 | P13 | P5 | P13 | P13 | P12 | P═O | P═O | S |
| 274 | H | H | H | H | H | H | P═O | B | S |
| 275 | D | D | D | D | D | D | P═O | B | S |
| 276 | P1 | P1 | P1 | P1 | P1 | P1 | P═O | B | S |
| 277 | P2 | P2 | P2 | P2 | P2 | P2 | P═O | B | S |
| 278 | P3 | P3 | P3 | P3 | P3 | P3 | P═O | B | S |
| 279 | P5 | P5 | P5 | P5 | P5 | P5 | P═O | B | S |
| 280 | P6 | P6 | P6 | P6 | P6 | P6 | P═O | B | S |
| 281 | P8 | P8 | P8 | P8 | P8 | P8 | P═O | B | S |
| 282 | P10 | P10 | P10 | P10 | P10 | P10 | P═O | B | S |
| 283 | P12 | P12 | P12 | P12 | P12 | P12 | P═O | B | S |
| 284 | P13 | P13 | P13 | P13 | P13 | P13 | P═O | B | S |
| 285 | P1 | P1 | H | P1 | P1 | P1 | P═O | B | S |
| 286 | P2 | P2 | H | P2 | P2 | P2 | P═O | B | S |
| 287 | P3 | P3 | H | P3 | P3 | P3 | P═O | B | S |
| 288 | P5 | P5 | H | P5 | P5 | P5 | P═O | B | S |
| 289 | P6 | P6 | H | P6 | P6 | P6 | P═O | B | S |
| 290 | P8 | P8 | H | P8 | P8 | P8 | P═O | B | S |
| 291 | P10 | P10 | H | P10 | P10 | P10 | P═O | B | S |
| 292 | P12 | P12 | H | P12 | P12 | P12 | P═O | B | S |
| 293 | P13 | P13 | H | P13 | P13 | P13 | P═O | B | S |
| 294 | H | H | P17 | H | H | H | B | P═O | S |
| 295 | P1 | P1 | P17 | P1 | P1 | P1 | B | P═O | S |
| 296 | P2 | P2 | P17 | P2 | P2 | P2 | B | P═O | S |
| 297 | P3 | P3 | P17 | P3 | P3 | P3 | B | P═O | S |
| 298 | P5 | P5 | P17 | P5 | P5 | P5 | B | P═O | S |
| 299 | P6 | P6 | P17 | P6 | P6 | P6 | B | P═O | S |
| 300 | P8 | P8 | P17 | P8 | P8 | P8 | B | P═O | S |
| 301 | P10 | P10 | P17 | P10 | P10 | P10 | B | P═O | S |
| 302 | P12 | P12 | P17 | P12 | P12 | P12 | B | P═O | S |
| 303 | P13 | P13 | P17 | P13 | P13 | P13 | B | P═O | S |
| 304 | P5 | H | P5 | H | H | P5 | B | P═O | S |
| 305 | P5 | P1 | P5 | P1 | P1 | P5 | B | P═O | S |
| 306 | P5 | P2 | P5 | P2 | P2 | P5 | B | P═O | S |
| 307 | P5 | P3 | P5 | P3 | P3 | P5 | B | P═O | S |
| 308 | P5 | P6 | P5 | P6 | P6 | P5 | B | P═O | S |
| 309 | P5 | P8 | P5 | P8 | P8 | P5 | B | P═O | S |
| 310 | P5 | P10 | P5 | P10 | P10 | P5 | B | P═O | S |
| 311 | P5 | P12 | P5 | P12 | P12 | P5 | B | P═O | S |
| 312 | P5 | P13 | P5 | P13 | P13 | P5 | B | P═O | S |
| 313 | P19 | H | P5 | H | H | P19 | B | P═O | S |
| 314 | P19 | P1 | P5 | P1 | P1 | P19 | P═O | P═O | Se |
| 315 | P19 | P2 | P5 | P2 | P2 | P19 | P═O | P═O | Se |
| 316 | P19 | P3 | P5 | P3 | P3 | P19 | P═O | P═O | Se |
| 317 | P19 | P6 | P5 | P6 | P6 | P19 | P═O | P═O | Se |
| 318 | P19 | P8 | P5 | P8 | P8 | P19 | P═O | P═O | Se |
| 319 | P19 | P10 | P5 | P10 | P10 | P19 | P═O | P═O | Se |
| 320 | P19 | P12 | P5 | P12 | P12 | P19 | P═O | P═O | Se |
| 321 | P19 | P13 | P5 | P13 | P13 | P19 | P═O | P═O | Se |
| 322 | P12 | H | P5 | H | H | P12 | P═O | P═O | Se |
| 323 | P12 | P1 | P5 | P1 | P1 | P12 | P═O | P═O | Se |
| 324 | P12 | P2 | P5 | P2 | P2 | P12 | P═O | P═O | Se |
| 325 | P12 | P3 | P5 | P3 | P3 | P12 | P═O | P═O | Se |
| 326 | P12 | P6 | P5 | P6 | P6 | P12 | P═O | P═O | Se |
| 327 | P12 | P8 | P5 | P8 | P8 | P12 | P═O | P═O | Se |
| 328 | P12 | P10 | P5 | P10 | P10 | P12 | P═O | P═O | Se |
| 329 | P12 | P12 | P5 | P12 | P12 | P12 | P═O | P═O | Se |
| 330 | P12 | P13 | P5 | P13 | P13 | P12 | P═O | P═O | Se |

wherein Ph represents phenyl, Me represents methyl, and P1 to P19 have the following structures: 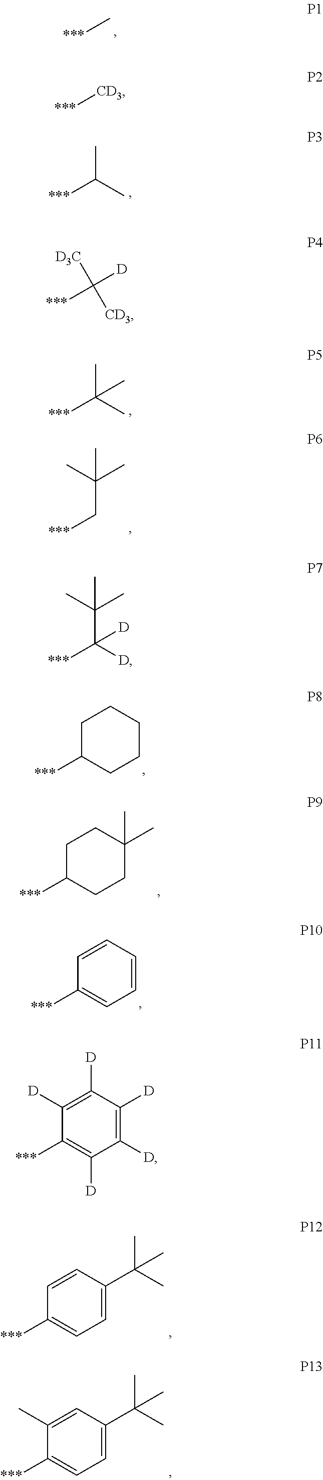 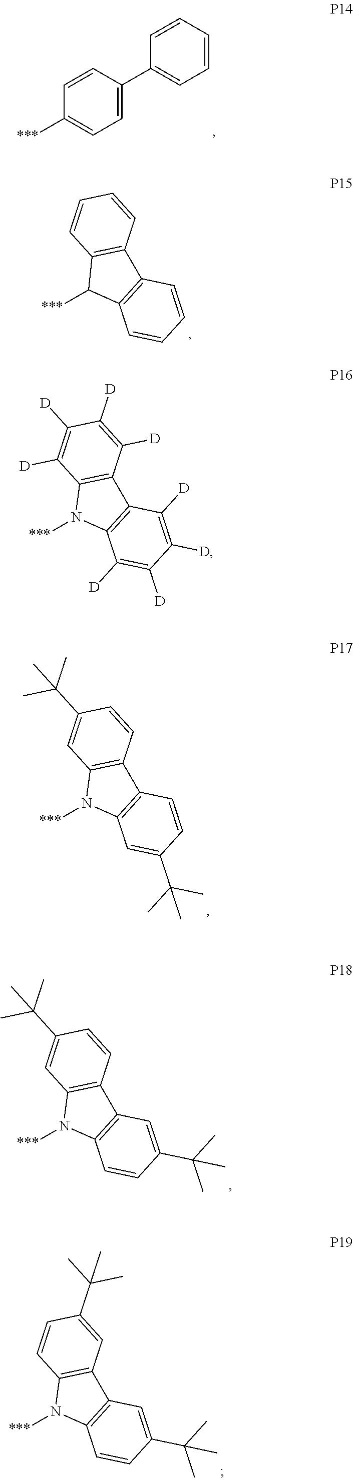
wherein “***” represents a position where P1 to P19 are each joined to Compound 3-1-k2 to Compound 3-14-k2;
Compound 4-1-1 to Compound 4-1-129 have the following structures: 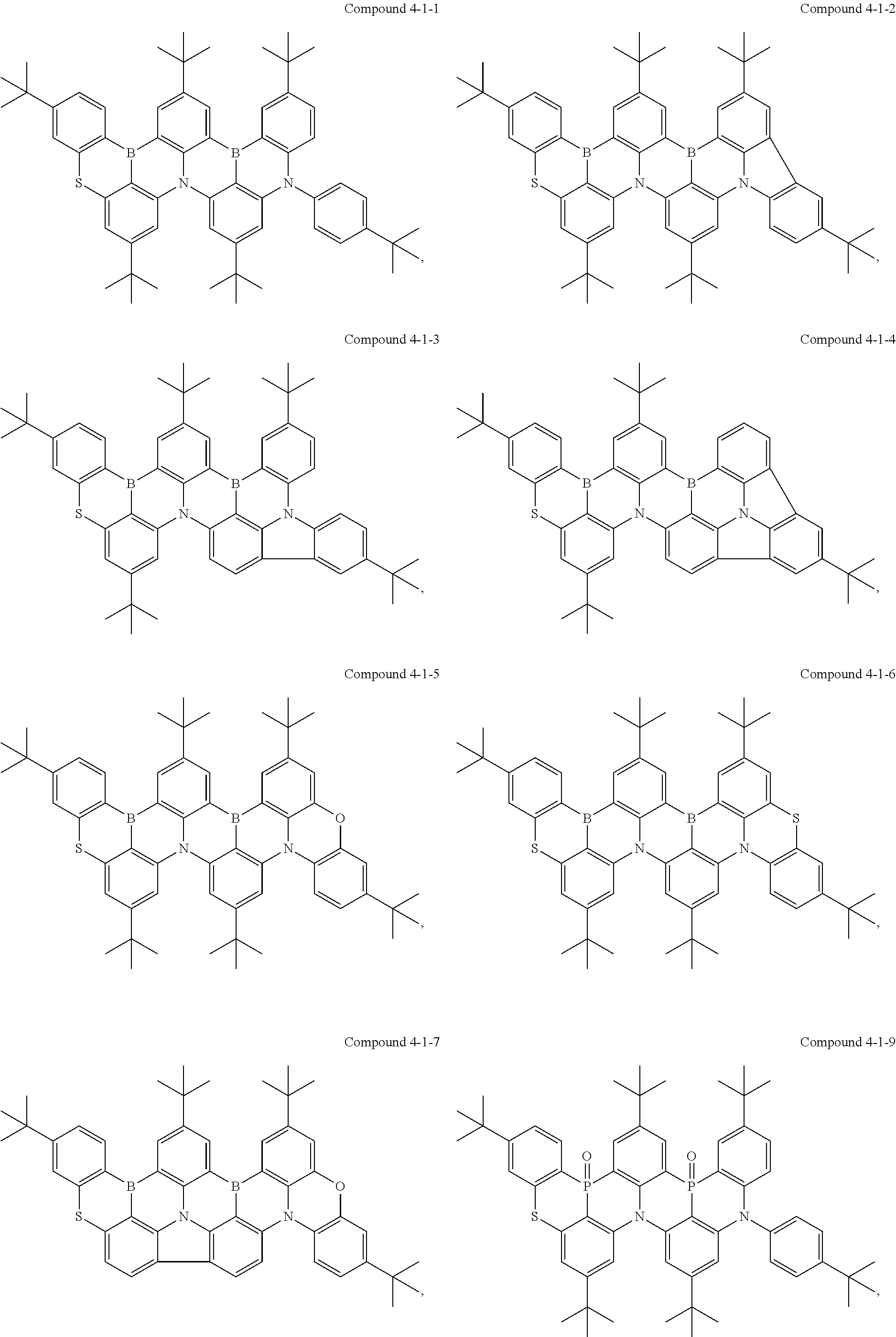 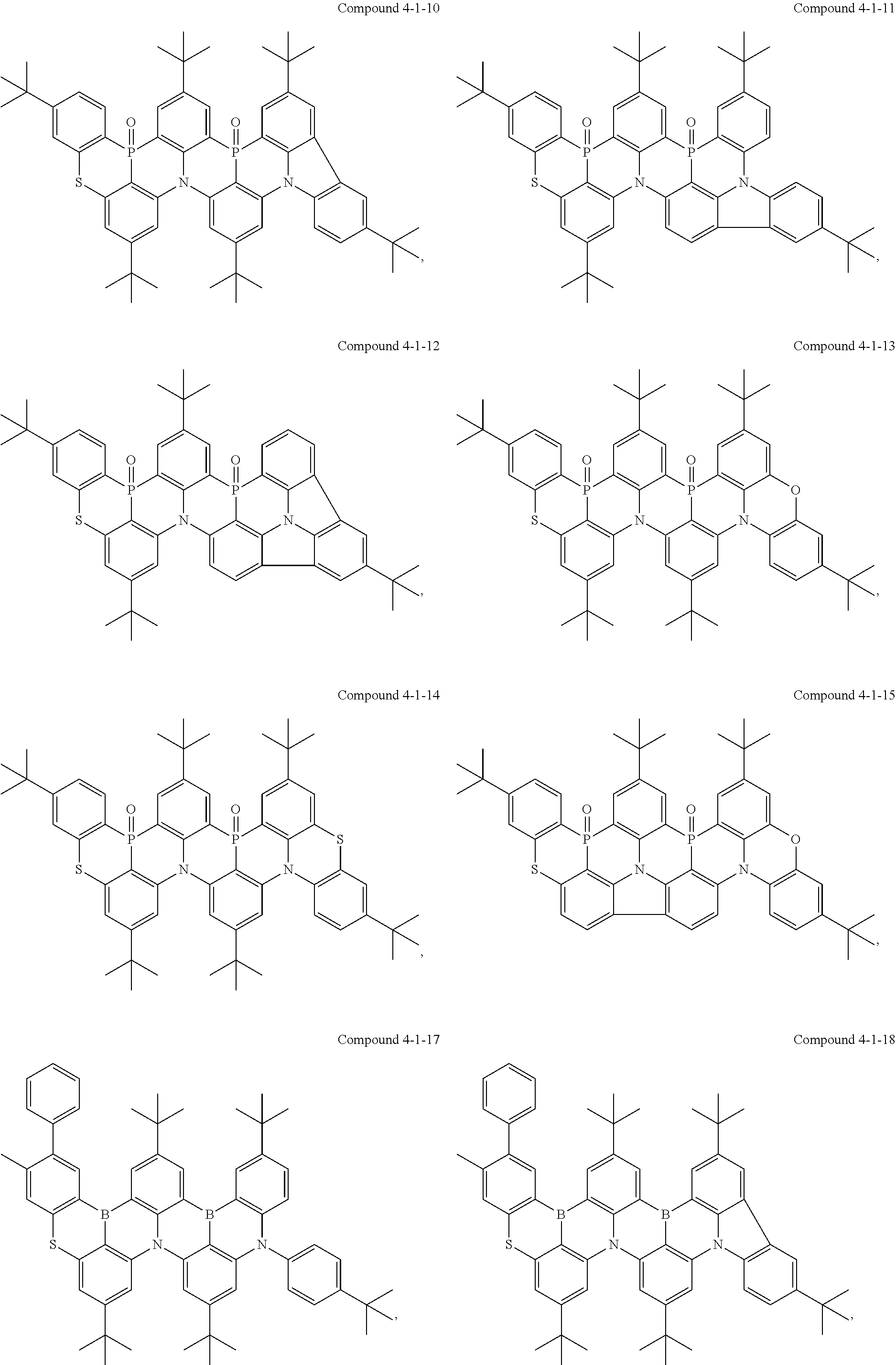 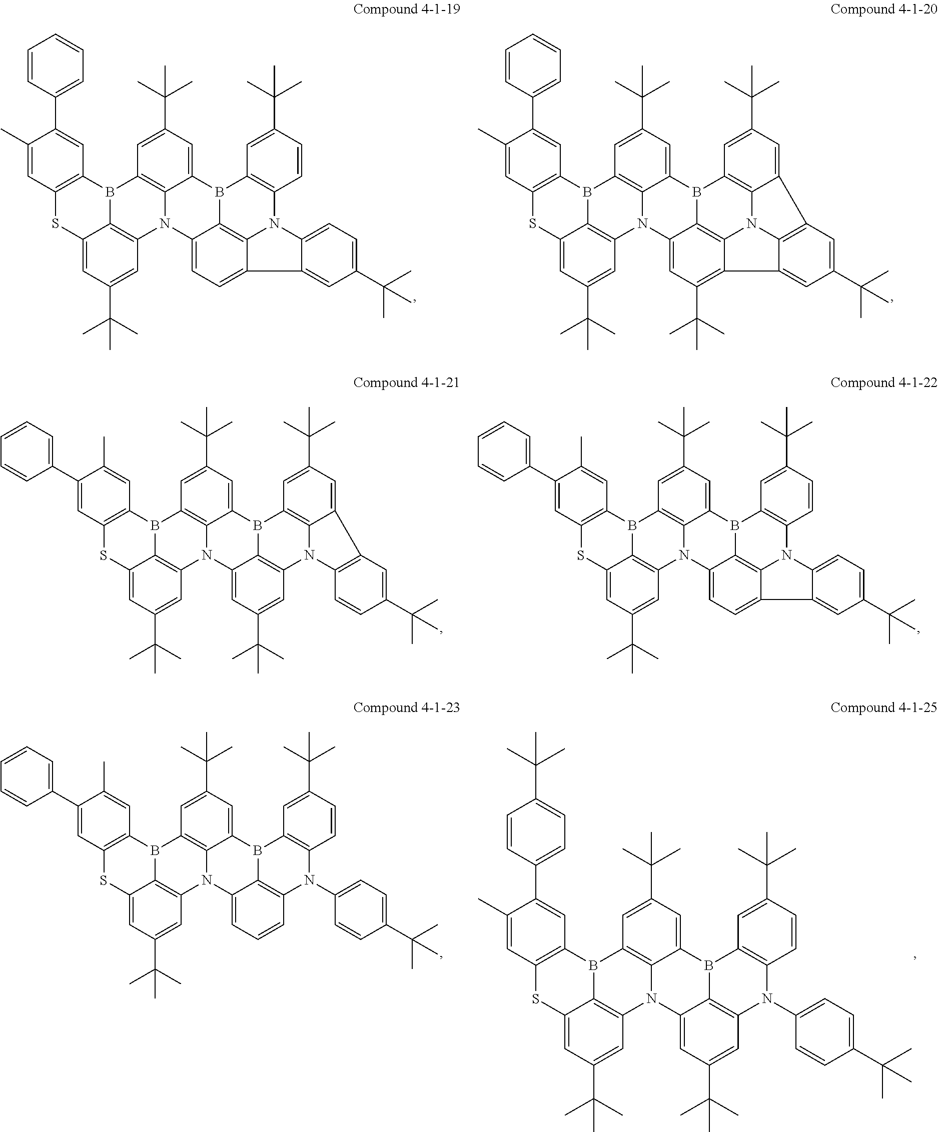 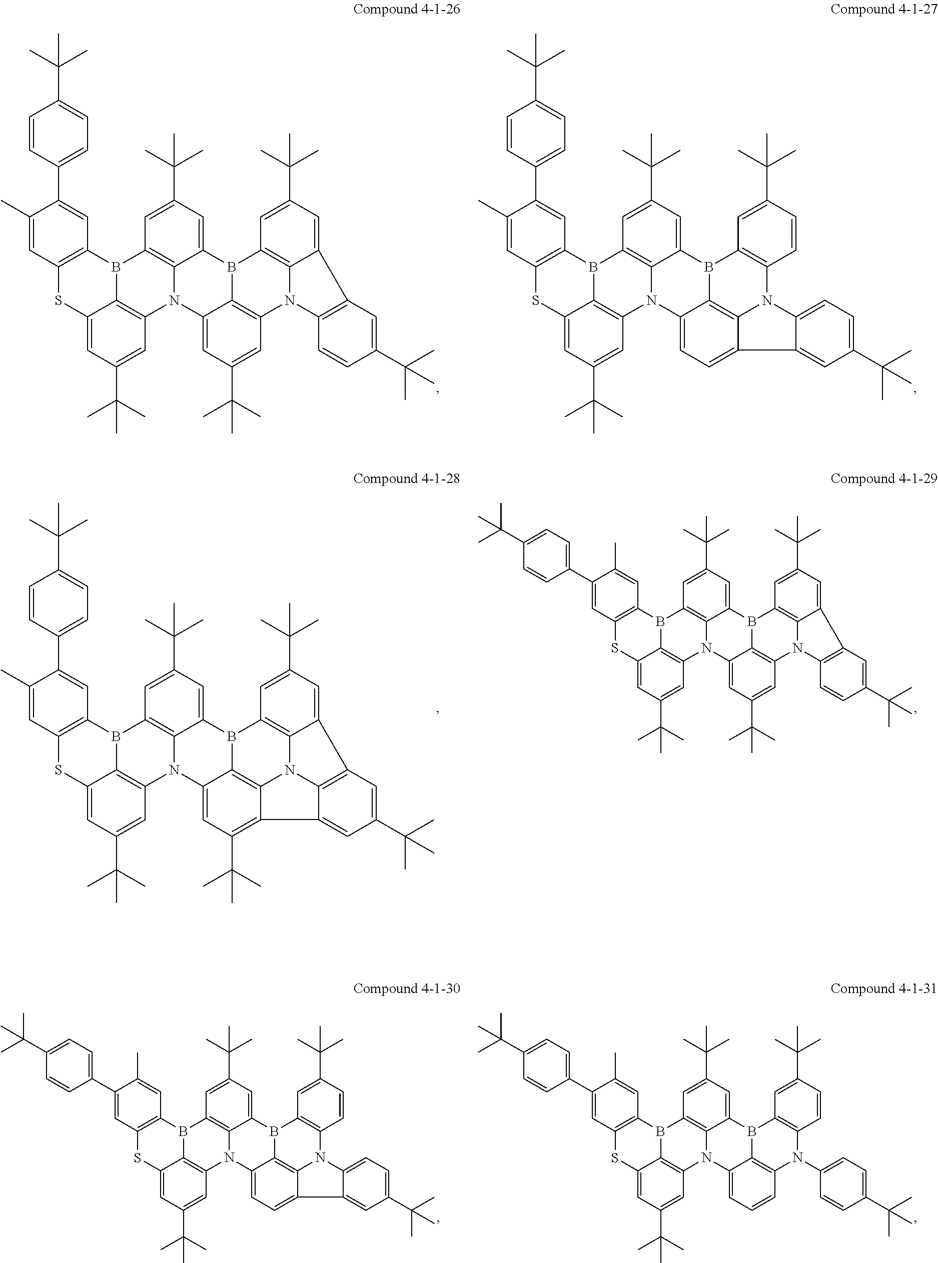 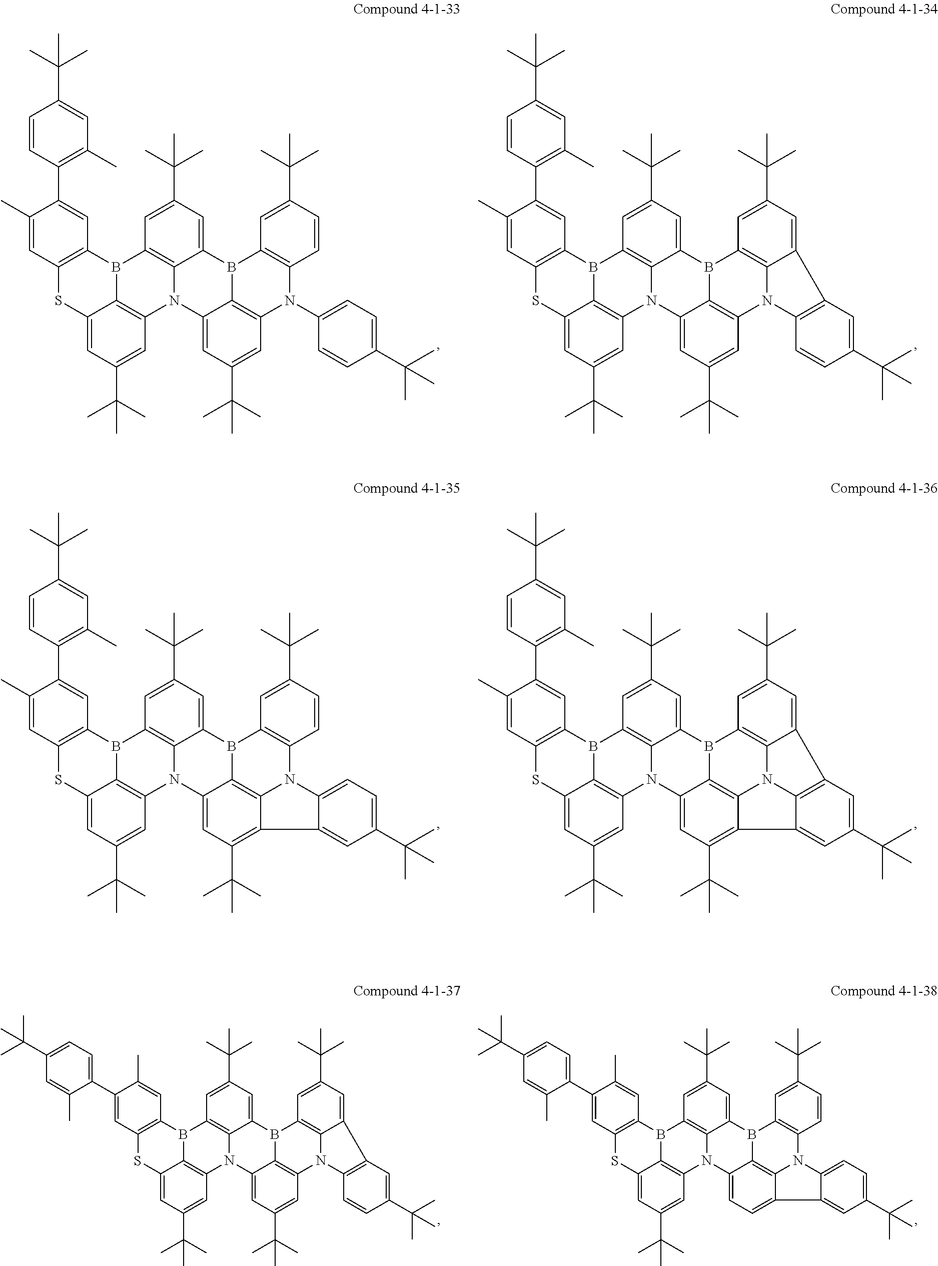 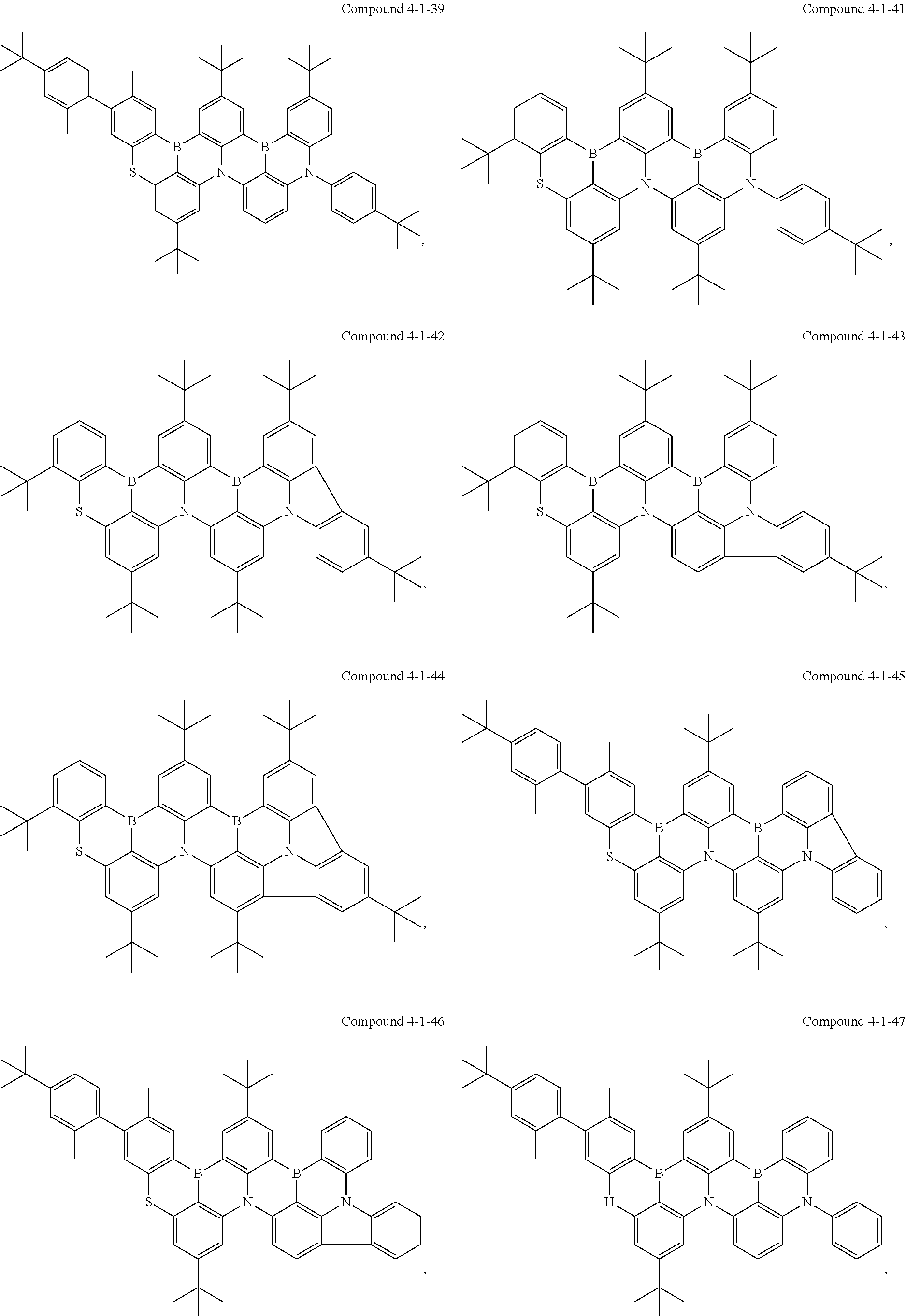 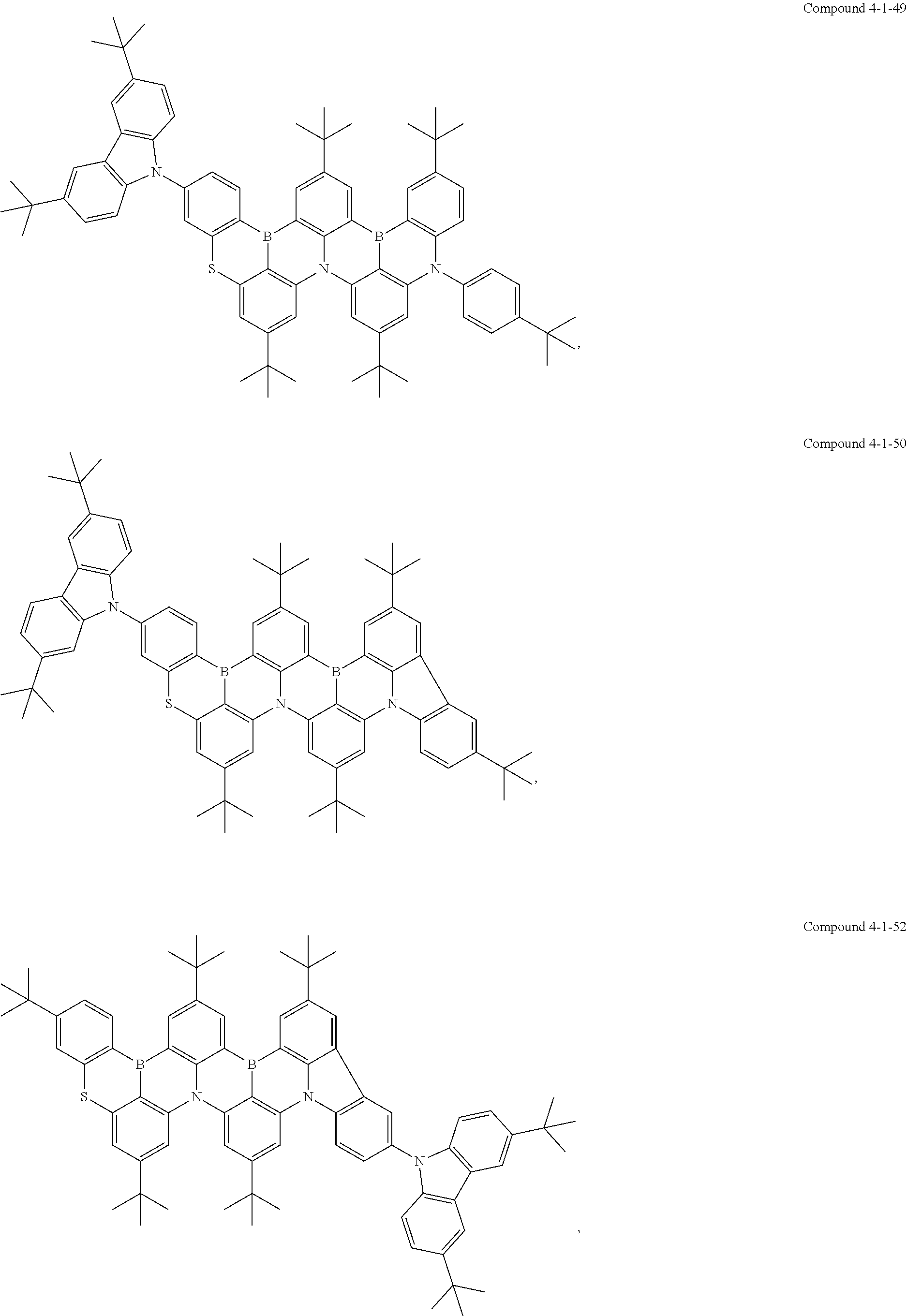 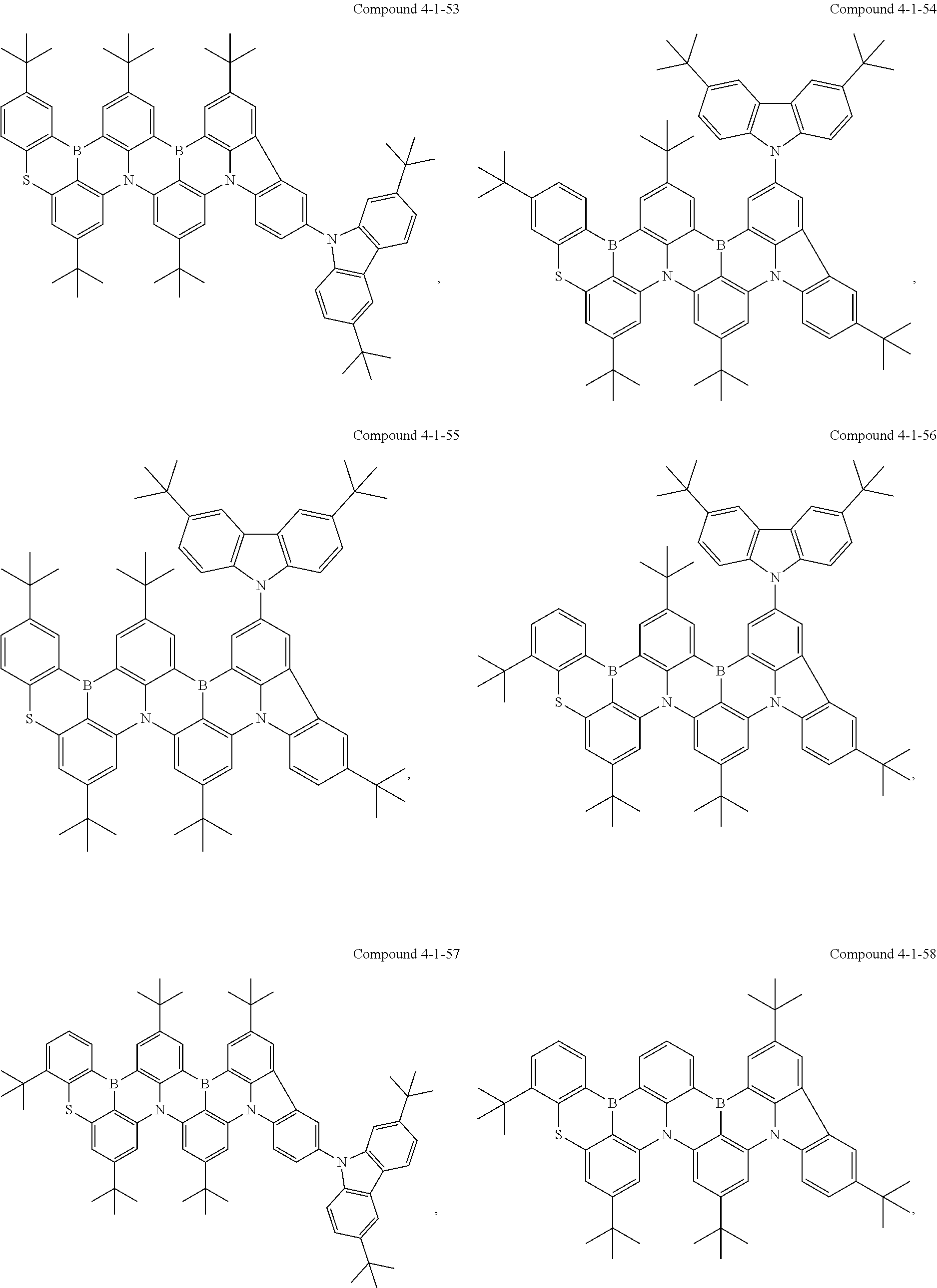 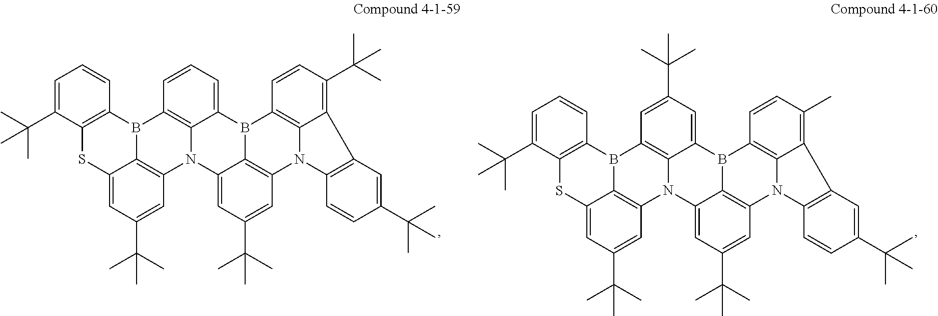 [SMILES: CC(C)(C)c1cc2c3c(c1)N1c4cc(C(C)(C)C)cc5c4B(c4cccc(c41)B3c1cccc(C(C)(C)C)c1S2)c1ccc(C(C)(C)C)c2c3cc(C(C)(C)C)ccc3n-5c12 ; Cc1ccc2c3c1c1cc(C(C)(C)C)ccc1n3-c1cc(C(C)(C)C)cc3c1B2c1cc(C(C)(C)C)cc2c1N3c1cc(C(C)(C)C)cc3c1B2c1cccc(C(C)(C)C)c1S3] 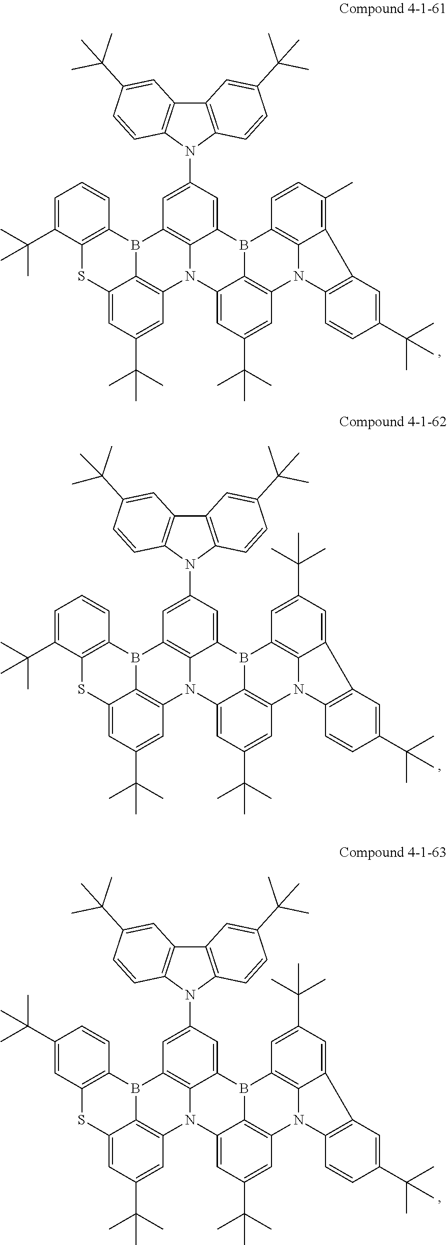 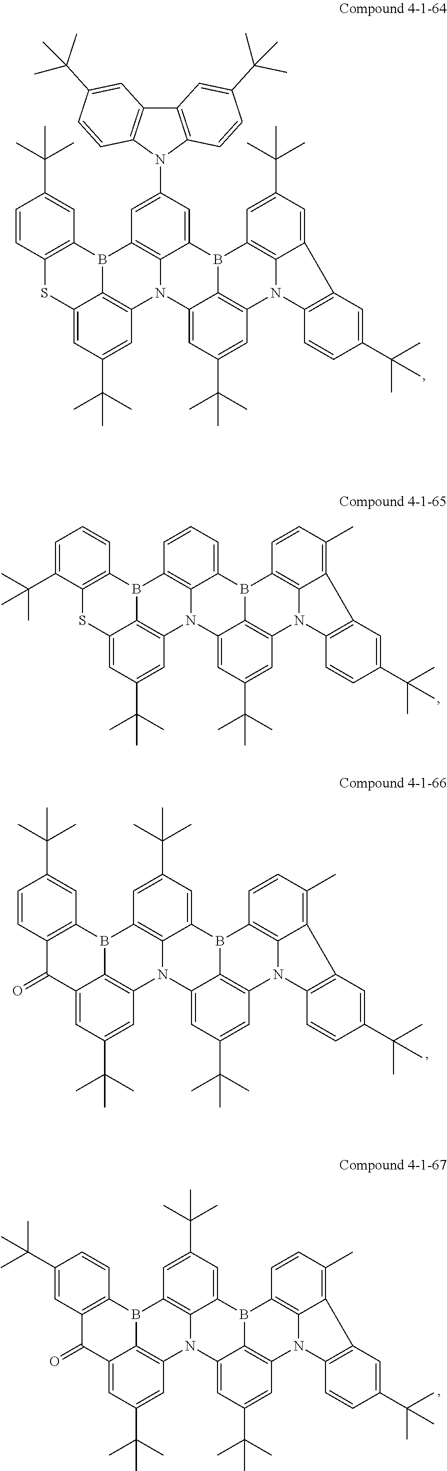 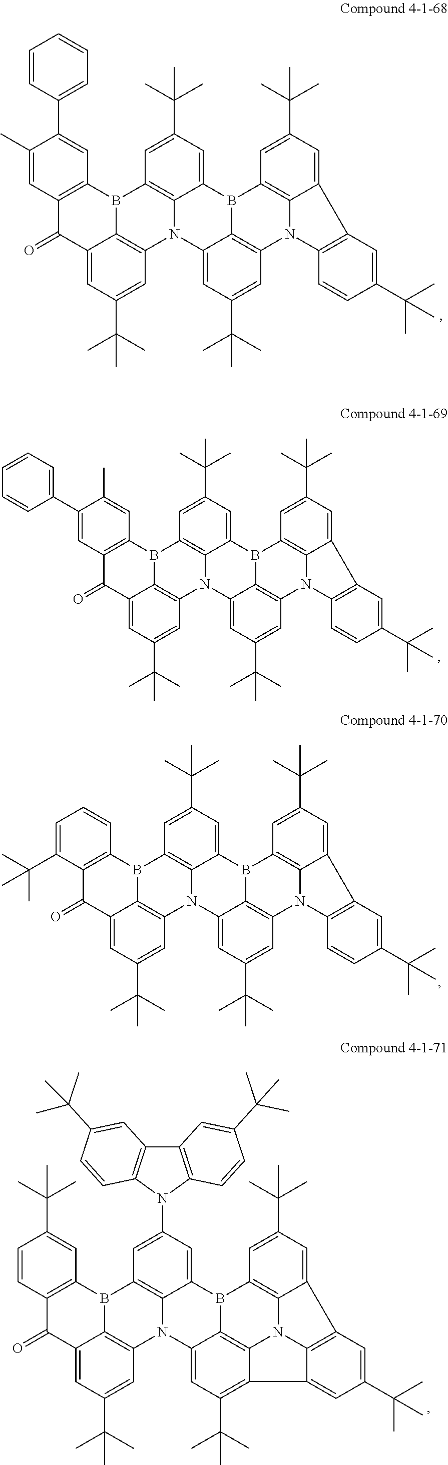 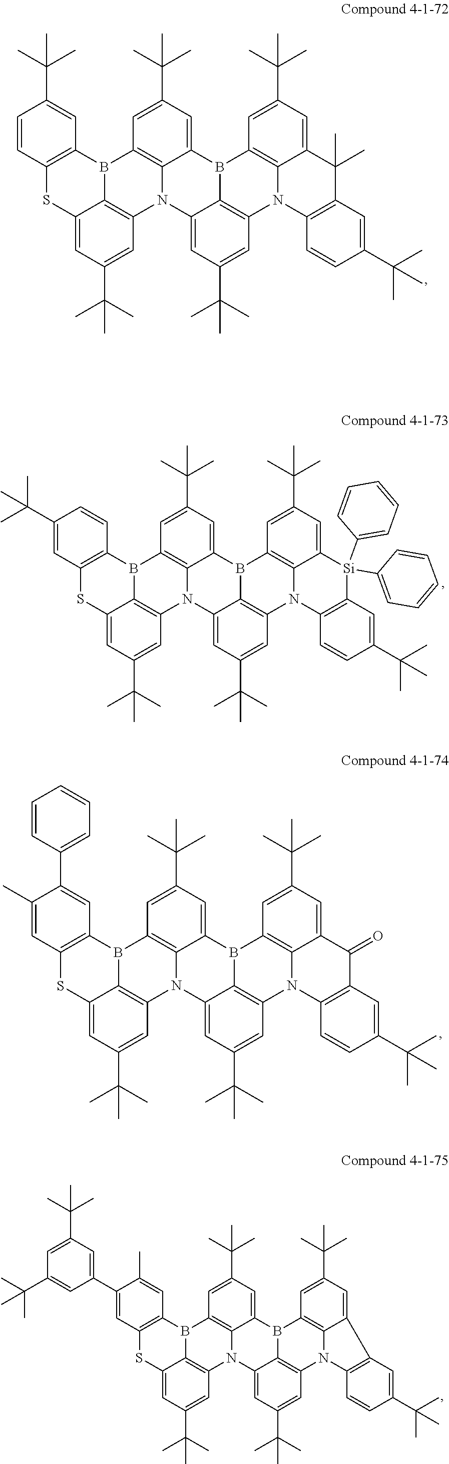 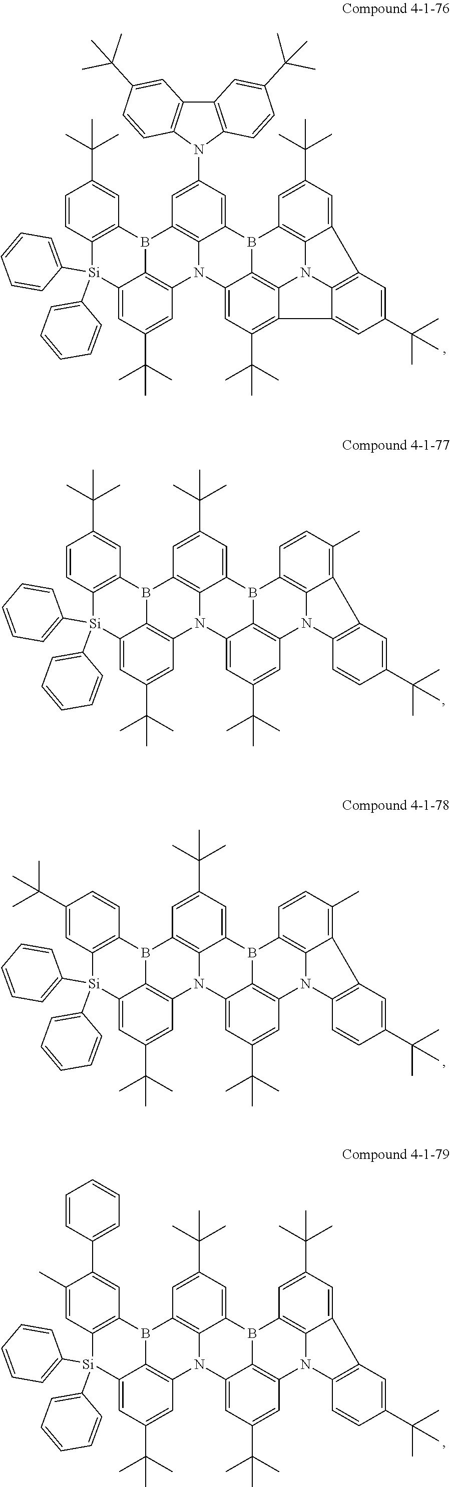 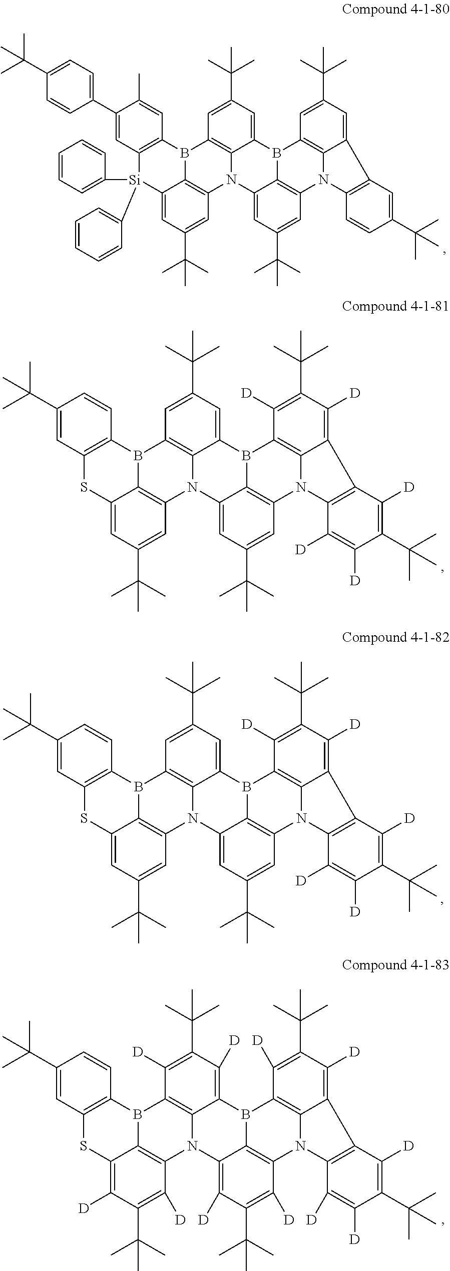 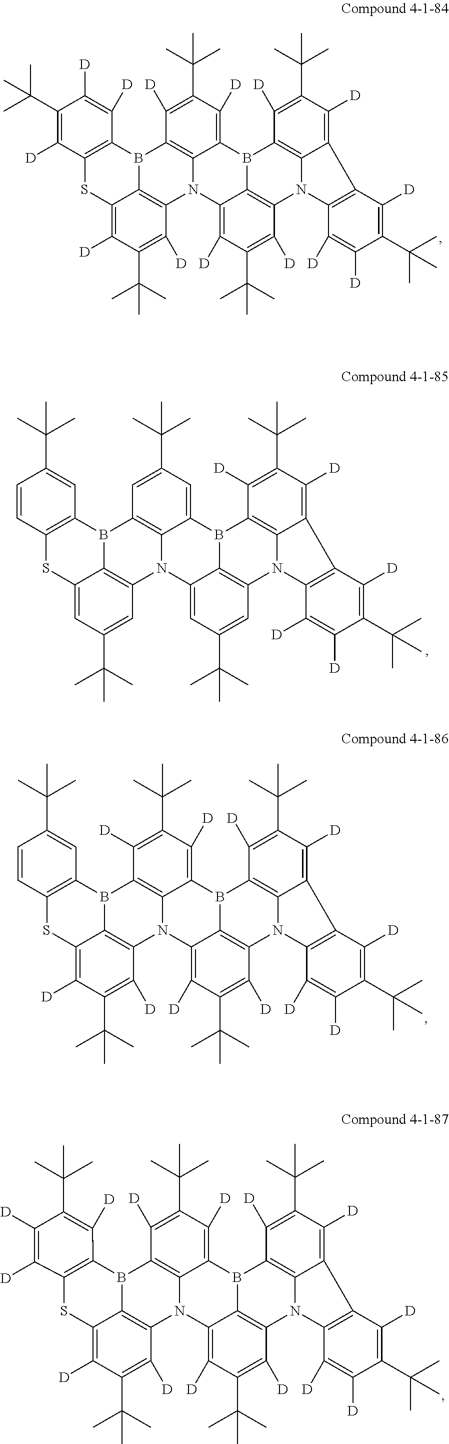 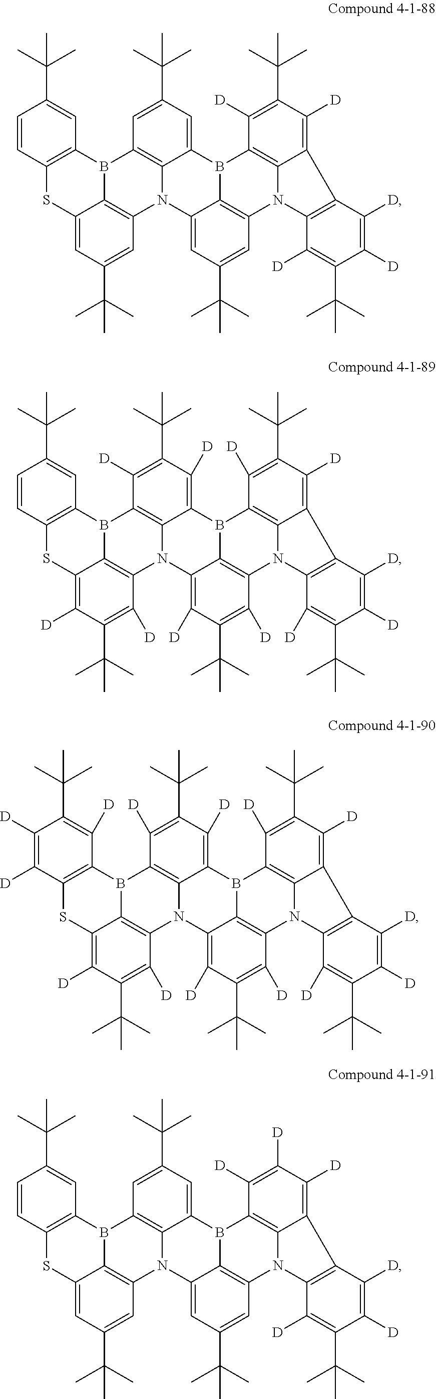 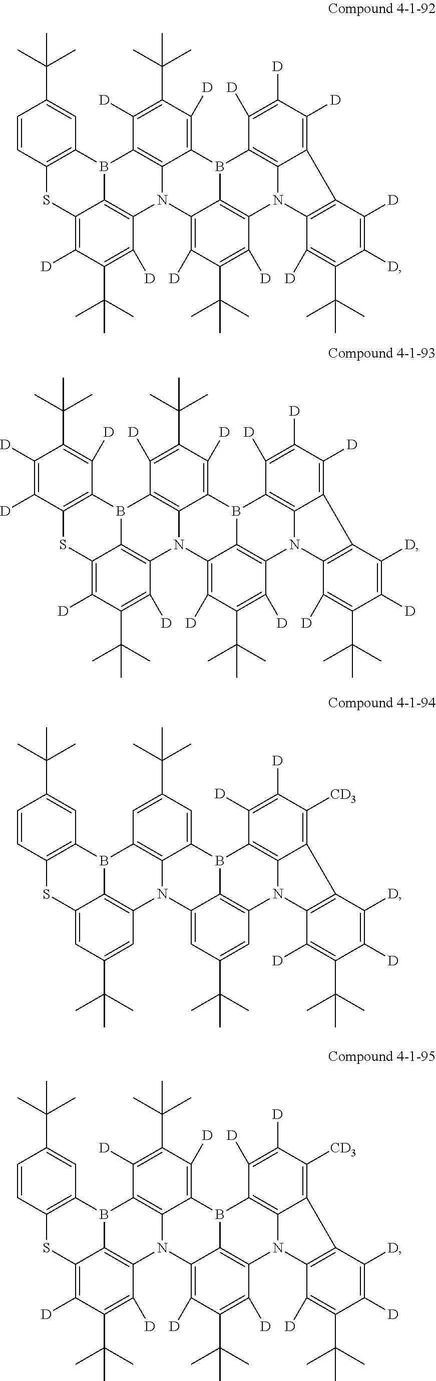 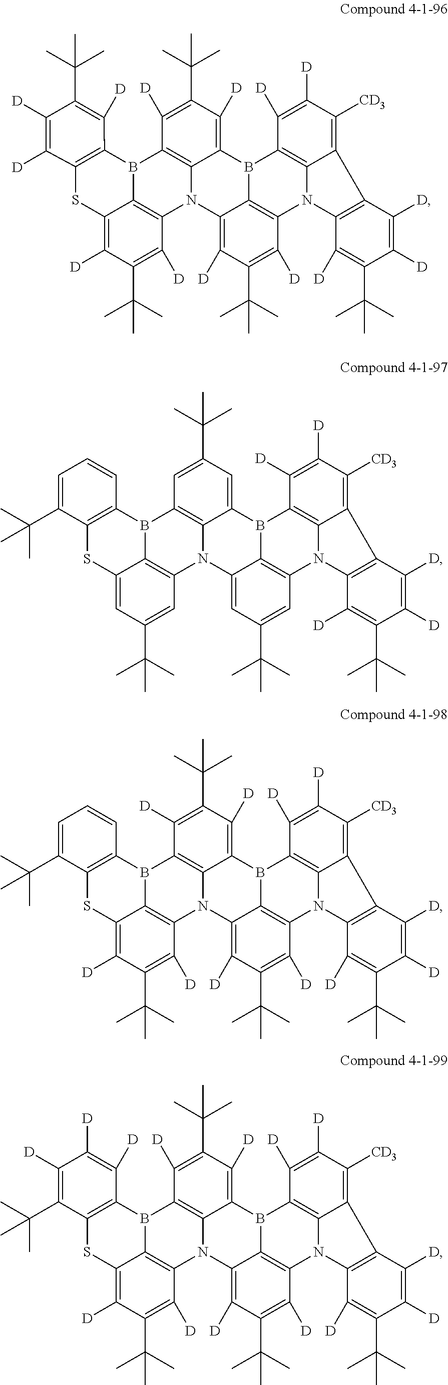 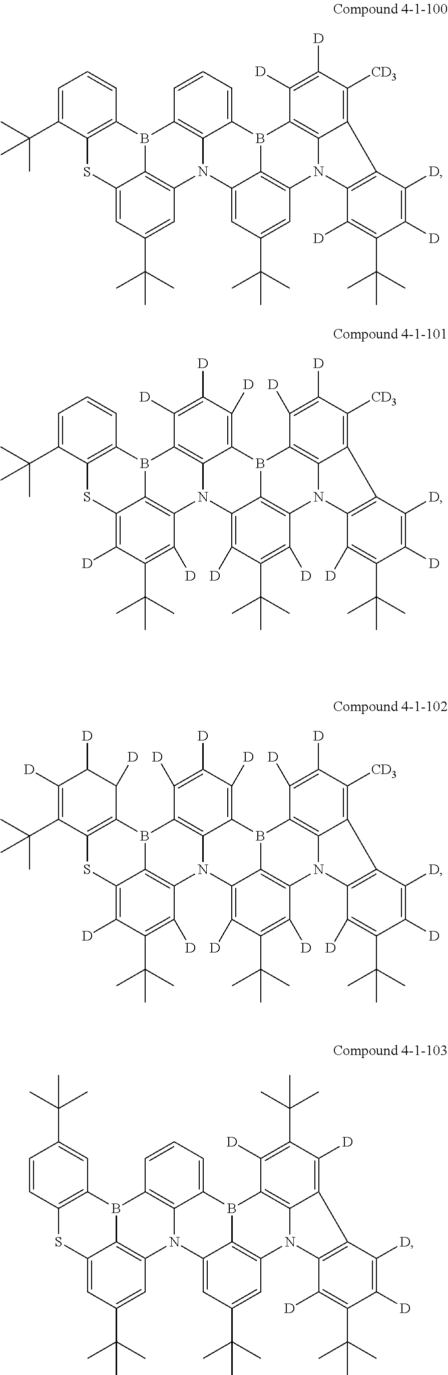 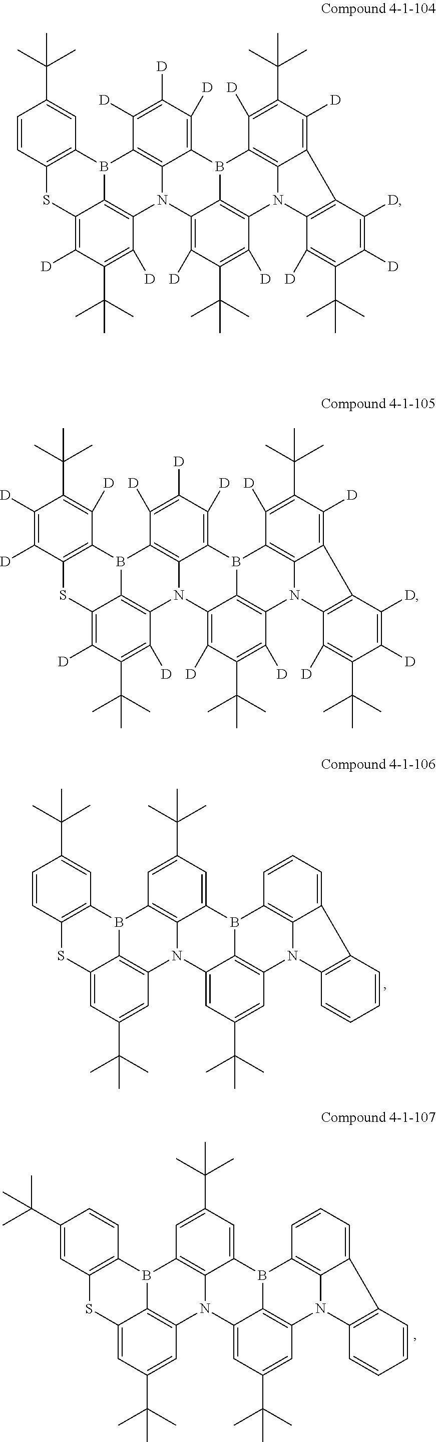 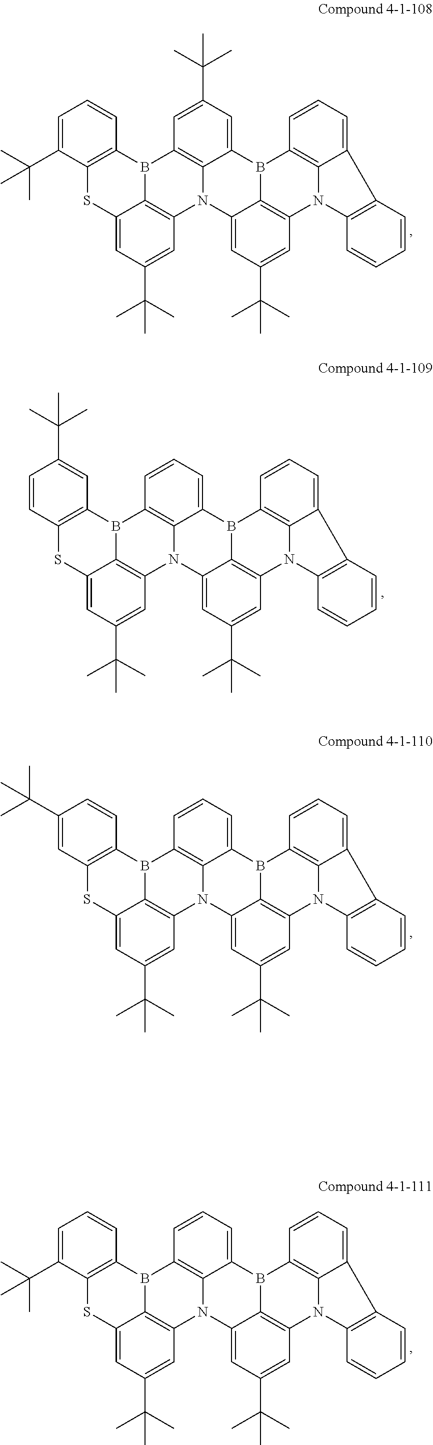 [SMILES: CC(C)(C)c1cc2c3c(c1)B1c4c(cc(C(C)(C)C)cc4-n4c5ccccc5c5cccc1c54)N3c1cc(C(C)(C)C)cc3c1B2c1cccc(C(C)(C)C)c1S3 ; CC(C)(C)c1ccc2c(c1)B1c3cccc4c3N(c3cc(C(C)(C)C)cc(c31)S2)c1cc(C(C)(C)C)cc2c1B4c1cccc3c4ccccc4n-2c13 ; CC(C)(C)c1ccc2c(c1)Sc1cc(C(C)(C)C)cc3c1B2c1cccc2c1N3c1cc(C(C)(C)C)cc3c1B2c1cccc2c4ccccc4n-3c12 ; CC(C)(C)c1cc2c3c(c1)N1c4cc(C(C)(C)C)cc5c4B(c4cccc(c41)B3c1cccc(C(C)(C)C)c1S2)c1cccc2c3ccccc3n-5c12] 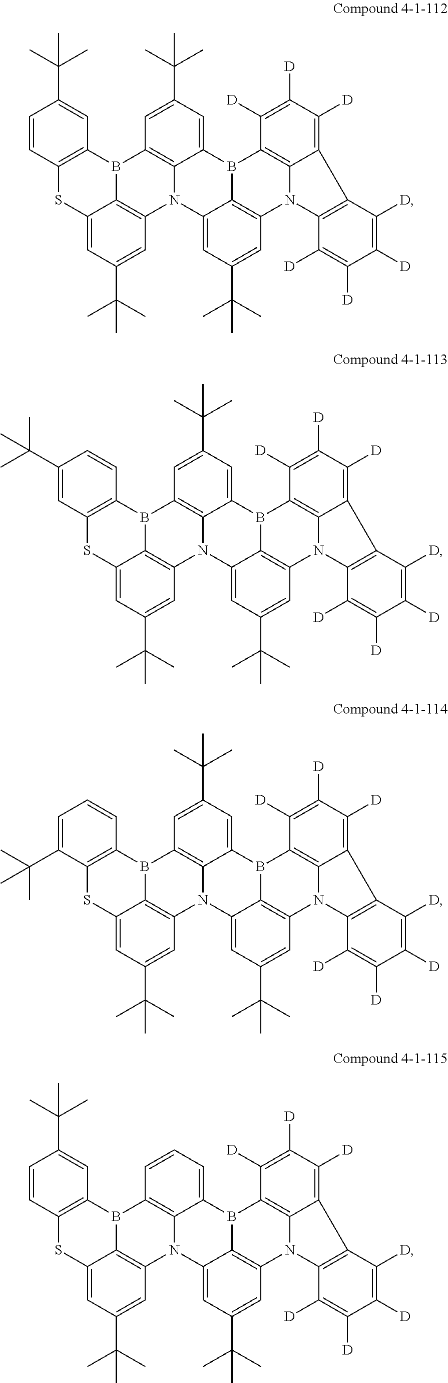 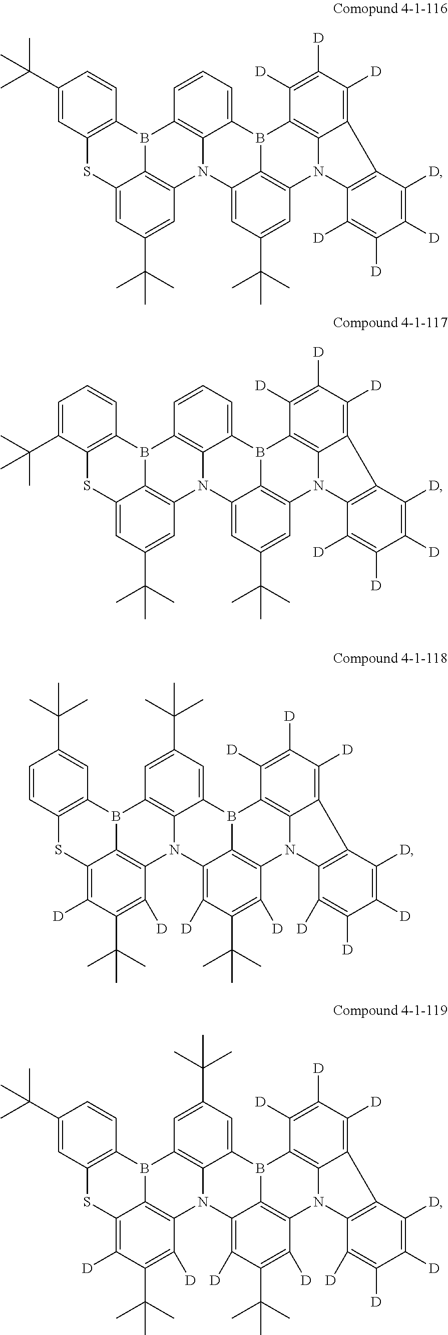 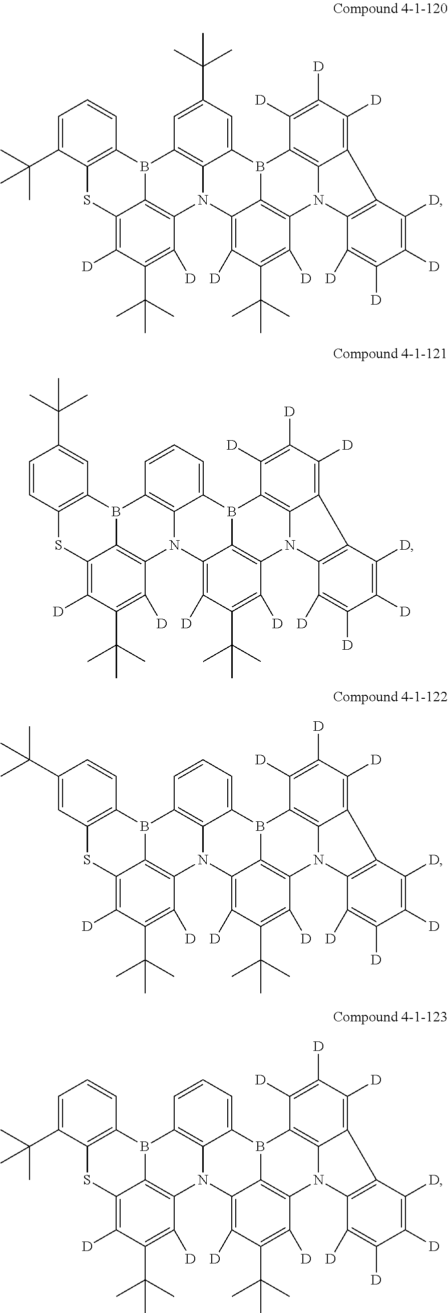 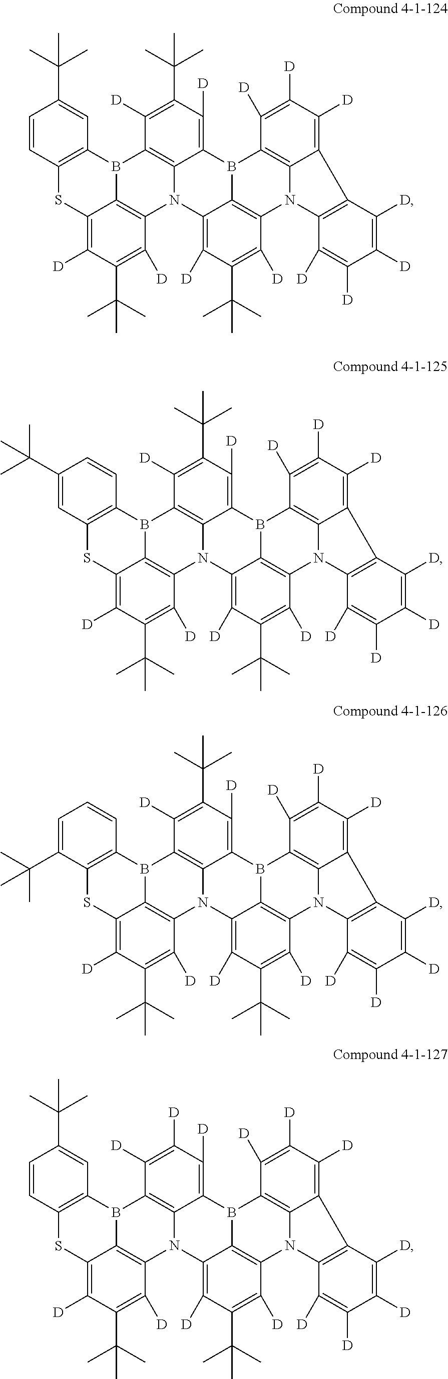 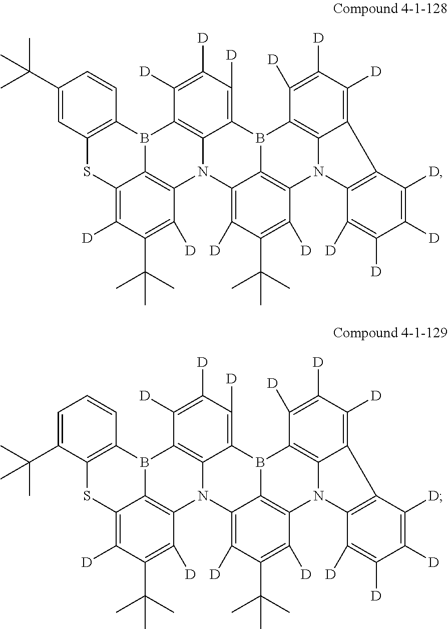
and
Compound 5-1-1 to Compound 5-1-400 have the following structures: 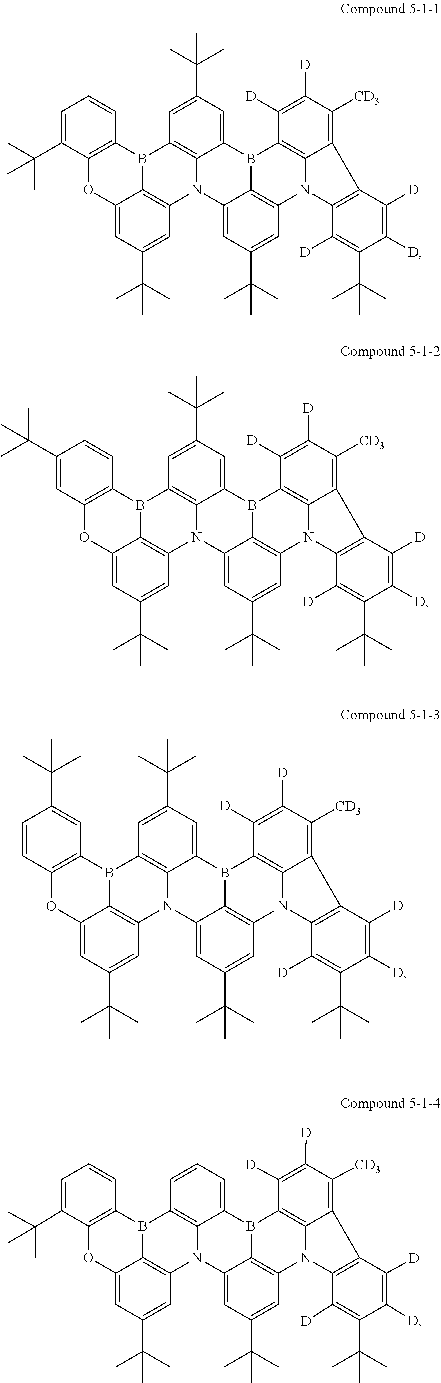 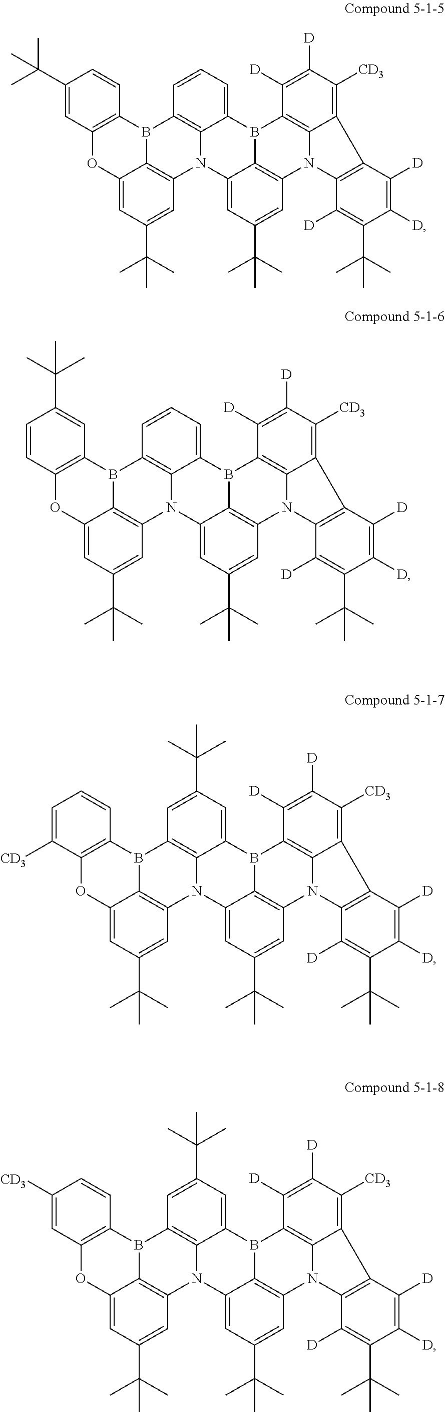 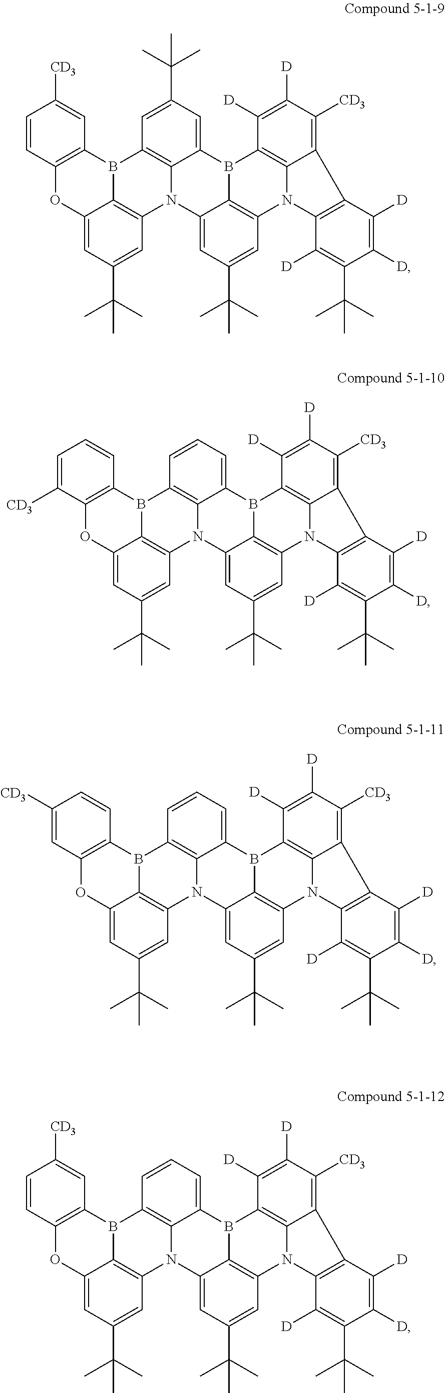 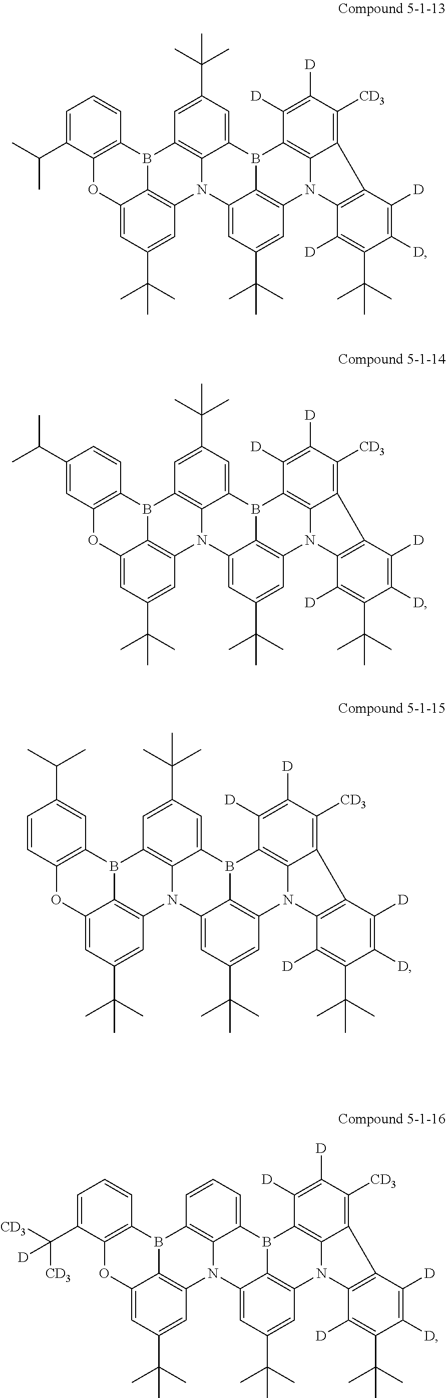 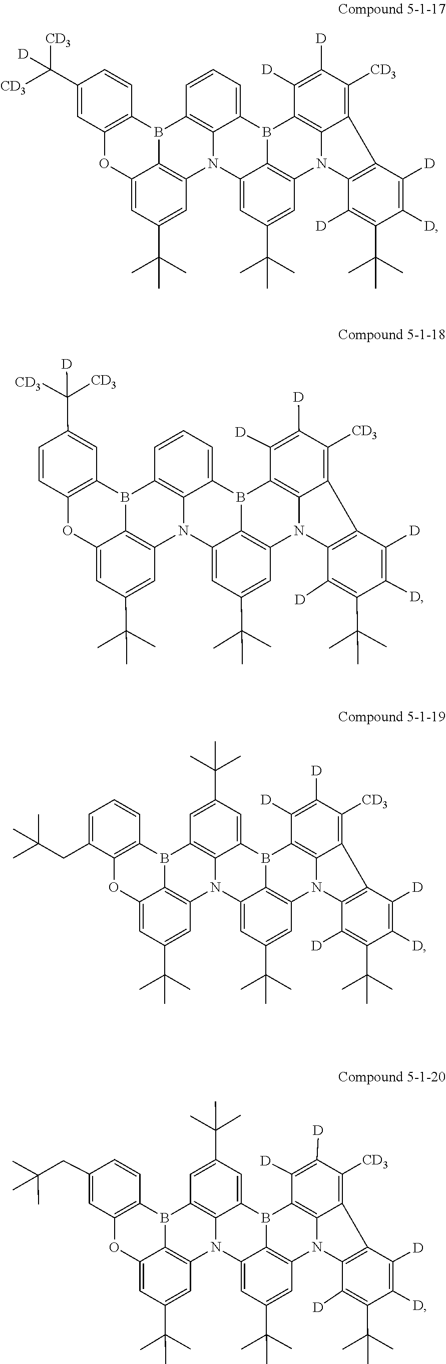 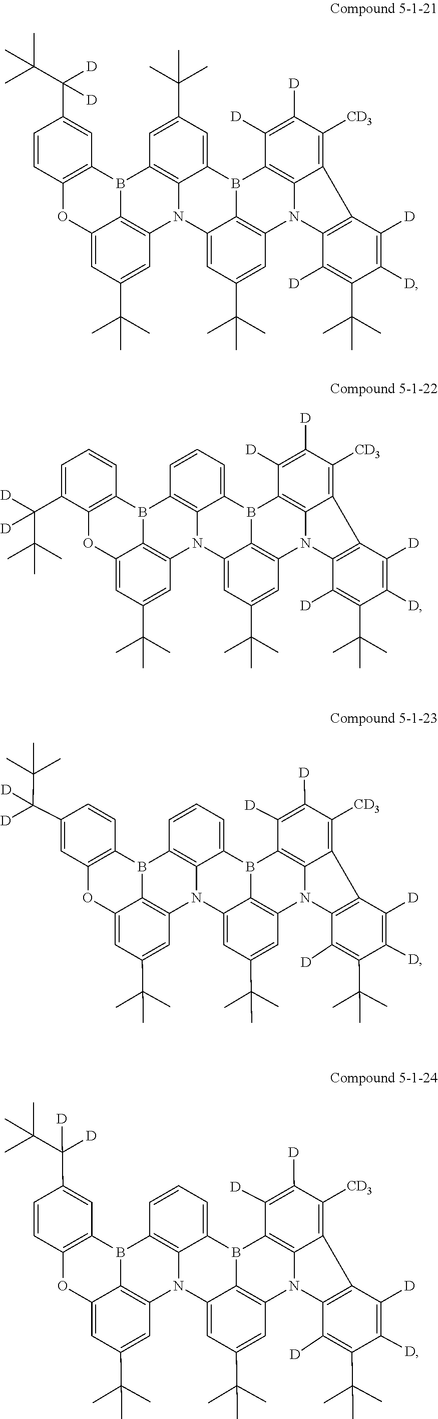 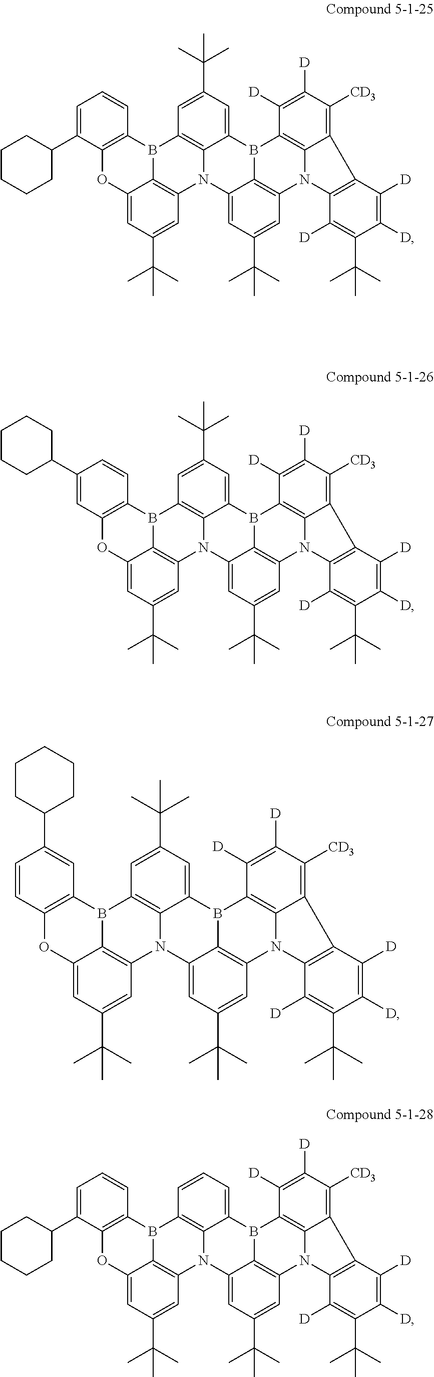 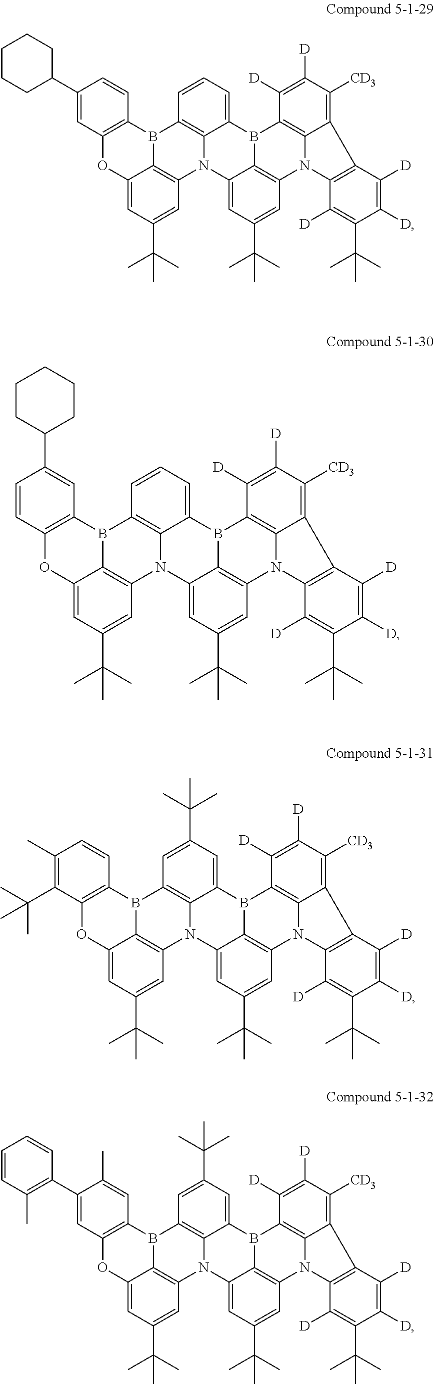 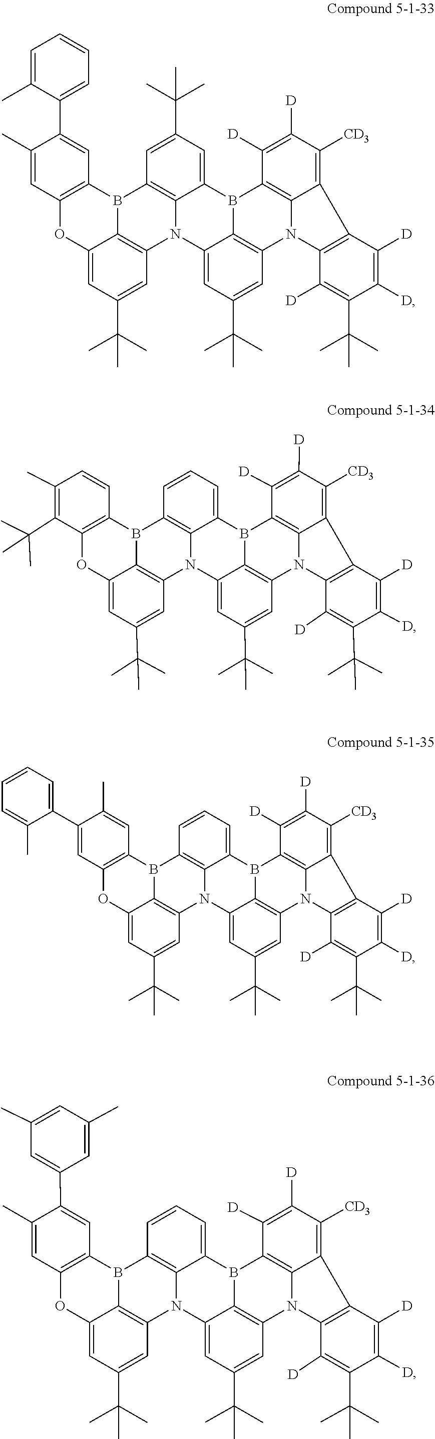 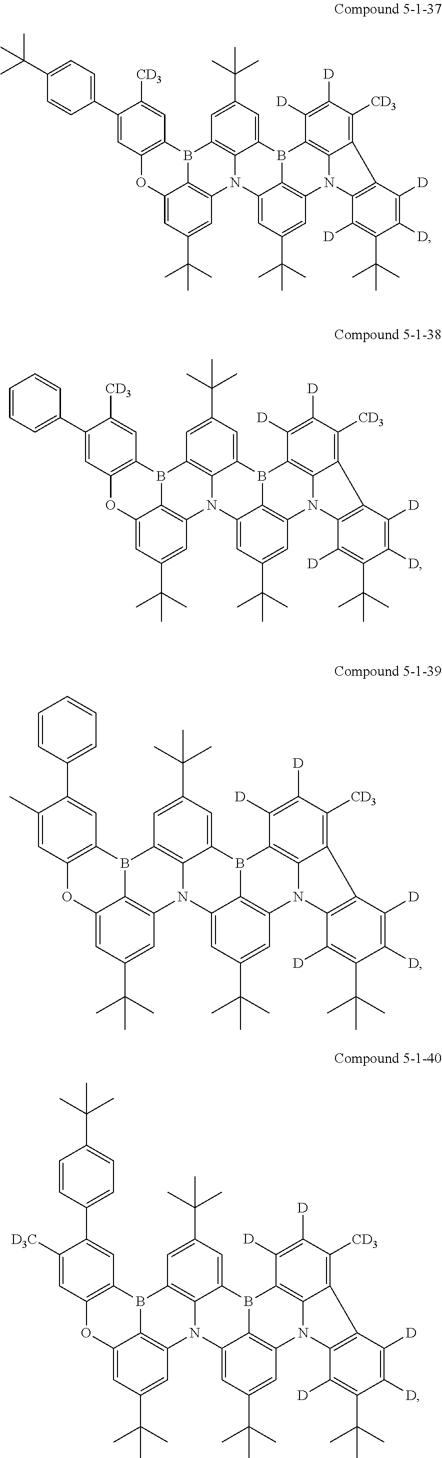 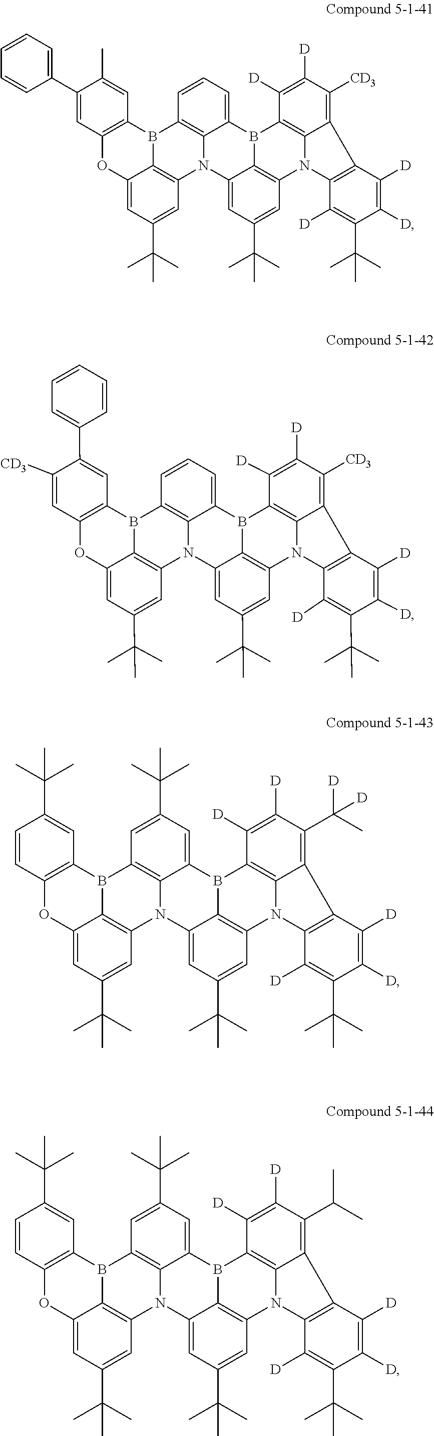 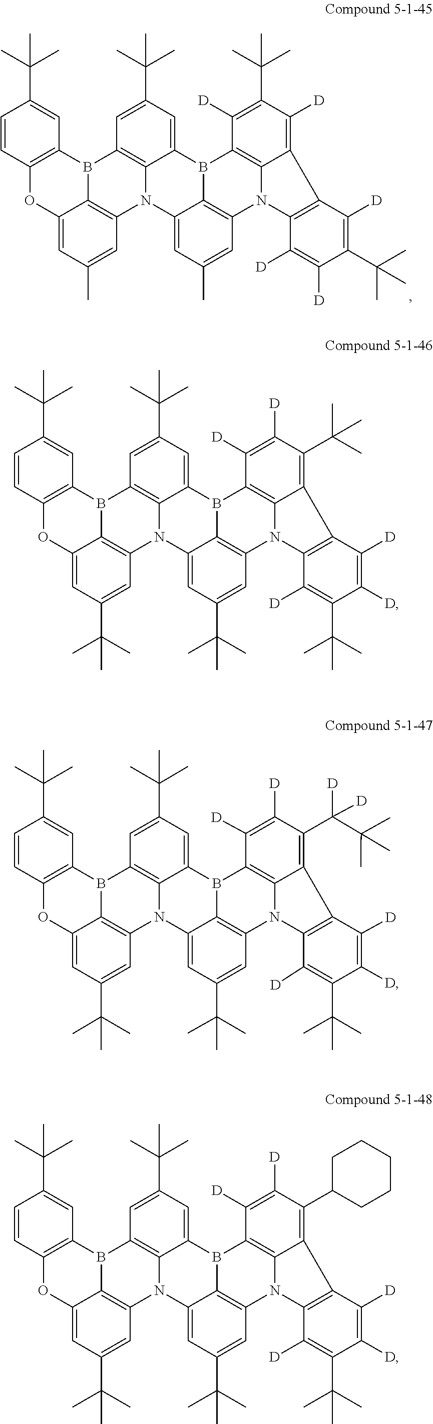 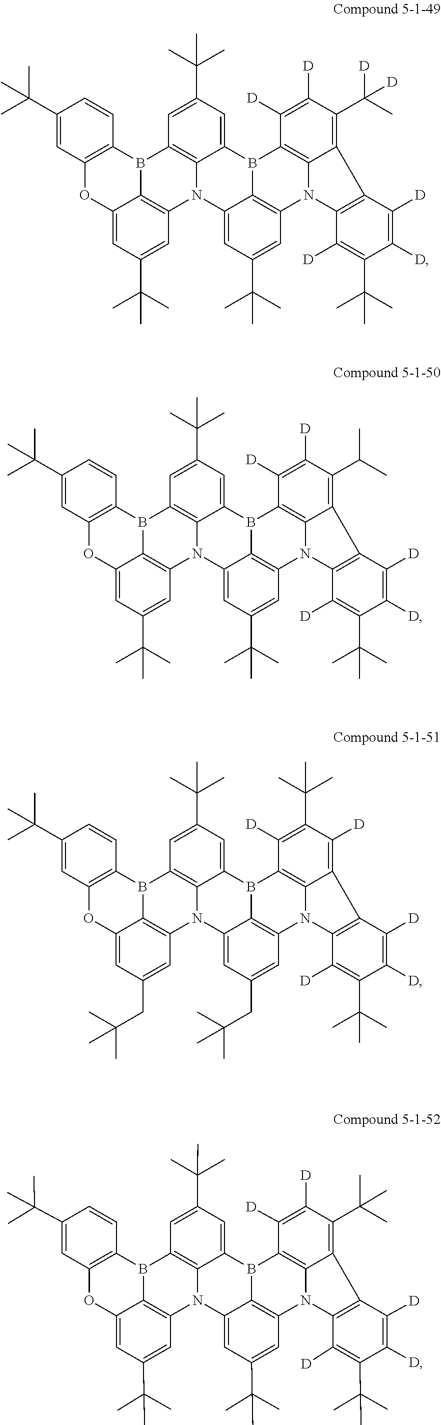 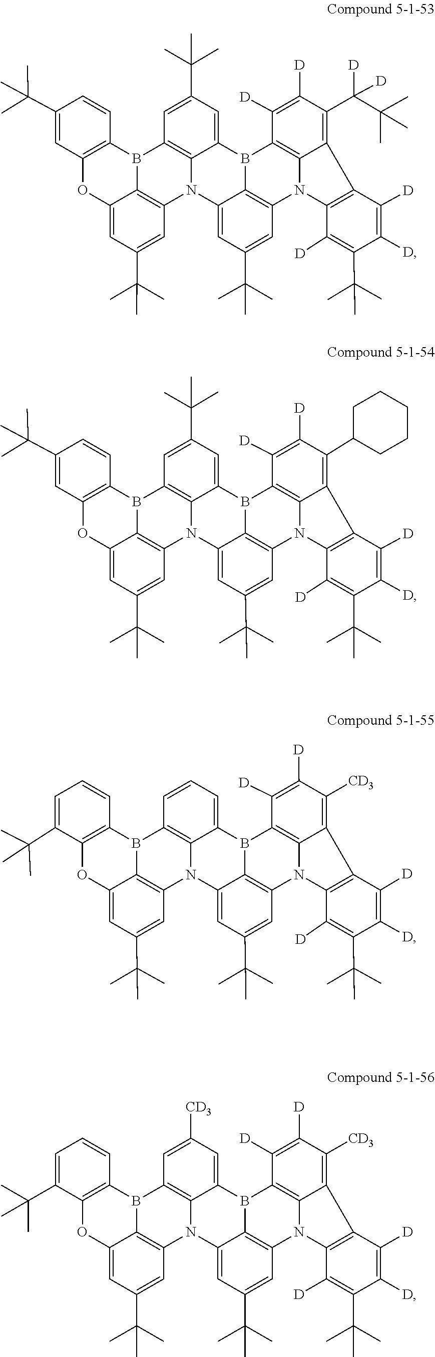 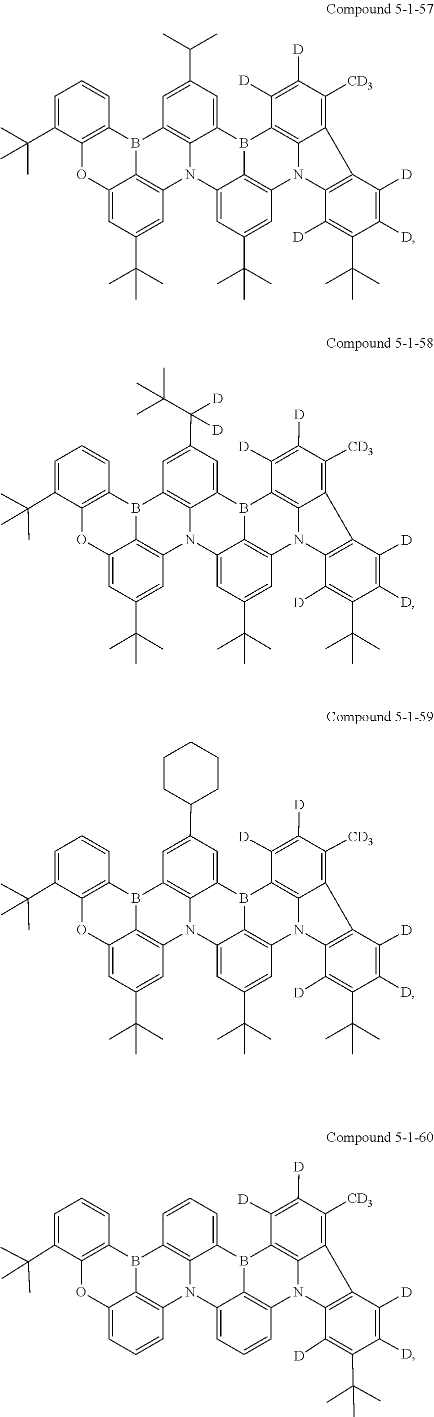 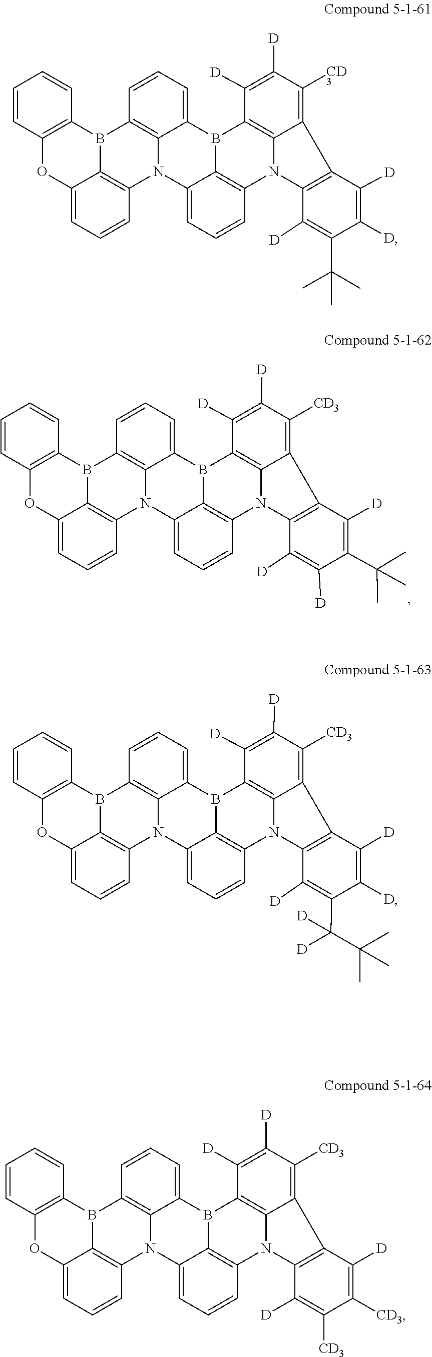 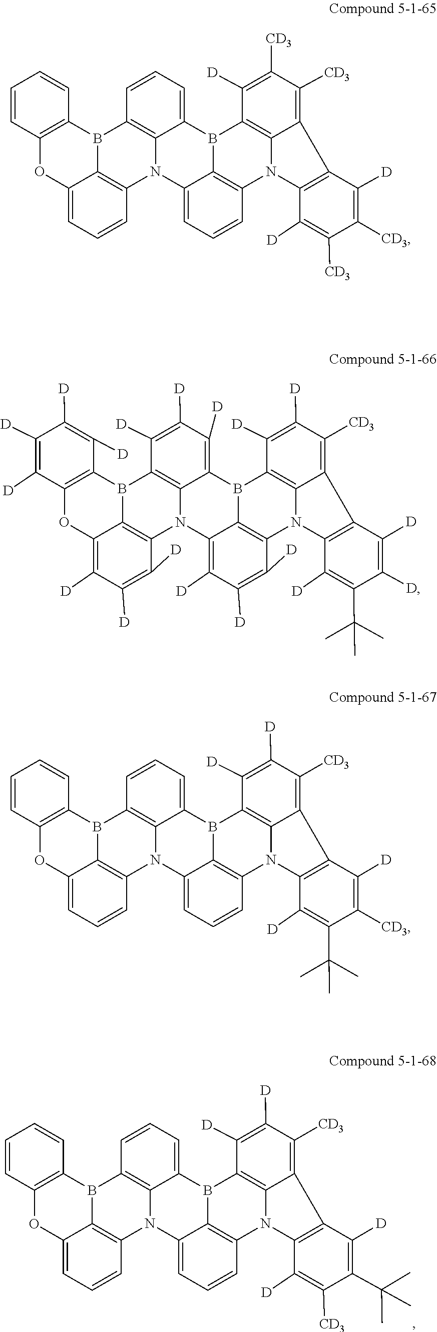 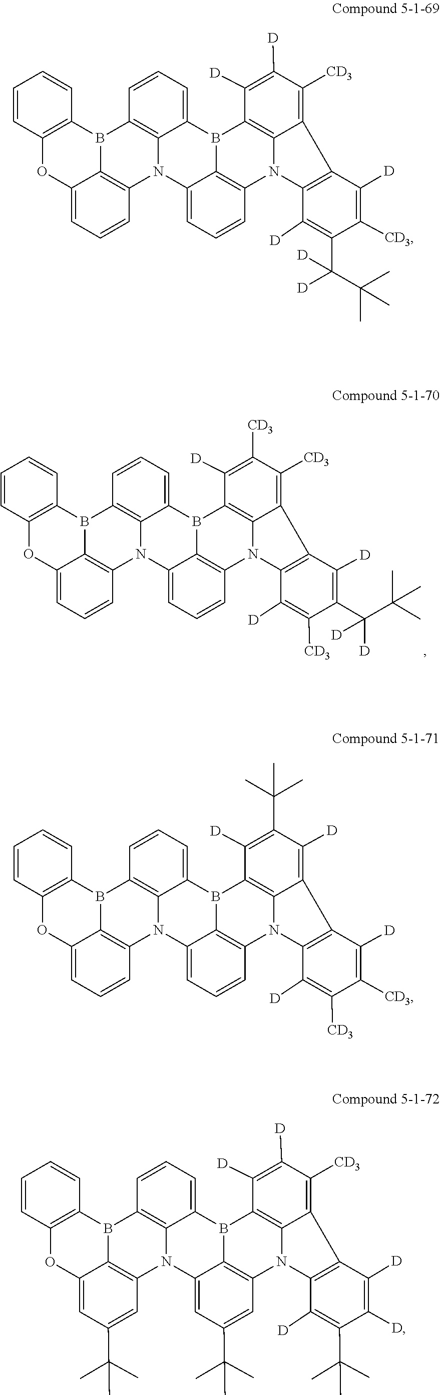 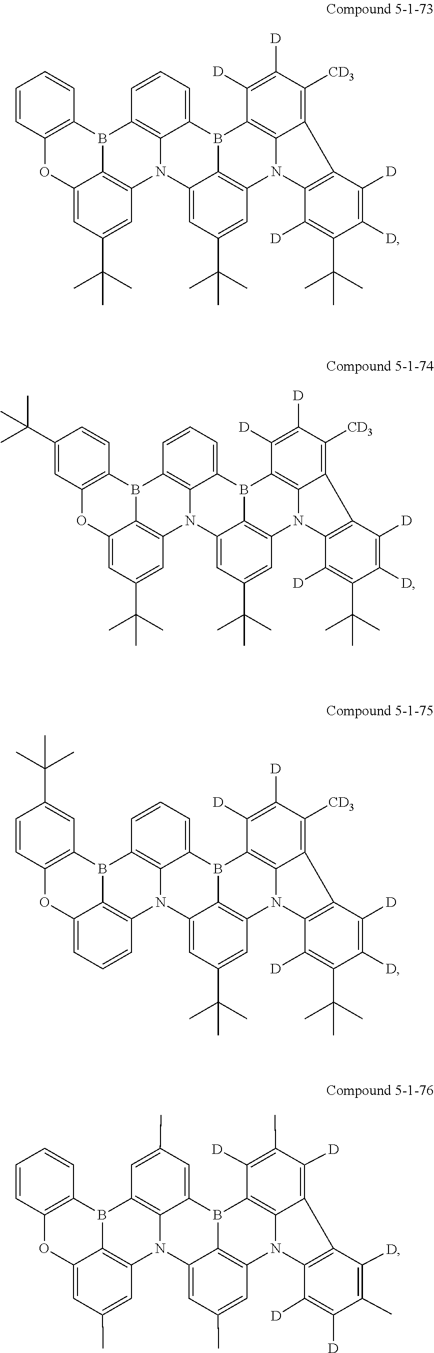 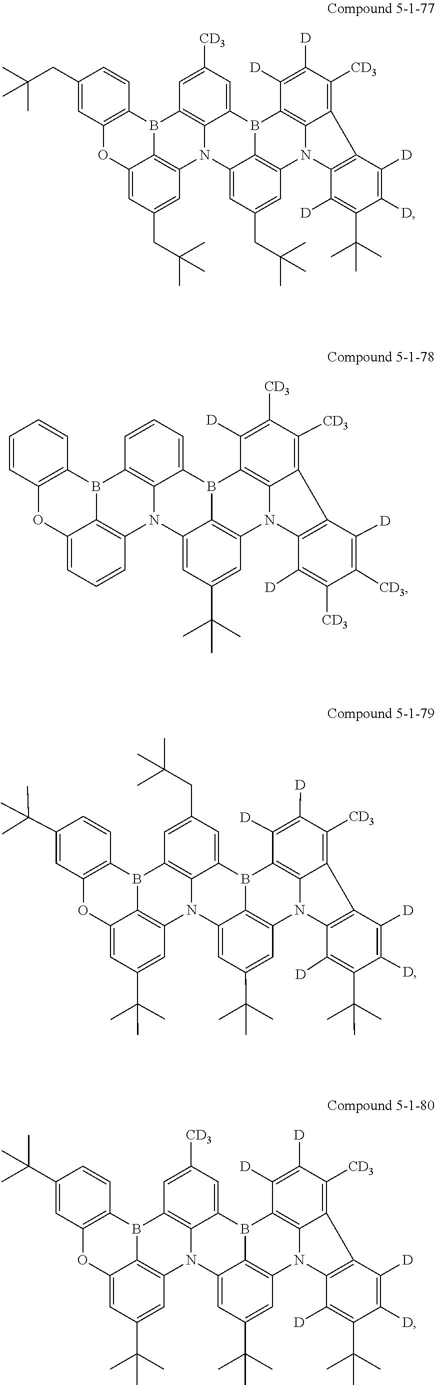 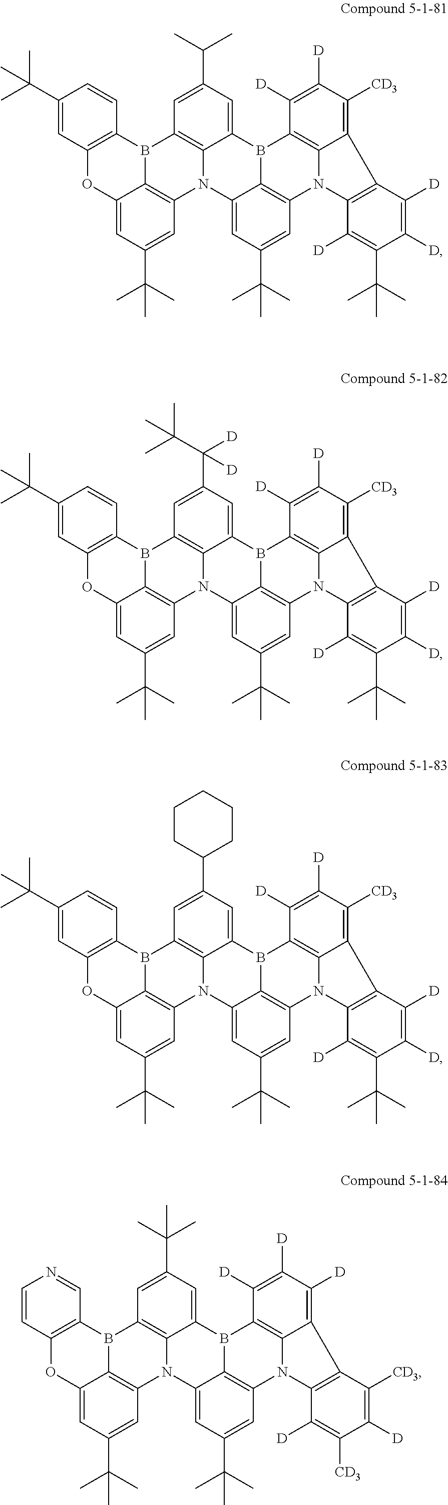 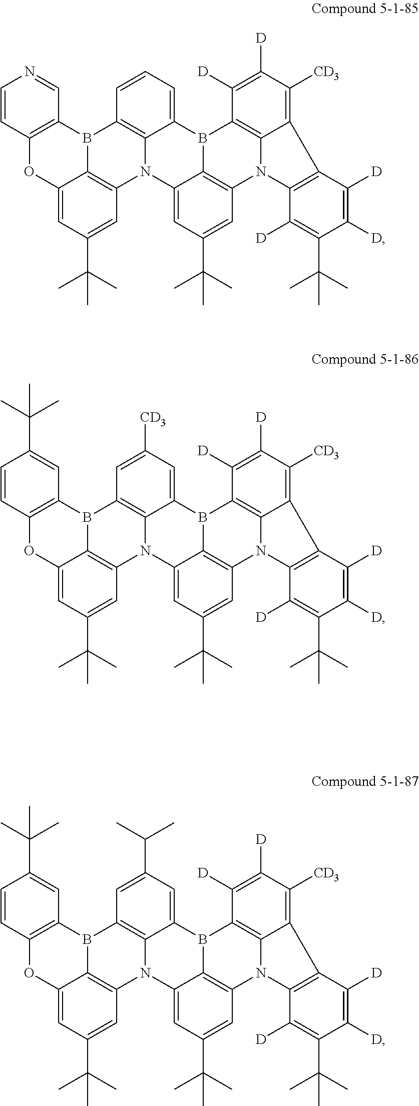 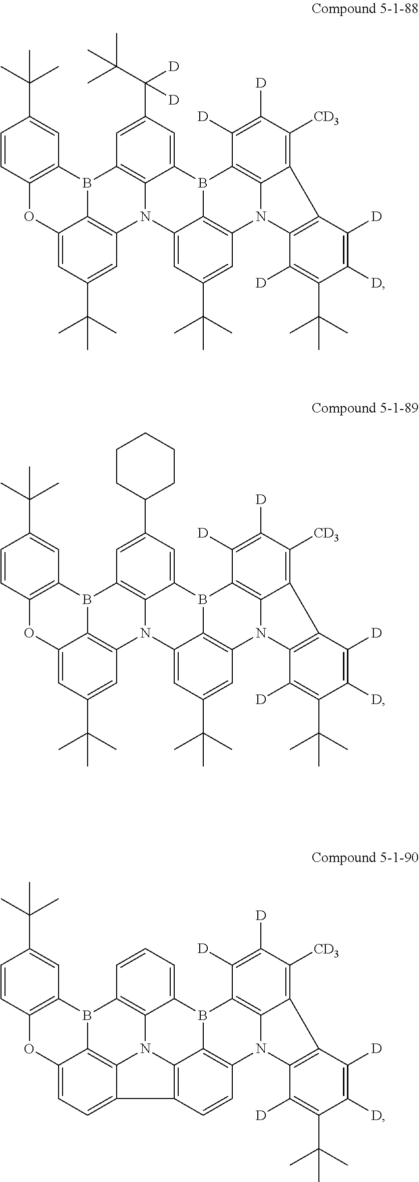 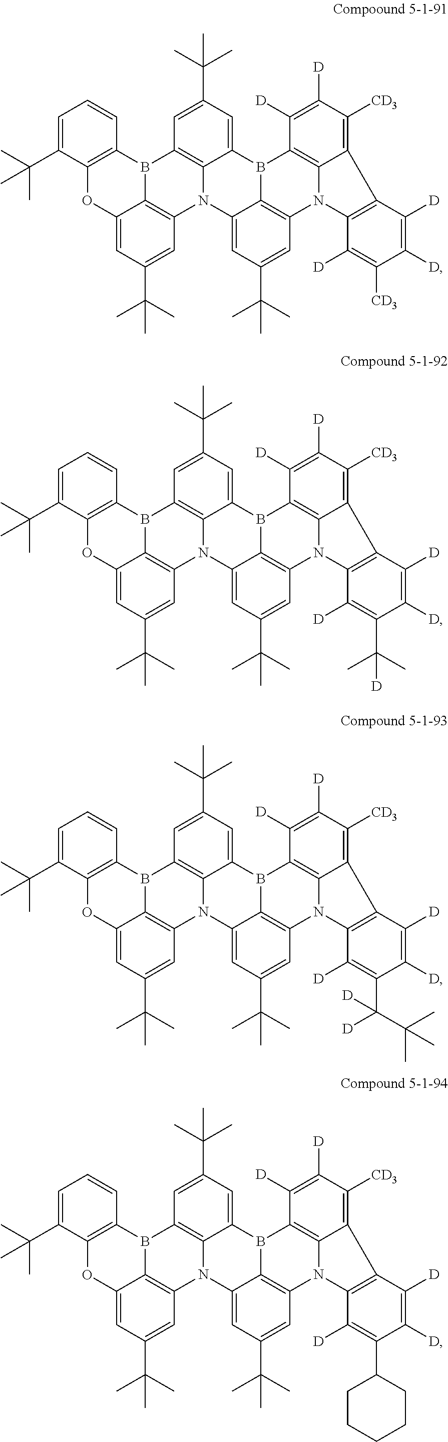 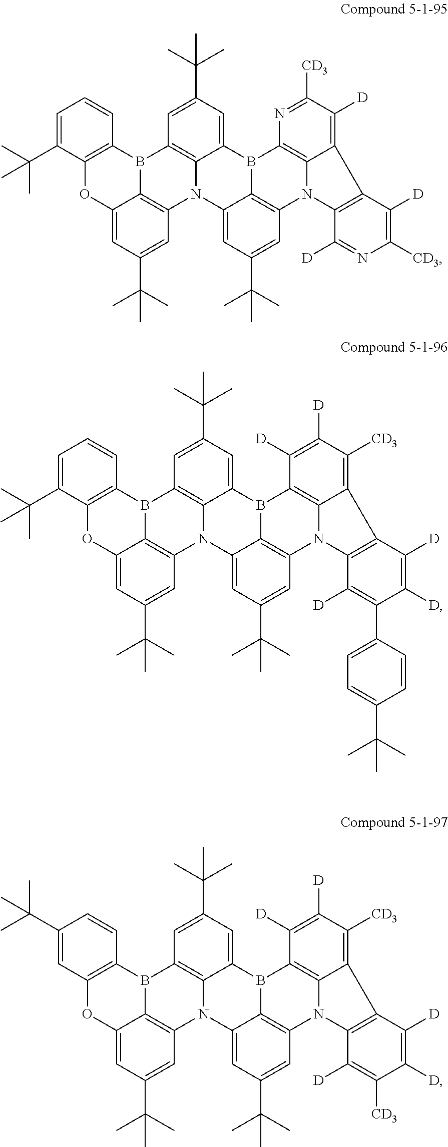 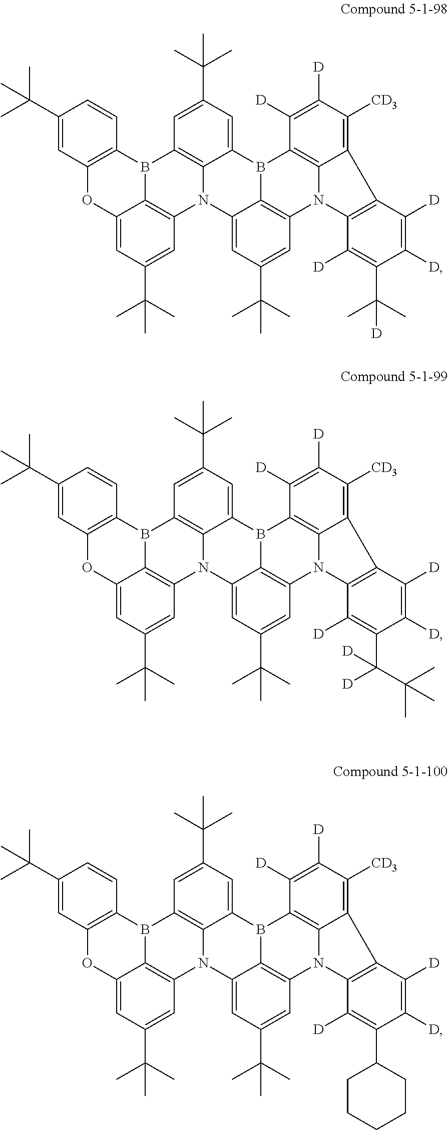 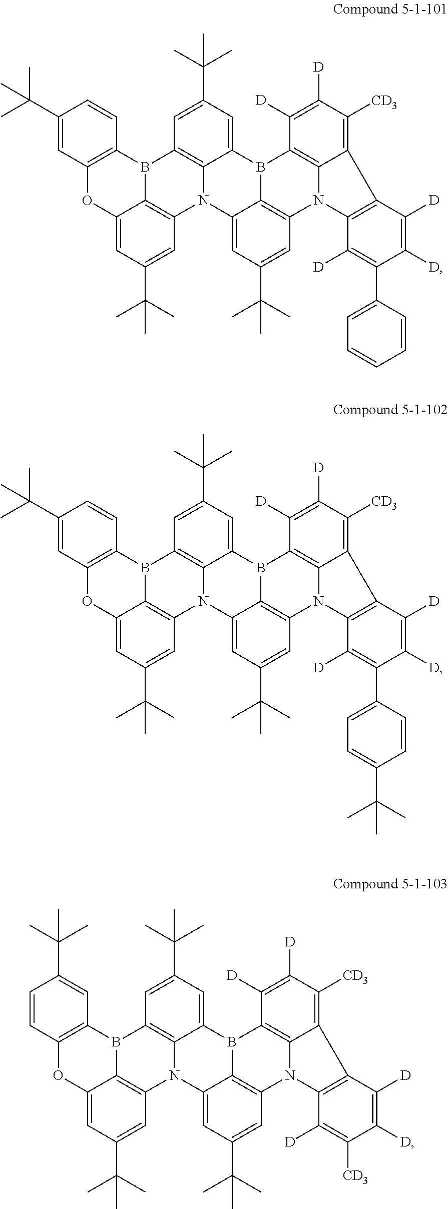 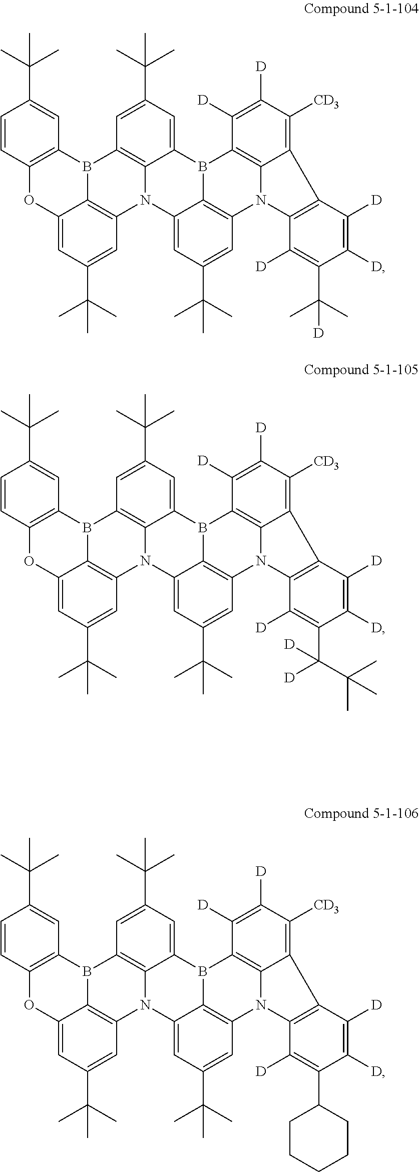 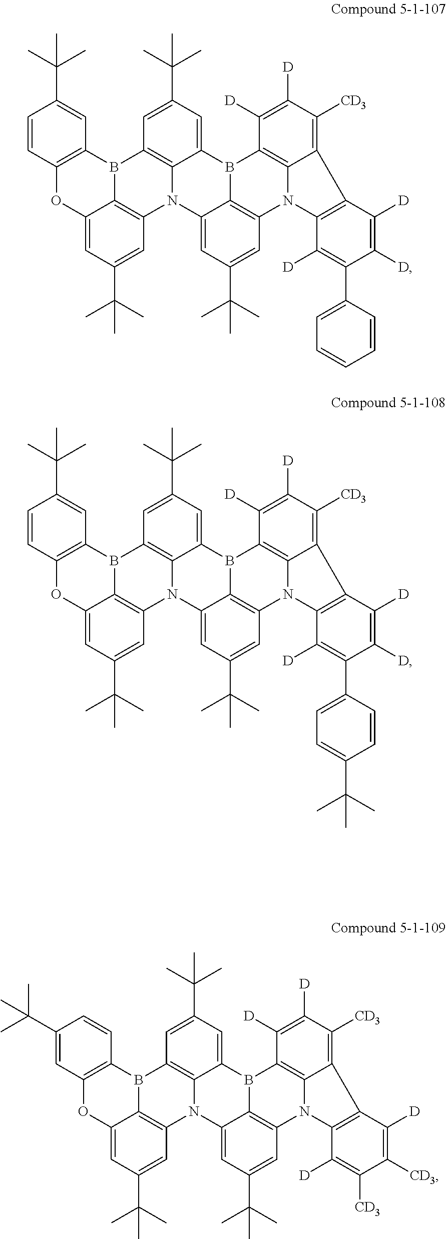 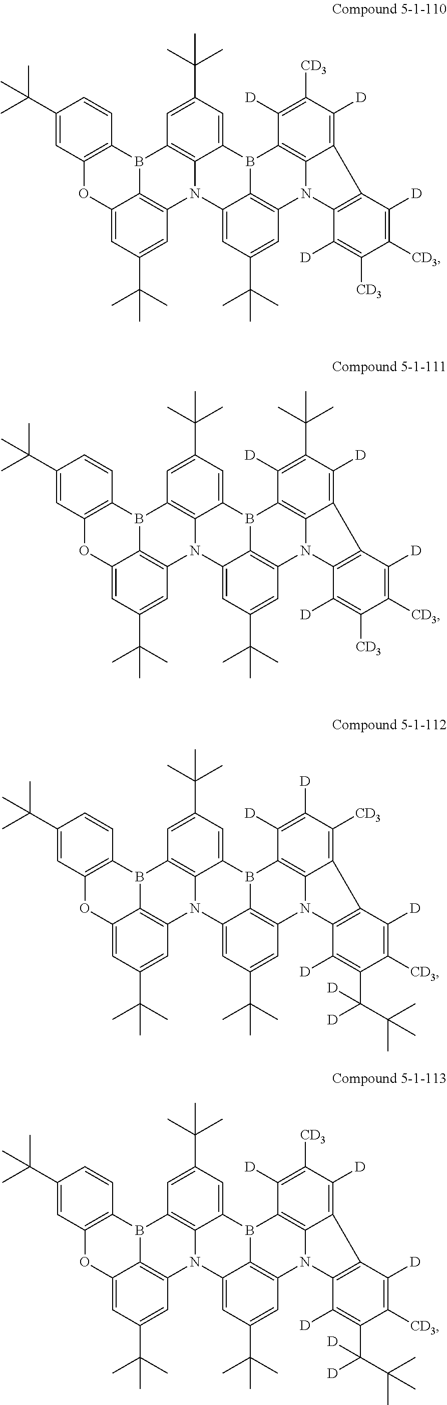 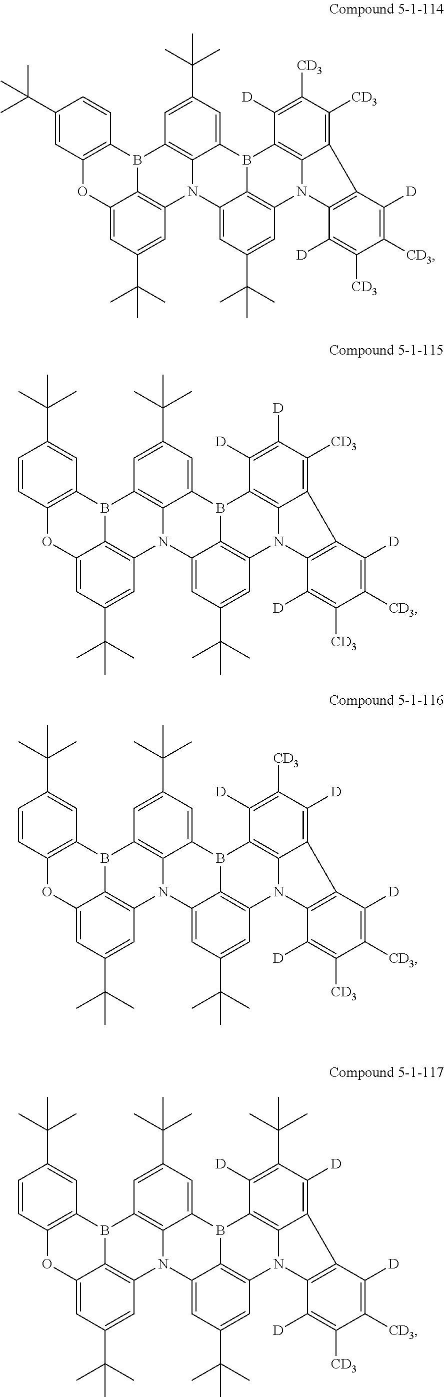 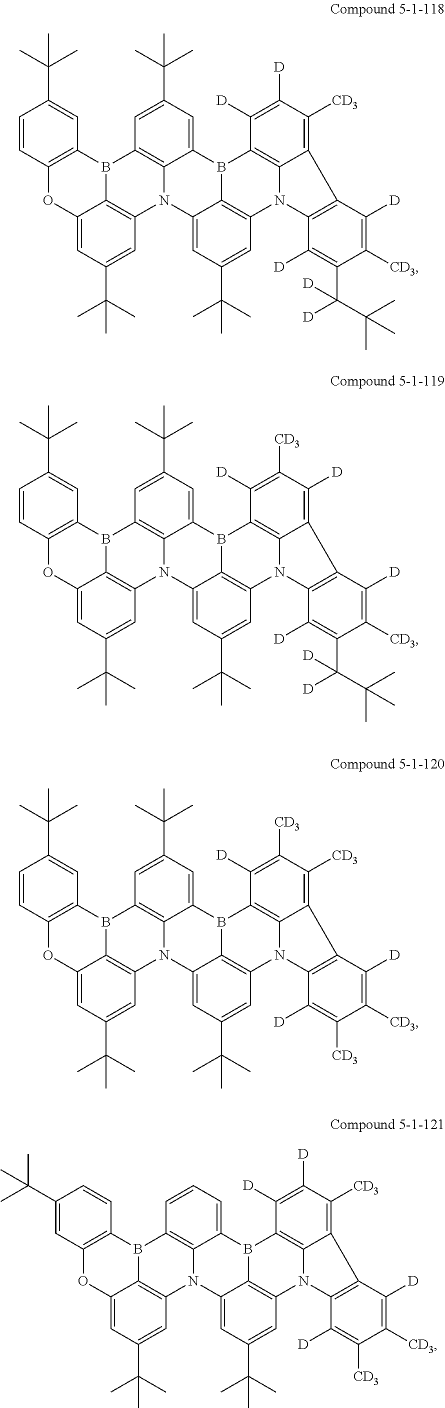 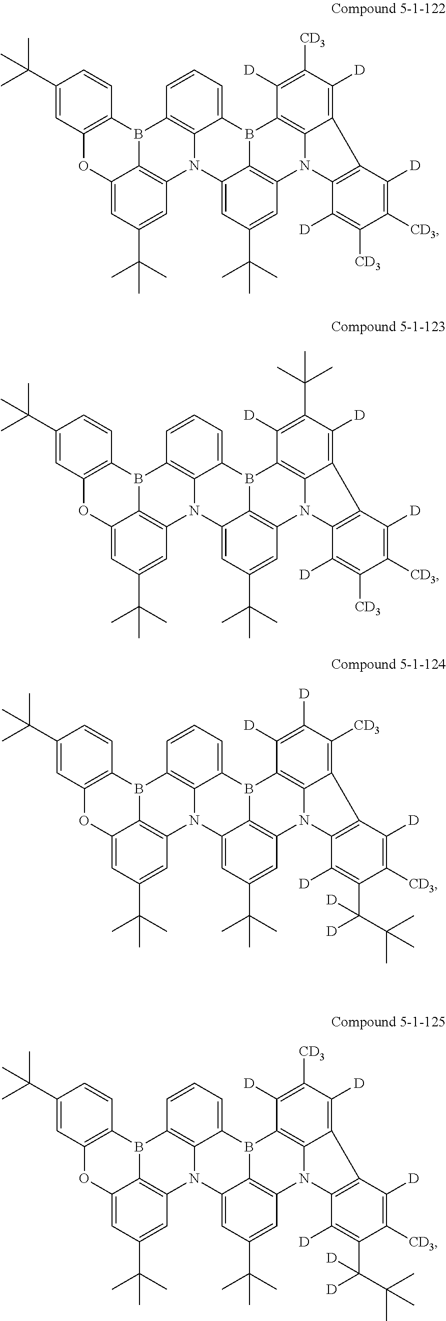 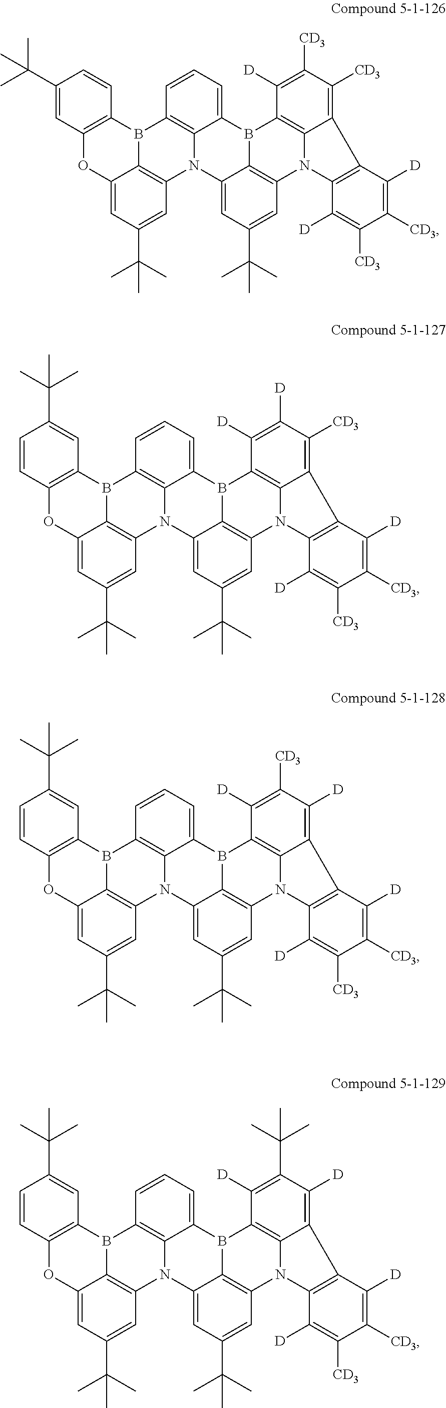 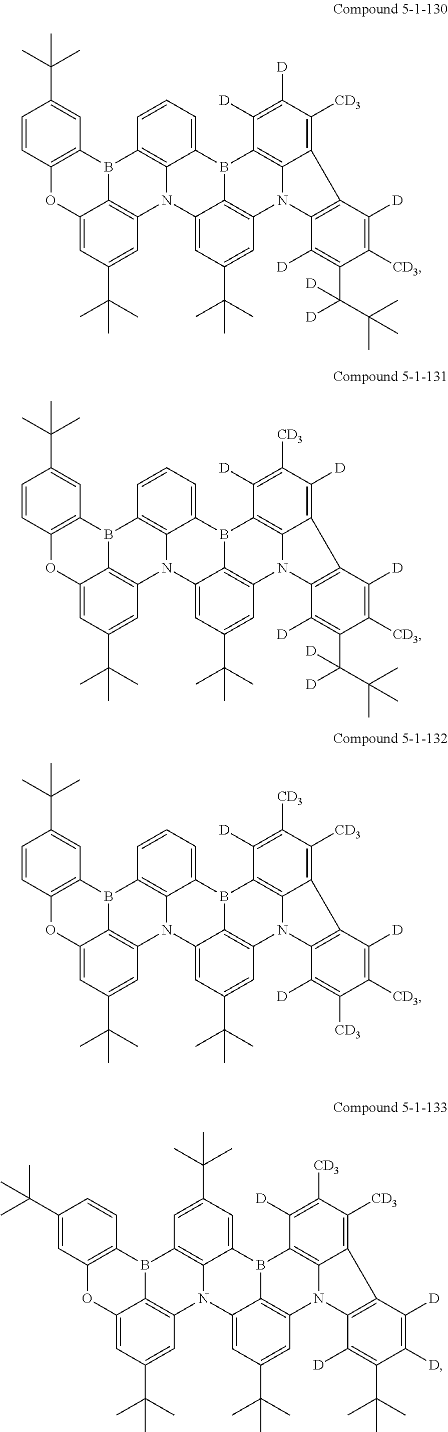 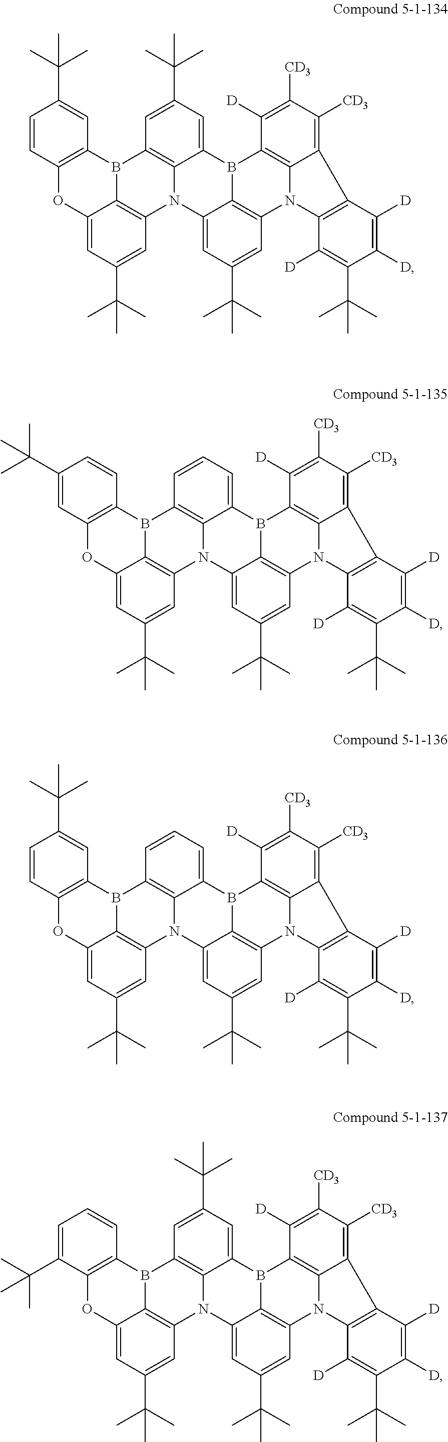 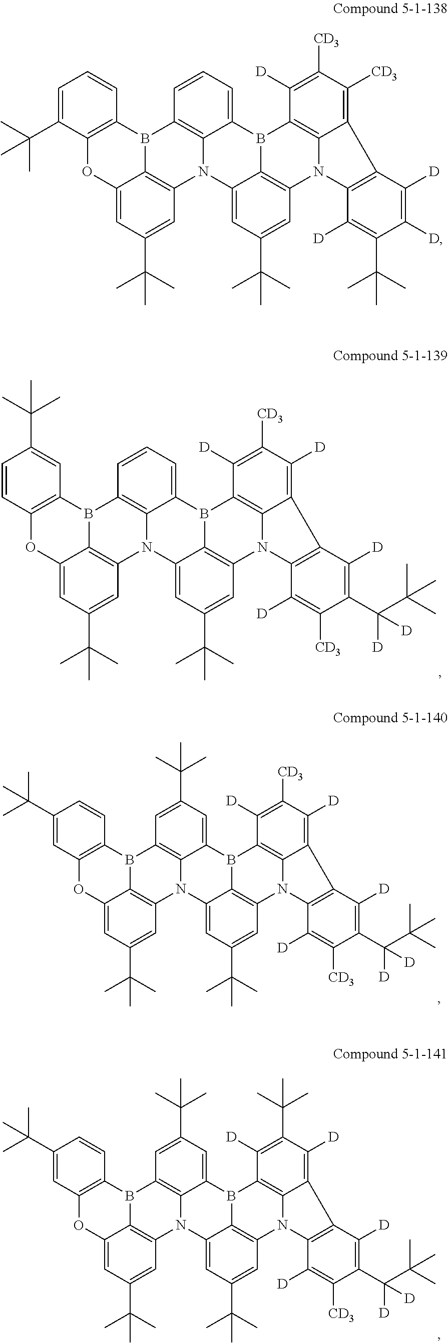 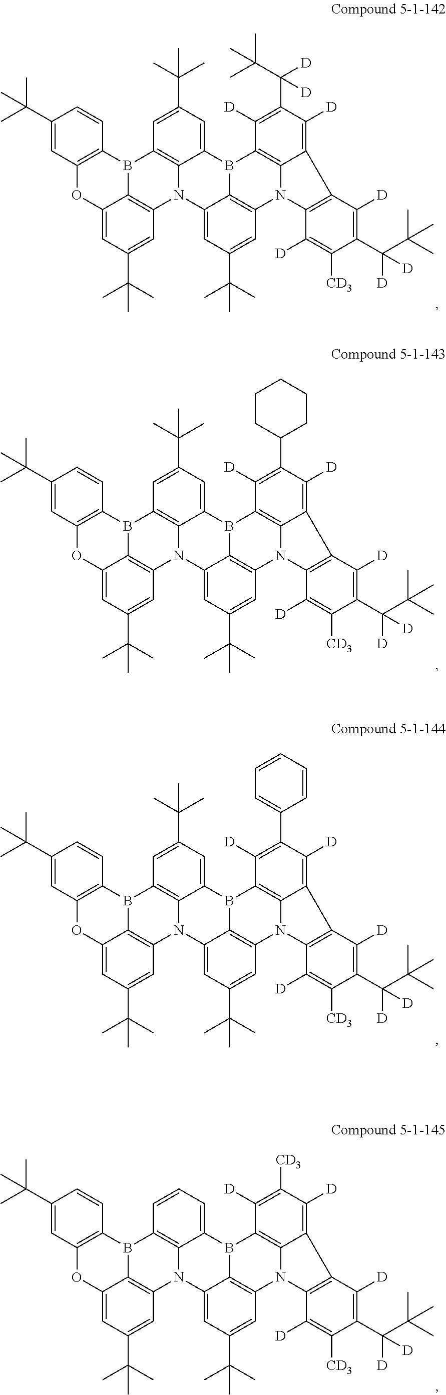 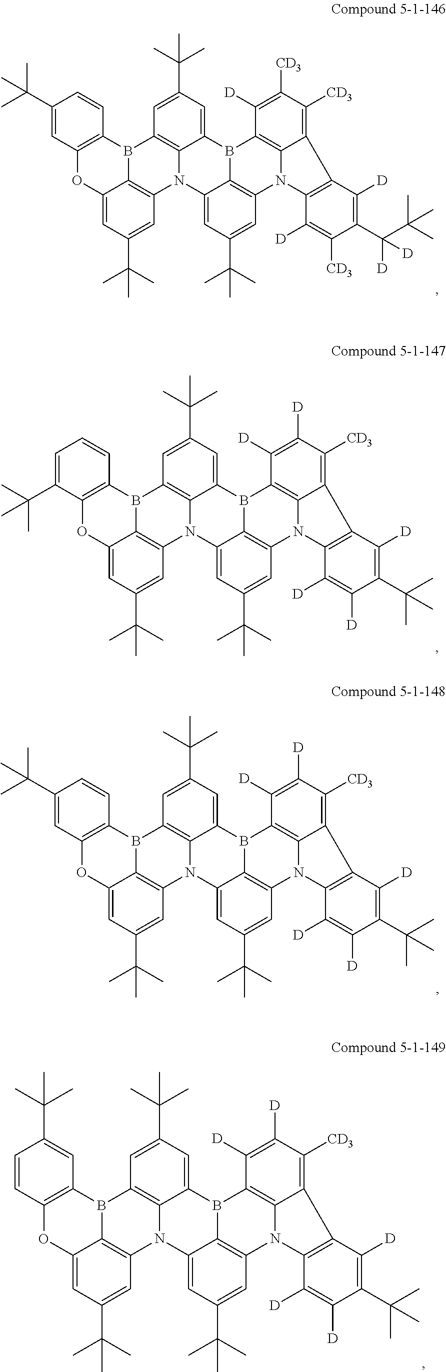 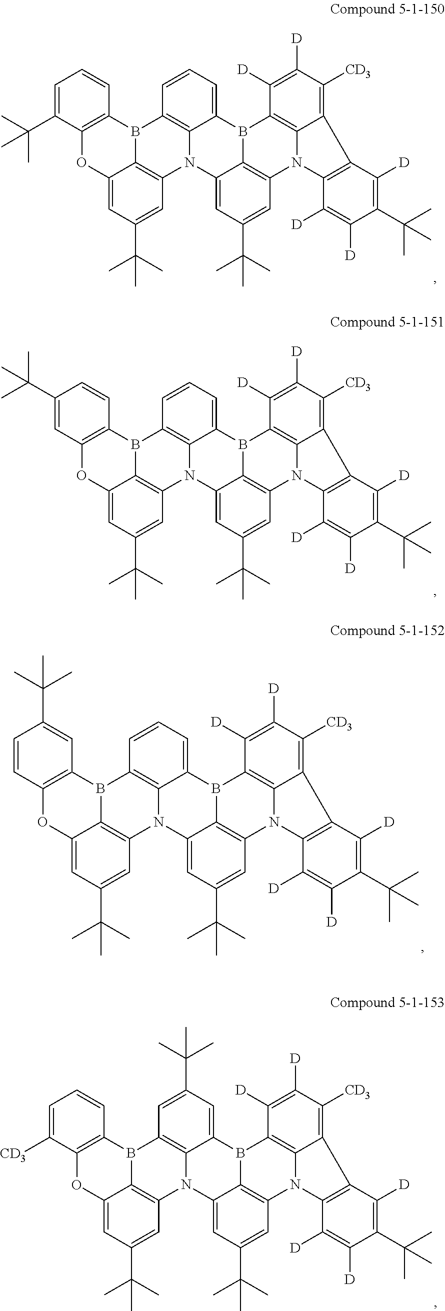 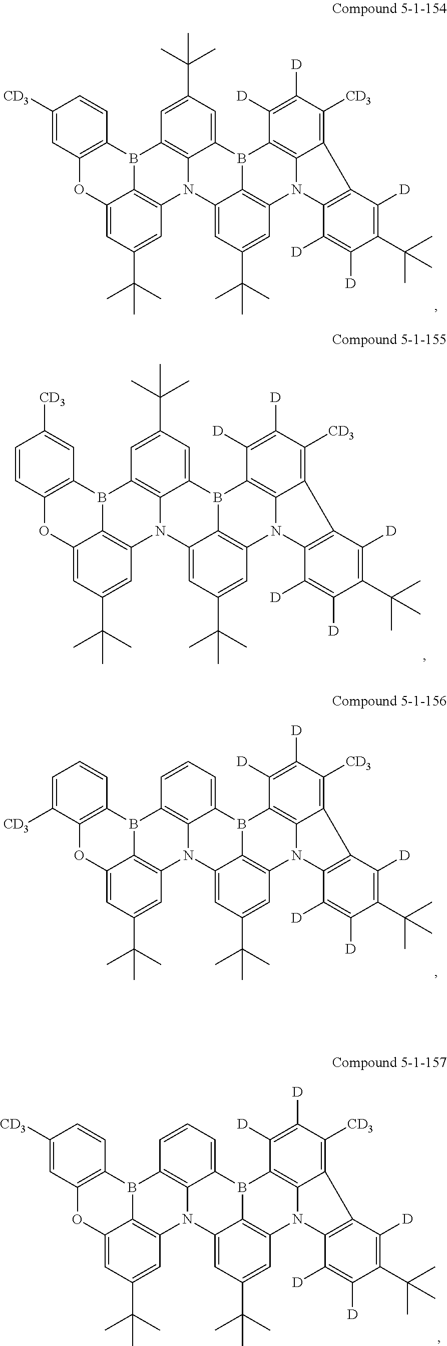 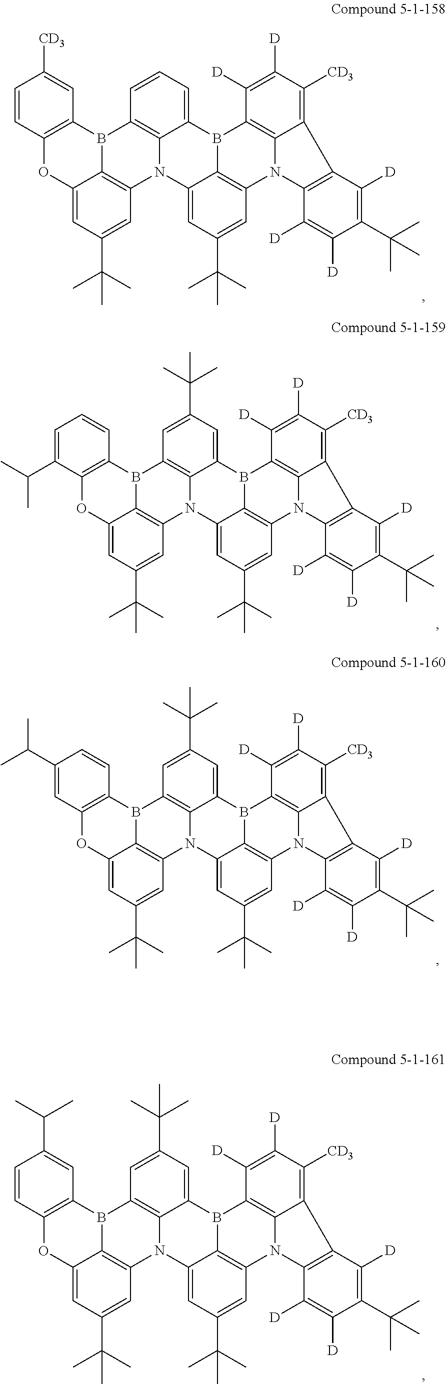 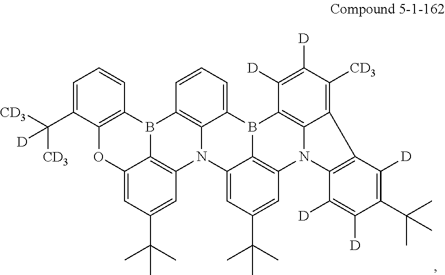 [SMILES: [2H]c1c([2H])c2c3c(c1C([2H])([2H])[2H])c1c([2H])c(C(C)(C)C)c([2H])c([2H])c1n3-c1cc(C(C)(C)C)cc3c1B2c1cccc2c1N3c1cc(C(C)(C)C)cc3c1B2c1cccc(C([2H])(C([2H])([2H])[2H])C([2H])([2H])[2H])c1O3] 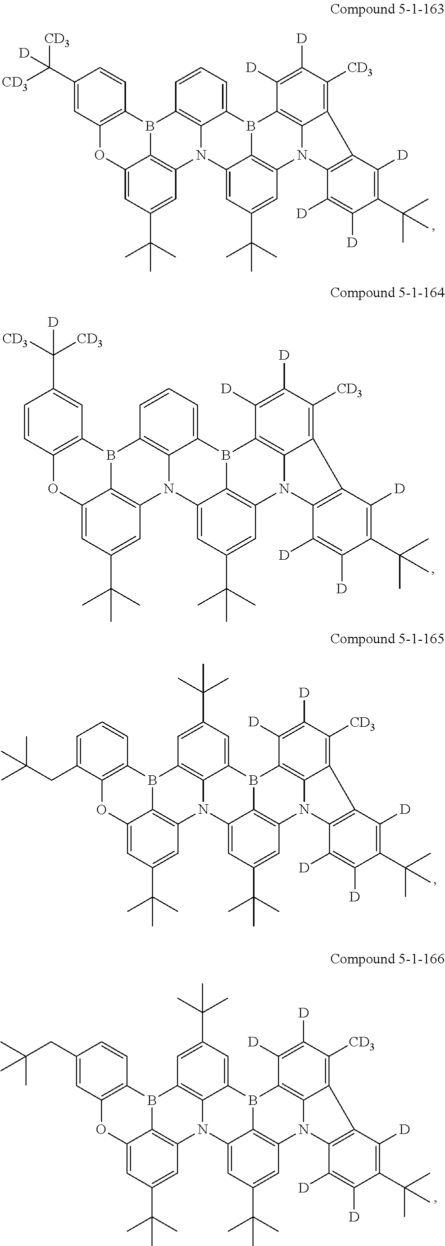 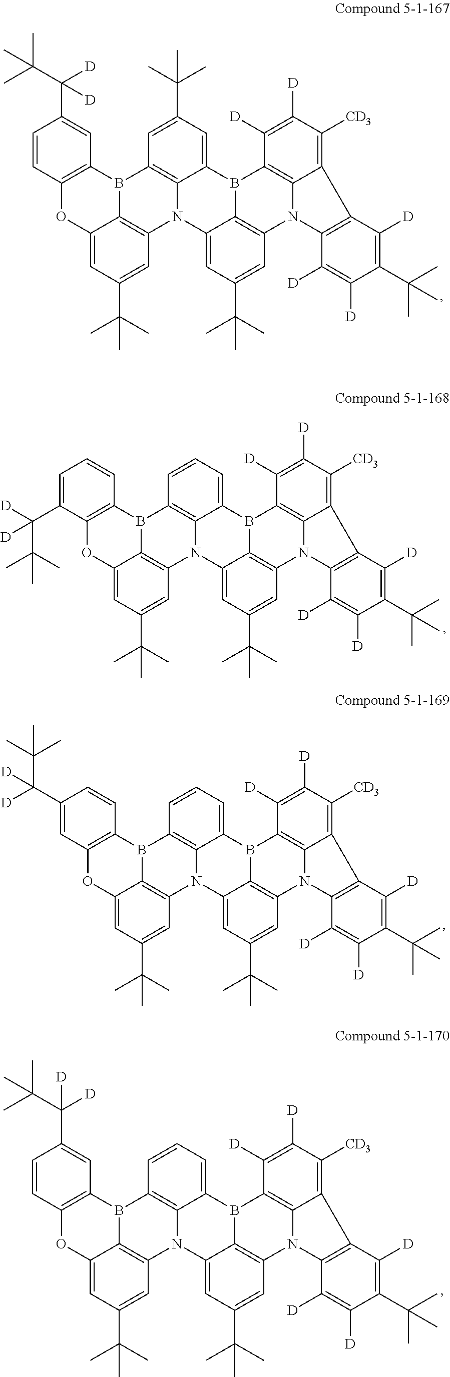 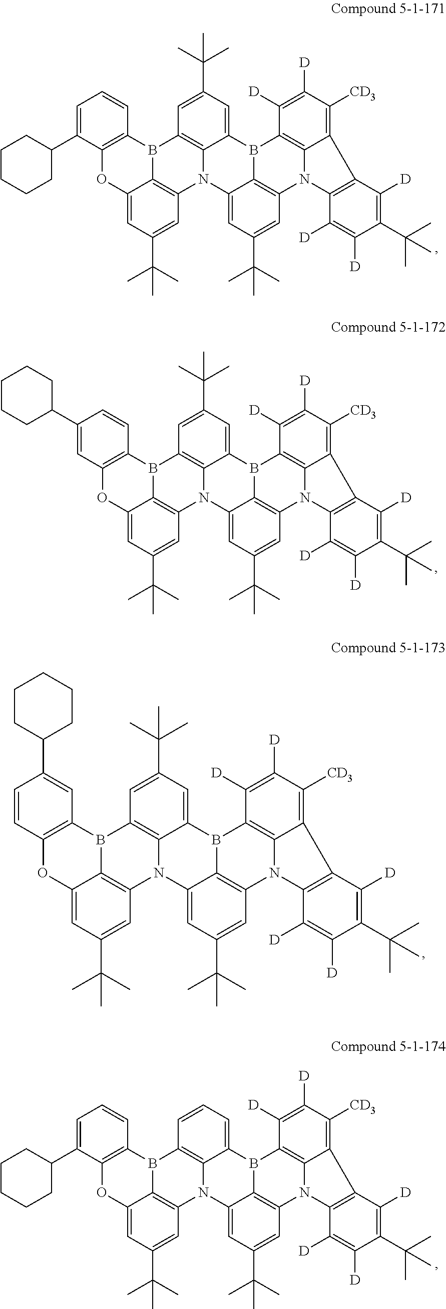 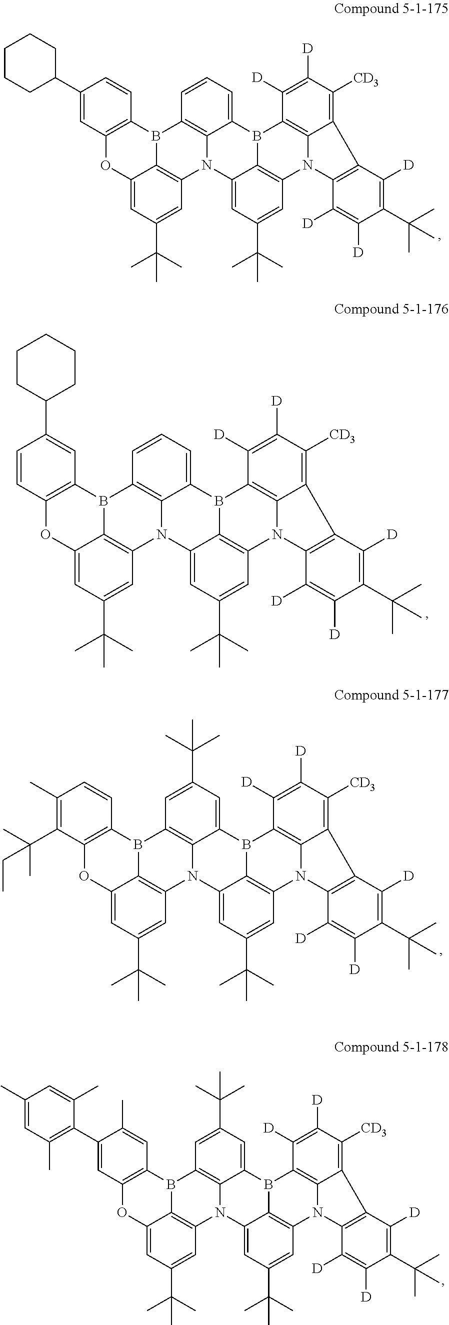 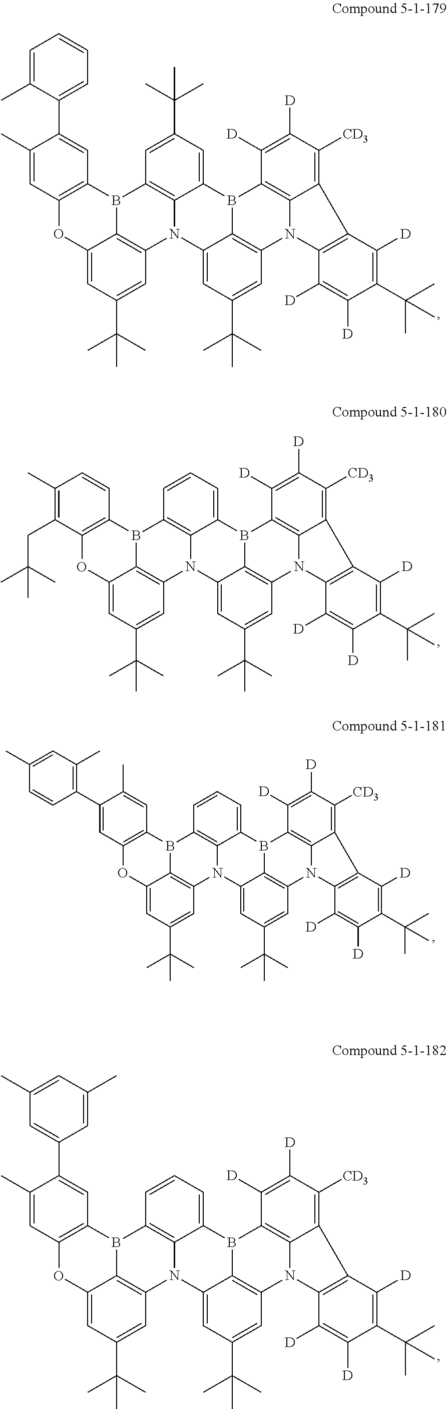 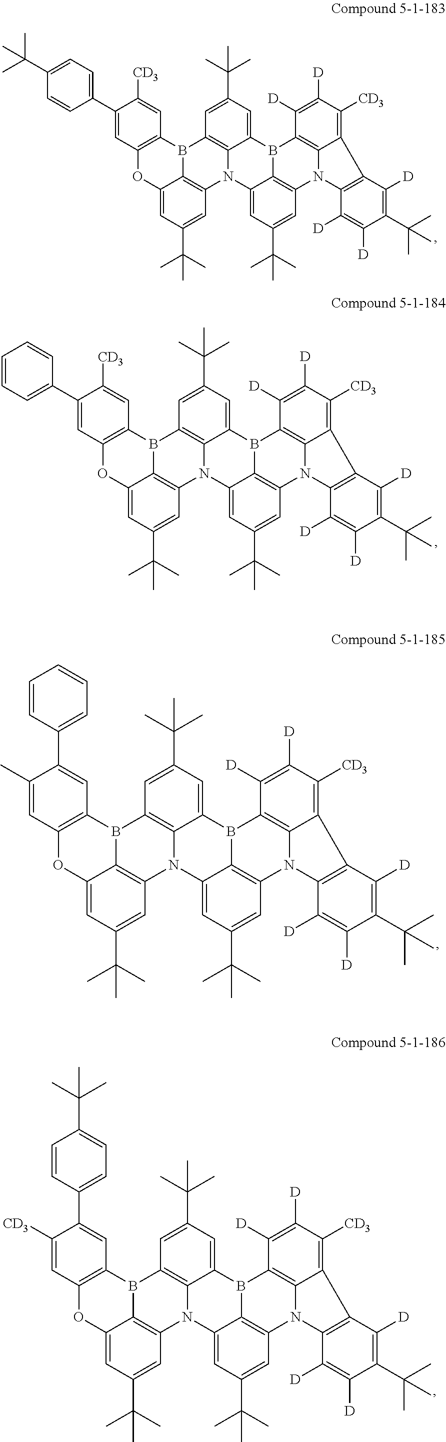 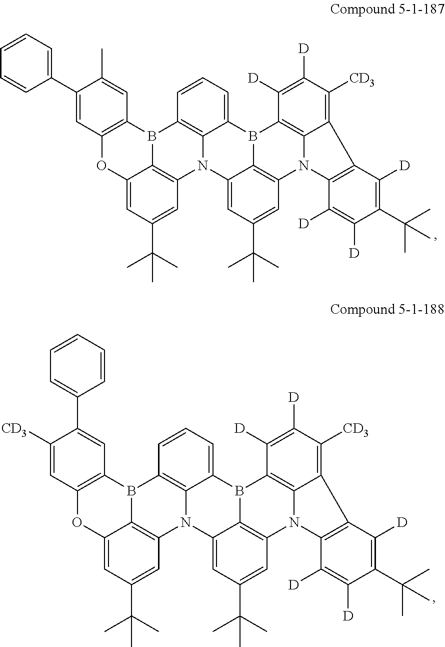 [SMILES: [2H]c1c([2H])c2c3c(c1C([2H])([2H])[2H])c1c([2H])c(C(C)(C)C)c([2H])c([2H])c1n3-c1cc(C(C)(C)C)cc3c1B2c1cccc2c1N3c1cc(C(C)(C)C)cc3c1B2c1cc(C)c(-c2ccccc2)cc1O3 ; [2H]c1c([2H])c2c3c(c1C([2H])([2H])[2H])c1c([2H])c(C(C)(C)C)c([2H])c([2H])c1n3-c1cc(C(C)(C)C)cc3c1B2c1cccc2c1N3c1cc(C(C)(C)C)cc3c1B2c1cc(-c2ccccc2)c(C([2H])([2H])[2H])cc1O3] 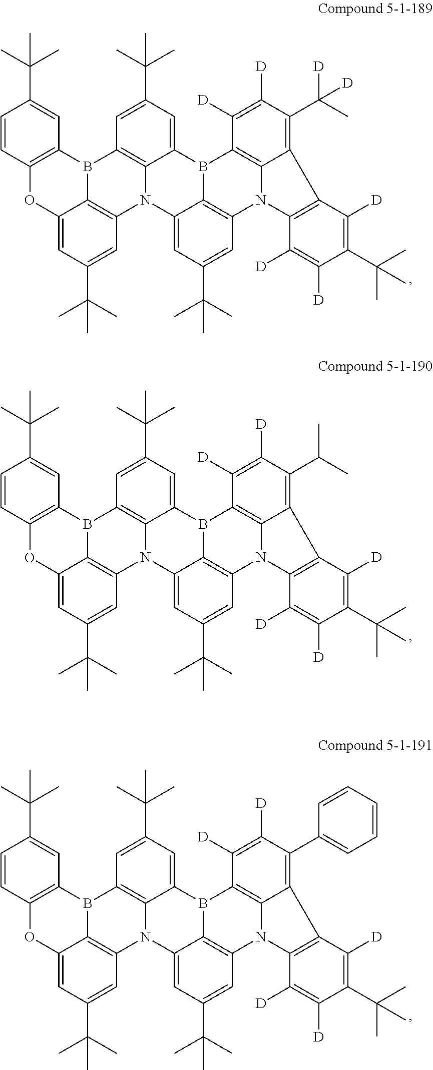 [SMILES: [2H]c1c([2H])c2c3c(c1C([2H])([2H])C)c1c([2H])c(C(C)(C)C)c([2H])c([2H])c1n3-c1cc(C(C)(C)C)cc3c1B2c1cc(C(C)(C)C)cc2c1N3c1cc(C(C)(C)C)cc3c1B2c1cc(C(C)(C)C)ccc1O3 ; [2H]c1c([2H])c2c3c(c1C(C)C)c1c([2H])c(C(C)(C)C)c([2H])c([2H])c1n3-c1cc(C(C)(C)C)cc3c1B2c1cc(C(C)(C)C)cc2c1N3c1cc(C(C)(C)C)cc3c1B2c1cc(C(C)(C)C)ccc1O3 ; [2H]c1c([2H])c2c3c(c1-c1ccccc1)c1c([2H])c(C(C)(C)C)c([2H])c([2H])c1n3-c1cc(C(C)(C)C)cc3c1B2c1cc(C(C)(C)C)cc2c1N3c1cc(C(C)(C)C)cc3c1B2c1cc(C(C)(C)C)ccc1O3] 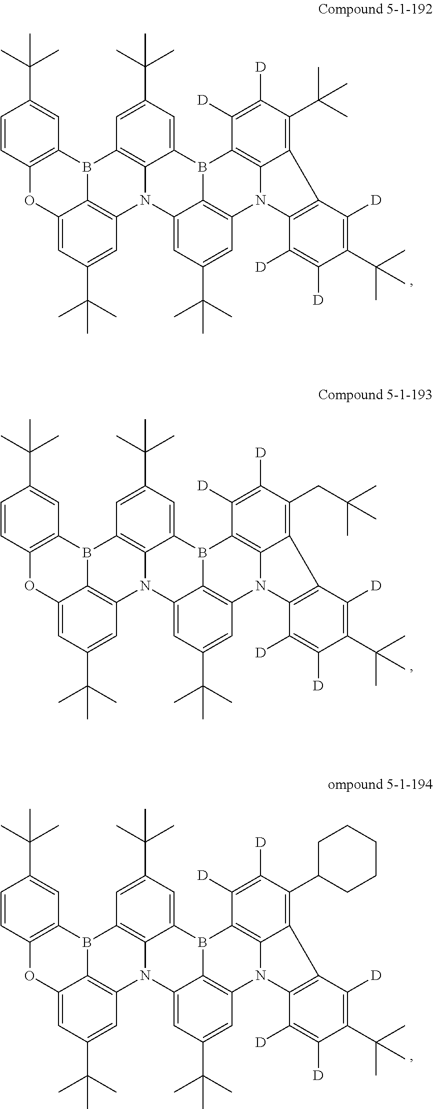 [SMILES: [2H]c1c([2H])c2c3c(c1C(C)(C)C)c1c([2H])c(C(C)(C)C)c([2H])c([2H])c1n3-c1cc(C(C)(C)C)cc3c1B2c1cc(C(C)(C)C)cc2c1N3c1cc(C(C)(C)C)cc3c1B2c1cc(C(C)(C)C)ccc1O3 ; [2H]c1c([2H])c2c3c(c1CC(C)(C)C)c1c([2H])c(C(C)(C)C)c([2H])c([2H])c1n3-c1cc(C(C)(C)C)cc3c1B2c1cc(C(C)(C)C)cc2c1N3c1cc(C(C)(C)C)cc3c1B2c1cc(C(C)(C)C)ccc1O3 ; [2H]c1c([2H])c2c3c(c1C1CCCCC1)c1c([2H])c(C(C)(C)C)c([2H])c([2H])c1n3-c1cc(C(C)(C)C)cc3c1B2c1cc(C(C)(C)C)cc2c1N3c1cc(C(C)(C)C)cc3c1B2c1cc(C(C)(C)C)ccc1O3] 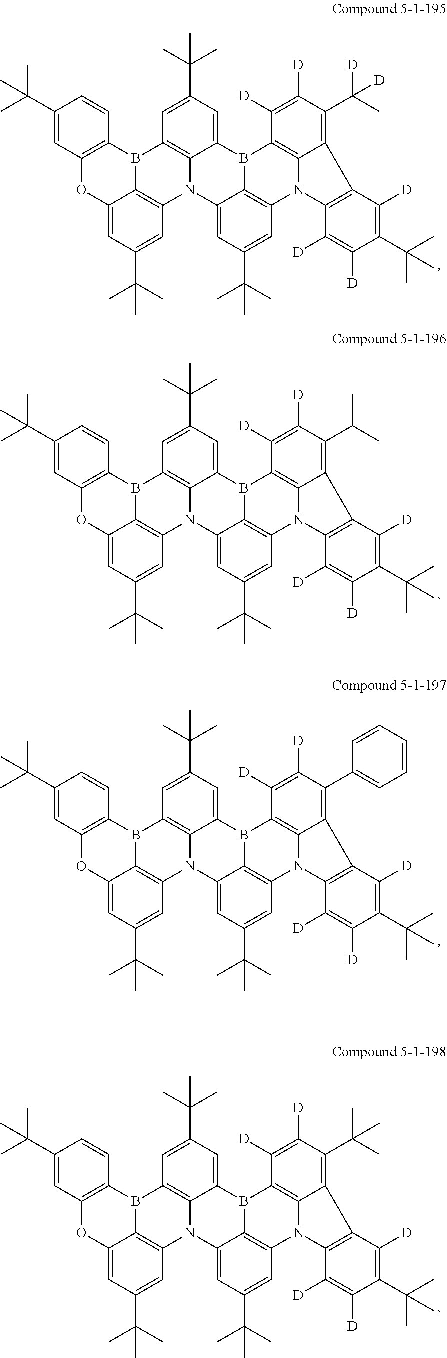 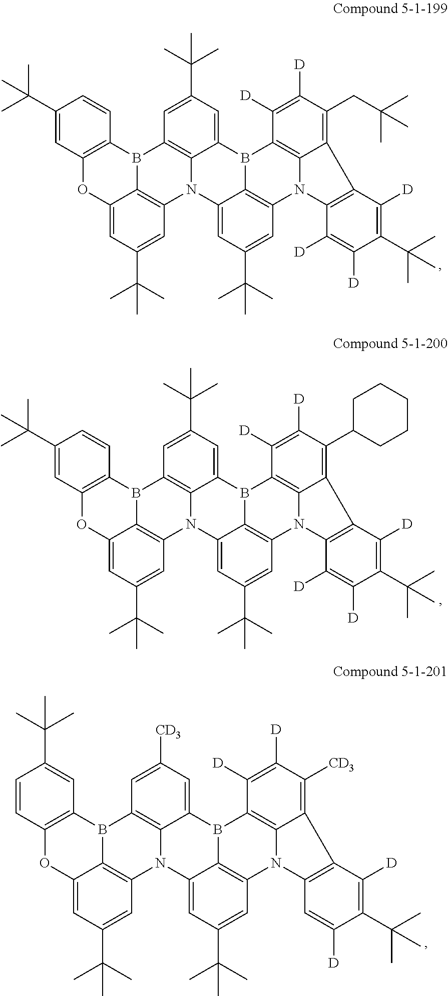 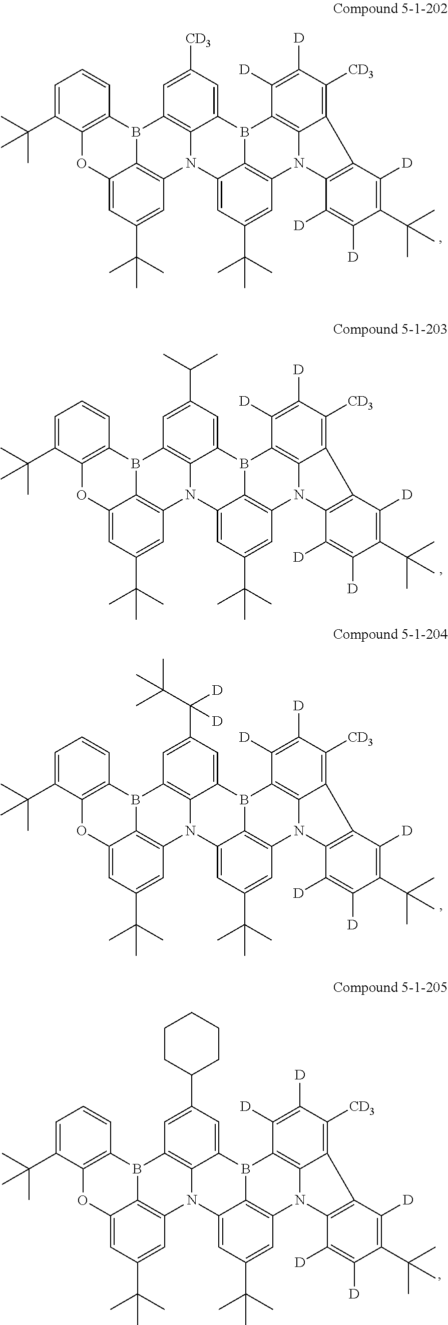 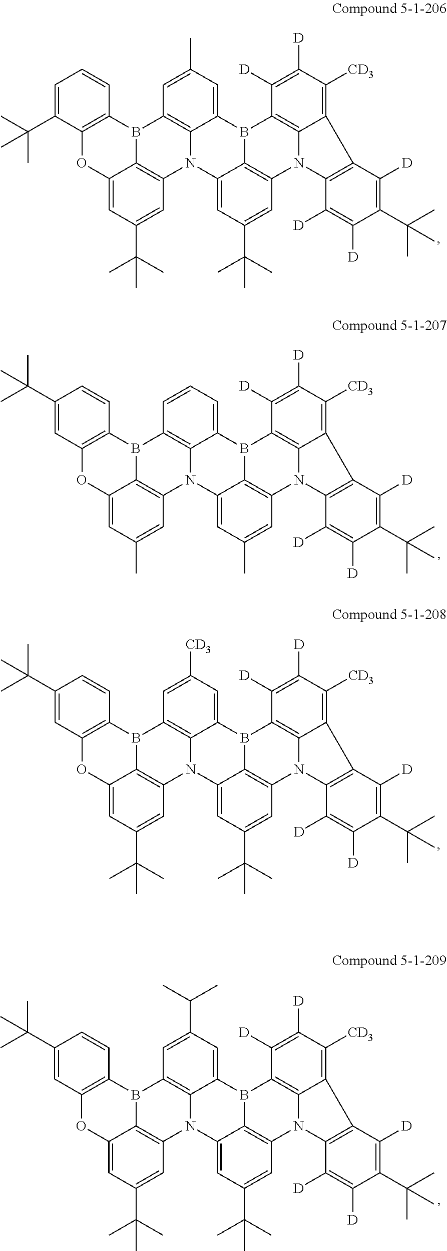 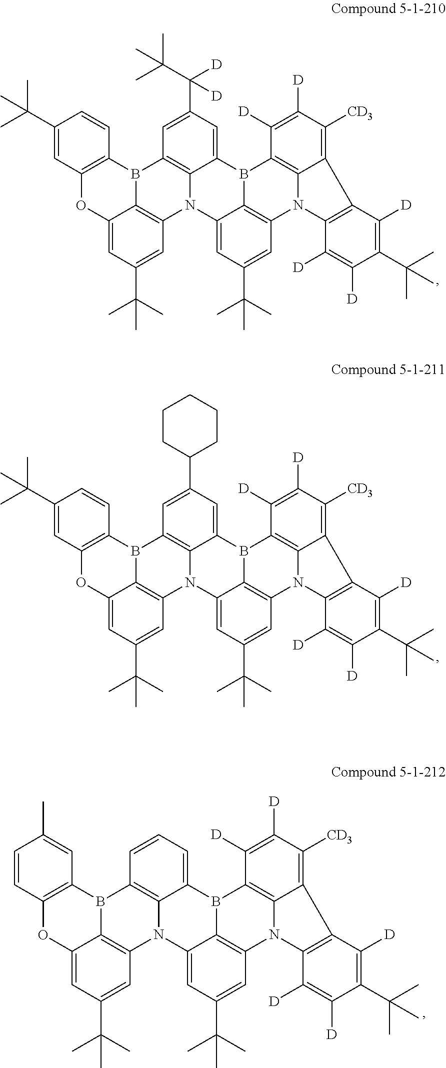 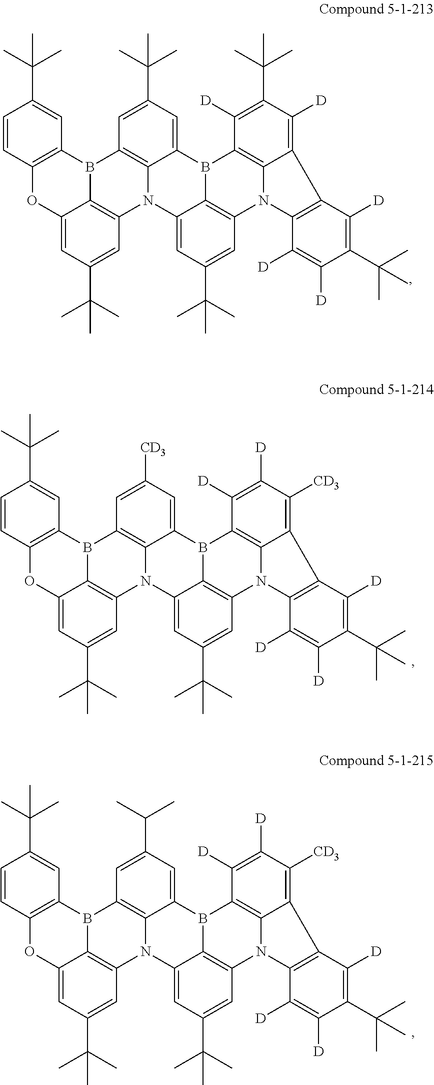 [SMILES: [2H]c1c(C(C)(C)C)c([2H])c2c3c([2H])c(C(C)(C)C)c([2H])c4c3n(c2c1[2H])-c1cc(C(C)(C)C)cc2c1B4c1cc(C(C)(C)C)cc3c1N2c1cc(C(C)(C)C)cc2c1B3c1cc(C(C)(C)C)ccc1O2 ; [2H]c1c([2H])c2c3c(c1C([2H])([2H])[2H])c1c([2H])c(C(C)(C)C)c([2H])c([2H])c1n3-c1cc(C(C)(C)C)cc3c1B2c1cc(C([2H])([2H])[2H])cc2c1N3c1cc(C(C)(C)C)cc3c1B2c1cc(C(C)(C)C)ccc1O3 ; [2H]c1c([2H])c2c3c(c1C([2H])([2H])[2H])c1c([2H])c(C(C)(C)C)c([2H])c([2H])c1n3-c1cc(C(C)(C)C)cc3c1B2c1cc(C(C)C)cc2c1N3c1cc(C(C)(C)C)cc3c1B2c1cc(C(C)(C)C)ccc1O3] 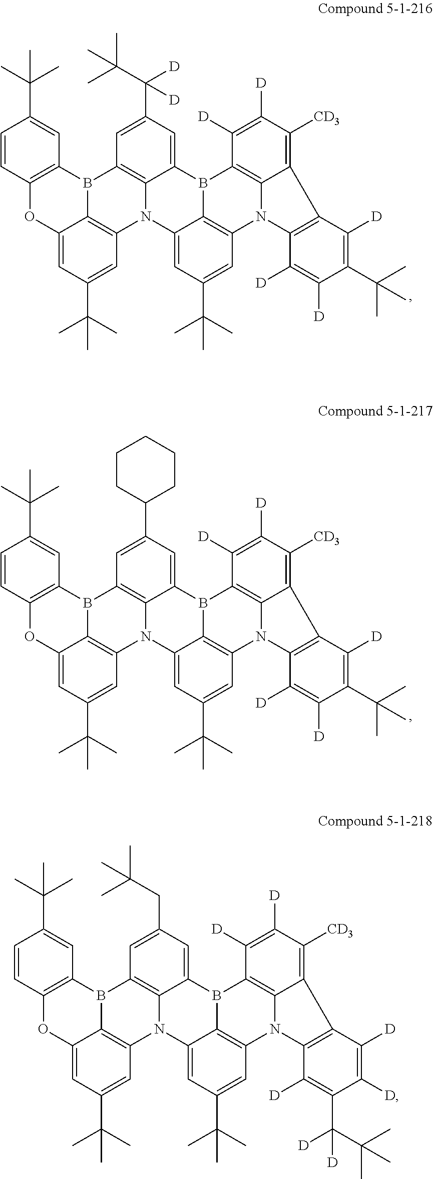 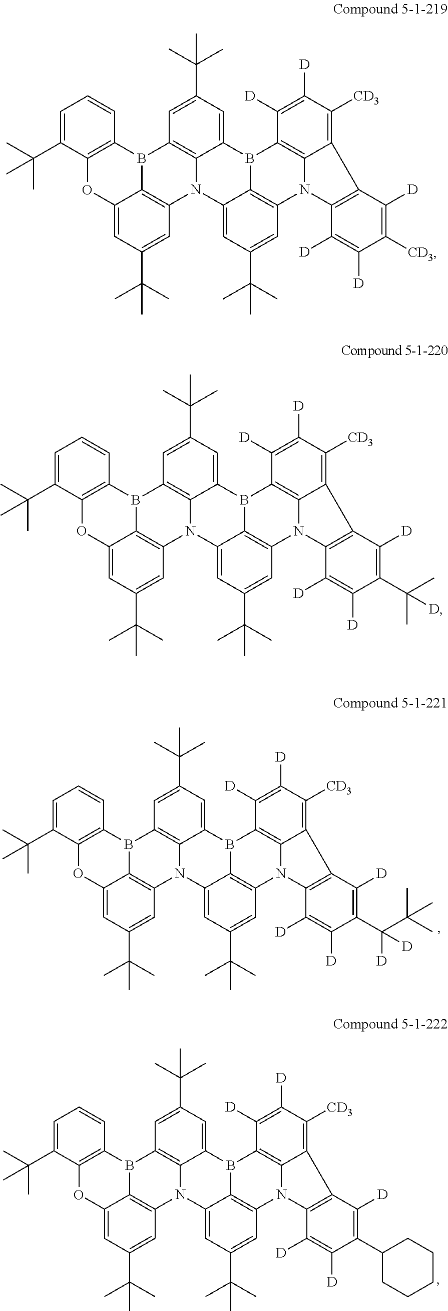 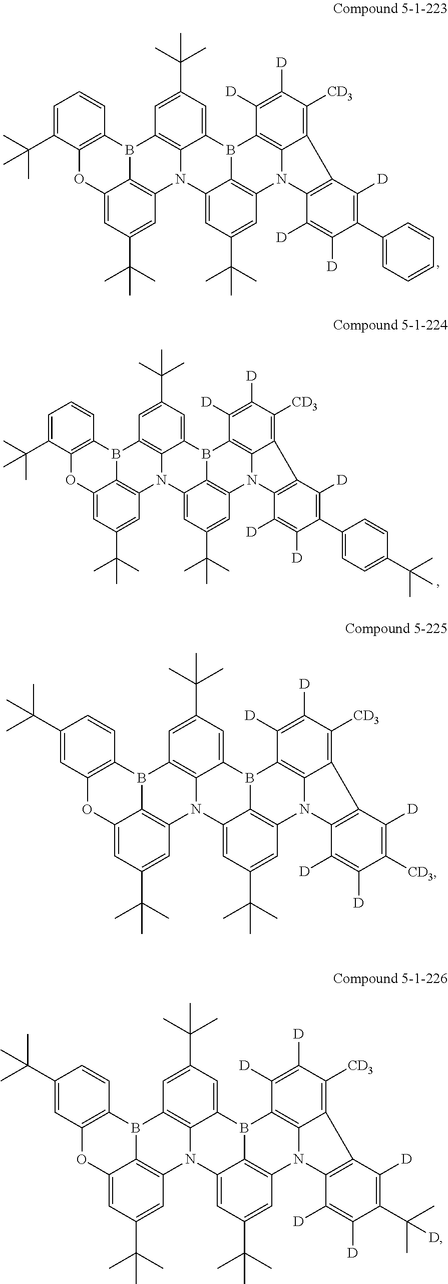 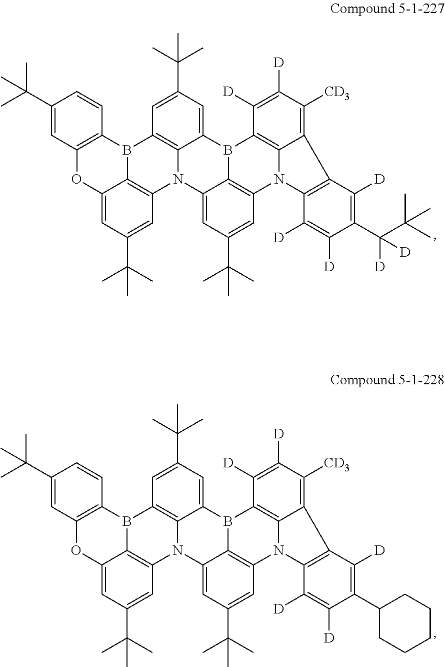 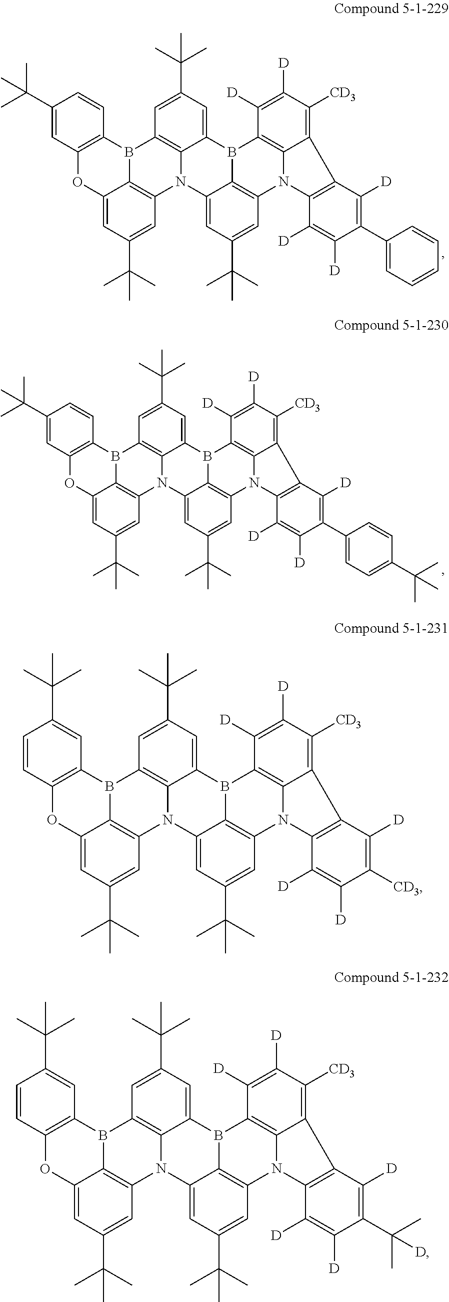 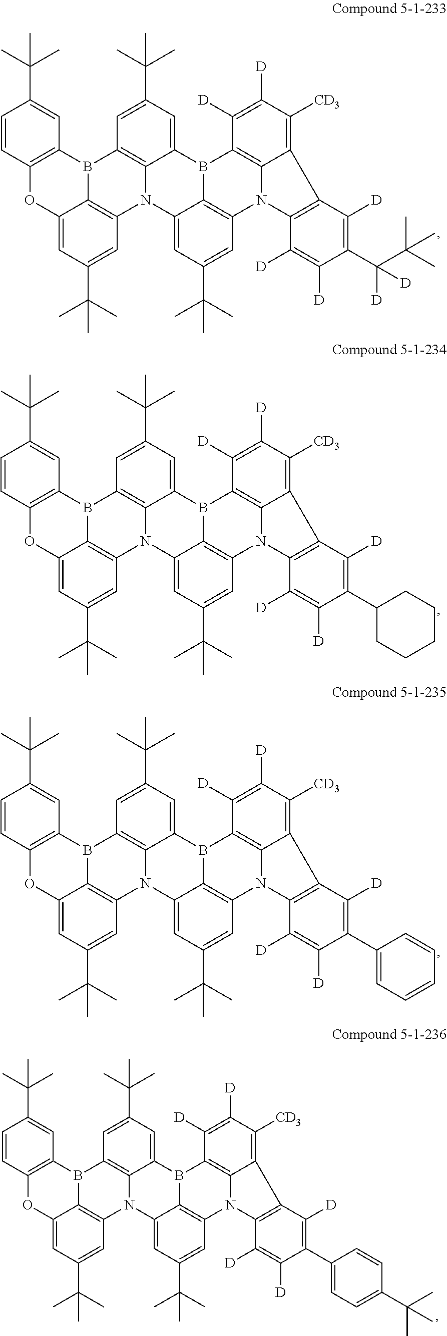 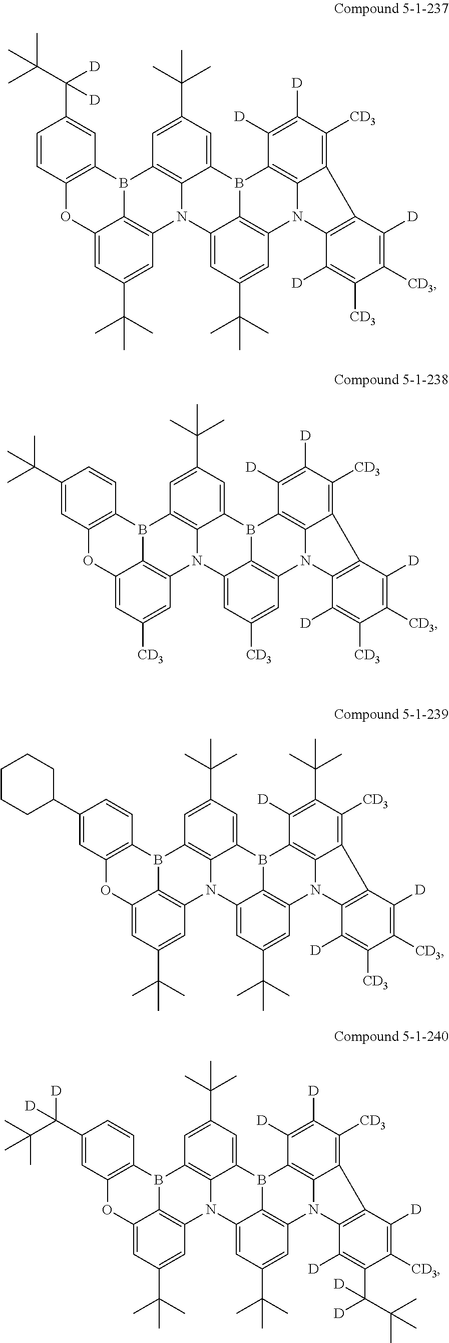 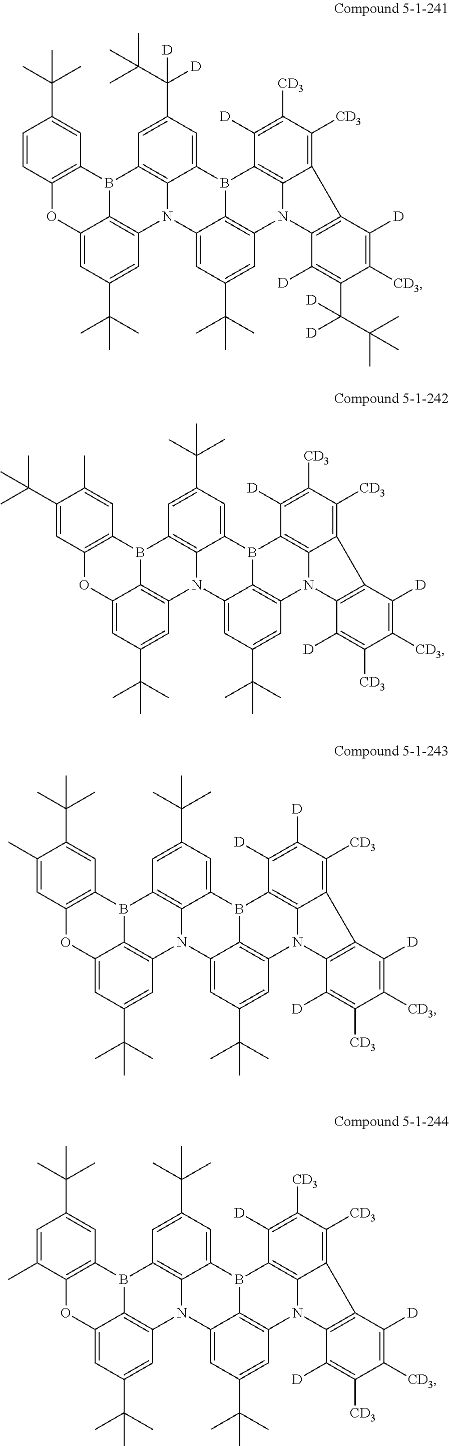 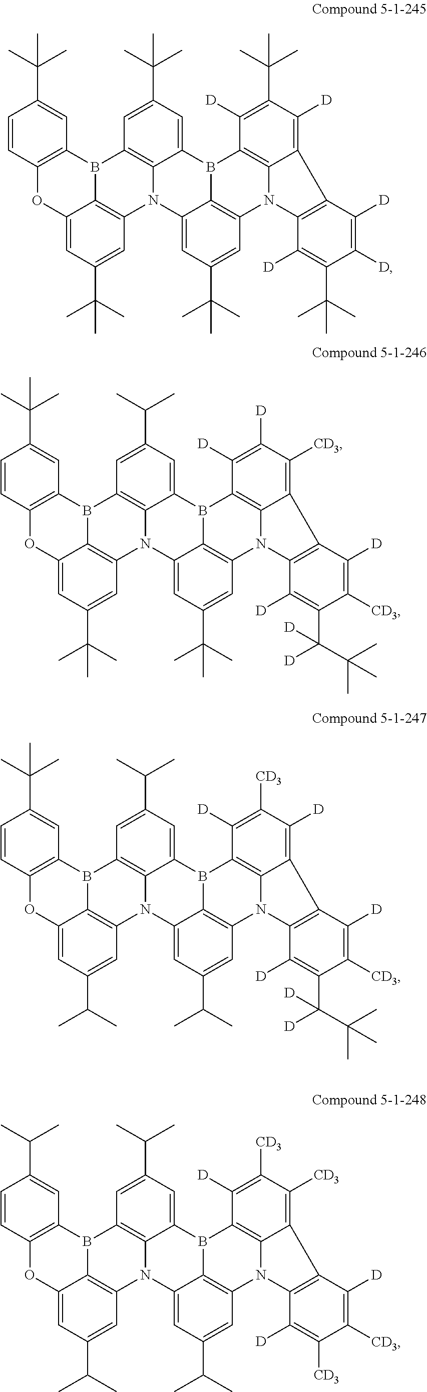 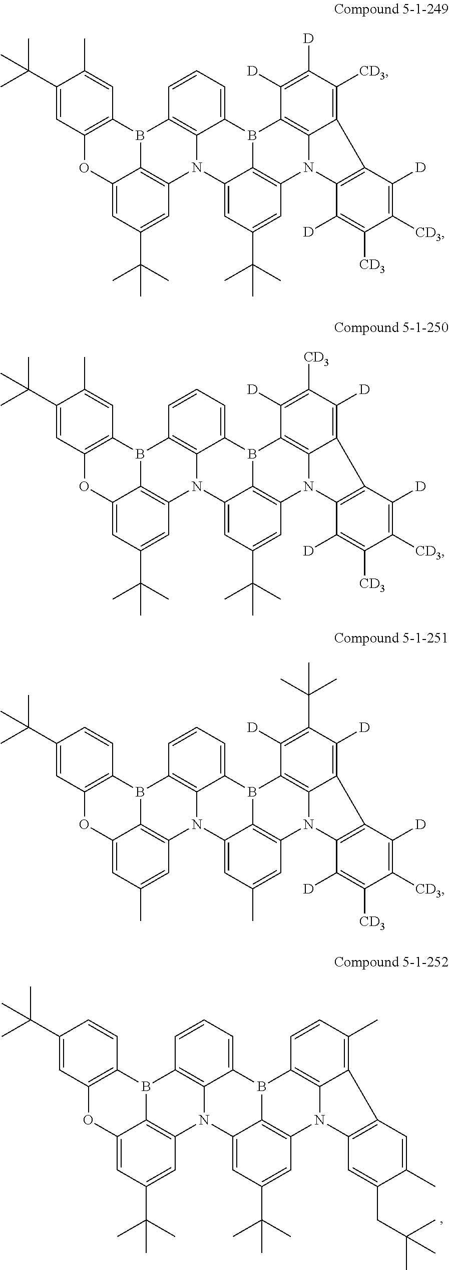 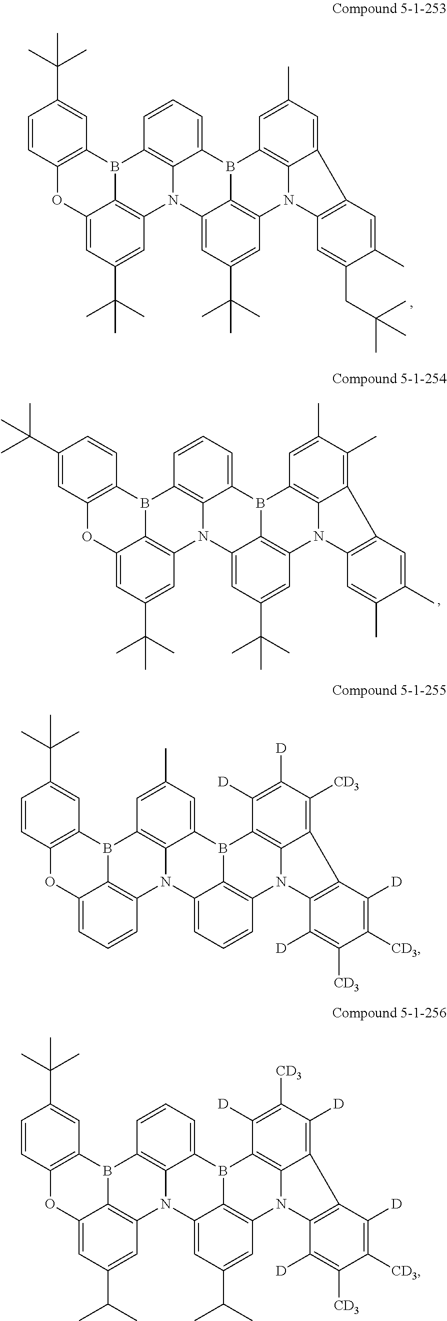 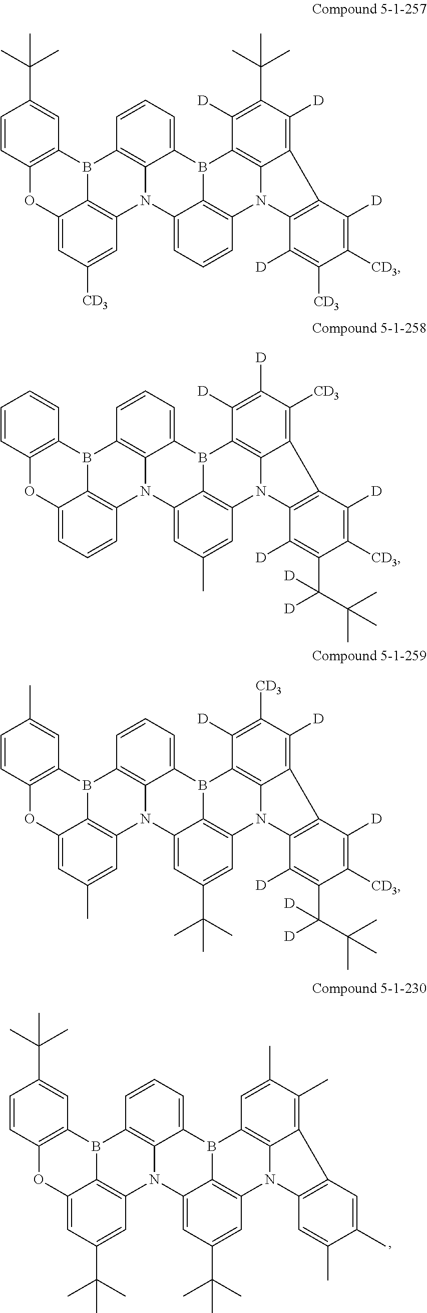 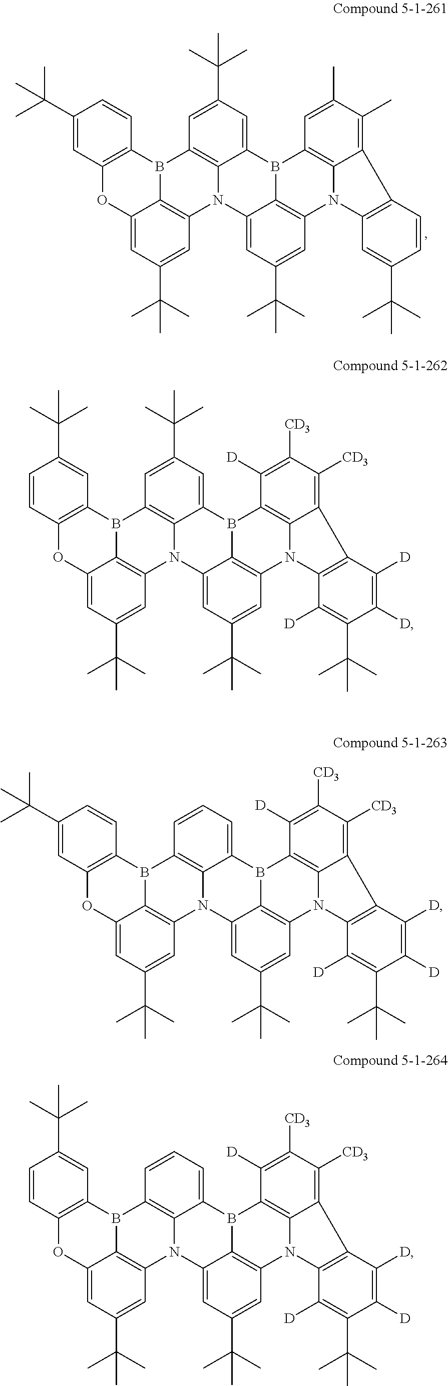 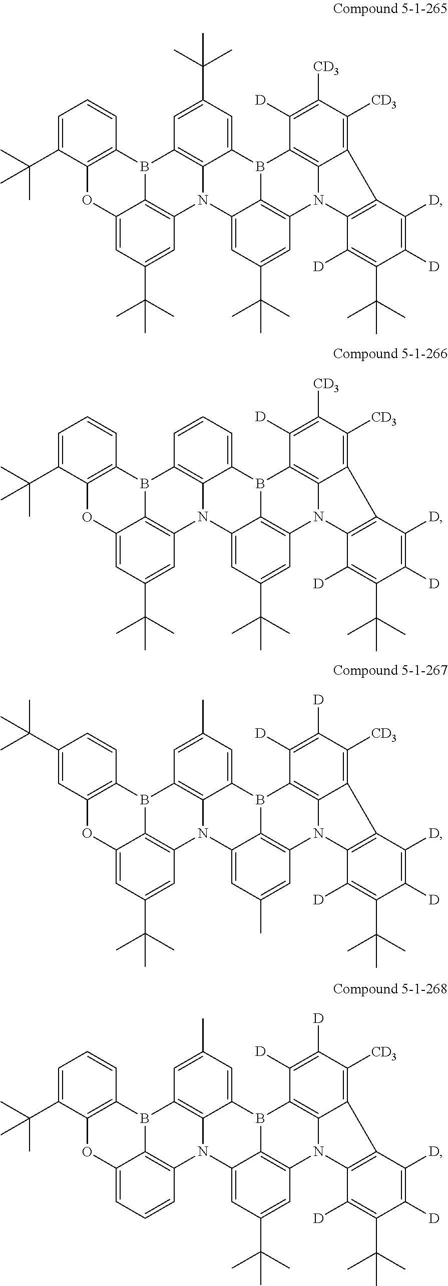 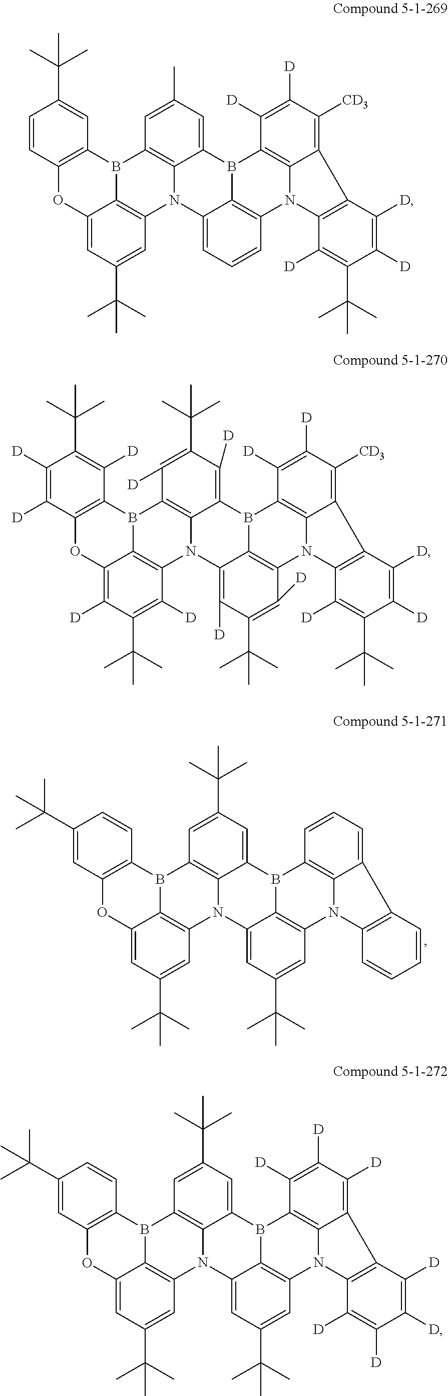 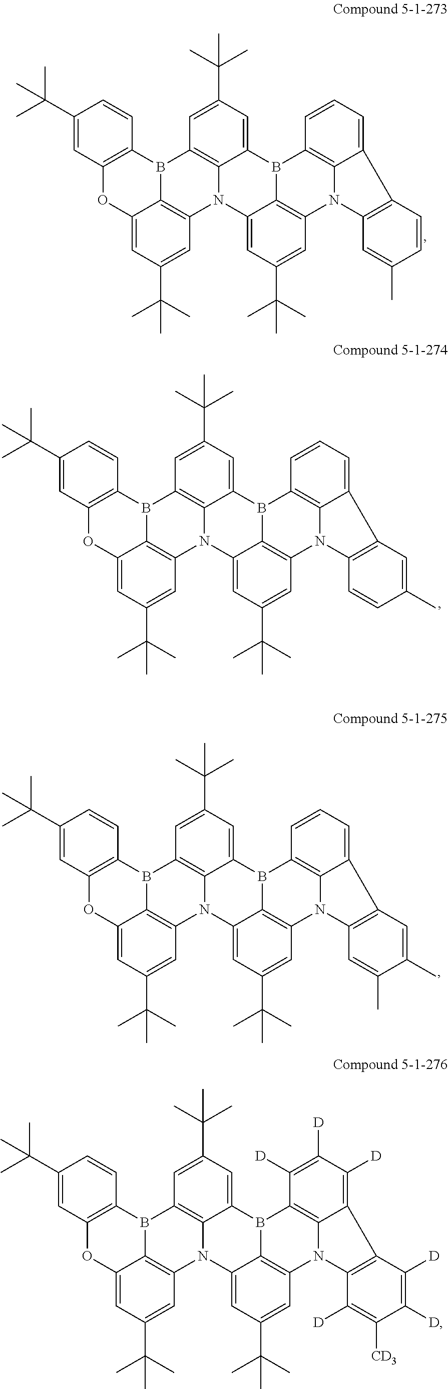 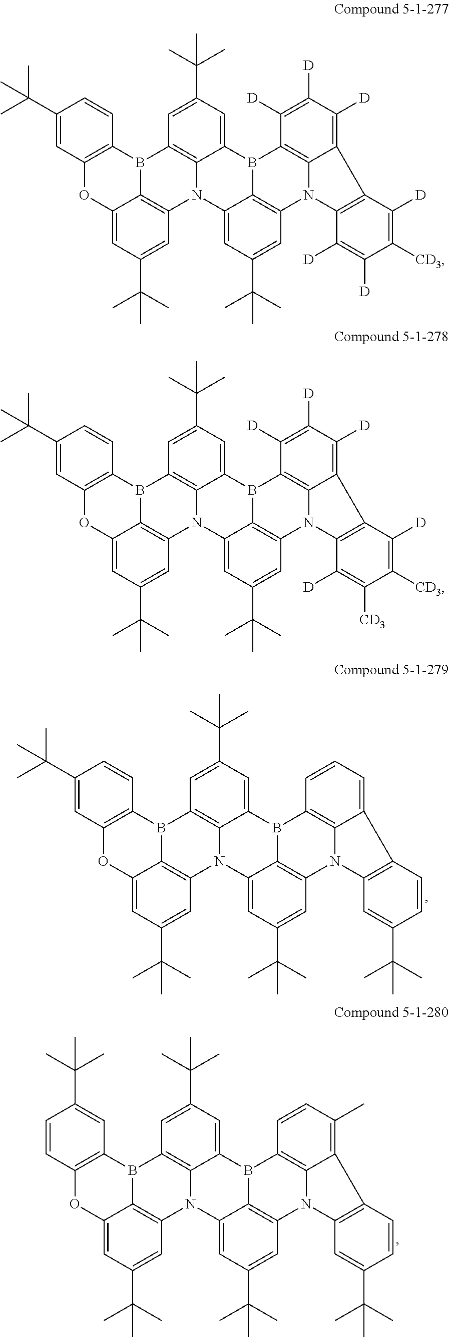 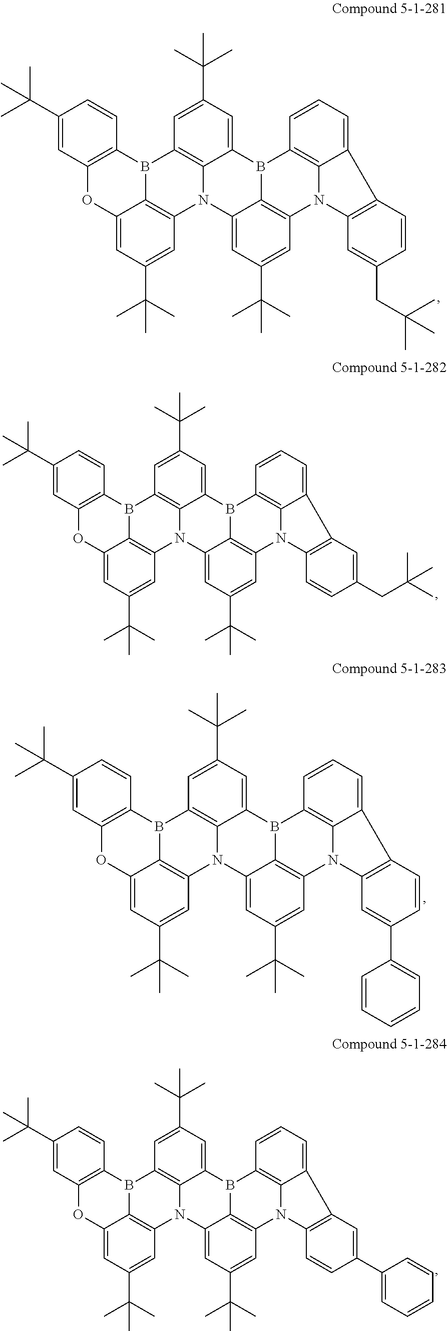 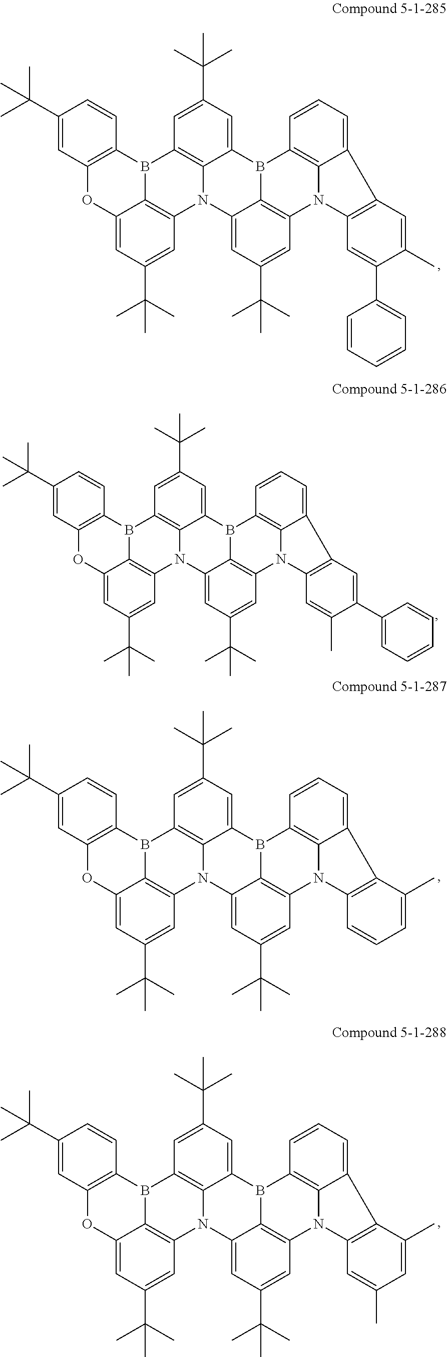 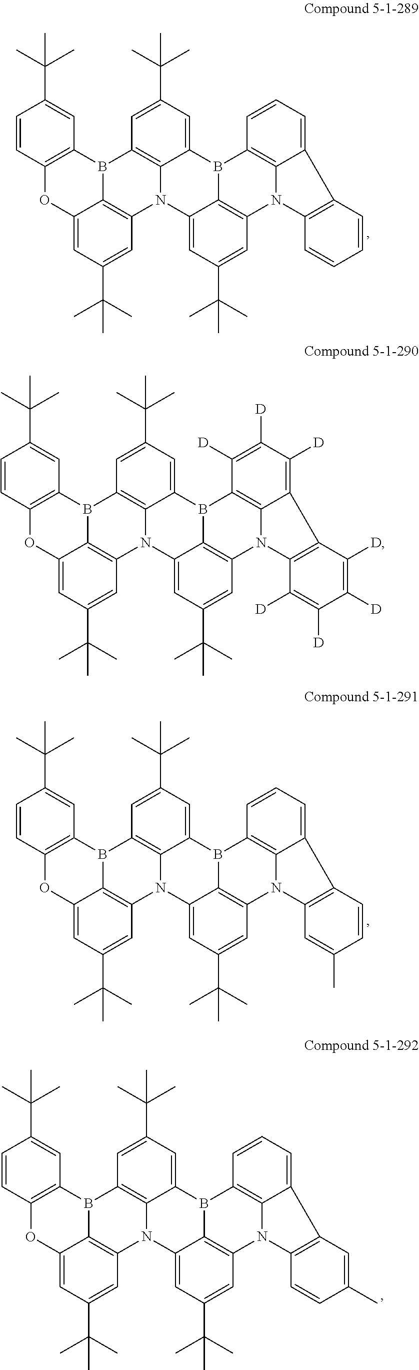 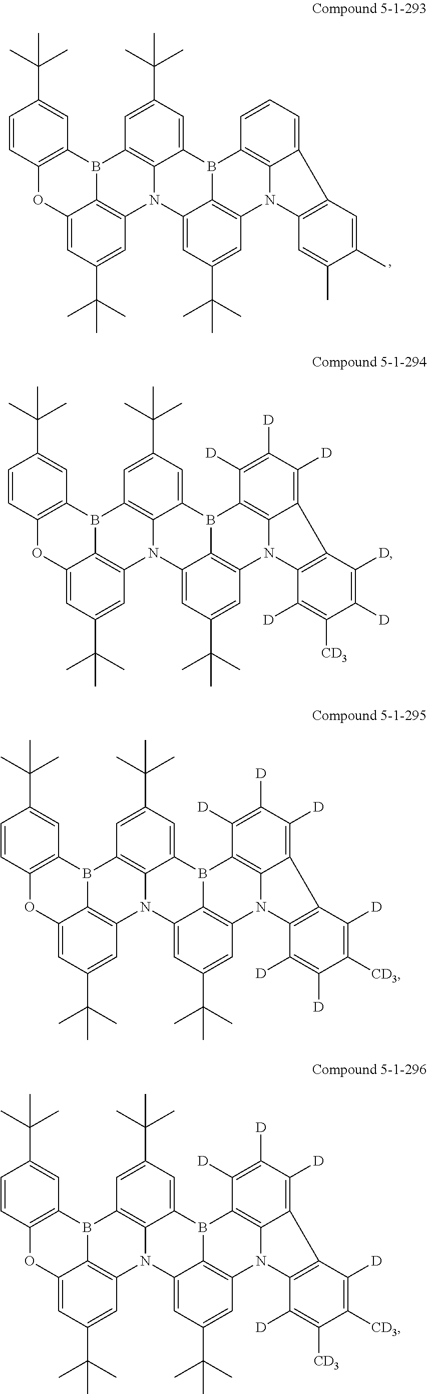 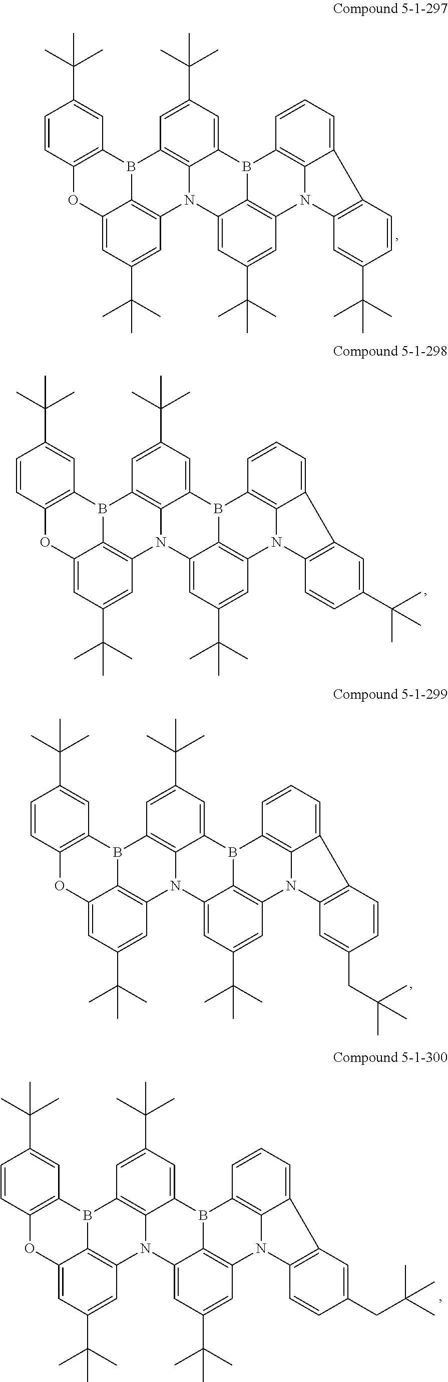 [SMILES: CC(C)(C)c1ccc2c(c1)B1c3cc(C(C)(C)C)cc4c3N(c3cc(C(C)(C)C)cc(c31)O2)c1cc(C(C)(C)C)cc2c1B4c1cccc3c4ccc(C(C)(C)C)cc4n-2c13 ; CC(C)(C)c1ccc2c(c1)B1c3cc(C(C)(C)C)cc4c3N(c3cc(C(C)(C)C)cc(c31)O2)c1cc(C(C)(C)C)cc2c1B4c1cccc3c4cc(C(C)(C)C)ccc4n-2c13 ; CC(C)(C)Cc1ccc2c3cccc4c3n(c2c1)-c1cc(C(C)(C)C)cc2c1B4c1cc(C(C)(C)C)cc3c1N2c1cc(C(C)(C)C)cc2c1B3c1cc(C(C)(C)C)ccc1O2 ; CC(C)(C)Cc1ccc2c(c1)c1cccc3c1n2-c1cc(C(C)(C)C)cc2c1B3c1cc(C(C)(C)C)cc3c1N2c1cc(C(C)(C)C)cc2c1B3c1cc(C(C)(C)C)ccc1O2] 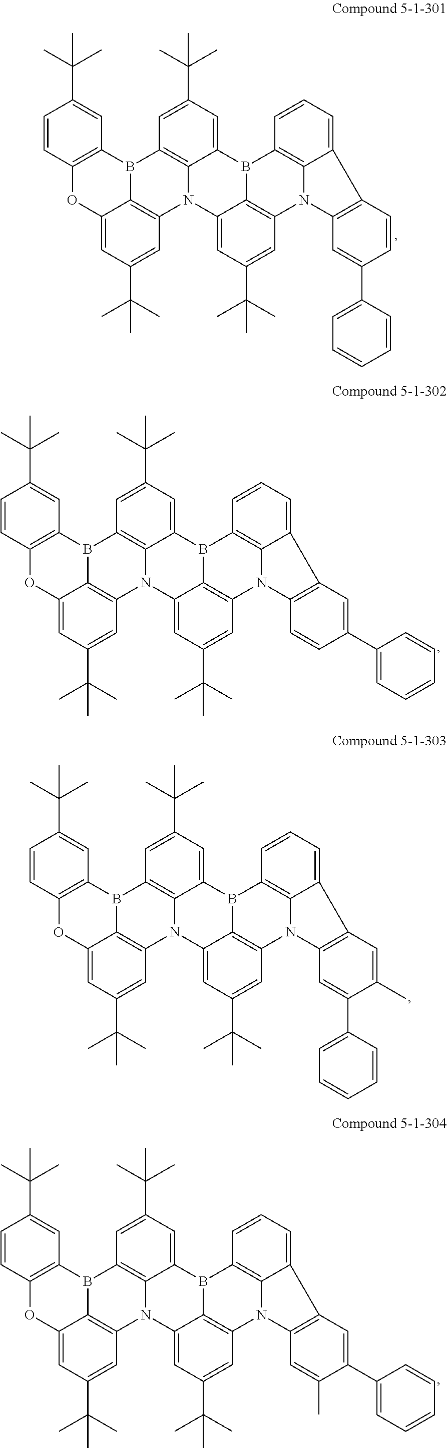 [SMILES: CC(C)(C)c1ccc2c(c1)B1c3cc(C(C)(C)C)cc4c3N(c3cc(C(C)(C)C)cc(c31)O2)c1cc(C(C)(C)C)cc2c1B4c1cccc3c4ccc(-c5ccccc5)cc4n-2c13 ; CC(C)(C)c1ccc2c(c1)B1c3cc(C(C)(C)C)cc4c3N(c3cc(C(C)(C)C)cc(c31)O2)c1cc(C(C)(C)C)cc2c1B4c1cccc3c4cc(-c5ccccc5)ccc4n-2c13 ; Cc1cc2c3cccc4c3n(c2cc1-c1ccccc1)-c1cc(C(C)(C)C)cc2c1B4c1cc(C(C)(C)C)cc3c1N2c1cc(C(C)(C)C)cc2c1B3c1cc(C(C)(C)C)ccc1O2 ; Cc1cc2c(cc1-c1ccccc1)c1cccc3c1n2-c1cc(C(C)(C)C)cc2c1B3c1cc(C(C)(C)C)cc3c1N2c1cc(C(C)(C)C)cc2c1B3c1cc(C(C)(C)C)ccc1O2] 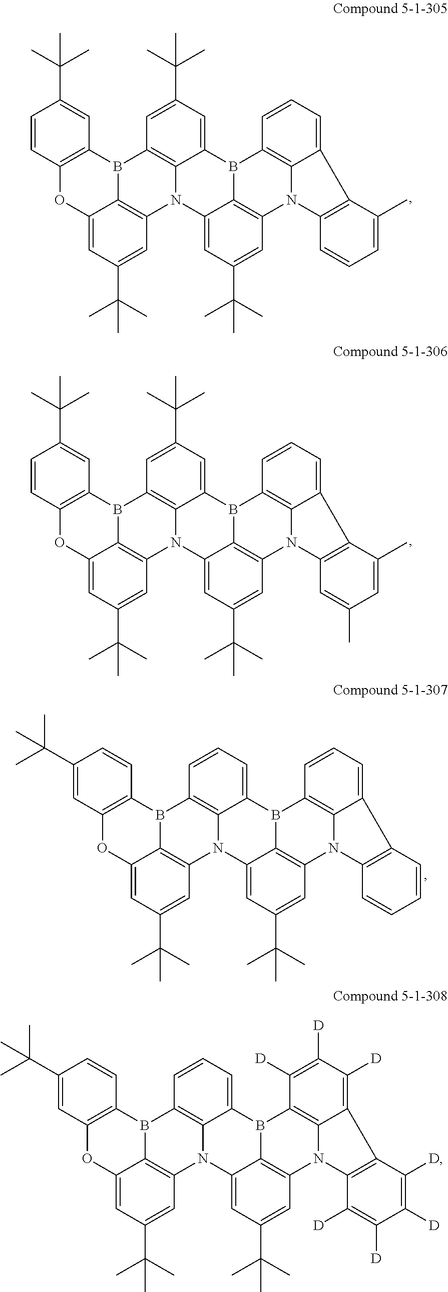 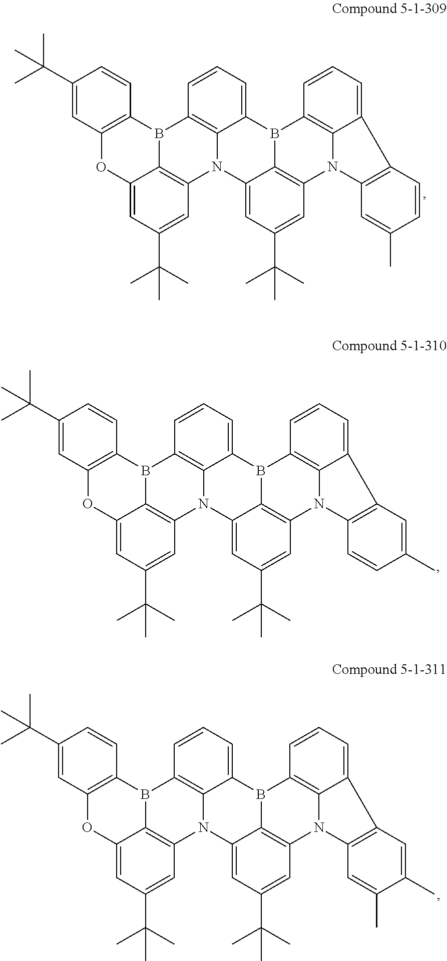 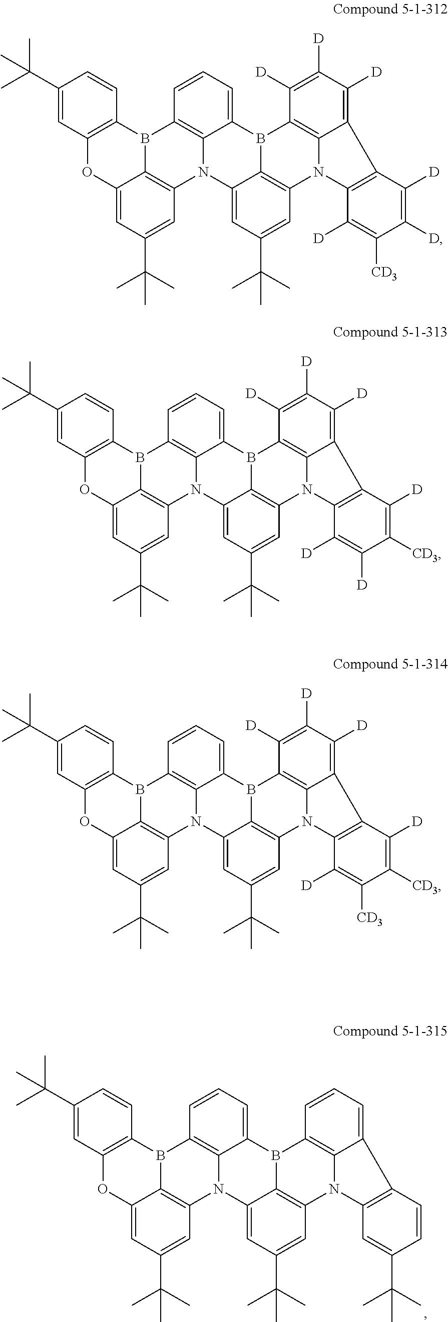 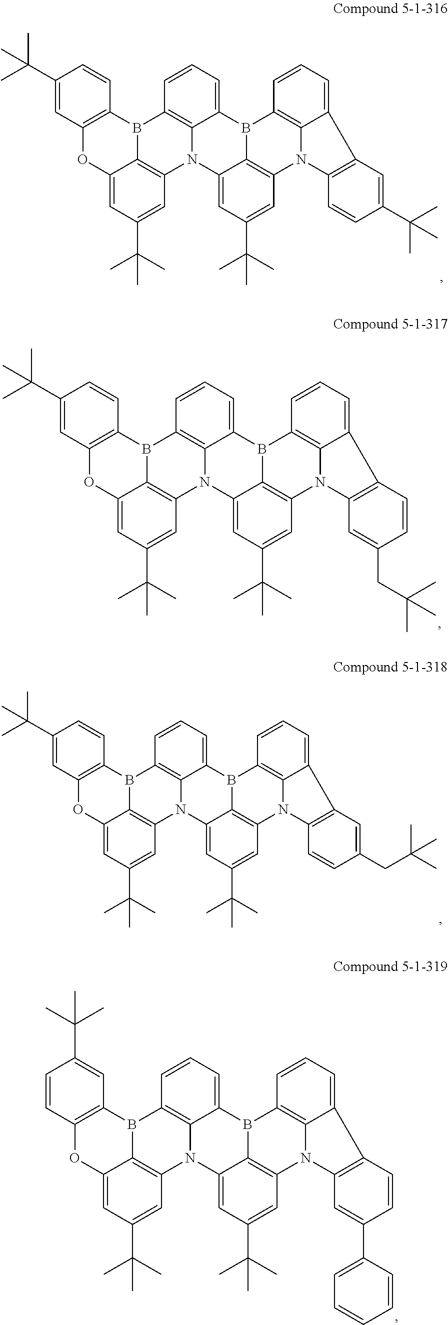 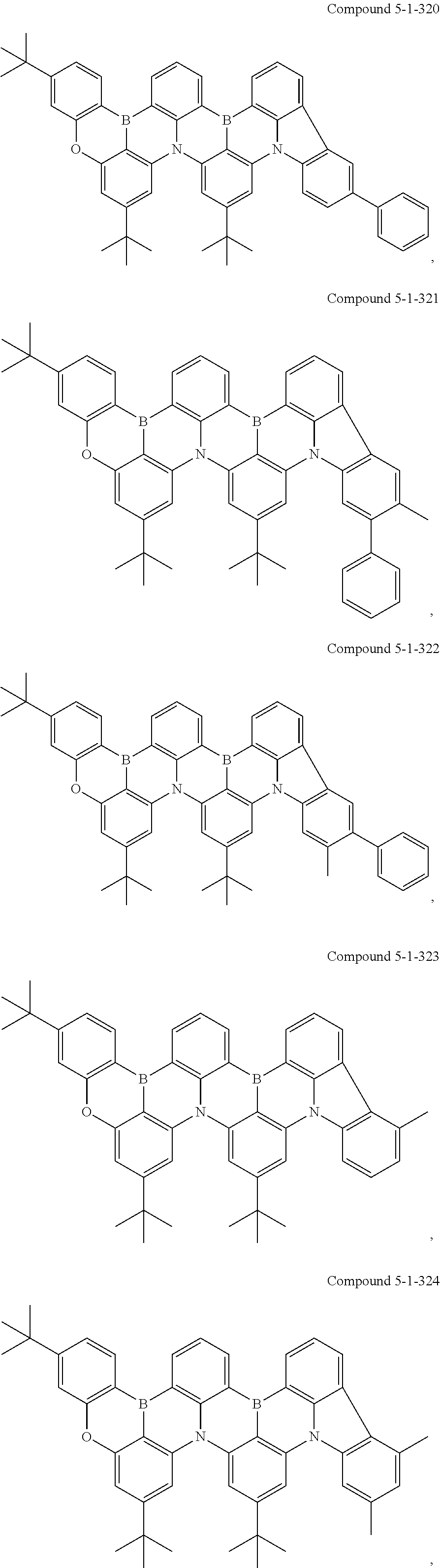 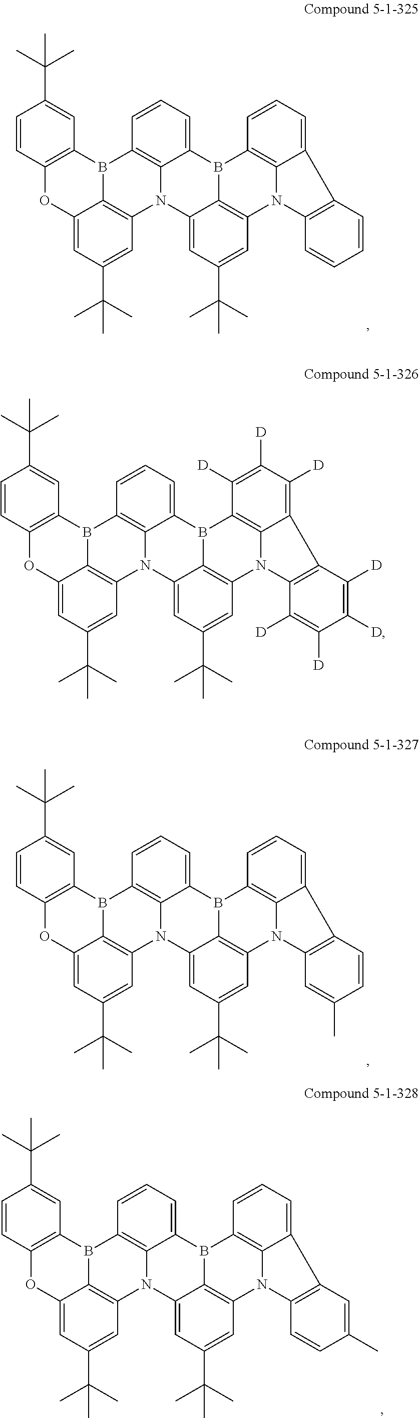 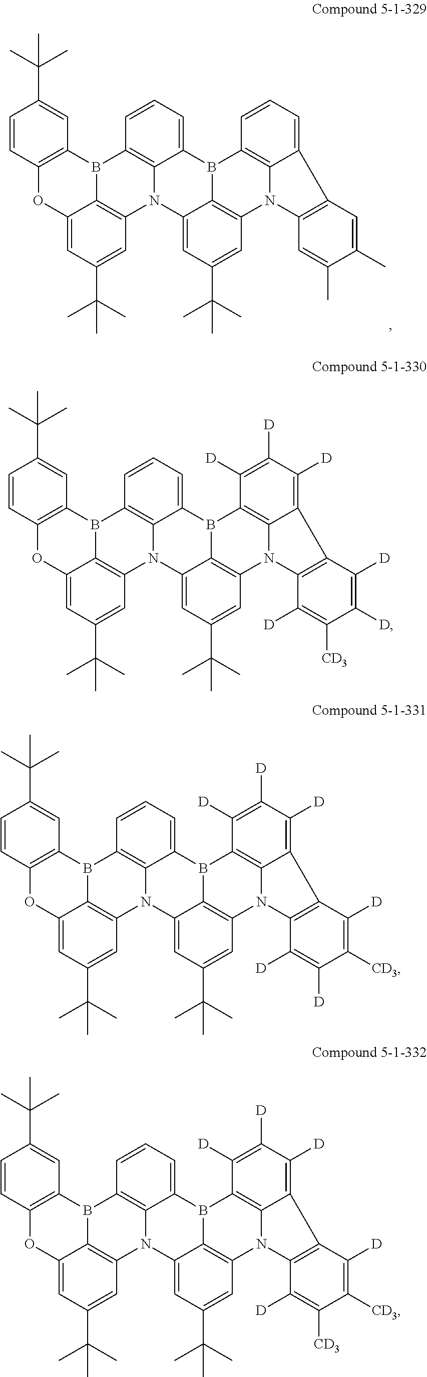 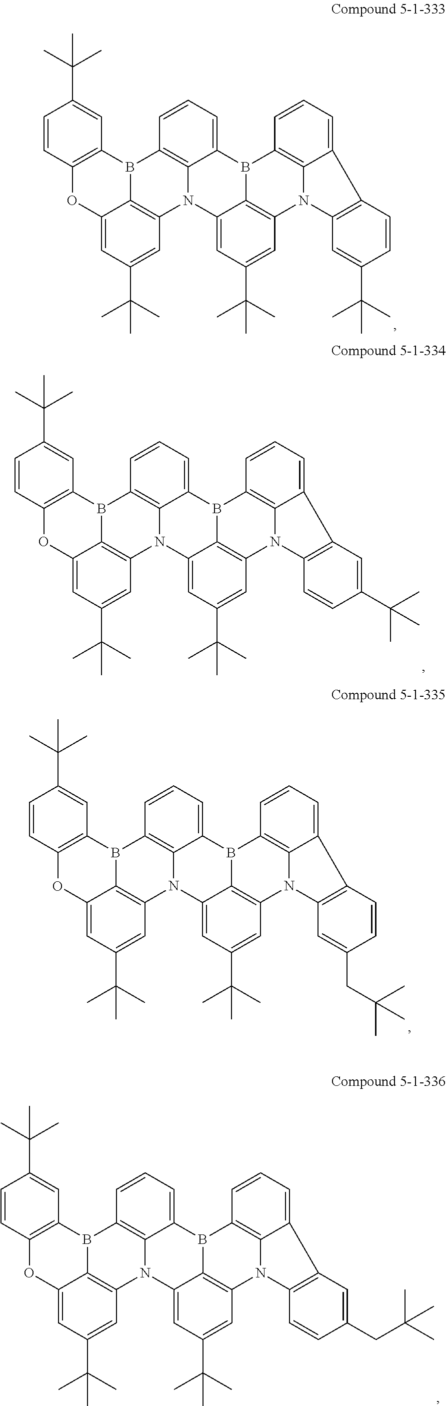 [SMILES: CC(C)(C)c1ccc2c(c1)B1c3cccc4c3N(c3cc(C(C)(C)C)cc(c31)O2)c1cc(C(C)(C)C)cc2c1B4c1cccc3c4ccc(C(C)(C)C)cc4n-2c13 ; CC(C)(C)c1ccc2c(c1)B1c3cccc4c3N(c3cc(C(C)(C)C)cc(c31)O2)c1cc(C(C)(C)C)cc2c1B4c1cccc3c4cc(C(C)(C)C)ccc4n-2c13 ; CC(C)(C)Cc1ccc2c3cccc4c3n(c2c1)-c1cc(C(C)(C)C)cc2c1B4c1cccc3c1N2c1cc(C(C)(C)C)cc2c1B3c1cc(C(C)(C)C)ccc1O2 ; CC(C)(C)Cc1ccc2c(c1)c1cccc3c1n2-c1cc(C(C)(C)C)cc2c1B3c1cccc3c1N2c1cc(C(C)(C)C)cc2c1B3c1cc(C(C)(C)C)ccc1O2] 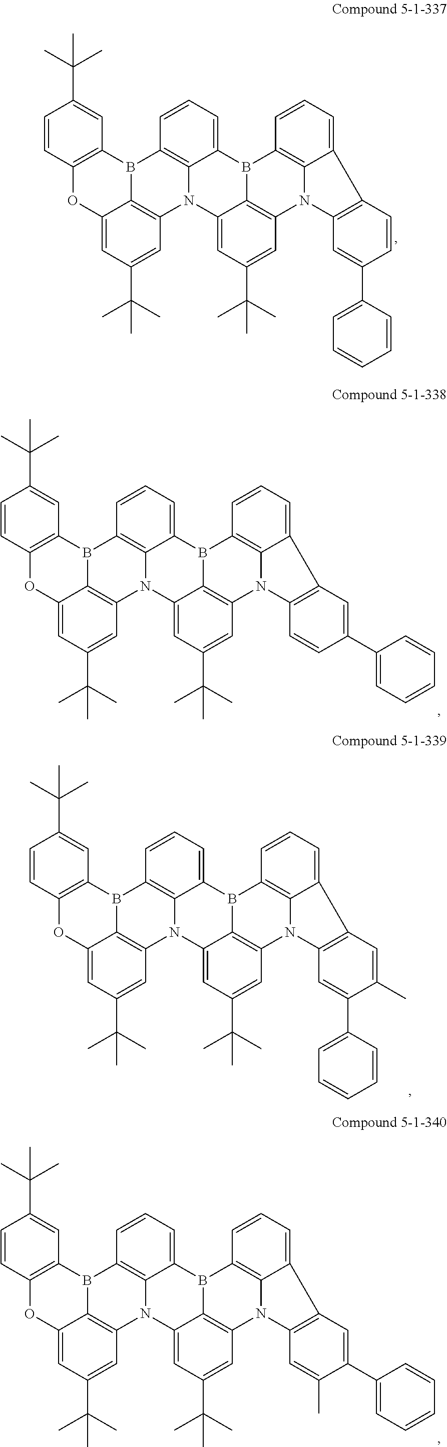 [SMILES: CC(C)(C)c1ccc2c(c1)B1c3cccc4c3N(c3cc(C(C)(C)C)cc(c31)O2)c1cc(C(C)(C)C)cc2c1B4c1cccc3c4ccc(-c5ccccc5)cc4n-2c13 ; CC(C)(C)c1ccc2c(c1)B1c3cccc4c3N(c3cc(C(C)(C)C)cc(c31)O2)c1cc(C(C)(C)C)cc2c1B4c1cccc3c4cc(-c5ccccc5)ccc4n-2c13 ; Cc1cc2c3cccc4c3n(c2cc1-c1ccccc1)-c1cc(C(C)(C)C)cc2c1B4c1cccc3c1N2c1cc(C(C)(C)C)cc2c1B3c1cc(C(C)(C)C)ccc1O2 ; Cc1cc2c(cc1-c1ccccc1)c1cccc3c1n2-c1cc(C(C)(C)C)cc2c1B3c1cccc3c1N2c1cc(C(C)(C)C)cc2c1B3c1cc(C(C)(C)C)ccc1O2] 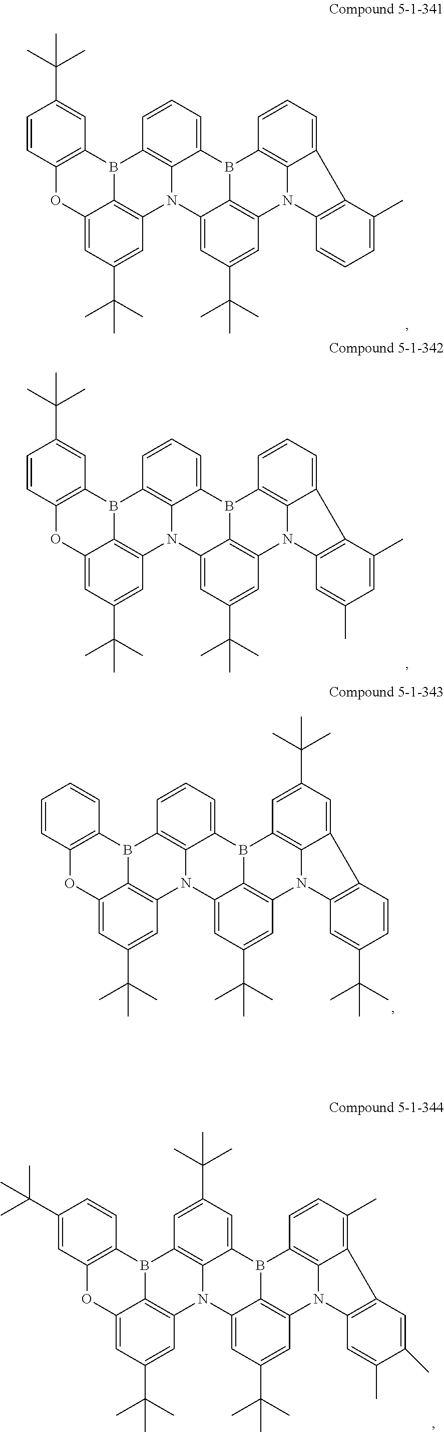 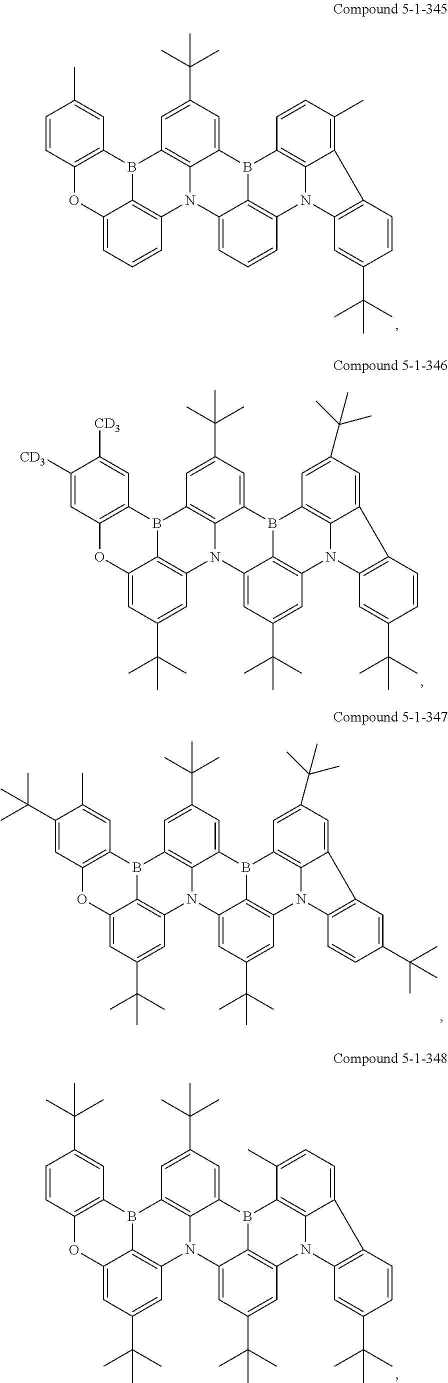 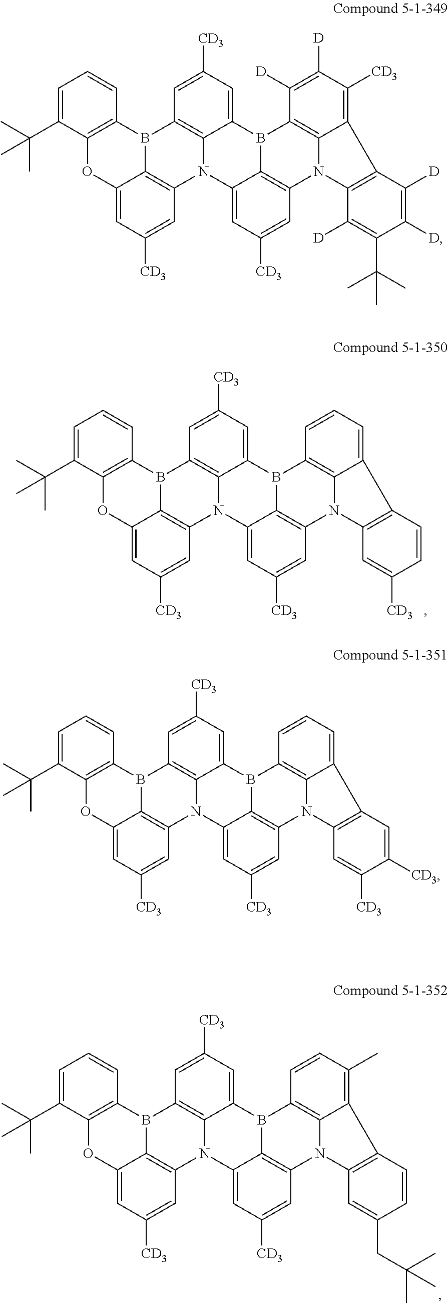 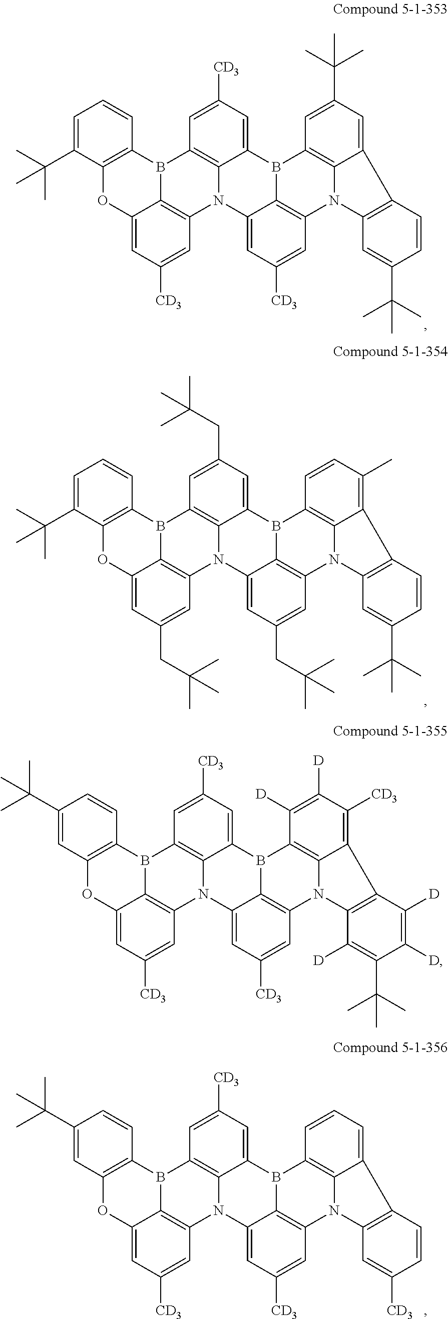 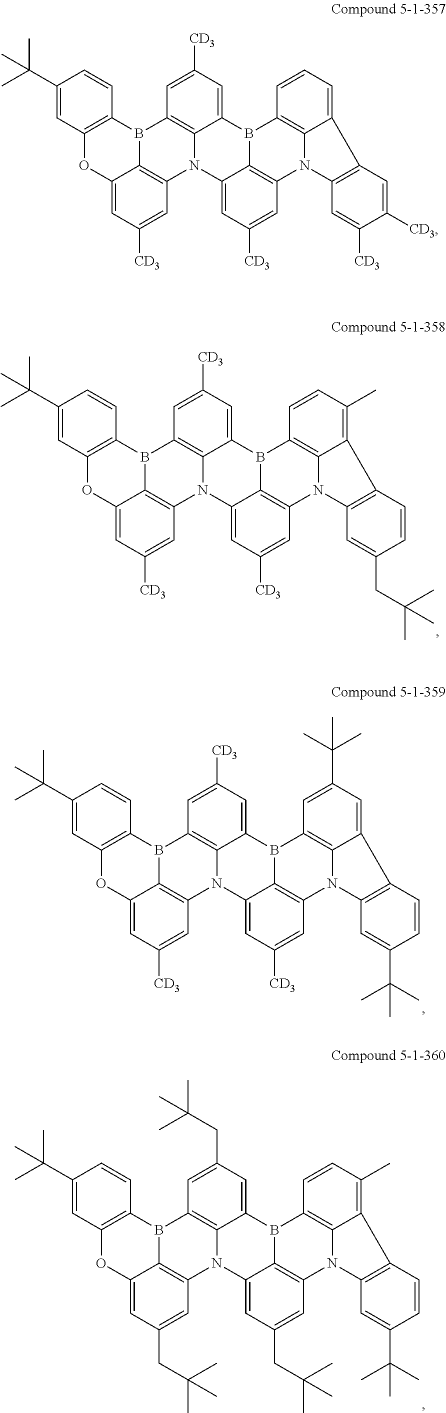 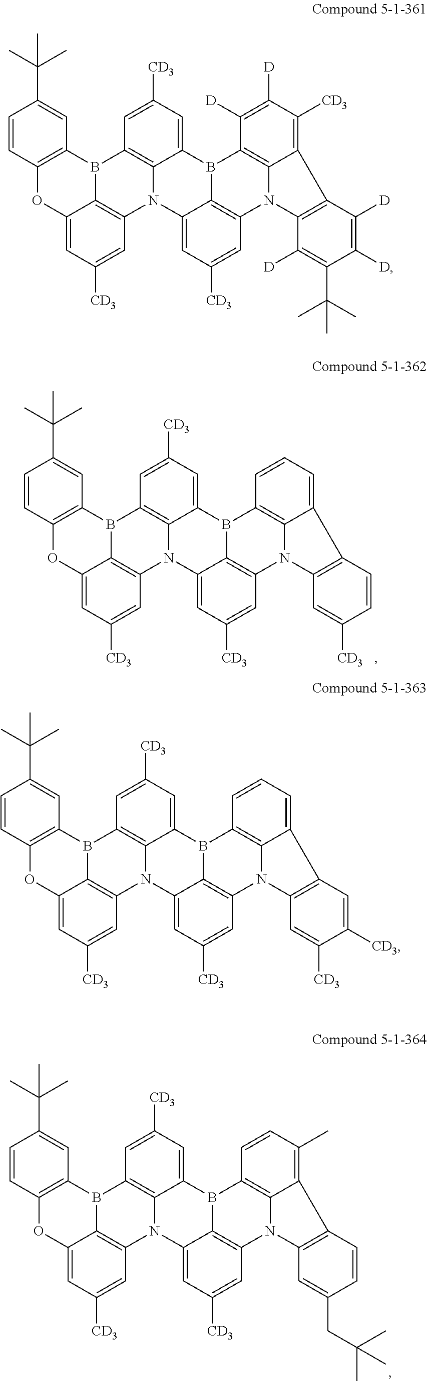 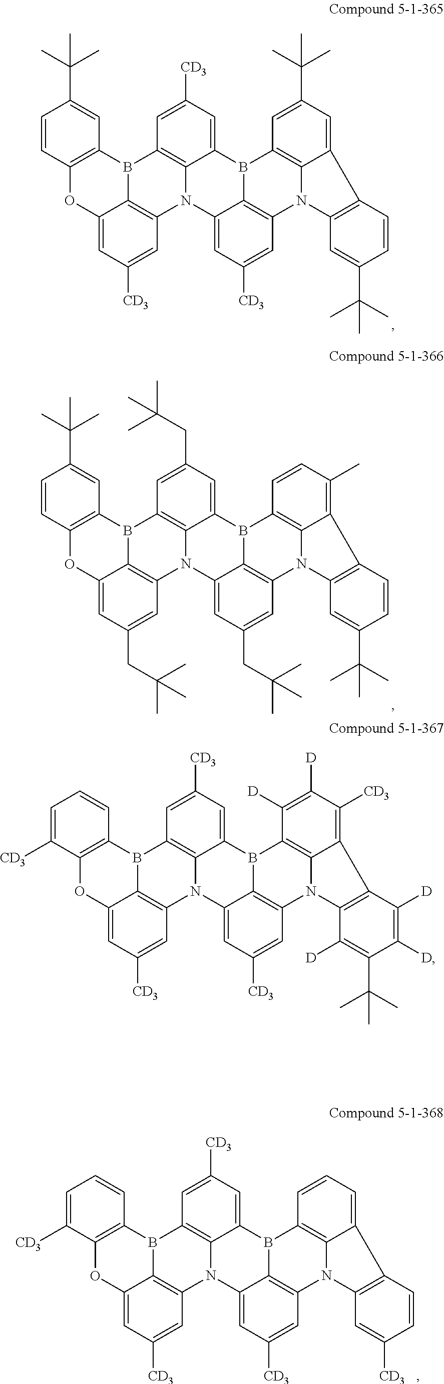 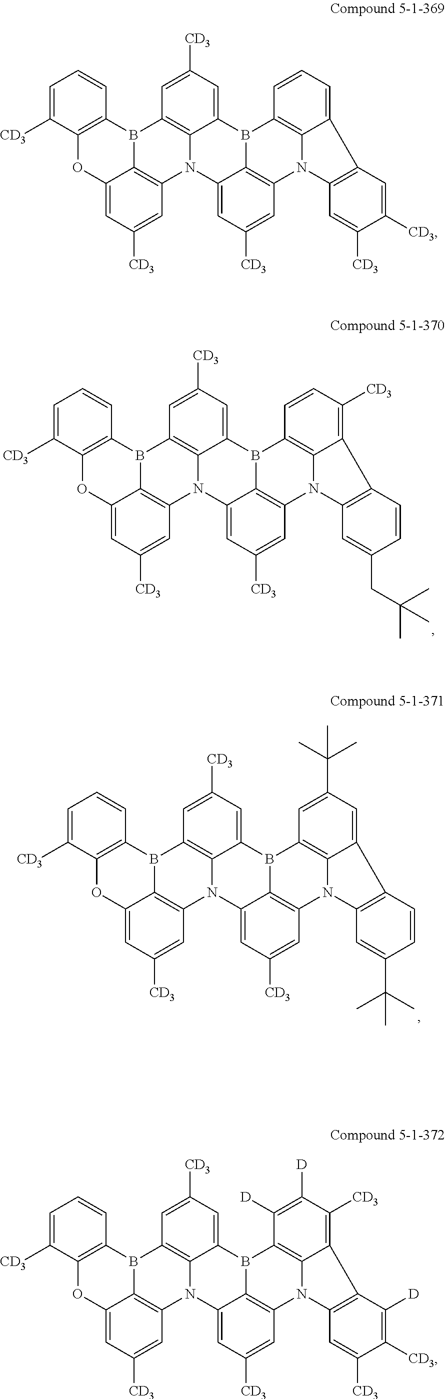 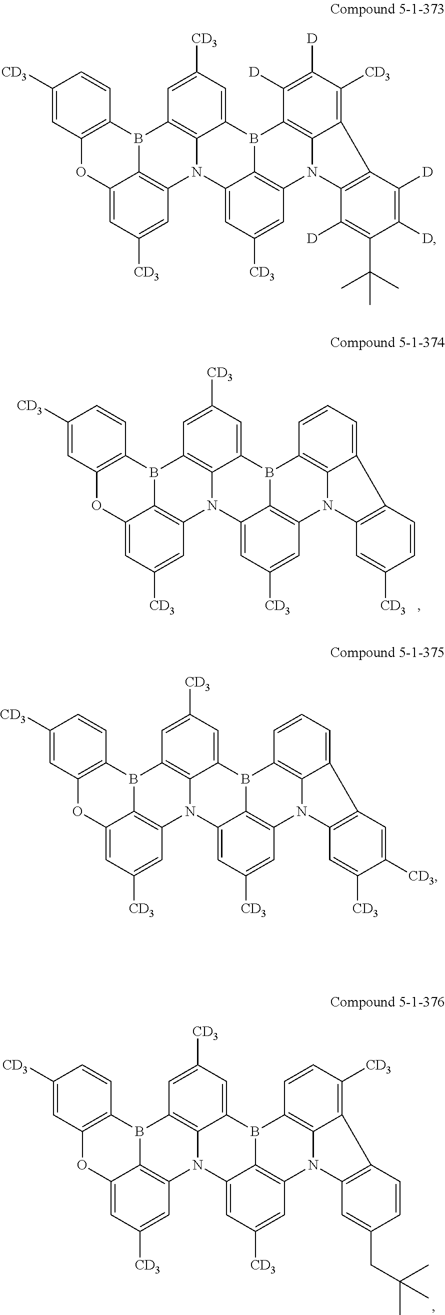 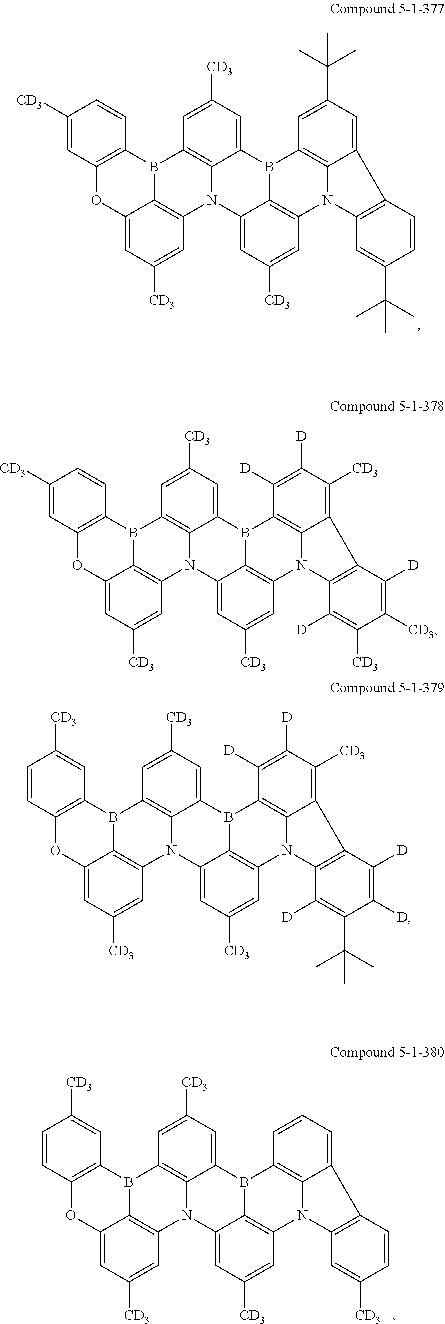 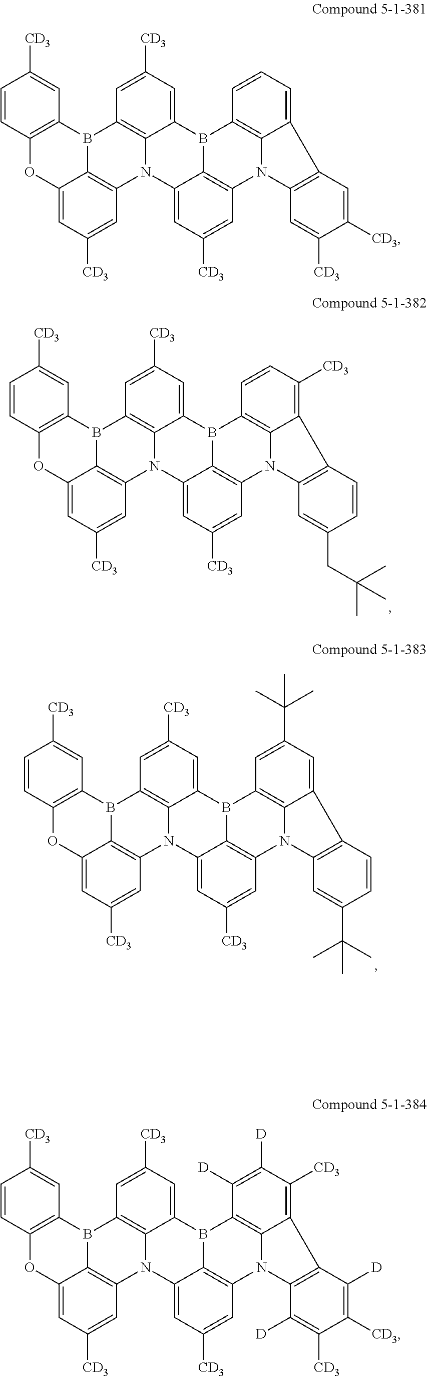 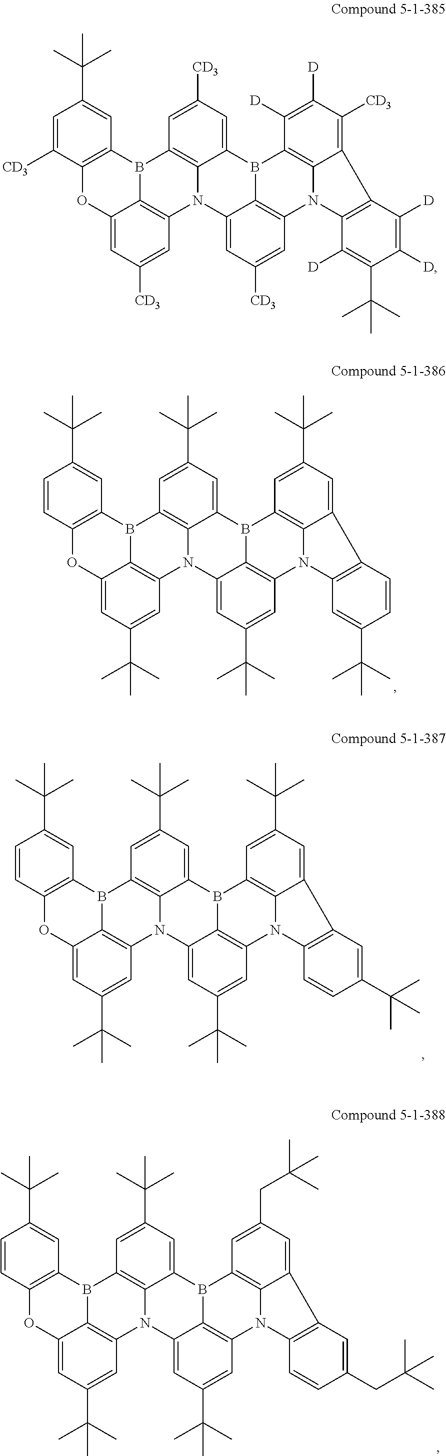 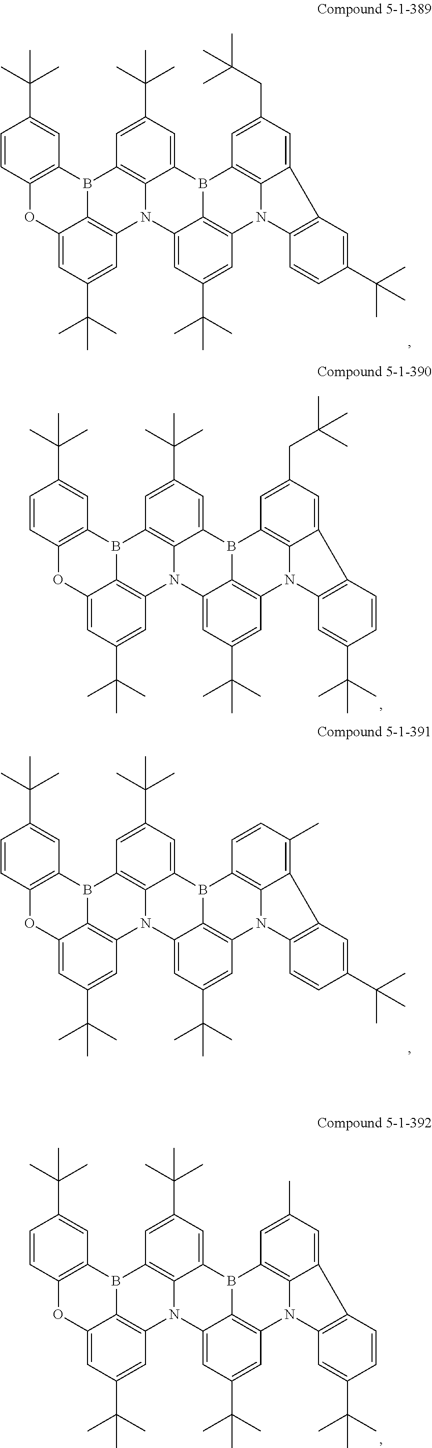 [SMILES: CC(C)(C)Cc1cc2c3c(c1)c1cc(C(C)(C)C)ccc1n3-c1cc(C(C)(C)C)cc3c1B2c1cc(C(C)(C)C)cc2c1N3c1cc(C(C)(C)C)cc3c1B2c1cc(C(C)(C)C)ccc1O3 ; CC(C)(C)Cc1cc2c3c(c1)c1ccc(C(C)(C)C)cc1n3-c1cc(C(C)(C)C)cc3c1B2c1cc(C(C)(C)C)cc2c1N3c1cc(C(C)(C)C)cc3c1B2c1cc(C(C)(C)C)ccc1O3 ; Cc1ccc2c3c1c1cc(C(C)(C)C)ccc1n3-c1cc(C(C)(C)C)cc3c1B2c1cc(C(C)(C)C)cc2c1N3c1cc(C(C)(C)C)cc3c1B2c1cc(C(C)(C)C)ccc1O3 ; Cc1cc2c3c(c1)c1ccc(C(C)(C)C)cc1n3-c1cc(C(C)(C)C)cc3c1B2c1cc(C(C)(C)C)cc2c1N3c1cc(C(C)(C)C)cc3c1B2c1cc(C(C)(C)C)ccc1O3] 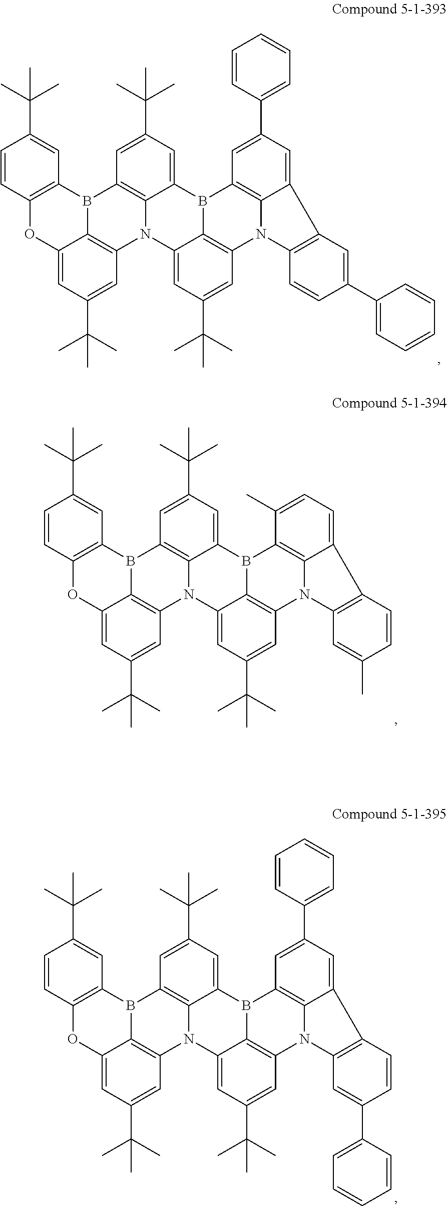 [SMILES: CC(C)(C)c1ccc2c(c1)B1c3cc(C(C)(C)C)cc4c3N(c3cc(C(C)(C)C)cc(c31)O2)c1cc(C(C)(C)C)cc2c1B4c1cc(-c3ccccc3)cc3c4cc(-c5ccccc5)ccc4n-2c13 ; Cc1ccc2c3ccc(C)c4c3n(c2c1)-c1cc(C(C)(C)C)cc2c1B4c1cc(C(C)(C)C)cc3c1N2c1cc(C(C)(C)C)cc2c1B3c1cc(C(C)(C)C)ccc1O2 ; CC(C)(C)c1ccc2c(c1)B1c3cc(C(C)(C)C)cc4c3N(c3cc(C(C)(C)C)cc(c31)O2)c1cc(C(C)(C)C)cc2c1B4c1cc(-c3ccccc3)cc3c4ccc(-c5ccccc5)cc4n-2c13] 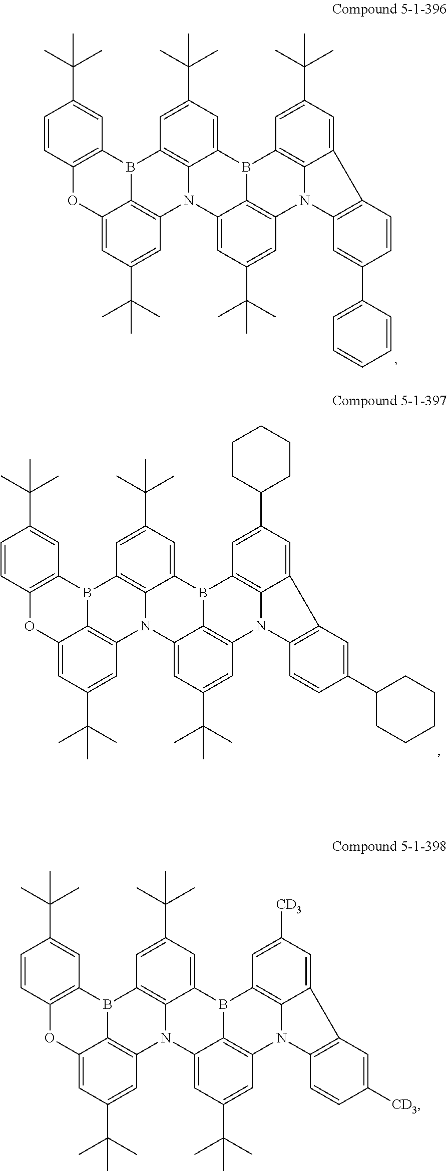 [SMILES: CC(C)(C)c1ccc2c(c1)B1c3cc(C(C)(C)C)cc4c3N(c3cc(C(C)(C)C)cc(c31)O2)c1cc(C(C)(C)C)cc2c1B4c1cc(C(C)(C)C)cc3c4ccc(-c5ccccc5)cc4n-2c13 ; CC(C)(C)c1ccc2c(c1)B1c3cc(C(C)(C)C)cc4c3N(c3cc(C(C)(C)C)cc(c31)O2)c1cc(C(C)(C)C)cc2c1B4c1cc(C3CCCCC3)cc3c4cc(C5CCCCC5)ccc4n-2c13 ; [2H]C([2H])([2H])c1ccc2c(c1)c1cc(C([2H])([2H])[2H])cc3c1n2-c1cc(C(C)(C)C)cc2c1B3c1cc(C(C)(C)C)cc3c1N2c1cc(C(C)(C)C)cc2c1B3c1cc(C(C)(C)C)ccc1O2] 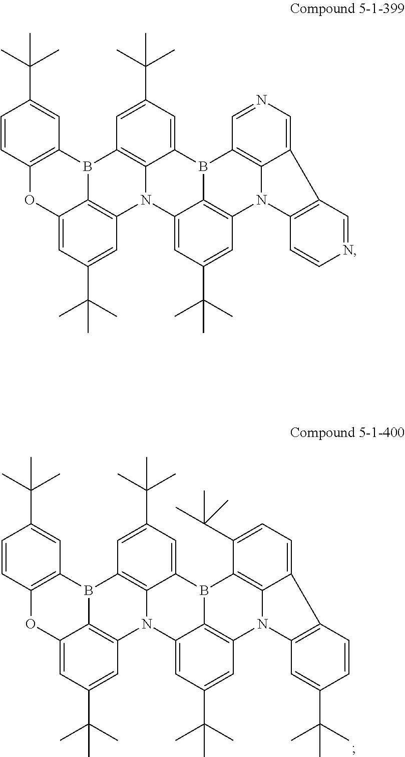 [SMILES: CC(C)(C)c1ccc2c(c1)B1c3cc(C(C)(C)C)cc4c3N(c3cc(C(C)(C)C)cc(c31)O2)c1cc(C(C)(C)C)cc2c1B4c1cncc3c4cnccc4n-2c13 ; CC(C)(C)c1ccc2c(c1)B1c3cc(C(C)(C)C)cc4c3N(c3cc(C(C)(C)C)cc(c31)O2)c1cc(C(C)(C)C)cc2c1B4c1c(C(C)(C)C)ccc3c4ccc(C(C)(C)C)cc4n-2c13]
wherein optionally, hydrogens in the above compounds can be partially or fully substituted with deuterium.

21. The organic electroluminescent device according to claim 1, wherein the organic layer is an emissive layer, the metal complex is a phosphorescent sensitizer, and the fluorescent material is a delayed fluorescent material; preferably, the fluorescent material is a thermally activated delayed fluorescent material.

22. The organic electroluminescent device according to claim 21, wherein the emissive layer comprises at least one first host compound;
preferably, the emissive layer further comprises at least two host compounds;
more preferably, at least one of the host compounds comprises at least one chemical group selected from the group consisting of: benzene, pyridine, pyrimidine, triazine, carbazole, azacarbazole, indolocarbazole, dibenzothiophene, aza-dibenzothiophene, dibenzofuran, azadibenzofuran, dibenzoselenophene, triphenylene, azatriphenylene, fluorene, silafluorene, naphthalene, quinoline, isoquinoline, quinazoline, quinoxaline, phenanthrene, azaphenanthrene, and combinations thereof.

23. The organic electroluminescent device according to claim 22, wherein the first host compound has a structure represented by Formula X-1 or Formula X-2: 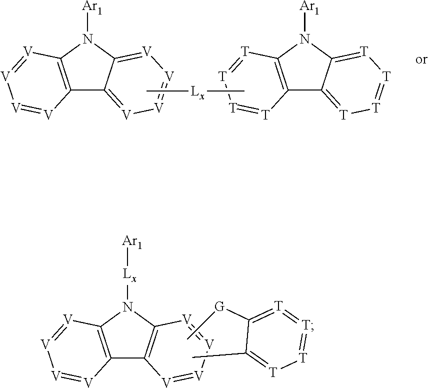
wherein
Lₓ is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 30 carbon atoms, substituted or unsubstituted heteroarylene having 3 to 30 carbon atoms, or a combination thereof;
G is, at each occurrence identically or differently, selected from C(R_{g})₂, NR_{g}, O, or S;
V is, at each occurrence identically or differently, selected from C, CRᵥ, or N;
in Formula X-1, T is, at each occurrence identically or differently, selected from C, CR_{T}, or N;
in Formula X-2, T is, at each occurrence identically or differently, selected from CR_{T} or N;
R_{g}, Rᵥ, and R_{T} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
Ar₁ is, at each occurrence identically or differently, selected from substituted or unsubstituted aryl having 6 to 30 carbon atoms, substituted or unsubstituted heteroaryl having 3 to 30 carbon atoms, or a combination thereof; and
adjacent substituents R_{g}, R_{y}, and R_{T} can be optionally joined to form a ring.

24. The organic electroluminescent device according to claim 22, wherein the emissive layer comprises the first host compound and a second host compound, and the second host compound has a structure represented by Formula Y: 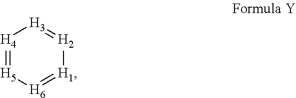
wherein
H₁ to H₆ are, at each occurrence identically or differently, selected from C, CRₕ, or N, at least two of H₁ to H₆ are N, and at least one of H₁ to H₆ is C and joined to Formula A: 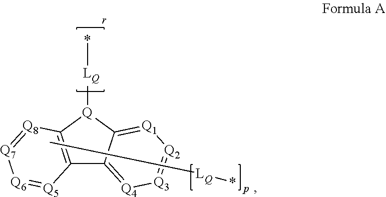
wherein
Q is, at each occurrence identically or differently, selected from the group consisting of O, S, Se, N, NR_{Q}, CR_{Q}R_{Q}, SiR_{Q}R_{Q}, GeR_{Q}R_{Q}, and R_{Q}C═CR_{Q}; when two R_{Q} are present at the same time, the two R_{Q} may be identical or different;
p is 0 or 1; r is 0 or 1;
when Q is selected from N, p is 0 and r is 1;
when Q is selected from the group consisting of O, S, Se, NR_{Q}, CR_{Q}R_{Q}, SiR_{Q}R_{Q}, GeR_{Q}R_{Q}, and R_{Q}C═CR_{Q}, p is 1 and r is 0;
L_{Q} is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 30 carbon atoms, substituted or unsubstituted heteroarylene having 3 to 30 carbon atoms, or a combination thereof;
Q₁ to Q₈ are, at each occurrence identically or differently, selected from C, CR_{q}, or N;
Rₕ, R_{Q}, and R_{q} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
“*” represents a position where Formula A is joined to Formula Y; and
adjacent substituents Rₕ, R_{Q}, and R_{q} can be optionally joined to form a ring.

25. A compound composition, comprising a metal complex and a fluorescent material; wherein the metal complex comprises a metal M and a ligand Lₐ coordinated to the metal M, the metal M is selected from a metal with a relative atomic mass greater than 40, and the ligand Lₐ has a structure represented by Formula 1: 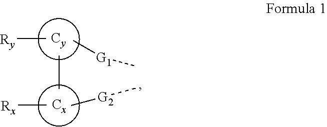
wherein
the ring C_{y} and the ring Cₓ are, at each occurrence identically or differently, selected from an aromatic ring having 6 to 30 ring atoms, a heteroaromatic ring having 5 to 30 ring atoms, or a combination thereof;
G₁ and G₂ are, at each occurrence identically or differently, selected from a single bond, O, S, or NR_{N};
Rₓ and R_{y} represent, at each occurrence identically or differently, mono-substitution, multiple substitutions, or non-substitution;
R_{N}, Rₓ, and R_{y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R_{N}, Rₓ, and R_{y} can be optionally joined to form a ring;
the fluorescent material has a structure represented by Formula 2: 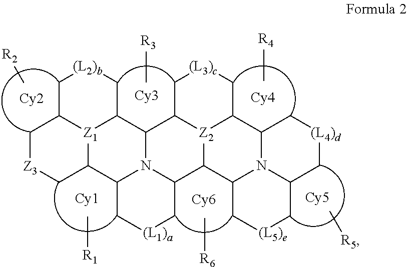
wherein
the ring Cy1, the ring Cy2, the ring Cy3, the ring Cy4, the ring Cy5, and the ring Cy6 are, at each occurrence identically or differently, selected from an unsaturated carbocyclic ring having 5 to 30 carbon atoms, an unsaturated heterocyclic ring having 3 to 30 carbon atoms, or a combination thereof;
Z₁ and Z₂ are, at each occurrence identically or differently, selected from B, N, P, P═O, P═S, As, As═O, or As═S;
Z₃ is, at each occurrence identically or differently, selected from O, S, Se, PR, P═OR, CRR, SiRR, GeRR, C═O, C═S, or C═CRR; when multiple R are present, the multiple R are identical or different;
L₁, L₂, L₃, L₄, and L₅ are, at each occurrence identically or differently, selected from a single bond, O, S, Se, BR′, NR′, PR′, P═OR′, P═SR′, AsR′, As═OR′, As═SR′, C—O, CR′R′, SiR′R′, or GeR′R′; when multiple R′ are present, the multiple R′ are identical or different;
a, b, c, d, and e are each independently selected from 0 or 1;
R₁, R₂, R₃, R₄, R₅, and R₆ represent, at each occurrence identically or differently, mono-substitution, multiple substitutions, or non-substitution;
R, R′, R₁, R₂, R₃, R₄, R₅, and R₆ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, —BR″R″, and combinations thereof;
R″ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents R, R′, R″, R₁, R₂, R₃, R₄, R₅, and R₆ can be optionally joined to form a ring.

26. A display apparatus, comprising the organic electroluminescent device according to claim 1.
